(19) United States
(12) Patent Application Publication
(10) Pub. No.: US 2024/0124497 A1
(43) Pub. Date: Apr. 18, 2024

(54) LIGHT EMITTING DEVICE AND FUSED POLYCYCLIC COMPOUND FOR THE LIGHT EMITTING DEVICE

(71) Applicant: Samsung Display Co., Ltd., Yongin-si (KR)

(72) Inventors: MinJae SUNG, Yongin-si (KR); TAEIL KIM, Yongin-si (KR); JUNHA PARK, Yongin-si (KR); JANG YEOL BAEK, Yongin-si (KR); MINJUNG JUNG, Yongin-si (KR); Seonhyoung HUR, Yongin-si (KR)

(73) Assignee: Samsung Display Co., Ltd., Yongin-si (KR)

(21) Appl. No.: 18/327,298

(22) Filed: Jun. 1, 2023

(30) Foreign Application Priority Data
Sep. 1, 2022 (KR) 10-2022-0111000

(51) Int. Cl. C07F 5/02; C07F 7/08; C07F 13/00; C09K 11/06; H10K 85/40; H10K 85/60

(52) U.S. Cl. CPC C07F 5/027; C07F 7/0805; C07F 13/00; C09K 11/06; H10K 85/40; H10K 85/633; H10K 85/6572; H10K 85/6574; H10K 85/658; C07B 2200/05

(57) ABSTRACT

Embodiments provide a fused polycyclic compound and a light emitting device including the fused polycyclic compound. The light emitting device includes a first electrode, a second electrode facing the first electrode, and an emission layer disposed between the first electrode and the second electrode, wherein the emission layer includes the fused polycyclic compound, which is represented by Formula 1 and is explained in the specification:

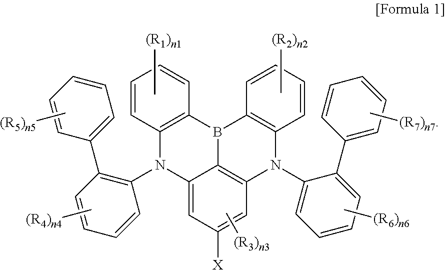

### CROSS-REFERENCE TO RELATED APPLICATION(S)

This application claims priority to and benefits of Korean Patent Application No. 10-2022-0111000 under 35 U.S.C. § 119, filed on Sep. 1, 2022 in the Korean Intellectual Property Office, the entire contents of which are incorporated herein by reference.

### BACKGROUND

### 1. Technical Field

The disclosure relates to a light emitting device and a fused polycyclic compound used in the light emitting device.

### 2. Description of the Related Art

Active development continues for an organic electroluminescence display apparatus as an image display apparatus. In contrast to liquid crystal display apparatuses and the like, the organic electroluminescence display apparatus is a so-called self-luminescent display apparatus in which holes and electrons respectively injected from a first electrode and a second electrode recombine in an emission layer, so that a luminescent material including an organic compound in the emission layer emits light to achieve display.

In the application of an organic electroluminescence device to a display apparatus, there is a demand for an organic electroluminescence device having a low driving voltage, high luminous efficiency, and a long service life, and continuous development is required on materials for an organic electroluminescence device that are capable of stably attaining such characteristics.

In order to implement a highly efficient organic electroluminescence device, technologies pertaining to phosphorescence emission using triplet state energy or to fluorescence using triplet-triplet annihilation (TTA) in which singlet excitons are generated by collision of triplet excitons are being developed, and development is currently directed to thermally activated delayed fluorescence (TADF) materials using delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device in which luminous efficiency and a device service life are improved.

The disclosure also provides a fused polycyclic compound that is capable of improving luminous efficiency and device service life for a light emitting device.

An embodiment provides a light emitting device which may include a first electrode, a second electrode facing the first electrode, and an emission layer disposed between the first electrode and the second electrode, wherein the emission layer includes a first compound represented by Formula 1:

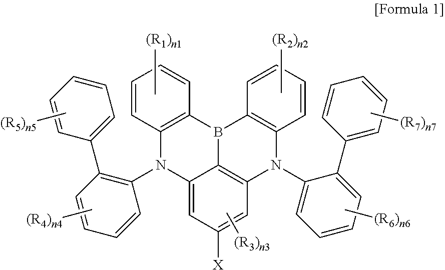

In Formula 1, X may be a substituted or unsubstituted cycloalkyl having 6 to 12 ring-forming carbon atoms; R₁ to R₇ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; n1, n2, n4, and n6 may each independently be an integer from 0 to 4; n3 may be an integer from 0 to 2; and n5 and n7 may each independently be an integer from 0 to 5.

In an embodiment, X may be a group represented by any one of Formula A-1 to Formula A-4:

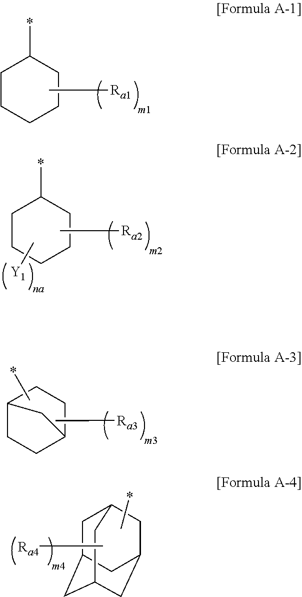

In Formula A-1 to Formula A-4, Rₐ₁ to Rₐ₄ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; Y₁ may be a substituted or unsubstituted alkyl group having 1 to 10 carbon atoms; m1 and m3 may each independently be an integer from 0 to 11; m2 may be an integer from 0 to 10; na may be an integer from 1 to 11; a sum of m2 and na may be less than or equal to 11; m4 may be an integer from 0 to 15; and [symbol] represents a position linked to Formula 1.

In an embodiment, the first compound may be represented by any one of Formula 2-1 to Formula 2-3:

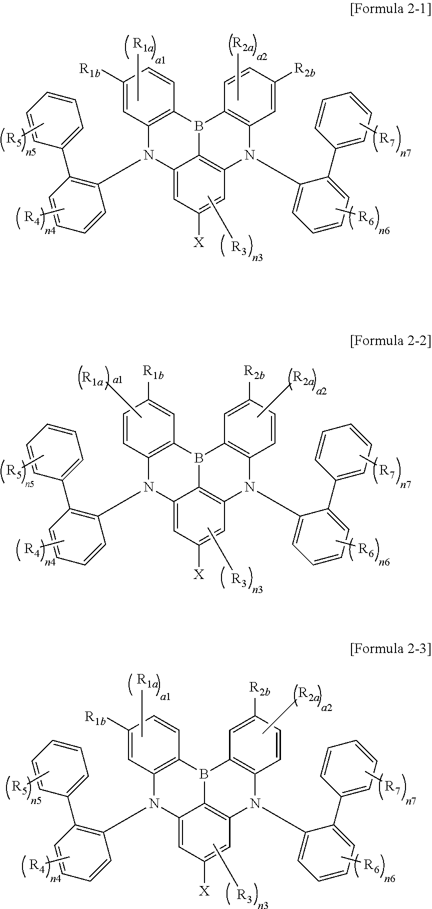

In Formula 2-1 to Formula 2-3, R₁ₐ and R₂ₐ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; R_{1b} and R_{2b} may each independently be a substituted or unsubstituted aryl group having 6 to 30 ring-forming carbon atoms or a substituted or unsubstituted heteroaryl group having 2 to 30 ring-forming carbon atoms; and a1 and a2 may each independently be an integer from 0 to 3.

In Formula 2-1 to Formula 2-3, X, R₃ to R₇, and n3 to n7 are the same as defined in Formula 1.

In an embodiment, R_{1b} and R_{2b} may each independently be a group represented by any one of Formula B-1 to Formula B-3:

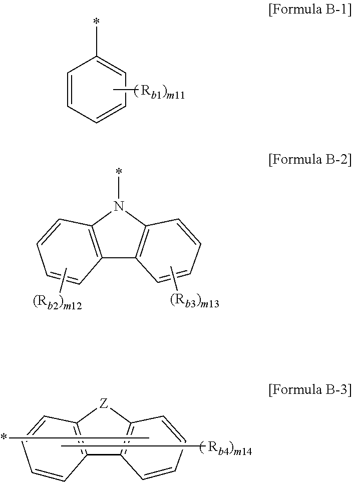

In Formula B-1 to Formula B-3, Z may be N(R_{b5}), O, or S; R_{b1} to R_{b5} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; m11 may be an integer from 0 to 5; m12 and m13 may each independently be an integer from 0 to 4; and m14 may be an integer from 0 to 7.

In an embodiment, the first compound may be represented by any one of Formula 3-1 to Formula 3-7:

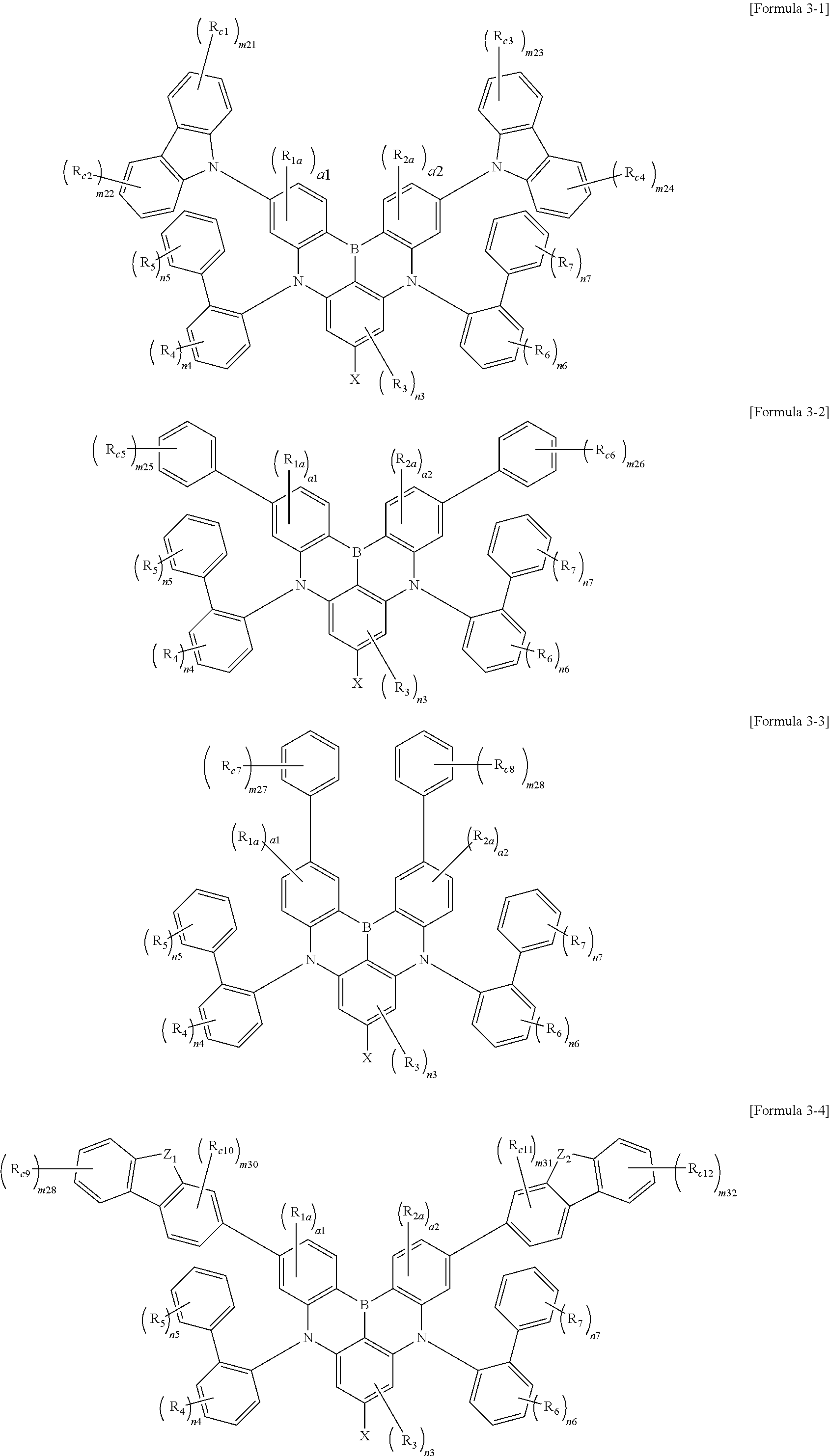

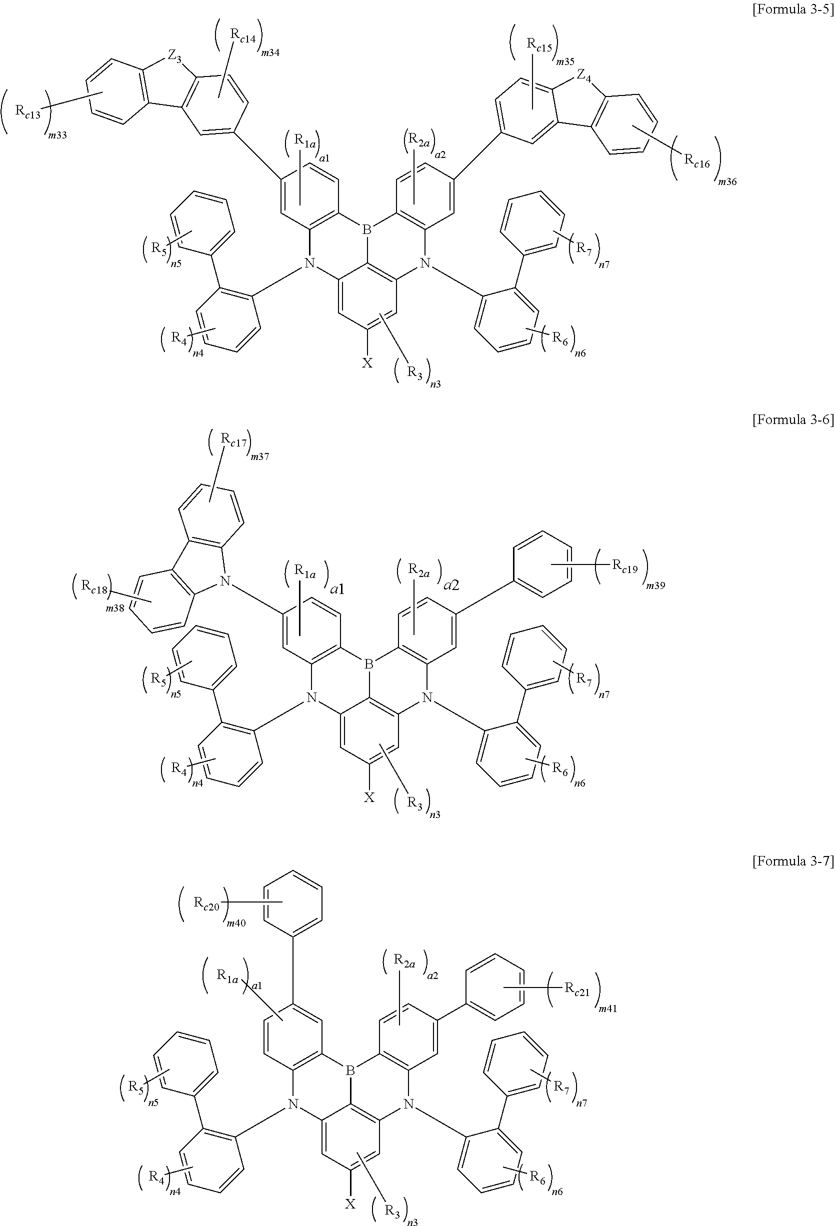

In Formula 3-1 to Formula 3-7, R₁ₐ and R₂ₐ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; Z₁ to Z₄ may each independently be N(R_{c22}), O, or S; R_{c1} to R_{c22} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; a1 and a2 may each independently be an integer from 0 to 3; m21 to m24, m29, m32, m33, and m36 to m38 may each independently be an integer from 0 to 4; m25 to m28 and m39 to m41 may each independently be an integer from 0 to 5; and m30, m31, m34, and m35 may each independently be an integer from 0 to 3.

In Formula 3-1 to Formula 3-7, X, R₃ to R₇, and n3 to n7 are the same as defined in Formula 1.

In an embodiment, the first compound may be represented by any one of Formula 4-1 to Formula 4-4:

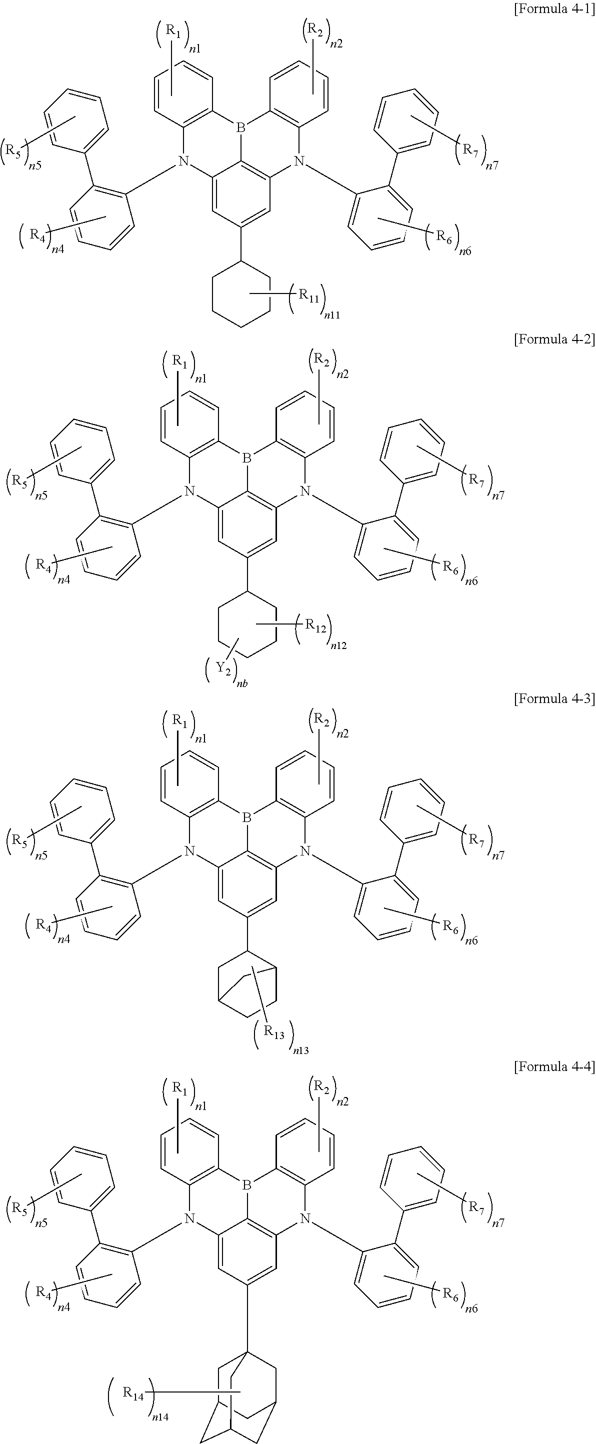

In Formula 4-1 to Formula 4-4, R₁₁ to R₁₄ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; Y₂ may be a substituted or unsubstituted alkyl group having 1 to 10 carbon atoms; n11 and n13 may each independently be an integer from 0 to 11; n12 may be an integer from 0 to 10; nb may be an integer from 1 to 11; a sum of n12 and nb may be less than or equal to 11; and n14 may be an integer from 0 to 15.

In Formula 4-1 to Formula 4-4, R₁ to R₇ and n1 to n7 are the same as defined in Formula 1.

In an embodiment, the first compound may be represented by Formula 5:

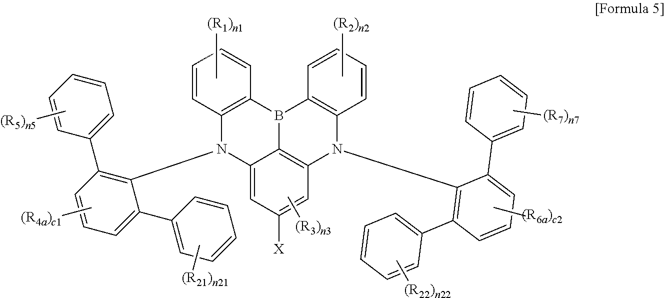

In Formula 5, R₄ₐ, R₆ₐ, R₂₁, and R₂₂ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; c1 and c2 may each independently be an integer from 0 to 3; and n21 and n22 may each independently be an integer from 0 to 5.

In Formula 5, X, R₁ to R₃, R₅, R₇, n1 to n3, n5, and n7 are the same as defined in Formula 1.

In an embodiment, the first compound may be represented by any one of Formula 6-1 to Formula 6-3:

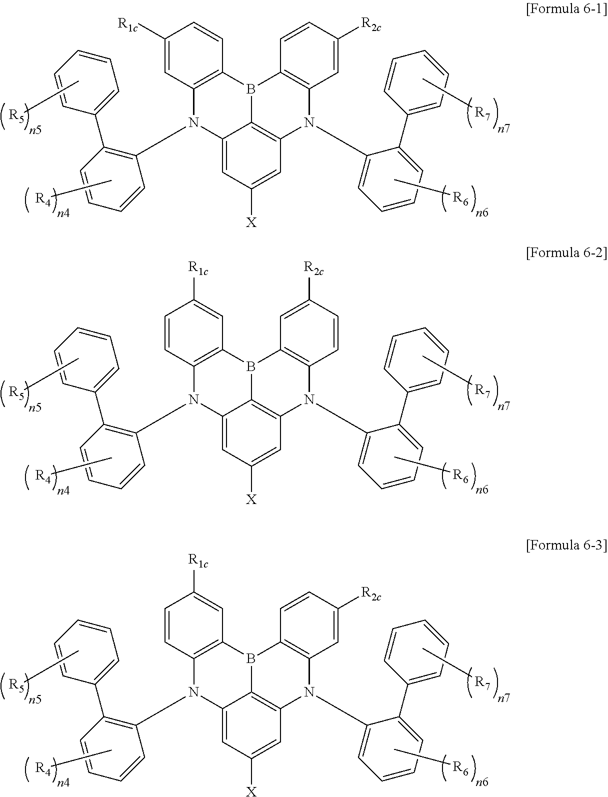

In Formula 6-1 to Formula 6-3, R_{1c} and R_{2c} may each independently be a substituted or unsubstituted phenyl group, a substituted or unsubstituted carbazole group, or a substituted or unsubstituted dibenzofuran group.

In Formula 6-1 to Formula 6-3, X, R₄ to R₇, and n4 to n7 are the same as defined in Formula 1.

In an embodiment, the first compound may include at least one compound selected from Compound Group 1, which is explained below.

In an embodiment, the emission layer may further include at least one of a second compound represented by Formula HT-1 or a third compound represented by Formula ET-1:

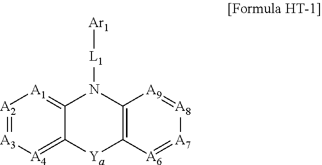

In Formula HT-1, A₁ to A₄ and A₆ to A₉ may each independently be N or C(R₄₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₄₂)(R₄₃), or Si(R₄₄)(R₄₅); Ar₁ may be a substituted or unsubstituted aryl group having 6 to 30 ring-forming carbon atoms or a substituted or unsubstituted heteroaryl group having 2 to 30 ring-forming carbon atoms; R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

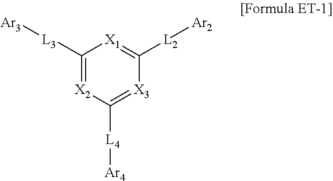

In Formula ET-1, at least one of X₁ to X₃ may be N; the remainder of X₁ to X₃ may each independently be C(R₄₆); R₄₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms; and Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the emission layer may further include a fourth compound represented by Formula D-1:

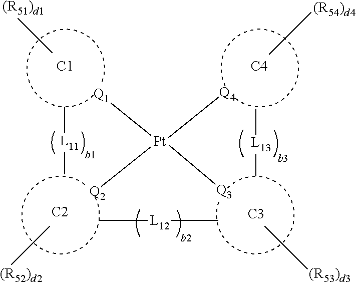

In Formula D-1, Q₁ to Q₄ may each independently be C or N; C1 to C4 may each independently be a substituted or unsubstituted hydrocarbon ring having 5 to 30 ring-forming carbon atoms or a substituted or unsubstituted heterocycle having 2 to 30 ring-forming carbon atoms; L₁₁ to L₁₃ may each independently be a direct linkage,

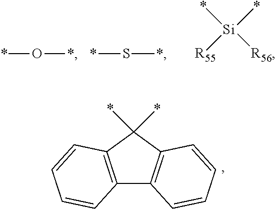

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b1 to b3 may each independently be 0 or 1; R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and d1 to d4 may each independently be an integer from 0 to 4.

An embodiment provides a fused polycyclic compound which may be represented by Formula 1, which is explained herein.

In an embodiment, X may be a group represented by any one of Formula A-1 to Formula A-4, which are explained herein.

In an embodiment, Formula 1 may be represented by any one of Formula 2-1 to Formula 2-3, which are explained herein.

In an embodiment, R_{1b} and R_{2b} may each independently be a group represented by any one of Formula B-1 to Formula B-3, which are explained herein.

In an embodiment, Formula 1 may be represented by any one of Formula 3-1 to Formula 3-7, which are explained herein.

In an embodiment, Formula 1 may be represented by any one of Formula 4-1 to Formula 4-4, which are explained herein.

In an embodiment, Formula 1 may be represented by Formula 5, which is explained herein.

In an embodiment, Formula 1 may be represented by any one of Formula 6-1 to Formula 6-3, which are explained herein.

In an embodiment, the fused polycyclic compound may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic cross-sectional view of a light emitting device according to an embodiment;

FIG. 4 is a schematic cross-sectional view of a light emitting device according to an embodiment;

FIG. 5 is a schematic cross-sectional view of a light emitting device according to an embodiment;

FIG. 6 is a schematic cross-sectional view of a light emitting device according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment;

FIG. 10 is a schematic cross-sectional view of a display apparatus according to an embodiment; and

FIG. 11 is a schematic perspective view of an electronic apparatus including a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. Although the number of carbon atoms in an alkynyl group is not specifically limited, it may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of substituted fluorenyl groups are as follows. However, embodiments are not limited thereto.

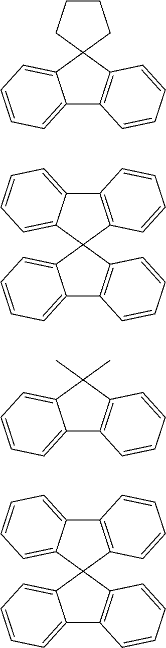

In the specification, a heterocyclic group may be any functional group or substituent derived from a ring that includes at least one of B, O, N, P, Si, Se, or S as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, Se, or S as a heteroatom. If a heterocyclic group includes two or more heteroatoms, the two or more heteroatoms may be the same as or different from each other. A heterocyclic group may be monocyclic or polycyclic, and a heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, Se, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, Se, or S as a heteroatom. When a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that the arylene group is a divalent group. The above description of a heteroaryl group may be applied to a heteroarylene group, except that the heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not specifically limited, but may be 1 to 40, 1 to 30, or 1 to 20. For example, a carbonyl group may have one of the following structures, but embodiments are not limited thereto.

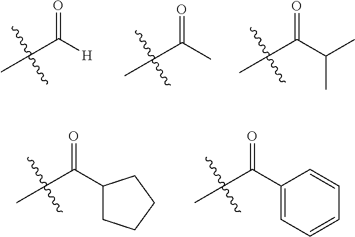

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not specifically limited, but may be, for example, 1 to 20 or 1 to 10. Examples of an oxy group may include a methoxy group, an ethoxy group, a n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not specifically limited, but may be 1 to 30. The amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, an alkyl group in an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group in an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

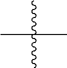

and [symbol] each represent a bonding site to a neighboring atom.

Hereinafter, embodiments will be described with reference to the accompanying drawings.

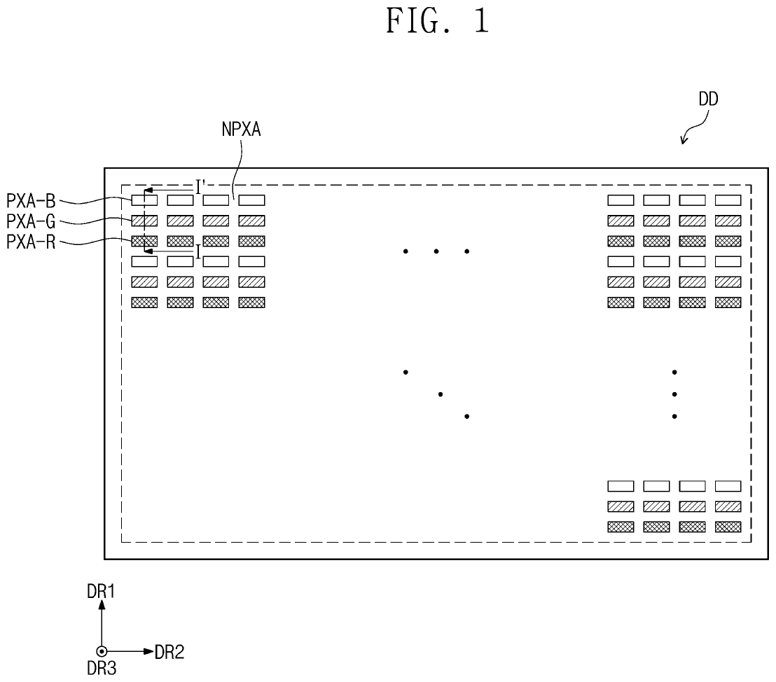

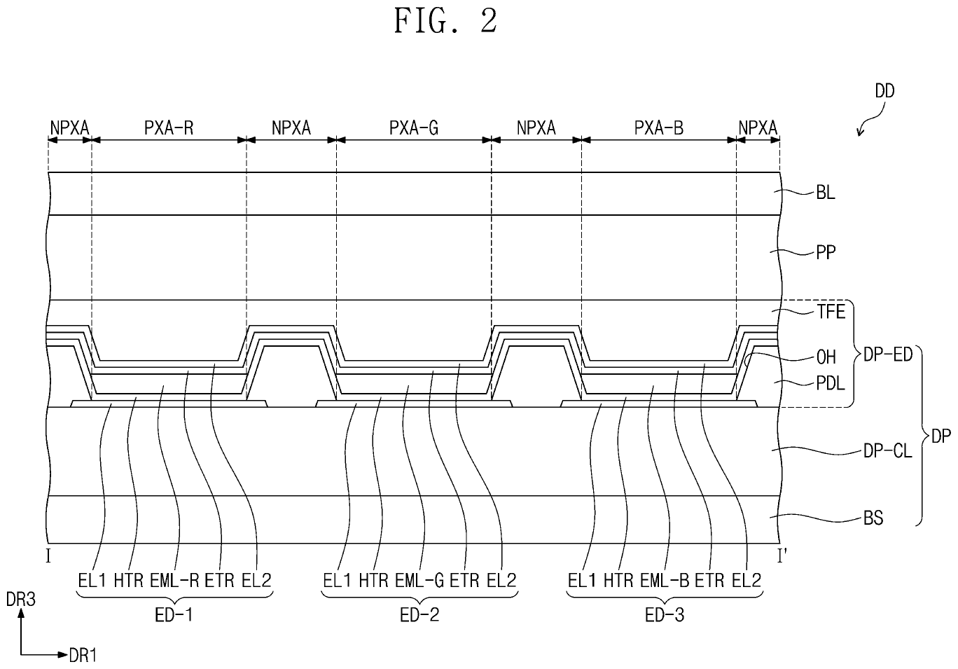

FIG. 1 is a schematic plan view of an embodiment of a display apparatus DD. FIG. 2 is a schematic cross-sectional view of a display apparatus DD according to an embodiment. FIG. 2 is a schematic cross-sectional view illustrating a part taken along line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include multiples of each of the light emitting devices ED-1, ED-2, and ED-3. The optical layer PP may be disposed on the display panel DP and may control light reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, light emitting devices ED-1, ED-2, and ED-3 disposed between portions of the pixel defining film PDL, and an encapsulation layer TFE disposed on the light emitting devices ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting devices ED-1, ED-2, and ED-3 of the display device layer DP-ED.

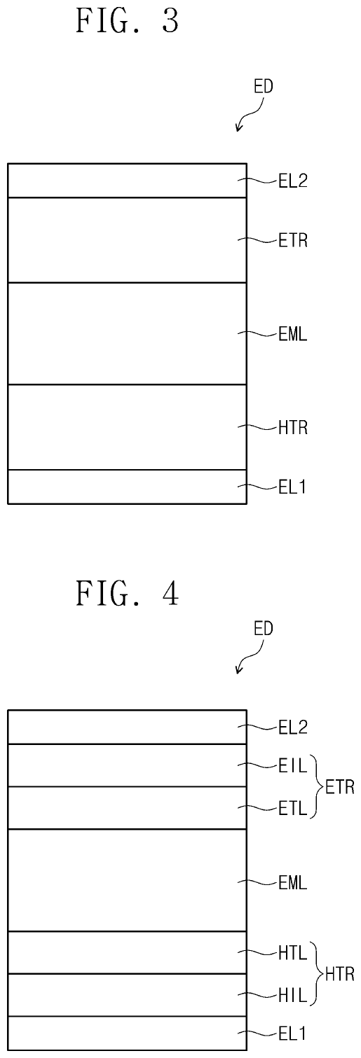

The light emitting devices ED-1, ED-2, and ED-3 may each have a structure of alight emitting device ED of an embodiment according to any of FIGS. 3 to 6, which will be described later. The light emitting devices ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are each provided as a common layer for the light emitting devices ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting devices ED-1, ED-2, and ED-3 may each be provided by being patterned by an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. In an embodiment, the encapsulation layer TFE may include at least one inorganic film (hereinafter, an encapsulation-inorganic film). In another embodiment, the encapsulation layer TFE may include at least one organic film (hereinafter, an encapsulation-organic film) and at least one encapsulation-inorganic film.

The encapsulation-inorganic film may protect the display device layer DP-ED from moisture and/or oxygen, and the encapsulation-organic film may protect the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include non-light emitting regions NPXA and light emitting regions PXA-R, PXA-G, and PXA-B. The light emitting regions PXA-R, PXA-G, and PXA-B may each be a region which emits light respectively generated by the light emitting devices ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting areas NPXA may be areas between adjacent light emitting areas PXA-R, PXA-G, and PXA-B, which may correspond to the pixel defining film PDL. For example, in an embodiment, the light emitting regions PXA-R, PXA-G, and PXA-B may each respectively correspond to a pixel. The pixel defining film PDL may separate the light emitting devices ED-1, ED-2, and ED-3. The emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting devices ED-1, ED-2, and ED-3. In the display apparatus DD according to an embodiment illustrated in FIGS. 1 and 2, three light emitting regions PXA-R, PXA-G, and PXA-B, which respectively emit red light, green light, and blue light are illustrated. For example, the display apparatus DD may include a red light emitting region PXA-R, a green light emitting region PXA-G, and a blue light emitting region PXA-B, which are separated from each other.

In the display apparatus DD according to an embodiment, the light emitting devices ED-1, ED-2, and ED-3 may emit light having different wavelengths from each other. For example, in an embodiment, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may respectively correspond to the first light emitting device ED-1, the second light emitting device ED-2, and the third light emitting device ED-3.

However, embodiments are not limited thereto, and the first to third light emitting devices ED-1, ED-2, and ED-3 may each emit light in a same wavelength range or at least one light emitting device may emit light in a wavelength range that is different from the others. For example, the first to third light emitting devices ED-1, ED-2, and ED-3 may each emit blue light.

The light emitting regions PXA-R, PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this order along a first directional axis DR1.

FIGS. 1 and 2 illustrate that the light emitting regions PXA-R, PXA-G, and PXA-B each have a similar area, but embodiments are not limited thereto. Thus, the light emitting regions PXA-R, PXA-G, and PXA-B may have different areas from each other according to a wavelength range of emitted light. For example, the areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required for the display apparatus DD. For example, the light emitting regions PXA-R, PXA-G, and PXA-B may be arranged in a pentile configuration (such as a PENTILE™ configuration) or in a diamond configuration (such as a Diamond Pixel™ configuration).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIGS. 3 to 6 are each a schematic cross-sectional view of a light emitting device according to an embodiment. The light emitting devices ED according to embodiments may each include a first electrode EL1, a hole transport region HTR, an emission layer EML, an electron transport region ETR, and a second electrode EL2, which are stacked in that order.

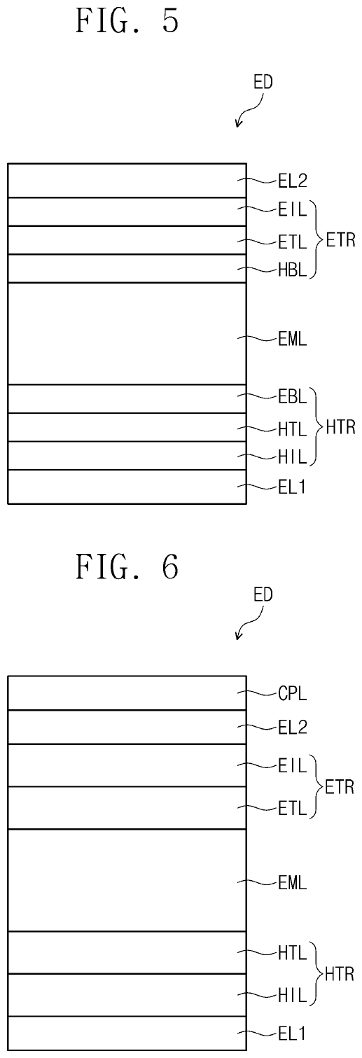

In comparison to FIG. 3, FIG. 4 shows a schematic cross-sectional view of a light emitting device ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 shows a schematic cross-sectional view of a light emitting device ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 shows a schematic cross-sectional view of a light emitting device ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective layer or a transflective layer formed of the above-described materials, and a transparent conductive layer formed of ITO, IZO, ZnO, ITZO, etc. For example, the first electrode EL1 may have a three-layer structure of ITO/Ag/ITO, but embodiments are not limited thereto. The first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

A hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting device ED according to an embodiment, the hole transport region HTR may include a compound represented by Formula H-2:

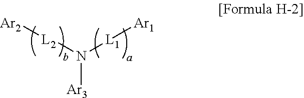

In Formula H-2, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-2, a and b may each independently be an integer from 0 to 10. When a or b is 2 or greater, multiple L₁ group and multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-2, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-2, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, compound represented by Formula H-2 may be a monoamine compound. In another embodiment, the compound represented by Formula H-2 may be a diamine compound in which at least one of Ar₁ to Ar₃ includes an amine group as a substituent. In yet another embodiment, the compound represented by Formula H-2 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-2 may be any compound selected from Compound Group H. However, the compounds listed in Compound Group H are only examples, and the compound represented by Formula H-2 is not limited to Compound Group H:

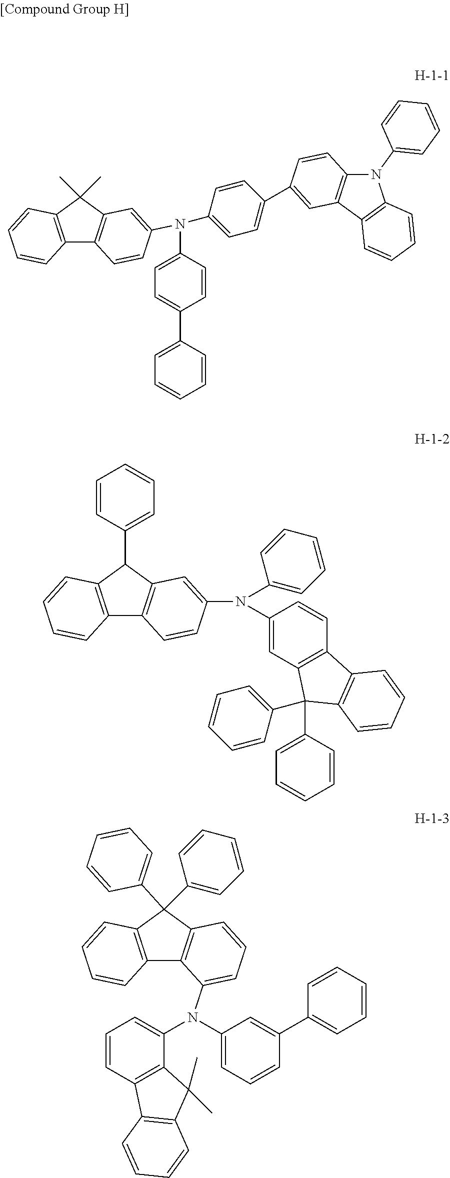 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(C2c3ccccc3-c3ccc(N(c4ccccc4)c4ccc5c(c4)C(c4ccccc4)(c4ccccc4)c4ccccc4-5)cc32)cc1 ; CC1(C)c2ccccc2-c2cccc(N(c3cccc(-c4ccccc4)c3)c3cccc4c3-c3ccccc3C4(c3ccccc3)c3ccccc3)c21]

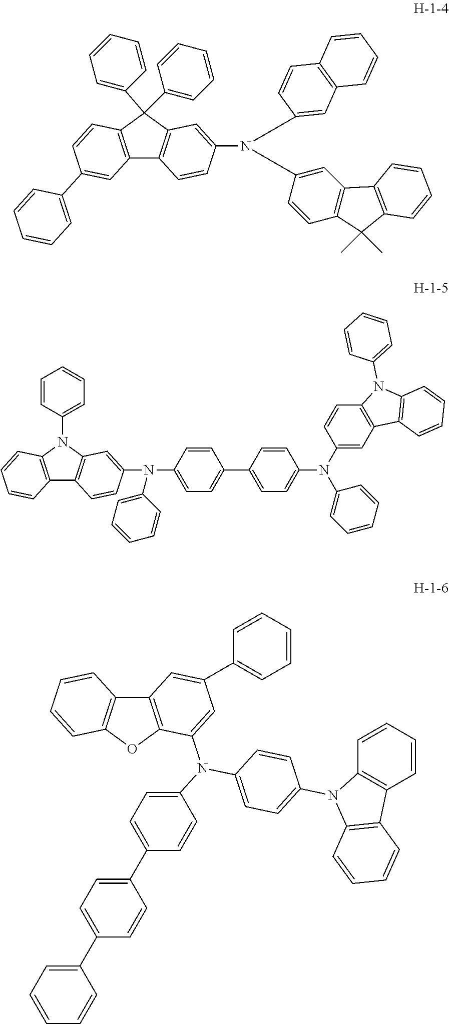 [SMILES: CC1(C)c2ccccc2-c2cc(CN(Cc3ccc4ccccc4c3)c3ccc4c(c3)C(c3ccccc3)(c3ccccc3)c3ccc(-c5ccccc5)cc3-4)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

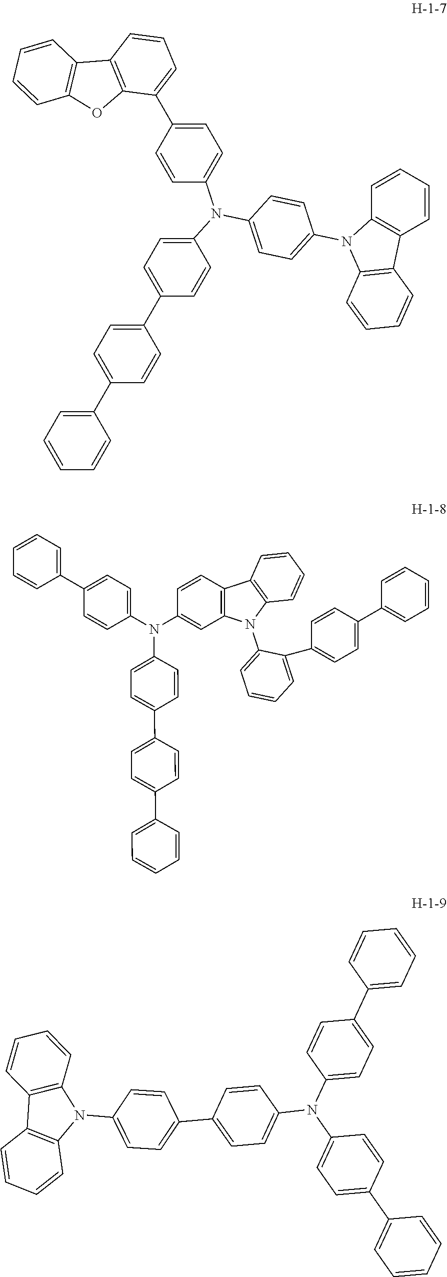 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

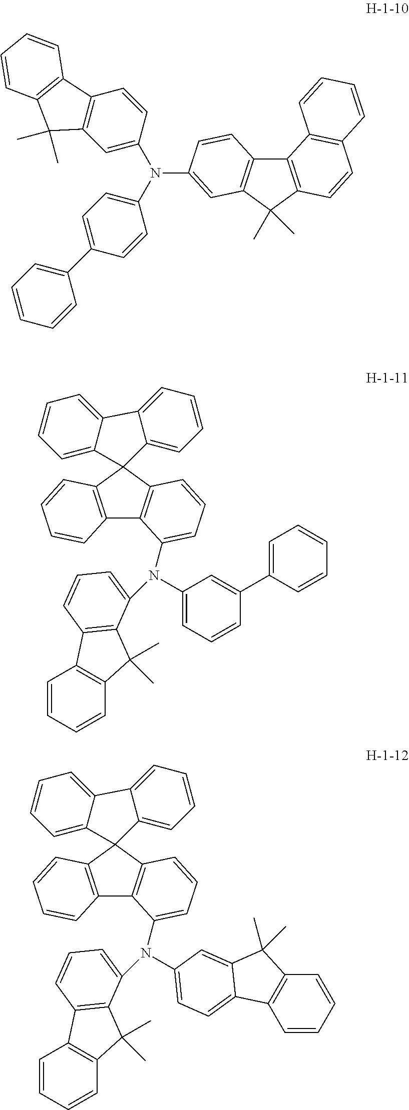

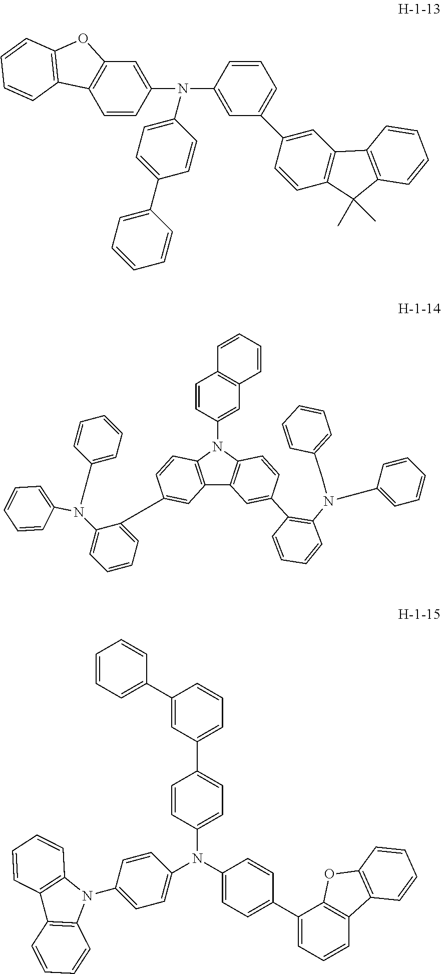 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(CN(Cc2ccccc2)c2ccccc2-c2ccc3c(c2)c2cc(Cc4ccccc4N(Cc4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

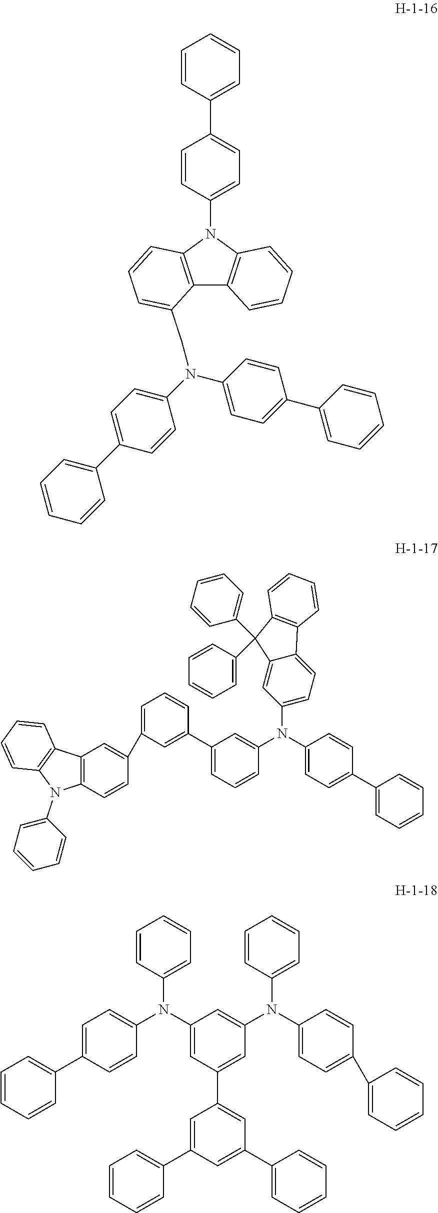 [SMILES: c1ccc(-c2ccc(N(Cc3cccc4c3c3ccccc3n4-c3ccc(-c4ccccc4)cc3)c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

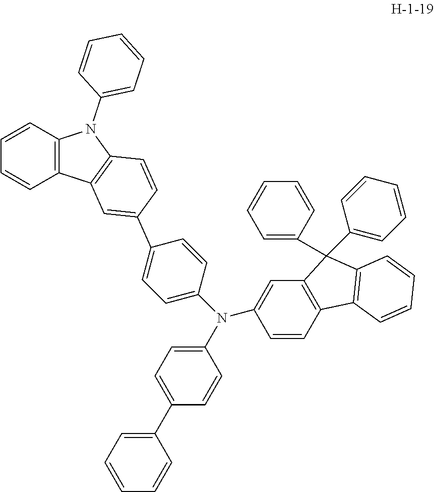 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N′,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material included in the buffer layer (not shown). The electron blocking layer EBL may prevent the injection of electrons from an electron transport region ETR to a hole transport region HTR.

The emission layer EML is provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The emission layer EML of the light emitting device ED may include a fused polycyclic compound according to an embodiment. In an embodiment, the emission layer EML may include the fused polycyclic compound as a dopant. The fused polycyclic compound may be a dopant material of the emission layer EML. In the specification, the fused polycyclic compound, which will be described later, may be referred to as a first compound.

The fused polycyclic compound may include a structure in which aromatic rings are fused via a boron atom and a nitrogen atom. The fused polycyclic compound may include a structure in which first to third aromatic rings are fused via a boron atom, a first nitrogen atom, and a second nitrogen atom. The first to third aromatic rings may each be linked to the boron atom, the first aromatic ring and the third aromatic ring may be linked via the first nitrogen atom, and the second aromatic ring and the third aromatic ring may be linked via the second nitrogen atom. In the specification, the boron atom, the first and second nitrogen atoms, and the first to third aromatic rings which are fused via the boron atom and the first and second nitrogen atoms may be referred to as a “fused ring core.”

The fused polycyclic compound may include a first substituent linked to a fused ring core. In an embodiment, the first substituent may be a substituted or unsubstituted cycloalkyl group having 6 to 12 ring-forming carbon atoms. The first substituent may be linked to the third aromatic ring of the fused ring core. The first substituent may be directly bonded to the third aromatic ring. The first substituent may be linked at a para-position to the boron atom of the fused ring core. The first substituent may be linked to the third aromatic ring at a para-position, with respect to the boron atom, among the carbon atoms constituting the third aromatic ring.

The fused polycyclic compound may include a second substituent and a third substituent, each of which is a substituent that provides steric hindrance in the molecular structure. The second substituent and the third substituent may be respectively linked to the first nitrogen atom and the second nitrogen atom of the fused ring core in the fused polycyclic compound. The second and third substituents may each be a substituent that includes a benzene moiety and in which a substituted or unsubstituted phenyl group is bonded at a specific position of the benzene moiety. The second substituent may be linked to the first nitrogen atom of the fused ring core, and include a structure in which a substituted or unsubstituted phenyl group is bonded at an ortho position with respect to the first nitrogen atom. The third substituent may be linked to the second nitrogen atom of the fused ring core, and include a structure in which a substituted or unsubstituted phenyl group is bonded at an ortho position with respect to the second nitrogen atom.

The fused polycyclic compound may be represented by Formula 1:

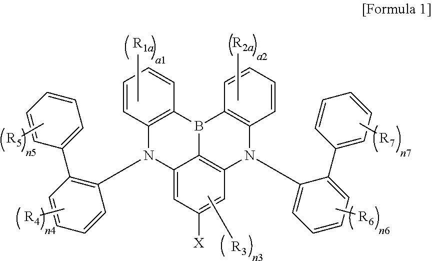

The fused polycyclic compound represented by Formula 1 may include a structure in which three aromatic rings are fused via a boron atom and two nitrogen atoms. The benzene ring that is substituted with the substituent represented by R₁ may correspond to the aforementioned first aromatic ring, the benzene ring that is substituted with a substituent represented by R₂ may correspond to the aforementioned second aromatic ring, and the benzene ring that is substituted with a substituent represented by R₃ may correspond to the aforementioned third aromatic ring. In Formula 1, X may correspond to the above-described first substituent.

In Formula 1, X may be a substituted or unsubstituted cycloalkyl group having 6 to 12 ring-forming carbon atoms. For example, X may be a substituted or unsubstituted cyclohexyl group, a substituted or unsubstituted bicycloheptanyl group, or a substituted or unsubstituted adamantyl group. For example, X may be a substituted or unsubstituted cyclohexyl group, a substituted or unsubstituted bicyclo[2,2,1]heptanyl group, or a substituted or unsubstituted adamantyl group.

In Formula 1, R₁ to R₇ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁ to R₇ may each independently be a hydrogen atom, a deuterium atom, a substituted or unsubstituted t-butyl group, a substituted or unsubstituted phenyl group, a substituted or unsubstituted carbazole group, or a substituted or unsubstituted dibenzofuran group.

In Formula 1, n1, n2, n4, and n6 may each independently be an integer from 0 to 4. If n1, n2, n4, and n6 are each 0, the fused polycyclic compound may not be substituted with R₁, R₂, R₄, and R₆. A case where n1, n2, n4, and n6 are each 4 and R₁ groups, R₂ groups, R₄ groups, and R₆ groups are all hydrogen atoms may be the same as a case where n1, n2, n4, and n6 are each 0 in Formula 1. If n1, n2, n4, and n6 are each 2 or more, multiple groups of each of R₁, R₂, R₄, and R₆ may all be the same, or at least one group thereof may be different from the remainder.

In Formula 1, n3 may be an integer from 0 to 2. If n3 is 0, the fused polycyclic compound may not be substituted with R₃. A case where n3 is 2 and R₃ groups are all hydrogen atoms may be the same as a case where n3 is 0 in Formula 1. If n3 is 2 or more, multiple groups of R₃ may all be the same, or at least one group thereof may be different from the remainder.

In Formula 1, n5 and n7 may each independently be an integer from 0 to 5. If n5 and n7 are each 0, the fused polycyclic compound may not be substituted with R₅ and R₇. A case where n5 and n7 are each 5 and R₅ groups and R₇ groups are all hydrogen atoms may be the same as a case where n5 and n7 are each 0 in Formula 1. If n5 and n7 are each 2 or more, multiple groups of R₅ and multiple groups of R₇ may all be the same, or at least one group thereof may be different from the remainder.

In an embodiment, X may be a group represented by any one of Formula A-1 to Formula A-4:

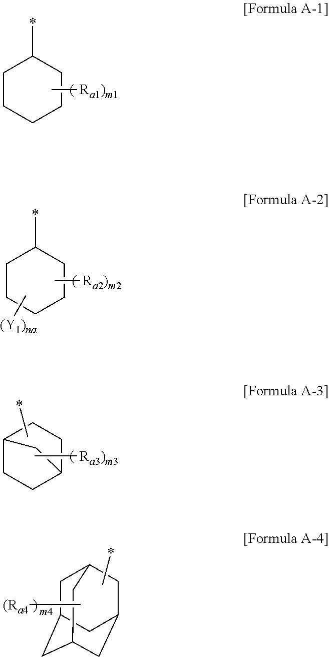

In Formula A-1 to Formula A-4, Rₐ₁ to Rₐ₄ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ₁ to Rₐ₄ may each be a hydrogen atom.

In Formula A-2, Y₁ may be a substituted or unsubstituted alkyl group having 1 to 10 carbon atoms. For example, Y₁ may be a substituted or unsubstituted methyl group, or a substituted or unsubstituted t-butyl group.

In Formula A-1 to Formula A-4, m1 and m3 may each independently be an integer from 0 to 11; m2 may be an integer from 0 to 10; na may be an integer from 1 to 11; and a sum of m2 and na may be less than or equal to 11. The substituent represented by Formula A-2 may include at least one Y₁.

If m1 and m3 are each 0, the fused polycyclic compound may not be substituted with Rₐ₁ and Rₐ₃. A case where m1 and m3 are each 11 and Rₐ₁ groups and Rₐ₃ groups are all hydrogen atoms may be the same as a case where m1 and m3 are each 0. If m1 and m3 are each 2 or more, multiple groups of Rₐ₁ and multiple groups of Rₐ₃ may all be the same, or at least one group thereof may be different from the remainder.

If m2 is 0, the fused polycyclic compound may not be substituted with Rₐ₂. A case where m2 is 10 and Rₐ₂ groups are all hydrogen atoms may be the same as a case where m2 is 0. If m2 is 2 or more, multiple groups of Rₐ₂ may all be the same, or at least one group thereof may be different from the remainder.

If na is 2 or more, multiple groups of Y₁ may all be the same, or at least one group thereof may be different from the remainder.

In Formula A-4, m4 may be an integer from 0 to 15. If m4 is 0, the fused polycyclic compound may not be substituted with Rₐ₄. A case where m3 is 15 and Rₐ₄ groups are all hydrogen atoms may be the same as a case where m4 is 0. If m4 is 2 or more, multiple groups of Rₐ₄ may all be the same, or at least one group thereof may be different from the remainder.

In Formula A-1 to Formula A-4, [symbol] represents a position linked to Formula 1.

In an embodiment, the group represented by Formula A-2 may be a group represented by any one of Formula A-2-1 to Formula A-2-4:

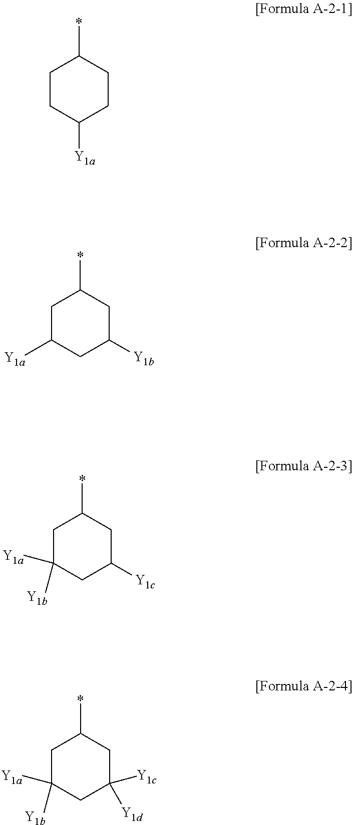

Formula A-2-1 to Formula A-2-4 represent cases where the number and bonding position of Y₁ groups are further defined in Formula A-2.

In Formula A-2-1 to Formula A-2-4, Y₁ₐ to Y_{1d} may each independently be a substituted or unsubstituted alkyl group having 1 to 10 carbon atoms. For example, Y₁ₐ to Y_{1d} may each independently be a substituted or unsubstituted methyl group or a substituted or unsubstituted t-butyl group.

In an embodiment, the first compound represented by Formula 1 may be represented by any one of Formula 2-1 to Formula 2-3:

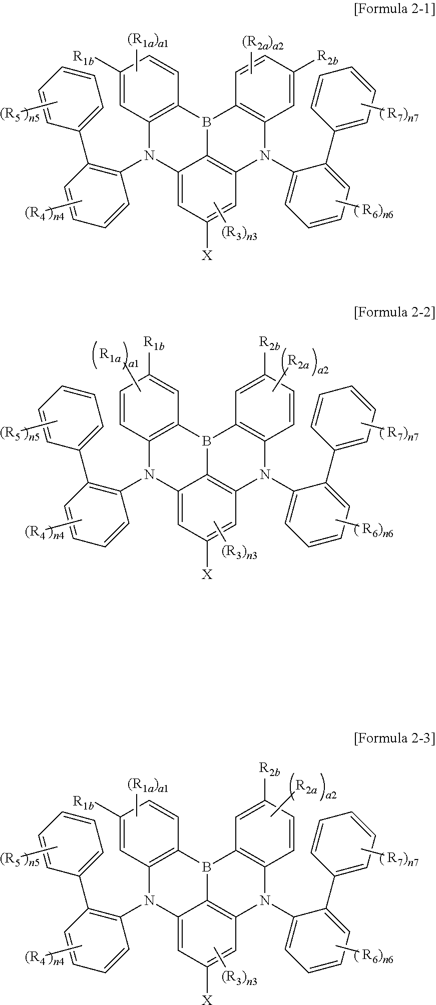

Formula 2-1 to Formula 2-3 represent cases where the type and bonding positions of R₁ and R₂ in Formula 1 are further defined.

Formula 2-1 represents a case wherein in Formula 1, at least one of R₁ and R₂, other than a hydrogen atom, is bonded at a para-position to the boron atom. Formula 2-2 represents a case wherein in Formula 1, at least one of R₁, other than a hydrogen atom, is bonded at a para-position to the first nitrogen atom, and at least one of R₂, other than a hydrogen atom, is bonded at a para-position to the second nitrogen atom. Formula 2-3 represents a case wherein in Formula 1, at least one of R₁, other than a hydrogen atom, is bonded at a para-position to the boron atom, and at least one of R₂, other than a hydrogen atom, is bonded at a para-position to the second nitrogen atom.

In Formula 2-1 to Formula 2-3, R₁ₐ and R₂ₐ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ria and R₂ₐ may each be a hydrogen atom.

In Formula 2-1 to Formula 2-3, R_{1b} and R_{2b} may each independently be a substituted or unsubstituted aryl group having 6 to 30 ring-forming carbon atoms or a substituted or unsubstituted heteroaryl group having 2 to 30 ring-forming carbon atoms. For example, R_{1b} and R_{2b} may each independently be a substituted or unsubstituted phenyl group, a substituted or unsubstituted carbazole group, or a substituted or unsubstituted dibenzofuran group.

In Formula 2-1 to Formula 2-3, a1 and a2 may each independently be an integer from 0 to 3. If a1 and a2 are each 0, the fused polycyclic compound may not be substituted with R₁ₐ and R₂ₐ. A case where a1 and a2 are each 3 and R₁ₐ groups and R₂ₐ groups are all hydrogen atoms may be the same as a case where a1 and a2 are each 0. If a1 and a2 are each 2 or more, multiple groups of R₁ₐ and multiple groups of R₂ₐ may all be the same, or at least one group thereof may be different from the remainder.

In Formula 2-1 to Formula 2-3, X, R₃ to R₇, and n3 to n7 are the same as described in Formula 1.

In an embodiment, R_{1b} and R_{2b} may each independently be a group represented by any one of Formula B-1 to Formula B-3:

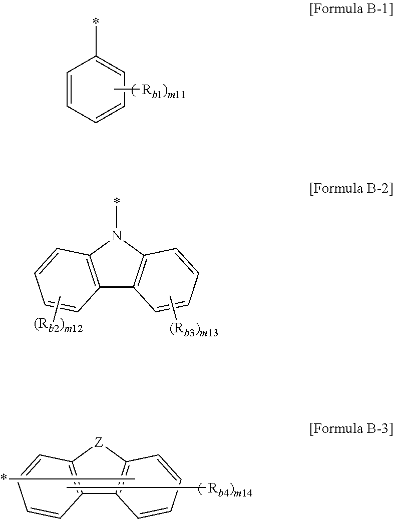

In Formula B-3, Z may be N(R_{b5}), O, or S. For example, Z may be O.

In Formula B-1 to Formula B-3, R_{b1} to R_{b5} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b1} to R_{b}s may each independently be a hydrogen atom, a deuterium atom, a halogen atom, a cyano group, a substituted or unsubstituted diphenylamine group, a substituted or unsubstituted trimethylsilyl group, a substituted or unsubstituted methoxy group, a substituted or unsubstituted t-butyl group, or a substituted or unsubstituted carbazole group.

In Formula B-1, m11 may be an integer from 0 to 5. If m11 is 0, the substituent represented by Formula B-1 may not be substituted with R_{b1}. A case where m11 is 5 and R_{b1} groups are all hydrogen atoms may be the same as a case where m11 is 0. If m11 is 2 or more, multiple groups of R_{b1} may all be the same, or at least one group thereof may be different from the remainder.

In Formula B-2, m12 and m13 may each independently be an integer from 0 to 4. If m12 and m13 are each 0, the substituent represented by Formula B-2 may not be substituted with R_{b2} and R_{b5}. A case where m12 and m13 are each 4 and R_{b2} groups and R_{b3} groups are all hydrogen atoms may be the same as a case where m12 and m13 are each 0. If m12 and m13 are each 2 or more, multiple groups of R_{b2} and multiple groups of R_{b3} may all be the same, or at least one group thereof may be different from the remainder.

In Formula B-3, m14 may be an integer from 0 to 7. If m14 is 0, the substituent represented by Formula B-3 may not be substituted with R_{b4}. A case where m14 is 7 and R_{b4} groups are all hydrogen atoms may be the same as a case where m14 is 0. If m14 is 2 or more, multiple groups of R_{b4} may be all the same, or at least one group thereof may be different from the remainder.

In an embodiment, R_{1b} and R_{2b} may each independently be a group represented by any one of Formula C-1 to Formula C-13:

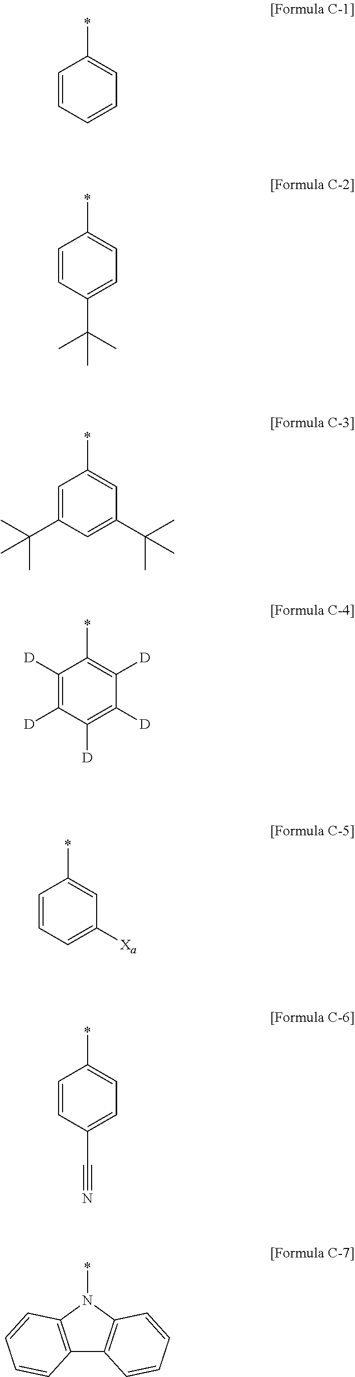

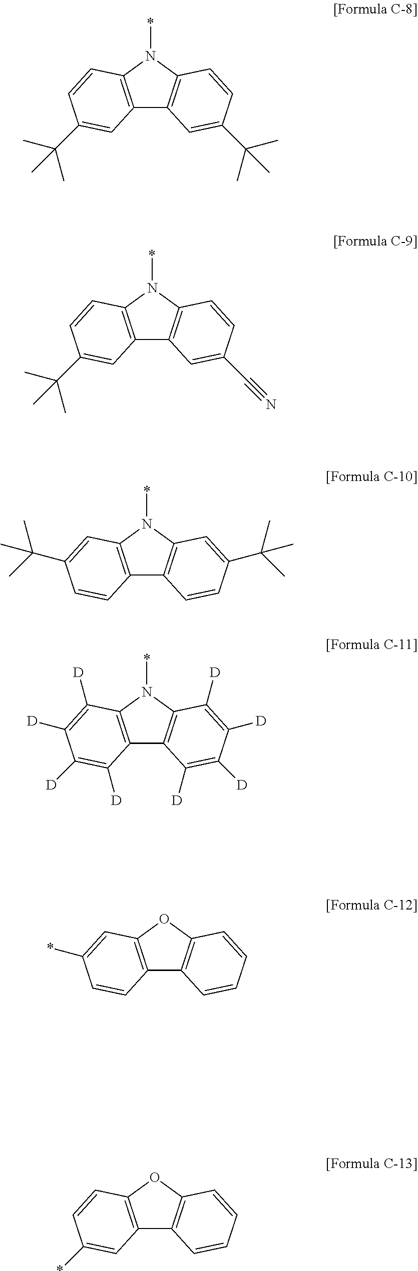

In Formula C-5, Xₐ may be a halogen atom, a substituted or unsubstituted methoxy group, a substituted or unsubstituted trimethylsilyl group, a substituted or unsubstituted diphenylamine group, or a substituted or unsubstituted carbazole group. In Formula C-4 and Formula C-11, D represents a deuterium atom.

In an embodiment, the first compound represented by Formula 1 may be represented by any one of Formula 3-1 to Formula 3-7:

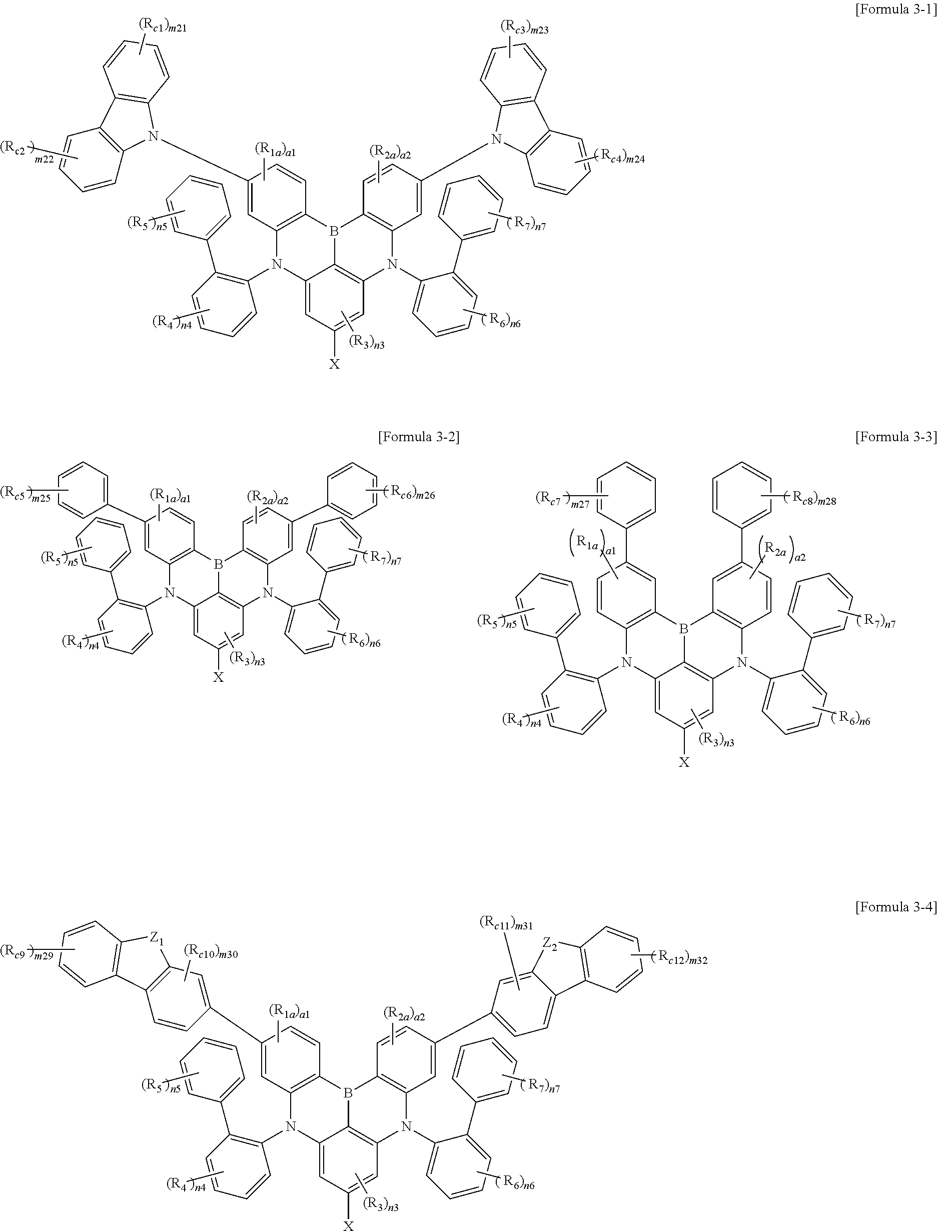

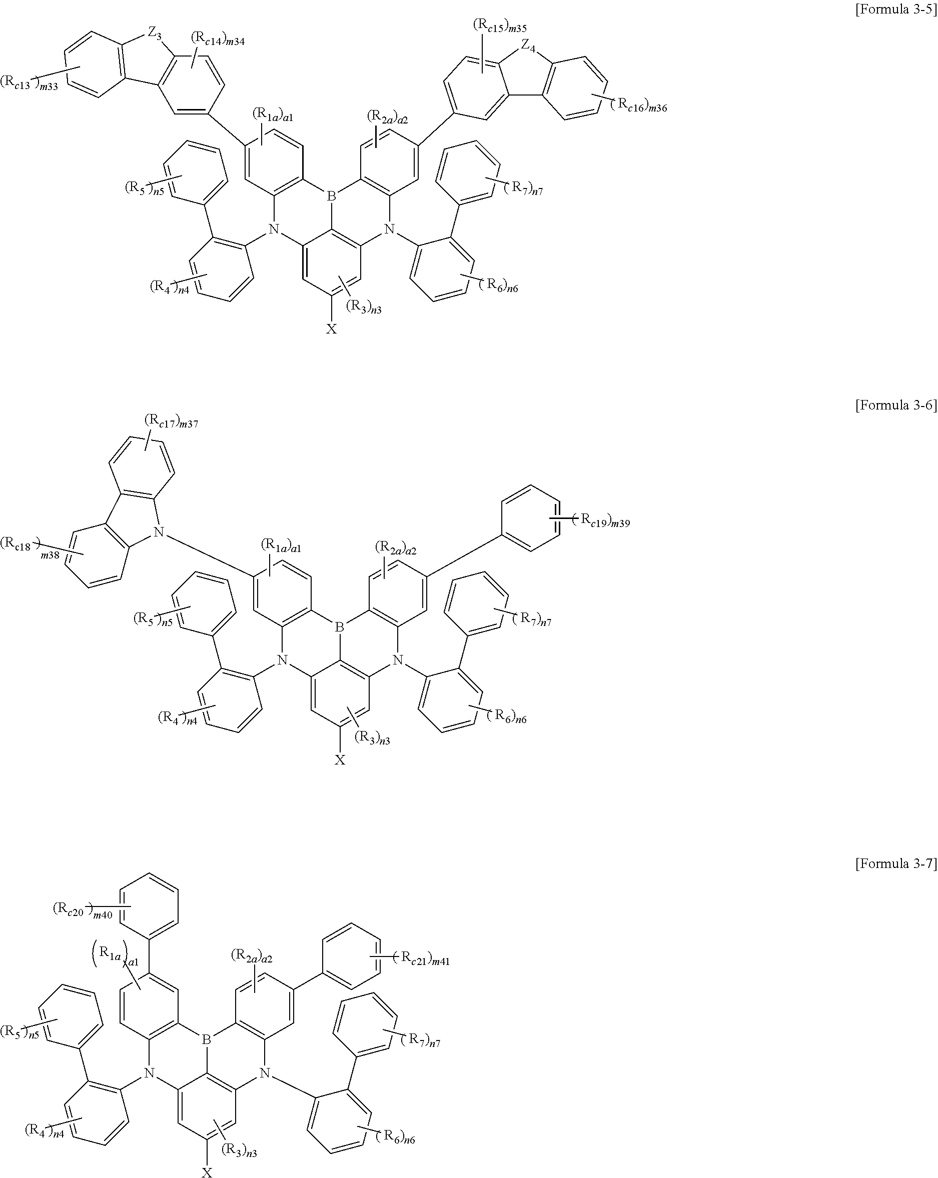

Formula 3-1 to Formula 3-7 represent cases where the type and bonding positions of R₁ and R₂ in Formula 1 are further defined.

In Formula 3-1 to Formula 3-7, R₁ₐ and R₂ₐ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁ₐ and R₂ₐ may each be a hydrogen atom.

In Formula 3-4 and Formula 3-5, Z₁ to Z₄ may each independently be N(R_{c22}), O, or S. For example, Z₁ to Z₄ may each be O.

In Formula 3-1 to Formula 3-7, R_{c1} to R_{c22} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rei to R_{c22} may each independently be a hydrogen atom, a deuterium atom, a halogen atom, a cyano group, a substituted or unsubstituted diphenylamine group, a substituted or unsubstituted trimethylsilyl group, a substituted or unsubstituted methoxy group, a substituted or unsubstituted t-butyl group, or a substituted or unsubstituted carbazole group.

In Formula 3-1 to Formula 3-7, a1 and a2 may each independently be an integer from 0 to 3. If a1 and a2 are each 0, the fused polycyclic compound may not be substituted with R₁ₐ and R₂ₐ. A case where a1 and a2 are each 3 and R₁ₐ groups and R₂ₐ groups are all hydrogen atoms may be the same as a case where a1 and a2 are each 0. If a1 and a2 are each 2 or more, multiple groups of R₁ₐ and multiple groups of R₂ₐ may all be the same, or at least group thereof may be different from the remainder.

In Formula 3-1 to Formula 3-7, m21 to m24, m29, m32, m33, and m36 to m38 may each independently be an integer from 0 to 4; m25 to m28 and m39 to m41 may each independently be an integer from 0 to 5; and m30, m31, m34, and m35 may each independently be an integer from 0 to 3.

If m21 to m24, m29, m32, m33, and m36 to m38 are each 0, the fused polycyclic compound may not be substituted with R_{c1} to R_{c4}, R_{c9}, R_{c12}, R_{c13}, and R_{c16} to R_{c18}. A case where m21 to m24, m29, m32, m33, and m36 to m38 are each 4 and R_{c1} groups to R_{c4} groups, R_{c9} groups, R_{c12} groups, R_{c13} groups, and R_{c16} groups to Reis groups are all hydrogen atoms may be the same as a case where m21 to m24, m29, m32, m33, and m36 to m38 are each 0. If m21 to m24, m29, m32, m33, and m36 to m38 are each 2 or more, multiple groups of each of R_{c1} to R_{c4}, R_{c9}, R_{c12}, R_{c13}, and R_{c16} to Reis may all be the same or at least one group thereof may be different from the remainder.

If m25 to m28 and m39 to m41 are each 0, the fused polycyclic compound may not be substituted with R_{c5} to Res and R_{c19} to R_{c21}. A case where m25 to m28 and m39 to m41 are each 5 and R_{c5} groups to Res groups and R_{c19} groups to R_{c21} groups are all hydrogen atoms may be the same as a case where m25 to m28 and m39 to m41 are each 0. If m25 to m28 and m39 to m41 are each 2 or more, multiple groups of each of R_{c5} to Res and R_{c19} to R_{c21} may all be the same, or at least one group thereof may be different from the remainder.

If m30, m31, m34, and m35 are each 0, the fused polycyclic compound may not be substituted with R_{c10}, R_{c11}, R_{c14}, and R_{c15}. A case where m30, m31, m34, and m35 are each 3 and R_{c10} groups, R_{c11} groups, R_{c14} groups, and R_{c15} groups are all hydrogen atoms may be the same as a case where m30, m31, m34, and m35 are each 0. If m30, m31, m34, and m35 are each 2 or more, multiple groups of each of R_{c10}, R_{c11}, R_{c14}, and R_{c15} may all be the same, or at least one group thereof may be different from the remainder.

In Formula 3-1 to Formula 3-7, X, R₃ to R₇, and n3 to n7 are the same as described in Formula 1.

In an embodiment, the first compound represented by Formula 1 may be represented by any one of Formula 4-1 to Formula 4-4:

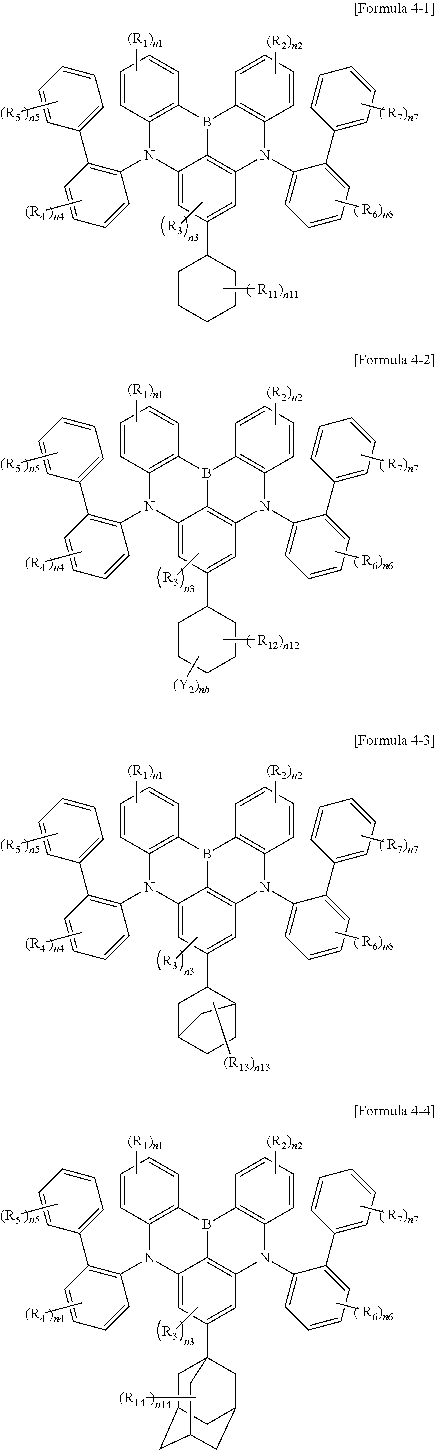

Formula 4-1 to Formula 4-4 represent cases where X is further defined in Formula 1.

In Formula 4-1 to Formula 4-4, R₁₁ to R₁₄ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₁ to R₁₄ may each be a hydrogen atom.

In Formula 4-2, Y₂ may be a substituted or unsubstituted alkyl group having 1 to 10 carbon atoms. For example, Y₂ may be a substituted or unsubstituted methyl group or a substituted or unsubstituted t-butyl group.

In Formula 4-1 to Formula 4-4, n11 and n13 may each independently be an integer from 0 to 11; n12 may be an integer from 0 to 10; nb may be an integer from 1 to 11; n14 may be an integer from 0 to 15; and a sum of n12 and nb may be less than or equal to 11. The fused polycyclic compound represented by Formula 4-2 may include at least one substituent represented by Y₂.

If n11 and n13 are each 0, the fused polycyclic compound may not be substituted with R₁₁ and R₁₃. A case where n11 and n13 are each 11 and Rₙ groups and R₁₃ groups are all hydrogen atoms may be the same as a case where n11 and n13 are each 0. If n11 and n13 are each 2 or more, multiple groups of Rₙ and multiple groups of R₁₃ may all be the same, or at least one group thereof may be different from the remainder.

If n12 is 0, the fused polycyclic compound may not be substituted with R₁₂. A case where n12 is 10 and R₁₂ groups are all hydrogen atoms may be the same as a case where n12 is 0. If n12 is 2 or more, multiple groups of R₁₂ may all be the same, or at least one group thereof may be different from the remainder.

If n14 is 0, the fused polycyclic compound may not be substituted with R₁₄. A case where n14 is 15 and R₁₄ groups are all hydrogen atoms may be the same as a case where n14 is 0. If n14 is 2 or more, multiple groups of R₁₄ may all be the same, or at least one group thereof may be different from the remainder.

In Formula 4-1 to Formula 4-4, R₁ to R₇ and n1 to n7 are the same as described in Formula 1.

In an embodiment, the first compound represented by Formula 1 may be represented by Formula 5:

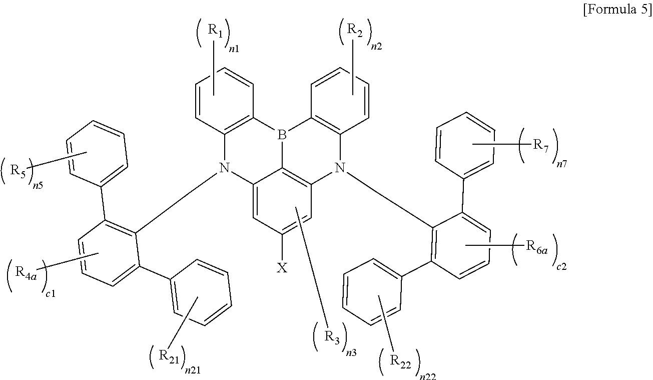

In Formula 5, R₄ₐ, R₆ₐ, R₂₁, and R₂₂ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₄ₐ, R₆ₐ, R₂₁, and R₂₂ may each independently be a hydrogen atom, a deuterium atom, or a substituted or unsubstituted t-butyl group.

In Formula 5, c1 and c2 may each independently be an integer from 0 to 3. If c1 and c2 are each 0, the fused polycyclic compound may not be substituted with R₄ₐ and R₆ₐ. A case where c1 and c2 are each 3 and R₄ₐ groups and R₆ₐ groups are all hydrogen atoms may be the same as a case where c1 and c2 are each 0. If c1 and c2 are each 2 or more, multiple groups of R₄ₐ and multiple groups of R₆ₐ may all be the same, or at least one group thereof may be different from the remainder.

In Formula 5, n21 and n22 may each independently be an integer from 0 to 5. If n21 and n22 are each 0, the fused polycyclic compound may not be substituted with R₂₁ and R₂₂. A case where n21 and n22 are each 5 and R₂₁ groups and R₂₂ groups are all hydrogen atoms may be the same as a case where n21 and n22 are each 0. If n21 and n22 are each 2 or more, multiple groups of R₂₁ and multiple groups of R₂₂ may all be the same, or at least one group thereof may be different from the remainder.

In Formula 5, X, R₁ to R₃, R₅, R₇, n1 to n3, n5, and n7 are the same as described in Formula 1.

In an embodiment, the first compound represented by Formula 1 may be represented by any one of Formula 5-1 to Formula 5-3:

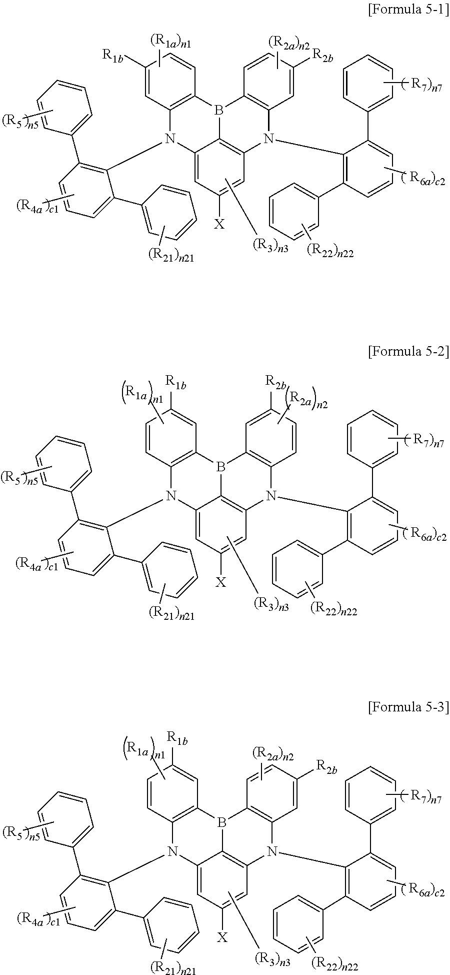

In Formula 5-1 to Formula 5-3, R₄ₐ, R₆ₐ, R₂₁, R₂₂, c1, c2, n21, and n22 are the same as described in Formula 5. In Formula 5-1 to Formula 5-3, R₁ₐ, R₂ₐ, Rib, R_{2b}, a1, and a2 are the same as described in Formula 2-1 to Formula 2-3. In Formula 5-1 to Formula 5-3, X, R₁ to R₃, R₅, R₇, n1 to n3, n5, and n7 are the same as described in Formula 1.

In an embodiment, the first compound represented by Formula 1 may be represented by any one of Formula 6-1 to Formula 6-3:

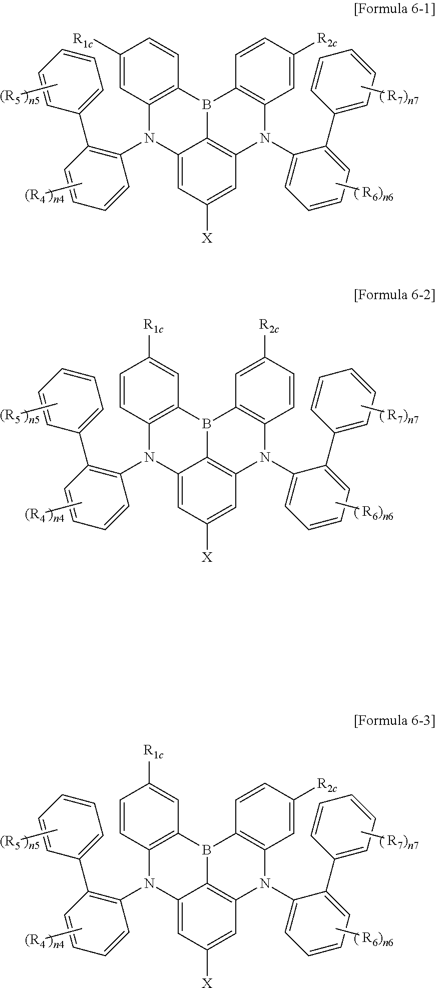

Formula 6-1 to Formula 6-3 represent cases where the type, the number, and bonding position of R₁ and R₂ in Formula 1 are further defined.

In Formula 6-1 to Formula 6-3, R_{1c} and R_{2c} may each independently be a substituted or unsubstituted phenyl group, a substituted or unsubstituted carbazole group, or a substituted or unsubstituted dibenzofuran group.

In Formula 6-1 to Formula 6-3, X, R₄ to R₇, and n4 to n7 are the same as described in Formula 1.

The fused polycyclic compound may be any compound selected from Compound Group 1 below. The light emitting device ED may include at least one compound selected from Compound Group 1 in the emission layer EML.

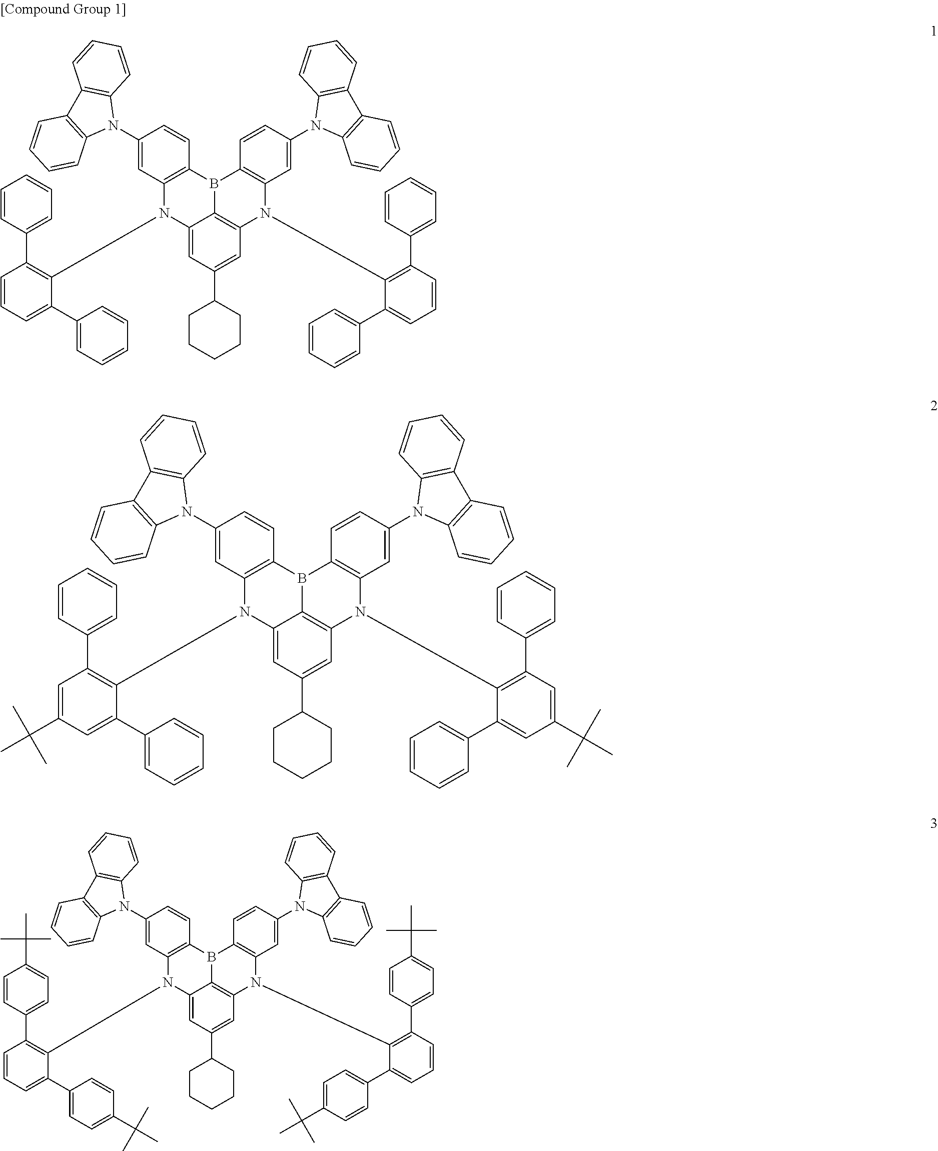

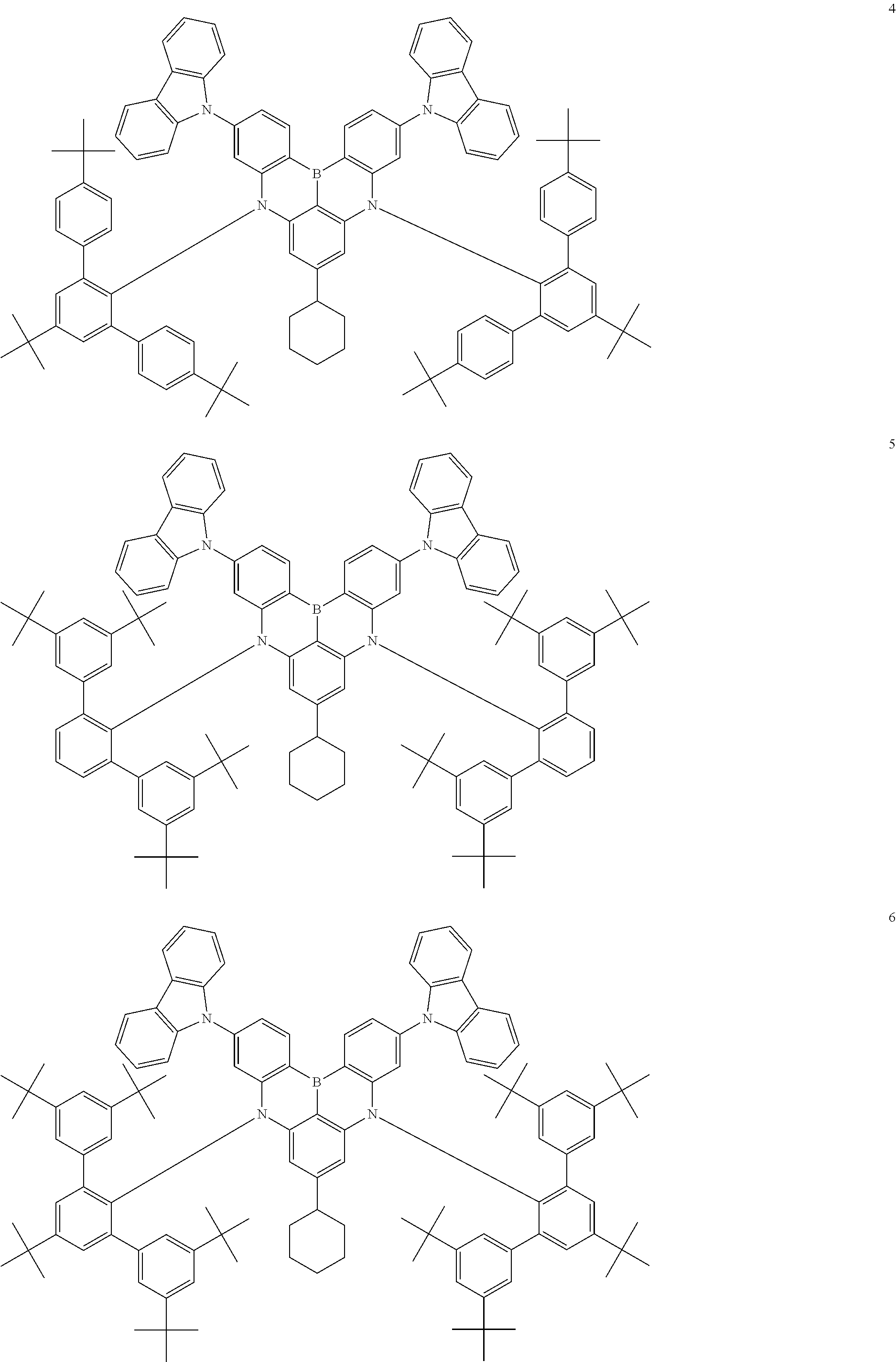

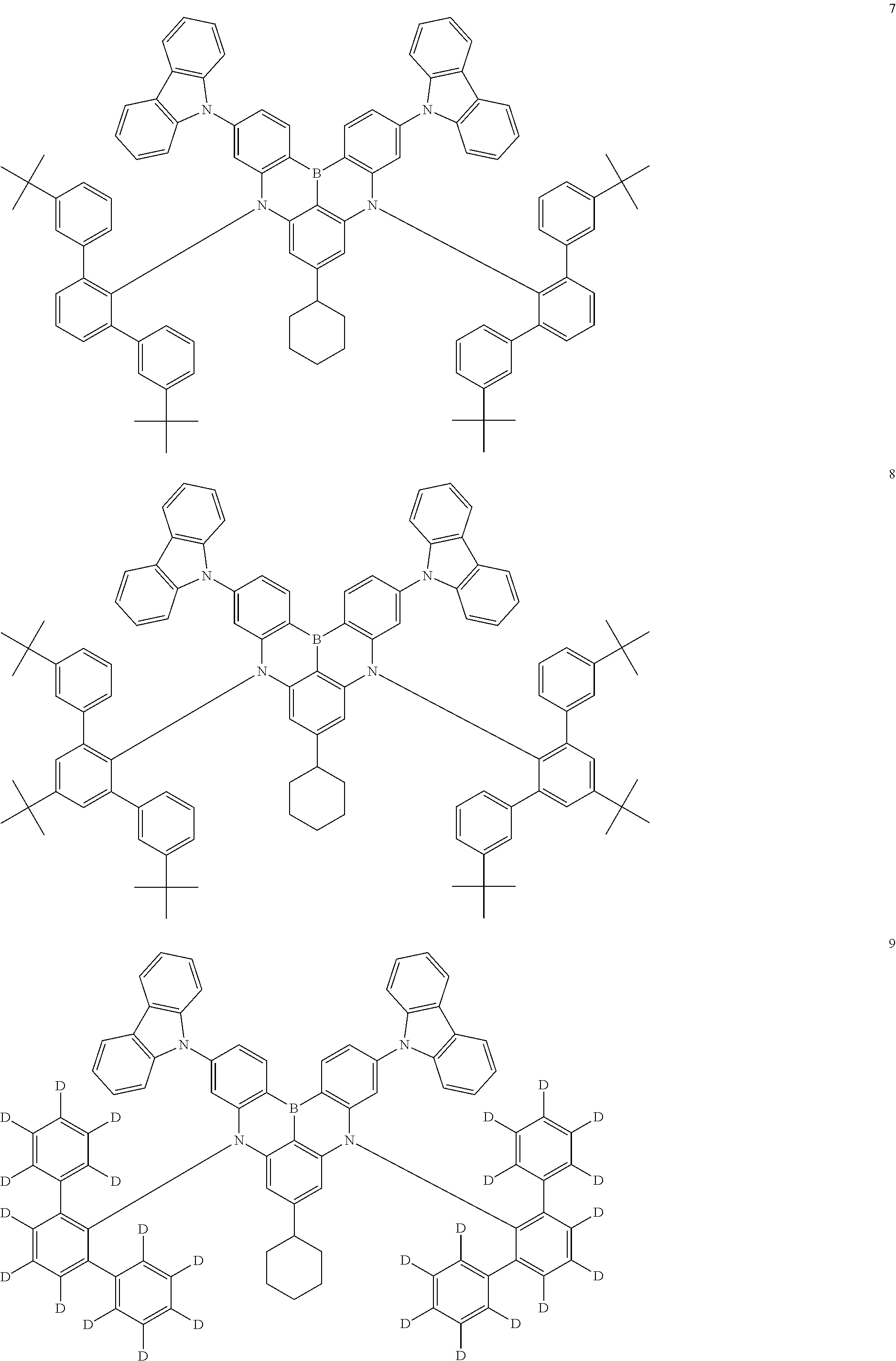

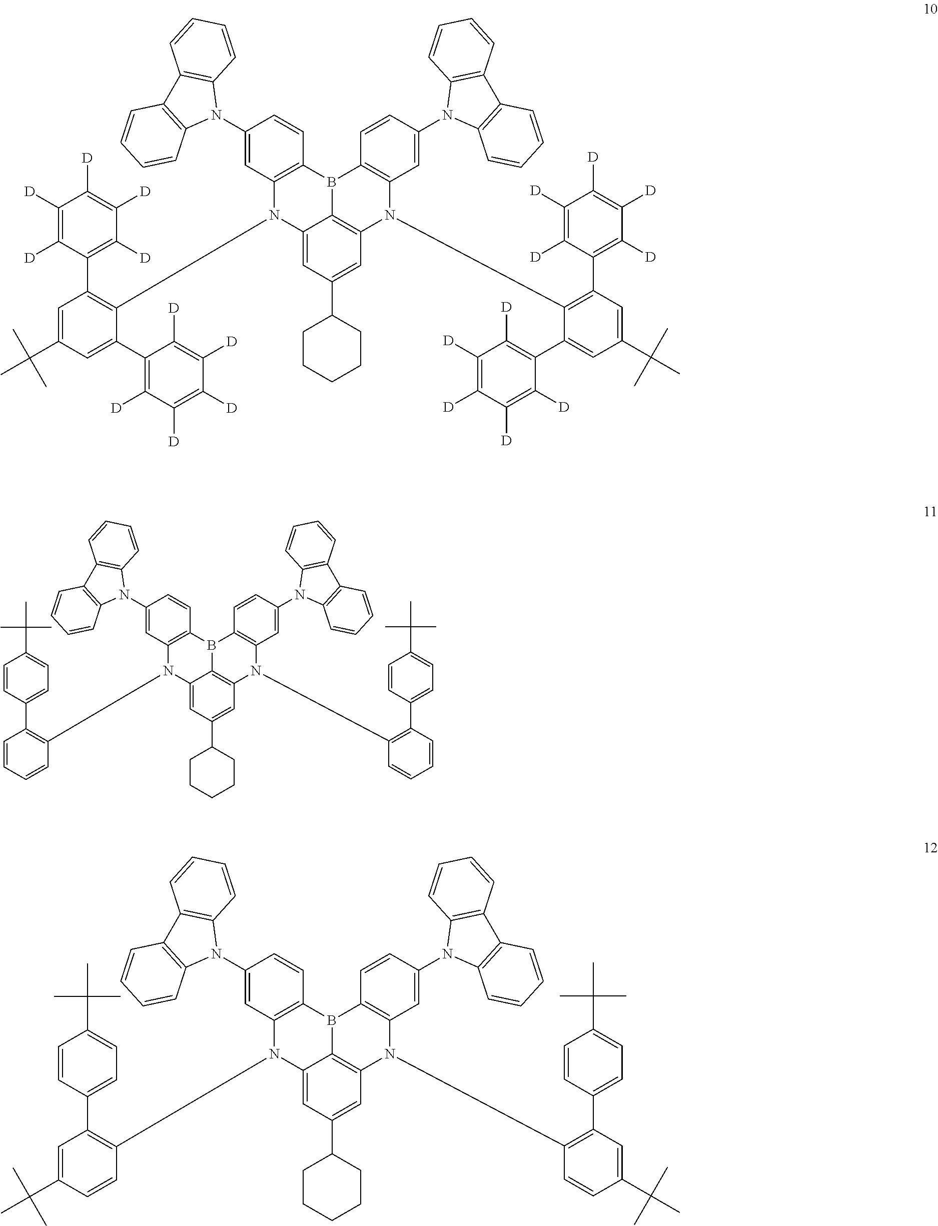

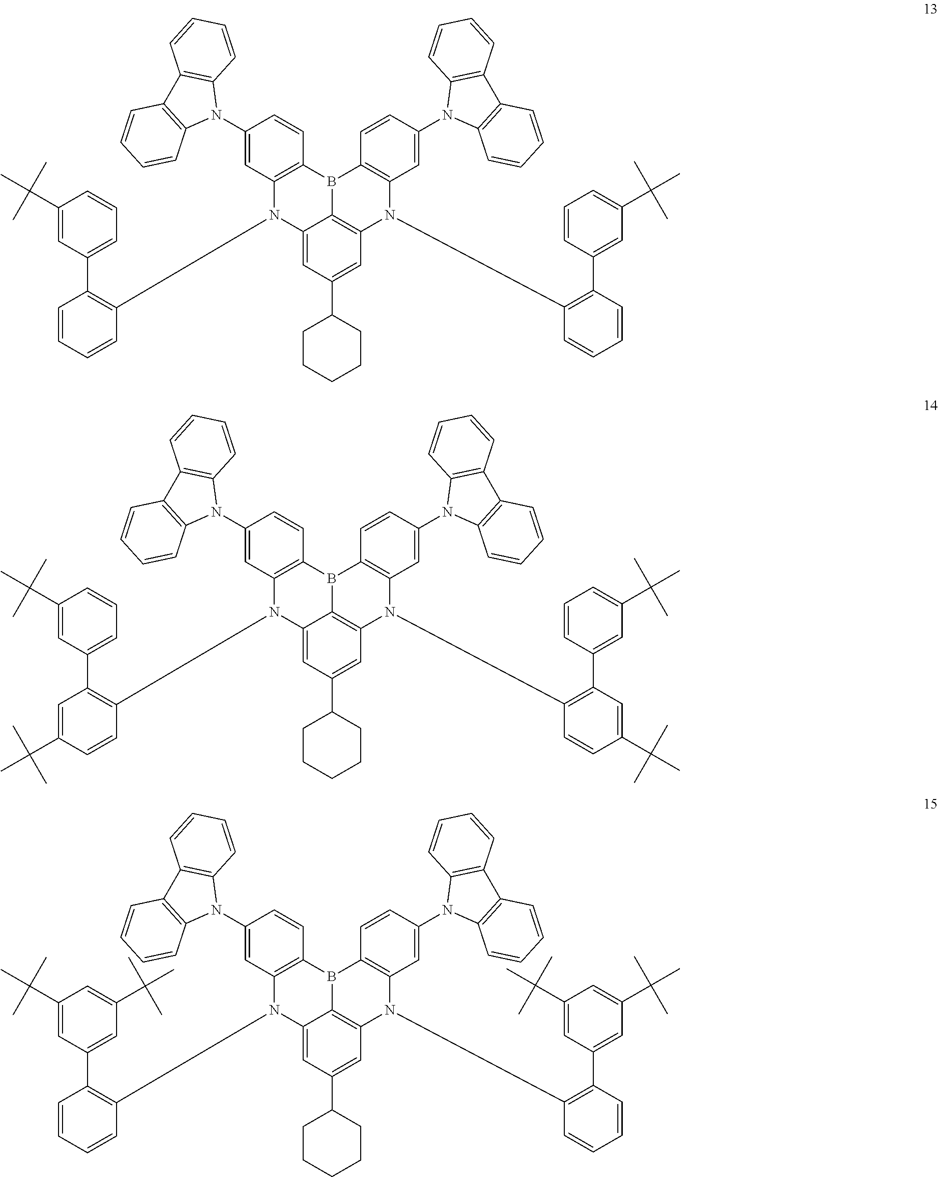

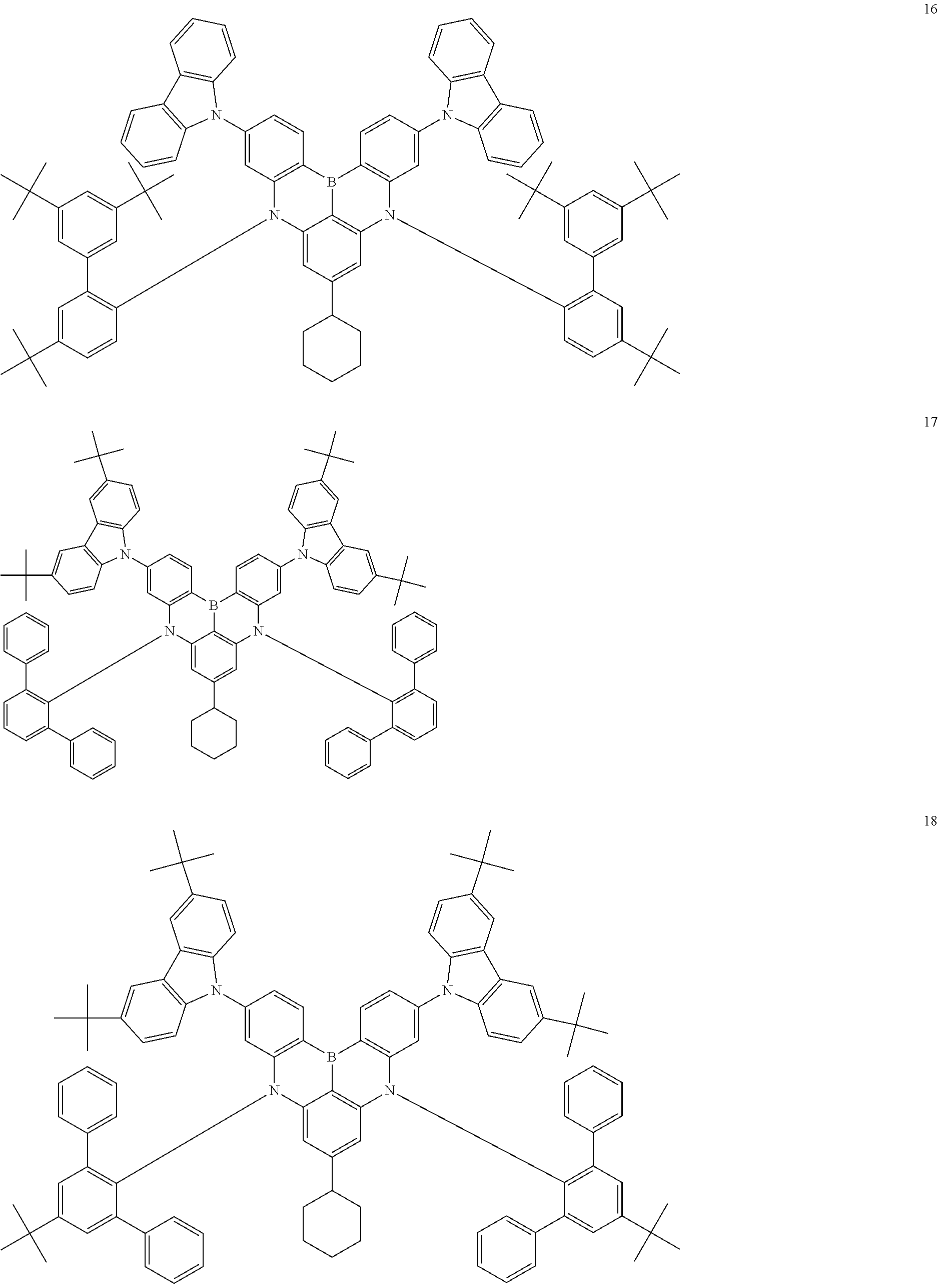

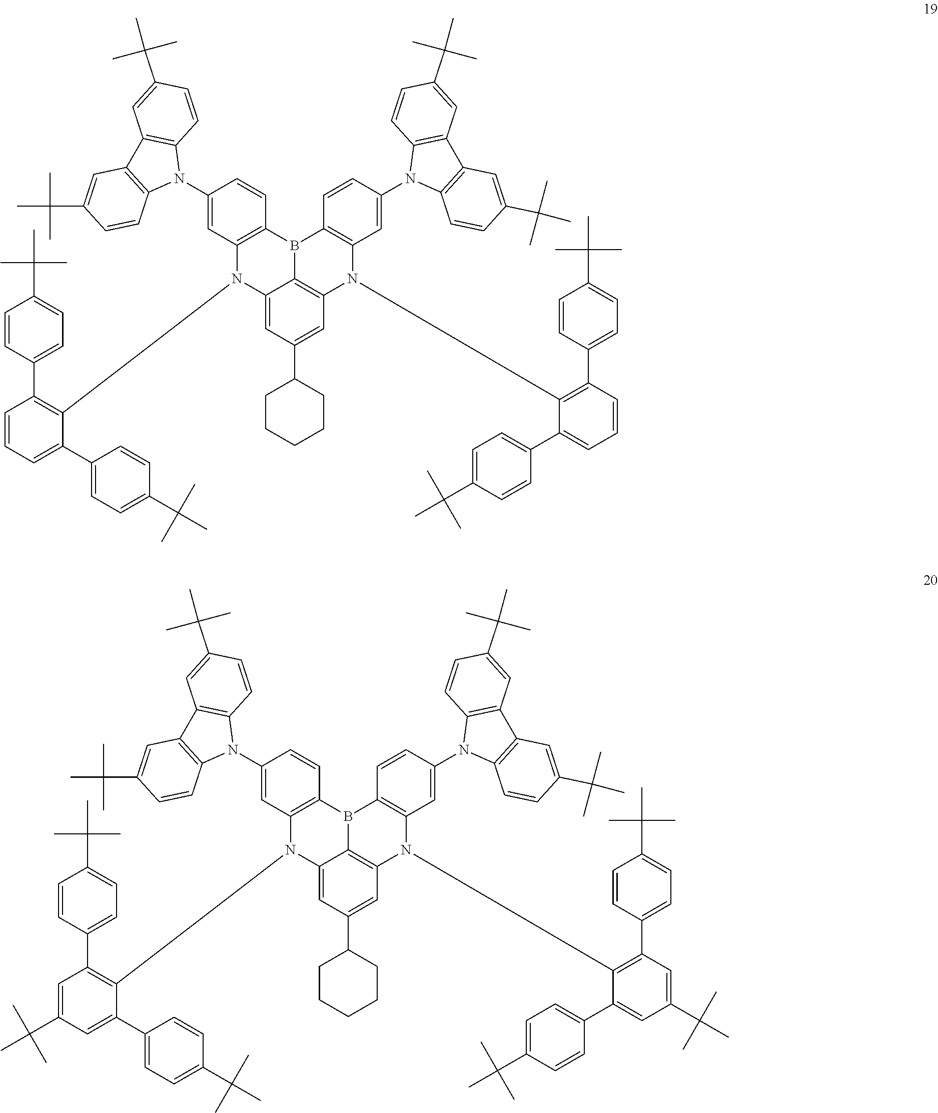

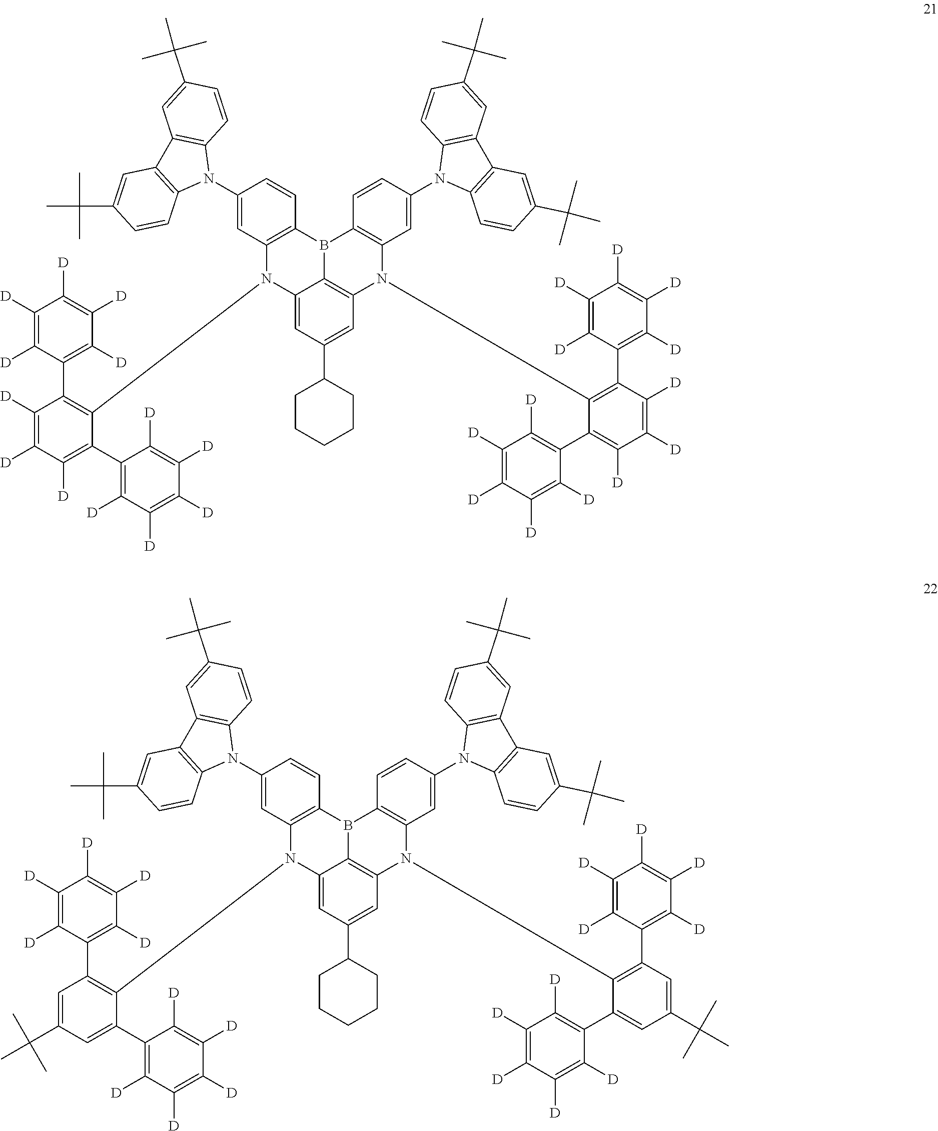

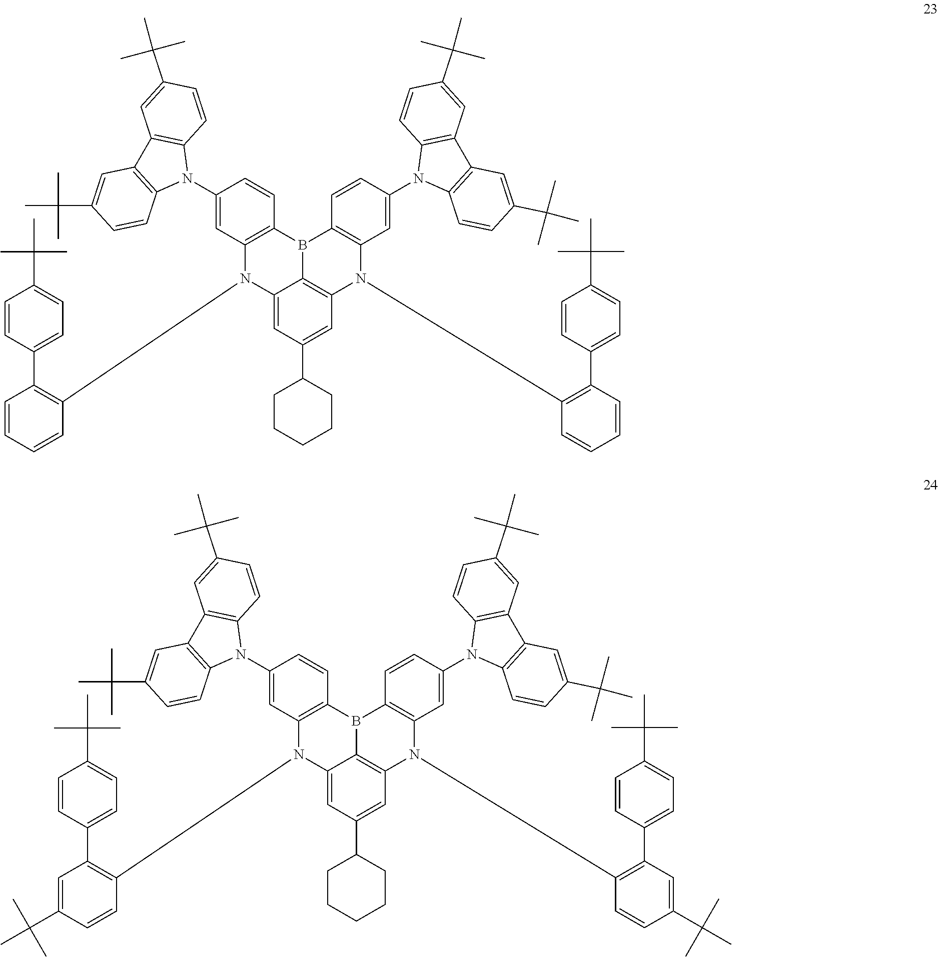

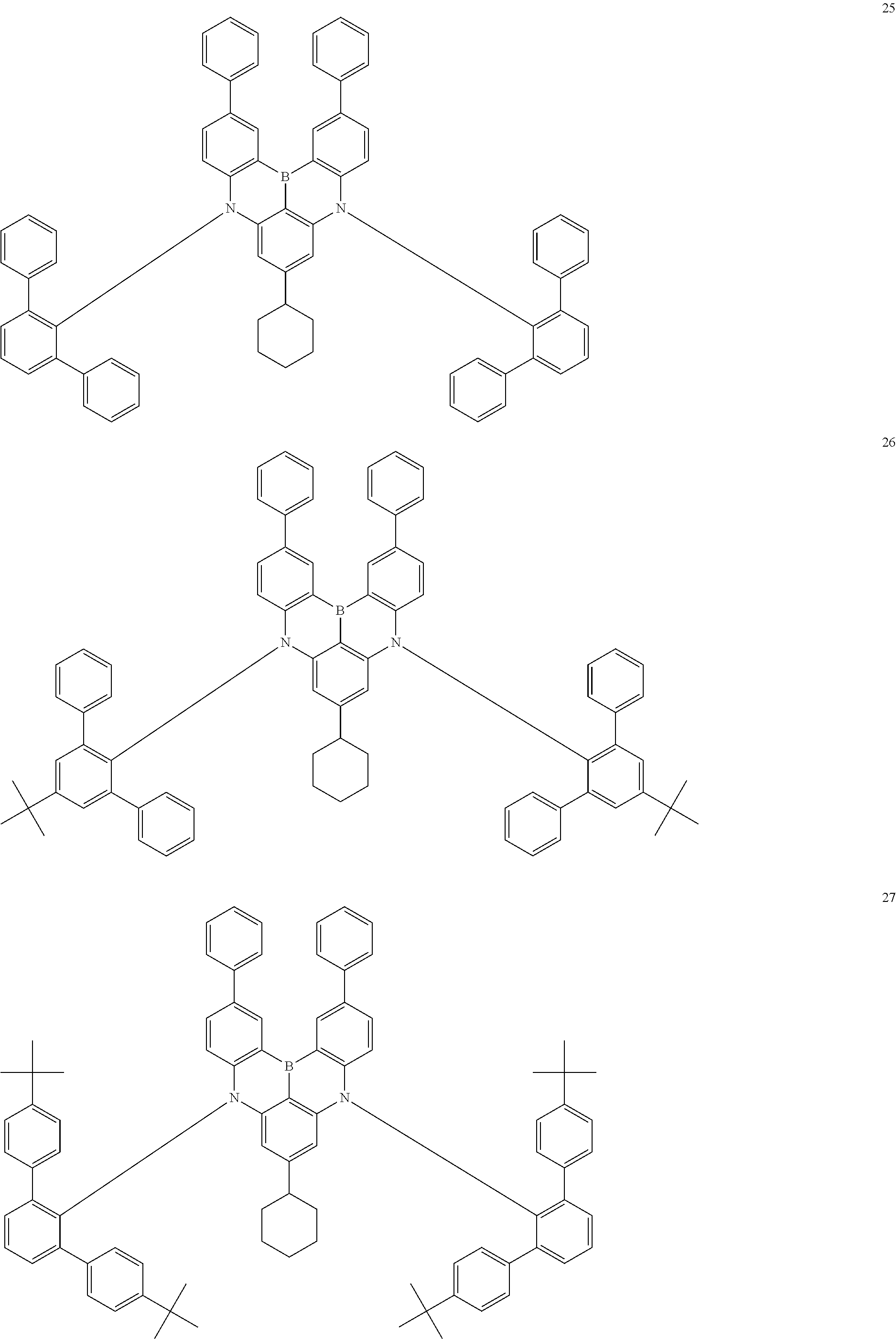

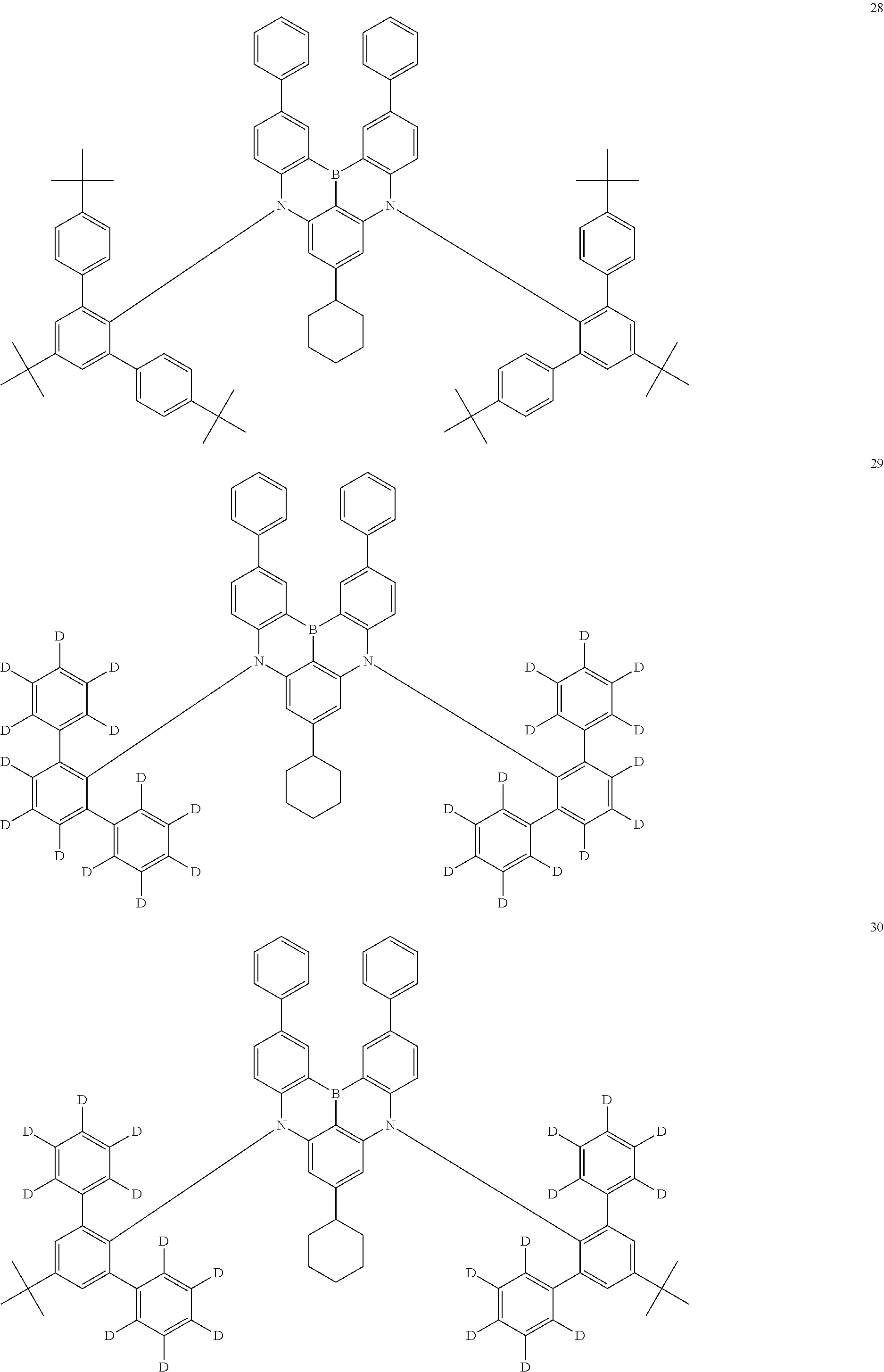

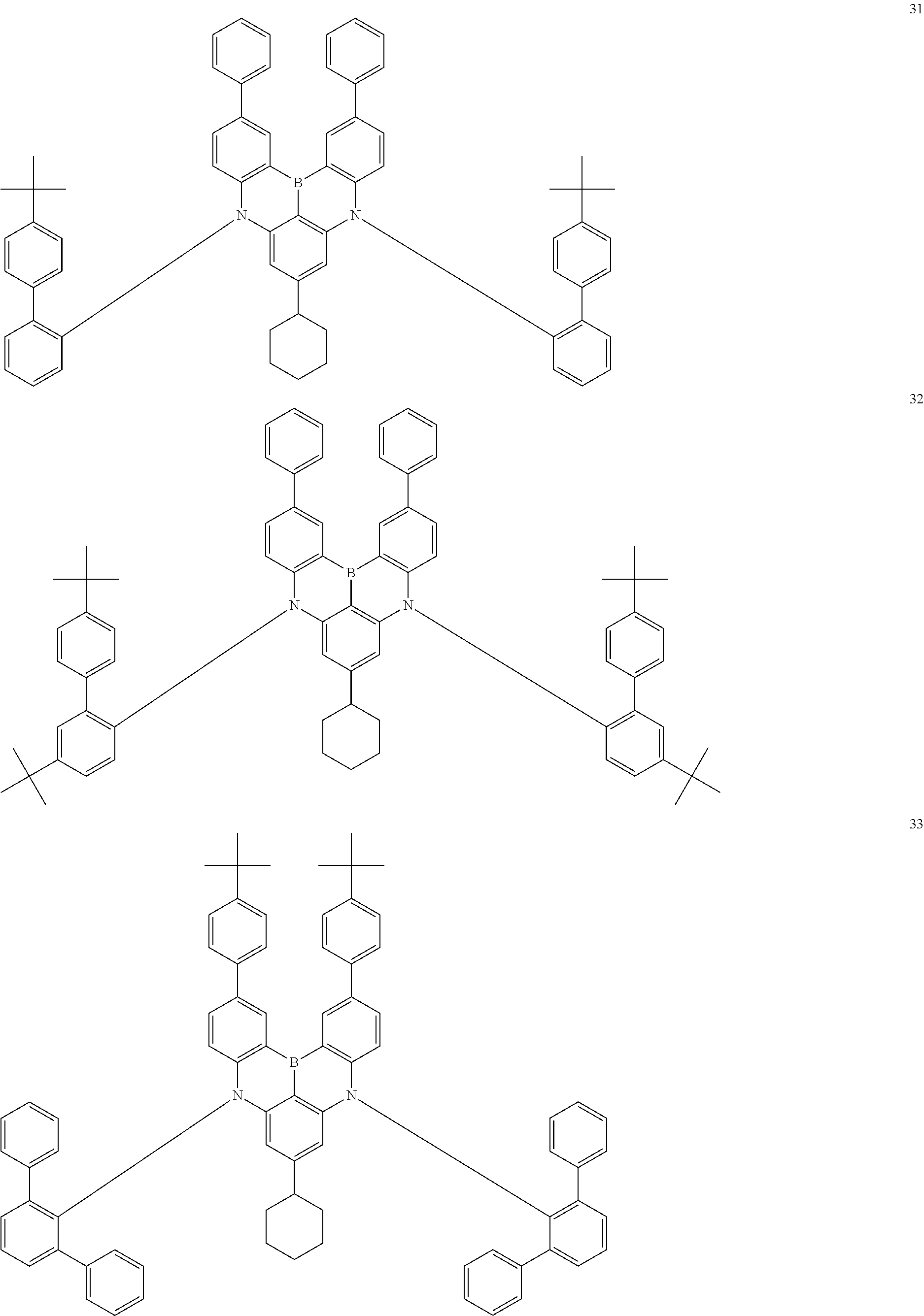

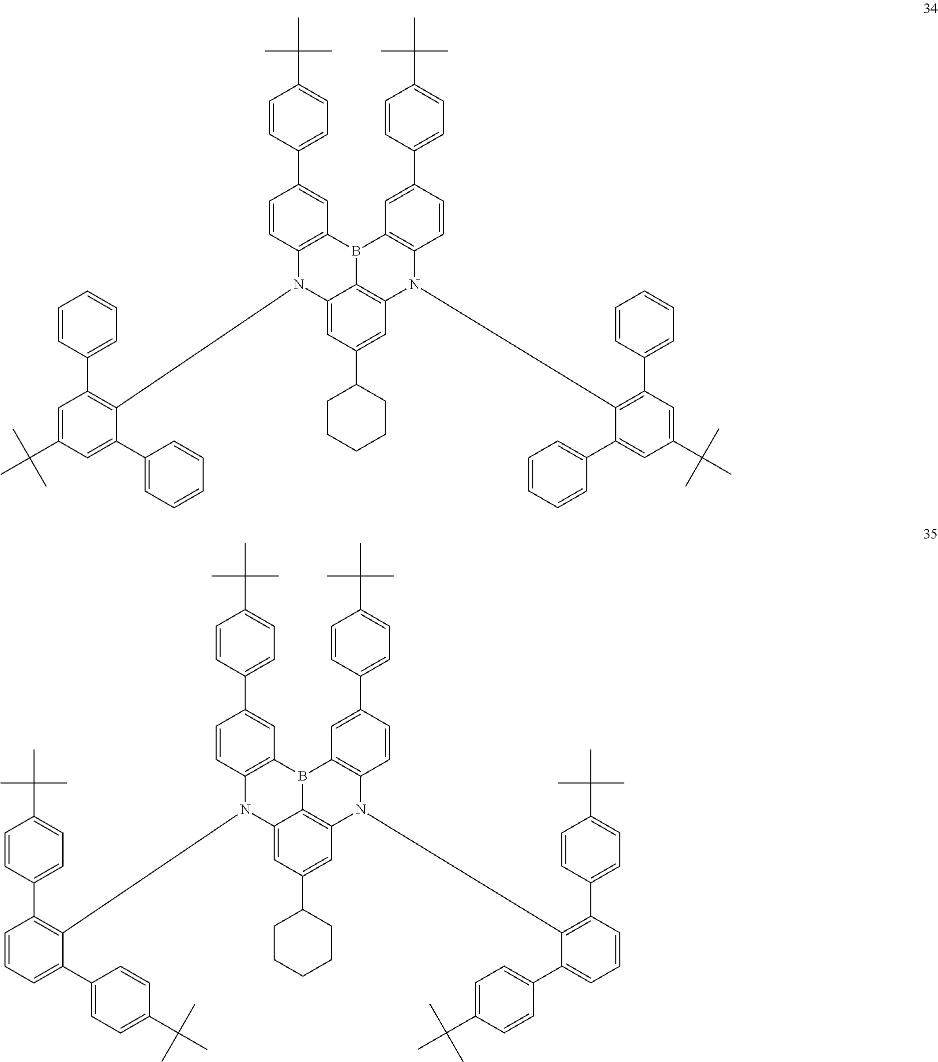

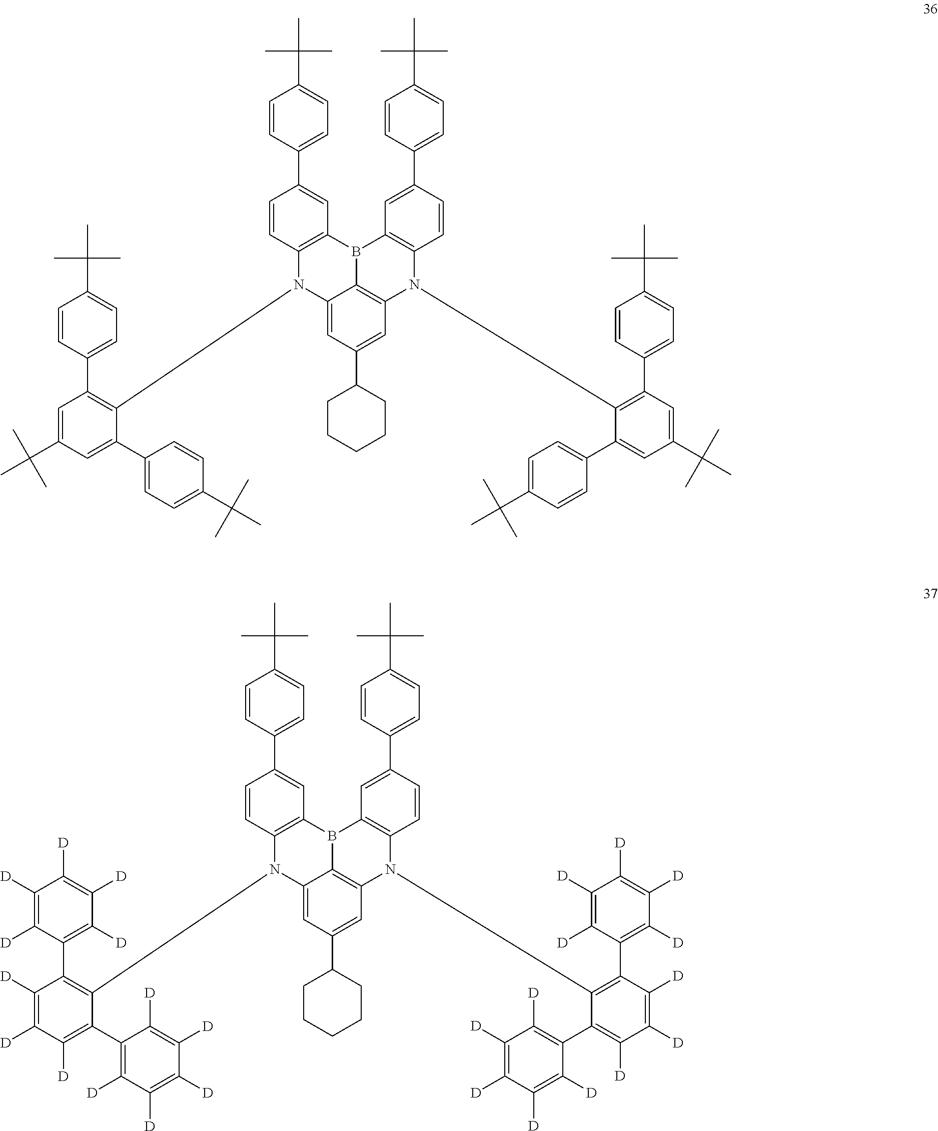 [SMILES: CC(C)(C)c1ccc(-c2ccc3c(c2)B2c4cc(-c5ccc(C(C)(C)C)cc5)ccc4N(c4c(-c5ccc(C(C)(C)C)cc5)cc(C(C)(C)C)cc4-c4ccc(C(C)(C)C)cc4)c4cc(C5CCCCC5)cc(c42)N3c2c(-c3ccc(C(C)(C)C)cc3)cc(C(C)(C)C)cc2-c2ccc(C(C)(C)C)cc2)cc1 ; [2H]c1c([2H])c([2H])c(-c2c([2H])c([2H])c([2H])c(-c3c([2H])c([2H])c([2H])c([2H])c3[2H])c2N2c3ccc(-c4ccc(C(C)(C)C)cc4)cc3B3c4cc(-c5ccc(C(C)(C)C)cc5)ccc4N(c4c(-c5c([2H])c([2H])c([2H])c([2H])c5[2H])c([2H])c([2H])c([2H])c4-c4c([2H])c([2H])c([2H])c([2H])c4[2H])c4cc(C5CCCCC5)cc2c43)c([2H])c1[2H]]

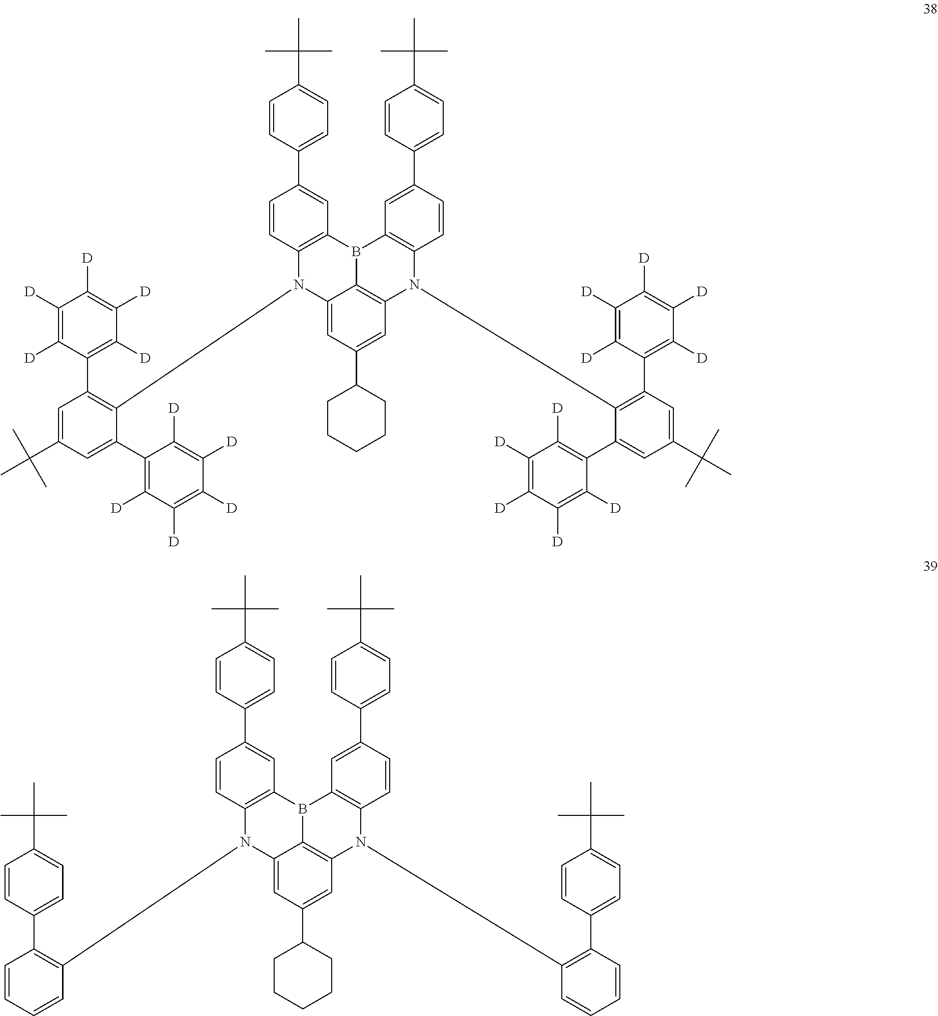

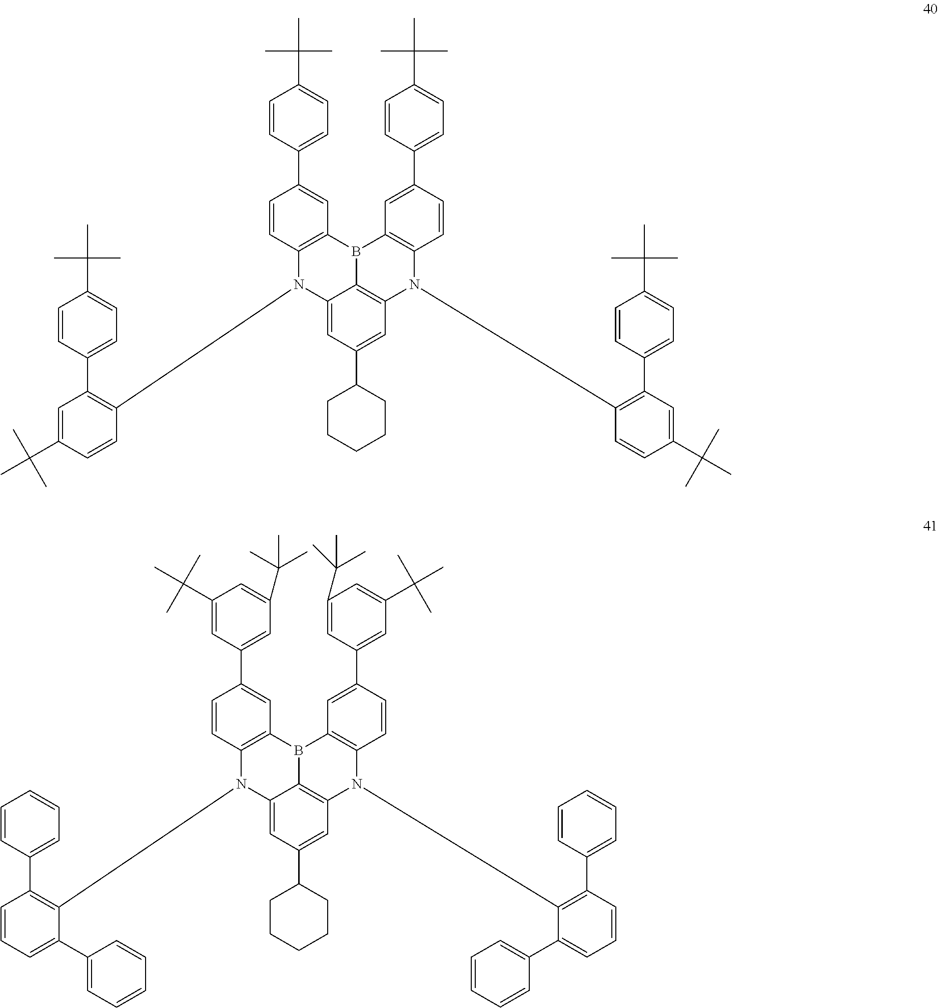 [SMILES: CC(C)(C)c1ccc(-c2ccc3c(c2)B2c4cc(-c5ccc(C(C)(C)C)cc5)ccc4N(c4ccc(C(C)(C)C)cc4-c4ccc(C(C)(C)C)cc4)c4cc(C5CCCCC5)cc(c42)N3c2ccc(C(C)(C)C)cc2-c2ccc(C(C)(C)C)cc2)cc1 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(C5CCCCC5)cc(c42)N3c2c(-c3ccccc3)cccc2-c2ccccc2)cc(C(C)(C)C)c1]

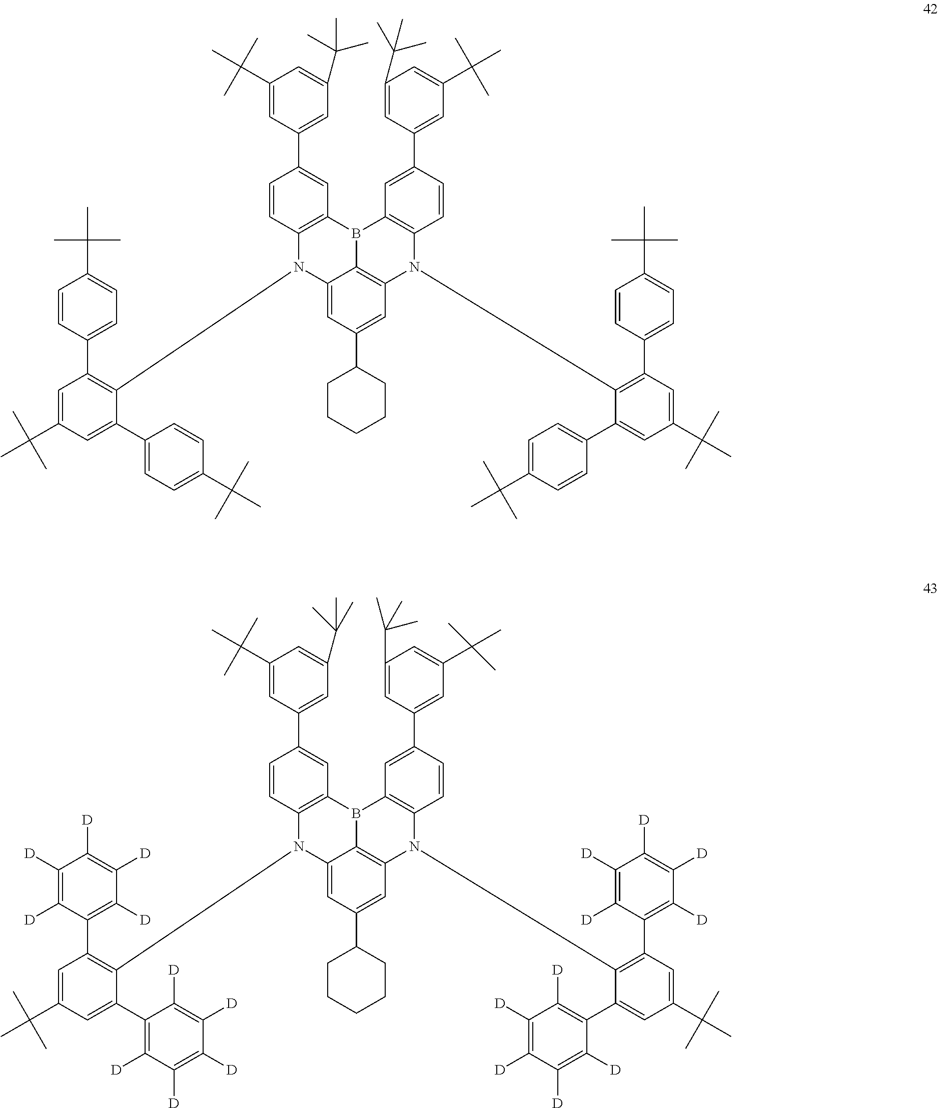

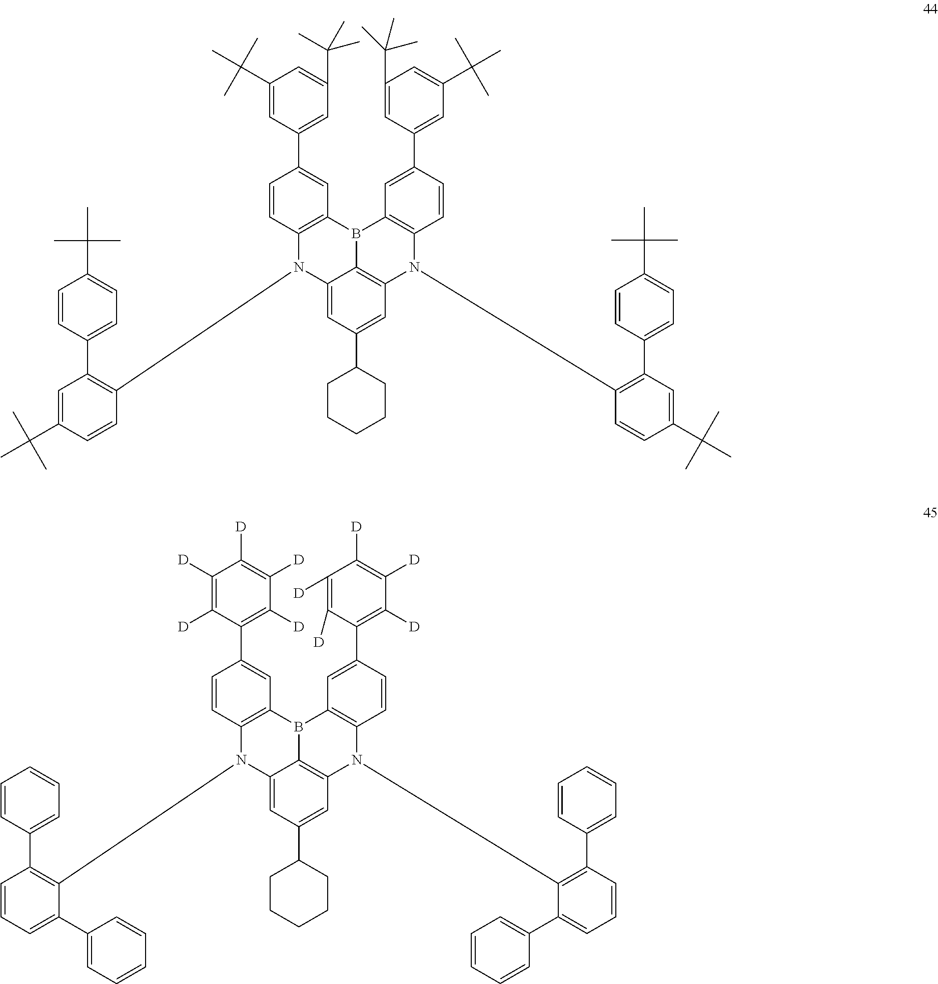 [SMILES: CC(C)(C)c1ccc(-c2cc(C(C)(C)C)ccc2N2c3ccc(-c4cc(C(C)(C)C)cc(C(C)(C)C)c4)cc3B3c4cc(-c5cc(C(C)(C)C)cc(C(C)(C)C)c5)ccc4N(c4ccc(C(C)(C)C)cc4-c4ccc(C(C)(C)C)cc4)c4cc(C5CCCCC5)cc2c43)cc1 ; [2H]c1c([2H])c([2H])c(-c2ccc3c(c2)B2c4cc(-c5c([2H])c([2H])c([2H])c([2H])c5[2H])ccc4N(c4c(-c5ccccc5)cccc4-c4ccccc4)c4cc(C5CCCCC5)cc(c42)N3c2c(-c3ccccc3)cccc2-c2ccccc2)c([2H])c1[2H]]

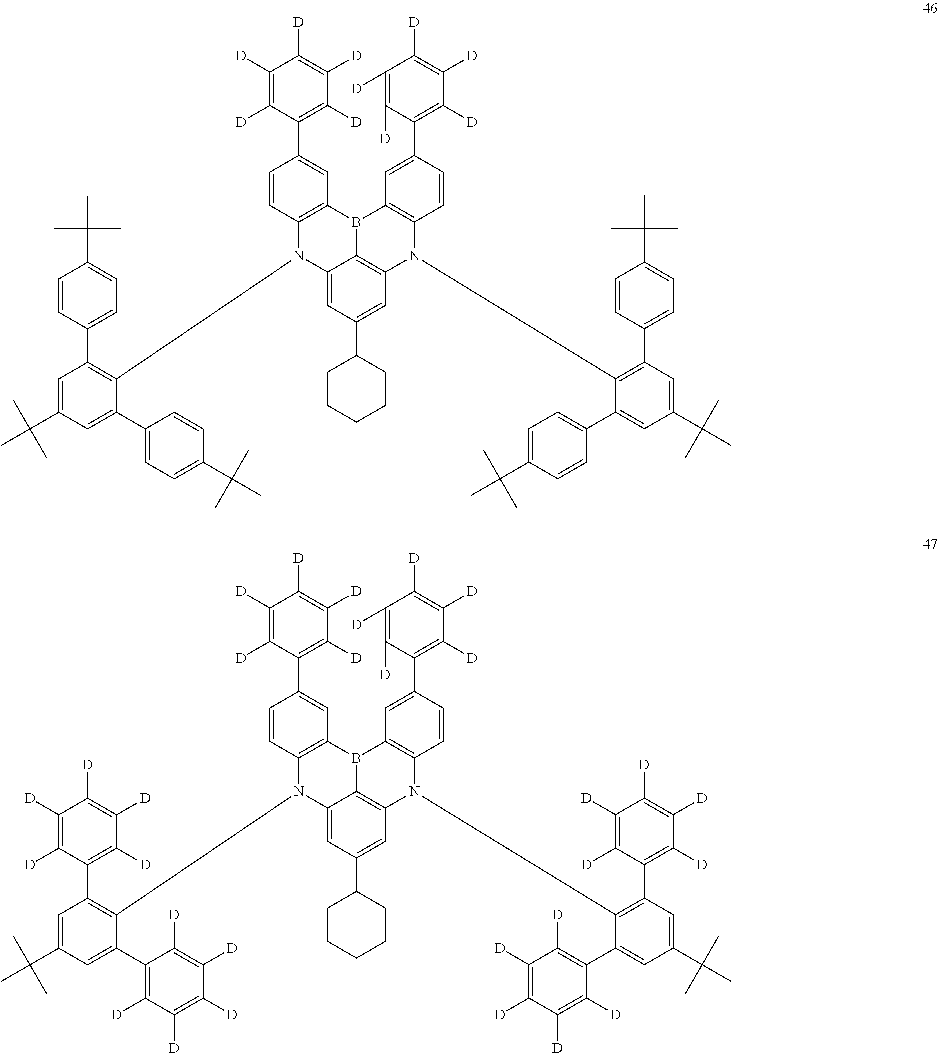

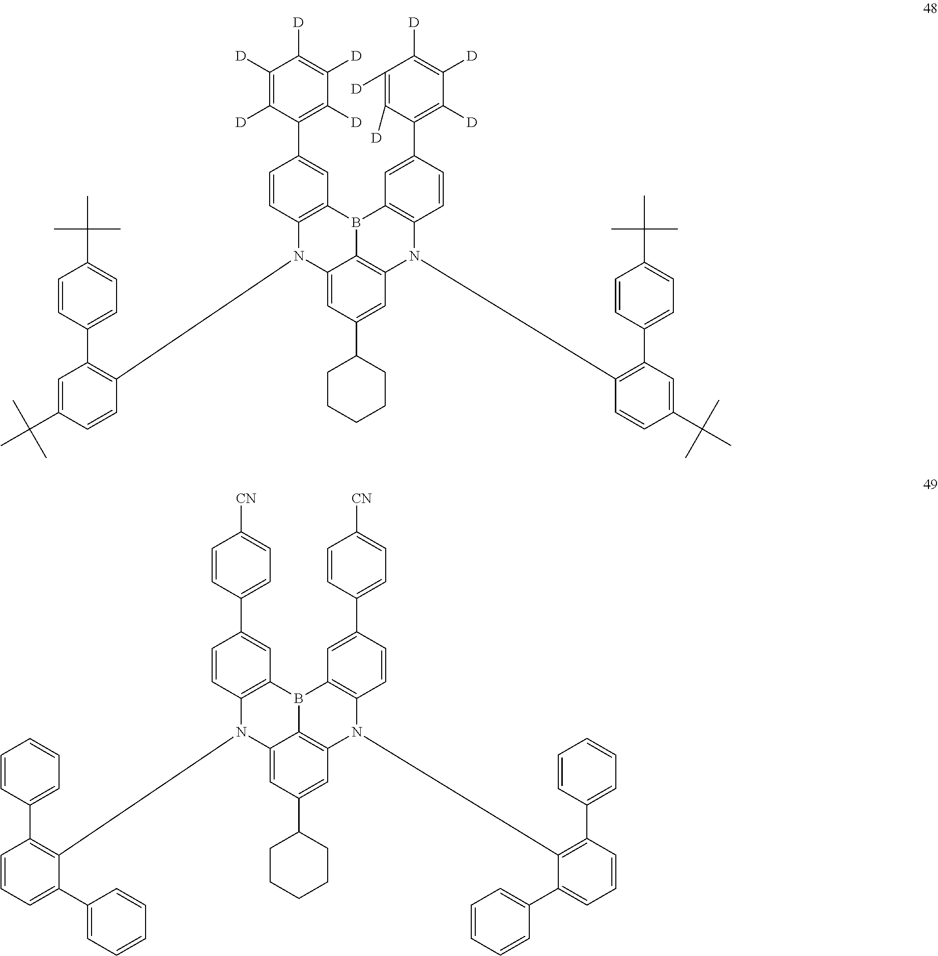 [SMILES: [2H]c1c([2H])c([2H])c(-c2ccc3c(c2)B2c4cc(-c5c([2H])c([2H])c([2H])c([2H])c5[2H])ccc4N(c4ccc(C(C)(C)C)cc4-c4ccc(C(C)(C)C)cc4)c4cc(C5CCCCC5)cc(c42)N3c2ccc(C(C)(C)C)cc2-c2ccc(C(C)(C)C)cc2)c([2H])c1[2H] ; N#Cc1ccc(-c2ccc3c(c2)B2c4cc(-c5ccc(C#N)cc5)ccc4N(c4c(-c5ccccc5)cccc4-c4ccccc4)c4cc(C5CCCCC5)cc(c42)N3c2c(-c3ccccc3)cccc2-c2ccccc2)cc1]

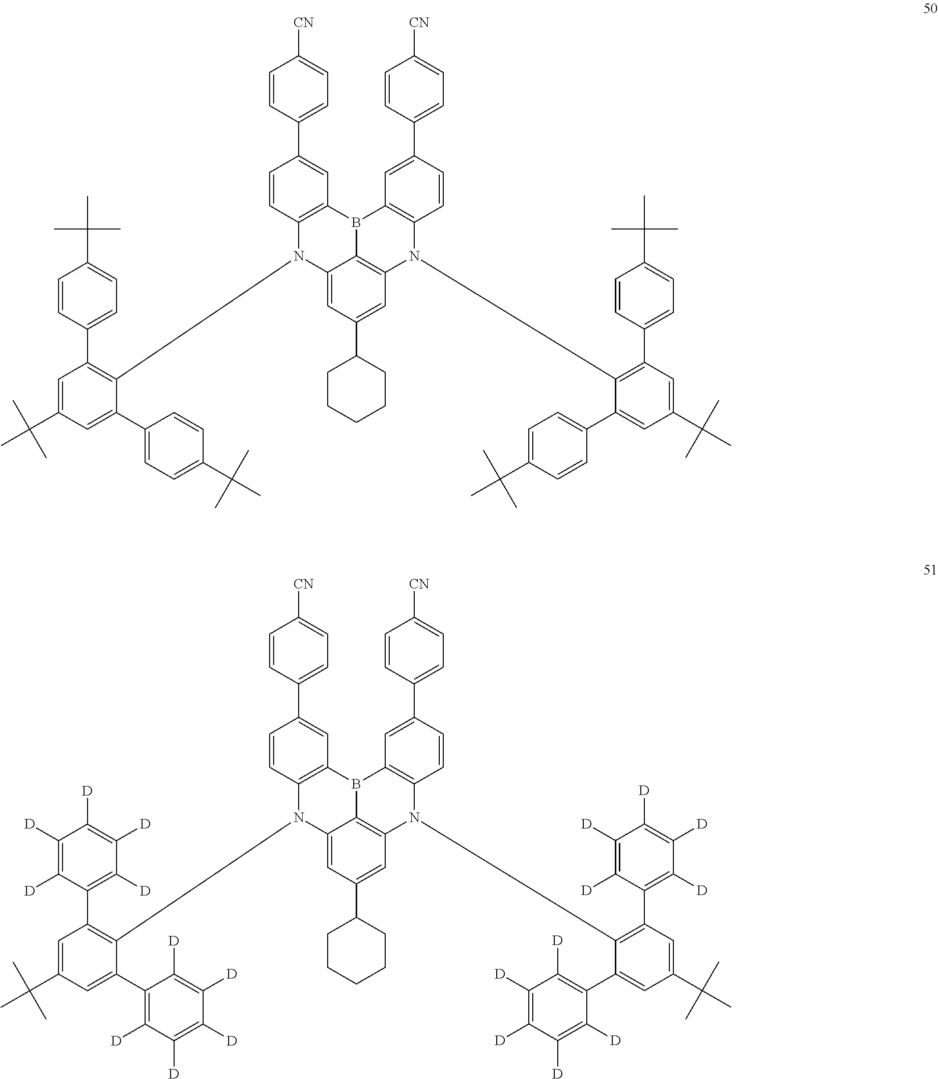

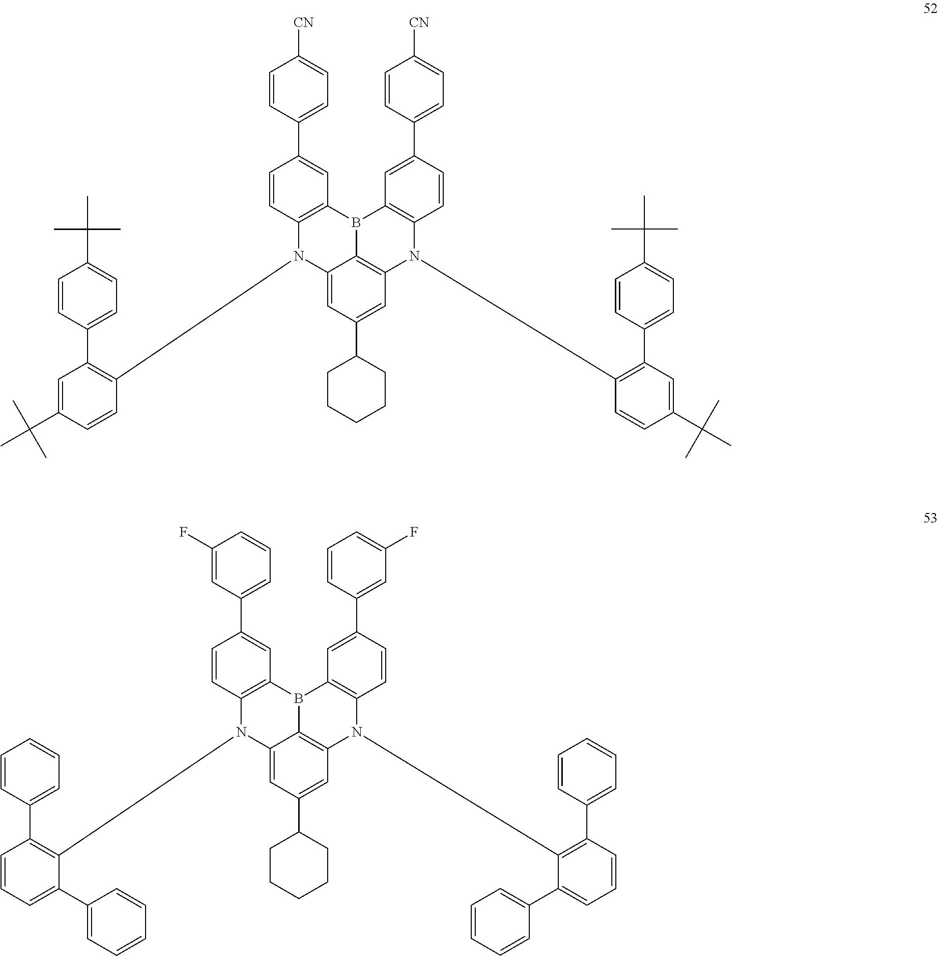 [SMILES: CC(C)(C)c1ccc(-c2cc(C(C)(C)C)ccc2N2c3ccc(-c4ccc(C#N)cc4)cc3B3c4cc(-c5ccc(C#N)cc5)ccc4N(c4ccc(C(C)(C)C)cc4-c4ccc(C(C)(C)C)cc4)c4cc(C5CCCCC5)cc2c43)cc1 ; Fc1cccc(-c2ccc3c(c2)B2c4cc(-c5cccc(F)c5)ccc4N(c4c(-c5ccccc5)cccc4-c4ccccc4)c4cc(C5CCCCC5)cc(c42)N3c2c(-c3ccccc3)cccc2-c2ccccc2)c1]

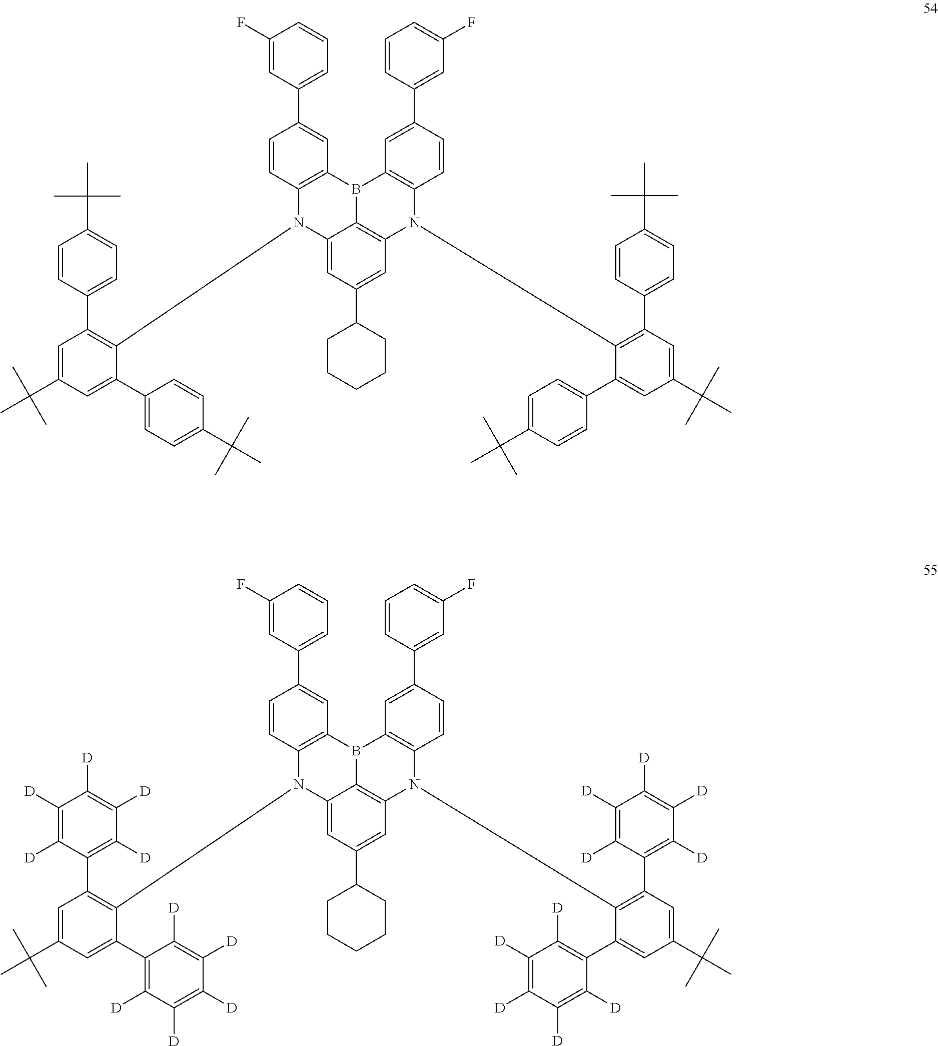

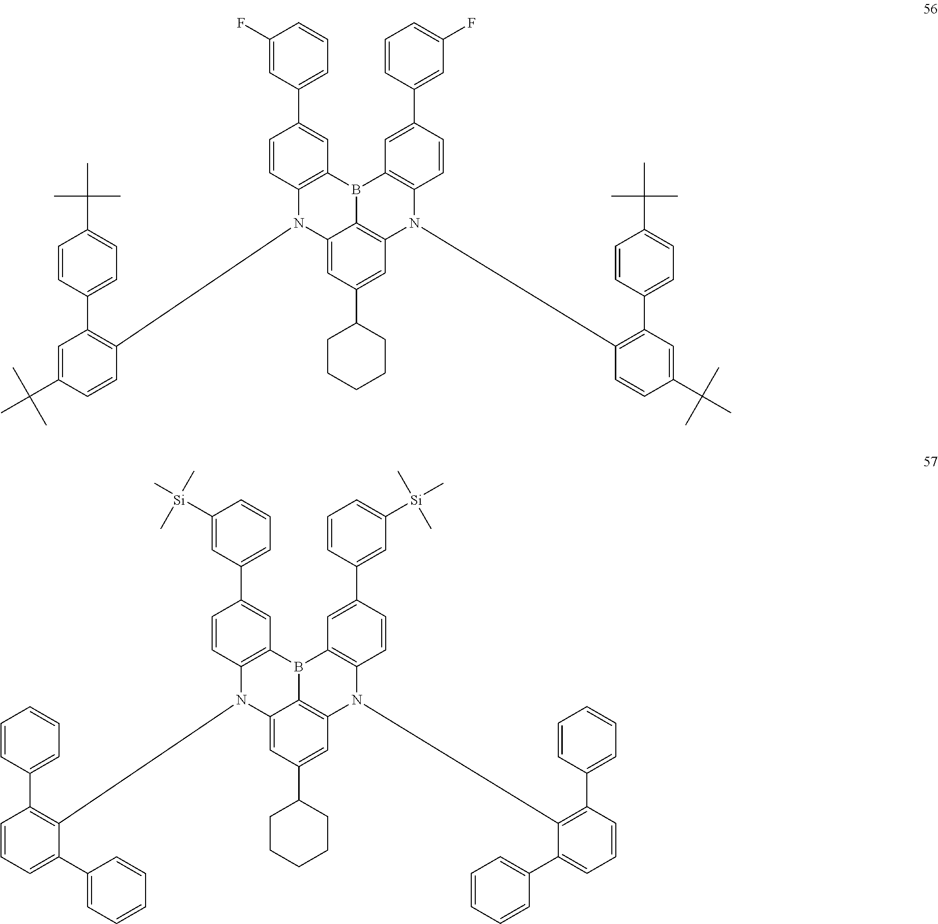 [SMILES: CC(C)(C)c1ccc(-c2cc(C(C)(C)C)ccc2N2c3ccc(-c4cccc(F)c4)cc3B3c4cc(-c5cccc(F)c5)ccc4N(c4ccc(C(C)(C)C)cc4-c4ccc(C(C)(C)C)cc4)c4cc(C5CCCCC5)cc2c43)cc1 ; C[Si](C)(C)c1cccc(-c2ccc3c(c2)B2c4cc(-c5cccc([Si](C)(C)C)c5)ccc4N(c4c(-c5ccccc5)cccc4-c4ccccc4)c4cc(C5CCCCC5)cc(c42)N3c2c(-c3ccccc3)cccc2-c2ccccc2)c1]

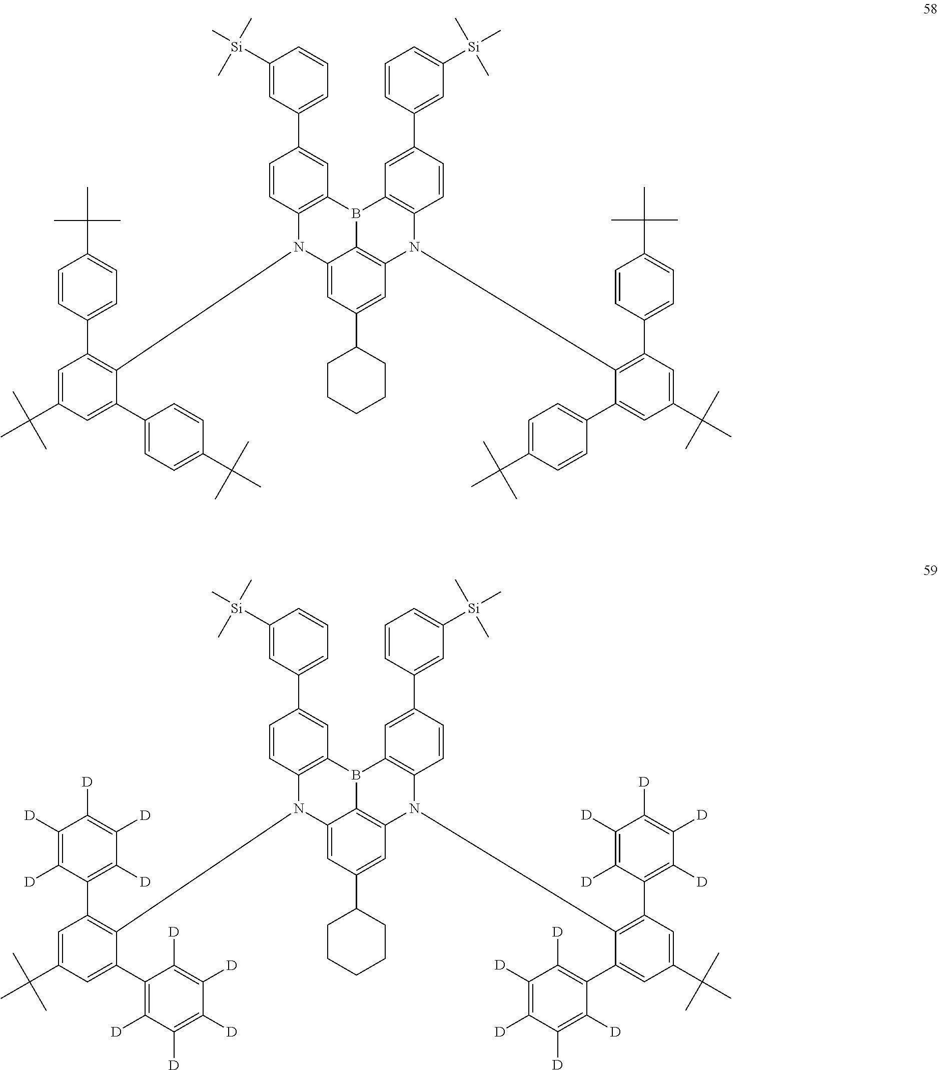

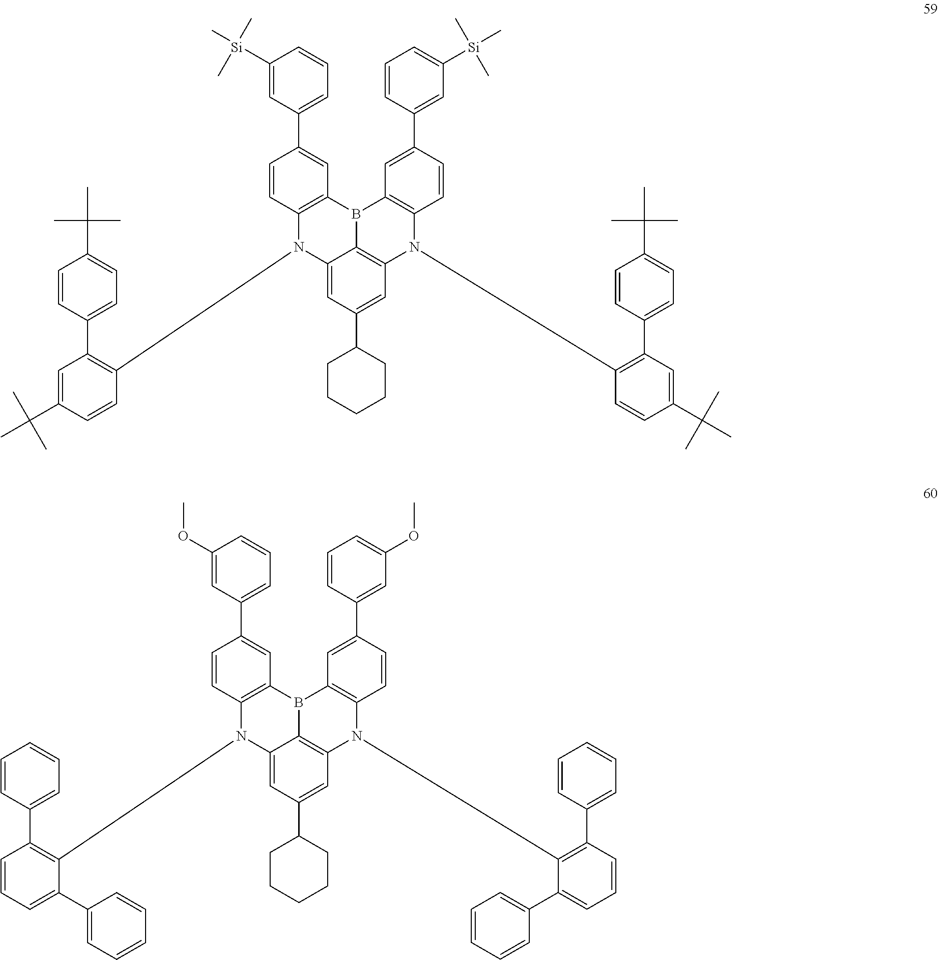 [SMILES: CC(C)(C)c1ccc(-c2cc(C(C)(C)C)ccc2N2c3ccc(-c4cccc([Si](C)(C)C)c4)cc3B3c4cc(-c5cccc([Si](C)(C)C)c5)ccc4N(c4ccc(C(C)(C)C)cc4-c4ccc(C(C)(C)C)cc4)c4cc(C5CCCCC5)cc2c43)cc1 ; COc1cccc(-c2ccc3c(c2)B2c4cc(-c5cccc(OC)c5)ccc4N(c4c(-c5ccccc5)cccc4-c4ccccc4)c4cc(C5CCCCC5)cc(c42)N3c2c(-c3ccccc3)cccc2-c2ccccc2)c1]

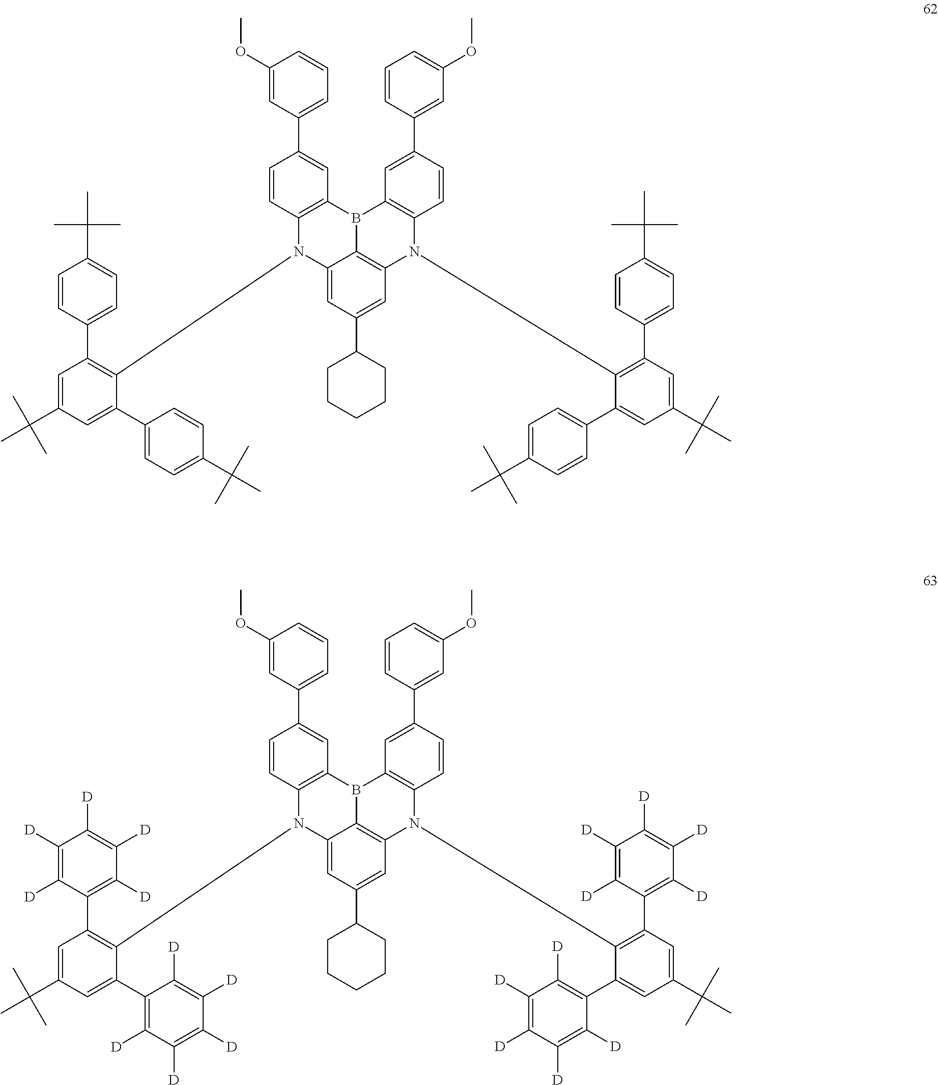

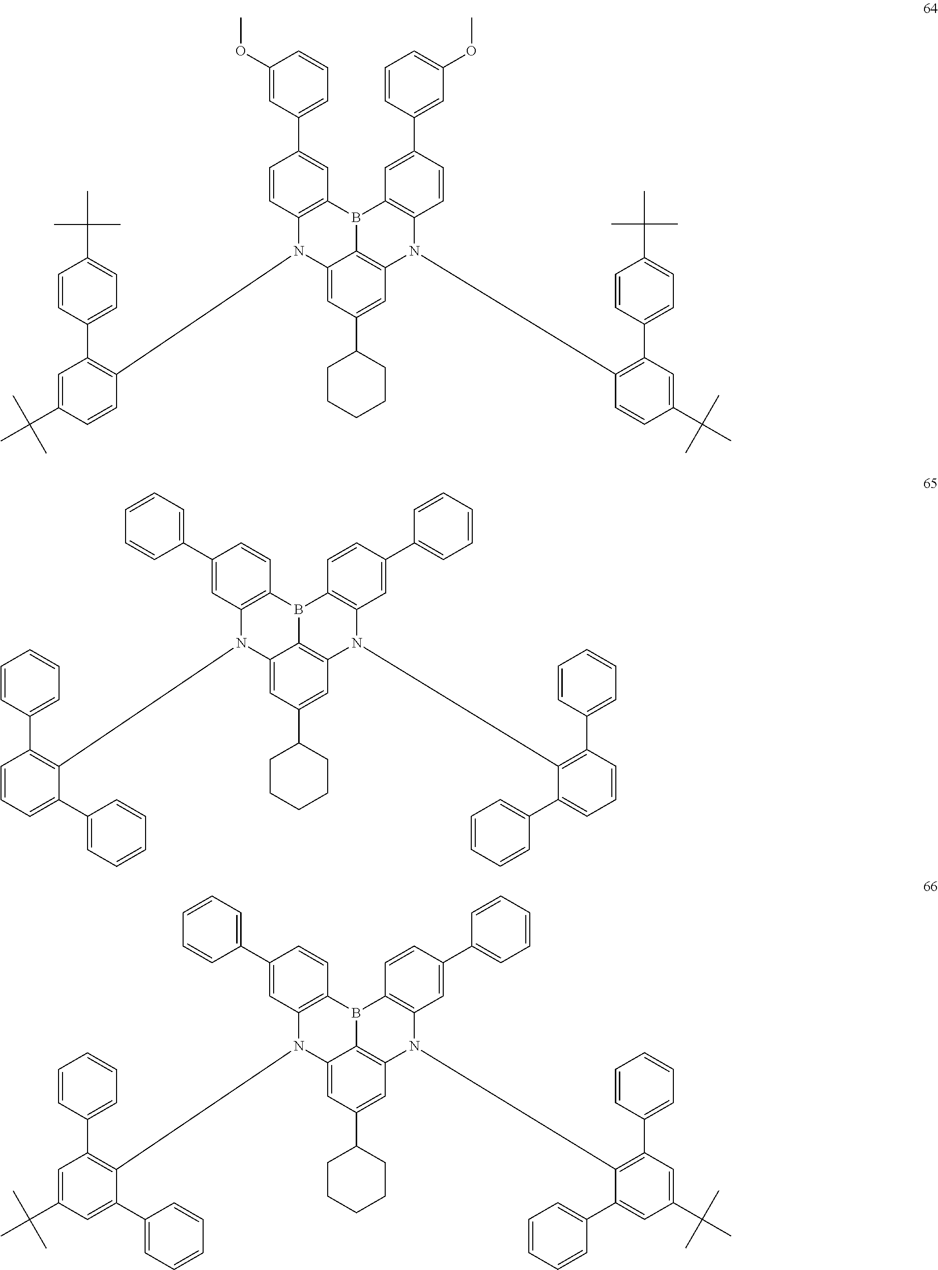

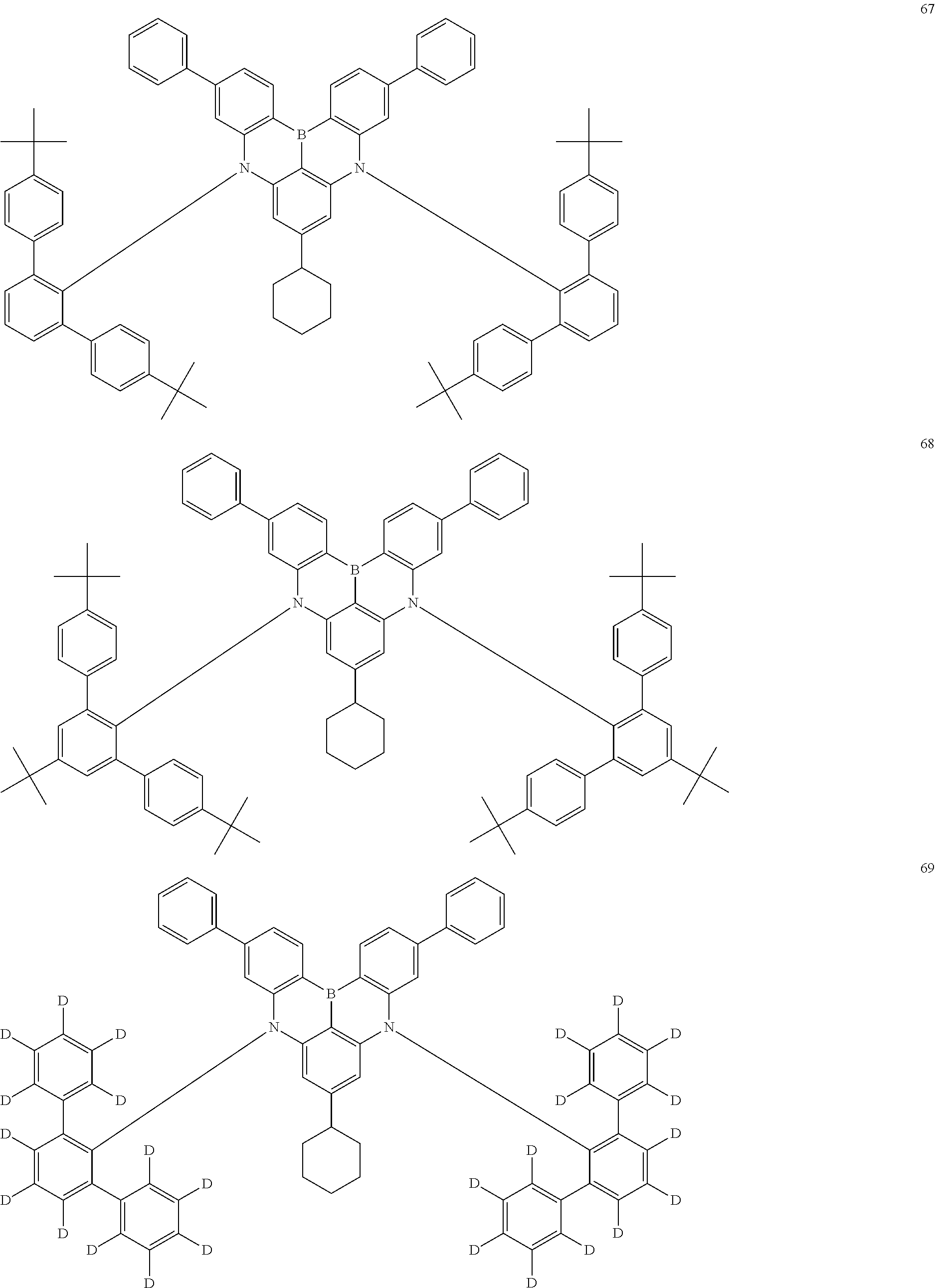

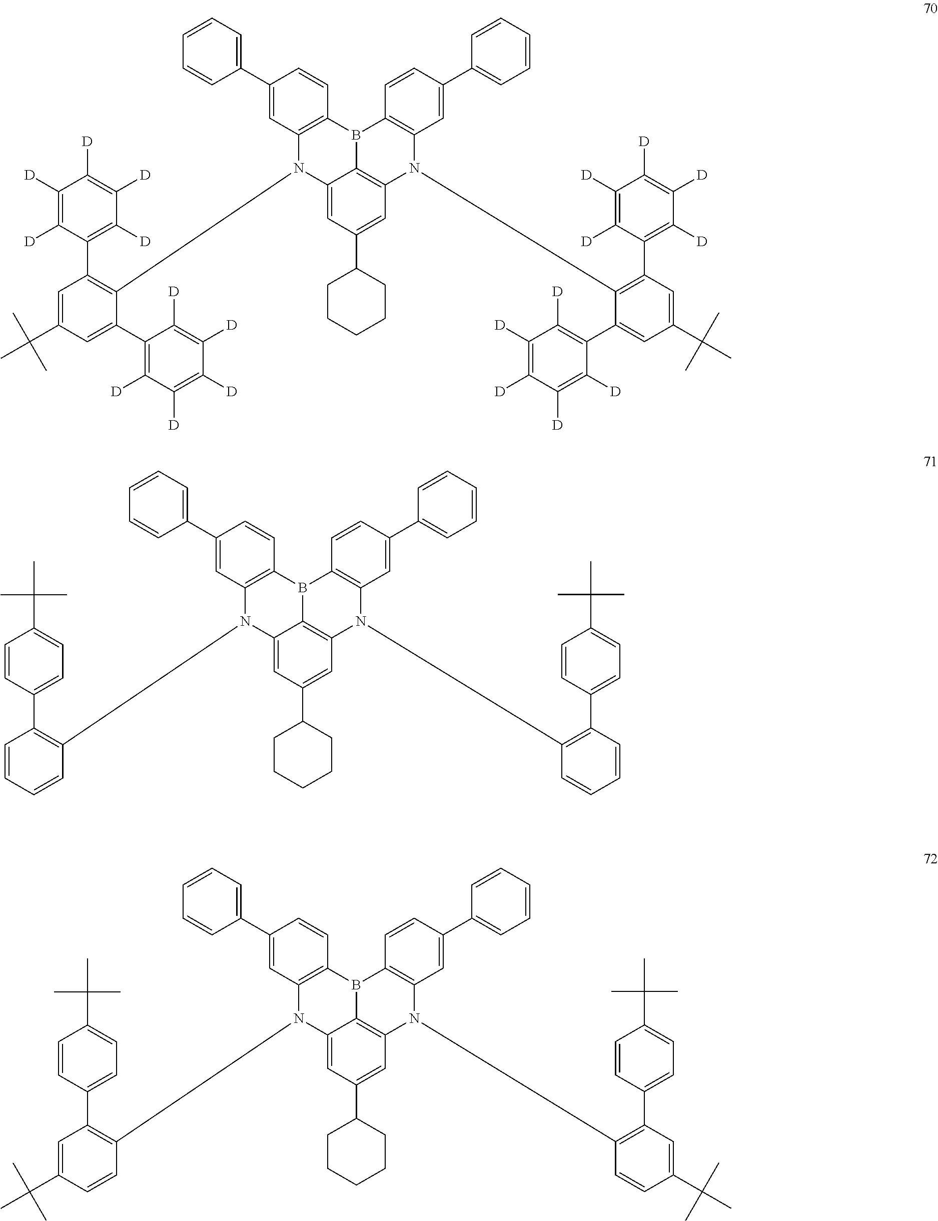

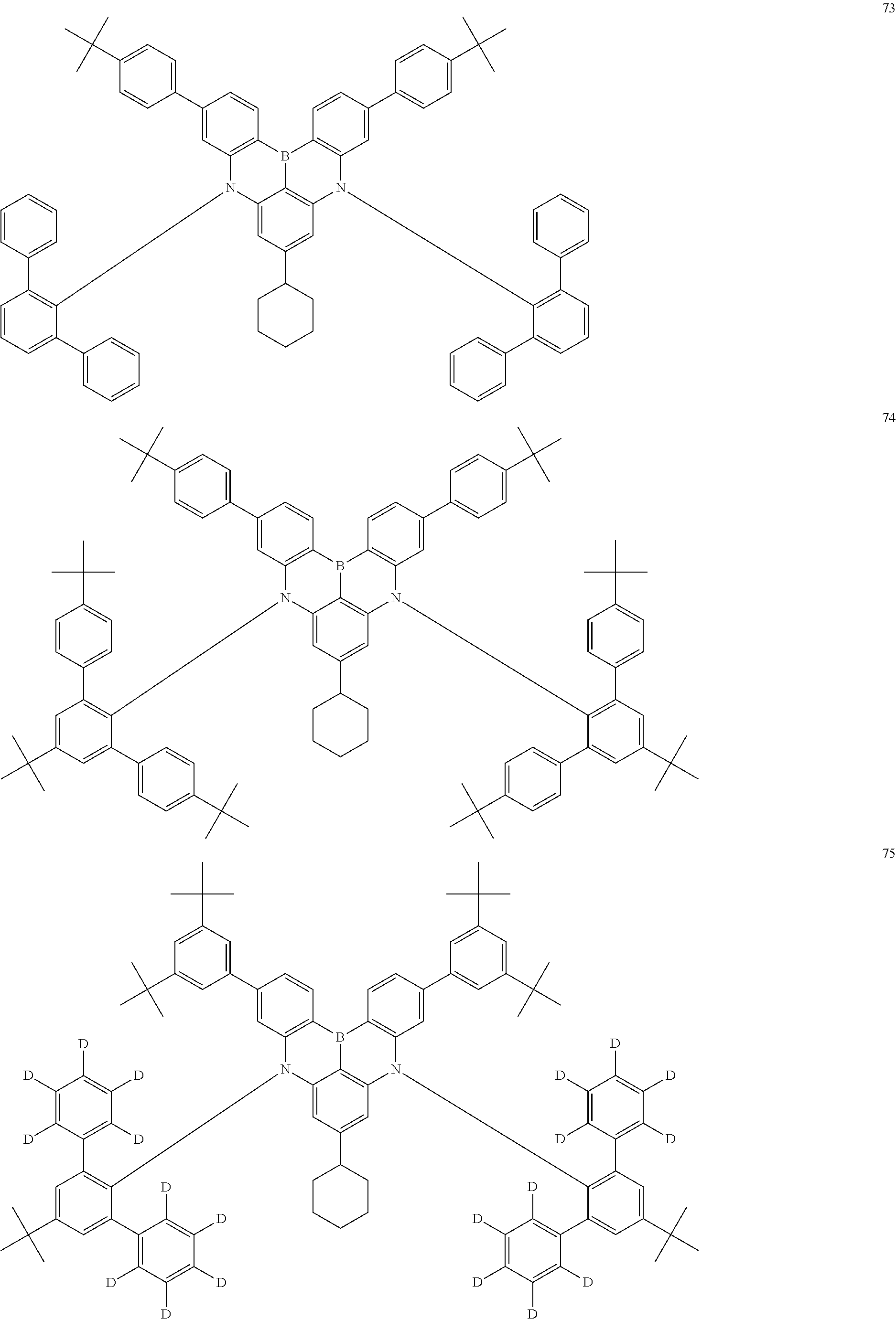

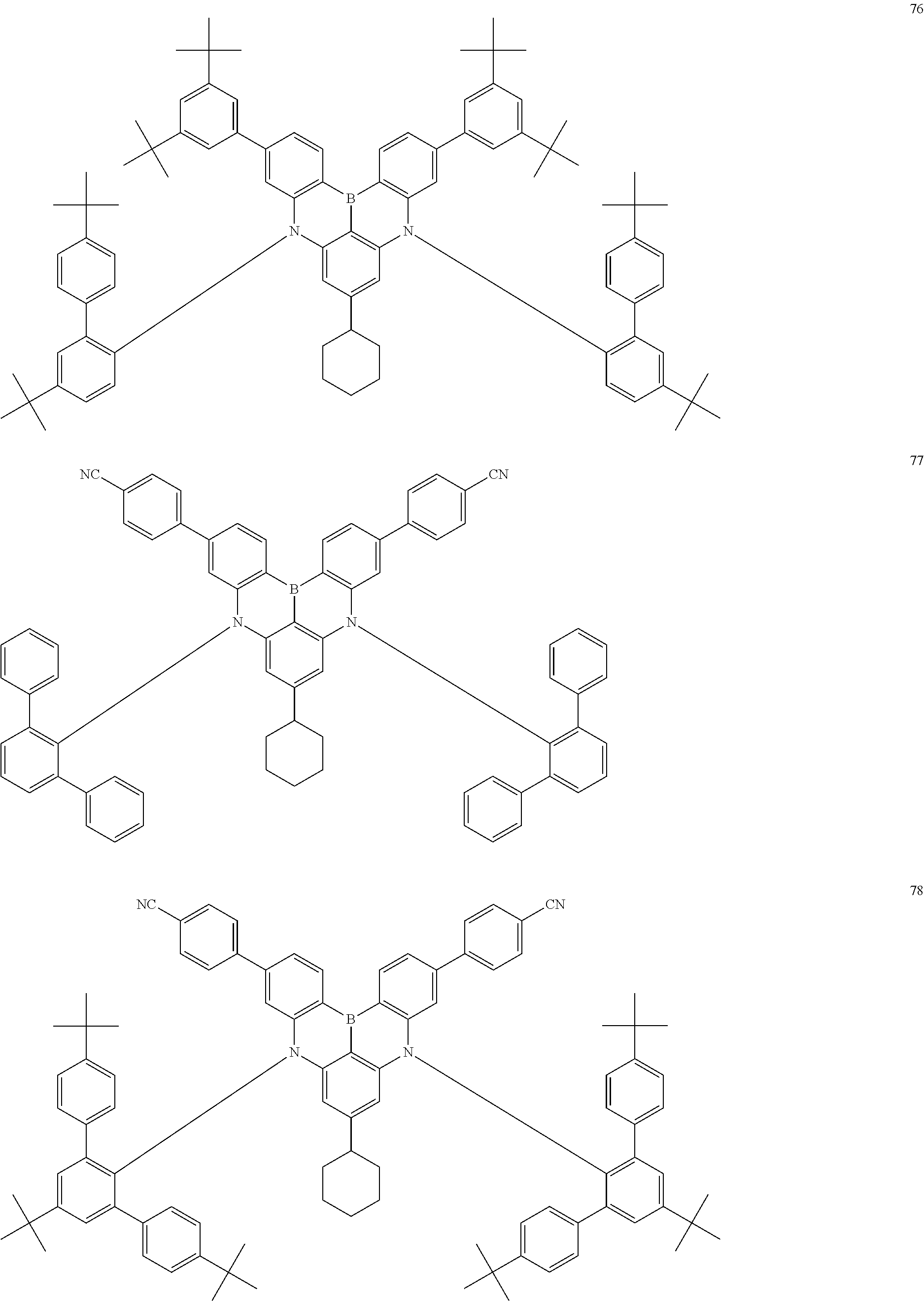

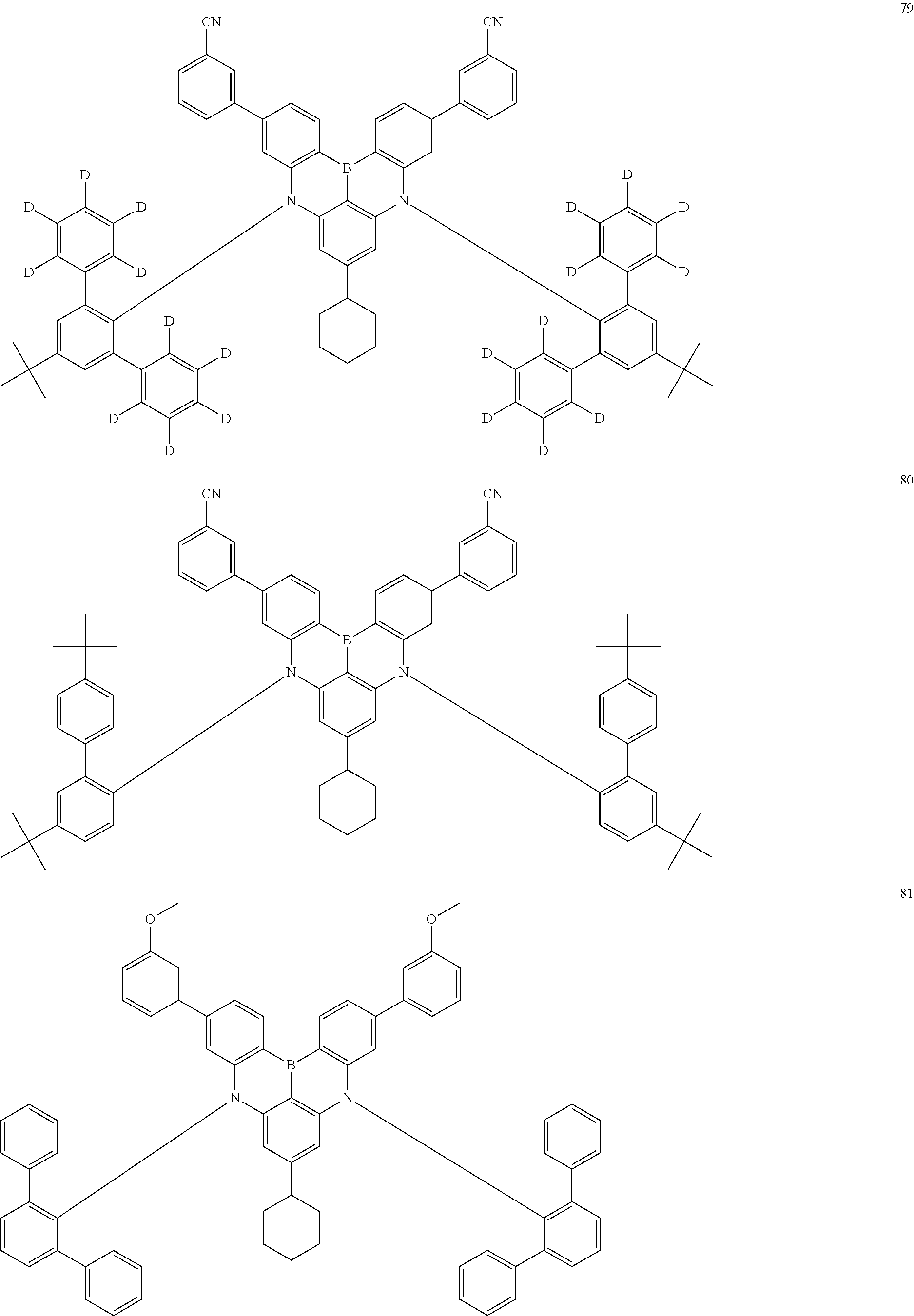

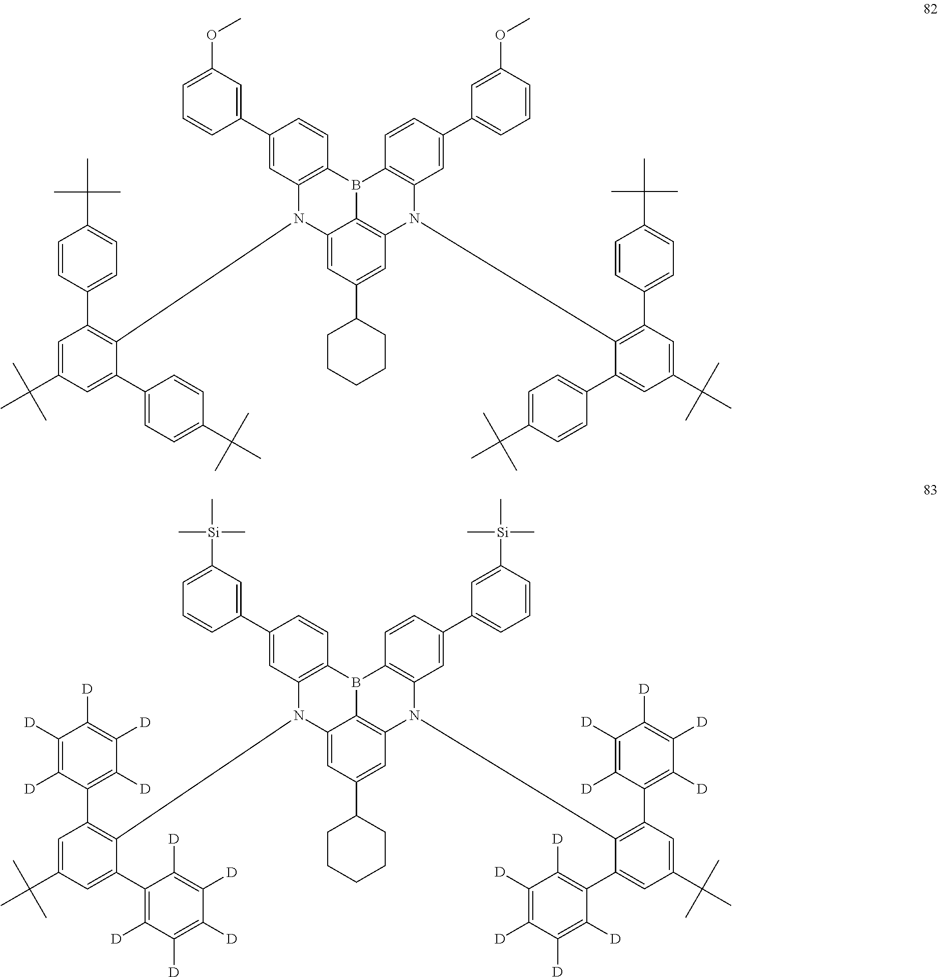

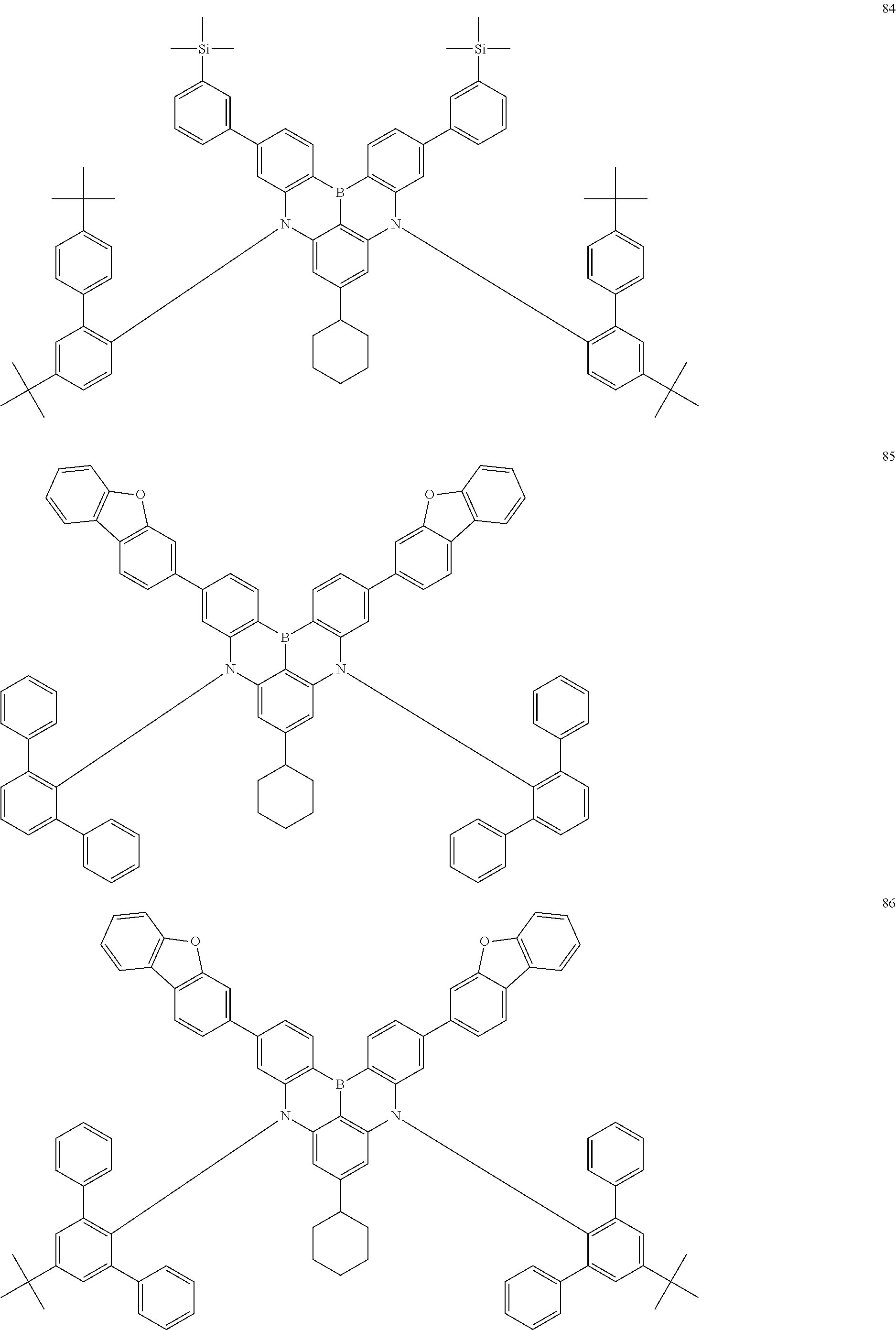

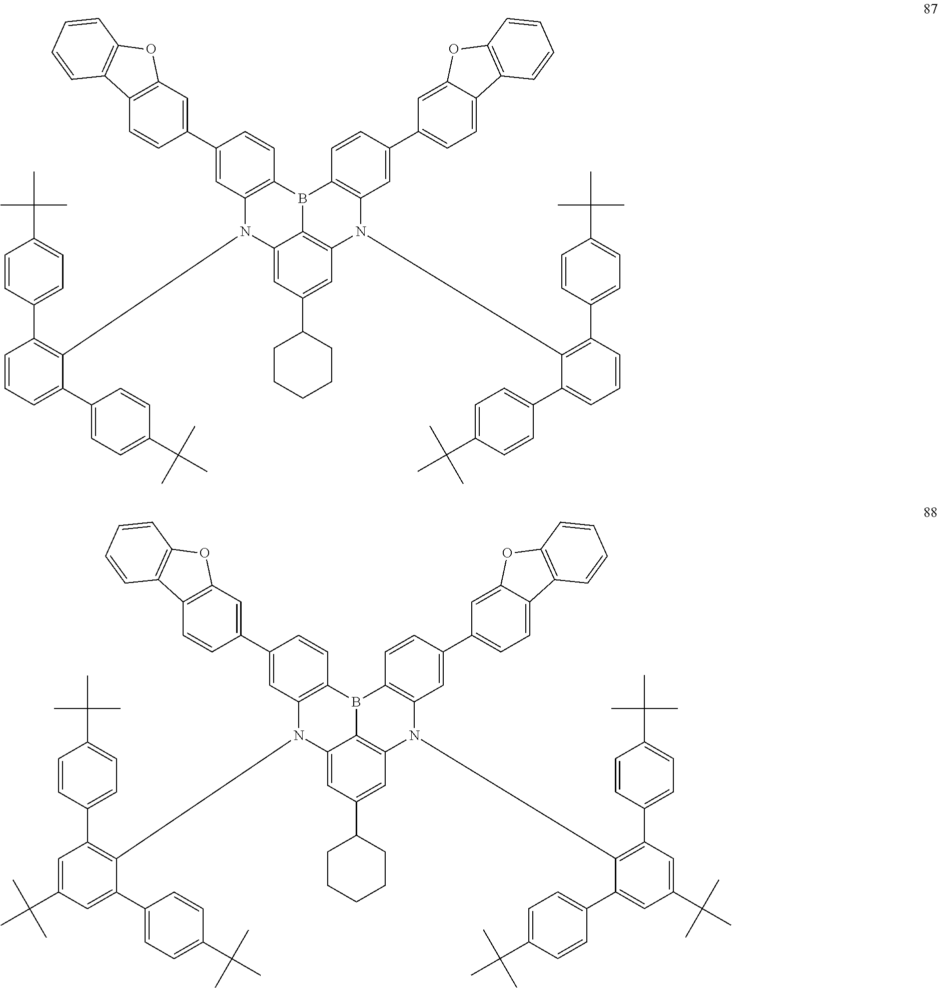

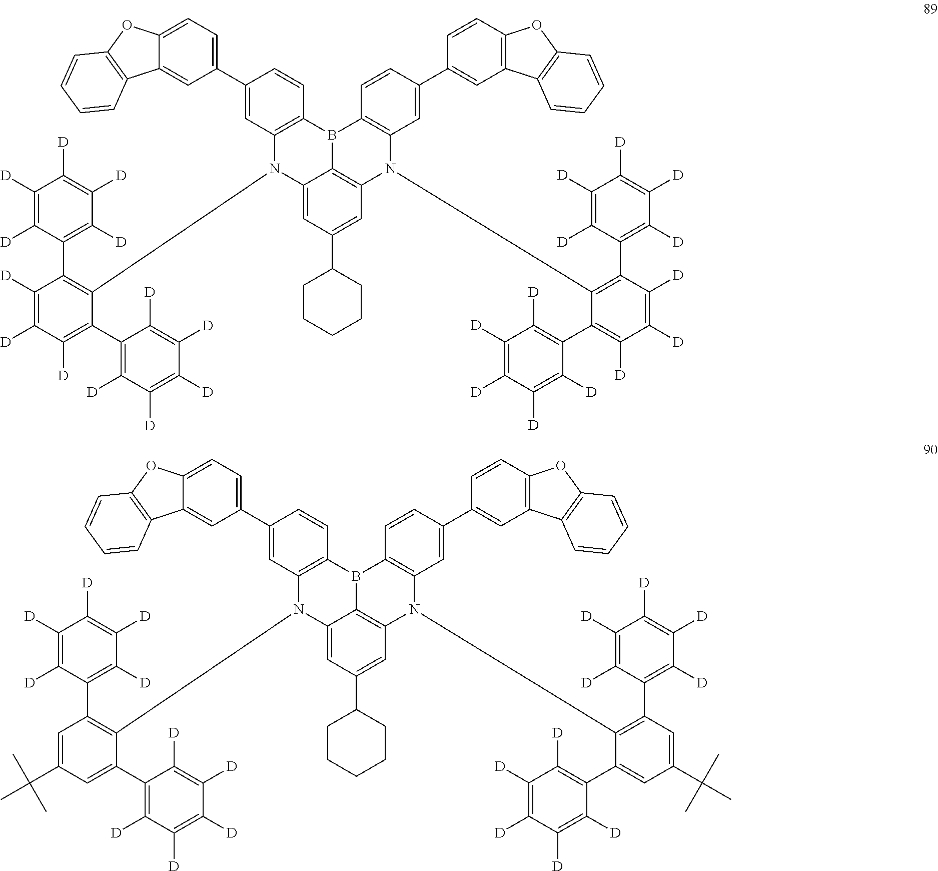

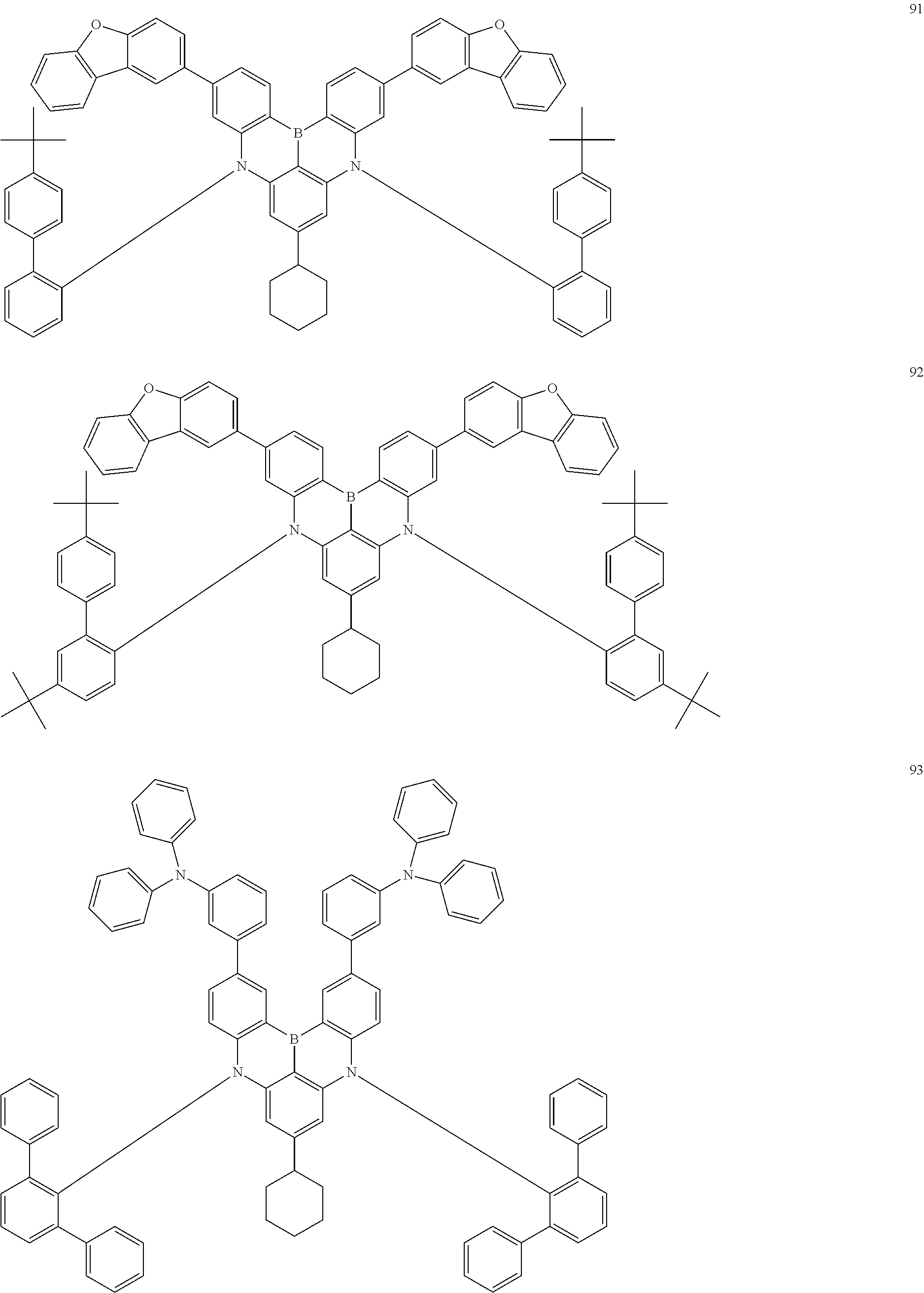

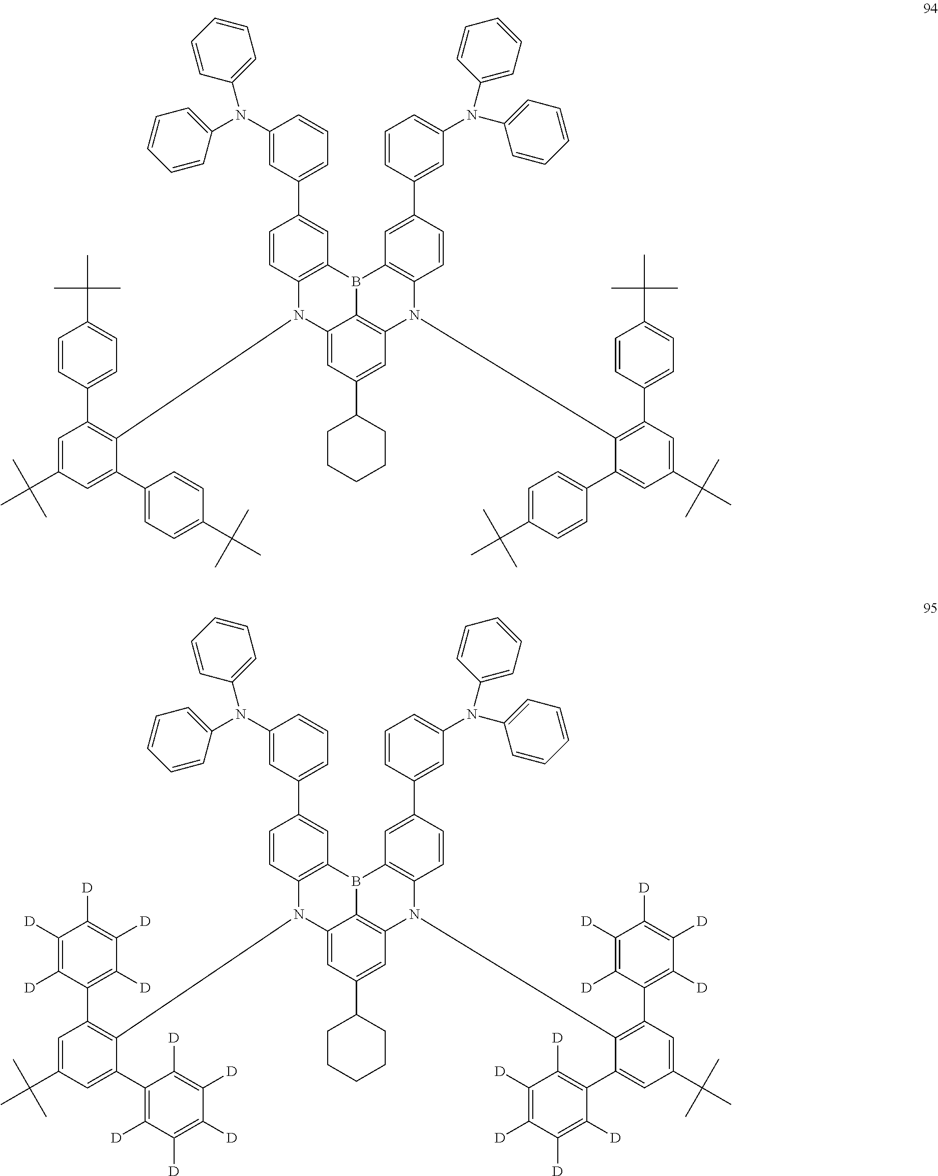

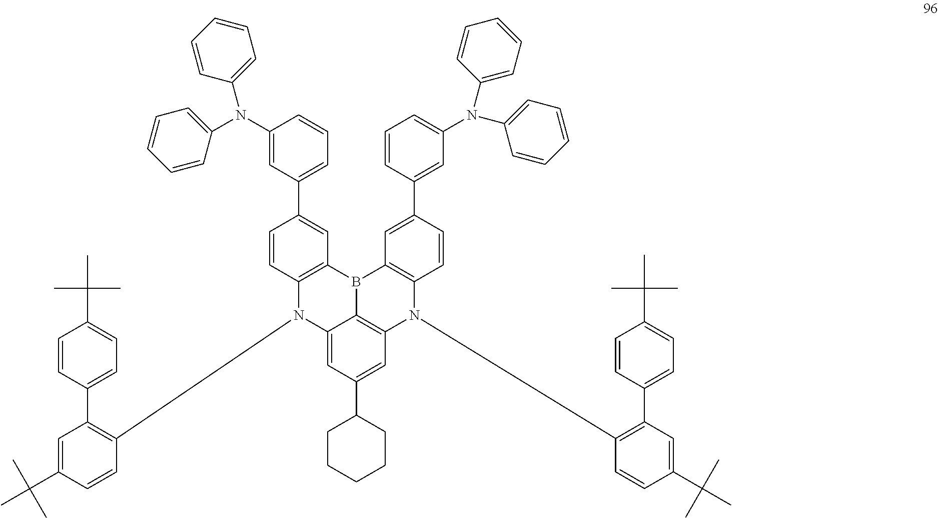 [SMILES: CC(C)(C)c1ccc(-c2cc(C(C)(C)C)ccc2N2c3ccc(-c4cccc(N(c5ccccc5)c5ccccc5)c4)cc3B3c4cc(-c5cccc(N(c6ccccc6)c6ccccc6)c5)ccc4N(c4ccc(C(C)(C)C)cc4-c4ccc(C(C)(C)C)cc4)c4cc(C5CCCCC5)cc2c43)cc1]

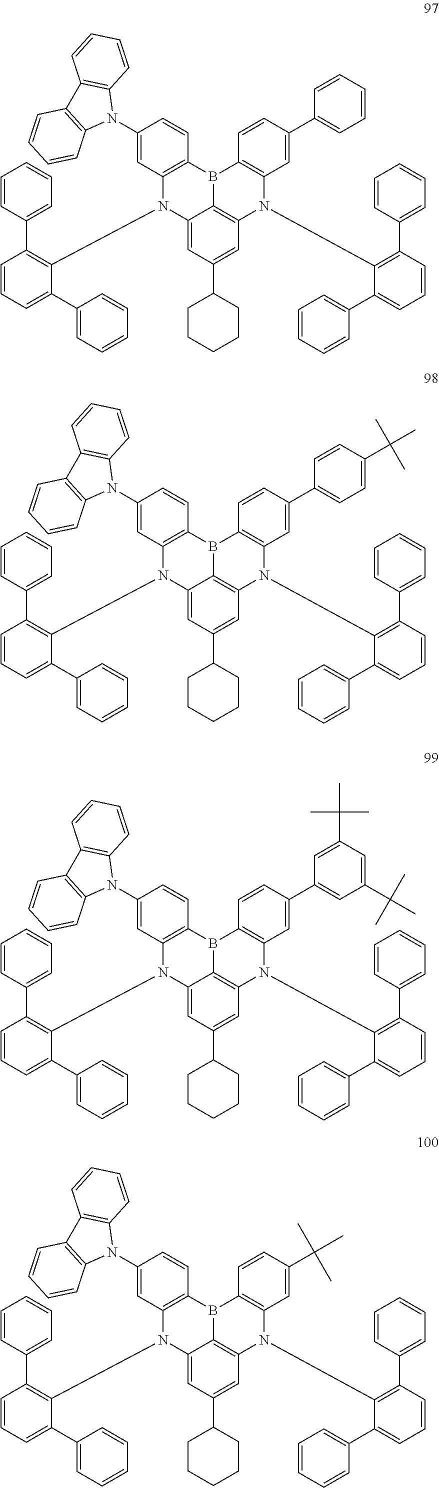

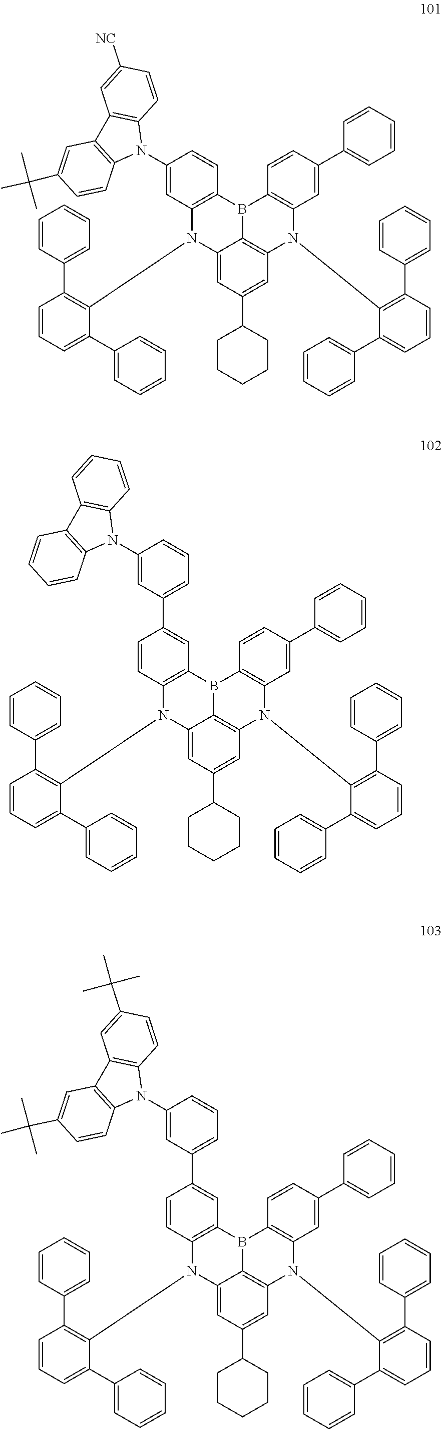 [SMILES: CC(C)(C)c1ccc2c(c1)c1cc(C#N)ccc1n2-c1ccc2c(c1)N(c1c(-c3ccccc3)cccc1-c1ccccc1)c1cc(C3CCCCC3)cc3c1B2c1ccc(-c2ccccc2)cc1N3c1c(-c2ccccc2)cccc1-c1ccccc1 ; c1ccc(-c2ccc3c(c2)N(c2c(-c4ccccc4)cccc2-c2ccccc2)c2cc(C4CCCCC4)cc4c2B3c2cc(-c3cccc(-n5c6ccccc6c6ccccc65)c3)ccc2N4c2c(-c3ccccc3)cccc2-c2ccccc2)cc1 ; CC(C)(C)c1ccc2c(c1)c1cc(C(C)(C)C)ccc1n2-c1cccc(-c2ccc3c(c2)B2c4ccc(-c5ccccc5)cc4N(c4c(-c5ccccc5)cccc4-c4ccccc4)c4cc(C5CCCCC5)cc(c42)N3c2c(-c3ccccc3)cccc2-c2ccccc2)c1]

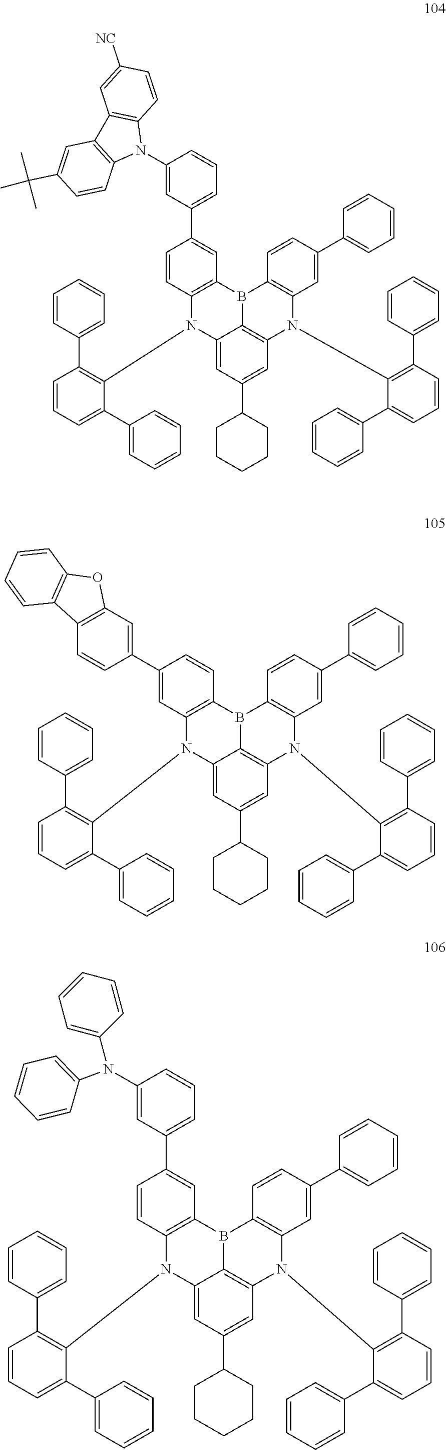 [SMILES: CC(C)(C)c1ccc2c(c1)c1cc(C#N)ccc1n2-c1cccc(-c2ccc3c(c2)B2c4ccc(-c5ccccc5)cc4N(c4c(-c5ccccc5)cccc4-c4ccccc4)c4cc(C5CCCCC5)cc(c42)N3c2c(-c3ccccc3)cccc2-c2ccccc2)c1 ; c1ccc(-c2ccc3c(c2)N(c2c(-c4ccccc4)cccc2-c2ccccc2)c2cc(C4CCCCC4)cc4c2B3c2ccc(-c3ccc5c(c3)oc3ccccc35)cc2N4c2c(-c3ccccc3)cccc2-c2ccccc2)cc1 ; c1ccc(-c2ccc3c(c2)N(c2c(-c4ccccc4)cccc2-c2ccccc2)c2cc(C4CCCCC4)cc4c2B3c2cc(-c3cccc(N(c5ccccc5)c5ccccc5)c3)ccc2N4c2c(-c3ccccc3)cccc2-c2ccccc2)cc1]

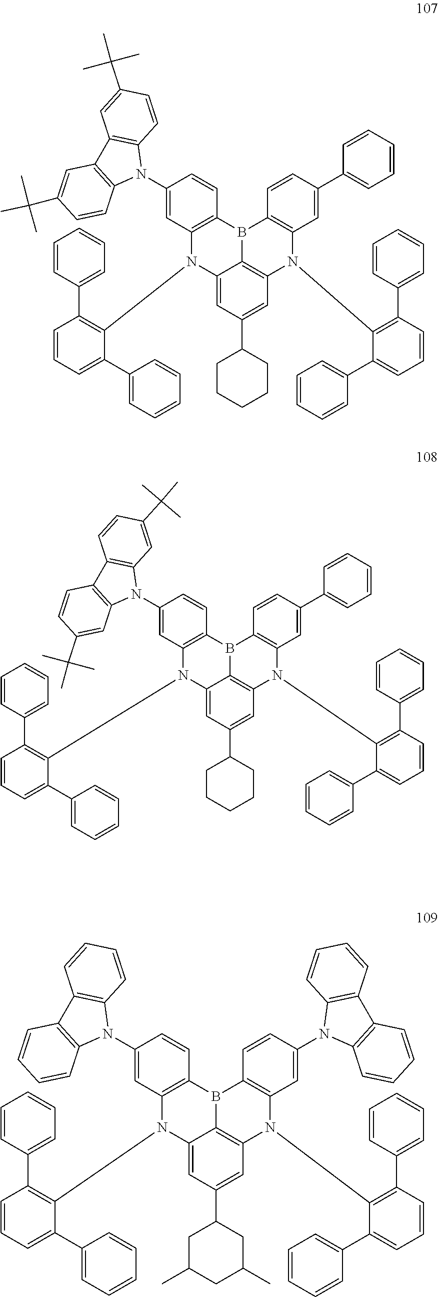 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(C3CCCCC3)cc3c1B2c1ccc(-c2ccccc2)cc1N3c1c(-c2ccccc2)cccc1-c1ccccc1 ; CC(C)(C)c1ccc2c3ccc(C(C)(C)C)cc3n(-c3ccc4c(c3)N(c3c(-c5ccccc5)cccc3-c3ccccc3)c3cc(C5CCCCC5)cc5c3B4c3ccc(-c4ccccc4)cc3N5c3c(-c4ccccc4)cccc3-c3ccccc3)c2c1 ; CC1CC(C)CC(c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)C1]

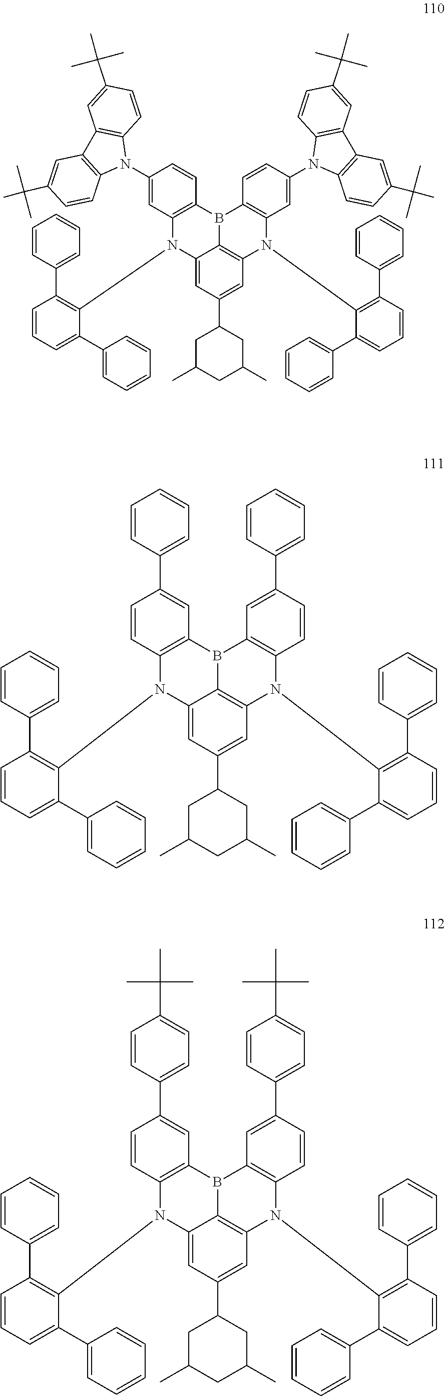 [SMILES: CC1CC(C)CC(c2cc3c4c(c2)N(c2c(-c5ccccc5)cccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3ccccc3)cccc2-c2ccccc2)C1 ; CC1CC(C)CC(c2cc3c4c(c2)N(c2c(-c5ccccc5)cccc2-c2ccccc2)c2ccc(-c5ccccc5)cc2B4c2cc(-c4ccccc4)ccc2N3c2c(-c3ccccc3)cccc2-c2ccccc2)C1 ; CC1CC(C)CC(c2cc3c4c(c2)N(c2c(-c5ccccc5)cccc2-c2ccccc2)c2ccc(-c5ccc(C(C)(C)C)cc5)cc2B4c2cc(-c4ccc(C(C)(C)C)cc4)ccc2N3c2c(-c3ccccc3)cccc2-c2ccccc2)C1]

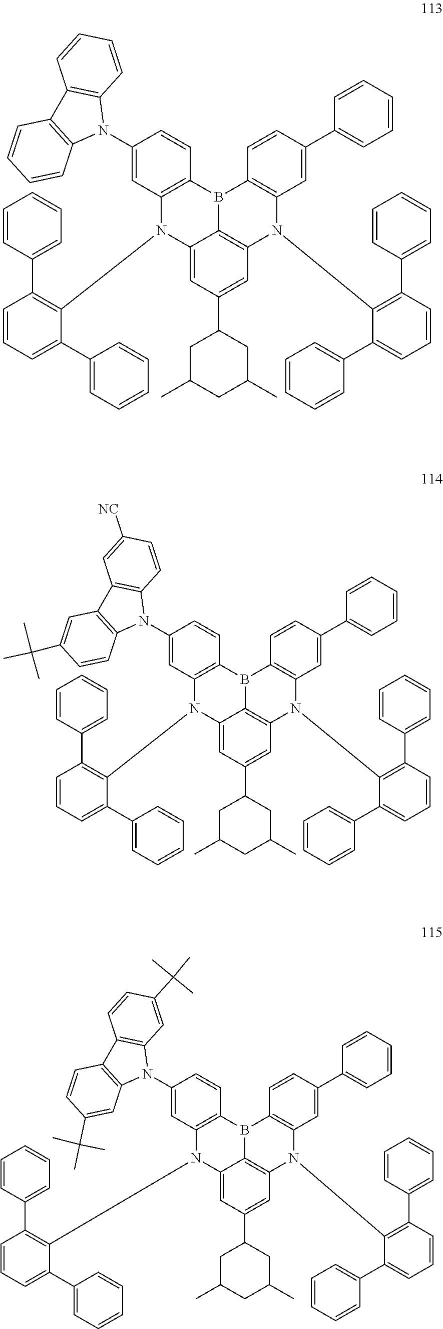 [SMILES: CC1CC(C)CC(c2cc3c4c(c2)N(c2c(-c5ccccc5)cccc2-c2ccccc2)c2cc(-n5c6ccccc6c6ccccc65)ccc2B4c2ccc(-c4ccccc4)cc2N3c2c(-c3ccccc3)cccc2-c2ccccc2)C1 ; CC1CC(C)CC(c2cc3c4c(c2)N(c2c(-c5ccccc5)cccc2-c2ccccc2)c2cc(-n5c6ccc(C#N)cc6c6cc(C(C)(C)C)ccc65)ccc2B4c2ccc(-c4ccccc4)cc2N3c2c(-c3ccccc3)cccc2-c2ccccc2)C1 ; CC1CC(C)CC(c2cc3c4c(c2)N(c2c(-c5ccccc5)cccc2-c2ccccc2)c2cc(-n5c6cc(C(C)(C)C)ccc6c6ccc(C(C)(C)C)cc65)ccc2B4c2ccc(-c4ccccc4)cc2N3c2c(-c3ccccc3)cccc2-c2ccccc2)C1]

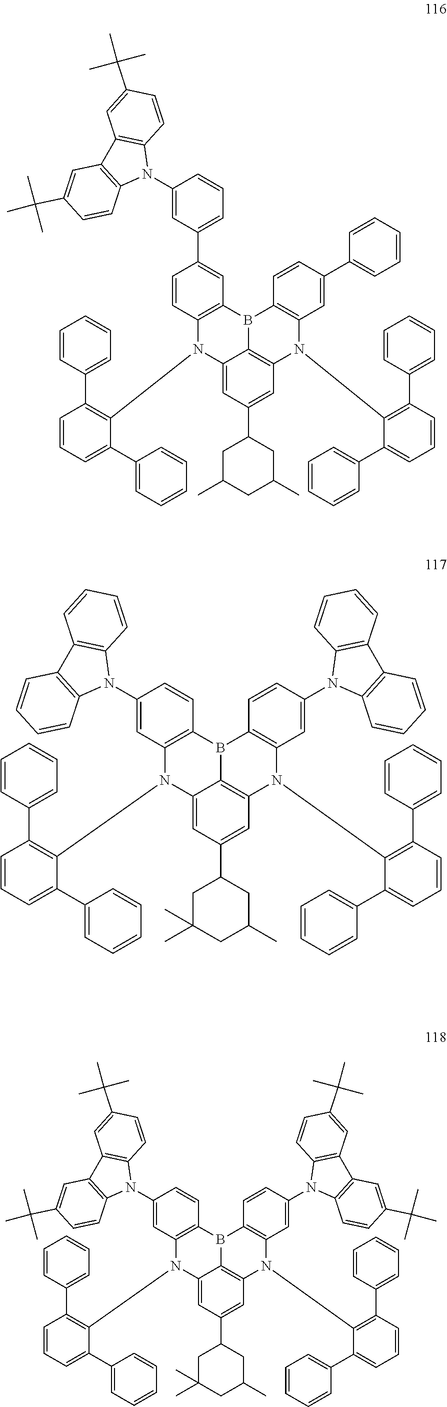

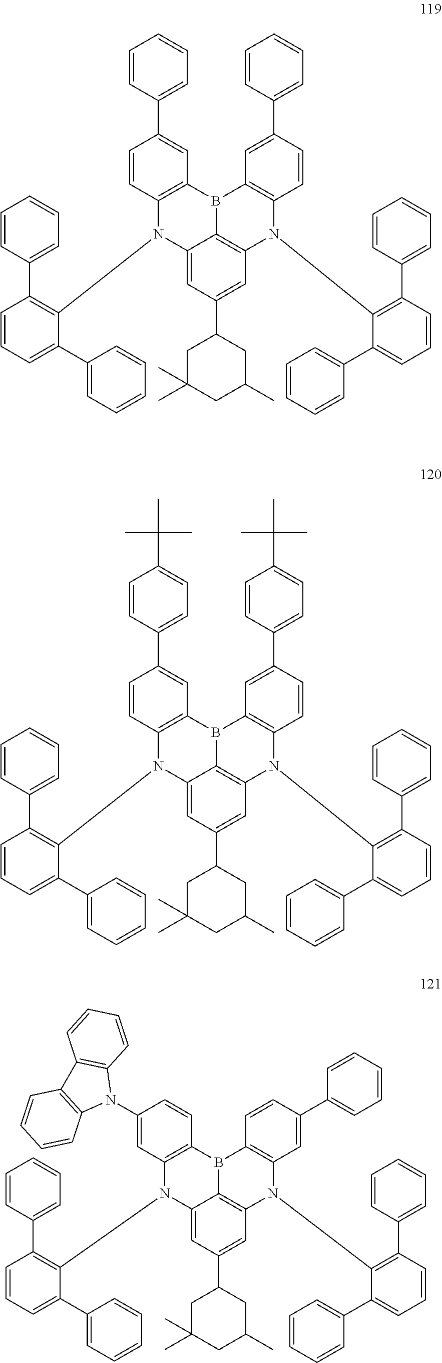 [SMILES: CC1CC(c2cc3c4c(c2)N(c2c(-c5ccccc5)cccc2-c2ccccc2)c2ccc(-c5ccccc5)cc2B4c2cc(-c4ccccc4)ccc2N3c2c(-c3ccccc3)cccc2-c2ccccc2)CC(C)(C)C1 ; CC1CC(c2cc3c4c(c2)N(c2c(-c5ccccc5)cccc2-c2ccccc2)c2ccc(-c5ccc(C(C)(C)C)cc5)cc2B4c2cc(-c4ccc(C(C)(C)C)cc4)ccc2N3c2c(-c3ccccc3)cccc2-c2ccccc2)CC(C)(C)C1 ; CC1CC(c2cc3c4c(c2)N(c2c(-c5ccccc5)cccc2-c2ccccc2)c2cc(-n5c6ccccc6c6ccccc65)ccc2B4c2ccc(-c4ccccc4)cc2N3c2c(-c3ccccc3)cccc2-c2ccccc2)CC(C)(C)C1]

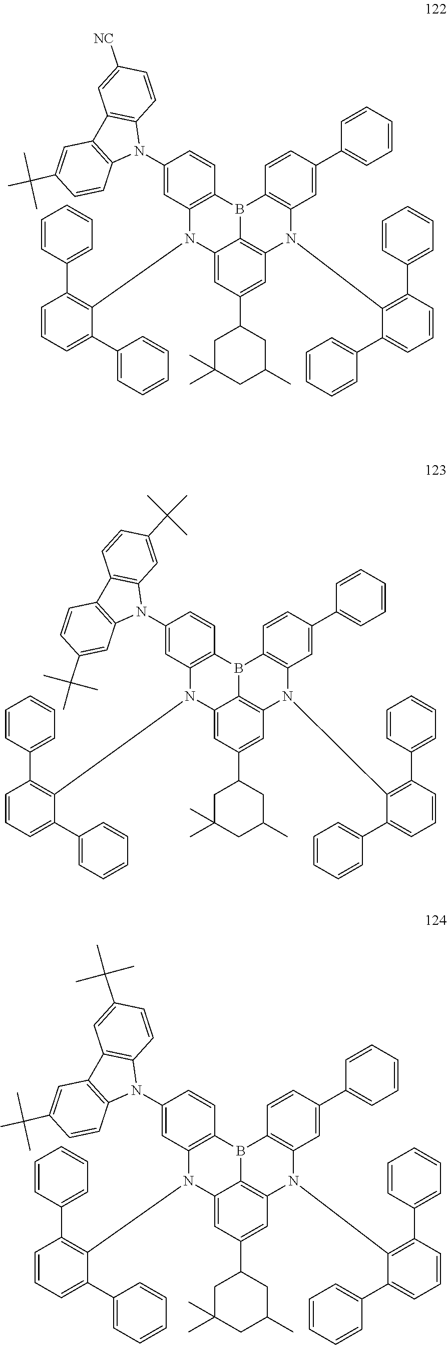 [SMILES: CC1CC(c2cc3c4c(c2)N(c2c(-c5ccccc5)cccc2-c2ccccc2)c2cc(-n5c6ccc(C#N)cc6c6cc(C(C)(C)C)ccc65)ccc2B4c2ccc(-c4ccccc4)cc2N3c2c(-c3ccccc3)cccc2-c2ccccc2)CC(C)(C)C1 ; CC1CC(c2cc3c4c(c2)N(c2c(-c5ccccc5)cccc2-c2ccccc2)c2cc(-n5c6cc(C(C)(C)C)ccc6c6ccc(C(C)(C)C)cc65)ccc2B4c2ccc(-c4ccccc4)cc2N3c2c(-c3ccccc3)cccc2-c2ccccc2)CC(C)(C)C1 ; CC1CC(c2cc3c4c(c2)N(c2c(-c5ccccc5)cccc2-c2ccccc2)c2cc(-n5c6ccc(C(C)(C)C)cc6c6cc(C(C)(C)C)ccc65)ccc2B4c2ccc(-c4ccccc4)cc2N3c2c(-c3ccccc3)cccc2-c2ccccc2)CC(C)(C)C1]

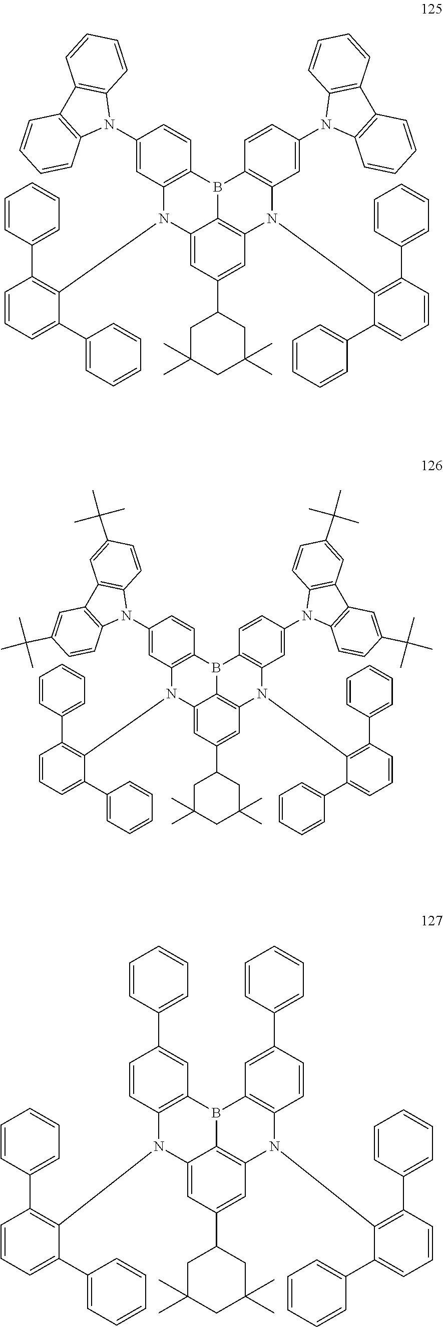 [SMILES: CC1(C)CC(c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)CC(C)(C)C1 ; CC1(C)CC(c2cc3c4c(c2)N(c2c(-c5ccccc5)cccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3ccccc3)cccc2-c2ccccc2)CC(C)(C)C1 ; CC1(C)CC(c2cc3c4c(c2)N(c2c(-c5ccccc5)cccc2-c2ccccc2)c2ccc(-c5ccccc5)cc2B4c2cc(-c4ccccc4)ccc2N3c2c(-c3ccccc3)cccc2-c2ccccc2)CC(C)(C)C1]

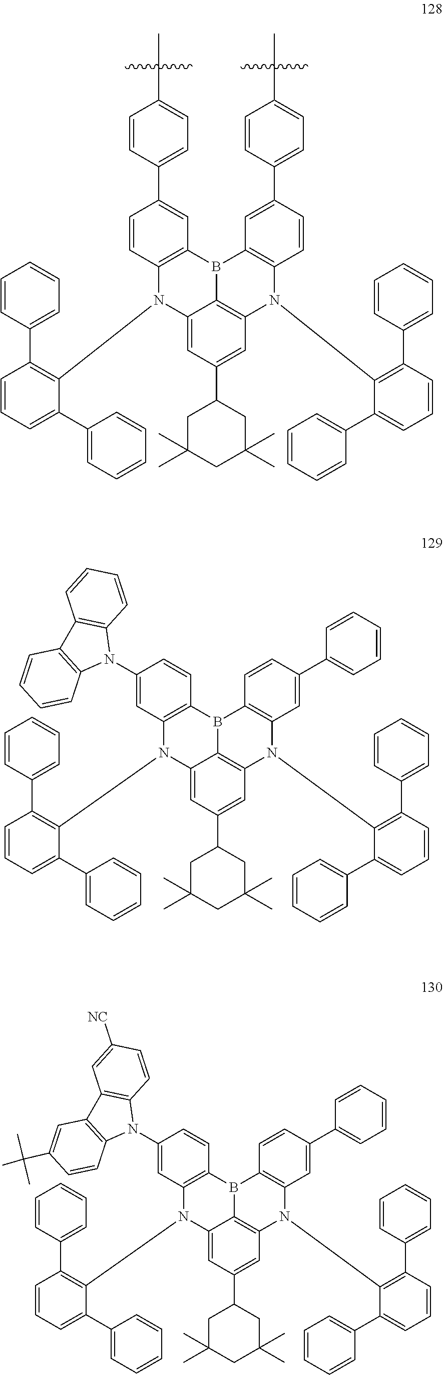 [SMILES: *c1ccc(-c2ccc3c(c2)B2c4cc(-c5ccc(*)cc5)ccc4N(c4c(-c5ccccc5)cccc4-c4ccccc4)c4cc(C5CC(C)(C)CC(C)(C)C5)cc(c42)N3c2c(-c3ccccc3)cccc2-c2ccccc2)cc1 ; CC1(C)CC(c2cc3c4c(c2)N(c2c(-c5ccccc5)cccc2-c2ccccc2)c2cc(-n5c6ccccc6c6ccccc65)ccc2B4c2ccc(-c4ccccc4)cc2N3c2c(-c3ccccc3)cccc2-c2ccccc2)CC(C)(C)C1 ; CC1(C)CC(c2cc3c4c(c2)N(c2c(-c5ccccc5)cccc2-c2ccccc2)c2cc(-n5c6ccc(C#N)cc6c6cc(C(C)(C)C)ccc65)ccc2B4c2ccc(-c4ccccc4)cc2N3c2c(-c3ccccc3)cccc2-c2ccccc2)CC(C)(C)C1]

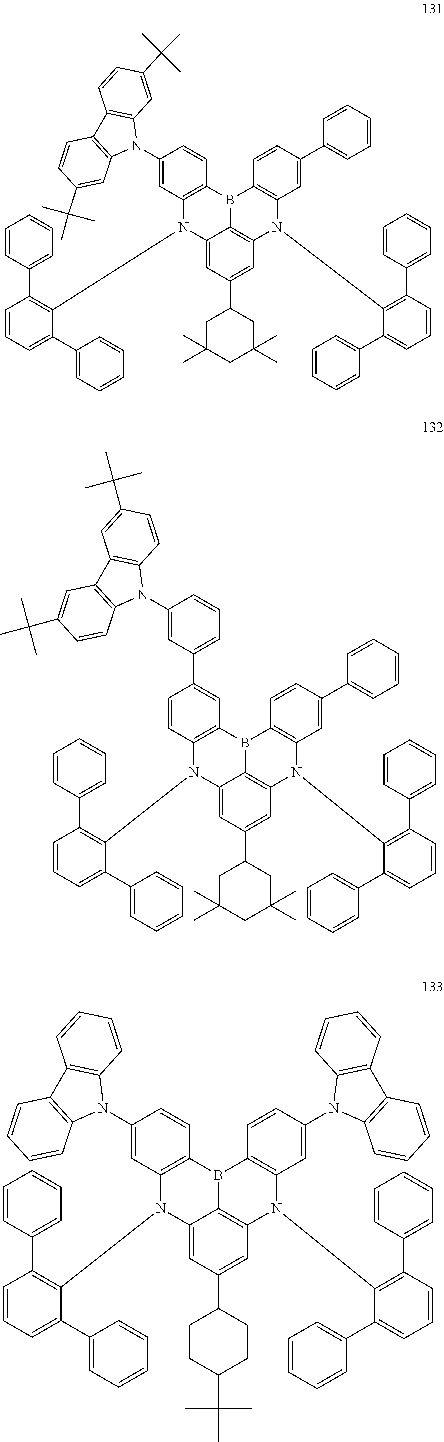 [SMILES: CC1(C)CC(c2cc3c4c(c2)N(c2c(-c5ccccc5)cccc2-c2ccccc2)c2cc(-n5c6cc(C(C)(C)C)ccc6c6ccc(C(C)(C)C)cc65)ccc2B4c2ccc(-c4ccccc4)cc2N3c2c(-c3ccccc3)cccc2-c2ccccc2)CC(C)(C)C1 ; CC1(C)CC(c2cc3c4c(c2)N(c2c(-c5ccccc5)cccc2-c2ccccc2)c2cc(-c5ccccc5)ccc2B4c2cc(-c4cccc(-n5c6ccc(C(C)(C)C)cc6c6cc(C(C)(C)C)ccc65)c4)ccc2N3c2c(-c3ccccc3)cccc2-c2ccccc2)CC(C)(C)C1 ; CC(C)(C)C1CCC(c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)CC1]

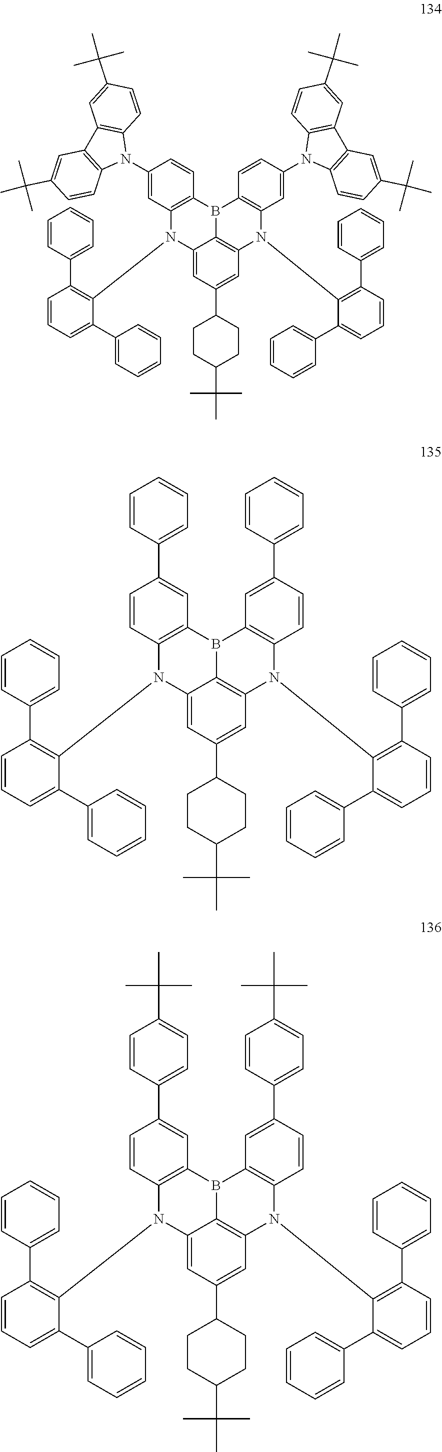 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(C3CCC(C(C)(C)C)CC3)cc3c1B2c1ccc(-n2c4ccc(C(C)(C)C)cc4c4cc(C(C)(C)C)ccc42)cc1N3c1c(-c2ccccc2)cccc1-c1ccccc1 ; CC(C)(C)C1CCC(c2cc3c4c(c2)N(c2c(-c5ccccc5)cccc2-c2ccccc2)c2ccc(-c5ccccc5)cc2B4c2cc(-c4ccccc4)ccc2N3c2c(-c3ccccc3)cccc2-c2ccccc2)CC1 ; CC(C)(C)c1ccc(-c2ccc3c(c2)B2c4cc(-c5ccc(C(C)(C)C)cc5)ccc4N(c4c(-c5ccccc5)cccc4-c4ccccc4)c4cc(C5CCC(C(C)(C)C)CC5)cc(c42)N3c2c(-c3ccccc3)cccc2-c2ccccc2)cc1]

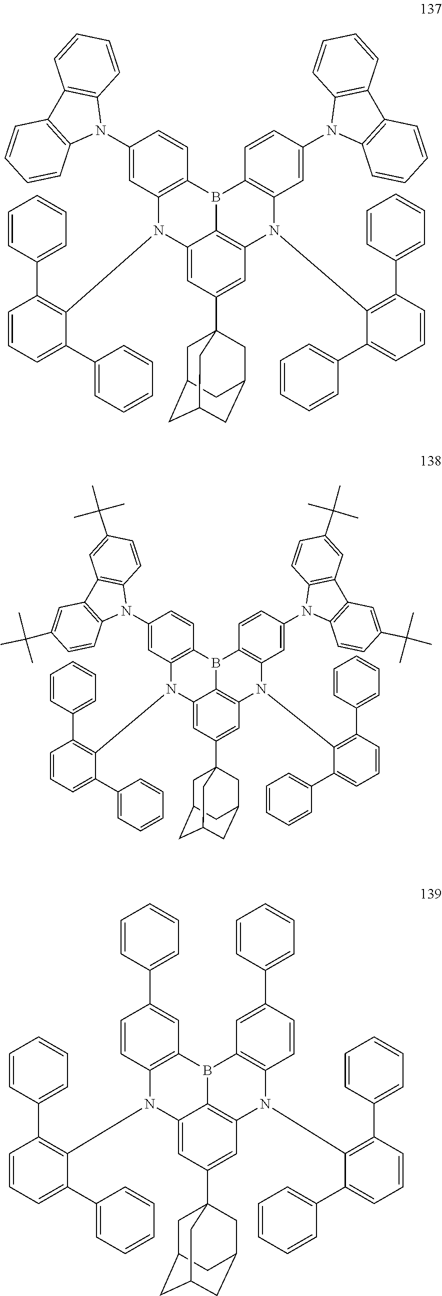 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(C56CC7CC(CC(C7)C5)C6)cc2c43)cc1 ; CC(C)(C)c1ccc2c(c1)c1cc(C(C)(C)C)ccc1n2-c1ccc2c(c1)N(c1c(-c3ccccc3)cccc1-c1ccccc1)c1cc(C34CC5CC(CC(C5)C3)C4)cc3c1B2c1ccc(-n2c4ccc(C(C)(C)C)cc4c4cc(C(C)(C)C)ccc42)cc1N3c1c(-c2ccccc2)cccc1-c1ccccc1 ; c1ccc(-c2ccc3c(c2)B2c4cc(-c5ccccc5)ccc4N(c4c(-c5ccccc5)cccc4-c4ccccc4)c4cc(C56CC7CC(CC(C7)C5)C6)cc(c42)N3c2c(-c3ccccc3)cccc2-c2ccccc2)cc1]

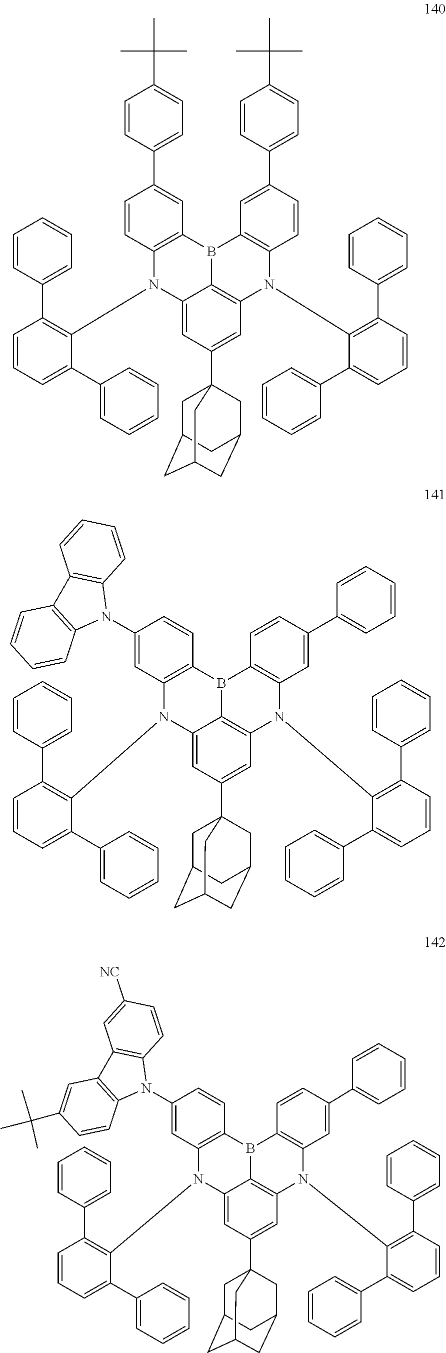 [SMILES: CC(C)(C)c1ccc(-c2ccc3c(c2)B2c4cc(-c5ccc(C(C)(C)C)cc5)ccc4N(c4c(-c5ccccc5)cccc4-c4ccccc4)c4cc(C56CC7CC(CC(C7)C5)C6)cc(c42)N3c2c(-c3ccccc3)cccc2-c2ccccc2)cc1 ; c1ccc(-c2ccc3c(c2)N(c2c(-c4ccccc4)cccc2-c2ccccc2)c2cc(C45CC6CC(CC(C6)C4)C5)cc4c2B3c2ccc(-n3c5ccccc5c5ccccc53)cc2N4c2c(-c3ccccc3)cccc2-c2ccccc2)cc1 ; CC(C)(C)c1ccc2c(c1)c1cc(C#N)ccc1n2-c1ccc2c(c1)N(c1c(-c3ccccc3)cccc1-c1ccccc1)c1cc(C34CC5CC(CC(C5)C3)C4)cc3c1B2c1ccc(-c2ccccc2)cc1N3c1c(-c2ccccc2)cccc1-c1ccccc1]

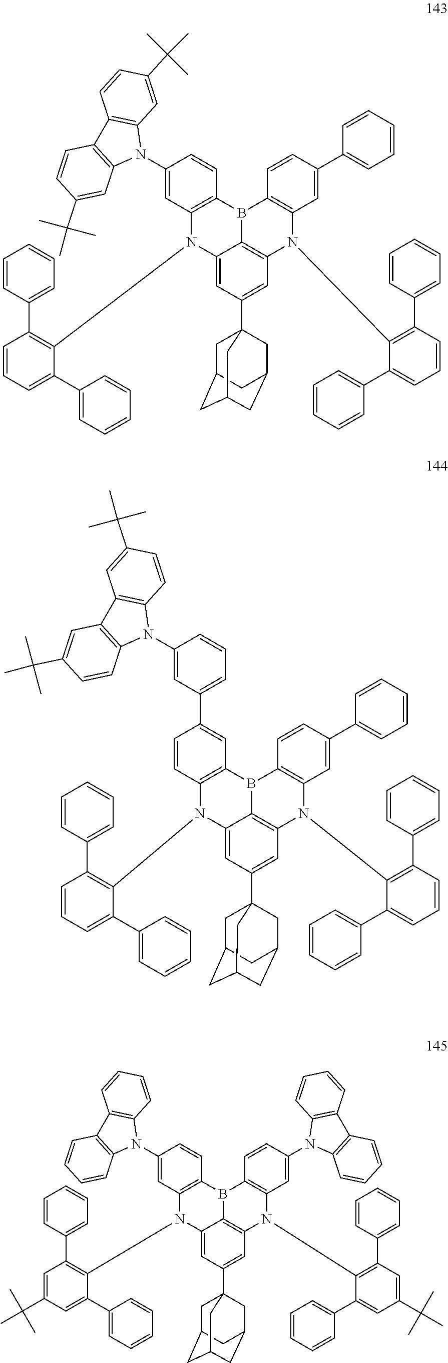

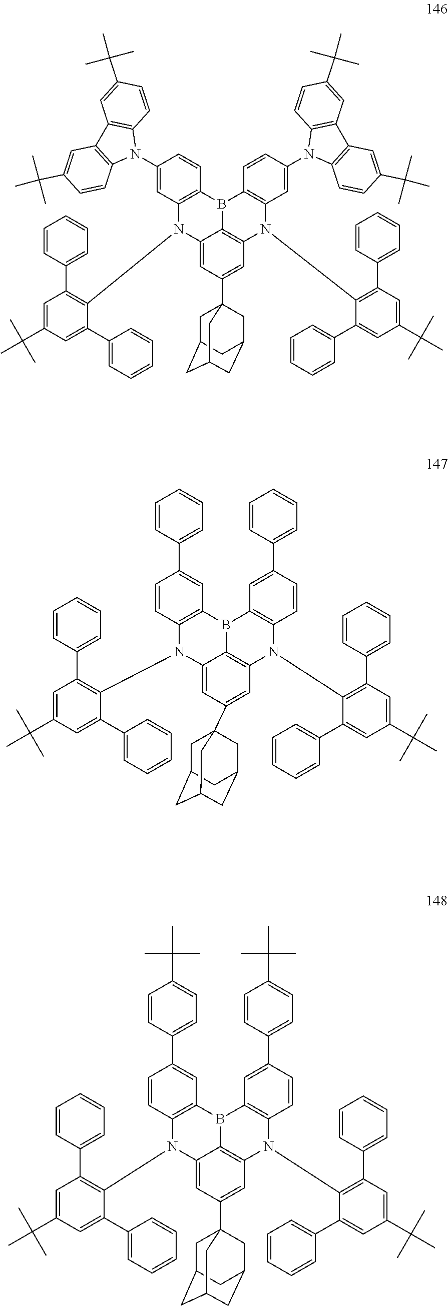

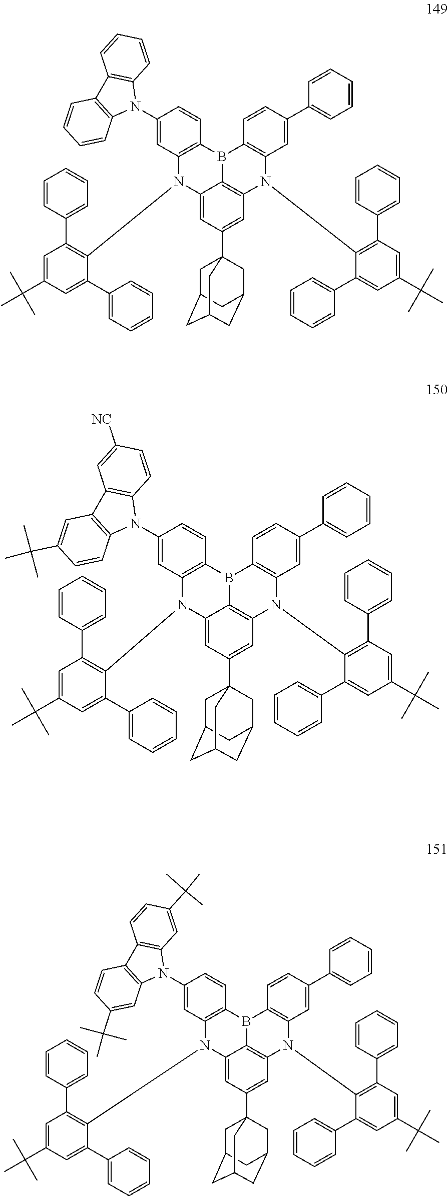

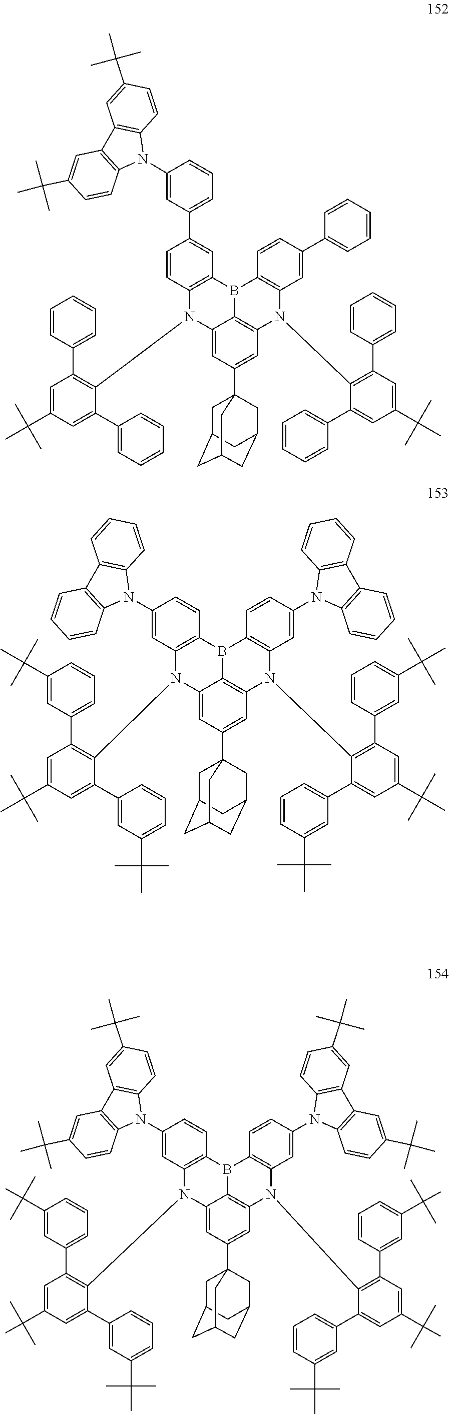

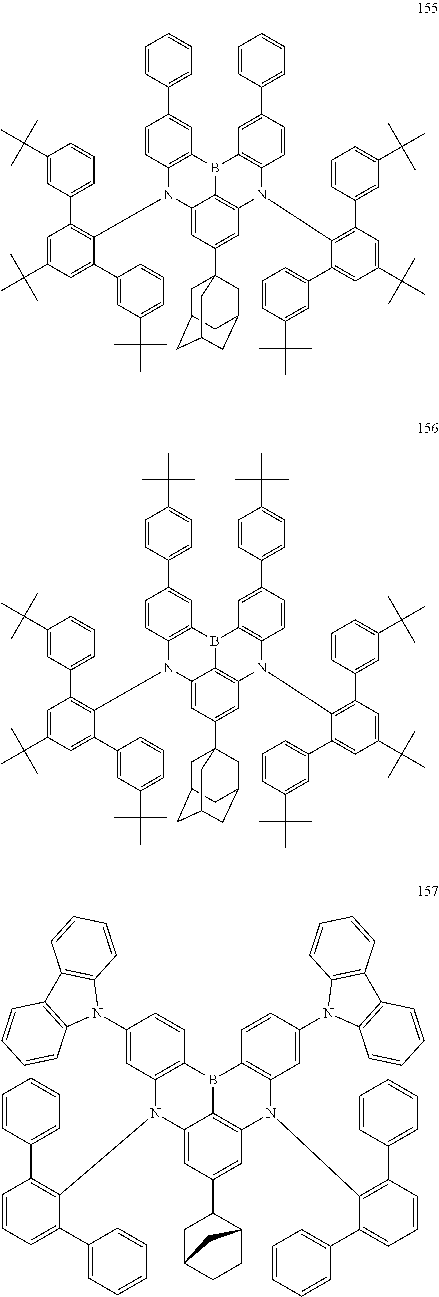

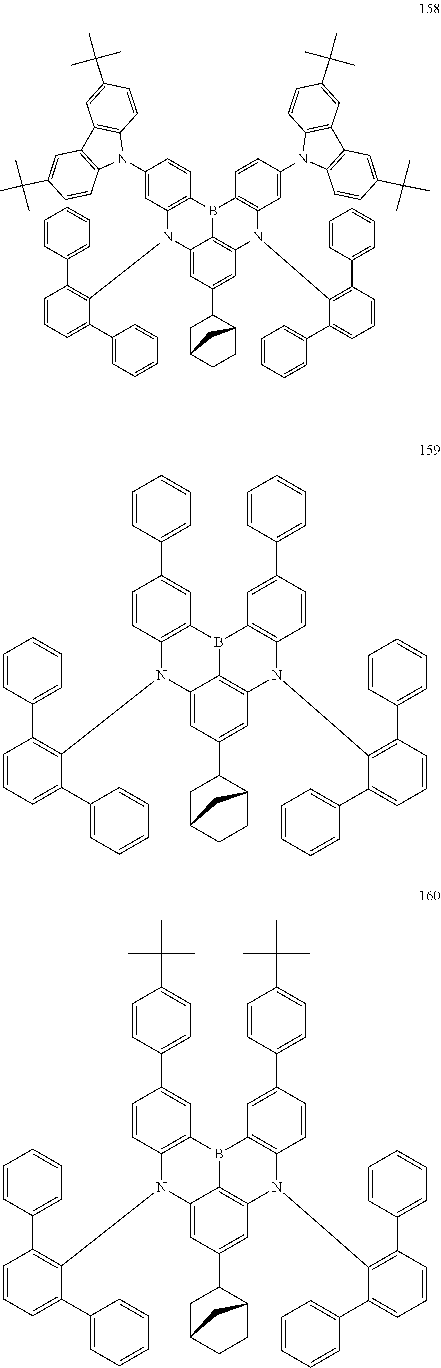 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(C3C[C@H]4CC[C@@H]3C4)cc3c1B2c1ccc(-n2c4ccc(C(C)(C)C)cc4c4cc(C(C)(C)C)ccc42)cc1N3c1c(-c2ccccc2)cccc1-c1ccccc1 ; c1ccc(-c2ccc3c(c2)B2c4cc(-c5ccccc5)ccc4N(c4c(-c5ccccc5)cccc4-c4ccccc4)c4cc(C5C[C@H]6CC[C@@H]5C6)cc(c42)N3c2c(-c3ccccc3)cccc2-c2ccccc2)cc1 ; CC(C)(C)c1ccc(-c2ccc3c(c2)B2c4cc(-c5ccc(C(C)(C)C)cc5)ccc4N(c4c(-c5ccccc5)cccc4-c4ccccc4)c4cc(C5C[C@H]6CC[C@@H]5C6)cc(c42)N3c2c(-c3ccccc3)cccc2-c2ccccc2)cc1]

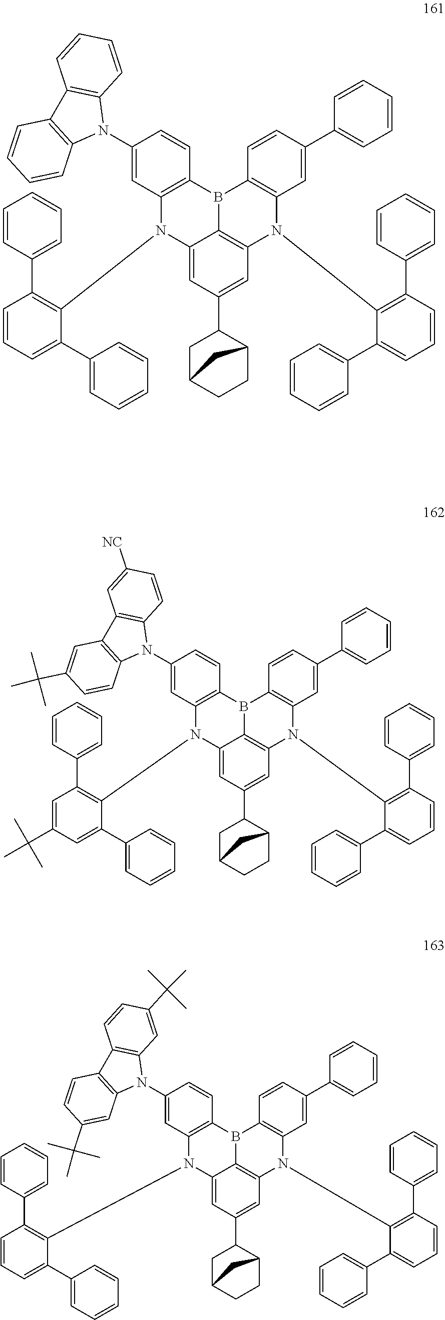 [SMILES: c1ccc(-c2ccc3c(c2)N(c2c(-c4ccccc4)cccc2-c2ccccc2)c2cc(C4C[C@H]5CC[C@@H]4C5)cc4c2B3c2ccc(-n3c5ccccc5c5ccccc53)cc2N4c2c(-c3ccccc3)cccc2-c2ccccc2)cc1 ; CC(C)(C)c1cc(-c2ccccc2)c(N2c3cc(-n4c5ccc(C#N)cc5c5cc(C(C)(C)C)ccc54)ccc3B3c4ccc(-c5ccccc5)cc4N(c4c(-c5ccccc5)cccc4-c4ccccc4)c4cc(C5C[C@H]6CC[C@@H]5C6)cc2c43)c(-c2ccccc2)c1 ; CC(C)(C)c1ccc2c3ccc(C(C)(C)C)cc3n(-c3ccc4c(c3)N(c3c(-c5ccccc5)cccc3-c3ccccc3)c3cc(C5C[C@H]6CC[C@@H]5C6)cc5c3B4c3ccc(-c4ccccc4)cc3N5c3c(-c4ccccc4)cccc3-c3ccccc3)c2c1]

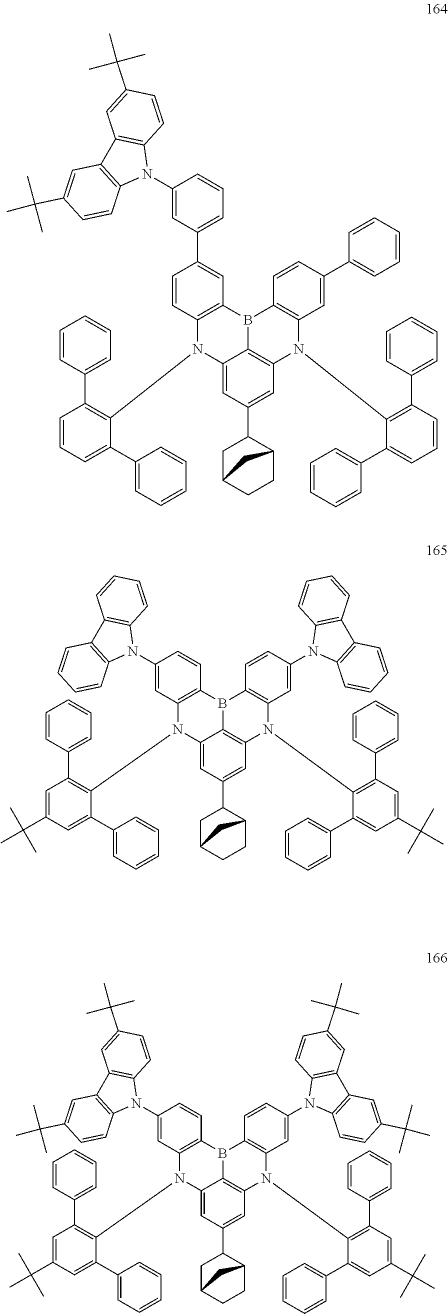

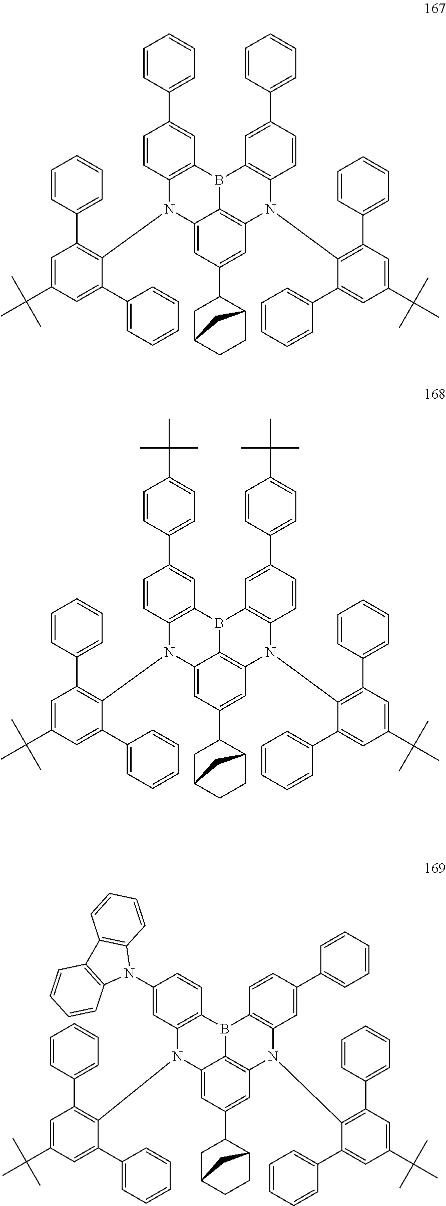

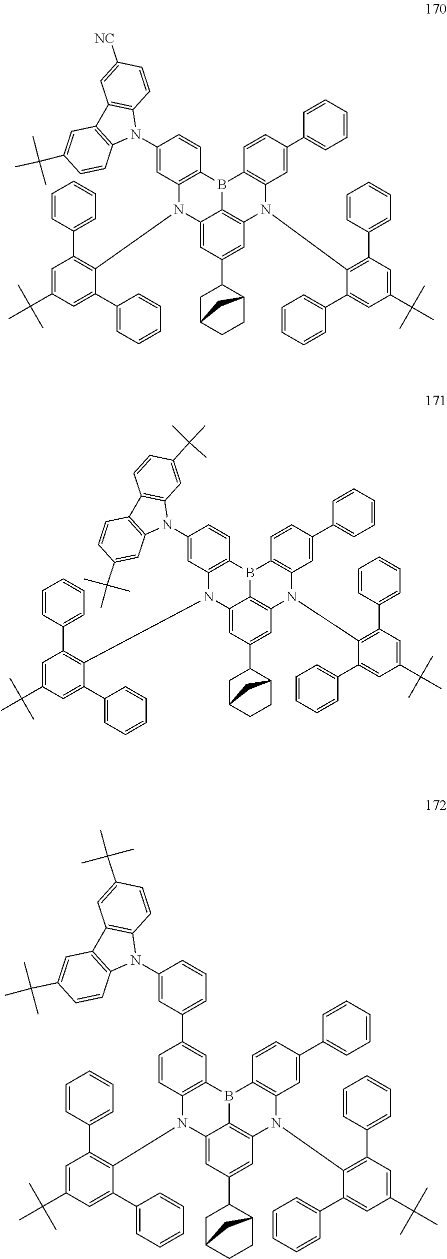

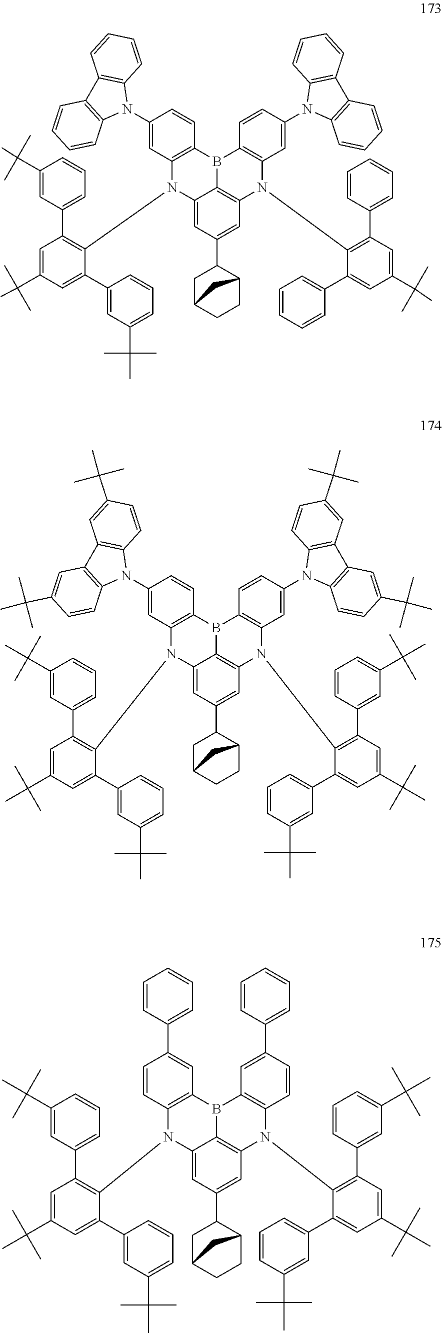

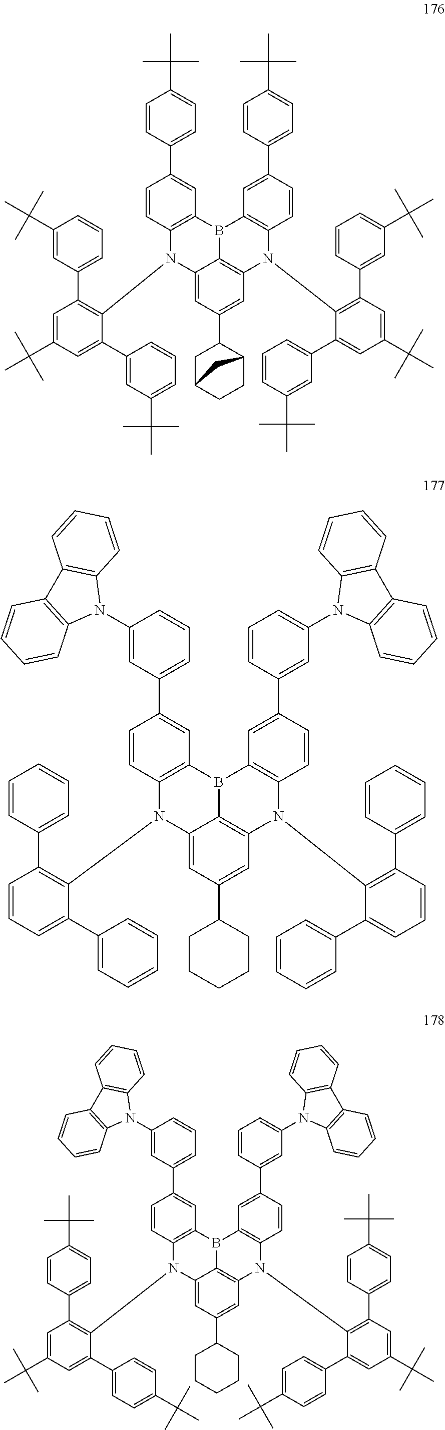

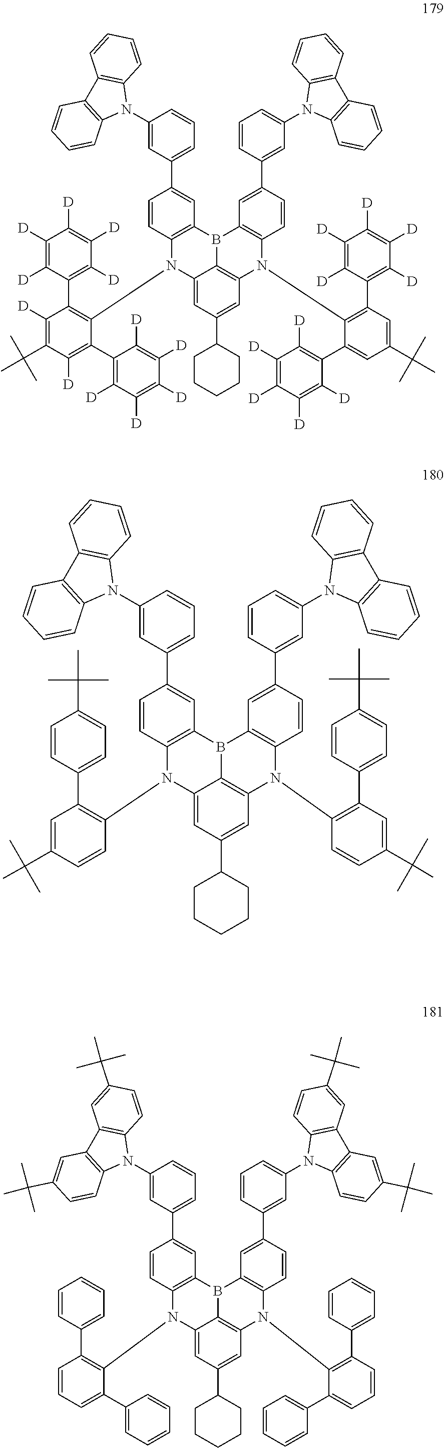

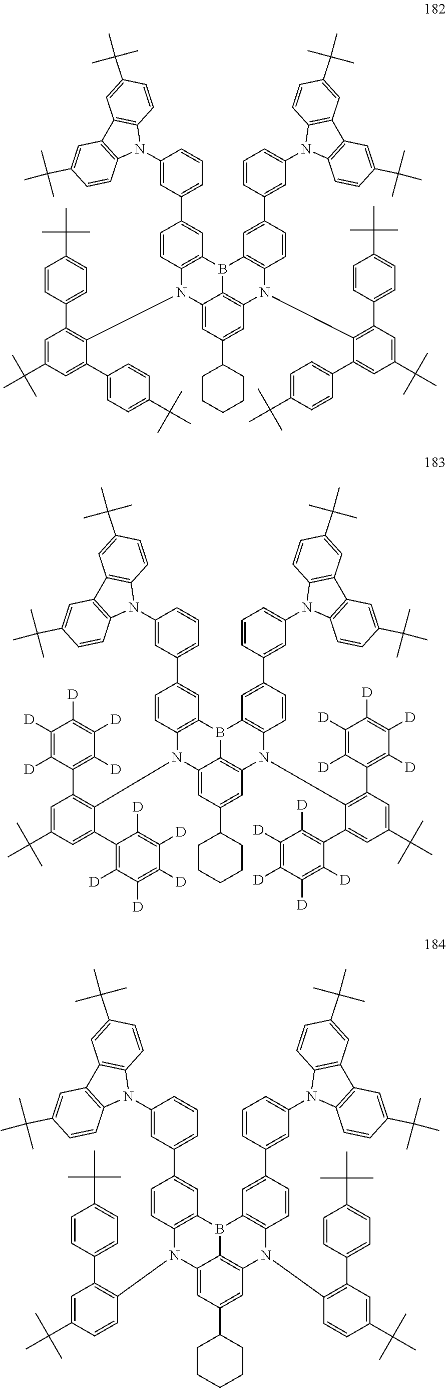

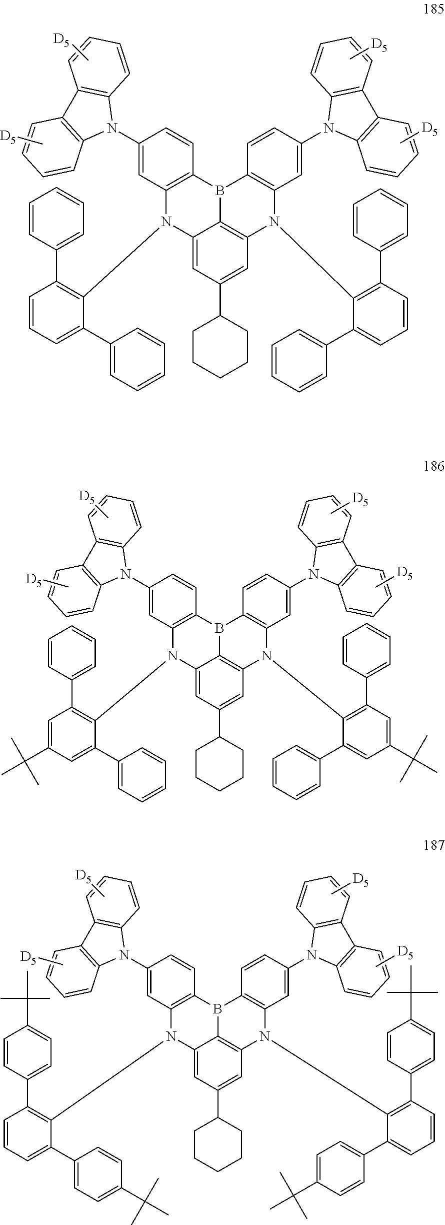

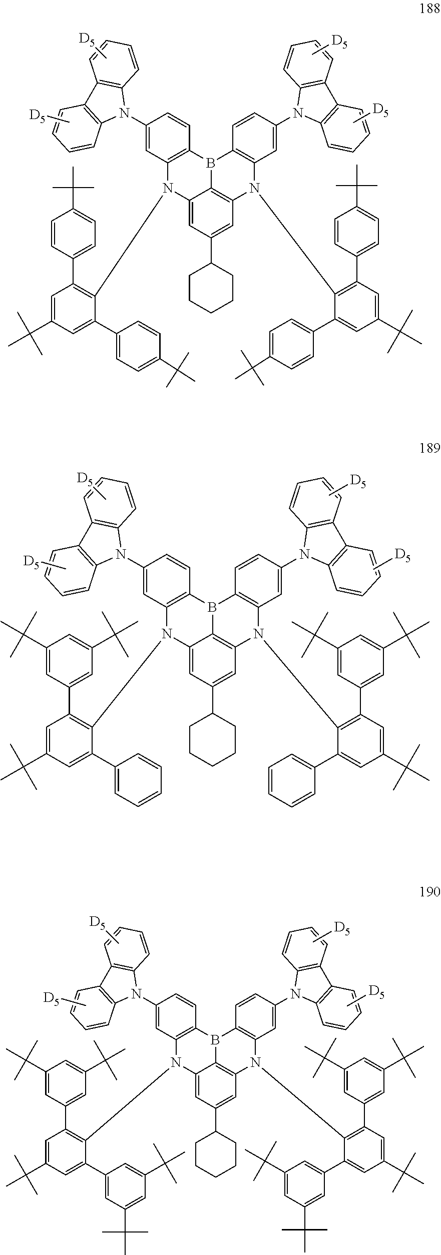

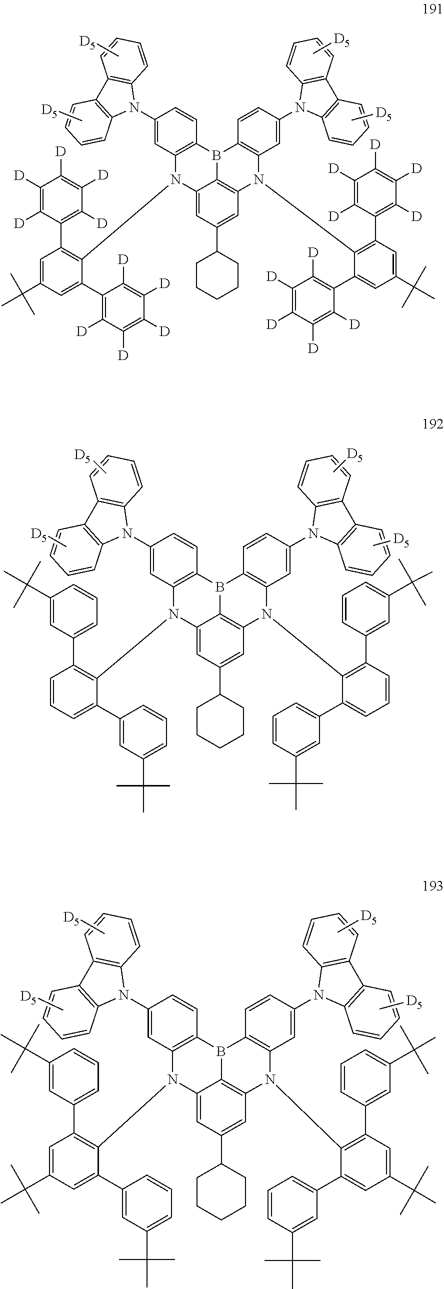

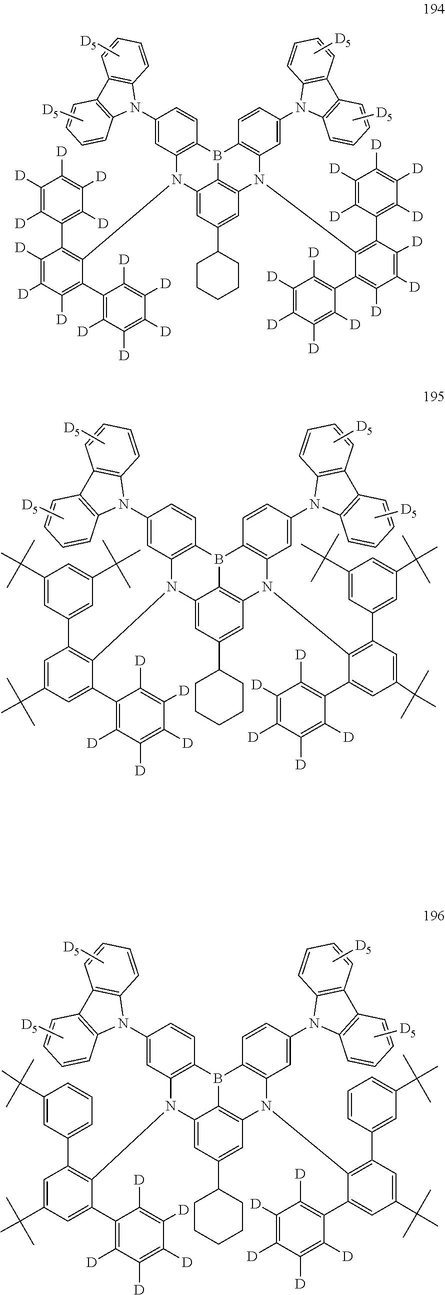

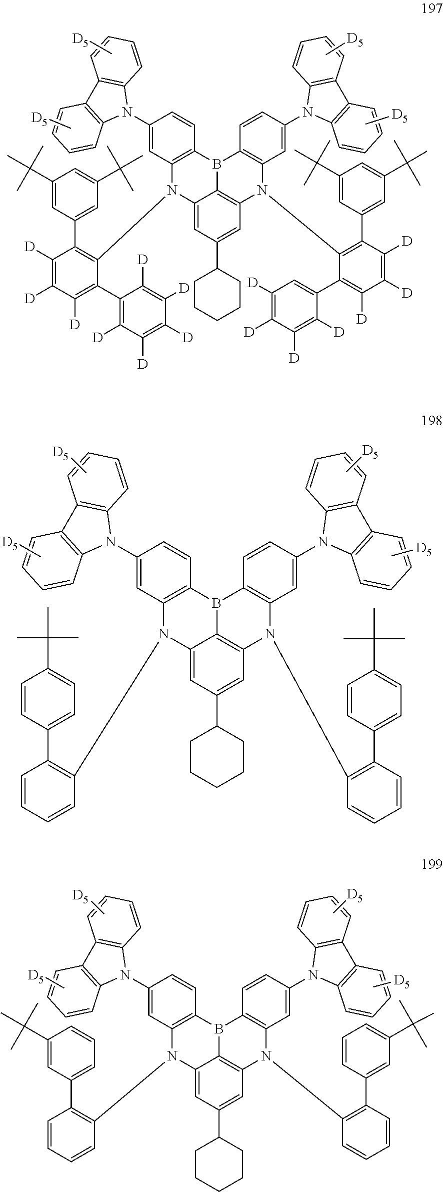

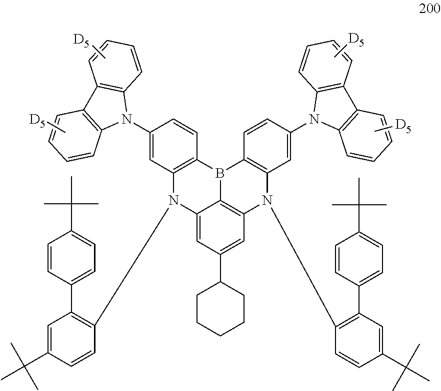

In Compound Group 1, D represents a deuterium atom.

The fused polycyclic compound represented by Formula 1 has a structure in which the first substituent, the second substituent, and the third substituent are bonded to the fused ring core, and thus may cause a blue shift of the luminescence wavelength, and at the same time may achieve high luminous efficiency and a long service life.

The fused polycyclic compound represented by Formula 1 may have a structure that includes the fused ring core in which the first to third aromatic rings are fused via the boron atom and the first and second nitrogen atoms, and in which the first substituent is bonded to the third aromatic ring. The first substituent may be bonded to the third aromatic ring at a para-position to the boron atom. The fused polycyclic compound may further include the second substituent and the third substituent which are respectively bonded to the first nitrogen atom and the second nitrogen atom.

The fused polycyclic compound having such a structure may effectively maintain a trigonal planar structure of the boron atom through a steric hindrance effect by the first substituent to the third substituent. The boron atom may have electron deficiency characteristics of a vacant p-orbital, thereby forming a bond with other nucleophiles, and thus be changed into a tetrahedral structure, which may cause deterioration of the device. The fused polycyclic compound according to an embodiment includes the first substituent to the third substituent bonded to the fused ring core, and may thereby effectively protect the vacant p-orbital of the boron atom, and thus may prevent deterioration due to structural change.

The fused polycyclic compound may have increased luminous efficiency by suppression of intermolecular interactions through steric hindrance effects of the first to third substituent, thereby controlling the formation of aggregates, excimers, or exciplexes. The fused polycyclic compound represented by Formula 1 has a bulky structure, and thus intermolecular distance may be increased to reduce Dexter energy transfer. Dexter energy transfer is a phenomenon in which a triplet exciton moves between molecules, and increases when intermolecular distance is short, and may thus become a factor that increases a quenching phenomenon due to an increase of triplet concentration. The fused polycyclic compound has increased distance between adjacent molecules due to the bulky structure to thereby suppress Dexter energy transfer, and thus may suppress the deterioration of service life due to the increase of triplet concentration. Therefore, when the fused polycyclic compound according to an embodiment is applied to the emission layer EML of the light emitting device ED, luminous efficiency may be increased and device service life may also be improved.

The fused polycyclic compound represented by Formula 1 includes the first substituent bonded to the third aromatic ring. In an embodiment, the first substituent may be a substituted or unsubstituted cycloalkyl group having 6 to 12 ring-forming carbon atoms. The cycloalkyl group has a bulky structure compared to an acyclic alkyl group (for example, compared to a linear or branched alkyl group), and thus may have a large steric hindrance effect when bonded to the fused polycyclic compound. The fused polycyclic compound represented by Formula 1 may control π-conjugation length of the whole molecule by bonding the first substituent at a specific position, and thus the luminescence wavelength may be blue-shifted. In order to achieve a steric hindrance effect, an aryl group having bulkiness similar to the cycloalkyl group may be included in fused polycyclic compound, but there exists a limitation in which conjugation is expanded to the aryl group, so that luminescence wavelength may be red-shifted. According to embodiments, the first substituent of the cycloalkyl group is bonded to a specific position of the fused ring core, and effective conjugation length of the molecule is shortened, and as a result, the luminescence wavelength may be blue-shifted. Accordingly, when the fused polycyclic compound having the first substituent introduced is applied to a light emitting device, blue emission with high color purity may be achieved.

The fused polycyclic compound may be included in the emission layer EML. The fused polycyclic compound may be included as a dopant material in the emission layer EML. The fused polycyclic compound of an embodiment may be a thermally activated delayed fluorescence material. The fused polycyclic compound may be used as a thermally activated delayed fluorescence (TADF) dopant. For example, in the light emitting device ED, the emission layer EML may include, as a thermally activated delayed fluorescence dopant, at least one fused polycyclic compound selected from Compound Group 1 as described above. However, a use of the fused polycyclic compound is not limited thereto.

In an embodiment, the emission layer EML may include multiple compounds. The emission layer EML may include the fused polycyclic compound represented by Formula 1 as a first compound, and the emission layer EML may further include at least one of a second compound represented by Formula HT-1, a third compound represented by Formula ET-1, or a fourth compound represented by Formula D-1, which will each be explained below.

In an embodiment, the emission layer EML may include a second compound represented by Formula HT-1. In an embodiment, the second compound represented by Formula HT-1 may be used as a hole transporting host material of the emission layer EML.

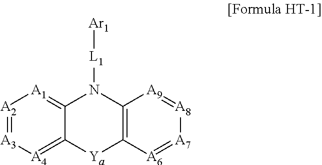

In Formula HT-1, A₁ to A₄ and A₆ to A₉ may each independently be N or C(R₄₁). For example, all of A₁ to A₄ and A₆ to A₉ may each independently be C(R₄₁). As another example, any one of A₁ to A₄ and A₆ to A₉ may be N, and the remainder of A₁ to A₄ and A₆ to A₉ may each independently be C(R₄₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₄₂)(R₄₃), or Si(R₄₄)(R₄₅). For example, the two benzene rings that are linked to the nitrogen atom in Formula HT-1 may be linked to each other via a direct linkage,

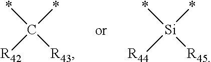

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₄₁ to R₄₅ may each independently be a hydrogen atom or a deuterium atom. As another example, R₄₁ to R₄₅ may each independently be an unsubstituted methyl group or an unsubstituted phenyl group.

In an embodiment, the second compound represented by Formula HT-1 may be selected from Compound Group 2. In an embodiment, in the light emitting device ED, the second compound may include at least one compound selected from Compound Group 2.

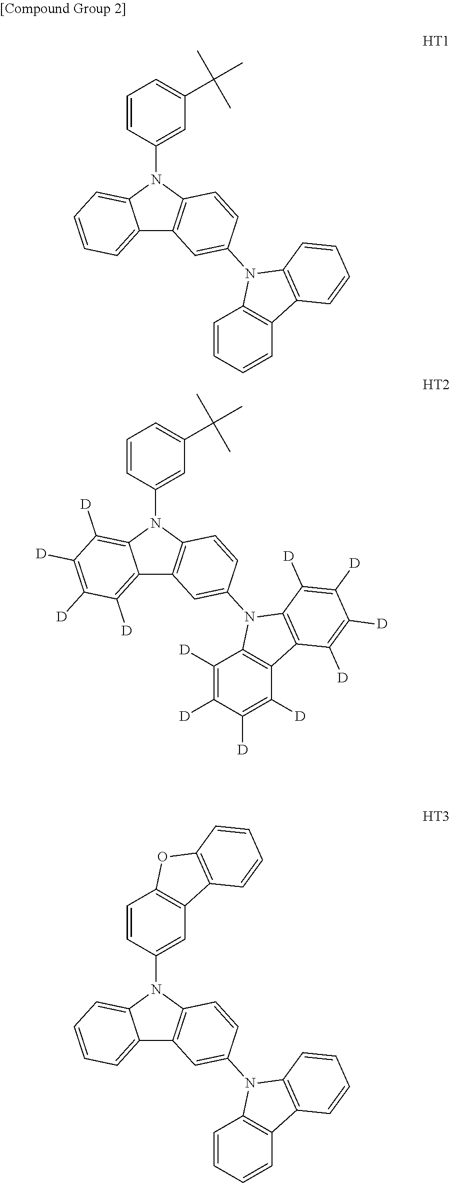

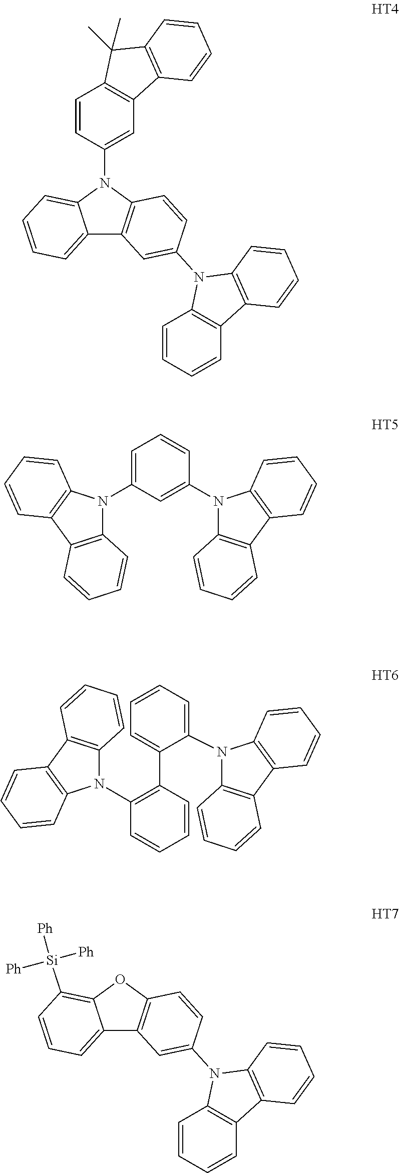 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

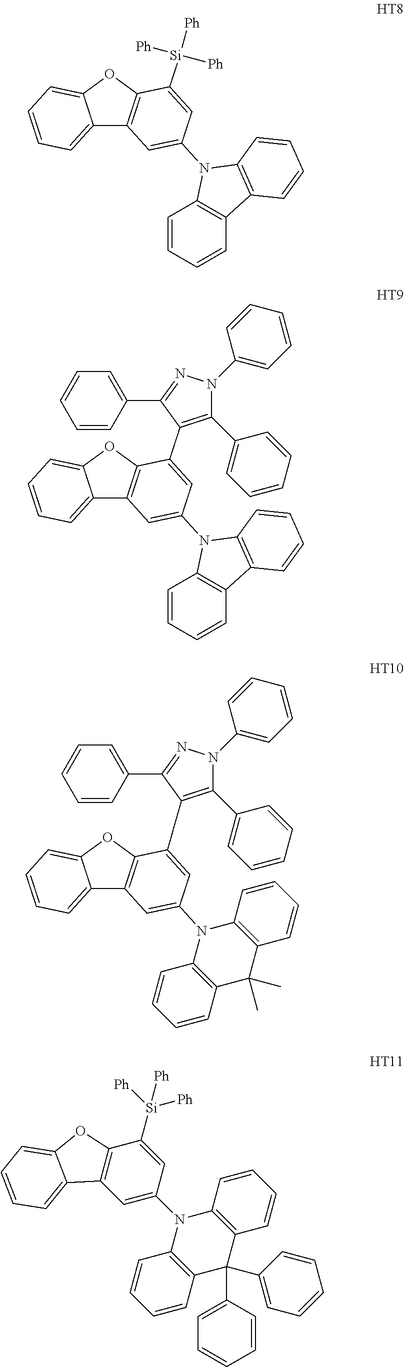 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

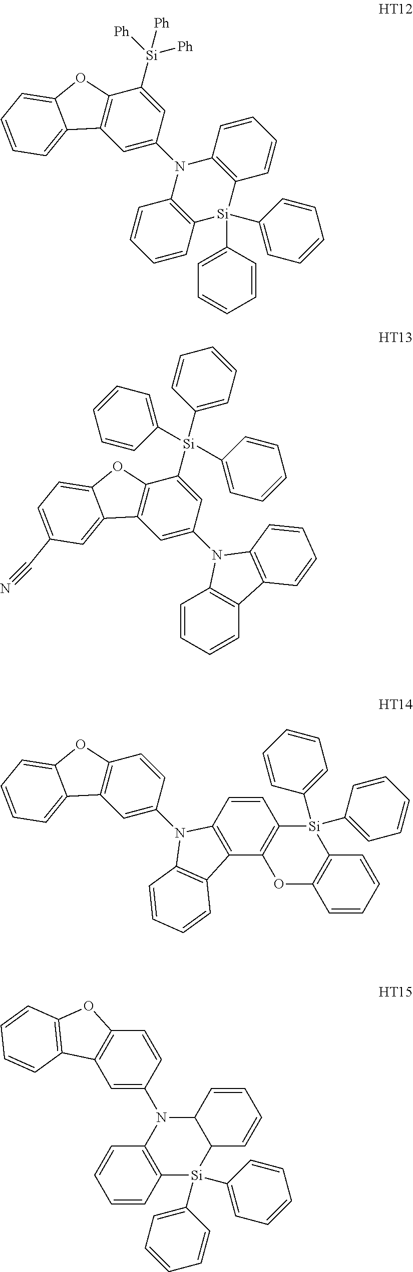

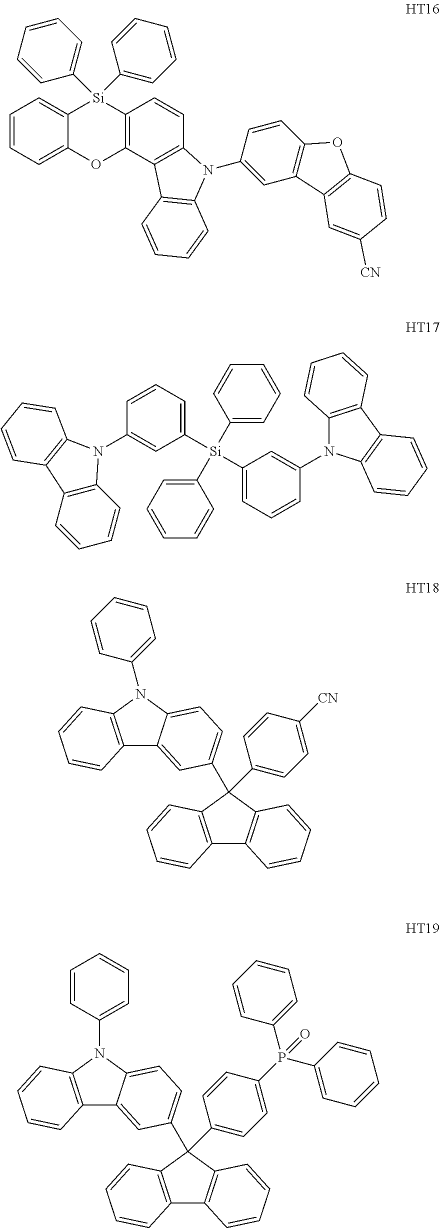 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

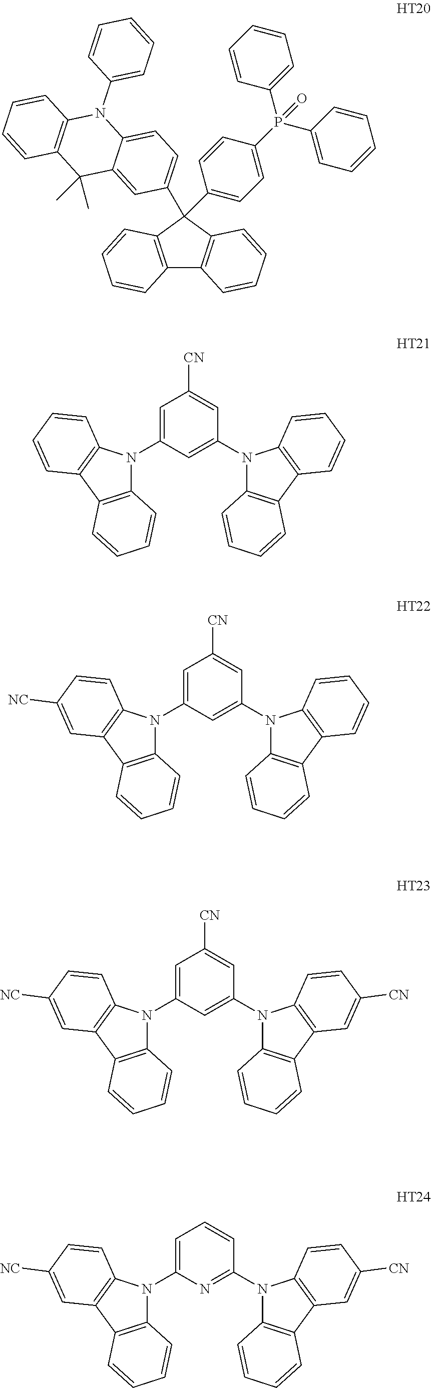 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

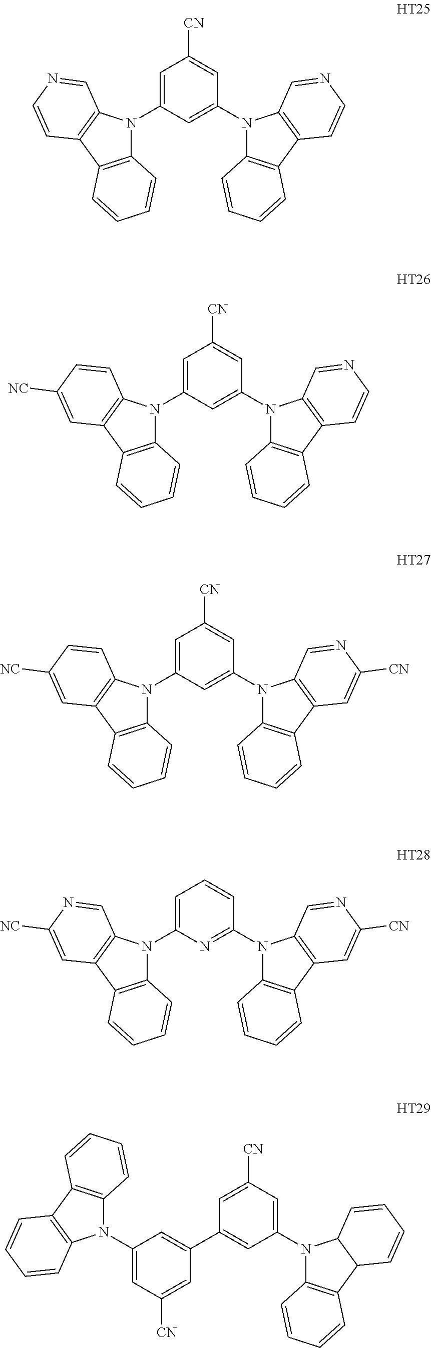 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ccc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(N2c3ccccc3C3C=CC=CC32)c1]

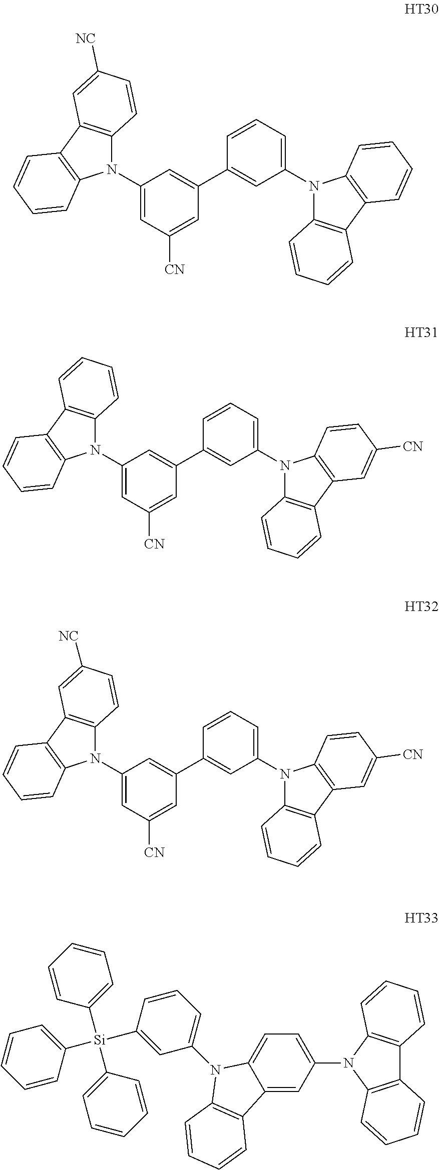 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

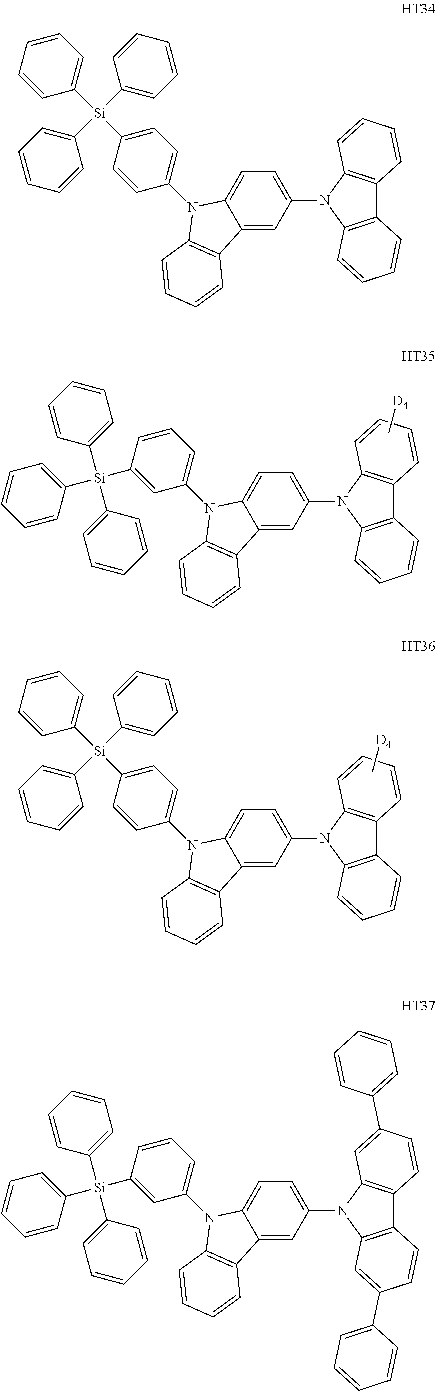

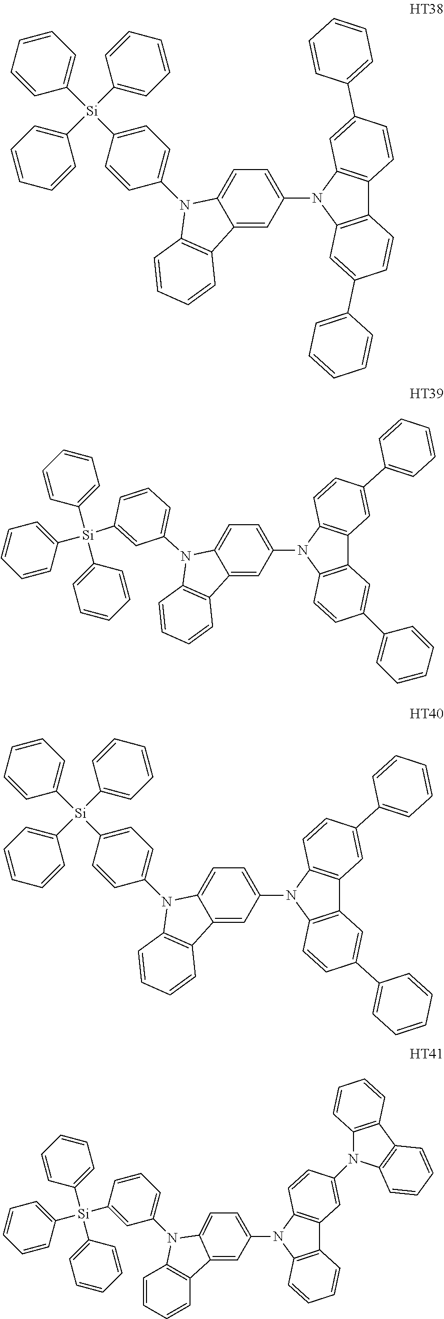 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

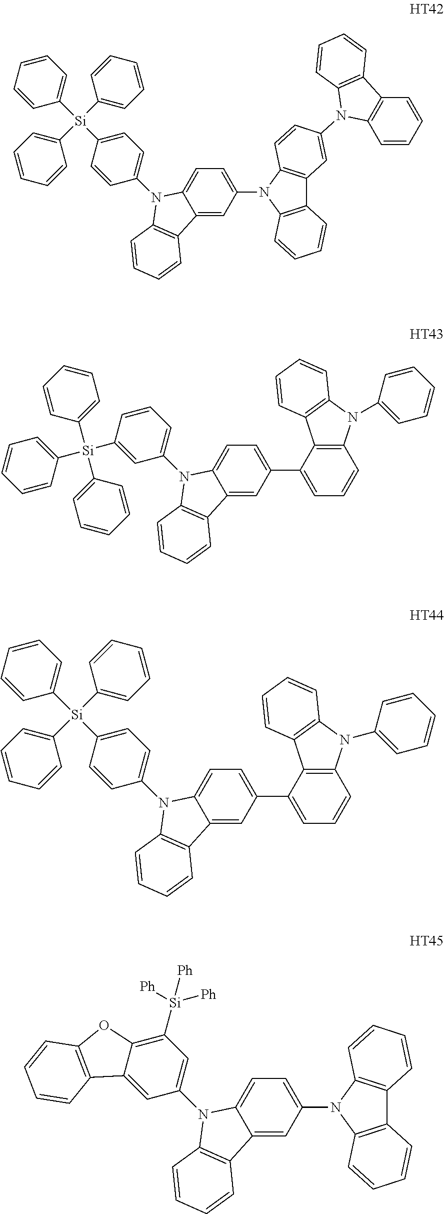 [SMILES: c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1 ; c1ccc([Si](c2ccccc2)(c2ccccc2)c2cc(-n3c4ccccc4c4cc(-n5c6ccccc6c6ccccc65)ccc43)cc3c2oc2ccccc23)cc1]

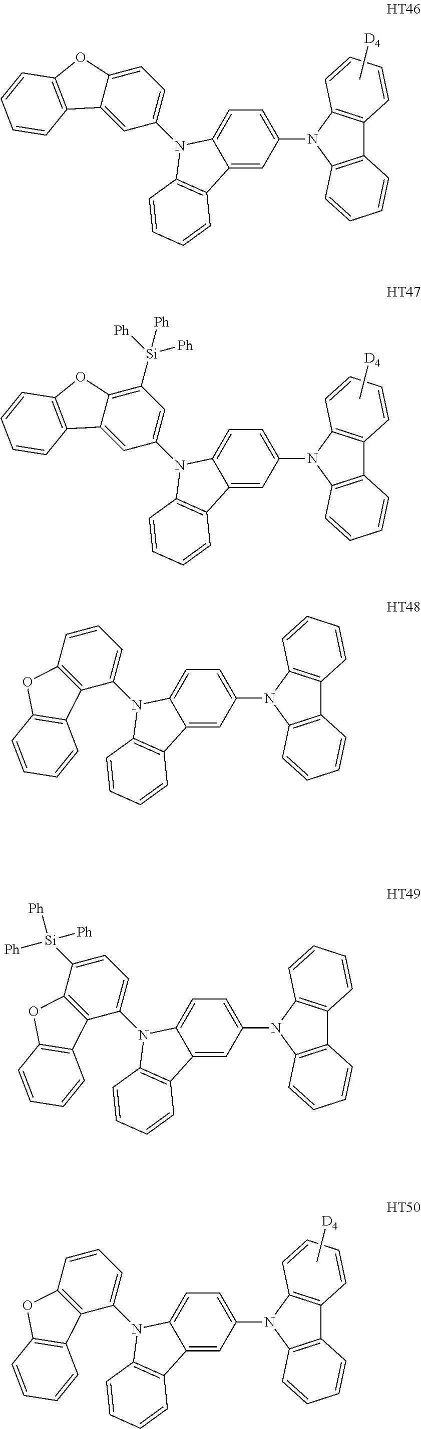

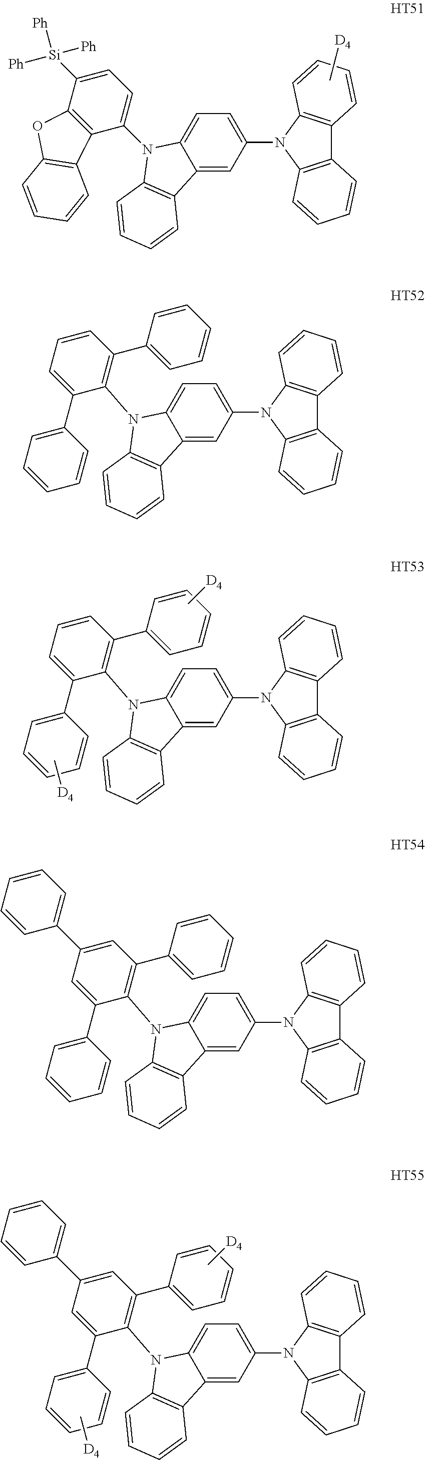

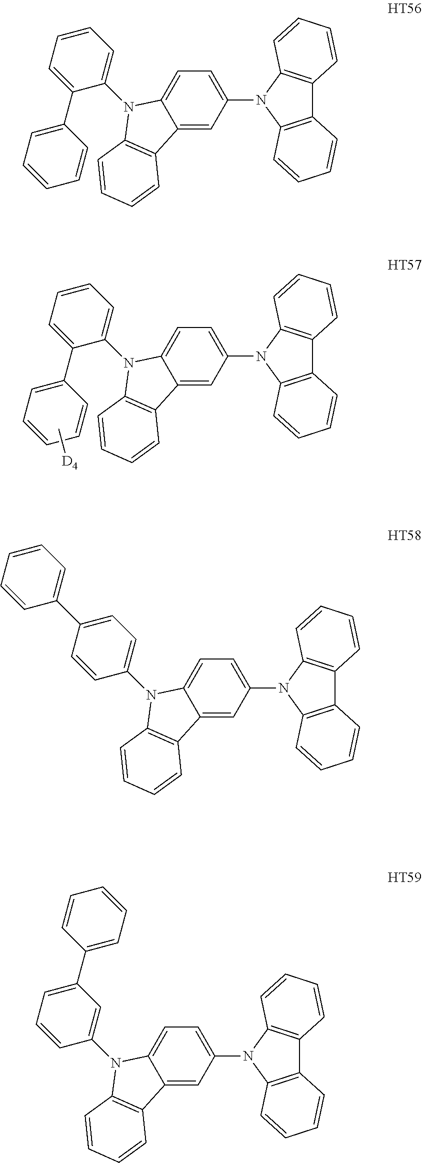

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may include a third compound represented by Formula ET-1. In an embodiment, the third compound represented by Formula ET-1 may be used as an electron transport host material for the emission layer EML.

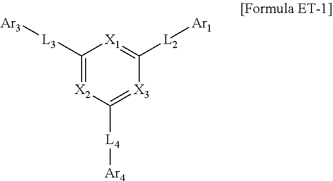

In Formula ET-1, at least one of X₁ to X₃ may be N, and the remainder of X₁ to X₃ may each independently be C(R₄₆). In an embodiment, any one of X₁ to X₃ may be N, and the remainder of X₁ to X₃ may each independently be C(R₄₆). Thus, the third compound represented by Formula ET-1 may include a pyridine moiety. In another embodiment, two of X₁ to X₃ may each be N, and the remainder of X₁ to X₃ may each independently be C(R₄₆). Thus, the third compound represented by Formula ET-1 may include a pyrimidine moiety. In still another embodiment, X₁ to X₃ may each be N. Thus, the third compound represented by Formula ET-1 may include a triazine moiety.

In Formula ET-1, R₄₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, Ar₂ to Ar₄ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

In an embodiment, the third compound represented by Formula ET-1 may be selected from Compound Group 3. In an embodiment, in the light emitting device ED, the third compound may include at least one compound selected from Compound Group 3.

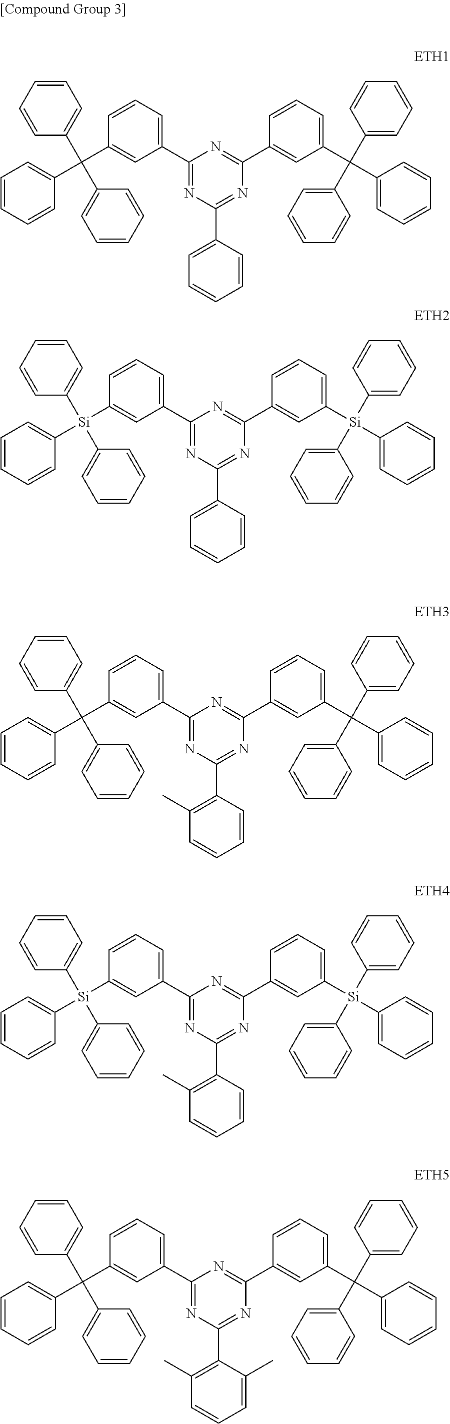

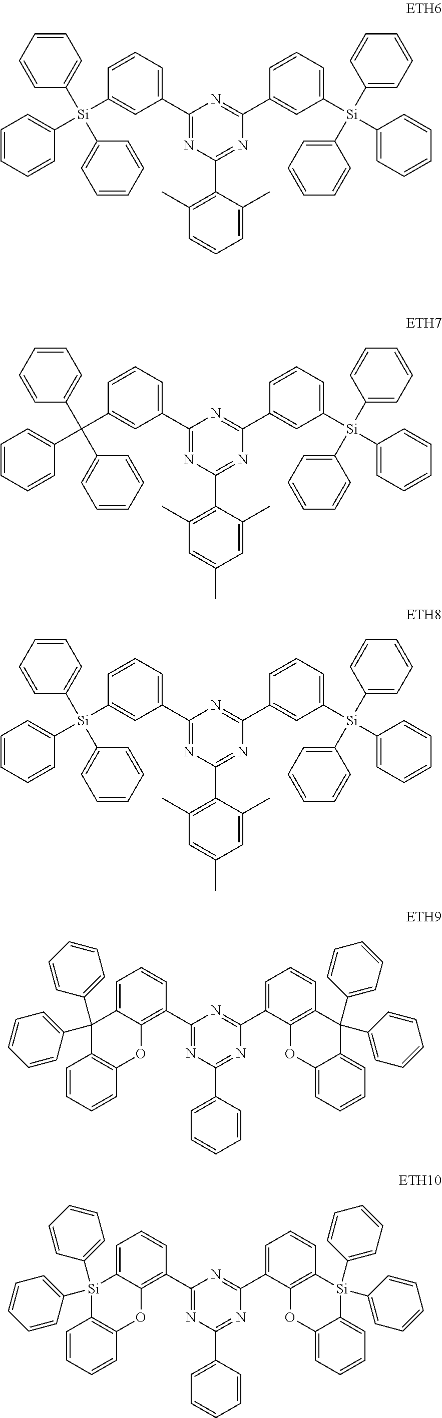

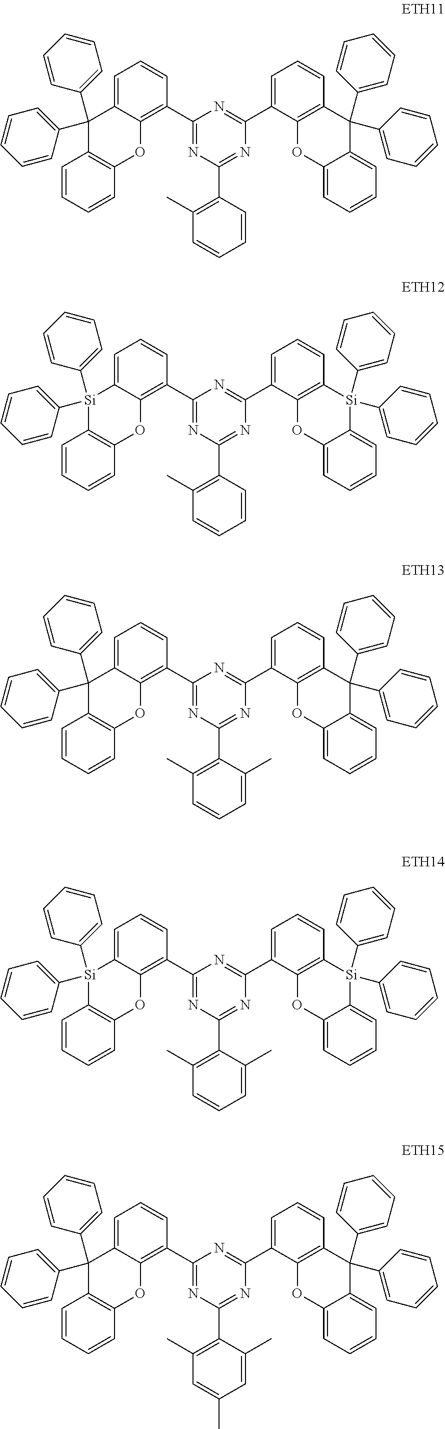

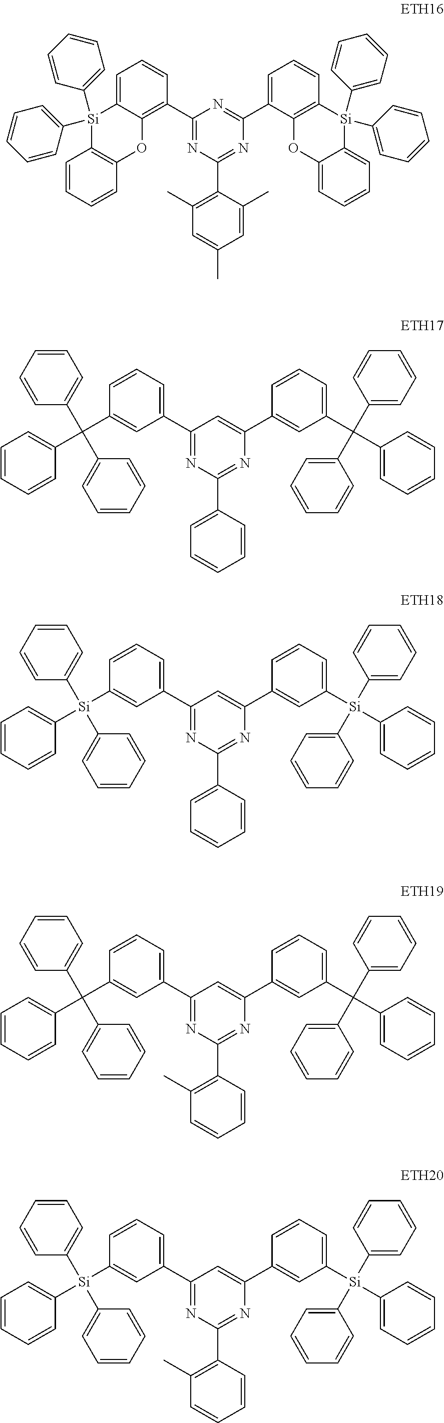

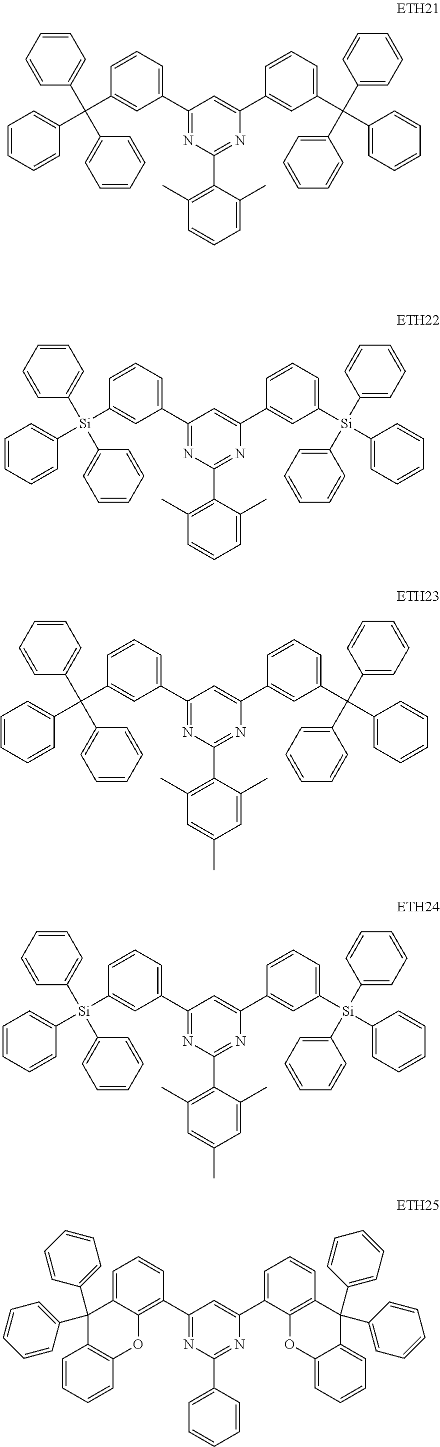

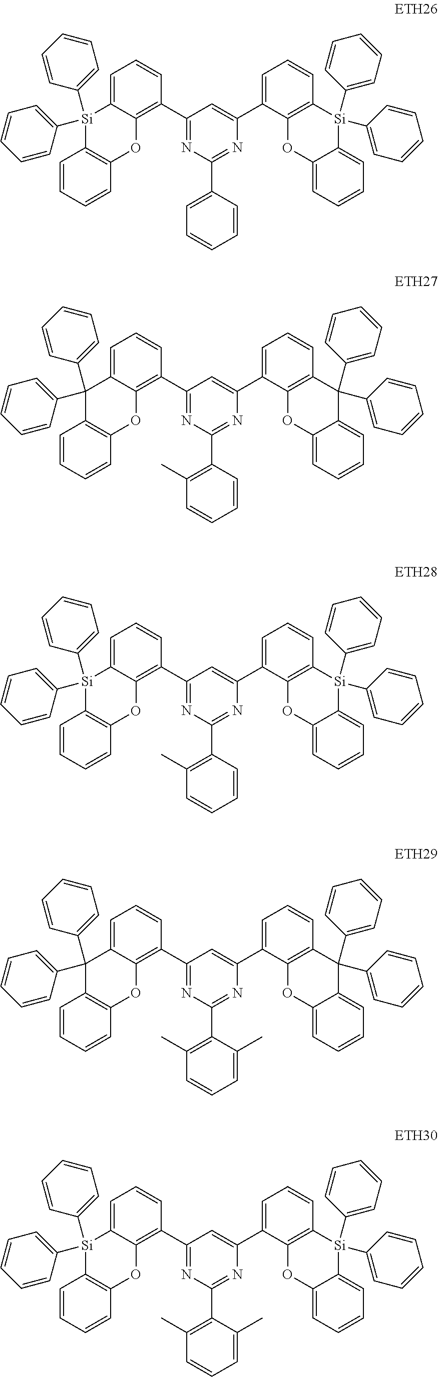

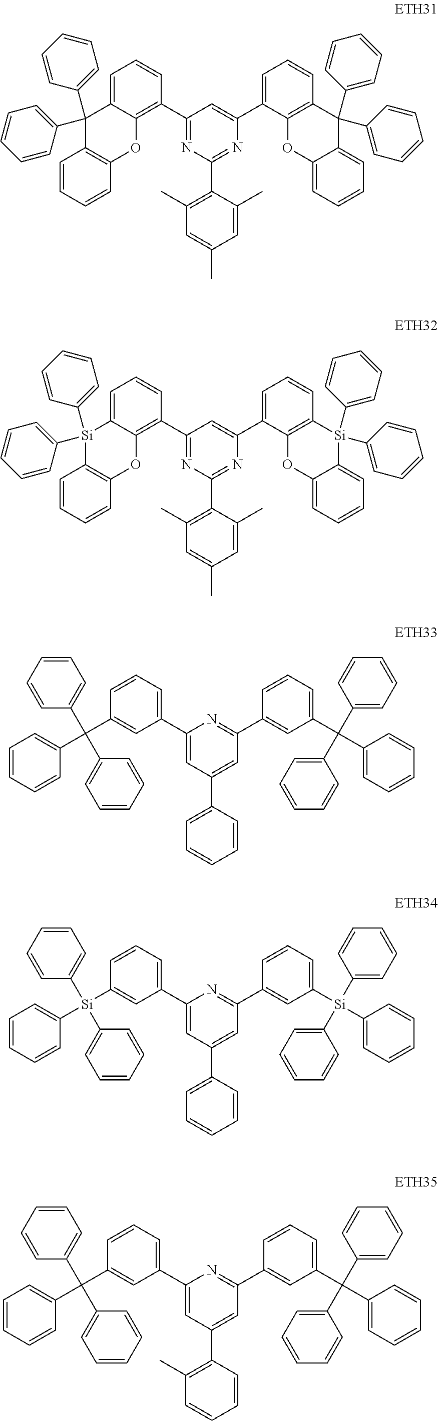

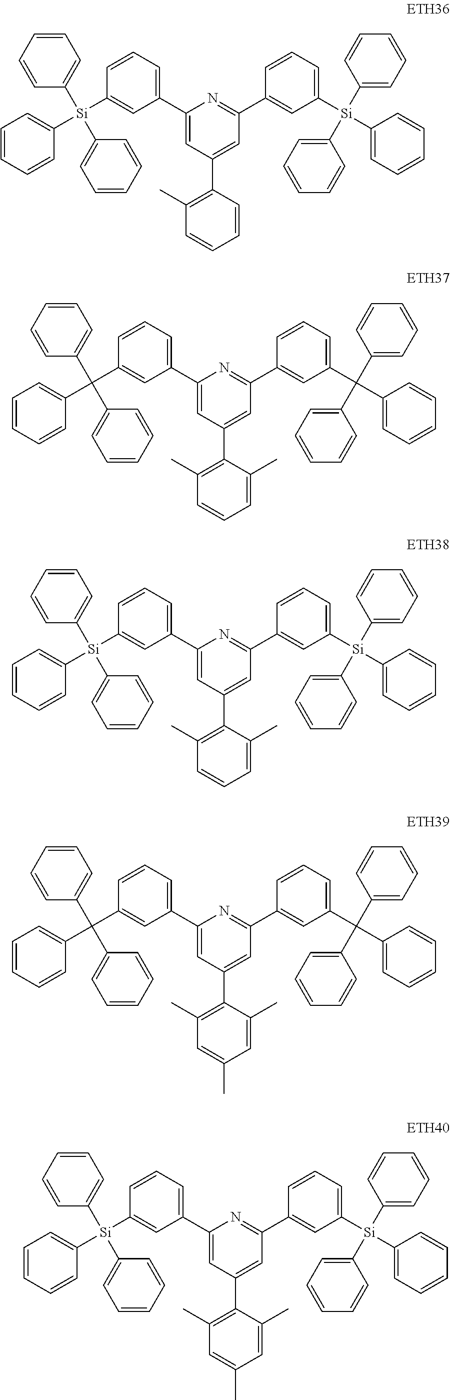

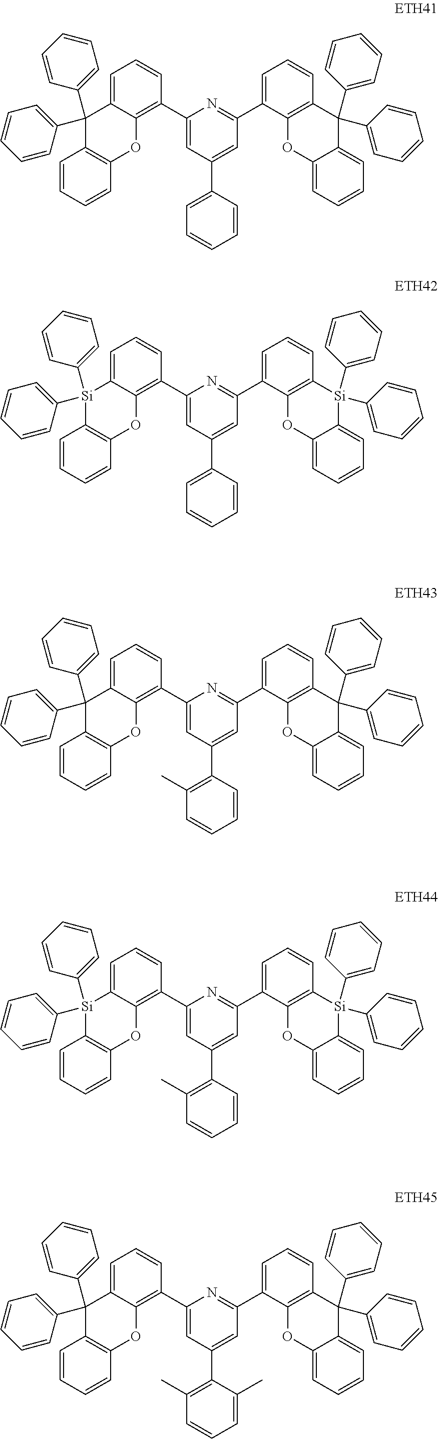

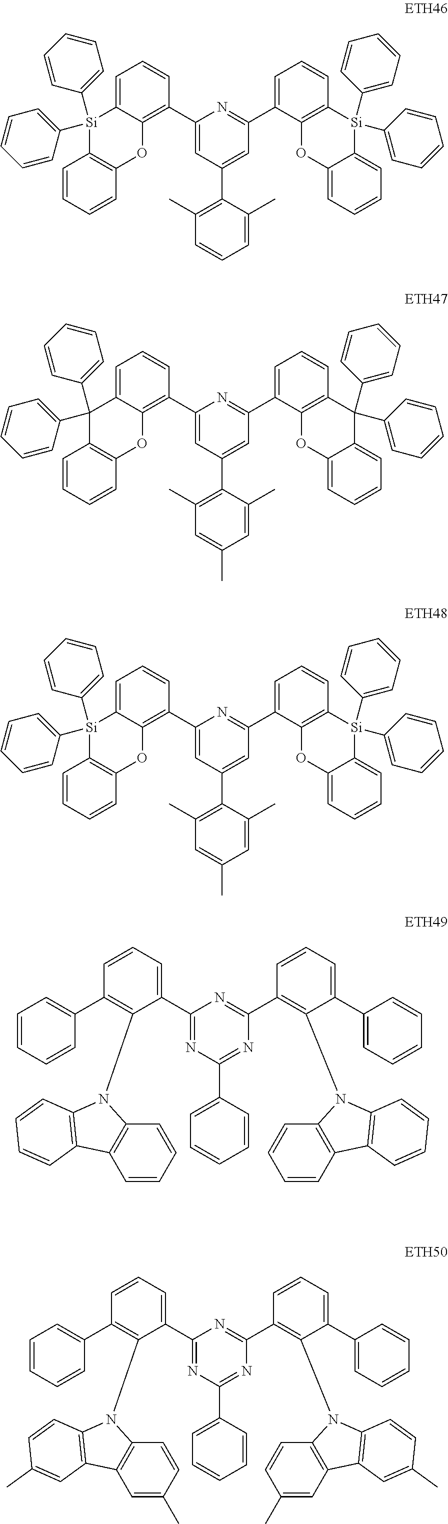

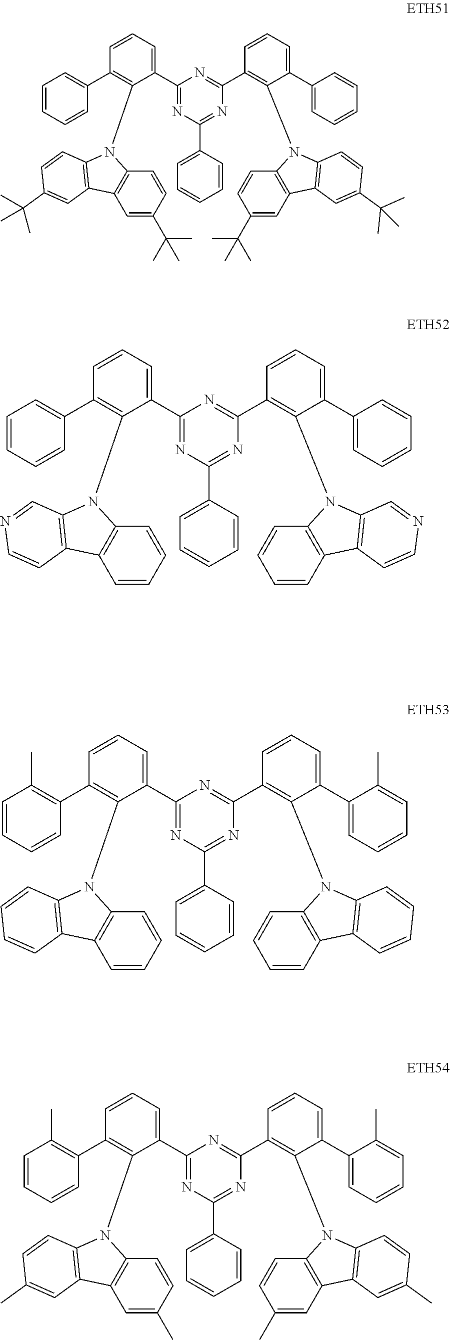

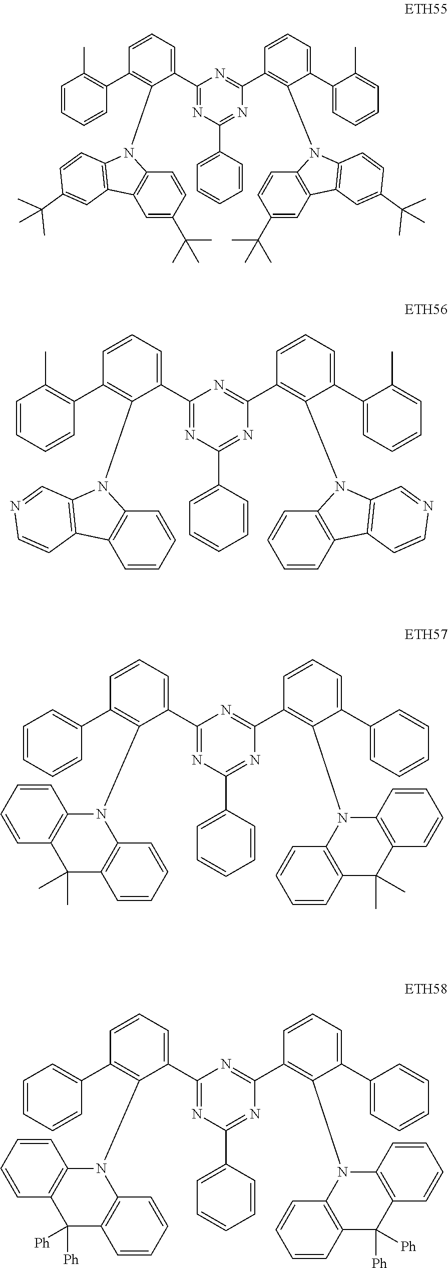

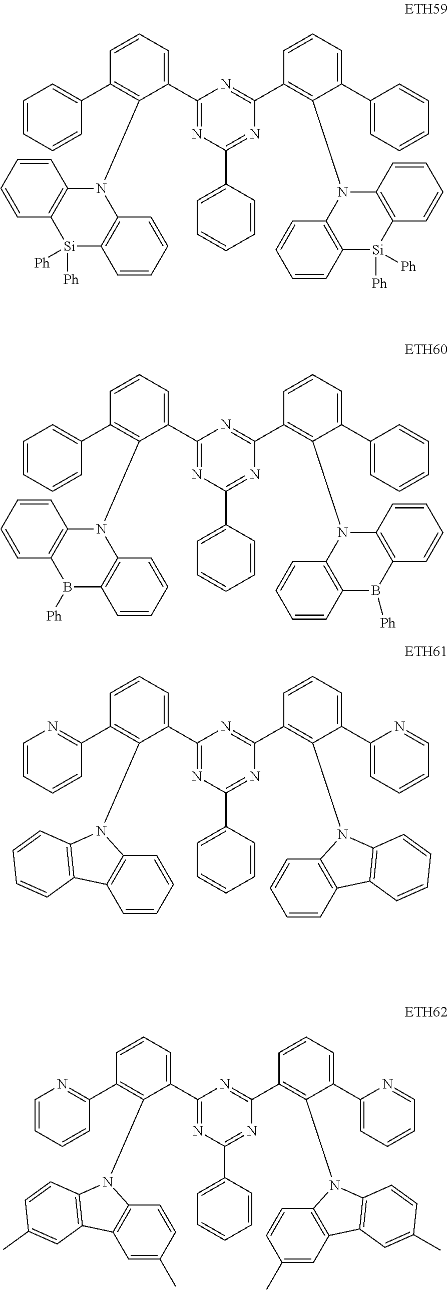

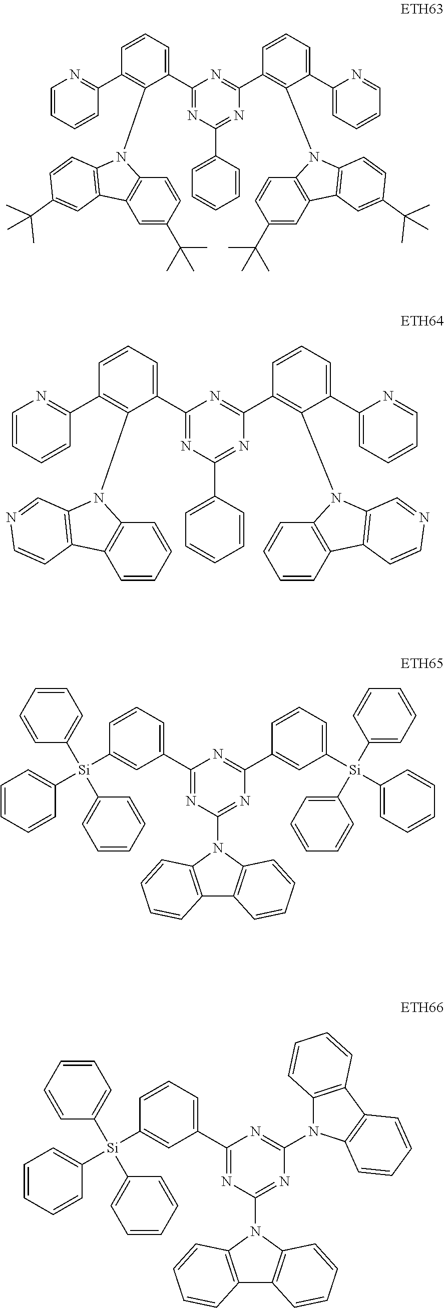 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

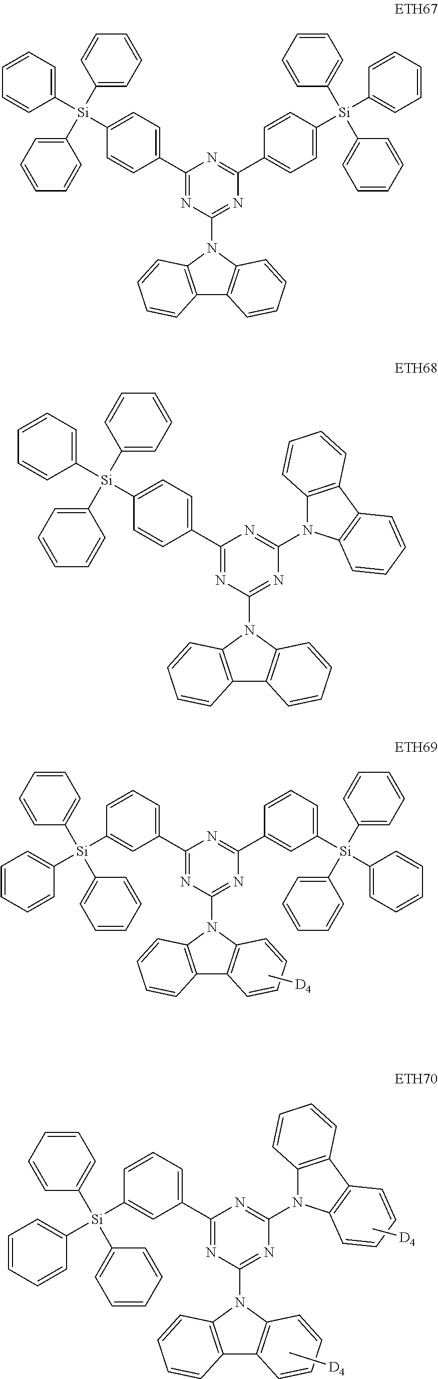

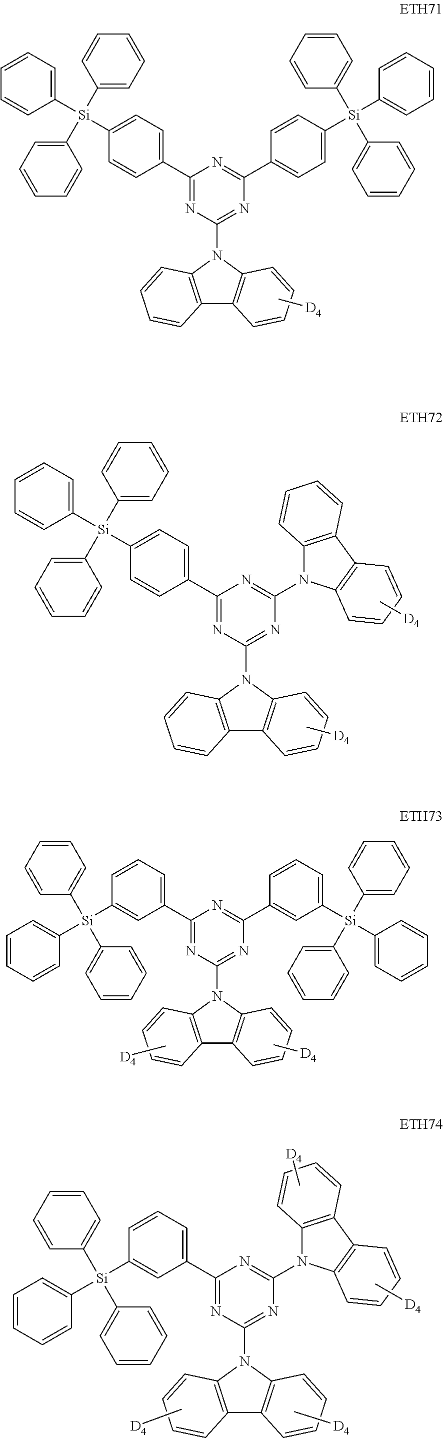

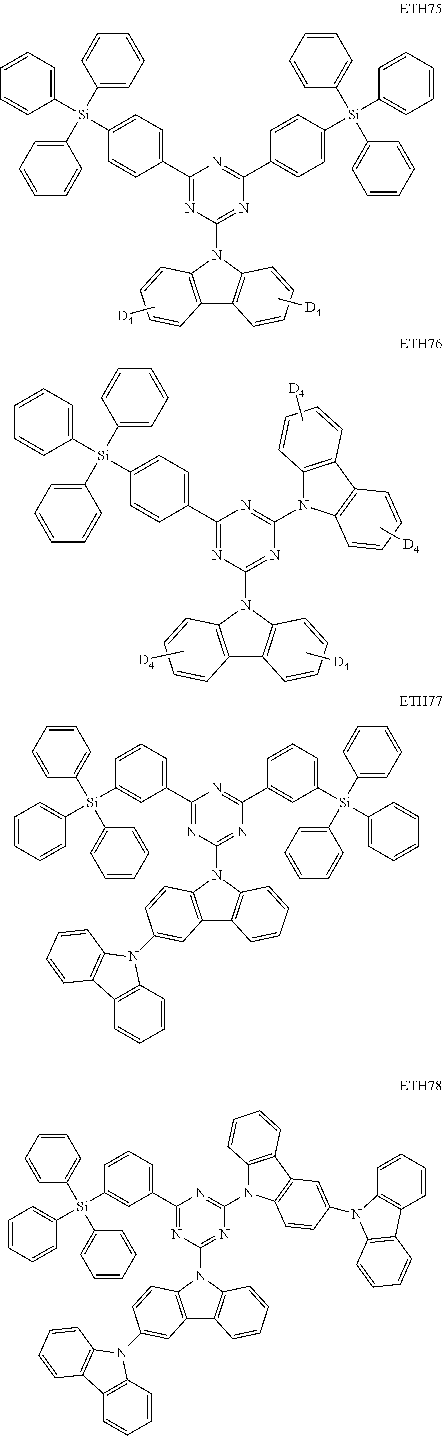

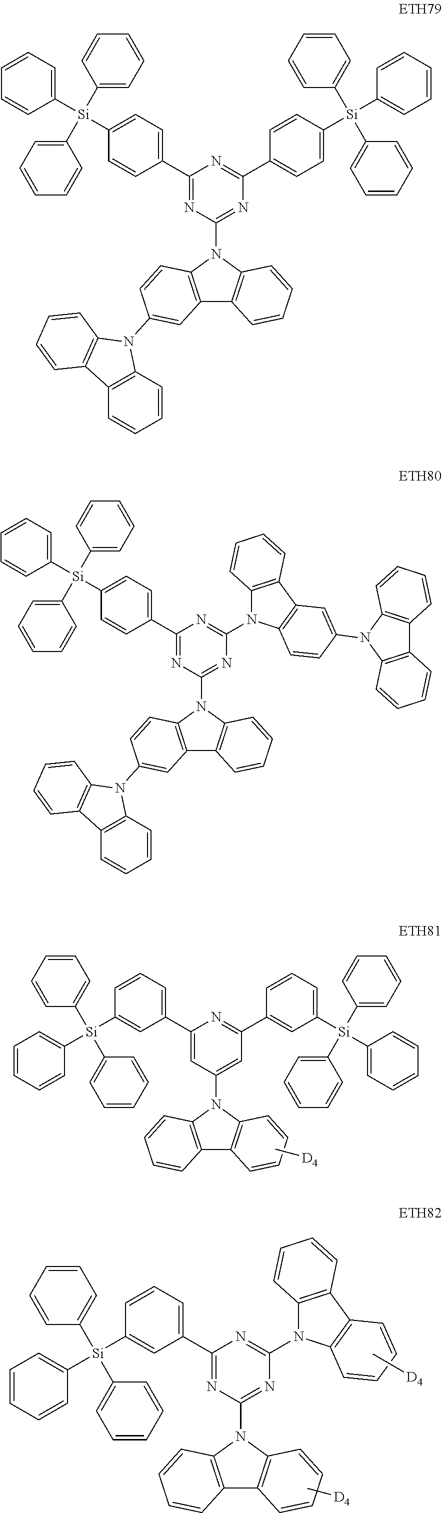

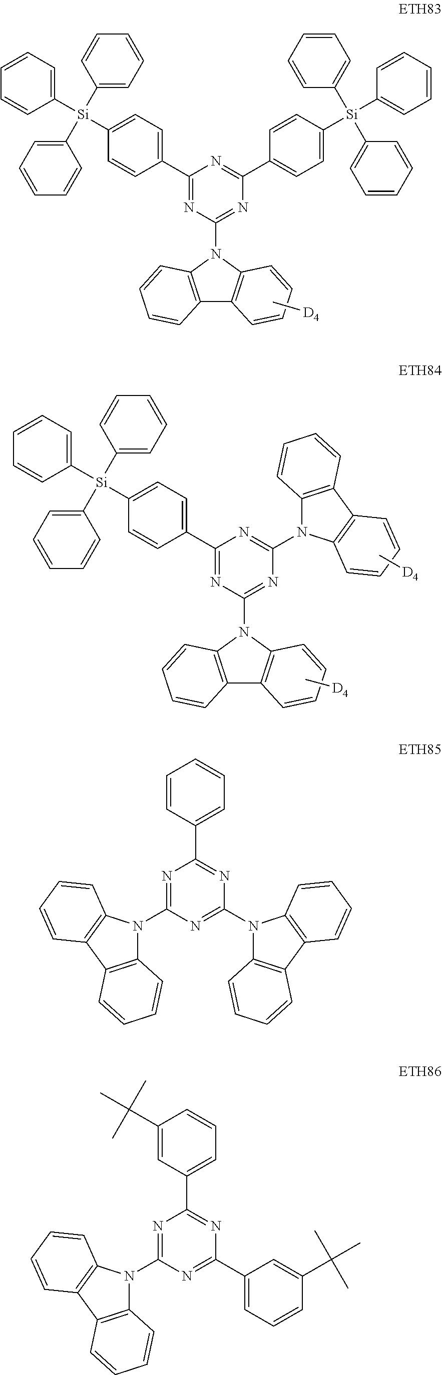

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by a hole transporting host and an electron transporting host may be in a range of about 2.4 eV to about 3.0 eV. A triplet energy level of the exciplex may be a value that is smaller than an energy gap of each host material. The exciplex may have a triplet energy level less than or equal to about 3.0 eV, which is an energy gap between the hole transporting host and the electron transporting host.

In an embodiment, the emission layer EML may include a fourth compound, in addition to the first compound to the third compound. The fourth compound may be used as a phosphorescent sensitizer in an emission layer EML. Energy may be transferred from the fourth compound to the first compound, thereby emitting light.

The emission layer EML may include a fourth compound that is an organometallic complex including platinum (Pt) as a central metal atom and ligands linked to the central metal atom. In an embodiment, the emission layer EML may include a fourth compound represented by Formula D-1.

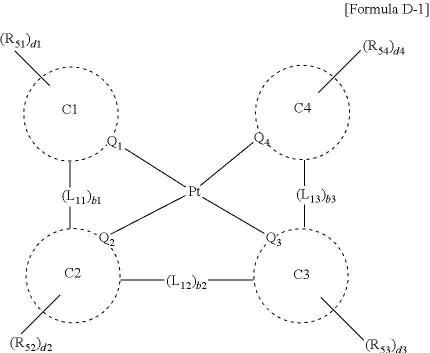

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage,

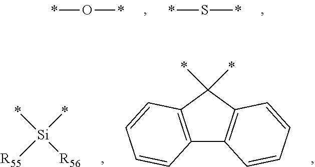

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] represents a bonding site to one of C1 to C4.

In Formula D-1, b1 to b3 may each independently be 0 or 1. If b1 is 0, C1 and C2 may not be linked to each other. If b2 is 0, C2 and C3 may not be linked to each other. If b3 is 0, C3 and C4 may not be linked to each other.

In Formula D-1, R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₅₁ to R₅₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₅₁ to R₅₄. A case where d1 to d4 are each 4 and R₅₁ groups, R₅₂ groups, R₅₃ groups, and R₅₄ groups, are all hydrogen atoms may be the same as a case where d1 to d4 are each 0. If d1 to d4 are each 2 or more, multiple groups of each of R₅₁ to R₅₄ may all be the same, or at least one group thereof may be different from the remainder.

In an embodiment, in Formula D-1, C1 to C4 may each independently be a substituted or unsubstituted hydrocarbon ring or a substituted or unsubstituted heterocycle represented by any one of Formula C-1 to Formula C-4.

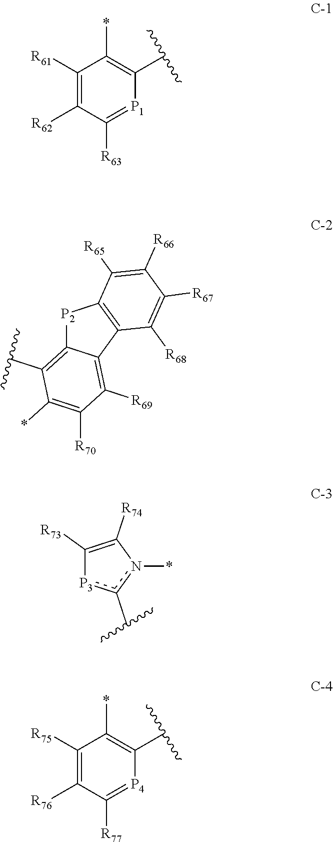

In Formula C-1 to Formula C-4, P₁ may be C—* or C(R₆₄), P₂ may be N—* or N(R₇₁), P₃ may be N—* or N(R₇₂), and P₄ may be C—* or C(R₇₈).

In Formula C-1 to Formula C-4, R₆₁ to R₇₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula C-1 to Formula C-4,

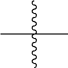

represents a bonding site to Pt that is a central metal atom, and [symbol] represents a bonding site to a neighboring cyclic group (C1 to C4) or to a linker (L₁₁ to L₁₃).

In an embodiment, the emission layer EVIL may include the first compound, which is a fused polycyclic compound, and may further include at least one of the second compound, the third compound, and the fourth compound. For example, the emission layer EVIL may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML of the light emitting device ED may serve as a sensitizer to transfer energy from the host to the first compound, which is a light emitting dopant. For example, the fourth compound, which serves as an auxiliary dopant, accelerates energy transfer to the first compound, which is a light emitting dopant, thereby increasing the emission ratio of the first compound. Therefore, the emission layer EML of an embodiment may improve luminous efficiency. When energy transfer to the first compound is increased, an exciton formed in the emission layer EML may not accumulate inside the emission layer EML and may emit light rapidly, and so that deterioration of the device may be reduced. Therefore, the service life of the light emitting device ED may increase.

The light emitting device ED may include the first compound, the second compound, the third compound, and the fourth compound, and the emission layer EML may include a combination of two host materials and two dopant materials. In the light emitting device ED, the emission layer EML may include the second compound and the third compound, which are two different hosts, the first compound may emit delayed fluorescence, and the fourth compound may include an organometallic complex, thereby exhibiting excellent luminous efficiency characteristics.

In an embodiment, the fourth compound represented by Formula D-1 may be selected from Compound Group 4. In an embodiment, in the light emitting device ED, the fourth compound may include at least one compound selected from Compound Group 4.

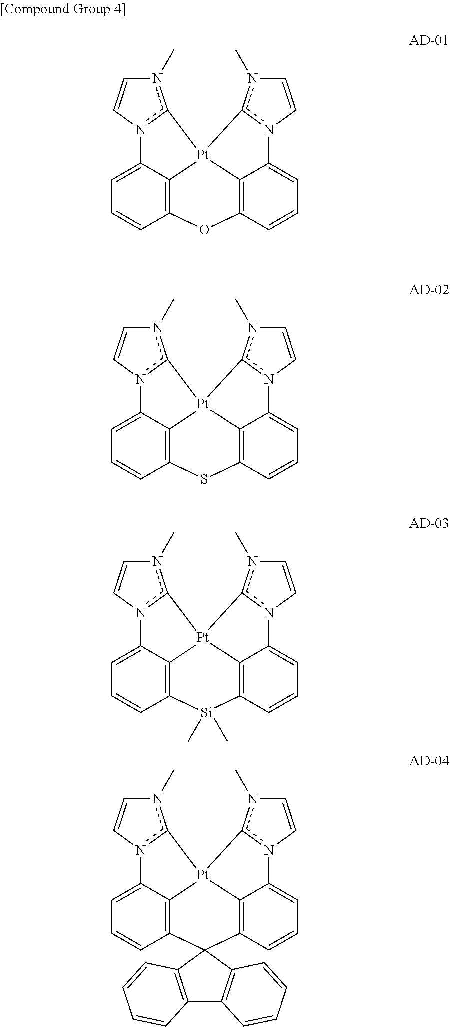

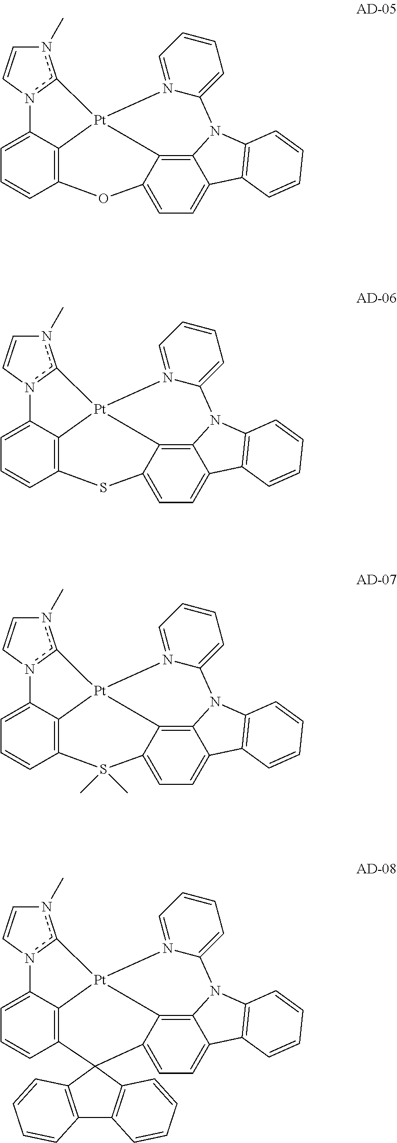

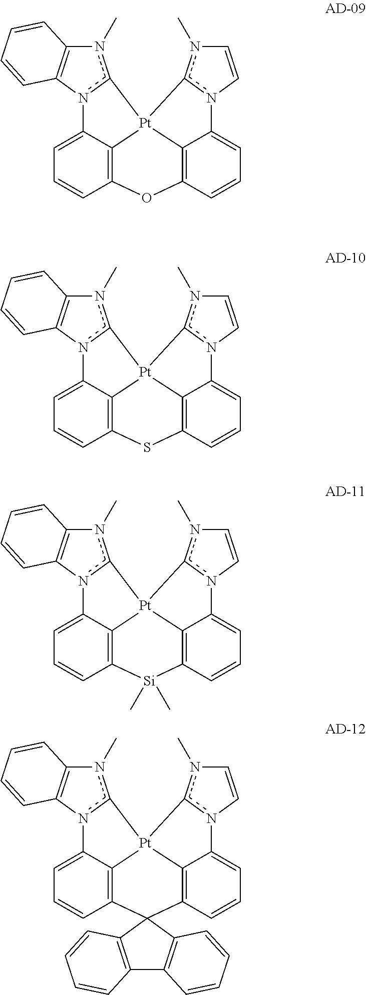

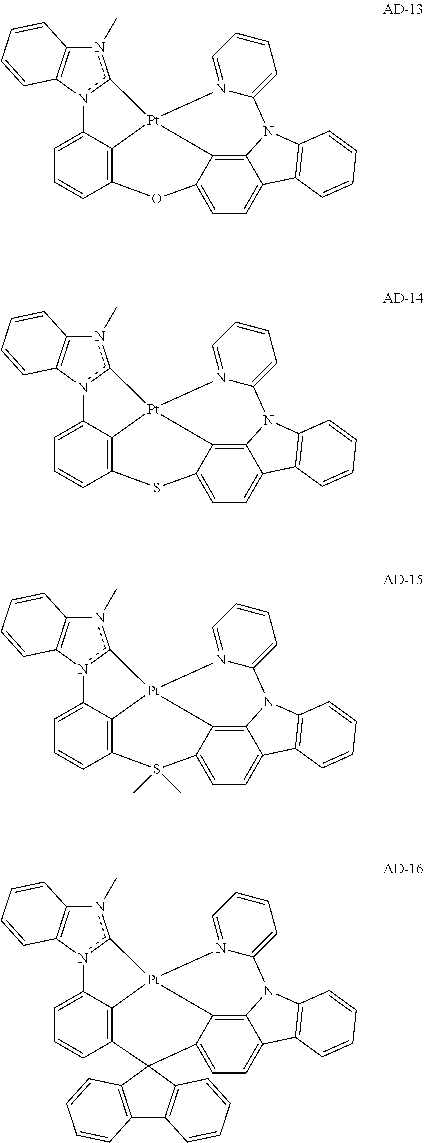

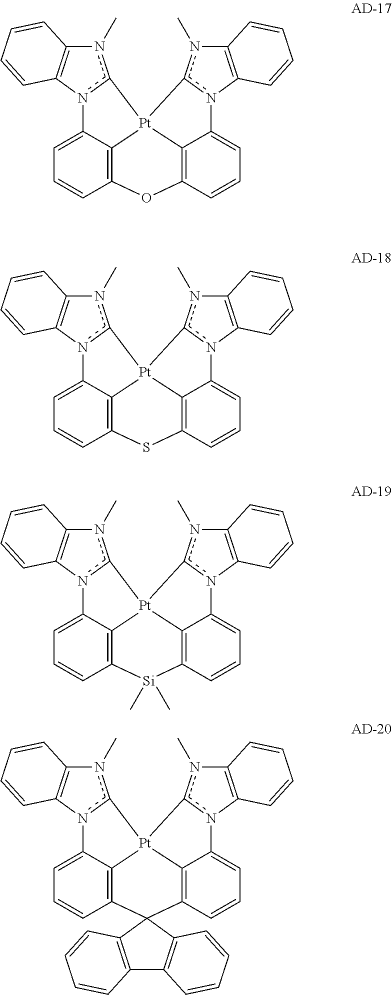

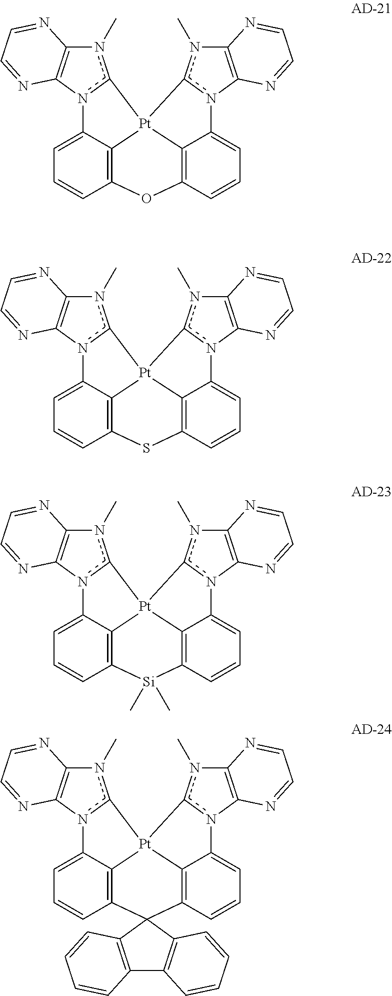

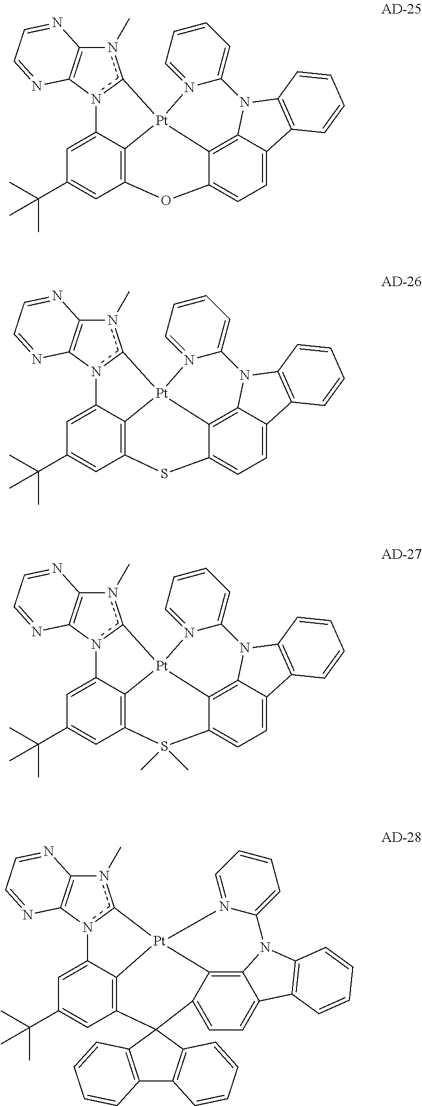

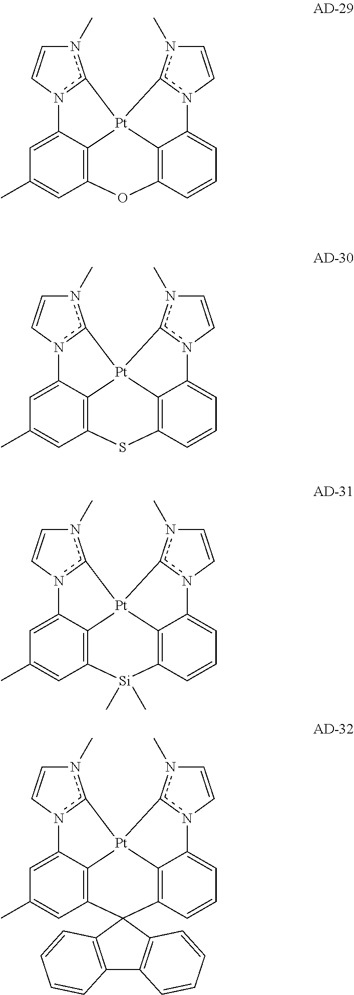

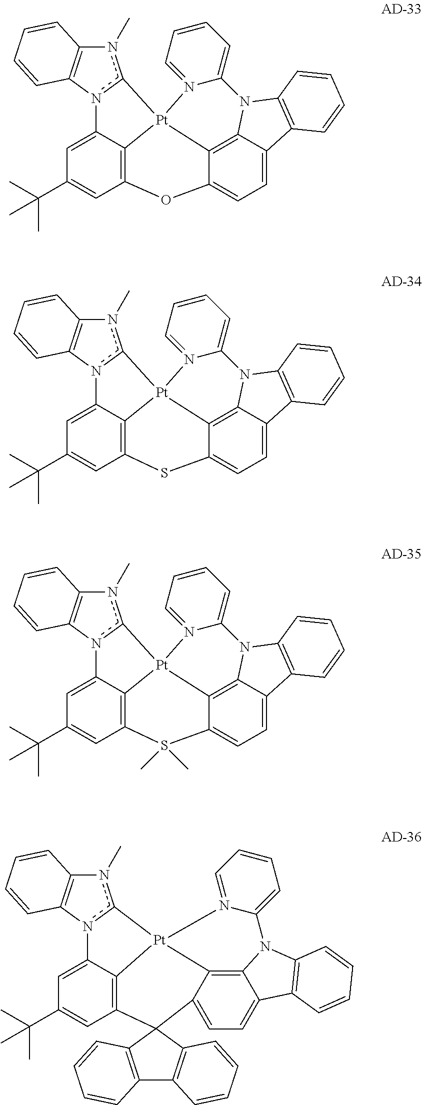

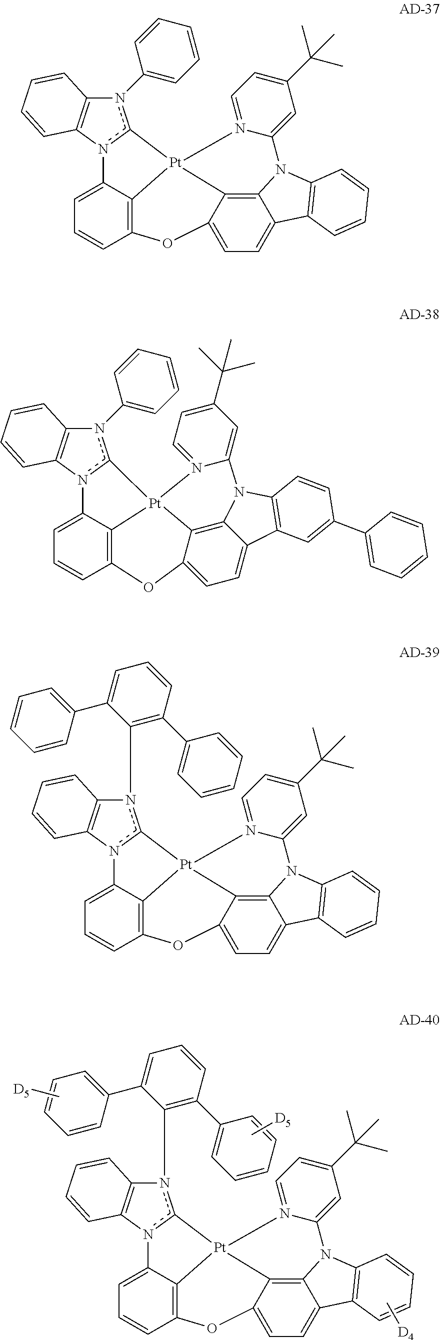

In Compound Group 4, D represents a deuterium atom.

In an embodiment, the light emitting device ED may include multiple emission layers. The emission layers may be provided as a stack of emission layers to emit white light. The light emitting device ED including multiple emission layers may be a light emitting device having a tandem structure. When the light emitting device ED includes multiple emission layers, at least one emission layer EML may include the first compound represented by Formula 1. When the light emitting device ED includes multiple emission layers, at least one emission layer EML may include the first compound, the second compound, the third compound, and the fourth compound as described above.

When the emission layer EML in the light emitting device ED includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the above-described range, energy transfer from the second compound and the third compound to the first compound may increase, and thus, luminous efficiency and device service life may increase.

A total amount of the second compound and the third compound in the emission layer EML may be the remainder of the total weight of the first compound, the second compound, and the third compound, apart from the amount of the first compound. For example, a total amount of the second compound and the third compound in the emission layer EML may be in a range of about 75 wt % to about 95 wt %, with respect to a total weight of the first compound, the second compound, and the third compound.

Within the total amount of the second compound and the third compound in the emission layer EML, a weight ratio of the second compound to the third compound may be in a range of about 3:7 to about 7:3.

When the amounts of the second compound and the third compound satisfy the above-described ranges and ratios, a charge balance characteristic in the emission layer EML may be improved, and thus the luminous efficiency and device service life may increase. When the amounts of the second compound and the third compound deviate from the above-described ranges and ratios, a charge balance in the emission layer EML may not be achieved, and thus the luminous efficiency may be reduced, and the device may deteriorate more readily.

When the emission layer EML includes the fourth compound, an amount of the fourth compound in the emission layer EML may be in a range of about 4 wt % to about 20 wt %, with respect to a total weight of the first compound, the second compound, the third compound, and the fourth compound. However, embodiments are not limited thereto. When an amount of the fourth compound satisfies the above-described range, energy transfer from the host to the first compound, which is a light emitting dopant, may increase, so that a luminous ratio may be improved, and thus, luminous efficiency of the emission layer EML may be improved. When the amounts of the first compound, the second compound, the third compound, and the fourth compound in the emission layer EML satisfy the above-described ranges and ratios, excellent luminous efficiency and long service life may be achieved.

In the light emitting device ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting device ED according to embodiments as shown in each of FIGS. 3 to 6, the emission layer EML may further include a host of the related art and a dopant of the related art, in addition to the above-described host and dopant. For example, the emission layer EML may include a compound represented by Formula E-1. The compound represented by Formula E-1 may be used as a fluorescent host material.

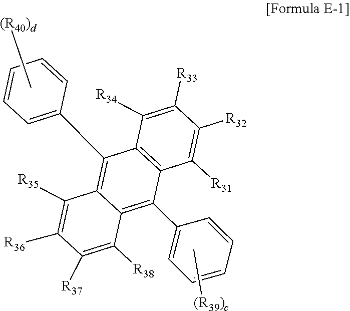

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

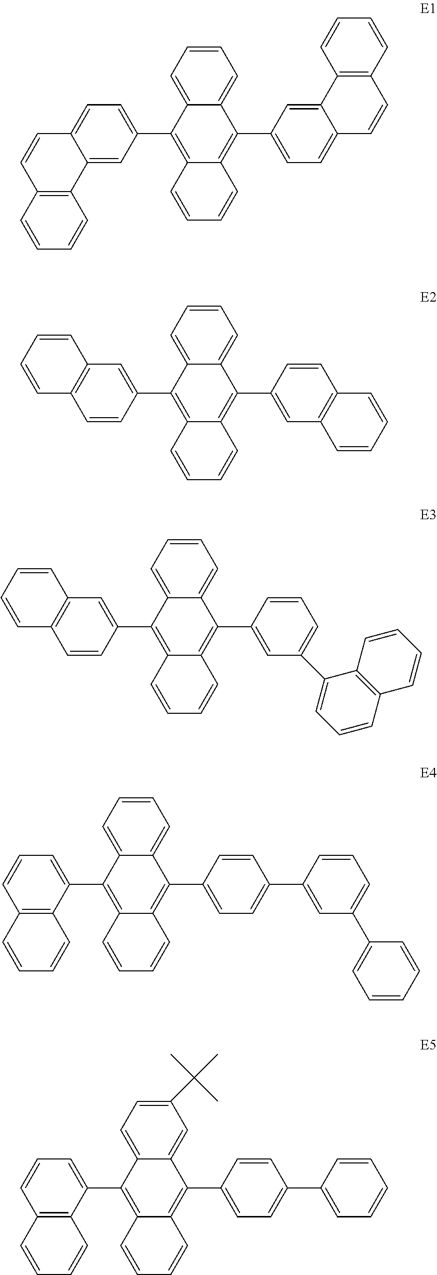

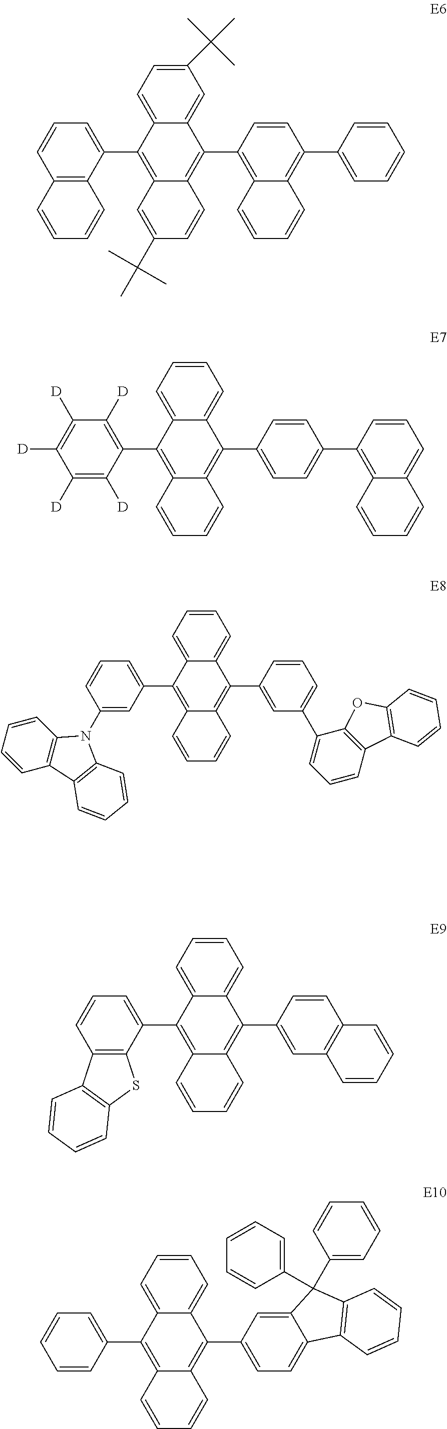

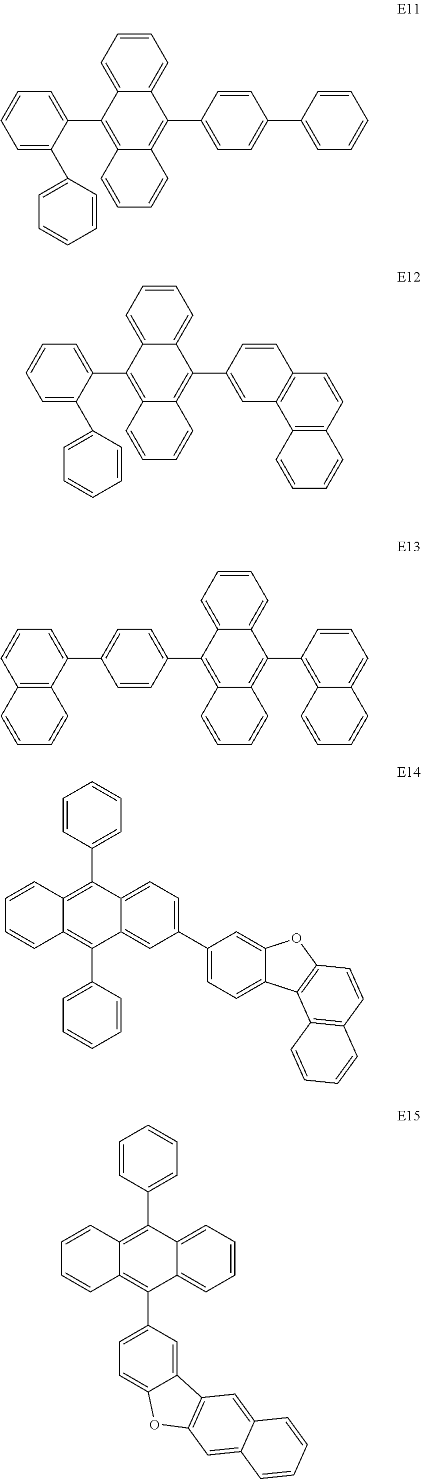

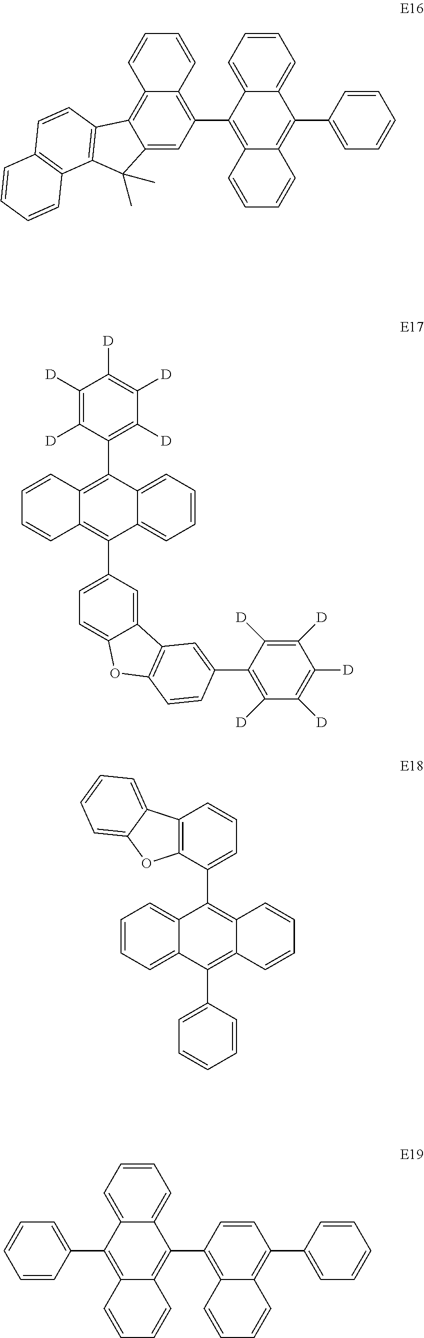

In an embodiment, the emission layer EML may include a compound represented by Formula E-2a or Formula E-2b. The compound represented by Formula E-2a or Formula E-2b may be used as a phosphorescent host material.

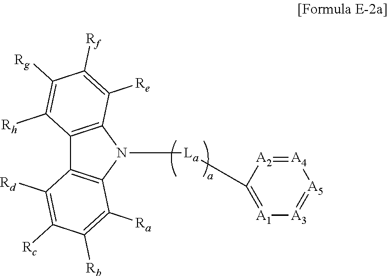

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or more, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

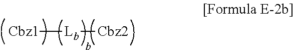

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2:

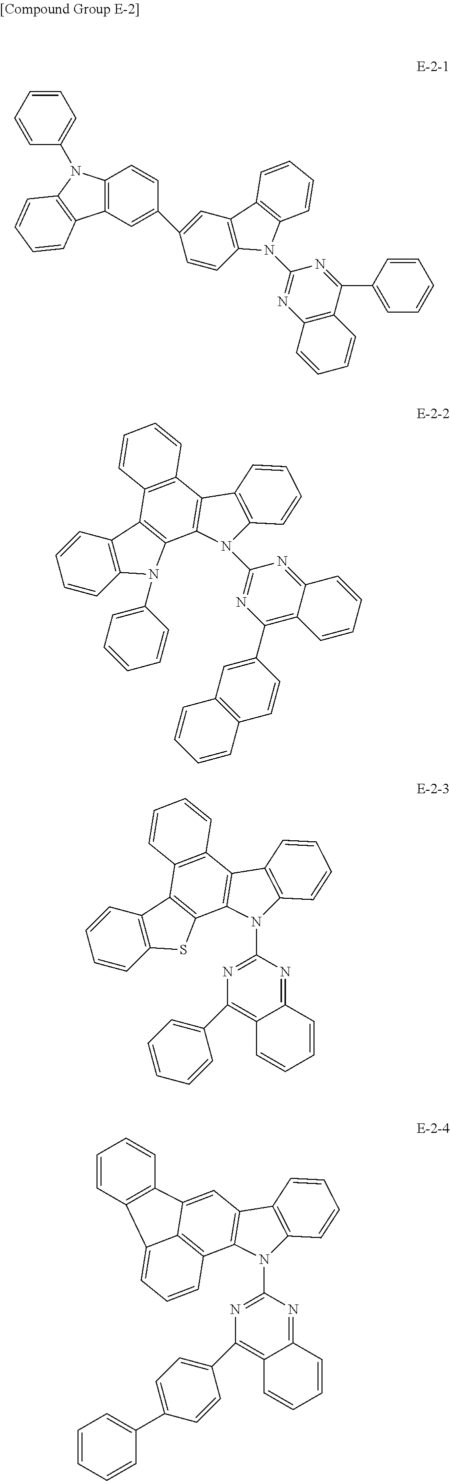

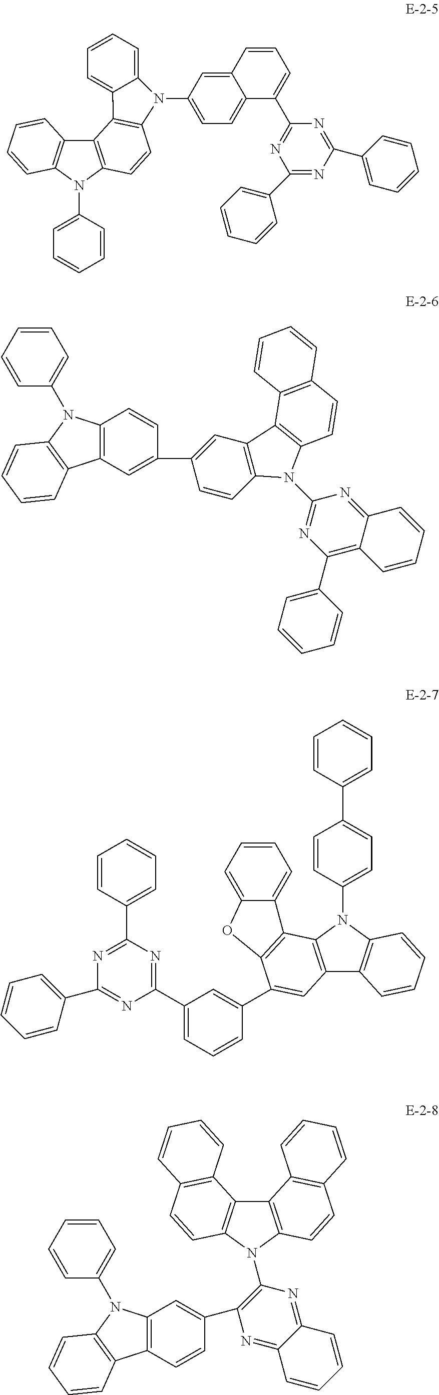 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

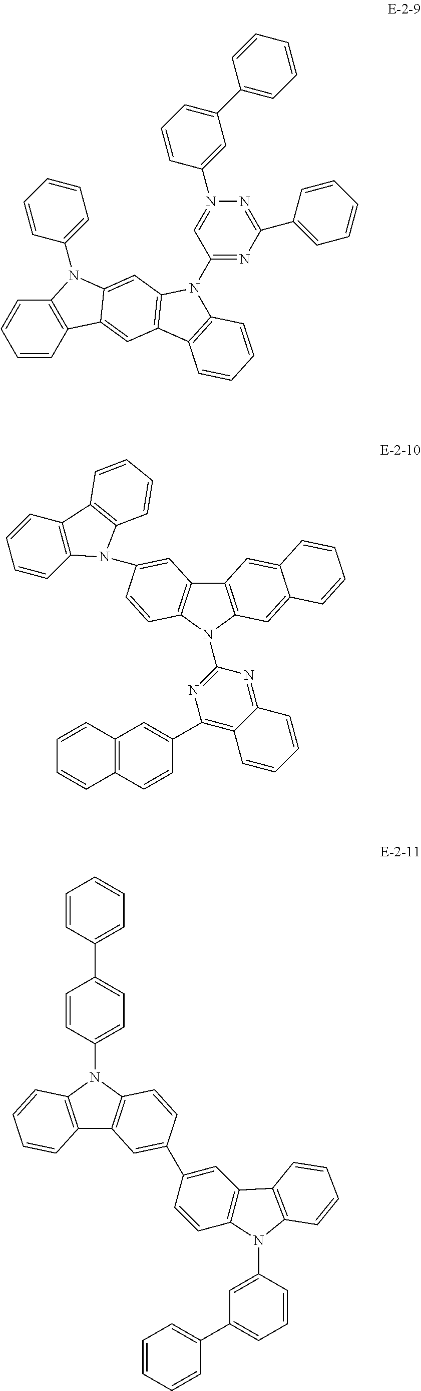

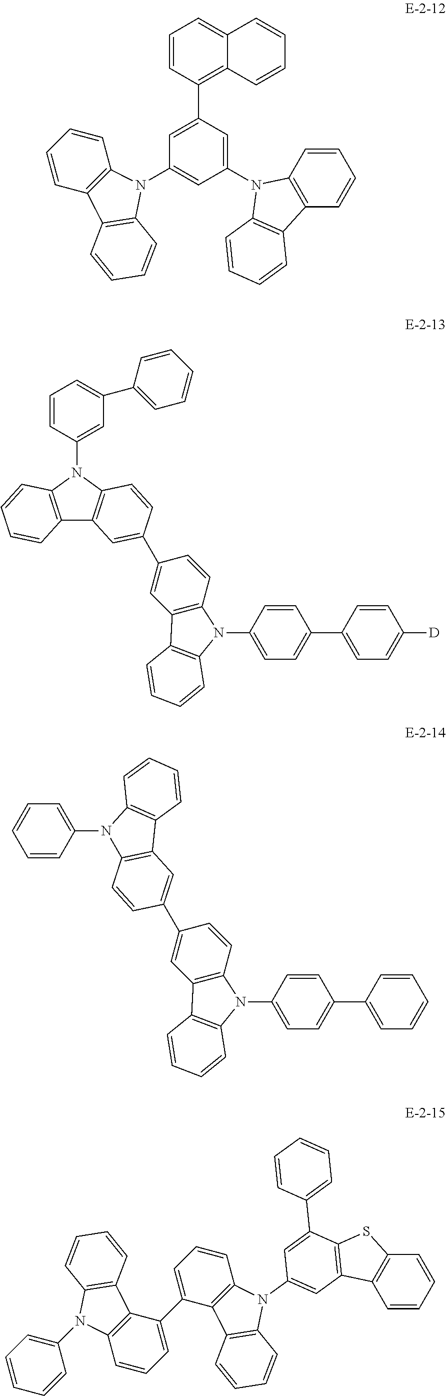 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

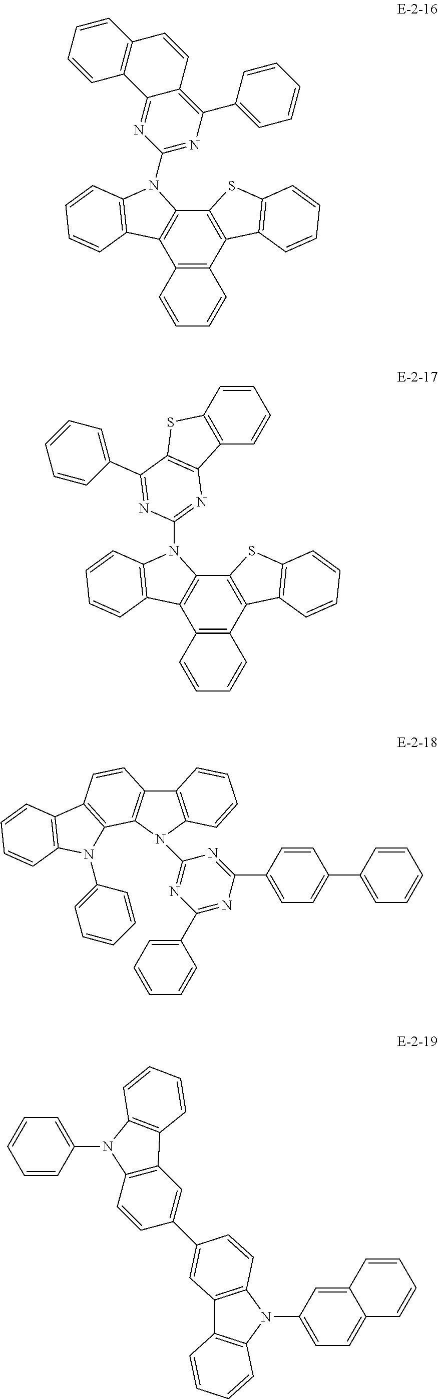 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

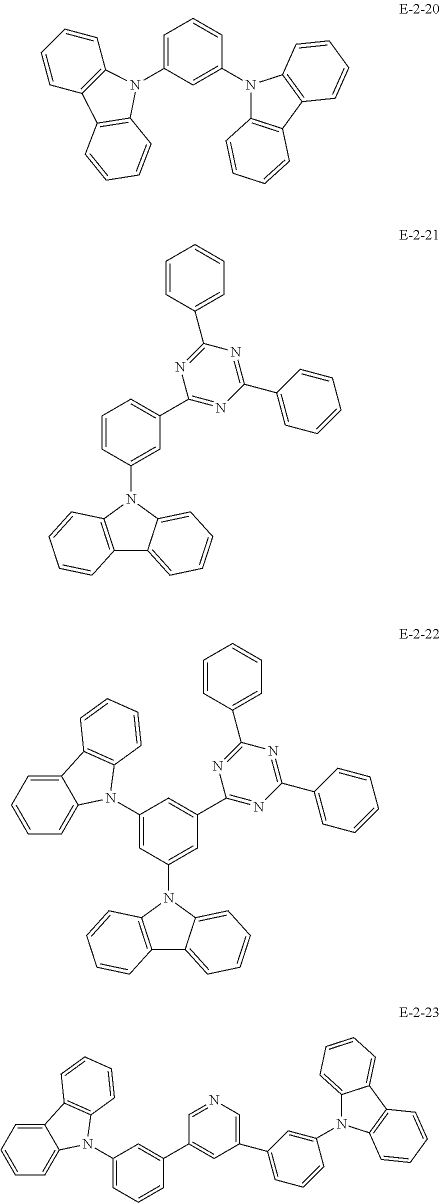 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

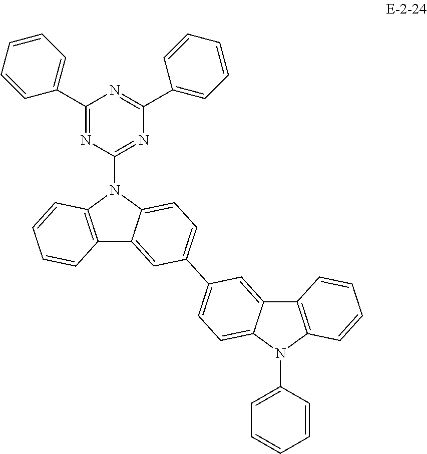 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include a compound represented by Formula M-a. The compound represented by Formula M-a may be used as a phosphorescent dopant material.

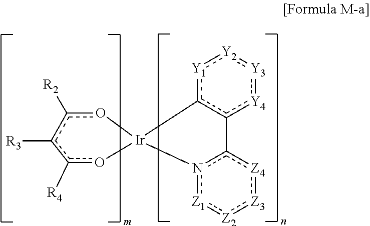

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be used as a phosphorescent dopant.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

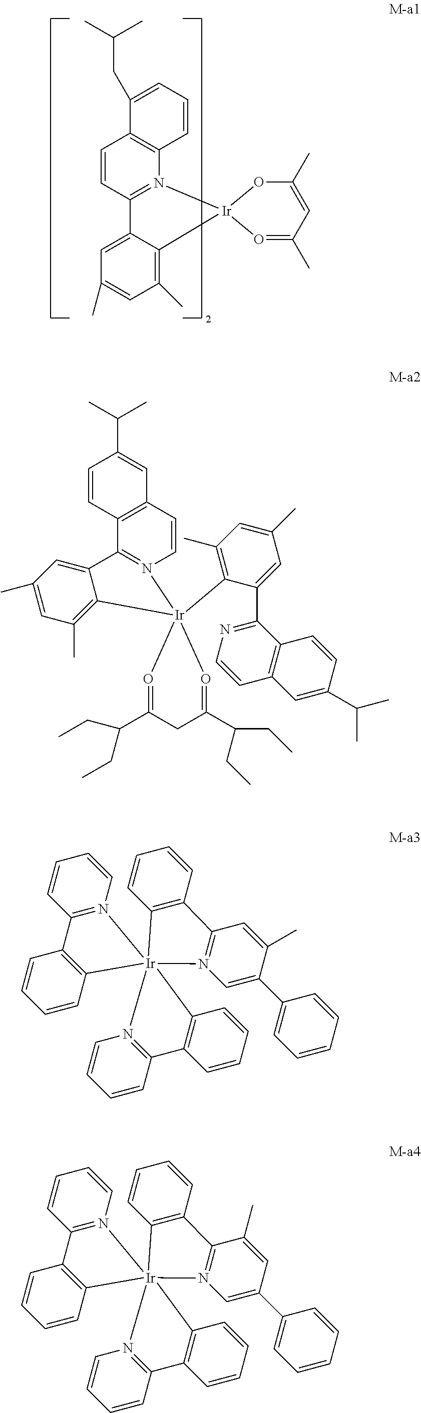

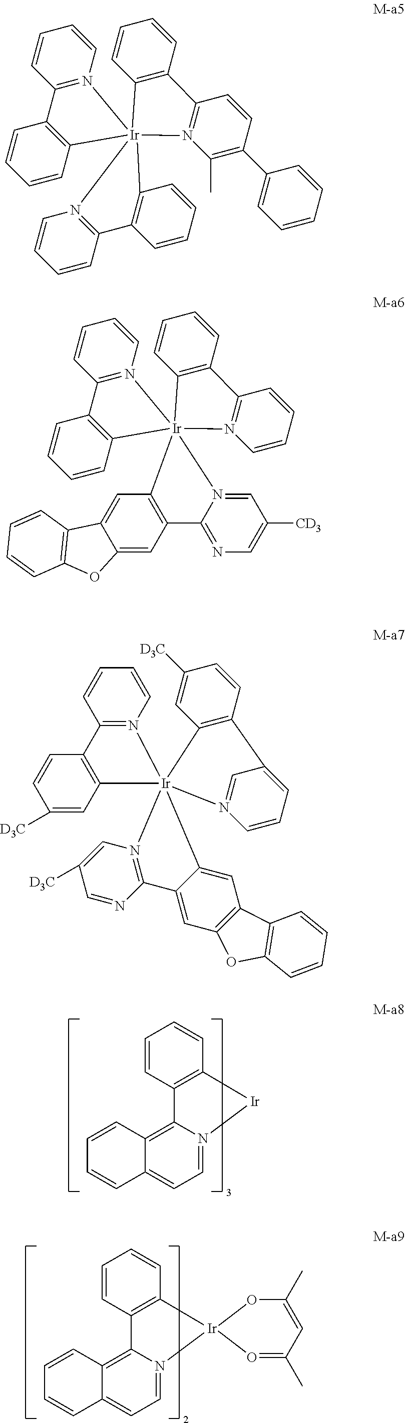

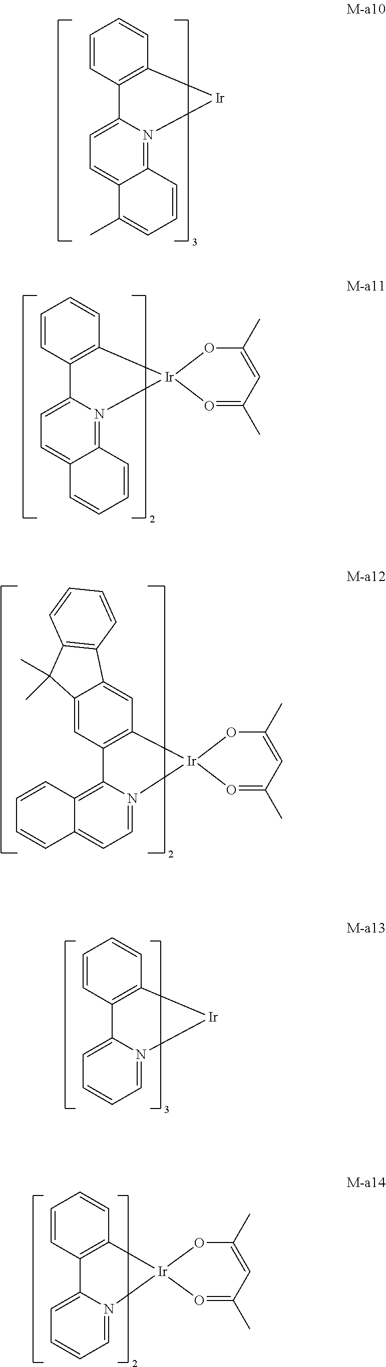

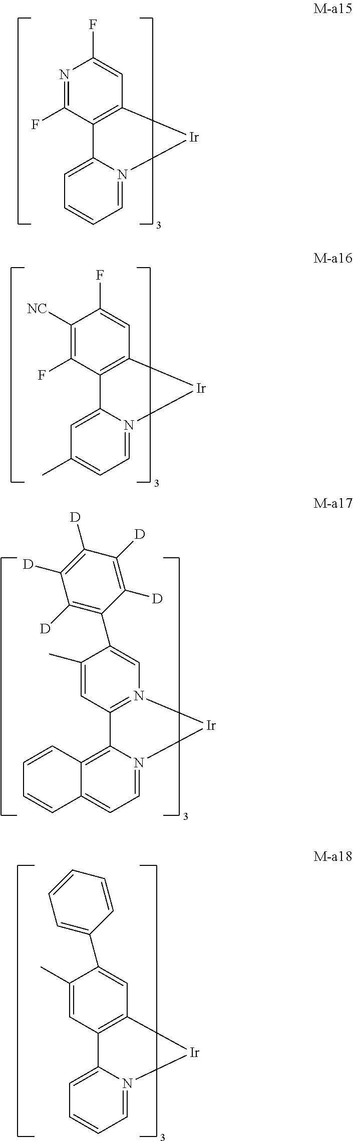

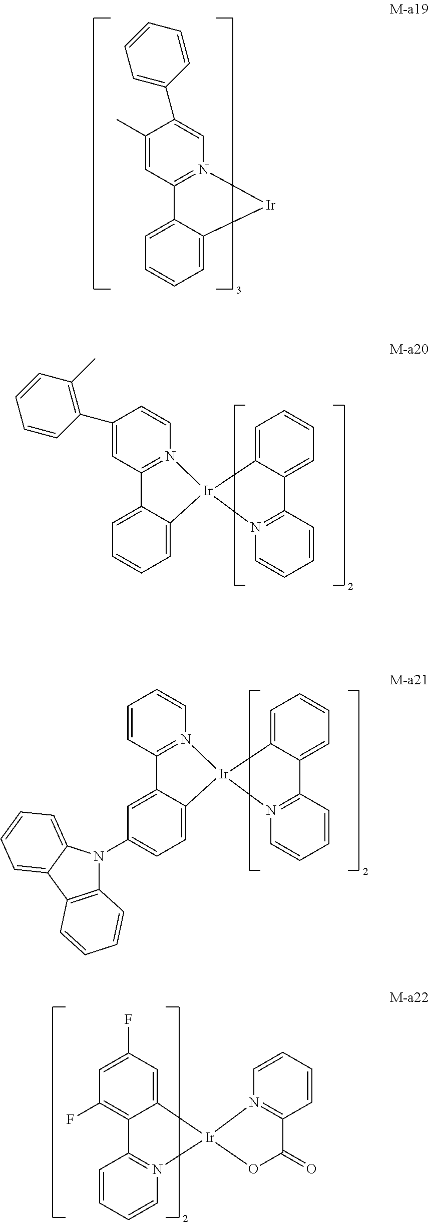

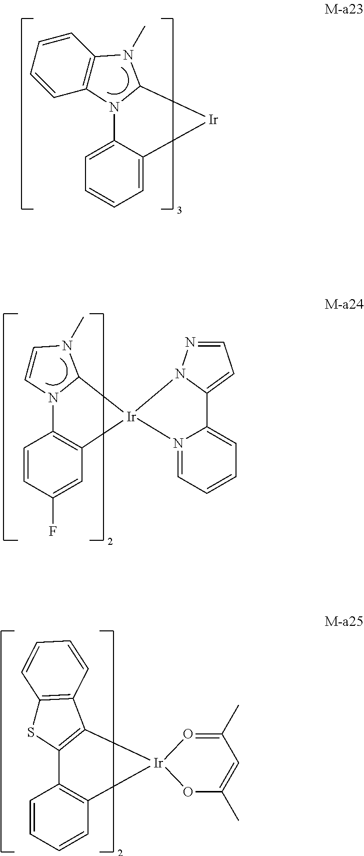

The emission layer EML may include a compound represented by any one of Formula F-a to Formula F-c. The compound represented by one of Formula F-a to Formula F-c may be used as a fluorescence dopant material.

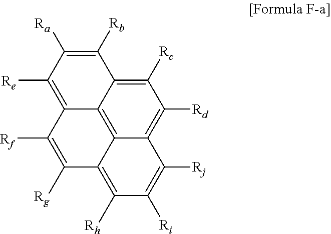

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may be a heteroaryl group containing O or S as a ring-forming atom.

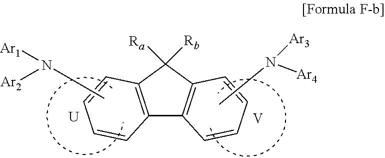

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Aᵣ to Ar₄ may be a heteroaryl group containing O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When the number of U and V are each 0, a fused ring having a fluorene core of Formula F-b may be a cyclic compound having three rings. When the number of U and V are each 1, a fused ring having a fluorene core of Formula F-b may be a cyclic compound having five rings.

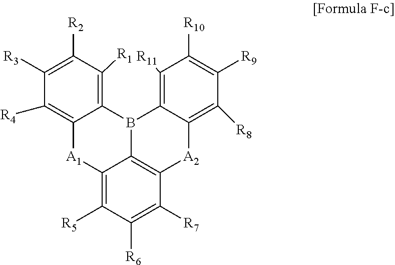

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may further include, as a dopant material of the related art, styryl derivatives (e.g., 1,4-bis[2-(3-N-ethylcarbazoryl)vinyl]benzene (BC_{Z}VB), 4-(di-p-tolylamino)-4′-[(di-p-tolylamino)styryl]stilbene (DPAVB), andN-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. The quantum dot may be a Group II-VI compound, a Group III-VI compound, a Group 1-III-VI compound, a Group III-V compound, a Group III—II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and any mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any mixture thereof, a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and any mixture thereof, or any combination thereof.

Examples of a Group III-VI compound may include: a binary compound such as In₂S₃ or In₂Se₃; a ternary compound such as InGaS₃ or InGaSe₃; or any combination thereof.

Examples of a Group 1-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and any mixture thereof, a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and any mixture thereof, a ternary compound selected from the group consisting of GaNP, GaNAs, GaNSb, GaPAs, GaPSb, AINP, AlNAs, AlNSb, AlPAs, AlPSb, InGaP, InAIP, InNP, InNAs, InNSb, InPAs, InPSb, and any mixture thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any mixture thereof, or any combination thereof. In an embodiment, a Group III-V compound may further include a Group II metal. For example, InZnP, etc., may be selected as a Group III-II-V compound.

Examples of a Group IV-VI compound may include: a binary compound selected from the group consisting of SnS, SnSe, SnTe, PbS, PbSe, PbTe, and any mixture thereof, a ternary compound selected from the group consisting of SnSeS, SnSeTe, SnSTe, PbSeS, PbSeTe, PbSTe, SnPbS, SnPbSe, SnPbTe, and any mixture thereof, a quaternary compound selected from the group consisting of SnPbSSe, SnPbSeTe, SnPbSTe, and any mixture thereof, or any combination thereof. Examples of a Group IV element may include Si, Ge, or any mixture thereof. Examples of a Group IV compound may include a binary compound selected from the group consisting of SiC, SiGe, and any mixture thereof.

A binary compound, a ternary compound, or a quaternary compound may be present in a particle at a uniform concentration distribution, or may be present in a particle at a partially different concentration distribution. In an embodiment, the quantum dot may have a core/shell structure in which a quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve as a charging layer to impart electrophoretic properties to the quantum dot. The shell may be a single layer or a multilayer. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited and may be any form used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

A quantum dot may control the color of emitted light according to a particle size thereof. Accordingly, the quantum dot may have various light emission colors such as green, red, etc.

In the light emitting device ED according to an embodiment as shown in each of FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure including different materials, or may have a structure in which an electron transport layer ETL/electron injection layer EIL, or a hole blocking layer HBL/electron transport layer ETL/electron injection layer EIL are stacked in its respective stated order from an emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

In the light emitting device ED according to an embodiment, the electron transport region ETR may include a compound represented by Formula ET-2:

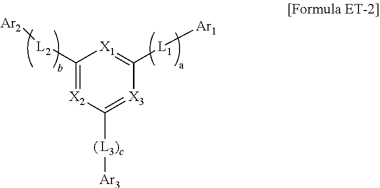

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each independently 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-Bis[3,5-di(pyridin-3-yl)phenyl]benzene (BmPyPhB), or any mixture thereof.

In an embodiment, the electron transport region ETR may include at least one compound selected from Compound ET1 to Compound ET36:

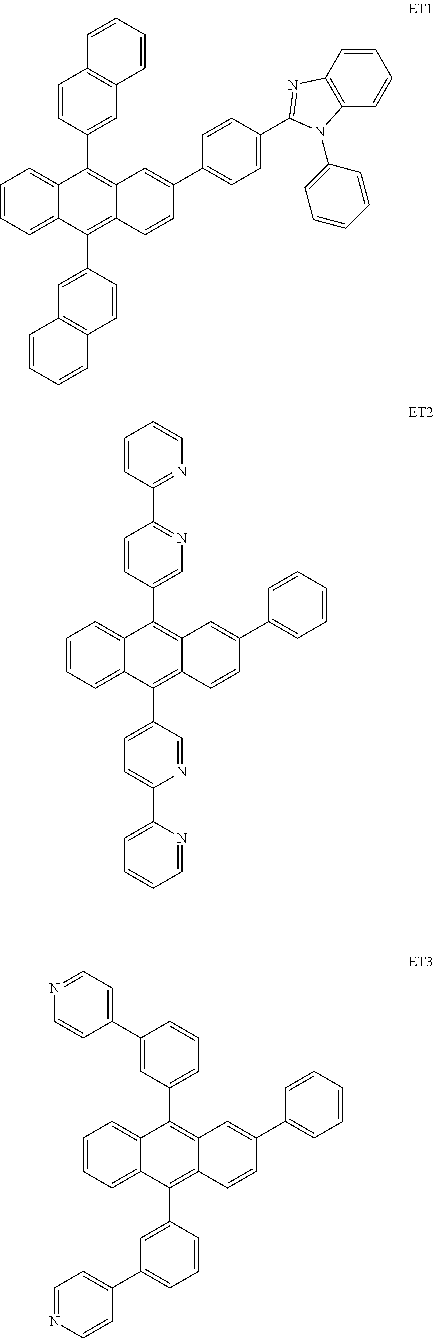 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

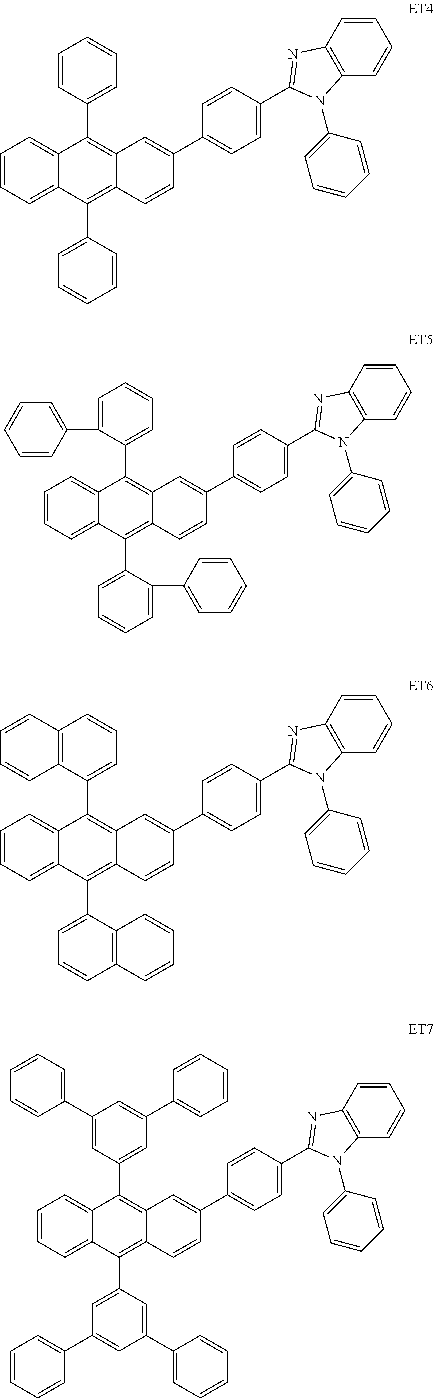 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

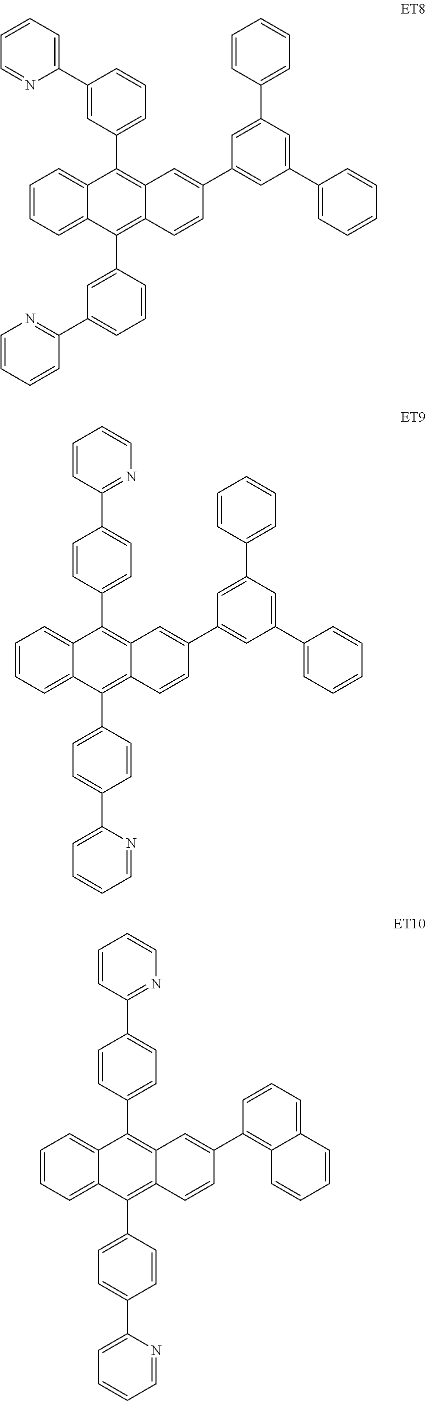 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

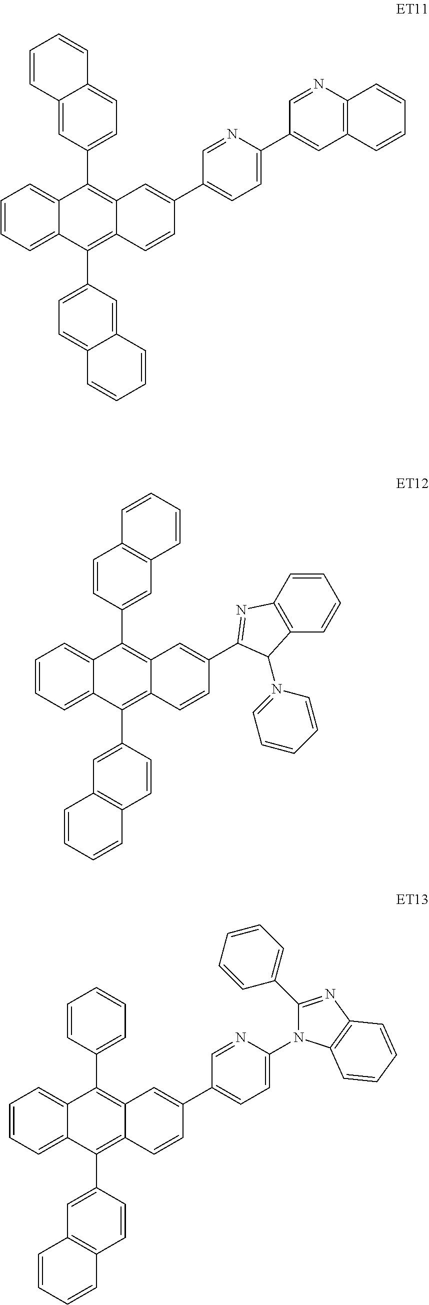

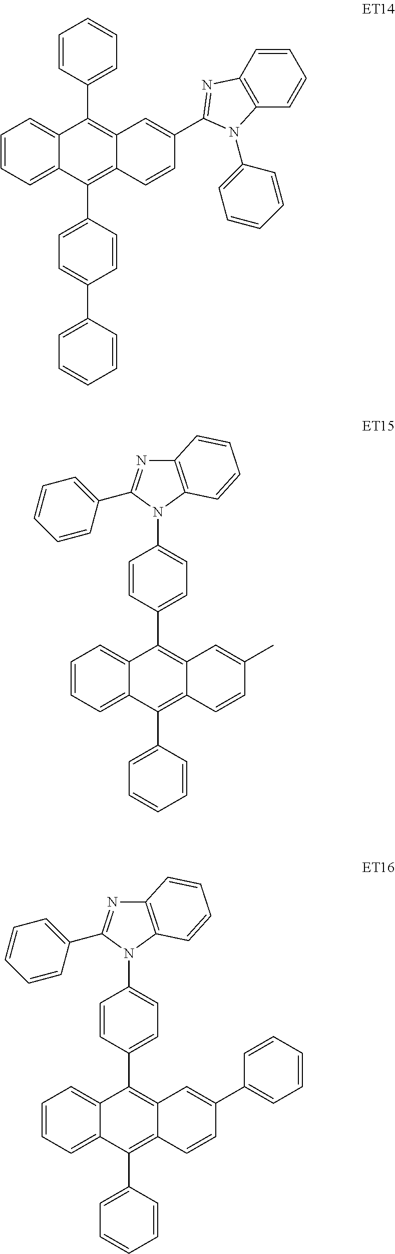 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

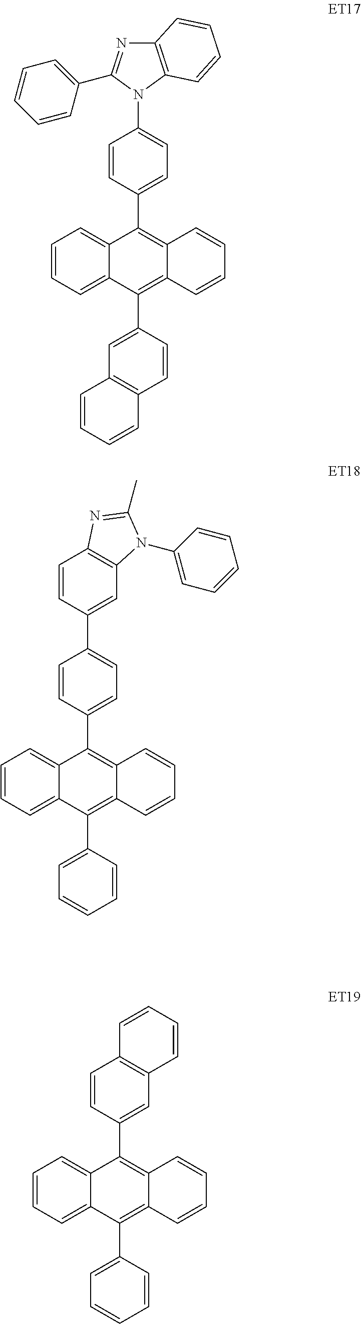

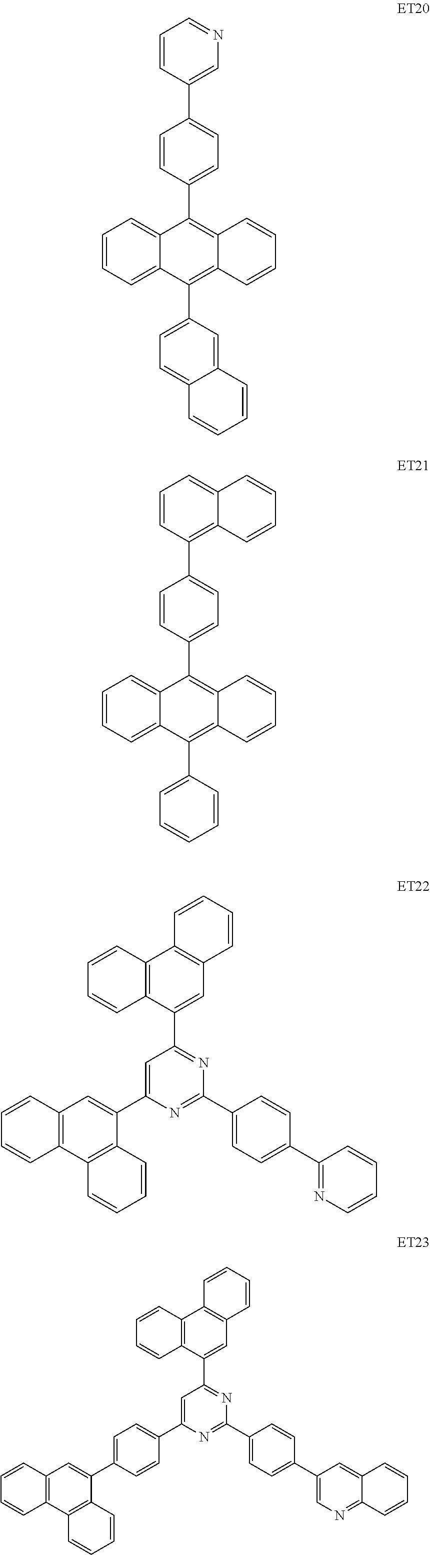

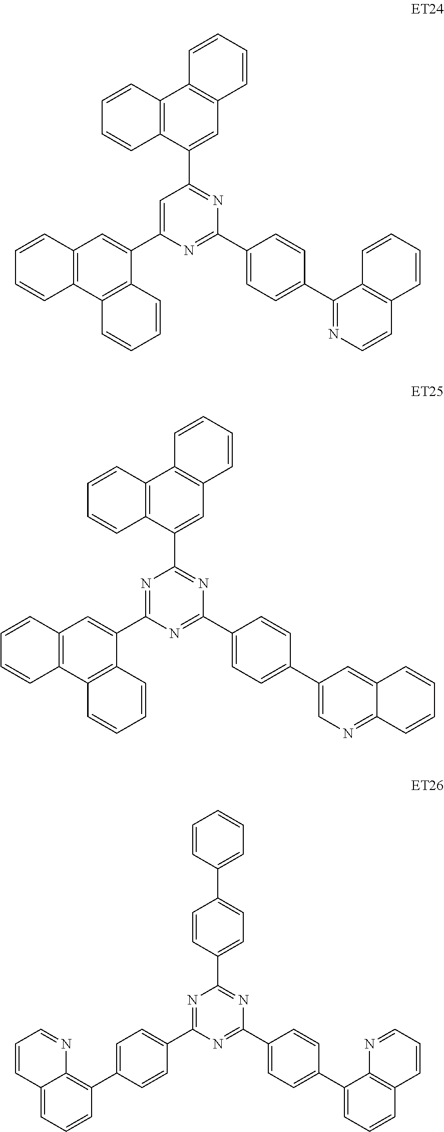 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

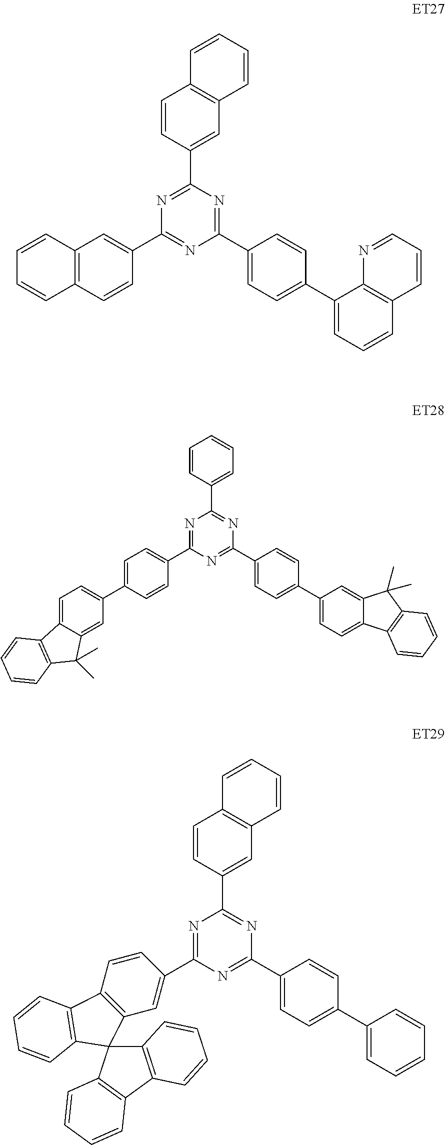 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc5c(c4)C4(c6ccccc6-c6ccccc64)c4ccccc4-5)nc(-c4ccc5ccccc5c4)n3)cc2)cc1]

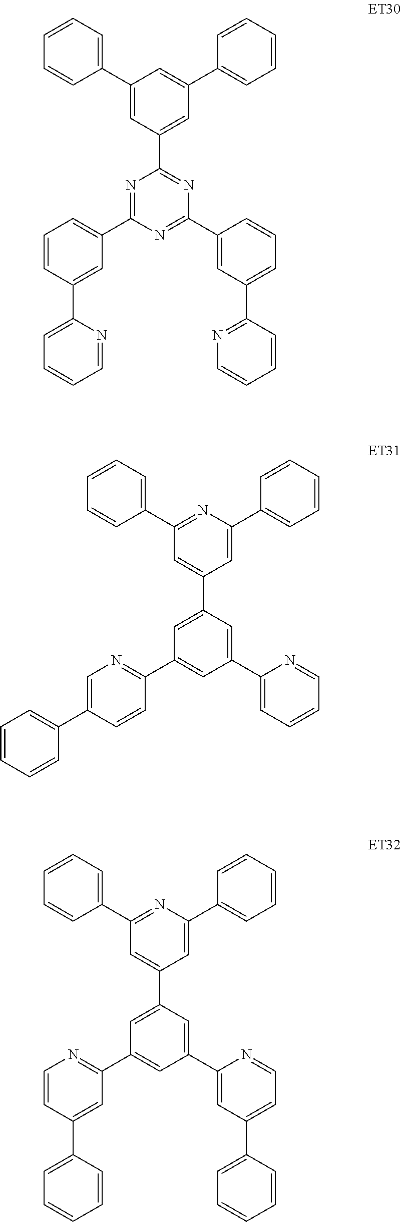 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

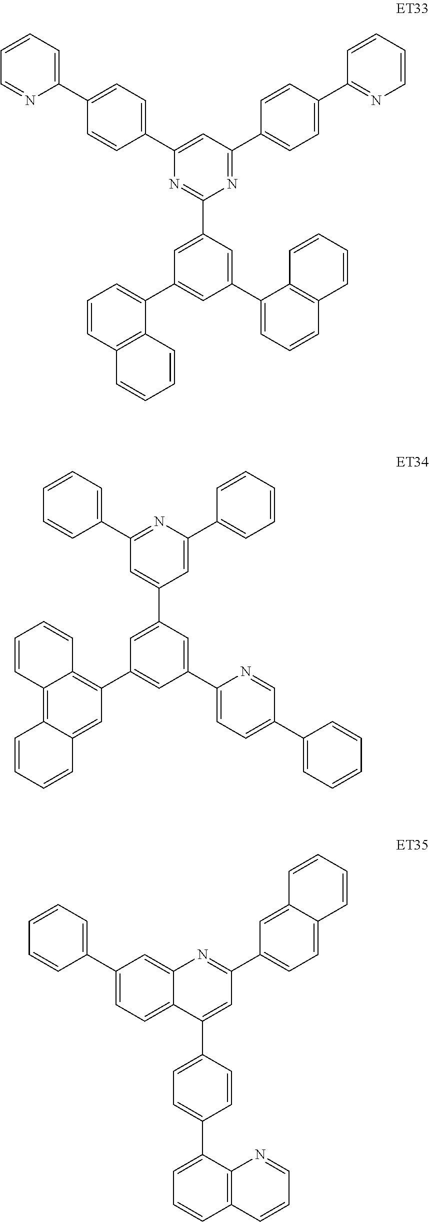 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

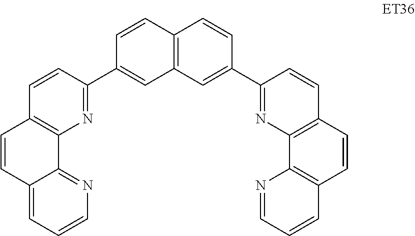 [SMILES: c1cnc2c(c1)ccc1ccc(-c3ccc4ccc(-c5ccc6ccc7cccnc7c6n5)cc4c3)nc12]

In an embodiment, the electron transport regions ETR may include: a metal halide such as LiF, NaCl, CsF, RbCl, RbI, CuI, or KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the electron transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may be decreased.

In an embodiment, the light emitting device ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or an epoxy resin, or an acrylate such as methacrylate. However, embodiments are not limited thereto, and the capping layer CPL may include at least one of Compounds P1 to P5:

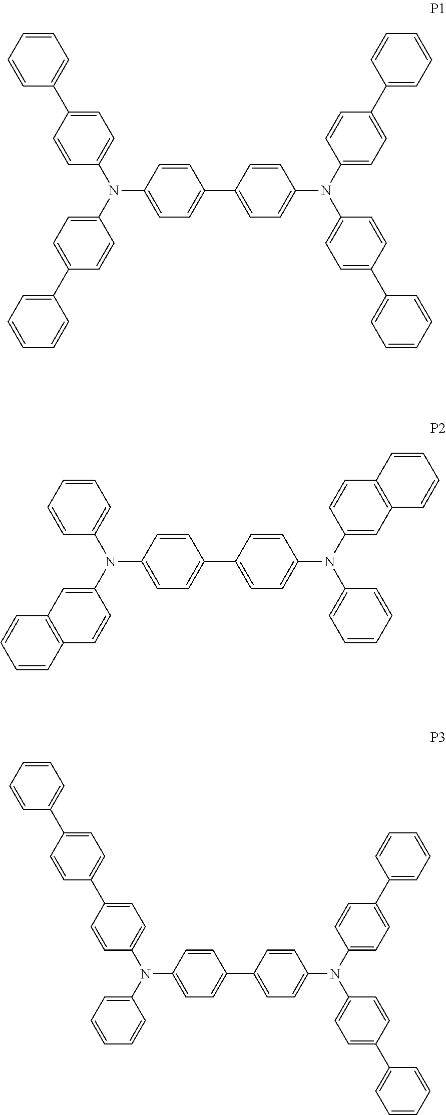 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

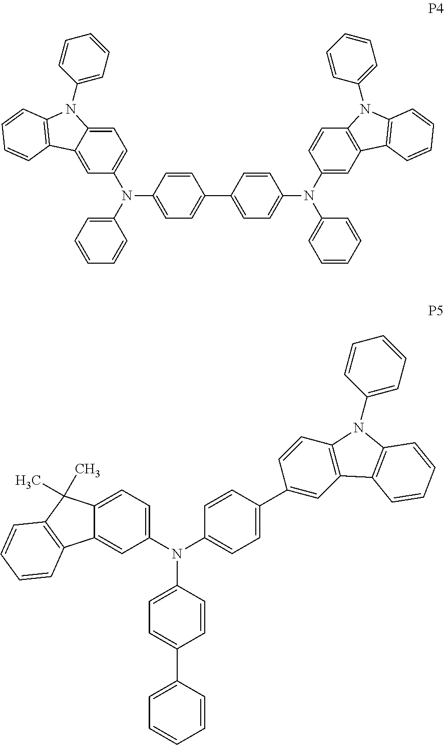 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than about 1.6 with respect to light in a wavelength range of about 550 nm to about 660 nm.

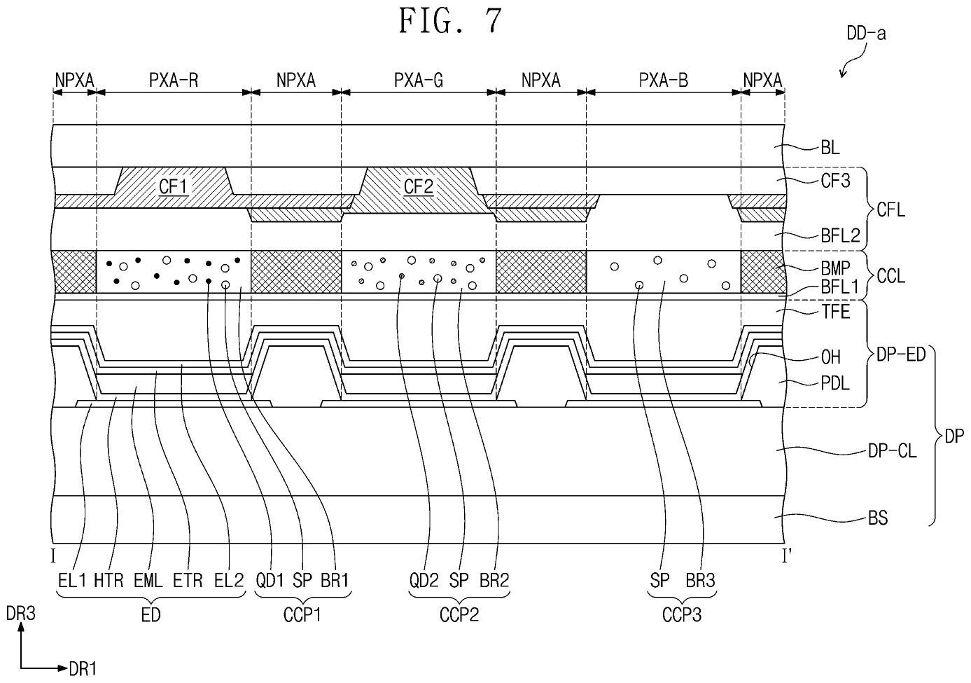

FIGS. 7 to 10 are each a schematic cross-sectional view of a display apparatus according to an embodiment. Hereinafter, in describing the display apparatuses according to embodiments in reference to FIGS. 7 to 10, the features which have been described above with respect to FIGS. 1 to 6 will not be explained again, and the differing features will be described.

Referring to FIG. 7, the display apparatus DD-a according to an embodiment may include a display panel DP including a display apparatus layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EIL disposed on the hole transport region HTR, an electron transport region ETR disposed on the emission layer EIL, and a second electrode EL2 disposed on the electron transport region ETR. In embodiments, a structure of the light emitting device ED illustrated in FIG. 7 may be the same as a structure of a light emitting device according to one of FIGS. 3 to 6 as described herein.

In the display apparatus DD-a, the emission layer EIL of the light emitting device ED may include the fused polycyclic compound according to an embodiment.

Referring to FIG. 7, the emission layer EIL may be disposed in an opening OH defined in a pixel defining film PDL. For example, the emission layer EIL, which is divided by the pixel defining film PDL and correspondingly provided to each of the light emitting regions PXA-R, PXA-G, and PXA-B, may each emit light in a same wavelength range. In the display apparatus DD-a, the emission layer EIL may emit blue light. Although not shown in the drawings, in an embodiment, the emission layer EMIL may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 including a first quantum dot QD1 that converts first color light provided from the light emitting device ED into second color light, a second light control part CCP2 including a second quantum dot QD2 that converts the first color light into third color light, and a third light control part CCP3 that transmits the first color light.

In an embodiment, the first light control part CCP1 may provide red light, which may be the second color light, and the second light control part CCP2 may provide green light, which may be the third color light. The third light control part CCP3 may transmit and provide blue light, which may be the first color light provided from the light emitting device ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and a scatterer SP, the second light control part CCP2 may include the second quantum dot QD2 and a scatterer SP, and the third light control part CCP3 may not include any quantum dot but may include a scatterer SP.

The scatterer SP may be inorganic particles. For example, the scatterer SP may include at least one of TiO₂, ZnO, Al₂O₃, SiO₂, or hollow silica. The scatterer SP may include any one of TiO₂, ZnO, Al₂O₃, SiO₂, and hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are each a medium in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may be formed of a single layer or of multiple layers.

In the display apparatus DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated and may be provided as one filter.

Although not shown in the drawings, the color filter layer CFL may include a light shielding part (not shown). The light shielding part (not shown) may be a black matrix. The light shielding part (not shown) may include an organic light shielding material or an inorganic light shielding material containing a black pigment or dye. The light shielding part (not shown) may prevent light leakage, and may separate boundaries between adjacent filters CF1, CF2, and CF3. In an embodiment, the light shielding part (not shown) may be formed of a blue filter.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

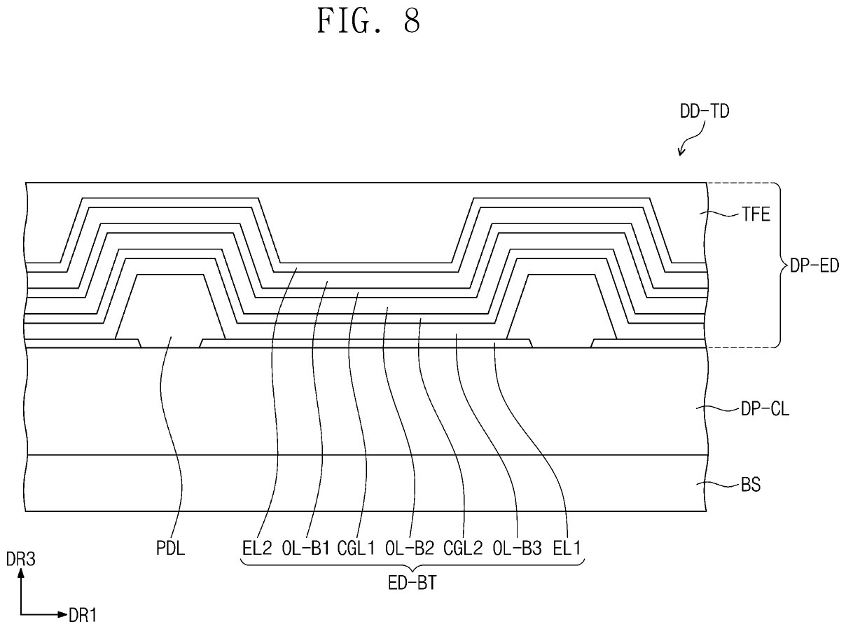

FIG. 8 is a schematic cross-sectional view of a portion of a display apparatus according to an embodiment. In the display apparatus DD-TD according to an embodiment, the light emitting device ED-BT may include light emitting structures OL-B1, OL-B2, and OL-B3. The light emitting device ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) located therebetween.

For example, the light emitting device ED-BT included in the display apparatus DD-TD may be a light emitting device having a tandem structure and including multiple emission layers.

In an embodiment illustrated in FIG. 8, light emitted from the light emitting structures OL-B1, OL-B2, and OL-B3 may each be blue light. However, embodiments are not limited thereto, and the light emitted from the light emitting structures OL-B1, OL-B2, and OL-B3 may have wavelength ranges that are different from each other. For example, the light emitting device ED-BT that includes the light emitting structures OL-B1, OL-B2, and OL-B3, which emit light having wavelength ranges that are different from each other, may emit white light.

Charge generation layers CGL1 and CGL2 may each be disposed between neighboring light emitting structures among OL-B1, OL-B2, and OL-B3. Charge generation layers CGL1 and CGL2 may each independently include a p-type charge generation layer and/or an n-type charge generation layer.

In an embodiment, at least one of the light emitting structures OL-B1, OL-B2, and OL-B3 included in the display apparatus DD-TD may include the fused polycyclic compound according to an embodiment as described herein. For example, at least one of the emission layers included in the light emitting device ED-BT may include the fused polycyclic compound.

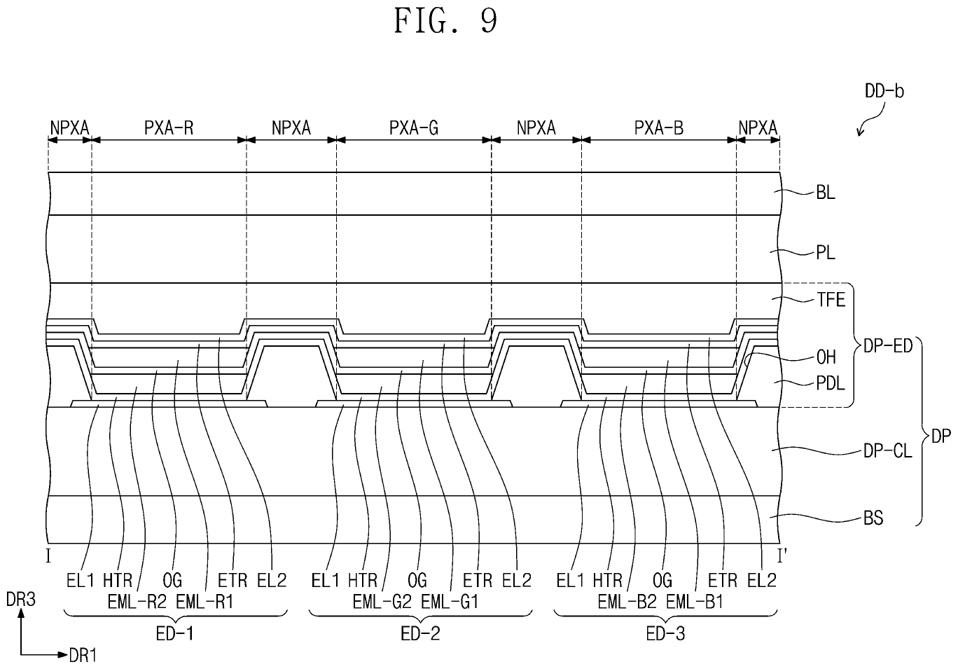

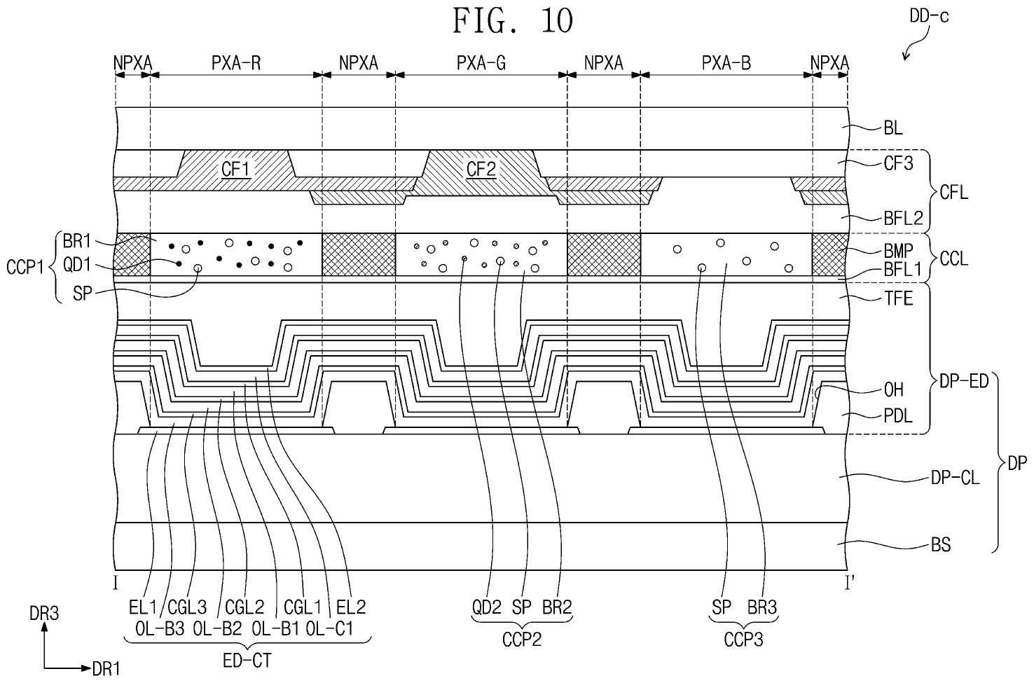

FIG. 9 is a schematic cross-sectional view of a display apparatus according to an embodiment; and FIG. 10 is a schematic cross-sectional view of a display apparatus according to an embodiment.

Referring to FIG. 9, the display apparatus DD-b according to an embodiment may include light emitting devices ED-1, ED-2, and ED-3 in which two emission layers are stacked. In comparison to the display apparatus DD illustrated in FIG. 2, the embodiment illustrated in FIG. 9 is different at least in that the first to third light emitting devices ED-1, ED-2, and ED-3 each include two emission layers that are stacked in a thickness direction. In each of the first to third light emitting devices ED-1, ED-2, and ED-3, the two emission layers may emit light in a same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. The third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting devices ED-1, ED-2, and ED-3. However, embodiments are not limited thereto, and the emission auxiliary part OG may be provided by being patterned in the openings OH defined in the pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display device layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display apparatus DD-b.

At least one emission layer included in the display apparatus DD-b illustrated in FIG. 9 may include the fused polycyclic compound according to an embodiment as described herein. For example, in an embodiment, at least one of the first blue emission layer EML-B1 or the second blue emission layer EML-B2 may include the fused polycyclic compound.

In contrast to FIGS. 8 and 9, FIG. 10 illustrates a display apparatus DD-c that is different at least in that it includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 which are disposed between adjacent light emitting structures OL-B1, OL-B2, OL-B3, and OL-C1 may each independently include a p-type charge generation layer and/or an n-type charge generation layer.

In the display apparatus DD-c, at least one of the light emitting structures OL-B1, OL-B2, OL-B3, and OL-C1 may each independently contain the fused polycyclic compound according to an embodiment as described herein. For example, in an embodiment, at least one of the first to third light emitting structures OL-B1, OL-B2, and OL-B3 may each independently include the fused polycyclic compound.

The light emitting device ED according to an embodiment may include the fused polycyclic compound represented by Formula 1 in at least one functional layer disposed between the first electrode EL1 and the second electrode EL2, thereby exhibiting excellent luminous efficiency and improved service life characteristics. For example, the emission layer EML of the light emitting device ED may include the fused polycyclic compound, and the light emitting device ED may exhibit long service life characteristics.

In an embodiment, an electronic apparatus may include a display apparatus including multiple light emitting devices, and a control part which controls the display apparatus. The electronic apparatus may be a device that is activated according to an electrical signal. The electronic apparatus may include display apparatuses according to various embodiments. For example, the electronic apparatus may be not only large-sized electronic apparatuses, such as a vehicle, a television, a monitor, or a billboard, but the electronic apparatus may also be a small- or a medium-sized electronic apparatus, such as a personal computer, a laptop computer, a personal digital terminal, a display apparatus for a vehicle, a game console, a portable electronic device, or a camera.

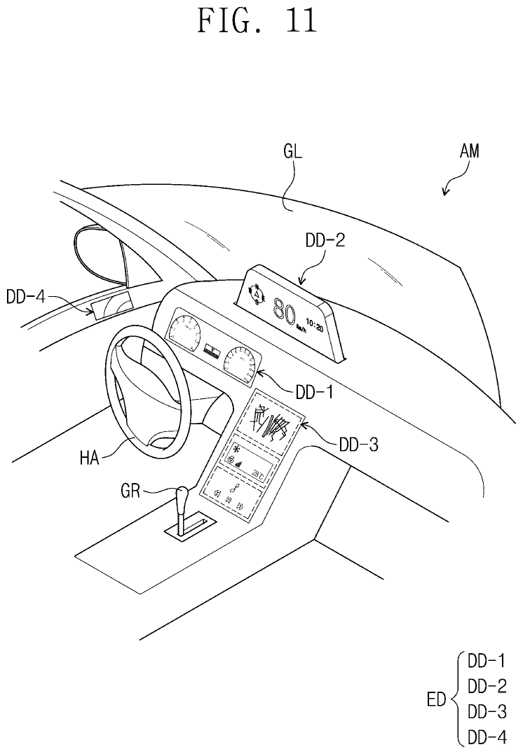

FIG. 11 is a schematic perspective view of an electronic apparatus including a display apparatus according to an embodiment. FIG. 11 illustrates a vehicle as an example of an electronic apparatus that includes display apparatuses.

Referring to FIG. 11, the electronic apparatus ED may include display apparatuses DD-1, DD-2, DD-3, and DD-4 for a vehicle AM. FIG. 11 illustrates the first to fourth display apparatuses DD-1, DD-2, DD-3, and DD-4 as display apparatuses for a vehicle AM disposed inside the vehicle AM. FIG. 11 illustrates a vehicle, but this is an example, and the first to fourth display apparatuses DD-1, DD-2, DD-3, and DD-4 may be disposed in various transportation means such as bicycles, motorcycles, trains, ships, and airplanes. At least one of the first to fourth display apparatuses DD-1, DD-2, DD-3, and DD-4 may have a structure according to one of display apparatuses DD, DD-a, DD-b, and DD-c, as described in reference to FIG. 1, FIG. 2, and FIGS. 7 to 10.

In an embodiment, at least one of the first to fourth display apparatuses DD-1, DD-2, DD-3, and DD-4 may include a light emitting device ED according to an embodiment as described in reference to FIGS. 3 to 6. The first to fourth display apparatuses DD-1, DD-2, DD-3, and DD-4 may each independently include multiple light emitting devices ED, and the light emitting devices ED may each include a first electrode EL1, a hole transport region HTR disposed on an upper portion of the first electrode EL1, an emission layer EML disposed on an upper portion of the hole transport region HTR, an electron transport region ETR disposed on an upper portion of the emission layer EML, and a second electrode disposed on an upper portion of the electron transport region ETR. The emission layer EML may include a fused polycyclic compound represented by Formula 1. Accordingly, the electronic apparatus ED may exhibit improved image quality.

Referring to FIG. 11, the vehicle AM may include a steering wheel HA and a gearshift GR for driving the vehicle AM, and a front window GL may be disposed so as to face the driver.

The first display apparatus DD-1 may be disposed in a first region overlapping the steering wheel HA. For example, the first display apparatus DD-1 may be a digital cluster for displaying first information of the vehicle AM. The first information may include a scale for indicating a driving speed of the vehicle AM, a scale for indicating an engine speed (for example, a tachometer showing revolutions per minute (RPM)), an image for indicating a fuel state, etc. A first scale and a second scale may each be indicated as a digital image.

The second display apparatus DD-2 may be disposed in a second region facing the driver's seat and overlapping the front window WD. The driver's seat may be a seat in which the steering wheel HA is disposed. For example, the second display apparatus DD-2 may be a head up display (HUD) for displaying second information of the vehicle AM. The second display apparatus DD-2 may be optically transparent. The second information may include digital numbers for indicating a driving speed, and may further include information such as the current time.

The third display apparatus DD-3 may be disposed in a third region adjacent to the gearshift GR. For example, the third display apparatus DD-3 may be disposed between the driver's seat and the passenger seat and may be a center information display (CID) for a vehicle for displaying third information. The passenger seat may be a seat spaced apart from the driver's seat with the gearshift GR disposed therebetween. The third information may include information about traffic (e.g., navigation information), playing music or radio, playing video, temperatures inside the vehicle AM, etc.

The fourth display apparatus DD-4 may be spaced apart from the steering wheel HA and the gearshift GR, and may be disposed in a fourth region adjacent to the side of the vehicle AM. For example, the fourth display apparatus DD-4 may be a digital side-view mirror for displaying fourth information. The fourth display apparatus DD-4 may display an image outside the vehicle AM taken by a camera module disposed outside the vehicle AM. The fourth information may include an image outside the vehicle AM.

The first to fourth information as described herein are only examples, and the first to fourth display apparatuses DD-1, DD-2, DD-3, and DD-4 may further display information about the inside and outside of the vehicle AM. The first to fourth information may include different information. However, embodiments are not limited thereto, and a part of the first to fourth information may include the same information as one another.

Hereinafter, a fused polycyclic according to an embodiment and a light emitting device according to an embodiment will be described in detail with reference to the Examples and the Comparative Examples. The Examples described below are only provided as illustrations to assist in understanding the disclosure, and the scope thereof is not limited thereto.

### EXAMPLES

### 1. Synthesis of Fused Polycyclic Compound

A synthesis method of the fused polycyclic compound according to an embodiment will be explained in detail by illustrating the synthesis methods of Compounds 18, 35, 91, 115, 133, and 146. The synthesis methods of the fused polycyclic compounds as described below are only examples, and the synthesis method of the fused polycyclic compound according to an embodiment is not limited to the following examples.

### (1) Synthesis of Compound 18

Compound 18 according to an example may be synthesized by, for example, the reaction below.

### Synthesis of Intermediate 18-1

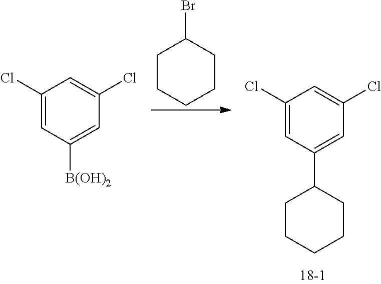

(3,5-dichlorophenyl)boronic acid (1.2 eq), bromocyclohexane (1 eq), tris(dibenzylideneacetone)dipalladium(0) (0.05 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 18-1. (yield: 84%)

### Synthesis of Intermediate 18-2

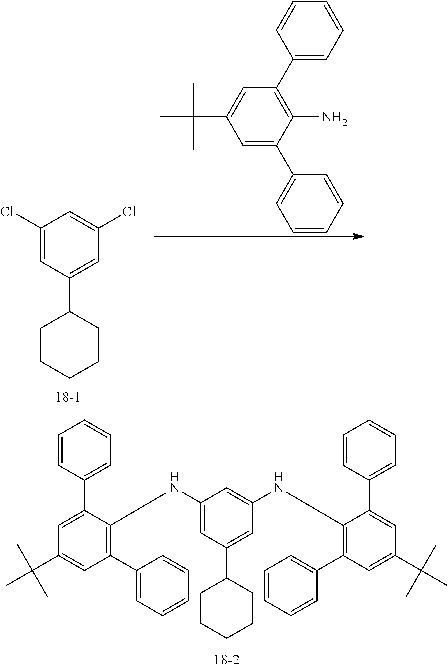 [SMILES: Clc1cc(Cl)cc(C2CCCCC2)c1 ; CC(C)(C)c1cc(-c2ccccc2)c(N)c(-c2ccccc2)c1 ; CC(C)(C)c1cc(-c2ccccc2)c(Nc2cc(Nc3c(-c4ccccc4)cc(C(C)(C)C)cc3-c3ccccc3)cc(C3CCCCC3)c2)c(-c2ccccc2)c1]

In a nitrogen atmosphere, Intermediate 18-1 (1 eq), 5′-(tert-butyl)-[1,1′:3′,1″-terphenyl]-2′-amine (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 18-2. (yield: 78%)

### Synthesis of Intermediate 18-3

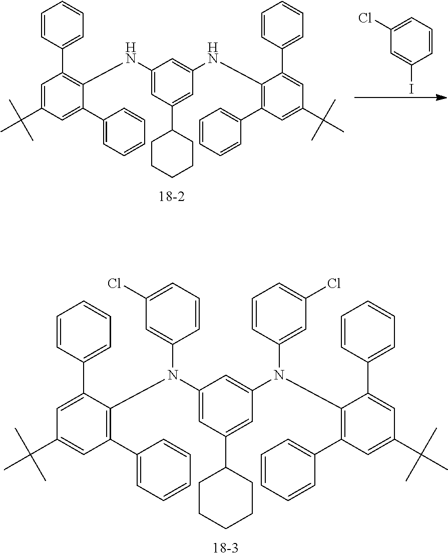

In a nitrogen atmosphere, Intermediate 18-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 18-3. (yield: 60%)

### Synthesis of Intermediate 18-4

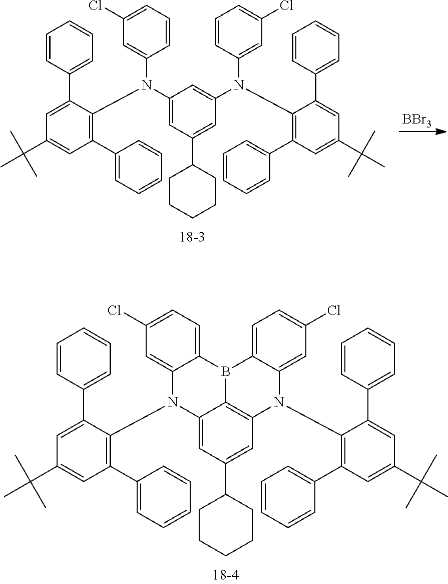

In a nitrogen atmosphere, Intermediate 18-3 (1 eq) was dissolved in o-dichlorobenzene, cooled using water and ice, and BBr₃ (5 equiv.) was slowly added dropwise thereto, and the reaction solution was stirred at about 180° C. for about 24 hours. After the reaction solution was cooled, the reaction was terminated by adding triethylamine (5 eq), the reaction solution was extracted with water/CH₂Cl₂ to collect organic layers, and the organic layers were dried over MgSO₄ and filtered. In the filtrate, the solvent was removed under reduced pressure to obtain a solid. The solid thus obtained was purified and separated by silica gel column chromatography to obtain Compound 18-4. (yield: 50%)

### Synthesis of Compound 18

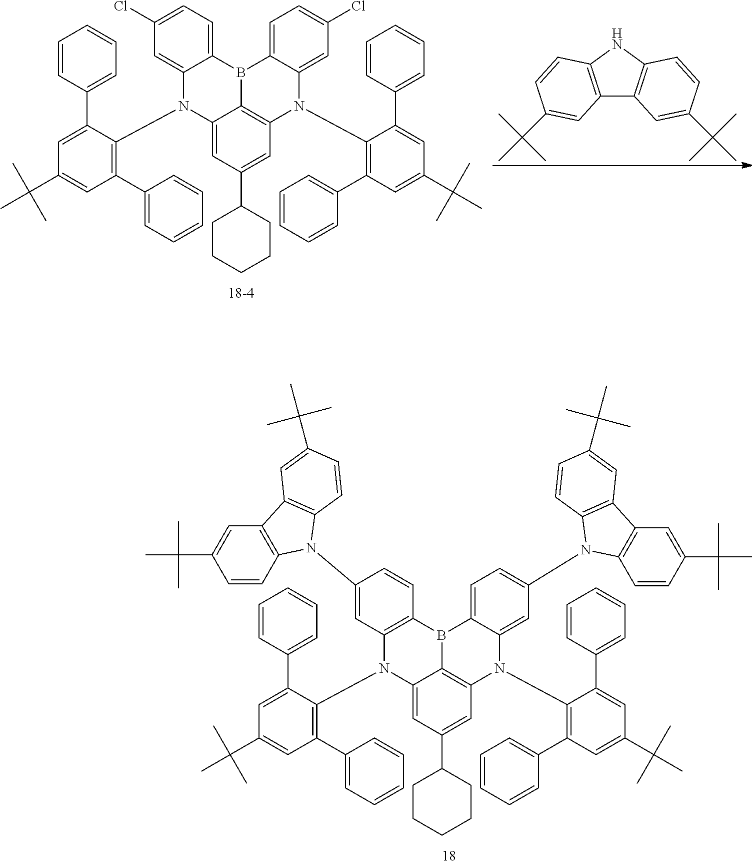

In a nitrogen atmosphere, Intermediate 18-4 (1 eq), 3,6-di-tert-butyl-9H-carbazole (2.4 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Compound 18. (yield: 85%)

### (2) Synthesis of Compound 35

Compound 35 according to an example may be synthesized by, for example, the reaction below:

### Synthesis of Intermediate 35-1

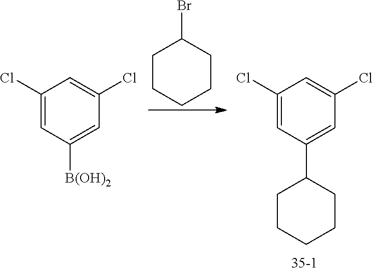

(3,5-dichlorophenyl)boronic acid (1.2 eq), bromocyclohexane (1 eq), tris(dibenzylideneacetone)dipalladium(0) (0.05 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 35-1. (yield: 84%)

### Synthesis of Intermediate 35-2

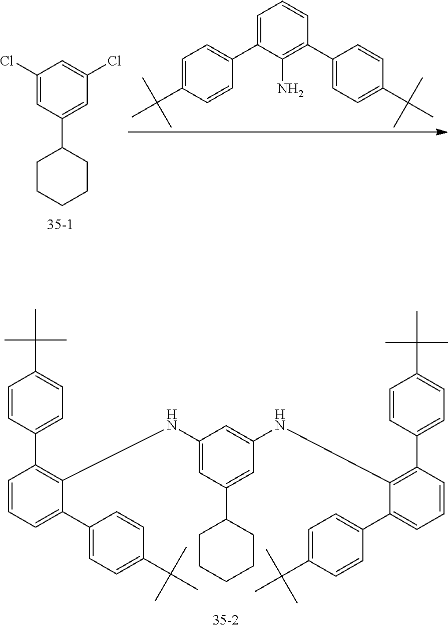

In a nitrogen atmosphere, Intermediate 35-1 (1 eq), 4,4″-di-tert-butyl-[1,1′:3′,1″-terphenyl]-2′-amine (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 35-2. (yield: 75%)

### Synthesis of Intermediate 35-3

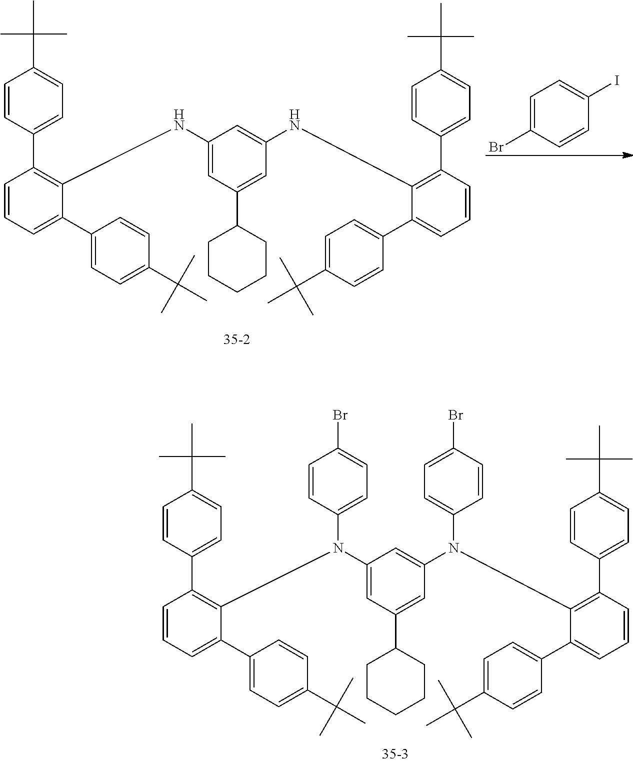

In a nitrogen atmosphere, Intermediate 35-2 (1 eq), 4-iodobromoobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 35-3. (yield: 70%)

### Synthesis of Intermediate 35-4

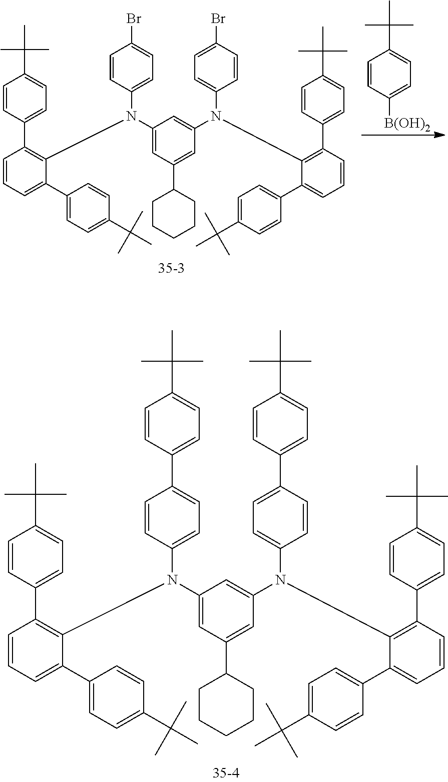

In a nitrogen atmosphere, Intermediate 35-3 (1 eq), (4-(tert-butyl)phenyl)boronic acid (2.5 eq), Pd(PPh₃)₄ (0.05 eq), and potassium carbonate (2 eq) were added and dissolved in toluene/H₂O, and the reaction solution was stirred at about 100° C. for about 12 hours. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 35-4. (yield: 80%)

### Synthesis of Compound 35

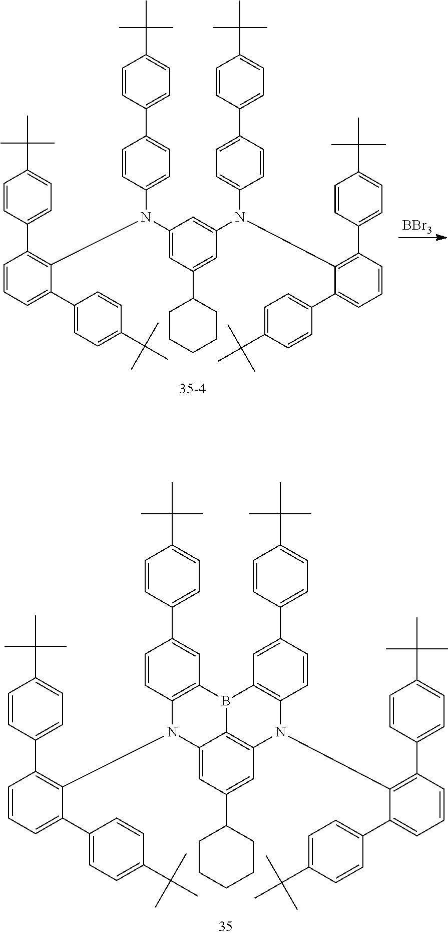

In a nitrogen atmosphere, Intermediate 35-4 (1 eq) was dissolved in o-dichlorobenzene, cooled using water and ice, and BBr₃ (5 eq) was slowly added dropwise thereto, and the reaction solution was stirred at about 180° C. for about 12 hours. After the reaction solution was cooled, the reaction was terminated by adding triethylamine (5 eq), the reaction solution was extracted with water/CH₂Cl₂ to collect organic layers, and the organic layers were dried over MgSO₄ and filtered. In the filtrate, the solvent was removed under reduced pressure to obtain a solid. The solid thus obtained was purified and separated by silica gel column chromatography to obtain Compound 35. (yield: 40%)

### (3) Synthesis of Compound 91

Compound 91 according to an example may be synthesized by, for example, the reaction below.

### Synthesis of Intermediate 91-1

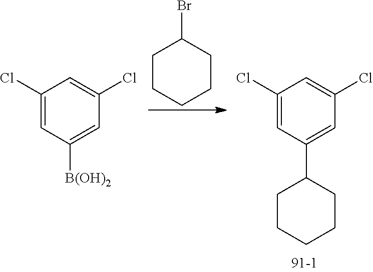

(3,5-dichlorophenyl)boronic acid (1.2 eq), bromocyclohexane (1 eq), tris(dibenzylideneacetone)dipalladium(0) (0.05 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 91-1. (yield: 84%)

### Synthesis of Intermediate 91-2

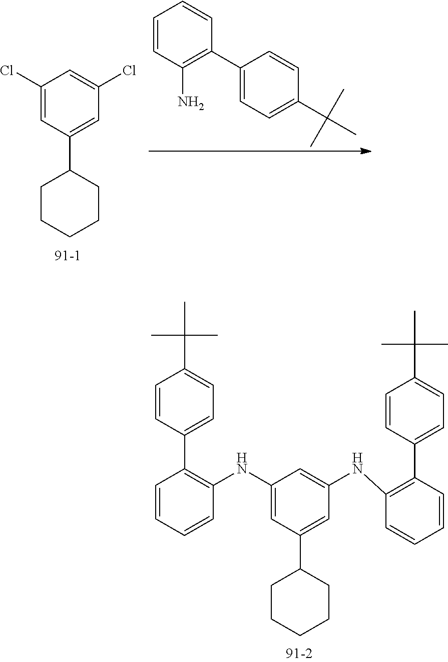

In a nitrogen atmosphere, Intermediate 91-1 (1 eq), 4′-(tert-butyl)-[1,1′-biphenyl]-2-amine (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 91-2. (yield: 73%)

### Synthesis of Intermediate 91-3

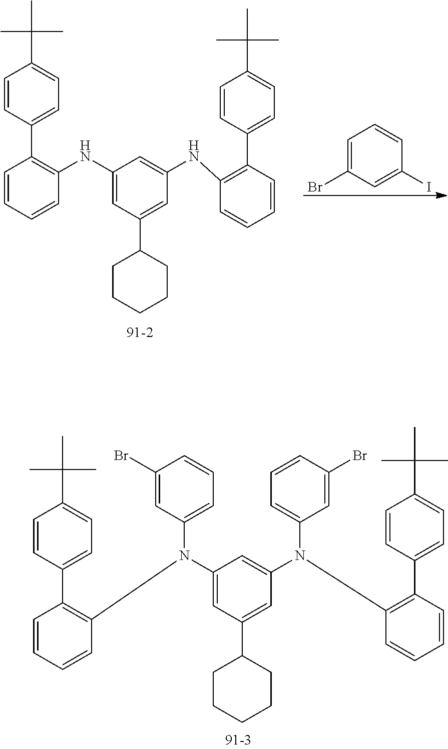

In a nitrogen atmosphere, Intermediate 91-2 (1 eq), 1-bromo-3-iodobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 91-3. (yield: 70%)

### Synthesis of Intermediate 91-4

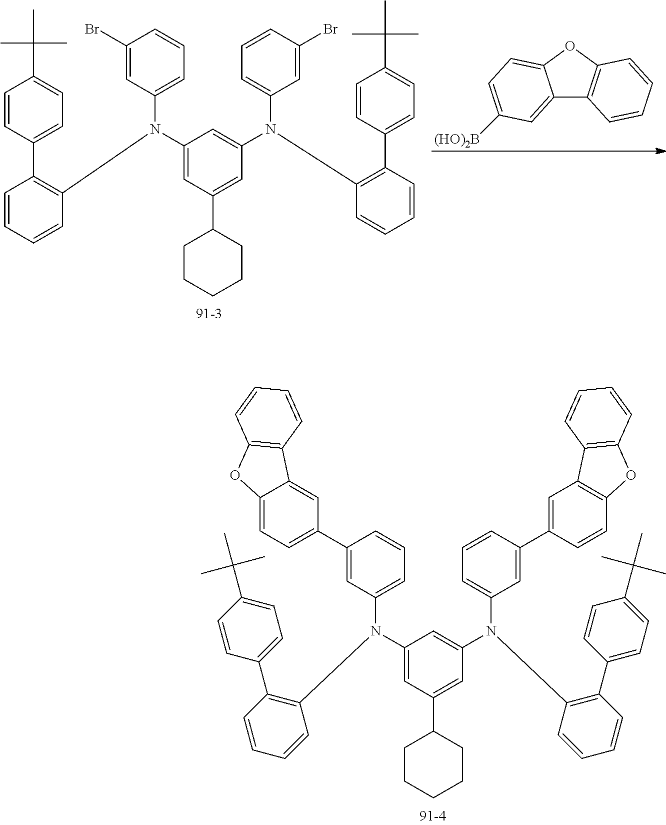

In an argon atmosphere, Intermediate 91-3 (1 eq), dibenzo[b,d]furan-2-ylboronic acid (2.5 eq), Pd(PPh₃)₄ (0.05 eq), and potassium carbonate (2 eq) were added and dissolved in toluene/H₂O, and the reaction solution was stirred at about 100° C. for about 12 hours. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 91-4. (yield: 80%)

### Synthesis of Compound 91

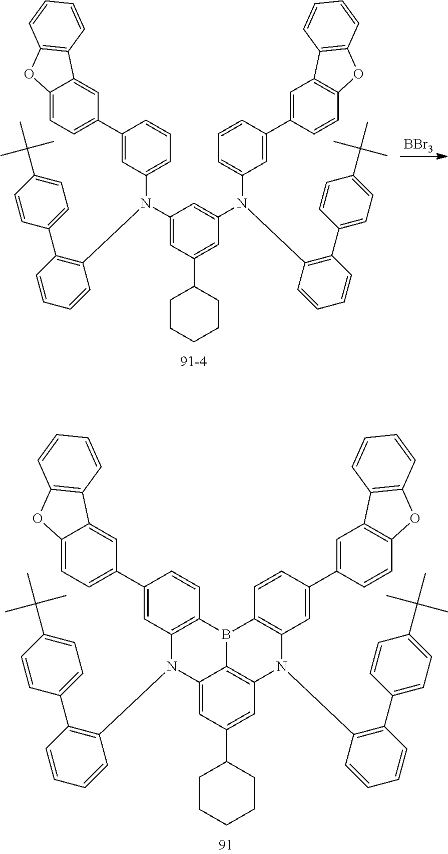

In a nitrogen atmosphere, Intermediate 91-4 (1 eq) was dissolved in o-dichlorobenzene, cooled using water and ice, and BBr₃ (5 eq) was slowly added dropwise thereto, and the reaction solution was stirred at about 180° C. for about 12 hours. After the reaction solution was cooled, the reaction was terminated by adding triethylamine (5 eq), the reaction solution was extracted with water/CH₂Cl₂ to collect organic layers, and the organic layers were dried over MgSO₄ and filtered. In the filtrate, the solvent was removed under reduced pressure to obtain a solid. The solid thus obtained was purified and separated by silica gel column chromatography to obtain Compound 91. (yield: 44%)

### (4) Synthesis of Compound 115

Compound 115 according to an example may be synthesized by, for example, the reaction below:

### Synthesis of Intermediate 115-1

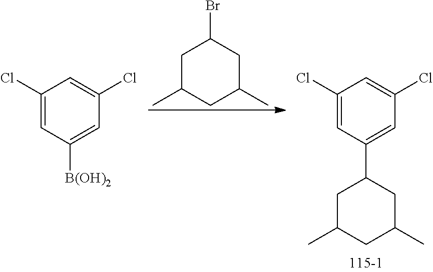

(3,5-dichlorophenyl)boronic acid (1.2 eq), 1-bromo-3,5-dimethylcyclohexane (1 eq), tris(dibenzylideneacetone)dipalladium(0) (0.05 eq), Pd(PPh₃)₄ (0.05 eq), and potassium carbonate (1.5 eq) were added and dissolved in a solvent of toluene:H₂O, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 115-1. (yield: 84%)

### Synthesis of Intermediate 115-2

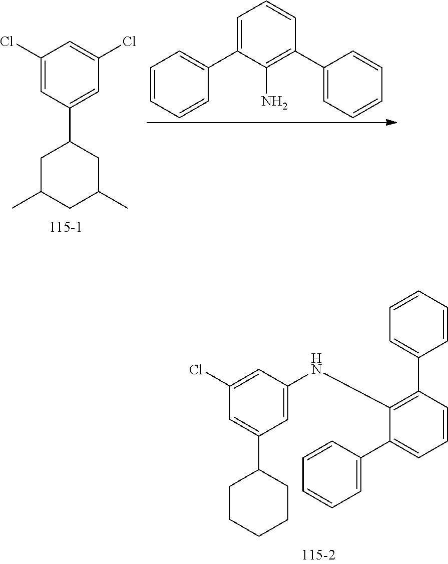

In a nitrogen atmosphere, Intermediate 115-1 (1 eq), [1,1′:3′,1″-terphenyl]-2′-amine (1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 115-2. (yield: 73%)

### Synthesis of Intermediate 115-3

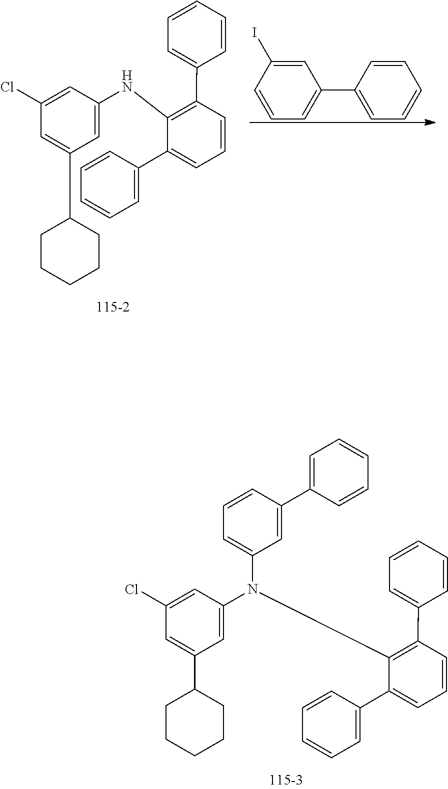

In a nitrogen atmosphere, Intermediate 115-2 (1 eq), 3-iodo-1,1′-biphenyl (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 115-3. (yield: 70%)

### Synthesis of Intermediate 115-4

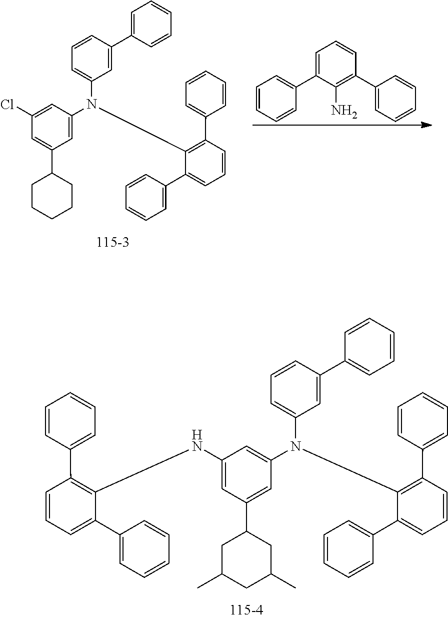

In a nitrogen atmosphere, Intermediate 115-3 (1 eq), [1,1′:3′,1″-terphenyl]-2′-amine (1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 115-4. (yield: 73%)

### Synthesis of Intermediate 115-5

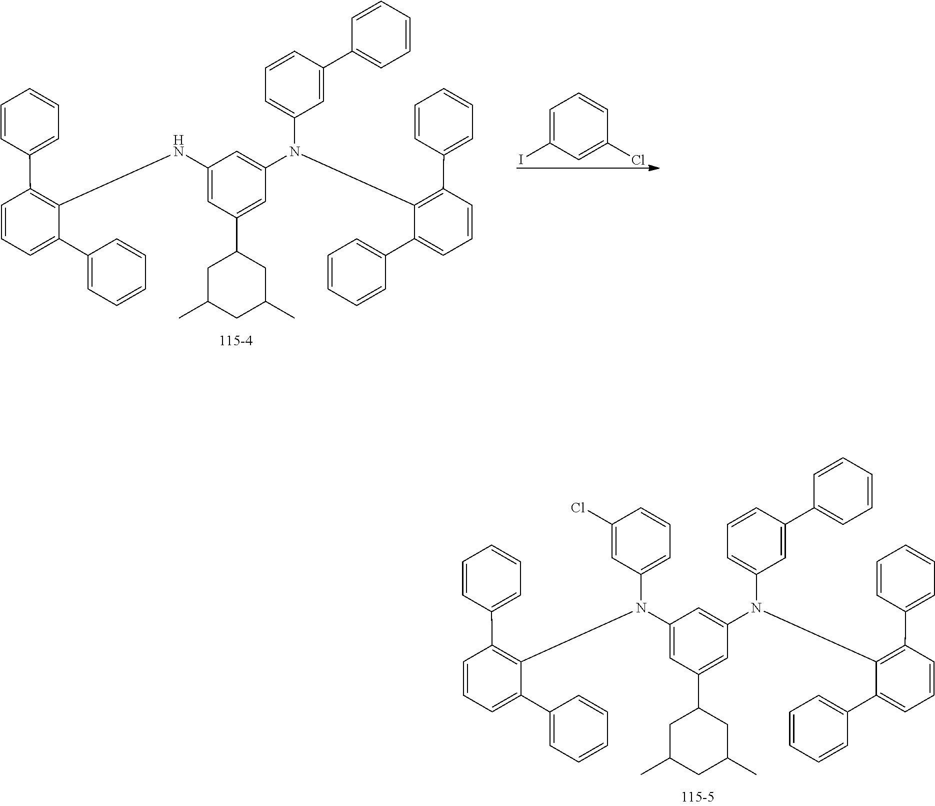 [SMILES: CC1CC(C)CC(c2cc(Nc3c(-c4ccccc4)cccc3-c3ccccc3)cc(N(c3cccc(-c4ccccc4)c3)c3c(-c4ccccc4)cccc3-c3ccccc3)c2)C1 ; Clc1cccc(I)c1 ; CC1CC(C)CC(c2cc(N(c3cccc(Cl)c3)c3c(-c4ccccc4)cccc3-c3ccccc3)cc(N(c3cccc(-c4ccccc4)c3)c3c(-c4ccccc4)cccc3-c3ccccc3)c2)C1]

In a nitrogen atmosphere, Intermediate 115-4 (1 eq), 1-chloro-3-iodobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 115-5. (yield: 70%)

### Synthesis of Intermediate 115-6

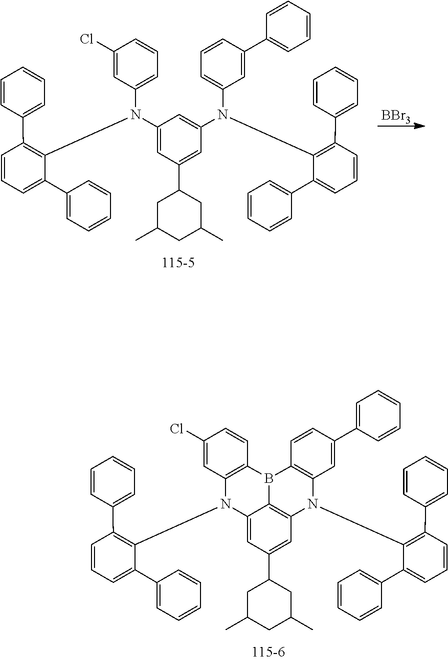

In a nitrogen atmosphere, Intermediate 115-5 (1 eq) was dissolved in o-dichlorobenzene, cooled using water and ice, and BBr₃ (5 eq) was slowly added dropwise thereto, and the reaction solution was stirred at about 180° C. for about 12 hours. After the reaction solution was cooled, the reaction was terminated by adding triethylamine (5 eq), the reaction solution was extracted with water/CH₂Cl₂ to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 115-6. (yield: 44%)

### Synthesis of Compound 115

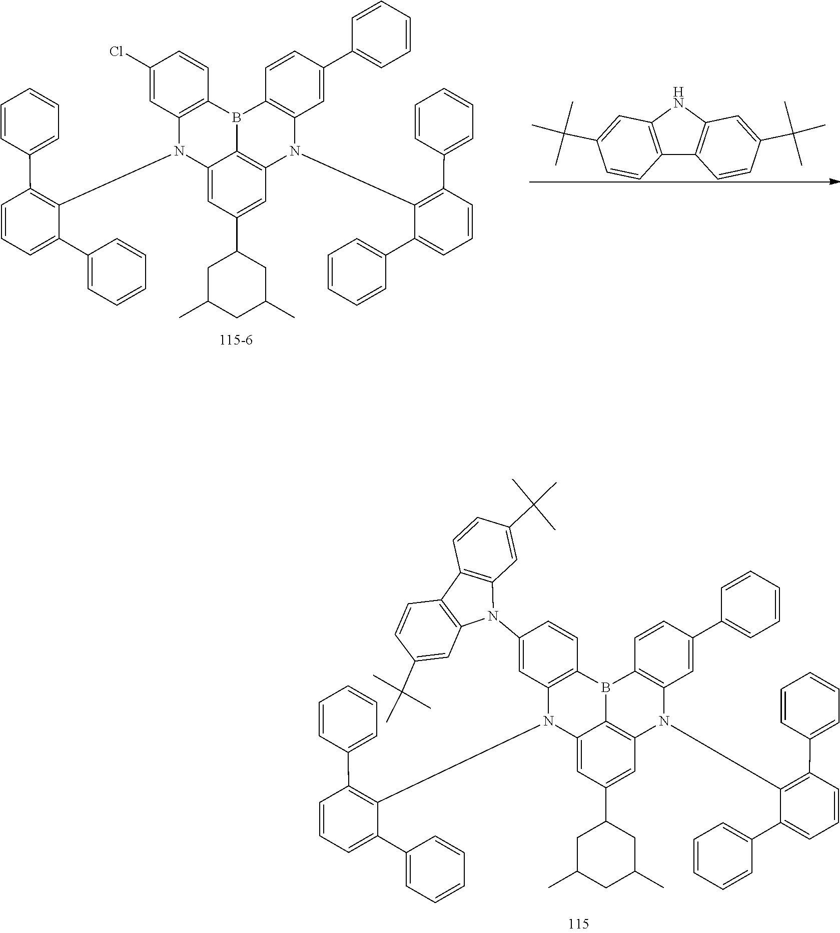 [SMILES: CC1CC(C)CC(c2cc3c4c(c2)N(c2c(-c5ccccc5)cccc2-c2ccccc2)c2cc(-c5ccccc5)ccc2B4c2ccc(Cl)cc2N3c2c(-c3ccccc3)cccc2-c2ccccc2)C1 ; CC(C)(C)c1ccc2c(c1)[nH]c1cc(C(C)(C)C)ccc12 ; CC1CC(C)CC(c2cc3c4c(c2)N(c2c(-c5ccccc5)cccc2-c2ccccc2)c2cc(-n5c6cc(C(C)(C)C)ccc6c6ccc(C(C)(C)C)cc65)ccc2B4c2ccc(-c4ccccc4)cc2N3c2c(-c3ccccc3)cccc2-c2ccccc2)C1]

In a nitrogen atmosphere, Intermediate 115-6 (1 eq), 3,6-di-tert-butyl-9H-carbazole (2.4 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Compound 115. (yield: 85%)

### (5) Synthesis of Compound 133

Compound 133 according to an example may be synthesized by, for example, the reaction below.

### Synthesis of Intermediate 133-1

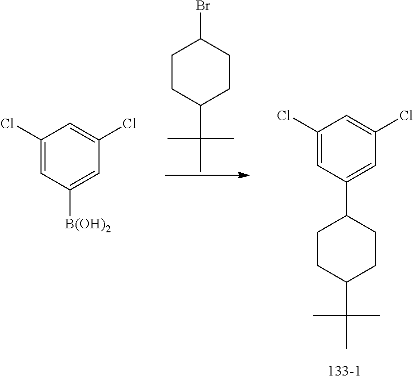

(3,5-dichlorophenyl)boronic acid (1.2 eq), 1-bromo-4-(tert-butyl)cyclohexane (1 eq), tris(dibenzylideneacetone)dipalladium(0) (0.05 eq), Pd(PPh₃)₄ (0.05 eq), and potassium carbonate (1.5 eq) were added and dissolved in a solvent of toluene:H₂O, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 133-1. (yield: 84%)

### Synthesis of Intermediate 133-2

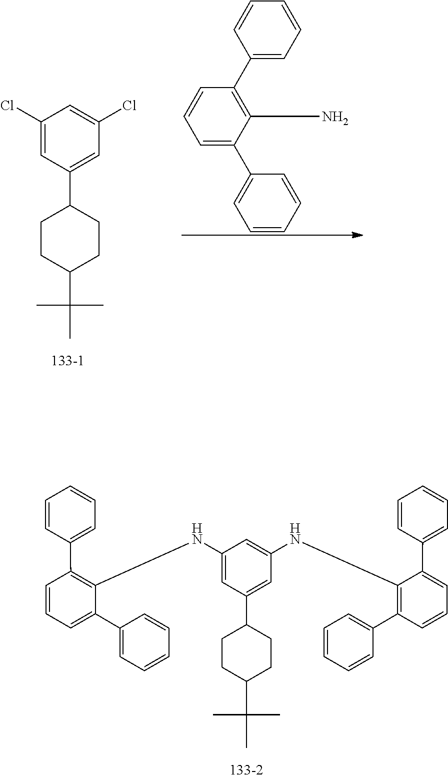 [SMILES: CC(C)(C)C1CCC(c2cc(Cl)cc(Cl)c2)CC1 ; Nc1c(-c2ccccc2)cccc1-c1ccccc1 ; CC(C)(C)C1CCC(c2cc(Nc3c(-c4ccccc4)cccc3-c3ccccc3)cc(Nc3c(-c4ccccc4)cccc3-c3ccccc3)c2)CC1]

In a nitrogen atmosphere, Intermediate 133-1 (1 eq), [1,1′:3′,1″-terphenyl]-2′-amine (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 133-2. (yield: 78%)

### Synthesis of Intermediate 133-3

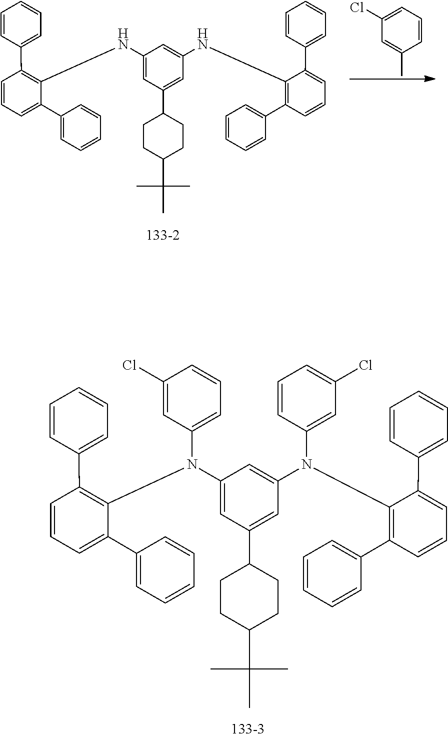

In a nitrogen atmosphere, Intermediate 133-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 133-3. (yield: 60%)

### Synthesis of Intermediate 133-4

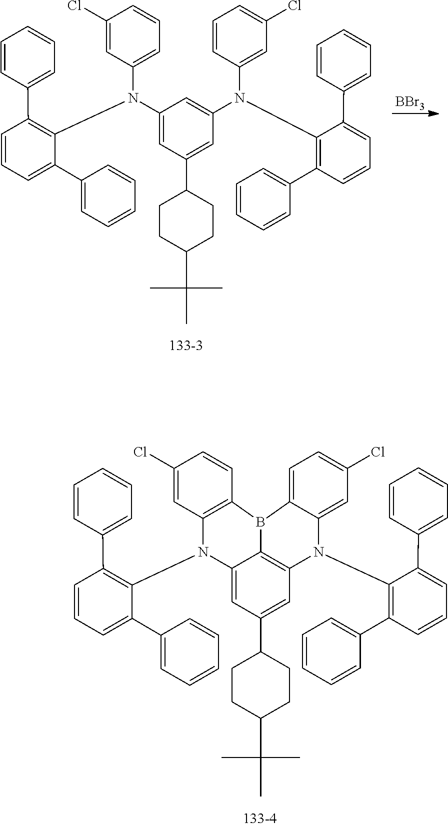

In a nitrogen atmosphere, Intermediate 133-3 (1 eq) was dissolved in o-dichlorobenzene, cooled using water and ice, and BBr₃ (5 eq) was slowly added dropwise thereto, and the reaction solution was stirred at about 180° C. for about 24 hours. After the reaction solution was cooled, the reaction was terminated by adding triethylamine (5 eq), the reaction solution was extracted with water/CH₂Cl₂ to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 133-4. (yield: 50%)

### Synthesis of Compound 133

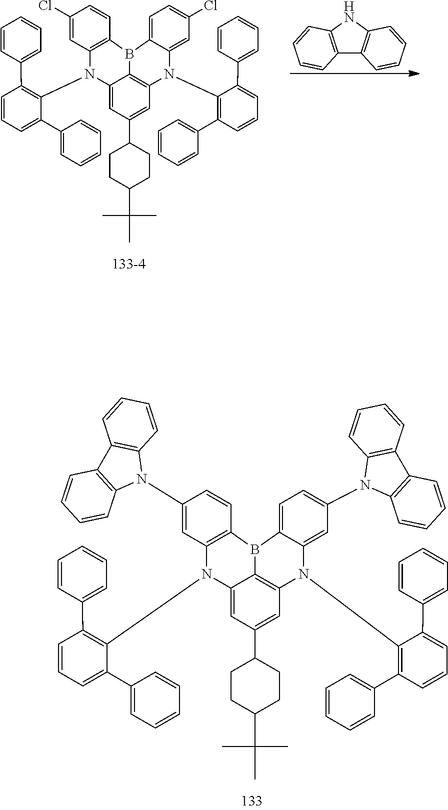

In a nitrogen atmosphere, Intermediate 133-4 (1 eq), 9H-carbazole (2.4 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Compound 133. (yield: 85%)

### (6) Synthesis of Compound 146

Compound 146 according to an example may be synthesized by, for example, the reaction below.

### Synthesis of Intermediate 146-1

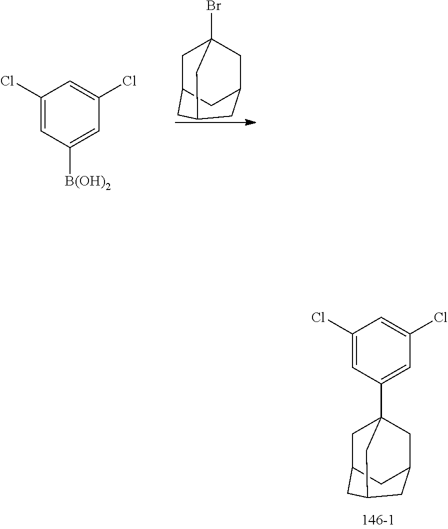 [SMILES: OB(O)c1cc(Cl)cc(Cl)c1 ; BrC12CC3CC(CC(C3)C1)C2 ; Clc1cc(Cl)cc(C23CC4CC(CC(C4)C2)C3)c1]

(3,5-dichlorophenyl)boronic acid (1.2 eq), 1-bromoadamantane (1 eq), tris(dibenzylideneacetone)dipalladium(0) (0.05 eq), Pd(PPh₃)₄ (0.05 eq), and potassium carbonate (1.5 eq) were added and dissolved in a solvent of toluene:H₂O, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 146-1. (yield: 84%)

### Synthesis of Intermediate 146-2

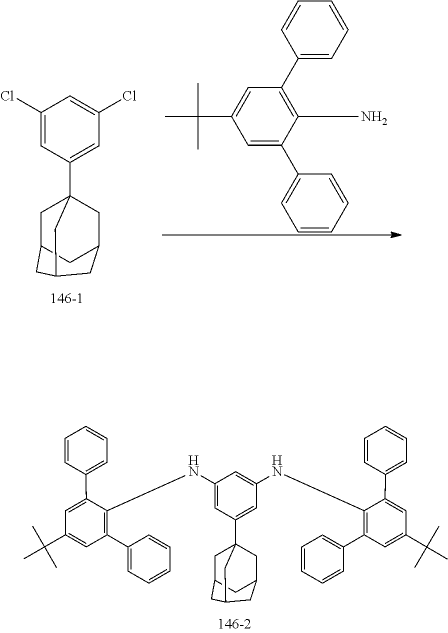 [SMILES: Clc1cc(Cl)cc(C23CC4CC(CC(C4)C2)C3)c1 ; CC(C)(C)c1cc(-c2ccccc2)c(N)c(-c2ccccc2)c1 ; CC(C)(C)c1cc(-c2ccccc2)c(Nc2cc(Nc3c(-c4ccccc4)cc(C(C)(C)C)cc3-c3ccccc3)cc(C34CC5CC(CC(C5)C3)C4)c2)c(-c2ccccc2)c1]

In a nitrogen atmosphere, Intermediate 146-1 (1 eq), 5′-(tert-butyl)-[1,1′:3′,1″-terphenyl]-2′-amine (2.1 eq), pd₂dba₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 146-2. (yield: 73%)

### Synthesis of Intermediate 146-3

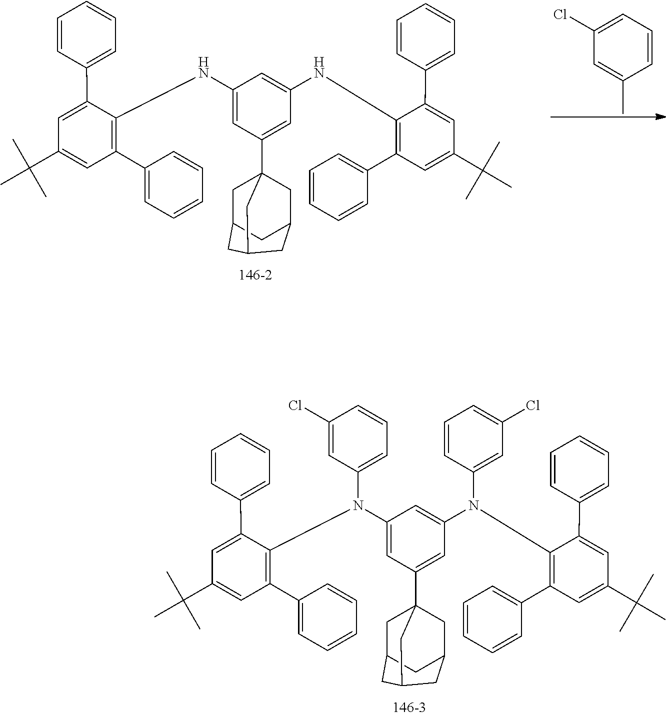

In a nitrogen atmosphere, Intermediate 146-2 (1 eq), 1-bromo-3-iodobenzene (10 eq), pd₂dba₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 146-3. (yield: 65%)

### Synthesis of Intermediate 146-4

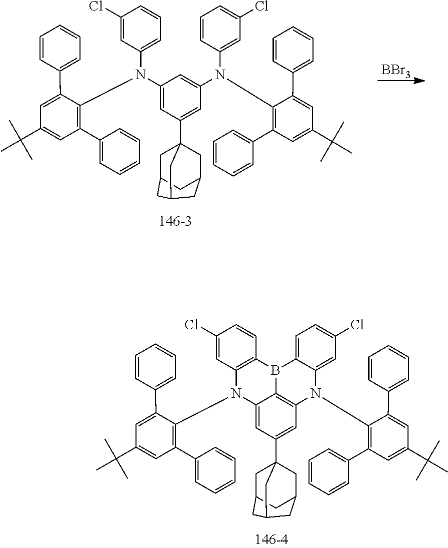

In a nitrogen atmosphere, Intermediate 146-3 (1 eq) was dissolved in o-dichlorobenzene, cooled using water and ice, and BBr₃ (5 eq) was slowly added dropwise thereto, and the reaction solution was stirred at about 180° C. for about 12 hours. After the reaction solution was cooled, the reaction was terminated by adding triethylamine (5 eq), the reaction solution was extracted with water/CH₂Cl₂ to collect organic layers, and the organic layers were dried over MgSO₄ and filtered. In the filtrate, the solvent was removed under reduced pressure to obtain a solid. The solid thus obtained was purified and separated by silica gel column chromatography to obtain Intermediate 146-4. (yield: 39%)

### Synthesis of Compound 146

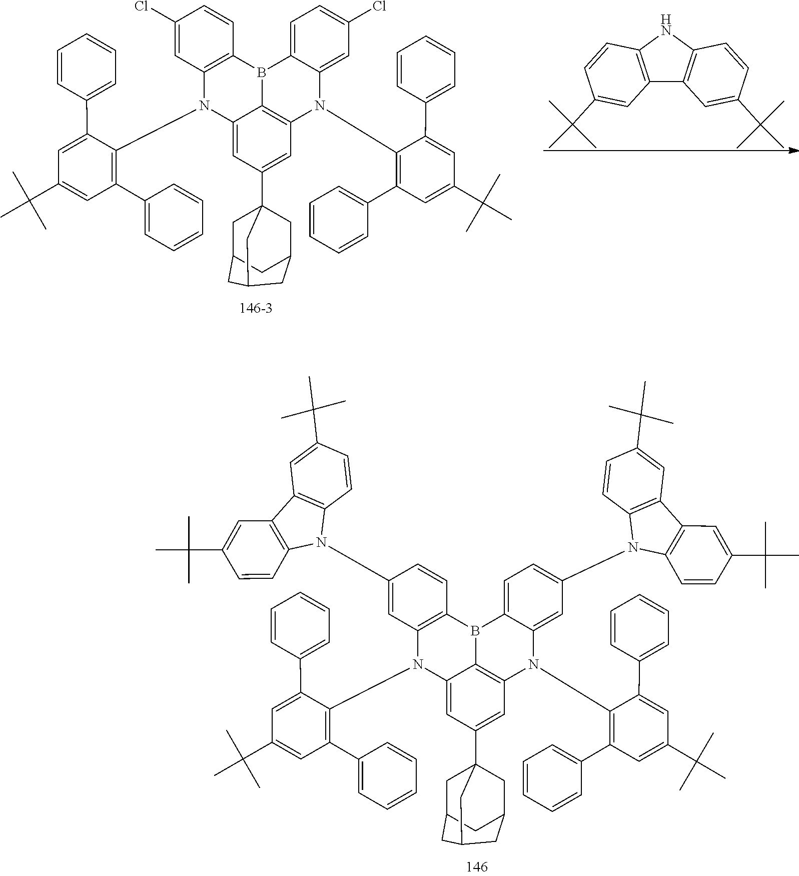

In a nitrogen atmosphere, Intermediate 146-4 (1 eq), 3,6-di-tert-butyl-9H-carbazole (2.4 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a solid. The solid thus obtained was purified and separated by silica gel column chromatography to obtain Compound 146. (yield: 80%)

¹H NMR and MS/FAB of the compounds according to Synthesis Examples (1) to (6) are shown in Table 1. The synthesis methods of other compounds may be readily recognized by those skilled in the art with reference to the above synthesis paths and raw materials.

TABLE 1

| | ¹H NMR chemical shift | MS-Cal. | MS-Meas. |
|---|---|---|---|
| 18 | 8.95 (d, 2H), 8.36 (d, 2H), 7.99 (s, 4H), 7.86 (m, 4H), 7.62 (m, 2H), 7.43- | 1473.90 | 1473.88 |
| | 7.39 (m, 16H), 7.23 (s, 2H), 7.08-7.07 (m, 12H), 2.72 (m, 1H), 1.85-1.46 | | |
| | (m, 10H), 1.43 (m, 36H), 1.32 (m, 18H). | | |
| 35 | 8.20 (d, 4H), 7.53 (s, 2H), 7.38-7.37 (m, 16H), 7.30-7.28 (m, 12H), 7.07 | 1295.70 | 1295.82 |
| | (s, 2H), 2.72 (m, 1H), 1.85-1.46 (m, 10H), 1.33-1.32 (m, 54H) | | |
| 91 | 8.10 (d, 2H), 7.98 (d, 2H), 7.88-2.79 (m, 8H), 7.54 (d, 2H), 7.43-7.30 | 1099.24 | 1098.53 |
| | (20H), 7.14 (t, 2H), 7.07 (s, 2H), 2.72 (m, 1H), 1.85-1.46 (m, 10H), 1.33 | | |
| | (m, 18H). | | |
| 115 | 8.35 (d, 1H), 8.20 (d, 4H), 8.13 (s, 1H), 8.04 (d, 1H), 7.80 (d, 2H), 7.75 | 1188.42 | 1187.63 |
| | (d, 2H), 7.50-7.39 (m, 21H), 7.27 (s, 2H), 7.08-7.03 (m, 11H), 2.72 (m, | | |
| | 1H), 1.54 (m, 6H), 1.38 (m, 18H), 0.86 (m, 6H). | | |
| 133 | 8.55 (d, 2H), 8.20-8.19 (m, 6H), 7.94 (d, 2H), 7.80 (d, 2H), 7.43-7.35 (m, | 1193.36 | 1192.56 |
| | 22H), 7.23-7.08 (m, 8H), 2.72 (m, 1H), 1.85-1.62 (m, 8H), 1.14 (m, 1H), | | |
| | 0.84 (m, 9H). | | |
| 146 | 8.95 (s, 2H), 8.36 (s, 2H), 7.99 (s, 4H), 7.89-7.80 (m, 4H), 7.62 (d, 2H), | 1525.97 | 1524.91 |
| | 7.50-7.39 (m, 8H), 7.23 (s, 2H), 7.11-7.08 (m, 12H), 2.05-1.99 (m, 8H), | | |
| | 1.87-1.72 (m, 12H), 1.43 (m, 36H), 1.32 (m, 18H). | | |

### 2. Manufacture and Evaluation of Light Emitting Devices 1

(1) Manufacture of Light Emitting Devices 1

A light emitting device including a fused polycyclic compound of an Example Compound in an emission layer was manufactured as follows. Compounds 18, 35, 91, 115, 133, and 146, which are Example Compounds as described above, were used as dopant materials for the emission layers to manufacture light emitting devices of Examples 1-1 to 1-6, respectively. Comparative Examples 1-1 to 1-5 correspond to the light emitting devices manufactured by using Comparative Example Compounds C1 to C5 as dopant materials for the emission layers, respectively.

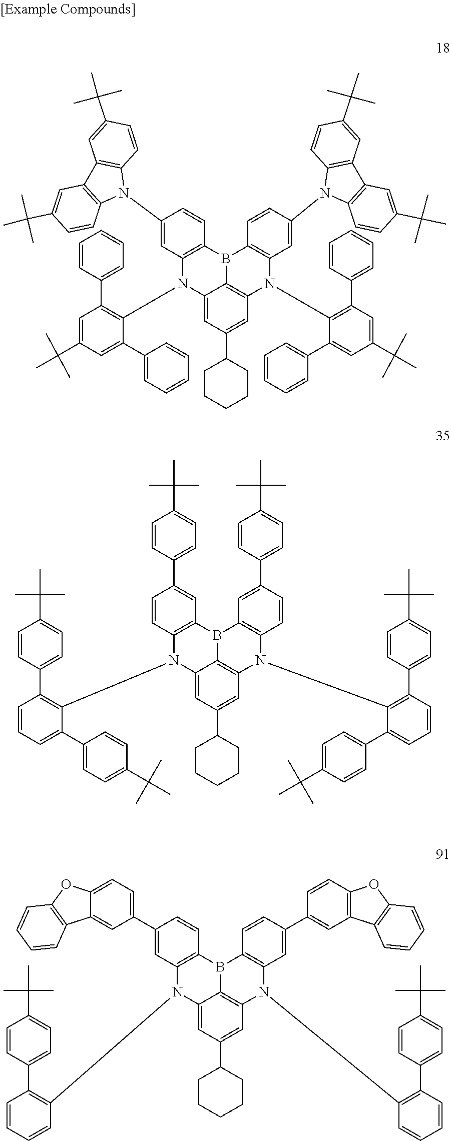

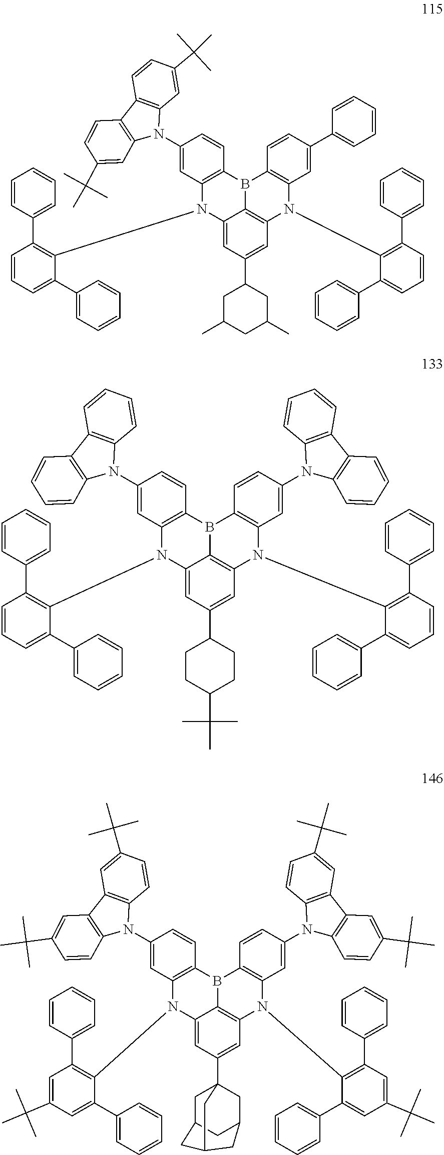

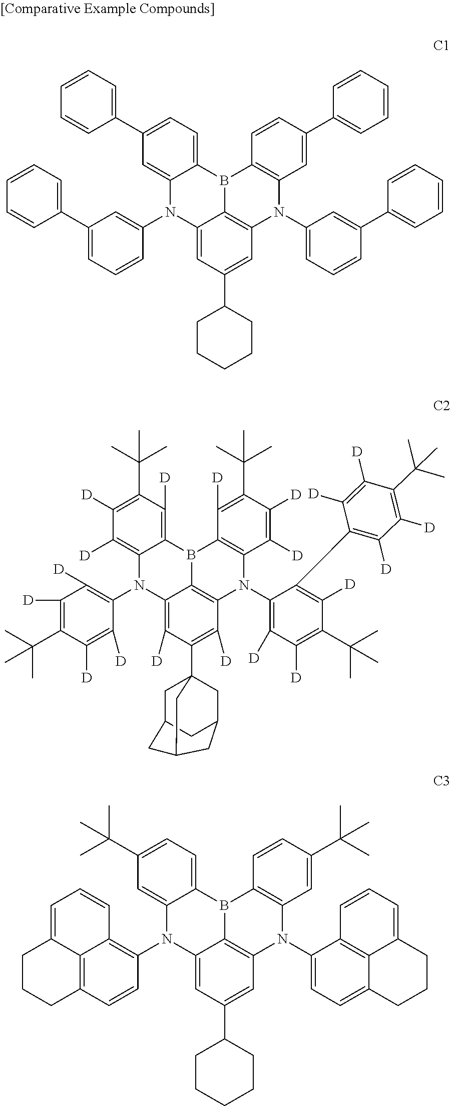 [SMILES: c1ccc(-c2cccc(N3c4cc(-c5ccccc5)ccc4B4c5ccc(-c6ccccc6)cc5N(c5cccc(-c6ccccc6)c5)c5cc(C6CCCCC6)cc3c54)c2)cc1 ; [2H]c1c([2H])c(C(C)(C)C)c([2H])c([2H])c1-c1c([2H])c(C(C)(C)C)c([2H])c([2H])c1N1c2c([2H])c([2H])c(C(C)(C)C)c([2H])c2B2c3c([2H])c(C(C)(C)C)c([2H])c([2H])c3N(c3c([2H])c([2H])c(C(C)(C)C)c([2H])c3[2H])c3c([2H])c(C45CC6CC(CC(C6)C4)C5)c([2H])c1c32 ; CC(C)(C)c1ccc2c(c1)N(c1ccc3c4c(cccc14)CCC3)c1cc(C3CCCCC3)cc3c1B2c1ccc(C(C)(C)C)cc1N3c1ccc2c3c(cccc13)CCC2]

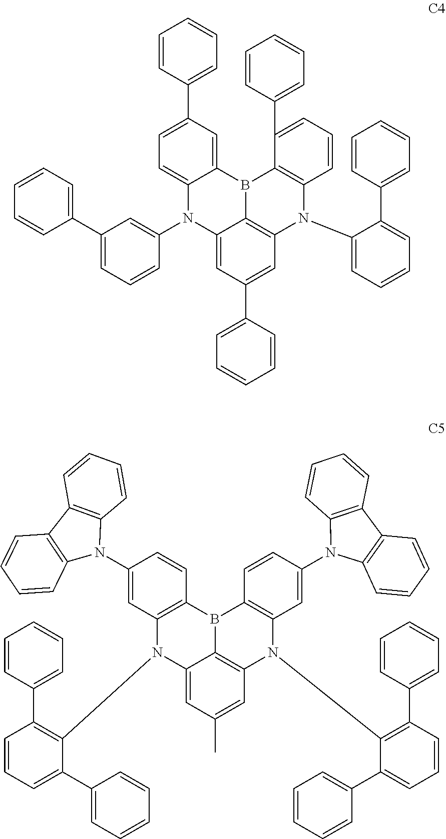 [SMILES: c1ccc(-c2cccc(N3c4ccc(-c5ccccc5)cc4B4c5c(-c6ccccc6)cccc5N(c5ccccc5-c5ccccc5)c5cc(-c6ccccc6)cc3c54)c2)cc1 ; Cc1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1c(-c2ccccc2)cccc1-c1ccccc1]

(Manufacture of Light Emitting Devices)

In the light emitting devices of the Examples and the Comparative Examples, a glass substrate (made by Corning Co.), on which an ITO electrode of about 15 Ω/cm² (about 1,200 Å) is formed as an anode, was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone and cleansed. The glass substrate was installed on a vacuum deposition apparatus.

NPD was deposited on the upper portion of the anode to form a 300 Å-thick hole injection layer, a hole transport material was deposited on the upper portion of the hole injection layer to form a 200 Å-thick hole transport layer, and CzSi was deposited on the upper portion of the hole transport layer to form a 100 Å-thick emission-auxiliary layer.

A host mixture in which the second compound and the third compound according to an embodiment were mixed at a ratio of about 1:1, the fourth compound, and an Example Compound or a Comparative Example Compound were co-deposited at a weight ratio of about 85:14:1 to form a 200 Å-thick emission layer, and on the upper portion of the emission layer, TSPO1 was deposited to form a 200 Å-thick hole blocking layer. On the upper portion of the hole blocking layer, TPBI was deposited to form a 300 Å-thick electron transport layer, and on the upper portion of the electron transport layer, LiF was deposited to form a 10 Å-thick electron injection layer. On the upper portion of the electron injection layer, Al was deposited to form a 3,000 Å-thick cathode, and P4 was deposited on the cathode to form a 700 Å-thick capping layer, thereby manufacturing a light emitting device.

Each layer was formed by a vacuum deposition method. Compounds H-1-2, H-1-3, H-1-4, and H-1-5 among the compounds as described above in Compound Group H were used as hole transport materials; Compounds HT1, HT2, HT3, and HT4 among the compounds as described above in Compound Group 2 were used as the second compound; Compounds ETH85, ETH66, and EHT86 among the compounds as described above in Compound Group 3 were used as the third compound; and Compounds AD-37 and AD-38 among the compounds as described above in Compound Group 4 were used as the fourth compound.

Compounds used for manufacturing the light emitting devices of Examples and Comparative Examples are disclosed below. The materials below were used to manufacture the devices by subjecting commercial products to sublimation purification.

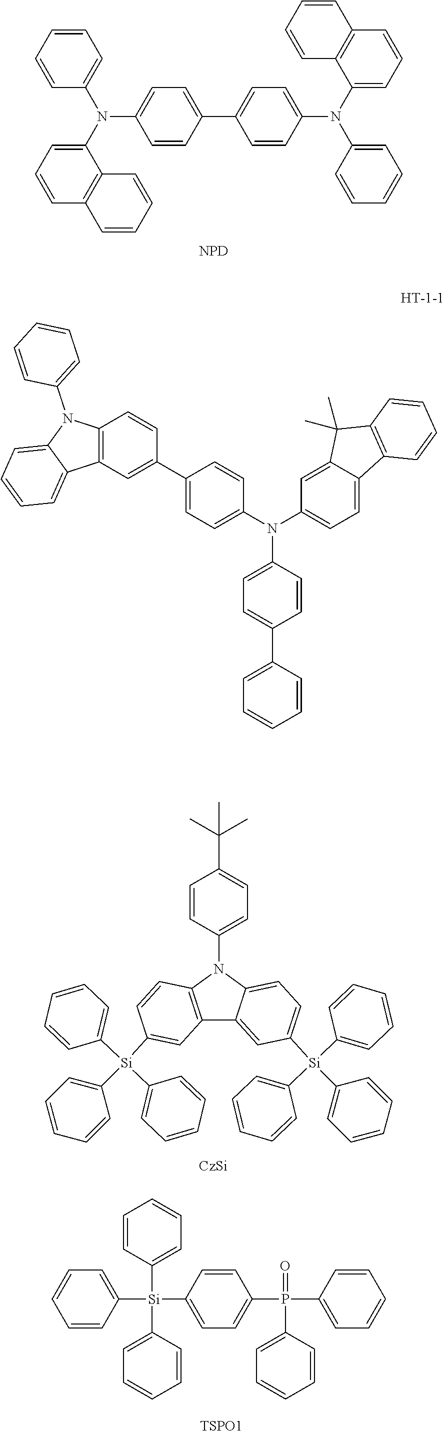

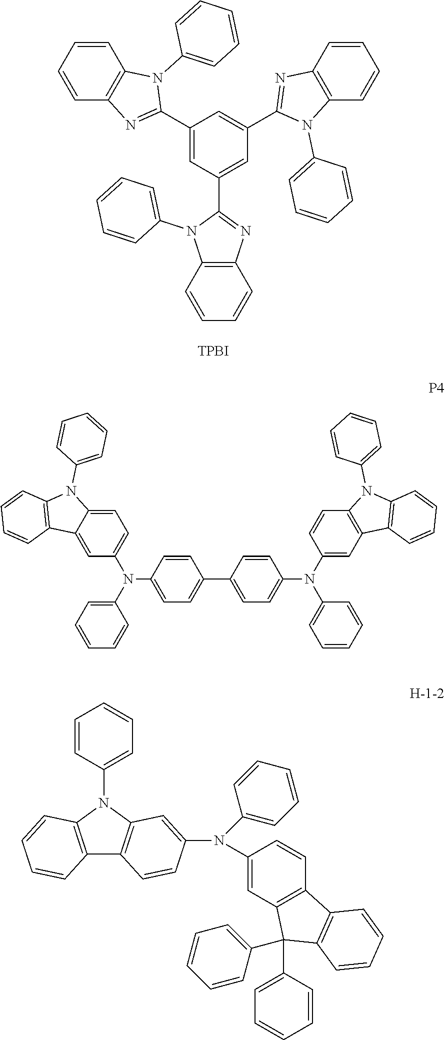

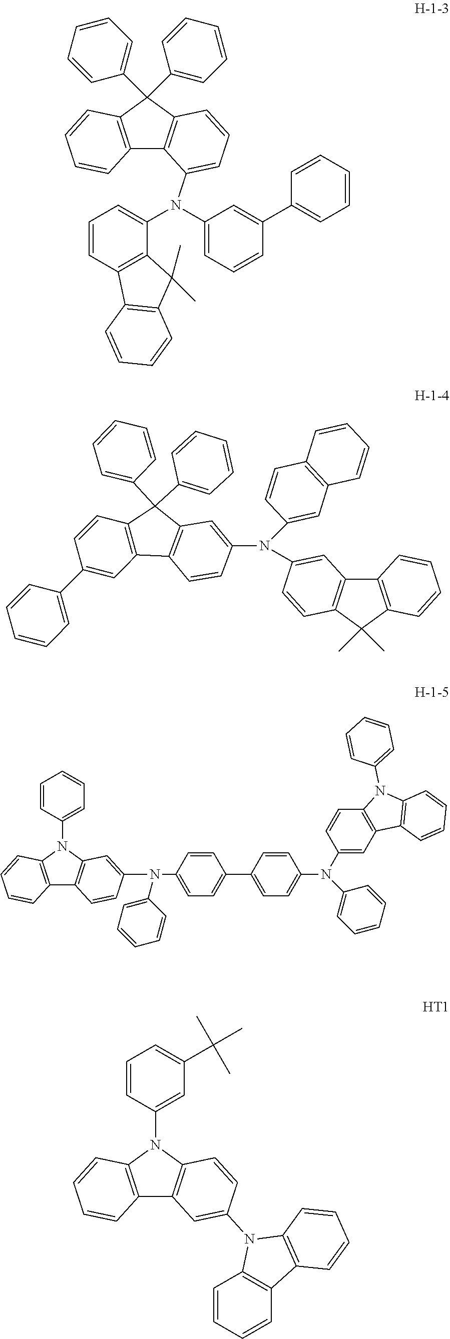 [SMILES: CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; CC(C)(C)c1cccc(-n2c3ccccc3c3cc(-n4c5ccccc5c5ccccc54)ccc32)c1]

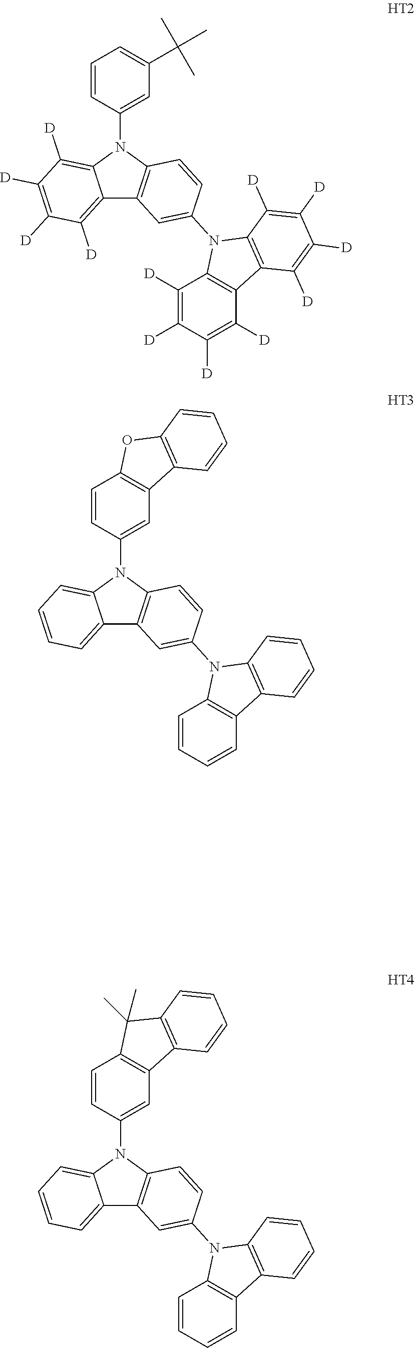

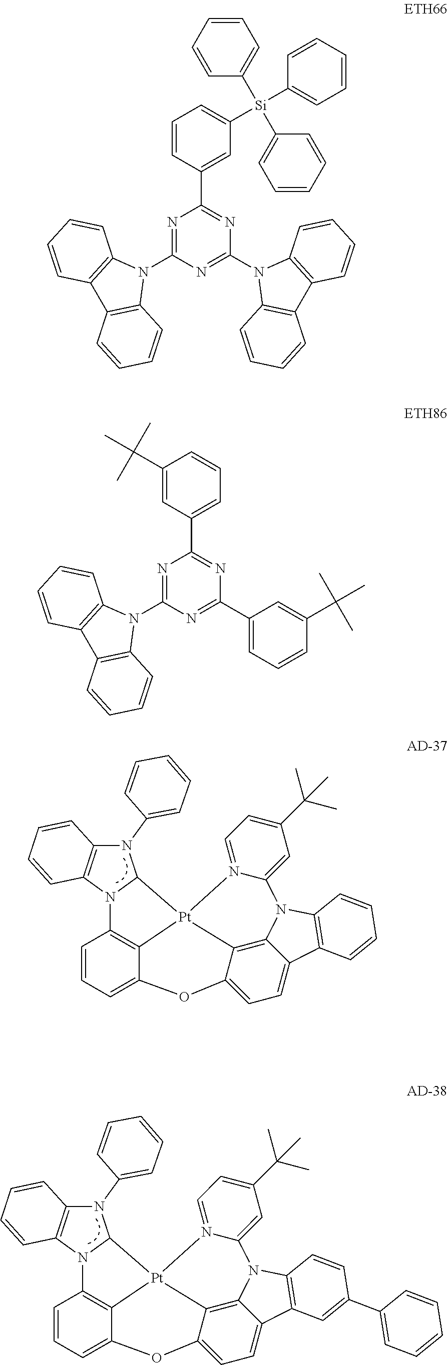

(2) Evaluation of Light Emitting Device Characteristics 1

Device efficiency and device service life of the light emitting device manufactured with Example Compounds 18, 35, 91, 115, 133, and 146, and Comparative Example Compounds C1 to C5 as described above were evaluated. Evaluation results of the light emitting devices of Examples 1-1 to 1-6 and Comparative Examples 1-1 to 1-5 are listed in Table 2. To evaluate the characteristics of the light emitting devices manufactured in Examples 1-1 to 1-6 and Comparative Examples 1-1 to 1-5 above, each of driving voltages (V), luminous efficiencies (Cd/A), maximum external quantum efficiencies (%), and emission colors at a current density of 1,000 cd/m² was measured by using Keithley MU 236 and a luminance meter PR650, and the time taken to reach 9500 brightness relative to an initial brightness was measured as a service life (T95), and a relative service life was calculated on the basis of the device of Comparative Example 1-1, and the results are listed in Table 2.

TABLE 2

| | | Host | | | | | | | |
|---|---|---|---|---|---|---|---|---|---|
| | | (second | | | | | Maximum | | |
| | | compound: | | | | | external | Service | |
| | Hole | third | | | Driving | | quantum | life | |
| | transport | compound = | Fourth | First | voltage | Efficiency | efficiency | ratio | Emission |
| | layer | 5:5) | compound | compound | (V) | (cd/A) | (%) | (T95) | color |
| Example 1-1 | H-1-3 | HT1/ | AD-38 | Example | 4.2 | 25.8 | 24.6 | 184 | Blue |
| | | ETH66 | | Compound 18 | | | | | |
| Example 1-2 | H-1-5 | HT2/ | AD-38 | Example | 4.3 | 19.5 | 18.3 | 137 | Blue |
| | | ETH86 | | Compound 35 | | | | | |
| Example 1-3 | H-1-4 | HT2/ | AD-37 | Example | 4.2 | 21.1 | 20.2 | 151 | Blue |
| | | ETH86 | | Compound 91 | | | | | |
| Example 1-4 | H-1-4 | HT4/ | AD-37 | Example | 4.5 | 24.2 | 22.6 | 169 | Blue |
| | | ETH66 | | Compound 115 | | | | | |
| Example 1-5 | H-1-2 | HT1/ | AD-38 | Example | 4.4 | 26.5 | 25.2 | 188 | Blue |
| | | ETH86 | | Compound 133 | | | | | |
| Example 1-6 | H-1-5 | HT1/ | AD-37 | Example | 4.5 | 20.1 | 19.3 | 141 | Blue |
| | | ETH86 | | Compound 146 | | | | | |
| Comparative | H-1-4 | HT2/ | AD-37 | Comparative | 4.4 | 13.4 | 12.3 | 100 | Blue |
| Example 1-1 | | ETH86 | | Example | | | | | |
| | | | | Compound C1 | | | | | |
| Comparative | H-1-3 | HT2/ | AD-38 | Comparative | 4.5 | 10.8 | 10.2 | 54 | Blue |
| Example 1-2 | | ETH86 | | Example | | | | | |
| | | | | Compound C2 | | | | | |
| Comparative | H-1-4 | HT2/ | AD-37 | Comparative | 4.4 | 13.4 | 12.3 | 64 | Blue |
| Example 1-3 | | ETH66 | | Example | | | | | |
| | | | | Compound C3 | | | | | |
| Comparative | H-1-2 | HT4/ | AD-38 | Comparative | 4.5 | 10.8 | 10.2 | 128 | Blue |
| Example 1-4 | | ETH86 | | Example | | | | | |
| | | | | Compound C4 | | | | | |
| Comparative | H-1-4 | HT4/ | AD-37 | Comparative | 4.3 | 16.5 | 15.9 | 130 | Blue |
| Example 1-5 | | ETH86 | | Example | | | | | |
| | | | | Compound C5 | | | | | |

Referring to the results of Table 2, it may be confirmed that the light emitting devices according to the Examples, in which the fused polycyclic compounds according to the Example Compounds are used as a luminescent material, have improved luminous efficiency and service life characteristics as compared with the light emitting devices according to the Comparative Examples. The Example Compounds have a fused ring core in which the first to third aromatic rings are fused around a boron atom and the first and second nitrogen atoms, and thus may have an increase in multiple resonance effects and have a low ΔE_{ST}. Accordingly, since reverse intersystem crossing (RISC) from the triplet excited state to the singlet excited state readily occurs, delayed fluorescence characteristics may be enhanced, thereby improving the luminous efficiency.

The Example Compounds include the first to third substituents, which are steric hindrance substituents and are linked to the fused ring core, and thus may effectively protect the boron atom, thereby achieving high efficiency and a long service life. The Example Compounds may each have an increase in the luminous efficiency and may suppress the red shift of luminescence wavelength because the intermolecular interaction may be suppressed by the introduction of the first to third substituents, thereby controlling the formation of an excimer or an exciplex. The Example Compounds each have an increase in the distance between adjacent molecules due to the large steric hindrance structure to thereby suppress Dexter energy transfer, and thus may suppress the deterioration of service life due to the increase of triplet concentration. The above-described substituted position effects and steric hindrance effects work synergistically, and thus when the fused polycyclic compound according to the Example Compounds is introduced as a material for the emission layer of the light emitting device, high efficiency and a long service life may be achieved.

The light emitting device of an example includes the first compound of an example as a light emitting dopant of a thermally activated delayed fluorescence (TADF) light emitting device, and thus may achieve high device efficiency in a blue wavelength region, particularly, a deep blue wavelength region.

Referring to Comparative Examples 1-1 and 1-3, it may be confirmed that Comparative Example Compounds C1 to C3 each include a fused ring core having one boron atom and two nitrogen atoms at the center thereof and have a structure in which a cyclohexyl group which is the first substituent is substituted at the fused ring core, but do not include the second and third substituents according to embodiments, and thus when Comparative Example Compounds C1 to C3 are applied to the devices, the devices have lower luminous efficiencies and device service lives compared to Examples. Like the fused polycyclic compound according to embodiments, inclusion of all the first to third substituents, which are linked to the fused ring core, may achieve high luminous efficiency and a long service life in a blue light wavelength region.

Referring to Comparative Example 1-2, it may be confirmed that Comparative Example Compound C2 includes a structure in which an adamantyl group, the first substituent, is linked to the fused ring core, but the luminous efficiency and device service life characteristics are reduced compared to Examples. In the case of Comparative Example Compound C2, it is thought that an ortho-type biphenyl group is linked to one nitrogen atom of the two nitrogen atom constituting the fused ring, but a phenyl group is linked to the other nitrogen atom, and thus the steric hindrance effect is not sufficient compared to Example Compounds, and thus when Comparative Example Compound C2 is applied to the light emitting device, the luminous efficiency and service life are reduced compared to Examples.

Referring to Comparative Example 1-4, it may be confirmed that Comparative Example Compound C4 does not include the first substituent linked to the fused ring core, and thus the luminous efficiency and device life are reduced compared to Examples. In Comparative Example Compound C4, an o-biphenyl group is linked to one nitrogen atom of the two nitrogen atom constituting the fused ring, but an m-biphenyl group is linked to the other nitrogen atom, and thus the steric hindrance effect is not sufficient compared to Example Compounds, and thus when Comparative Example Compound C4 is applied to the light emitting device, the luminous efficiency and service life may be reduced. Furthermore, Comparative Example Compound C4 is a compound in which a phenyl group instead of the first substituent is introduced to the position at which the first substituent is substituted compared to the Example Compounds, and conjugation is expanded to the phenyl group substituted at the fused ring core, thereby the luminescence wavelength may be red-shifted, and thus it may be difficult to achieve high device efficiency in a blue wavelength region like Example Compounds.

Referring to Comparative Examples 1-5, it may be confirmed that Comparative Example Compound C5 does not include the first substituent linked to the fused ring core, and thus the luminous efficiency and device life are reduced compared to Examples. When Example 1-5 and Comparative Example 1-5 including Example Compound 133 and Comparative Example Compound C5, respectively, having a similar structure are compared, it may be confirmed that Example 1-5 including Example Compound 133 in which a cycloalkyl group is substituted at the fused ring core has significantly improved luminous efficiency and service life as compared with Comparative Example 1-5. On the other hand, it may be confirmed that Comparative Example Compound C5 included in Comparative Example 1-5 has a methyl group, which is an acyclic alkyl group, substituted at the fused ring, and thus when Comparative Example Compound C5 is applied to the device, the luminous efficiency and device service life are reduced compared to Examples. In the case of a compound having a structure in which an acyclic alkyl group is substituted at the fused ring core like Comparative Example Compound C5, the steric hindrance effect is less than the Example Compound in which a cycloalkyl group is substituted, and thus when the compound is applied to the light emitting device, the luminous efficiency and device service life may be reduced. On the other hand, Example Compounds include the first substituent having a bulky structure in the fused polycyclic compound, and thus the steric hindrance effect is increased, so that it may be expected to have improved luminous efficiency and device service life characteristics.

### 3. Manufacture and Evaluation of Light Emitting Devices 2

(1) Manufacture of Light Emitting Devices 2

A light emitting device including a fused polycyclic compound of an Example Compound in an emission layer was manufactured as follows. Compounds 18, 35, 91, 115, 133, and 146, which are Example Compounds as described above, were used as dopant materials for the emission layers to manufacture the light emitting devices of Examples 2-1 to 2-6, respectively. Comparative Examples 2-1 to 2-5 correspond to the light emitting devices manufactured by using Comparative Example Compounds C1 to C5 as dopant materials for the emission layers, respectively.

The light emitting devices of Examples 2-1 to 2-6 were manufactured in the same manner as in the manufacture method of the light emitting devices of Examples 1-1 to 1-6 as described above except for the formation method of the emission layer. The light emitting devices of Examples 2-1 to 2-6 were manufactured in the same manner as in the manufacture method of the light emitting devices of Examples 1-1 to 1-6 as described above, except that the fourth compound was not provided in the formation of the emission layer. In the light emitting devices of Examples 2-1 to 2-6, the host compound and Example Compound were co-deposited at a weight ratio of 99:1. As described above, the host compound is provided by mixing the second compound and the third compound at a weight ratio of 5:5.

The light emitting devices of Comparative Examples 2-1 to 2-5 were manufactured in the same manner as in the manufacture method of the light emitting devices of Comparative Examples 1-1 to 1-5 as described above except for the formation method of the emission layer. The light emitting devices of Comparative Examples 2-1 to 2-5 were manufactured in the same manner as in the manufacture method of the light emitting devices of Comparative Examples 1-1 to 1-5 as described above except that the fourth compound was not provided. In the light emitting devices of Comparative Examples 2-1 to 2-5, the host compound and Comparative Example Compound were co-deposited at a weight ratio of 99:1.

(2) Evaluation of Light Emitting Device Characteristics 2

Evaluation results of the light emitting devices of Examples 2-1 to 2-6 and Comparative Examples 2-1 to 2-5 are listed in Table 3. Driving voltages (V), luminous efficiencies (Cd/A), maximum external quantum efficiencies (%), emission colors, and service lives (T95) in Table 3 were measured in the same manner as in the evaluation method as described with reference to Table 2.

TABLE 3

| | | Host | | | Maximum | |
|---|---|---|---|---|---|---|
| | | (second | | | external | |
| | Hole | compound:third | | | quantum | |
| | transport | compound = | | Efficiency | efficiency | Emission |
| | layer | 5:5) | First compound | (cd/A) | (%) | color |
| Example 2-1 | H-1-3 | HT1/ETH66 | Example Compound | 8.6 | 8.0 | Blue |
| | | | 18 | | | |
| Example 2-2 | H-1-5 | HT2/ETH86 | Example Compound | 6.1 | 5.9 | Blue |
| | | | 35 | | | |
| Example 2-3 | H-1-4 | HT2/ETH86 | Example Compound | 7.4 | 6.9 | Blue |
| | | | 91 | | | |
| Example 2-4 | H-1-4 | HT4/ETH66 | Example Compound | 7.9 | 7.6 | Blue |
| | | | 115 | | | |
| Example 2-5 | H-1-2 | HT1/ETH86 | Example Compound | 8.4 | 8.1 | Blue |
| | | | 133 | | | |
| Example 2-6 | H-1-5 | HT1/ETH86 | Example Compound | 6.6 | 6.2 | Blue |
| | | | 146 | | | |
| Comparative | H-1-4 | HT2/ETH86 | Comparative Example | 4.7 | 4.3 | Blue |
| Example 2-1 | | | Compound C1 | | | |
| Comparative | H-1-3 | HT2/ETH86 | Comparative Example | 2.8 | 2.5 | Blue |
| Example 2-2 | | | Compound C2 | | | |
| Comparative | H-1-4 | HT2/ETH66 | Comparative Example | 3.2 | 2.8 | Blue |
| Example 2-3 | | | Compound C3 | | | |
| Comparative | H-1-2 | HT4/ETH86 | Comparative Example | 5.2 | 4.8 | Blue |
| Example 2-4 | | | Compound C4 | | | |
| Comparative | H-1-4 | HT4/ETH86 | Comparative Example | 5.8 | 5.2 | Blue |
| Example 2-5 | | | Compound C5 | | | |

Referring to the results of Table 3, it may be confirmed that the light emitting devices according to the Examples, in which the fused polycyclic compounds according to the Example Compounds are used as a luminescent material, have improved luminous efficiency and service life characteristics as compared with the light emitting devices according to the Comparative Examples. When Examples 1-1 to 1-6 in Table 2 and Examples 2-1 to 2-6 in Table 3 are compared, it may be seen that Examples 1-1 to 1-6 have improved luminous efficiency and service life characteristics as compared with Examples 2-1 to 2-6 that do not include the fourth compound in the emission layer.

The light emitting device of an embodiment may exhibit improved device characteristics with high efficiency and a long service life.

The fused polycyclic compound of an embodiment may be included in the emission layer of the light emitting device to contribute to high efficiency and a long service life of the light emitting device.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting device comprising:
a first electrode;
a second electrode facing the first electrode; and
an emission layer disposed between the first electrode and the second electrode, wherein
the emission layer includes a first compound represented by Formula 1: 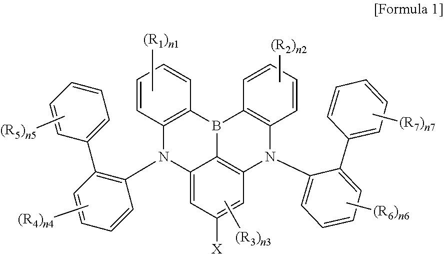
wherein in Formula 1,
X is a substituted or unsubstituted cycloalkyl group having 6 to 12 ring-forming carbon atoms,
R₁ to R₇ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
n1, n2, n4, and n6 are each independently an integer from 0 to 4,
n3 is an integer from 0 to 2, and
n5 and n7 are each independently an integer from 0 to 5.

2. The light emitting device of claim 1, wherein X is a group represented by one of Formula A-1 to Formula A-4: 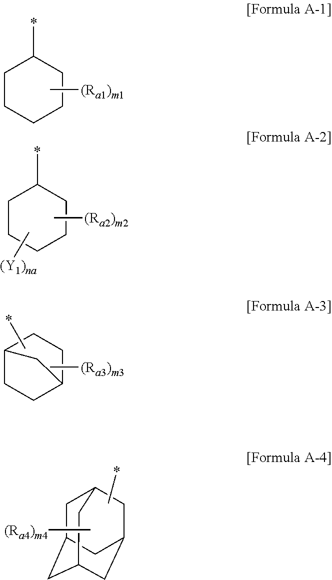
wherein in Formula A-1 to Formula A-4,
Rₐ₁ to Rₐ₄ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Y₁ is a substituted or unsubstituted alkyl group having 1 to 10 carbon atoms,
m1 and m3 are each independently an integer from 0 to 11,
m2 is an integer from 0 to 10,
na is an integer from 1 to 11,
a sum of m2 and na is less than or equal to 11,
m4 is an integer from 0 to 15, and [symbol]
represents a position linked to Formula 1.

3. The light emitting device of claim 1, wherein the first compound is represented by one of Formula 2-1 to Formula 2-3: 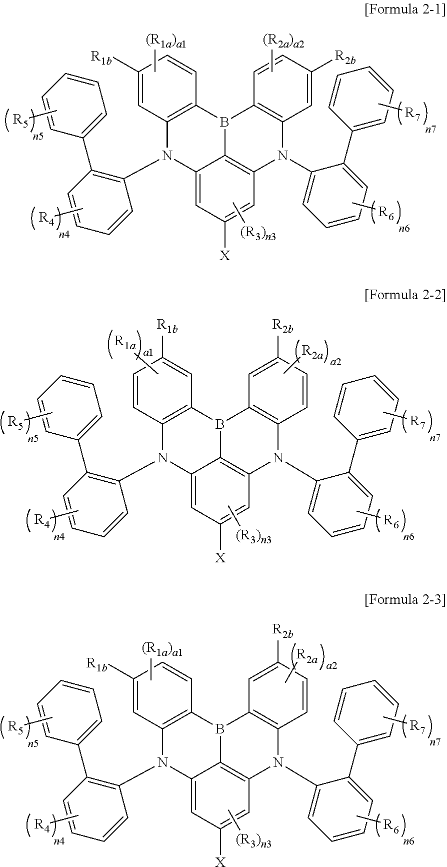
wherein in Formula 2-1 to Formula 2-3,
R₁ₐ and R₂ₐ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{1b} and R_{2b} are each independently a substituted or unsubstituted aryl group having 6 to 30 ring-forming carbon atoms or a substituted or unsubstituted heteroaryl group having 2 to 30 ring-forming carbon atoms,
a1 and a2 are each independently an integer from 0 to 3, and
X, R₃ to R₇, and n3 to n7 are the same as defined in Formula 1.

4. The light emitting device of claim 3, wherein R_{1b} and R_{2b} are each independently a group represented by one of Formula B-1 to Formula B-3: 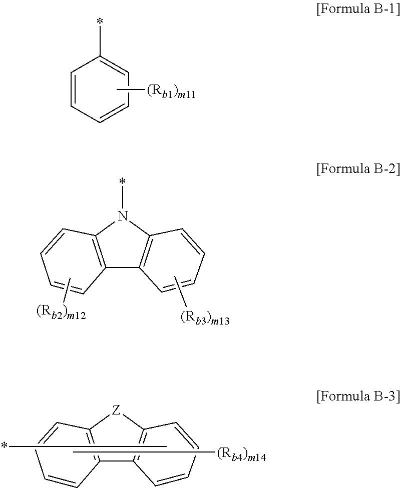
wherein in Formula B-1 to Formula B-3,
Z is N(R_{b5}), O, or S,
R_{b1} to R_{b5} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m11 is an integer from 0 to 5,
m12 and m13 are each independently an integer from 0 to 4, and
m14 is an integer from 0 to 7.

5. The light emitting device of claim 1, wherein the first compound is represented by one of Formula 3-1 to Formula 3-7: 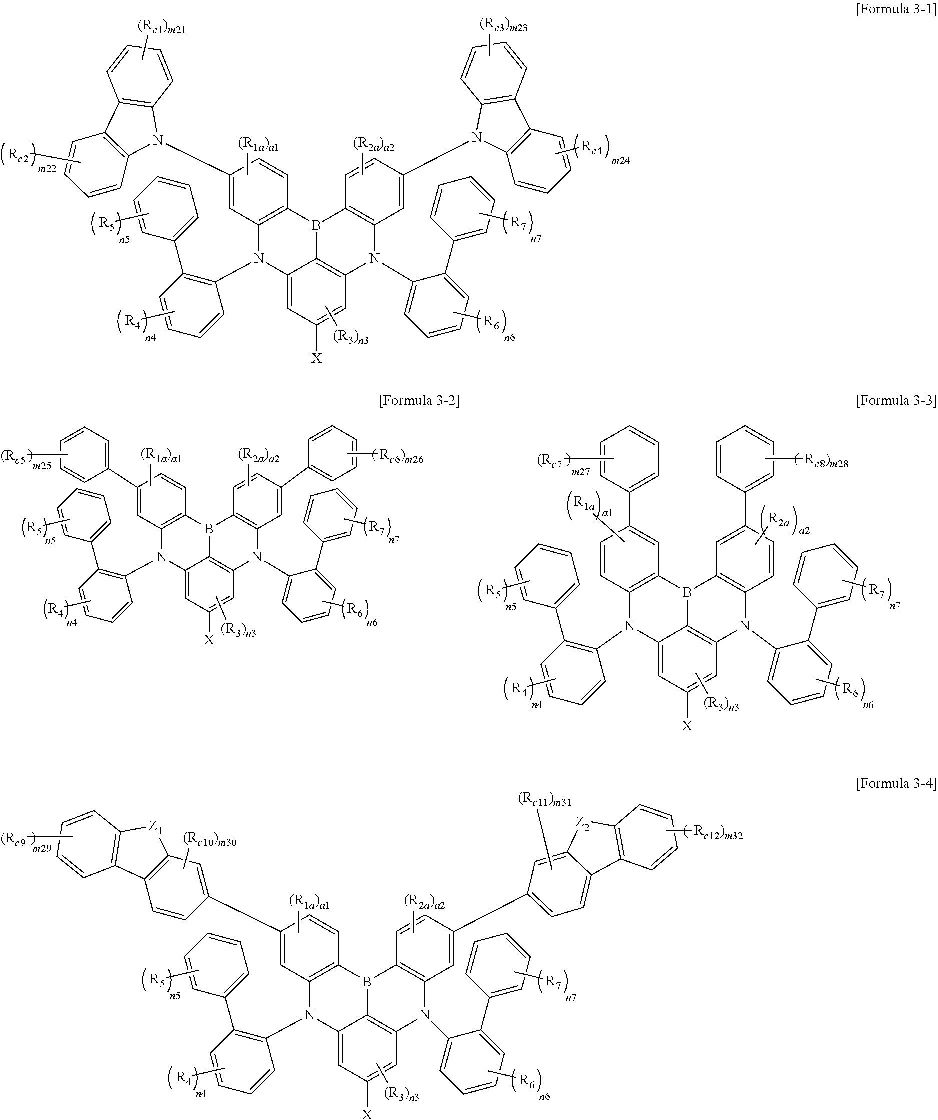 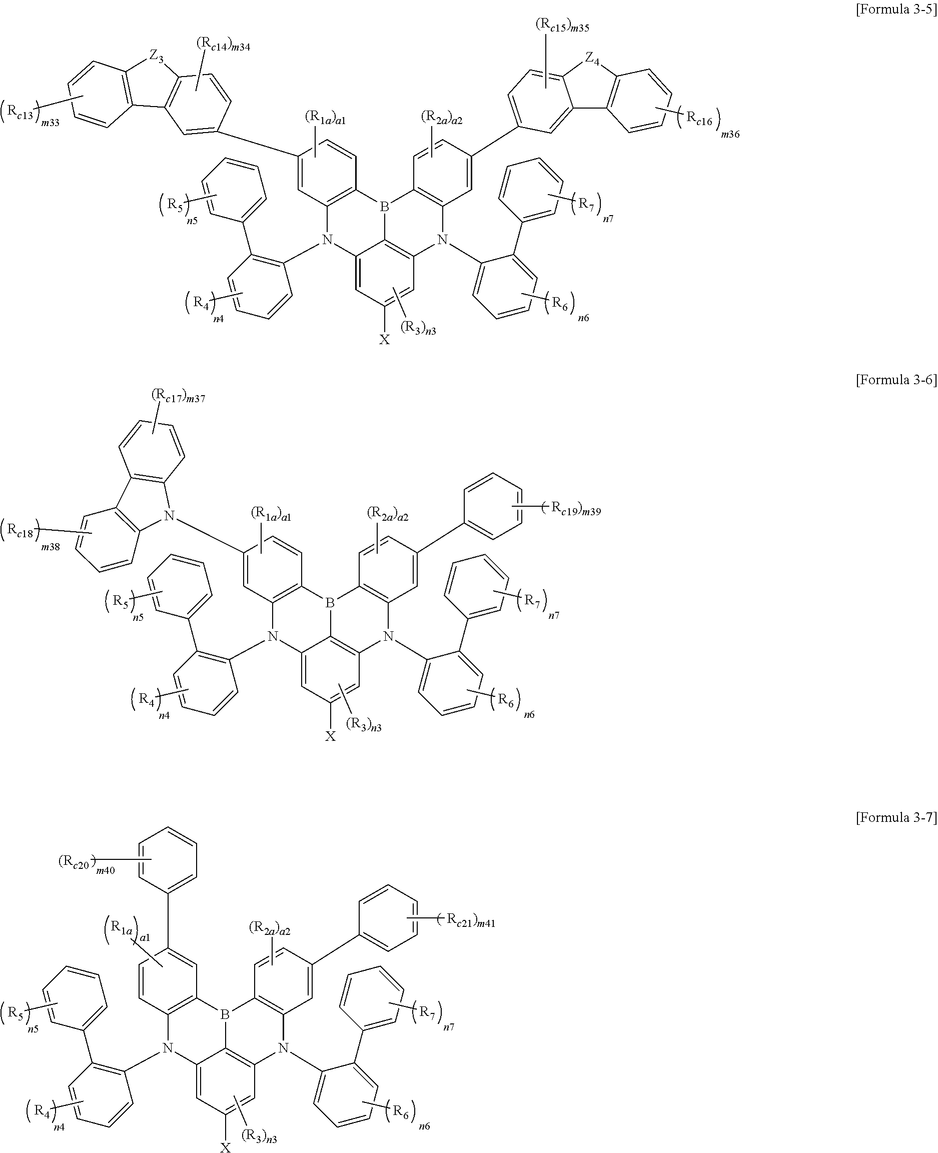
wherein in Formula 3-1 to Formula 3-7,
R₁ₐ (and R₂ₐ a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
Z₁ to Z₄ are each independently N(R_{c22}), O, or S,
R_{c1} to R_{c22} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a1 and a2 are each independently an integer from 0 to 3,
m21 to m24, m29, m32, m33, and m36 to m38 are each independently an integer from 0 to 4,
m25 to m28 and m39 to m41 are each independently an integer from 0 to 5,
m30, m31, m34, and m35 are each independently an integer from 0 to 3, and
X, R₃ to R₇, and n3 to n7 are the same as defined in Formula 1.

6. The light emitting device of claim 1, wherein the first compound is represented by one of Formula 4-1 to Formula 4-4: 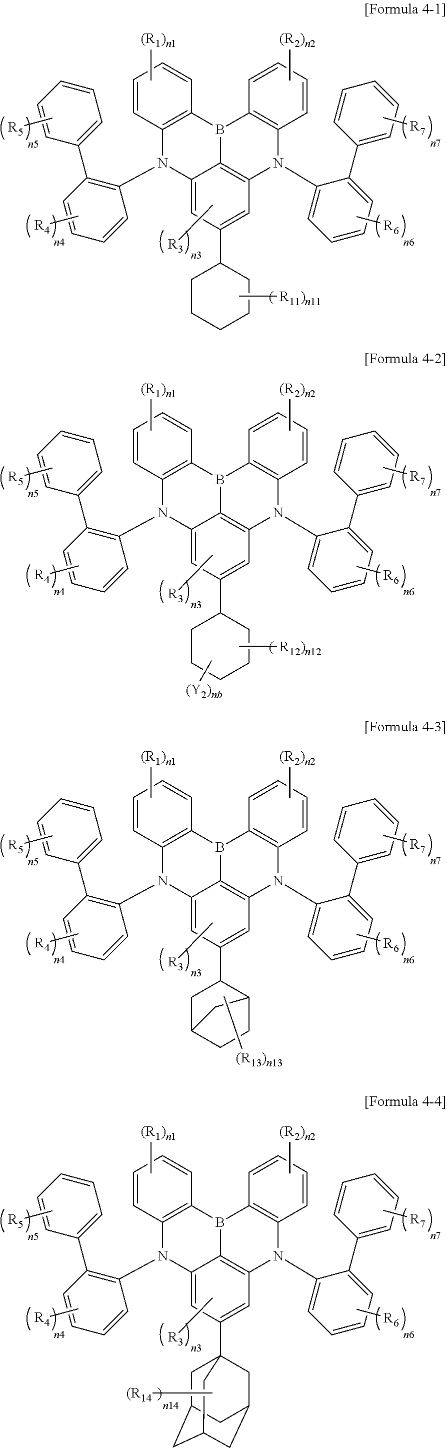
wherein in Formula 4-1 to Formula 4-4,
R₁₁ to R₁₄ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Y₂ is a substituted or unsubstituted alkyl group having 1 to 10 carbon atoms,
n11 and n13 are each independently an integer from 0 to 11,
n12 is an integer from 0 to 10,
nb is an integer from 1 to 11,
a sum of n12 and nb is less than or equal to 11,
n14 is an integer from 0 to 15, and
R₁ to R₇ and n1 to n7 are the same as defined in Formula 1.

7. The light emitting device of claim 1, wherein the first compound is represented by Formula 5: 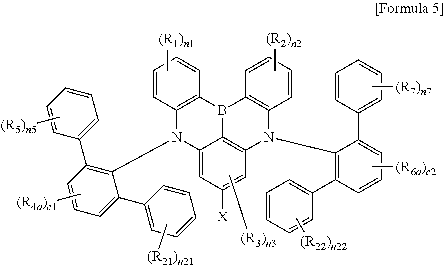
wherein in Formula 5,
R₄ₐ, R₆ₐ, R₂₁, and R₂₂ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
c1 and c2 are each independently an integer from 0 to 3,
n21 and n22 are each independently an integer from 0 to 5, and
X, R₁ to R₃, R₅, R₇, n1 to n3, n5, and n7 are the same as defined in Formula 1.

8. The light emitting device of claim 1, wherein the first compound is represented by one of Formula 6-1 to Formula 6-3: 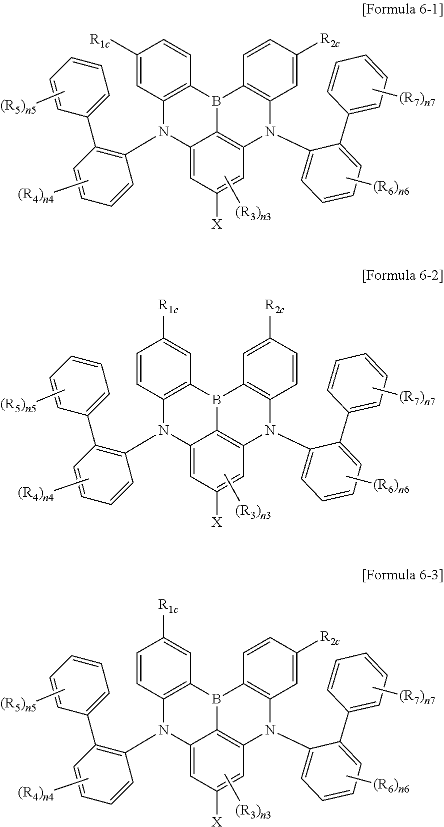
wherein in Formula 6-1 to Formula 6-3,
R₁, and R_{2c} are each independently a substituted or unsubstituted phenyl group, a substituted or unsubstituted carbazole group, or a substituted or unsubstituted dibenzofuran group, and
X, R₄ to R₇, and n4 to n7 are the same as defined in Formula 1.

9. The light emitting device of claim 1, wherein the first compound includes at least one compound selected from Compound Group 1:

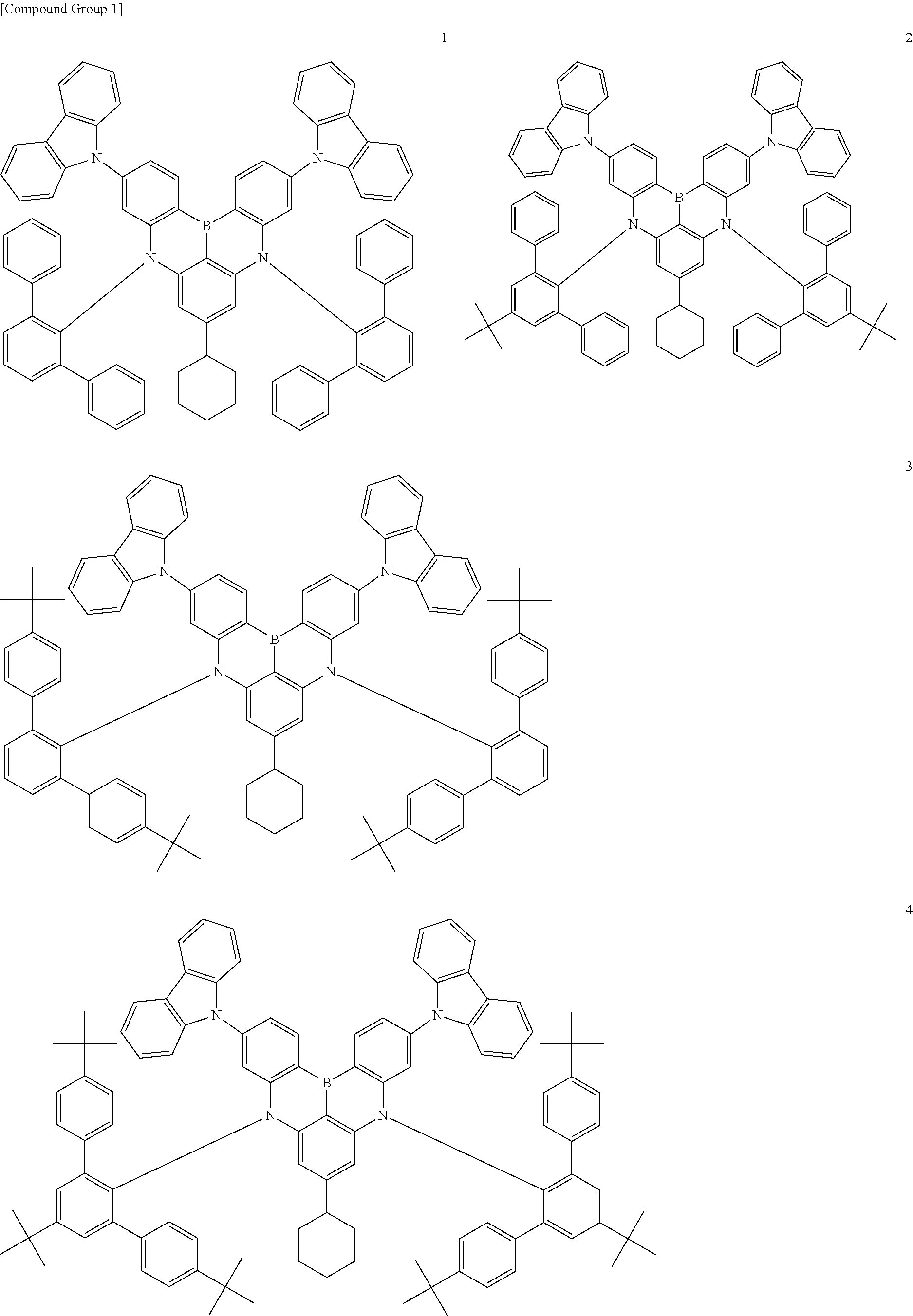

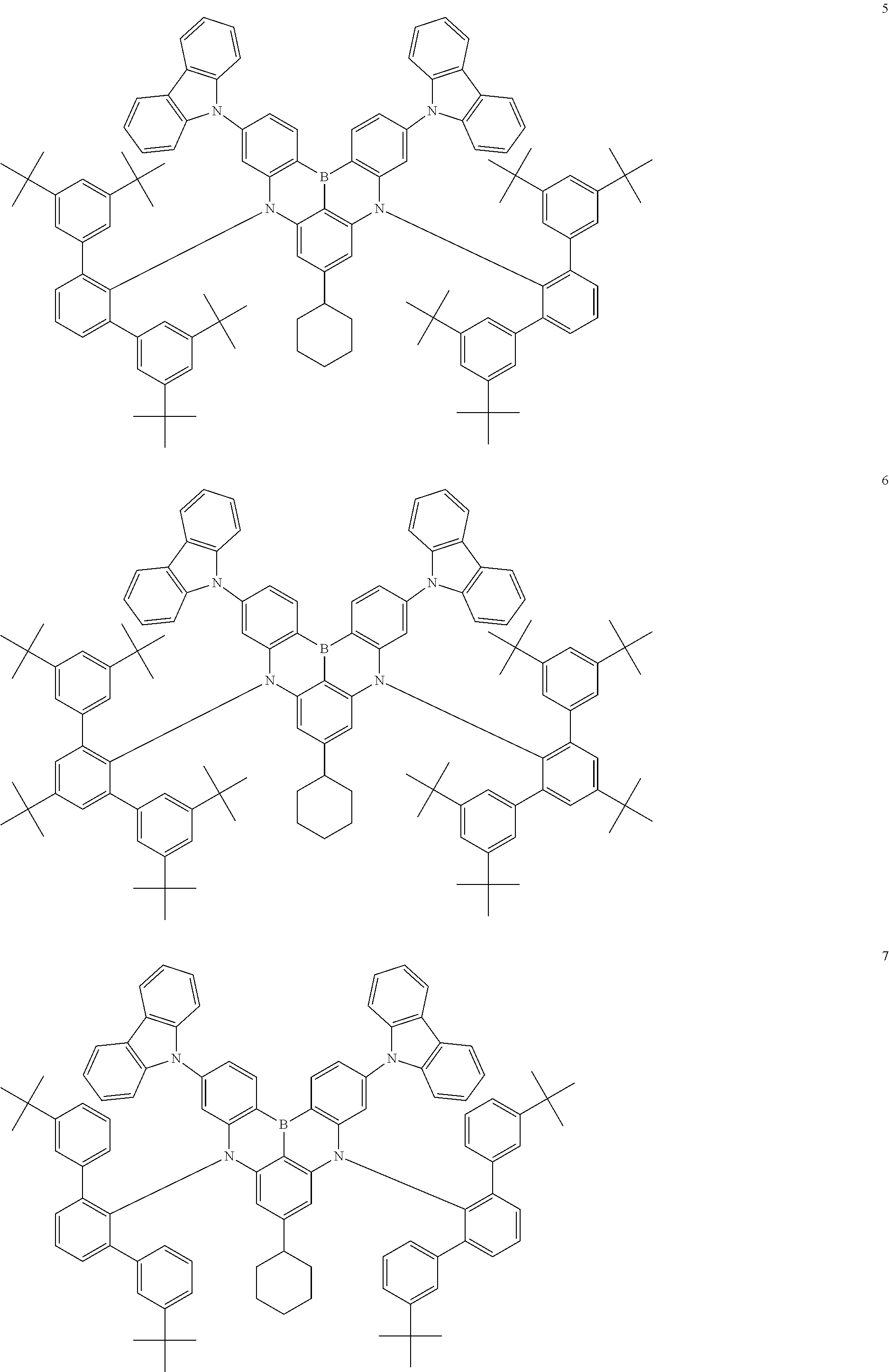

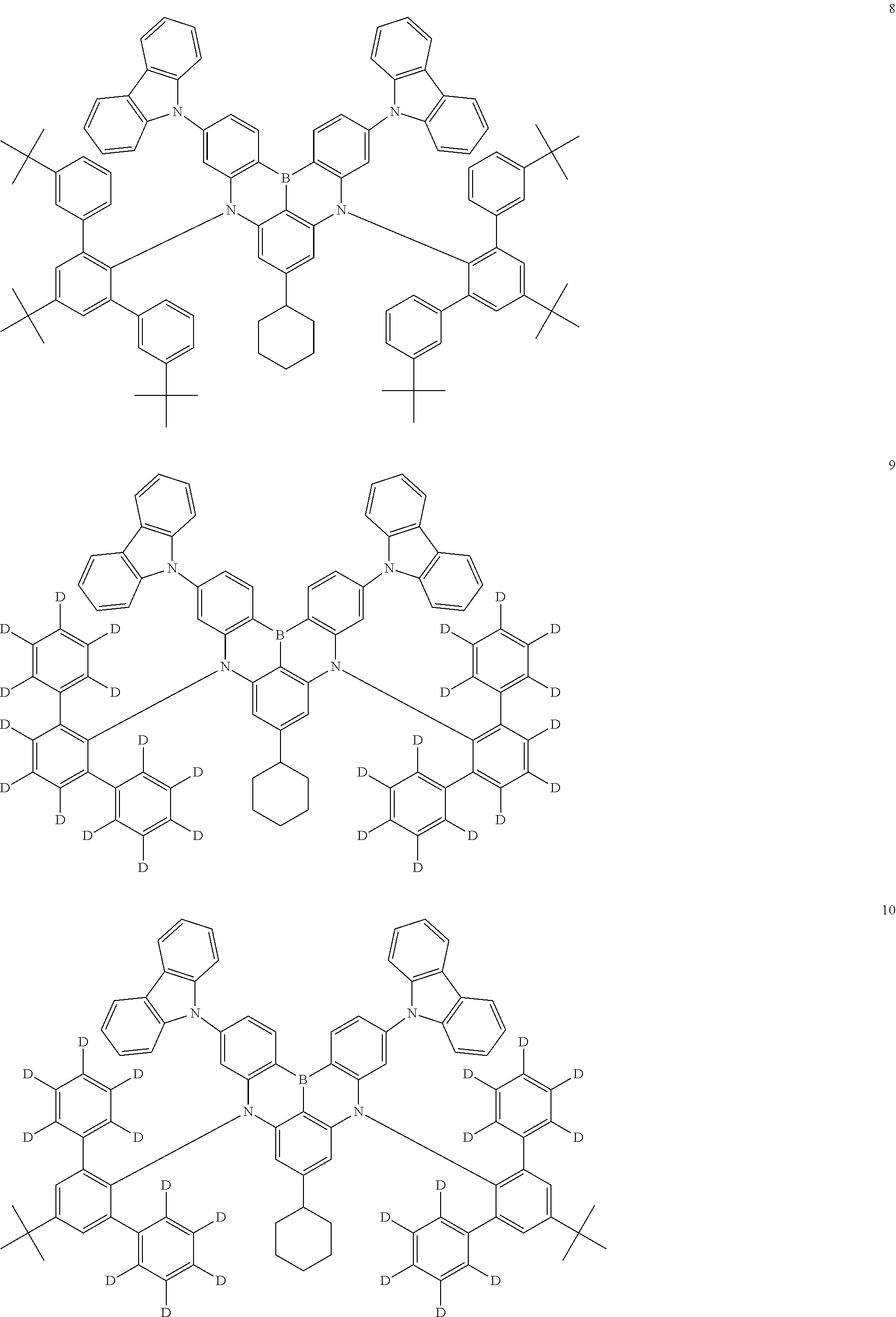

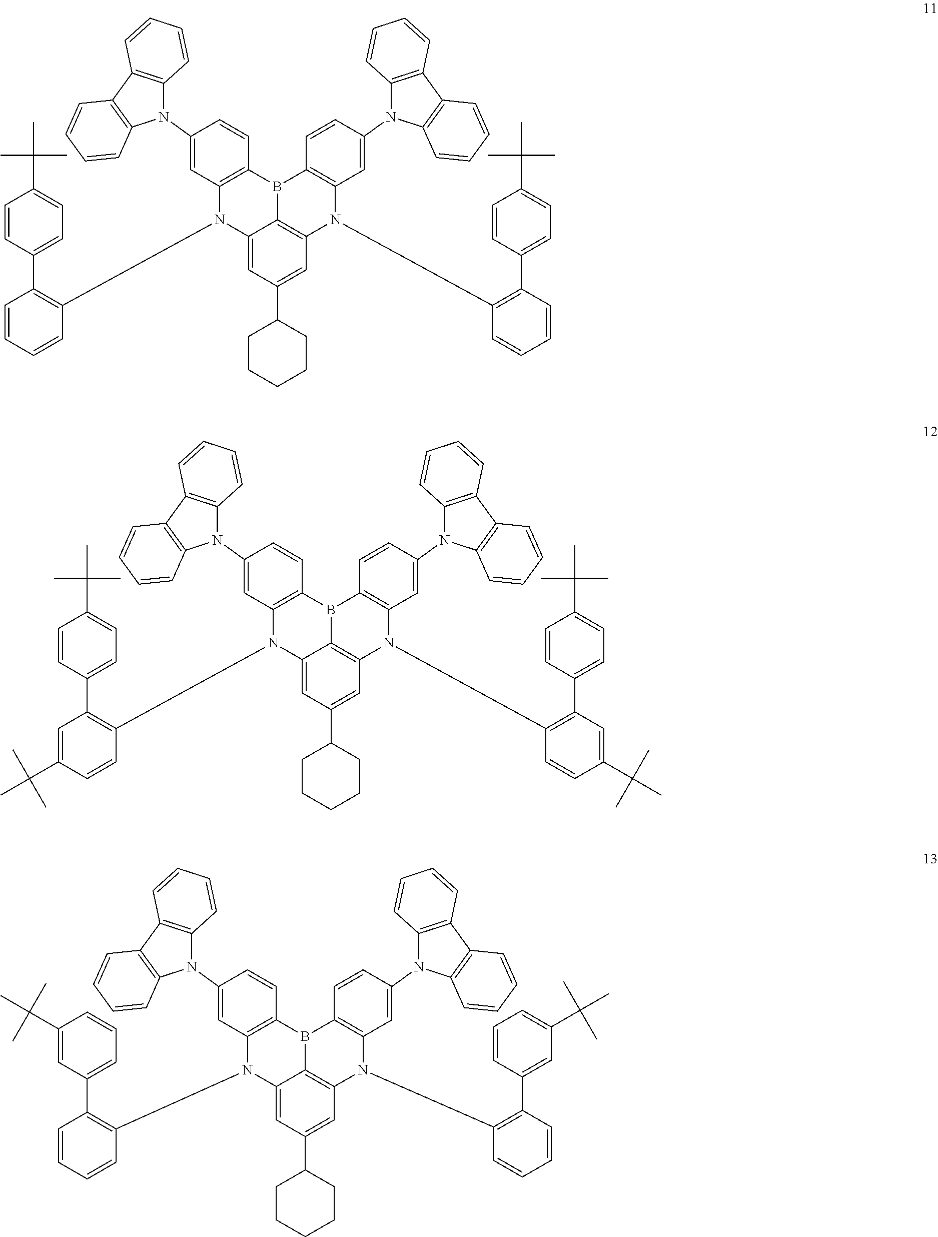

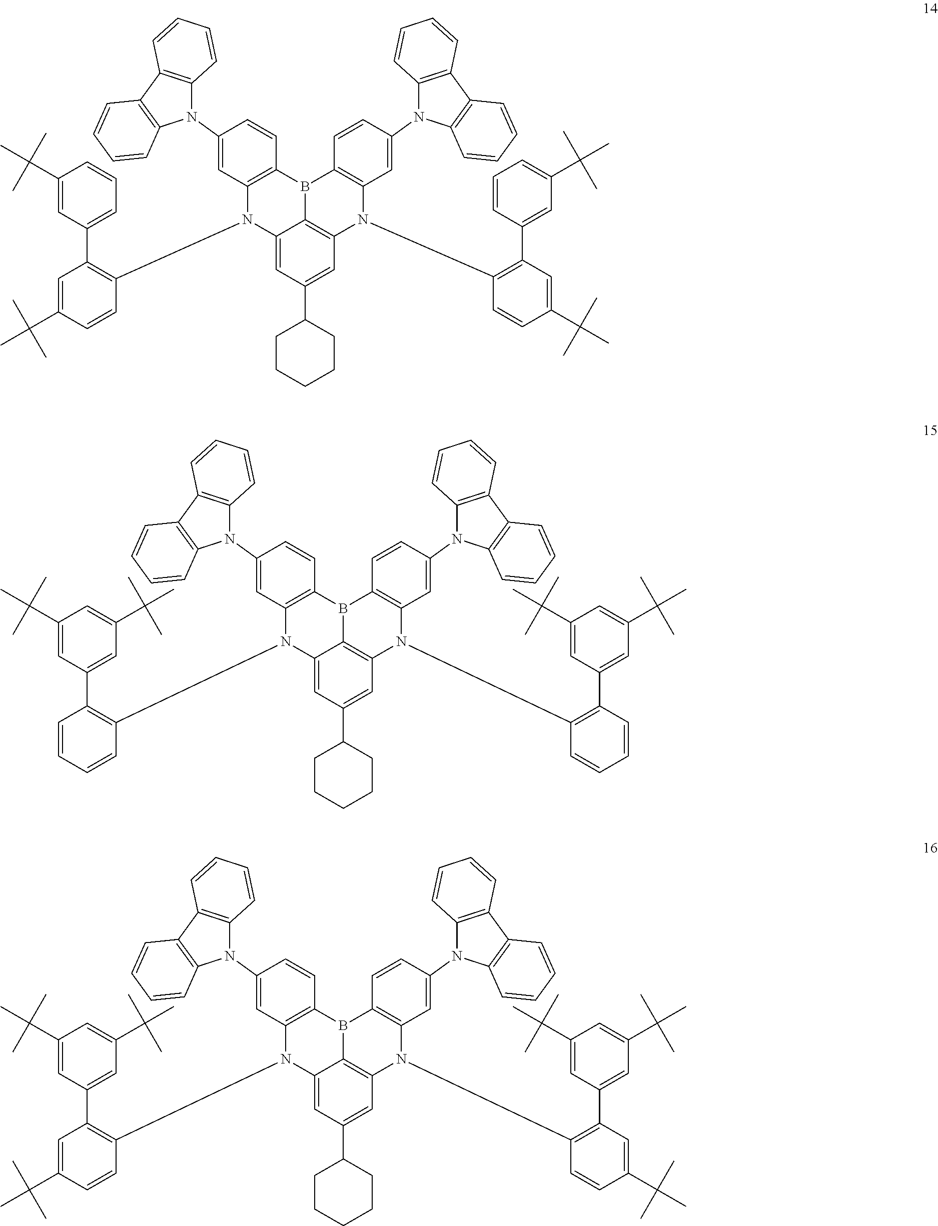

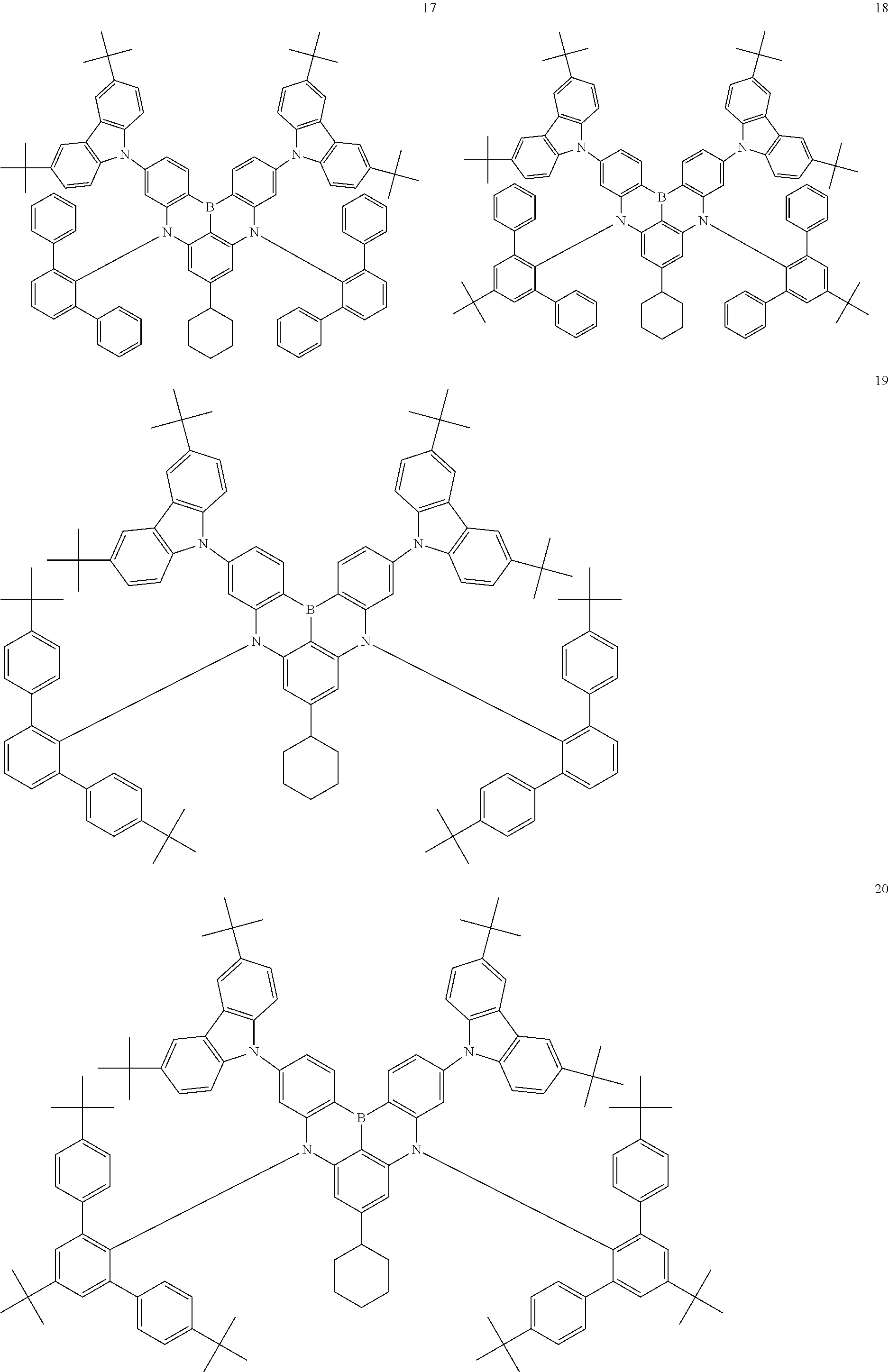

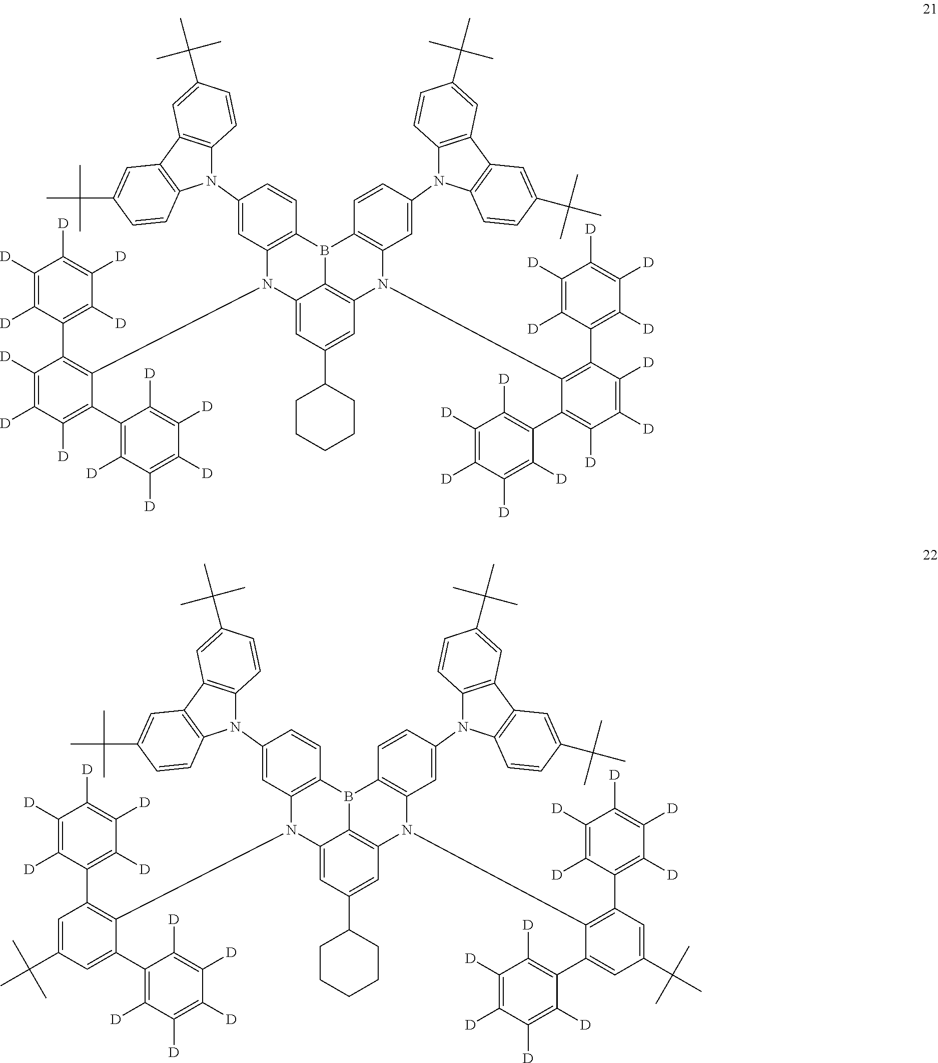

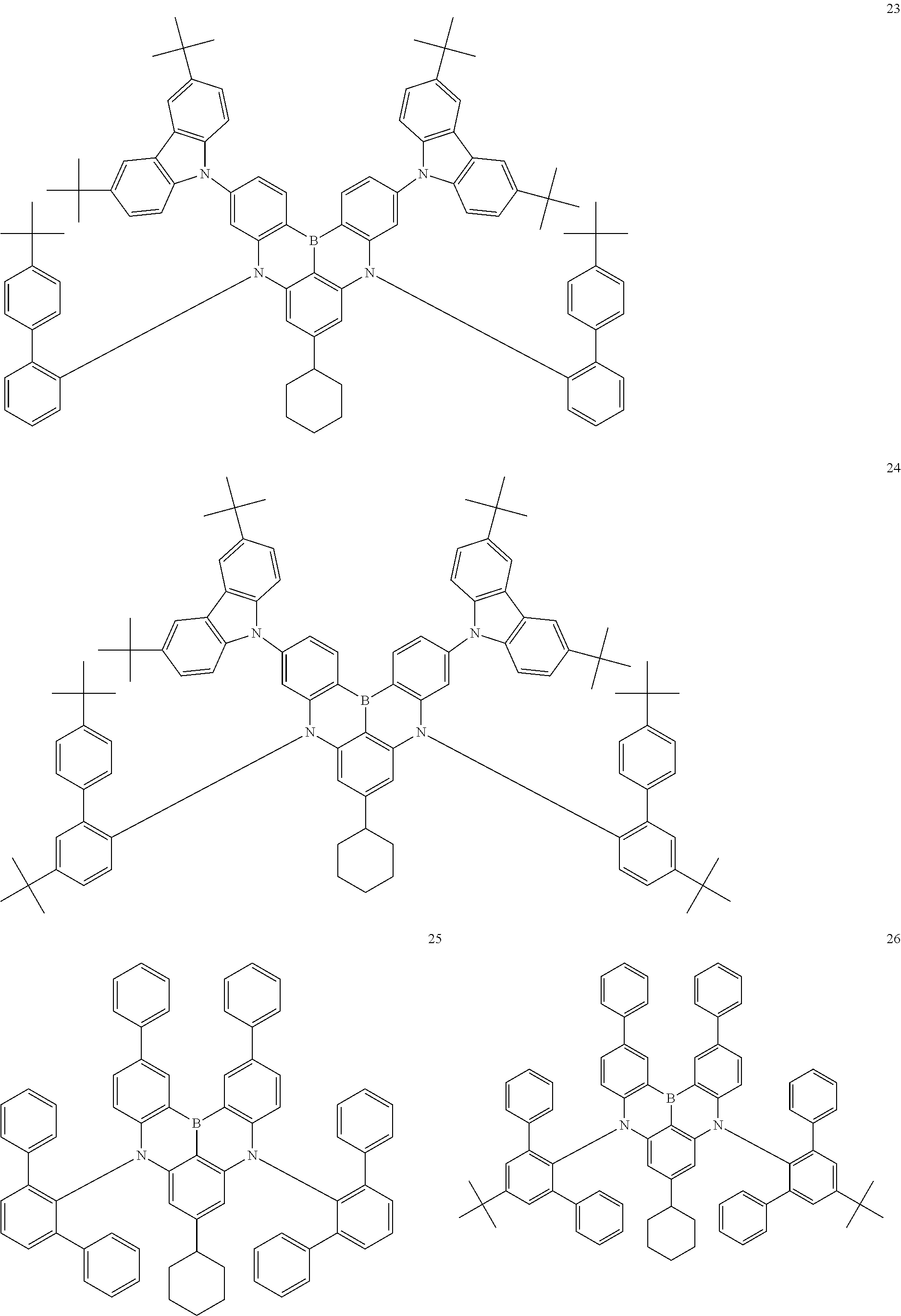

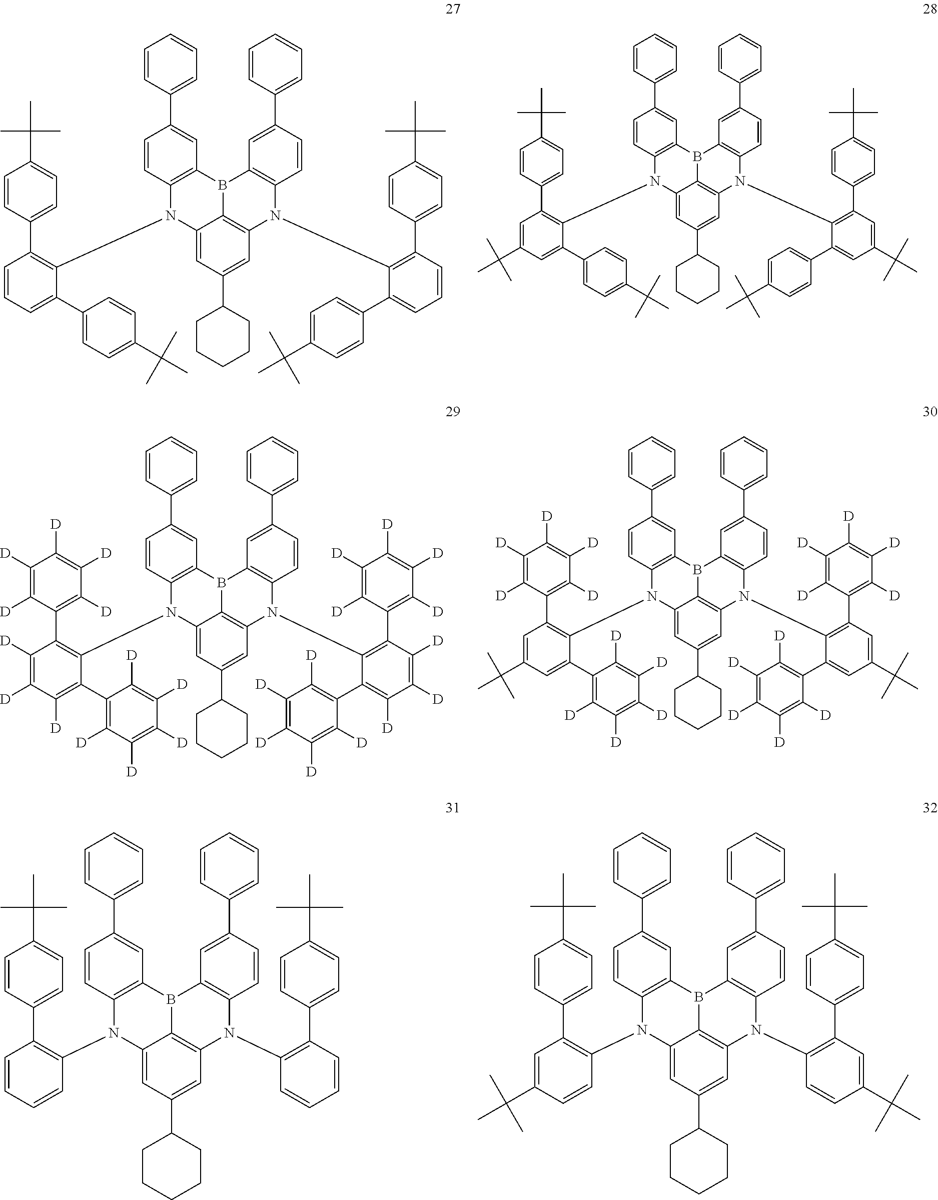

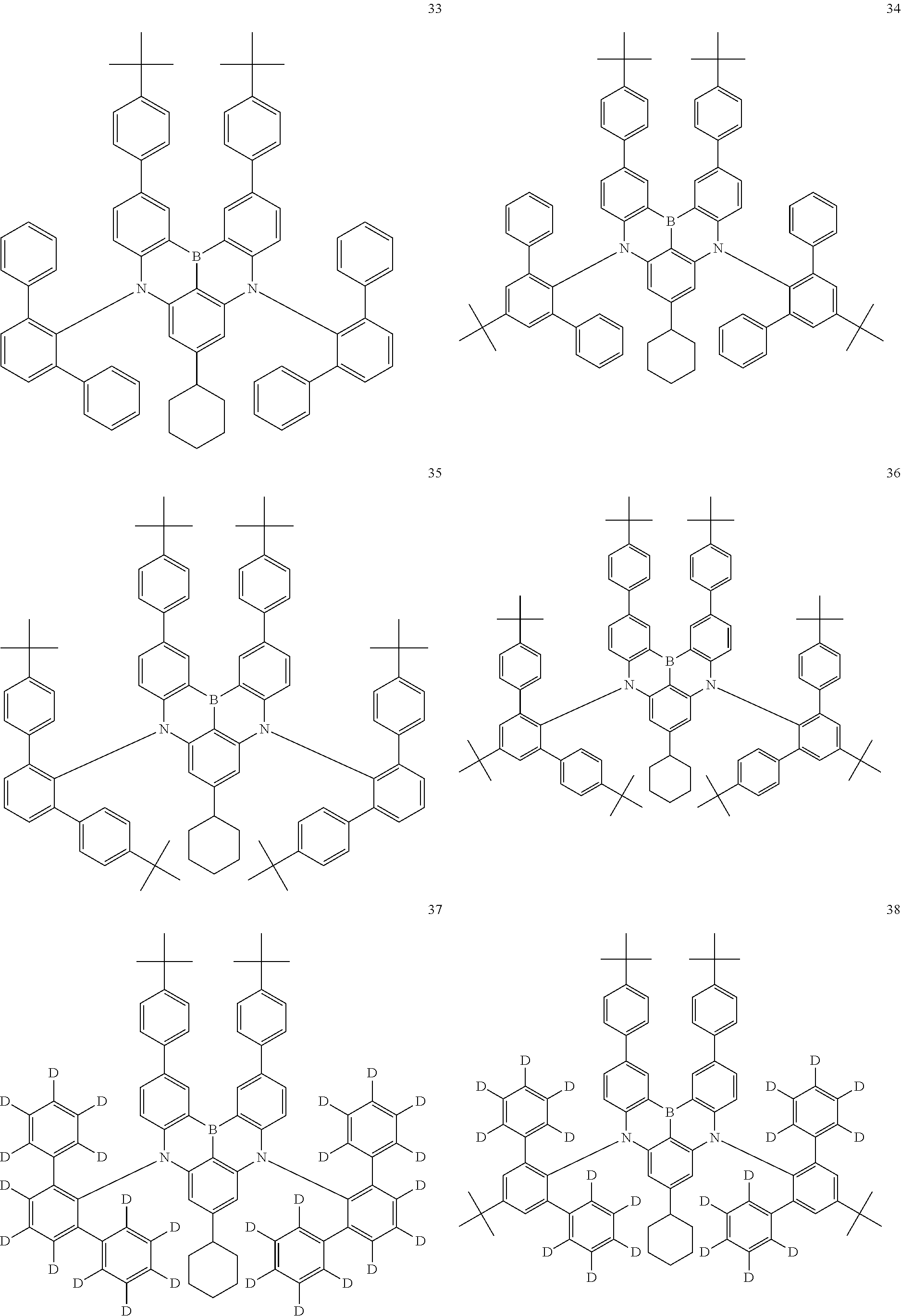

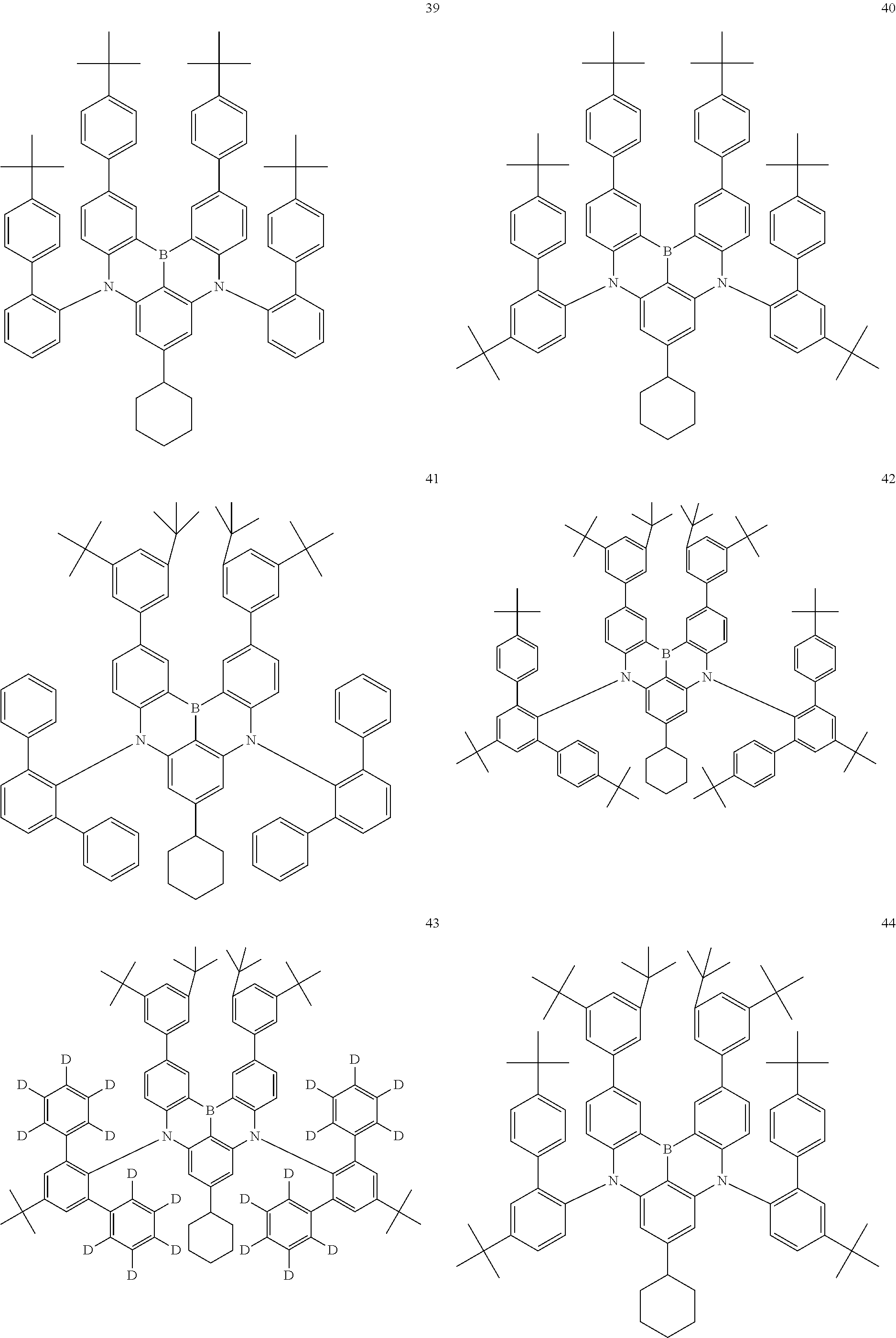

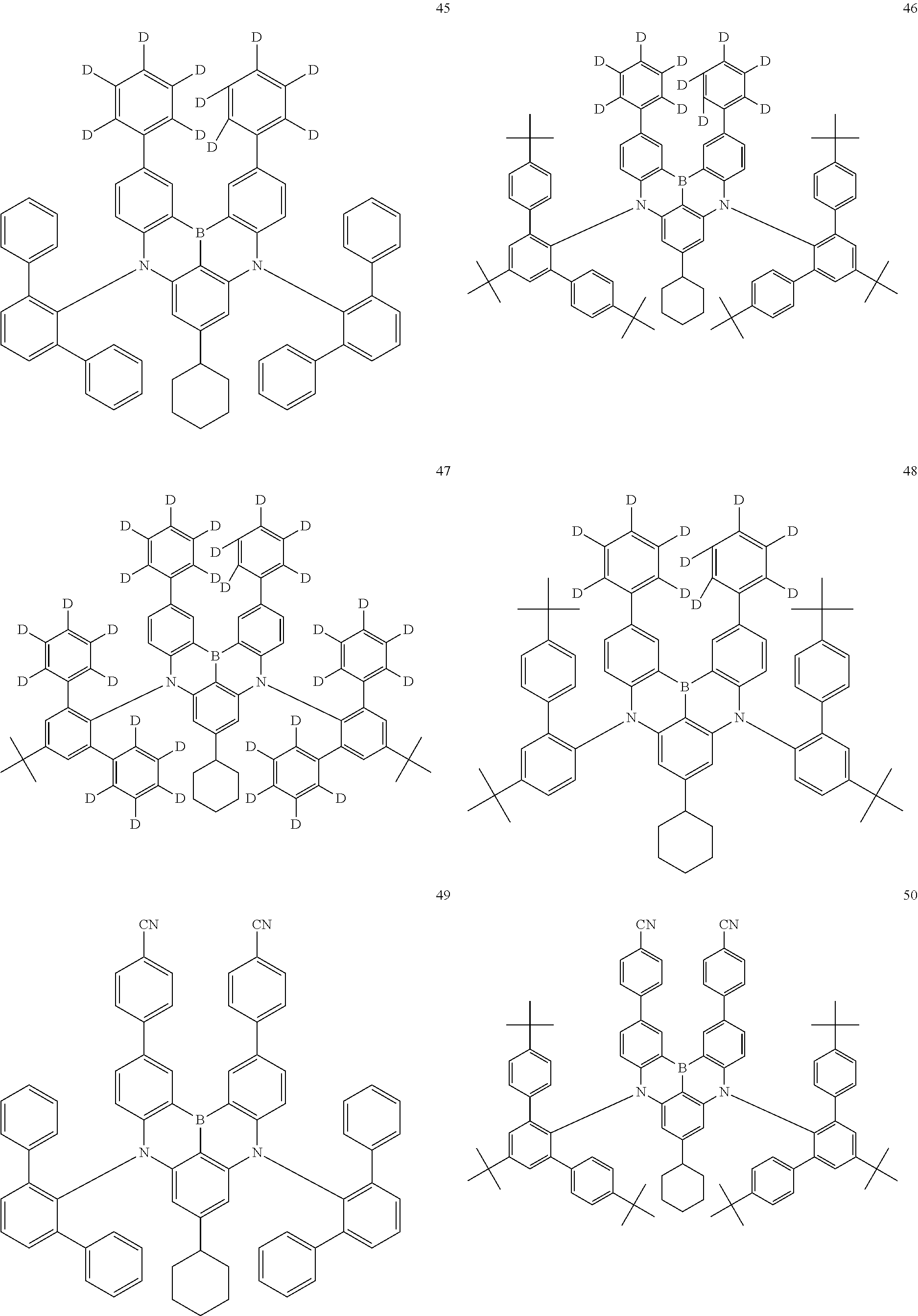

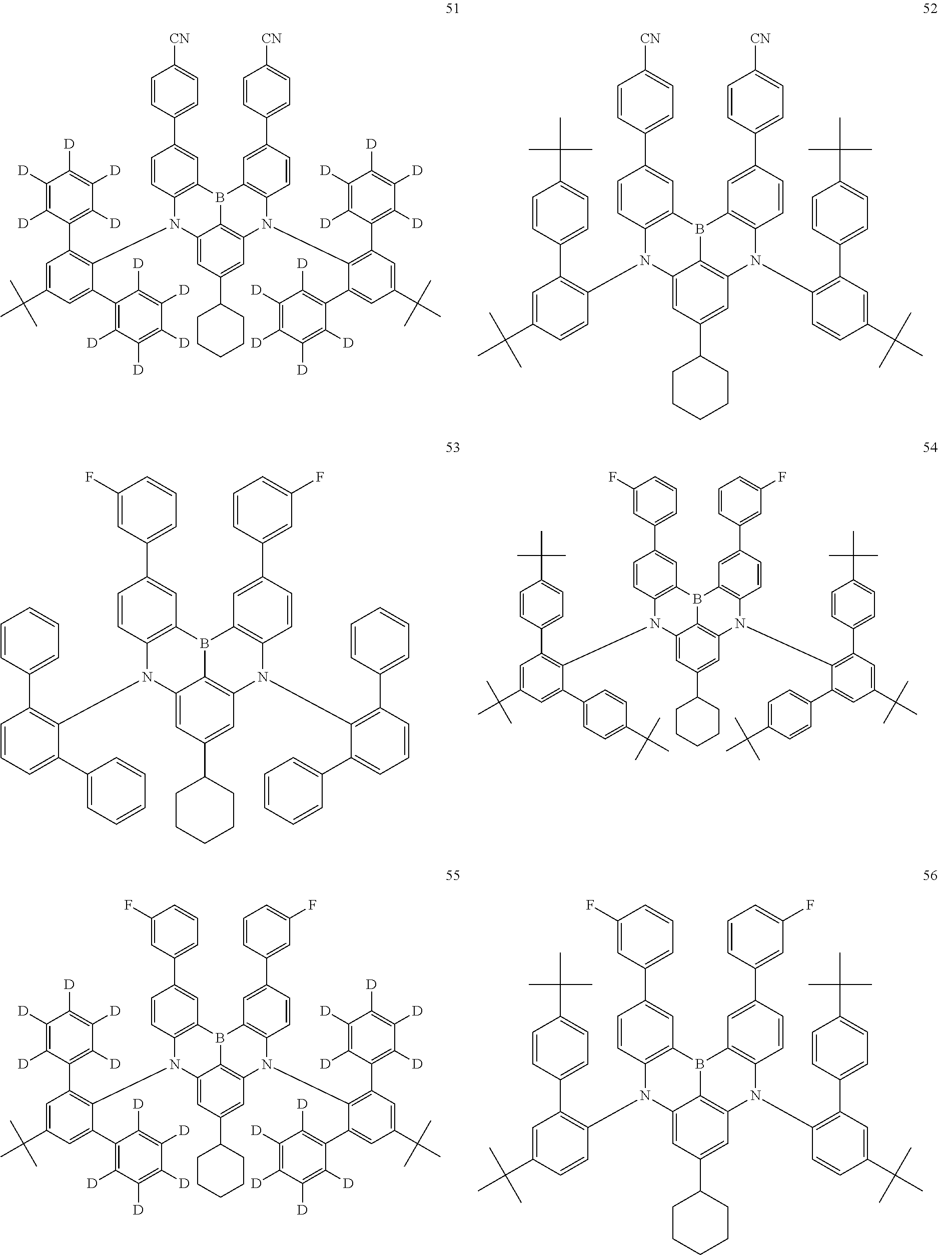

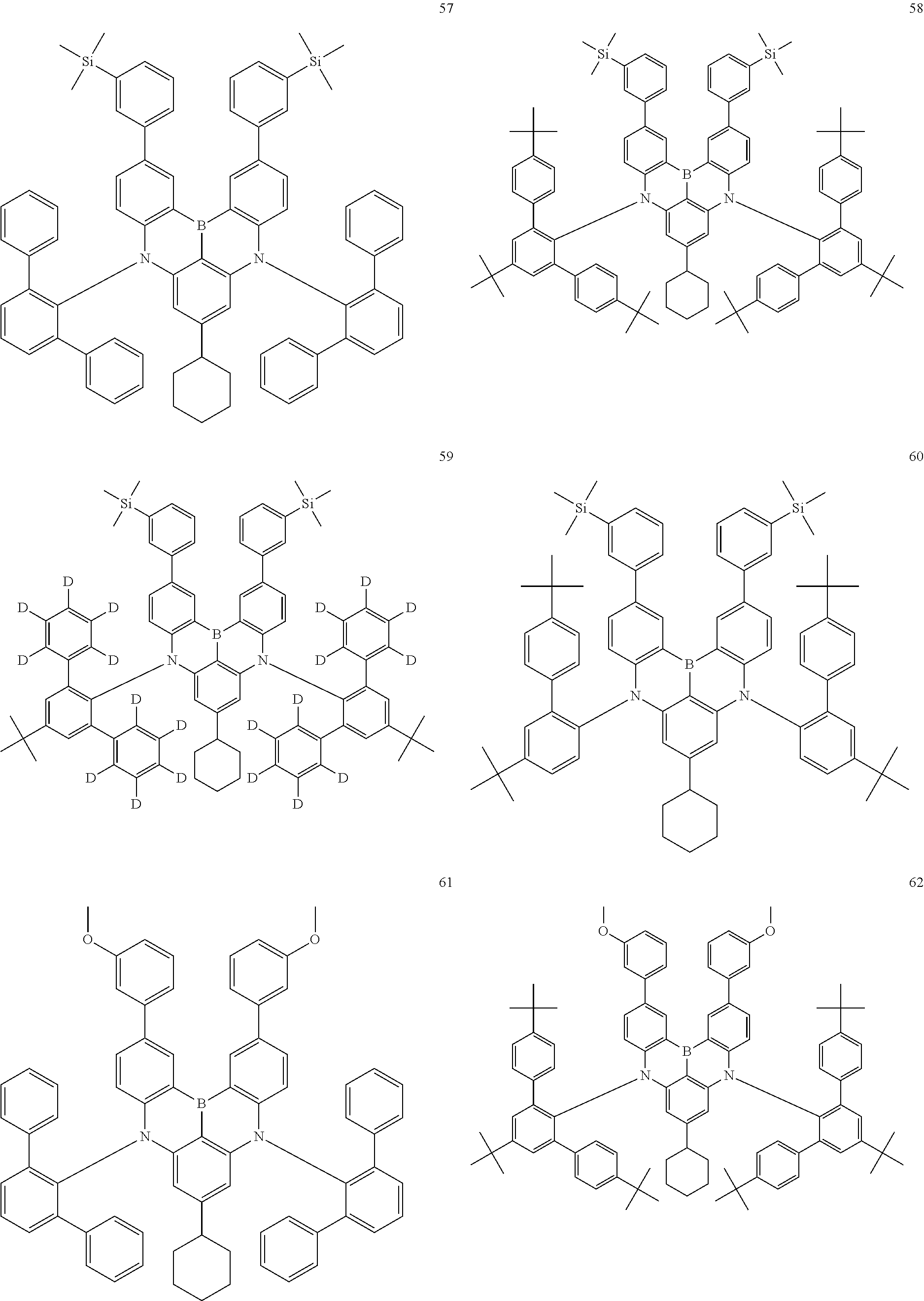

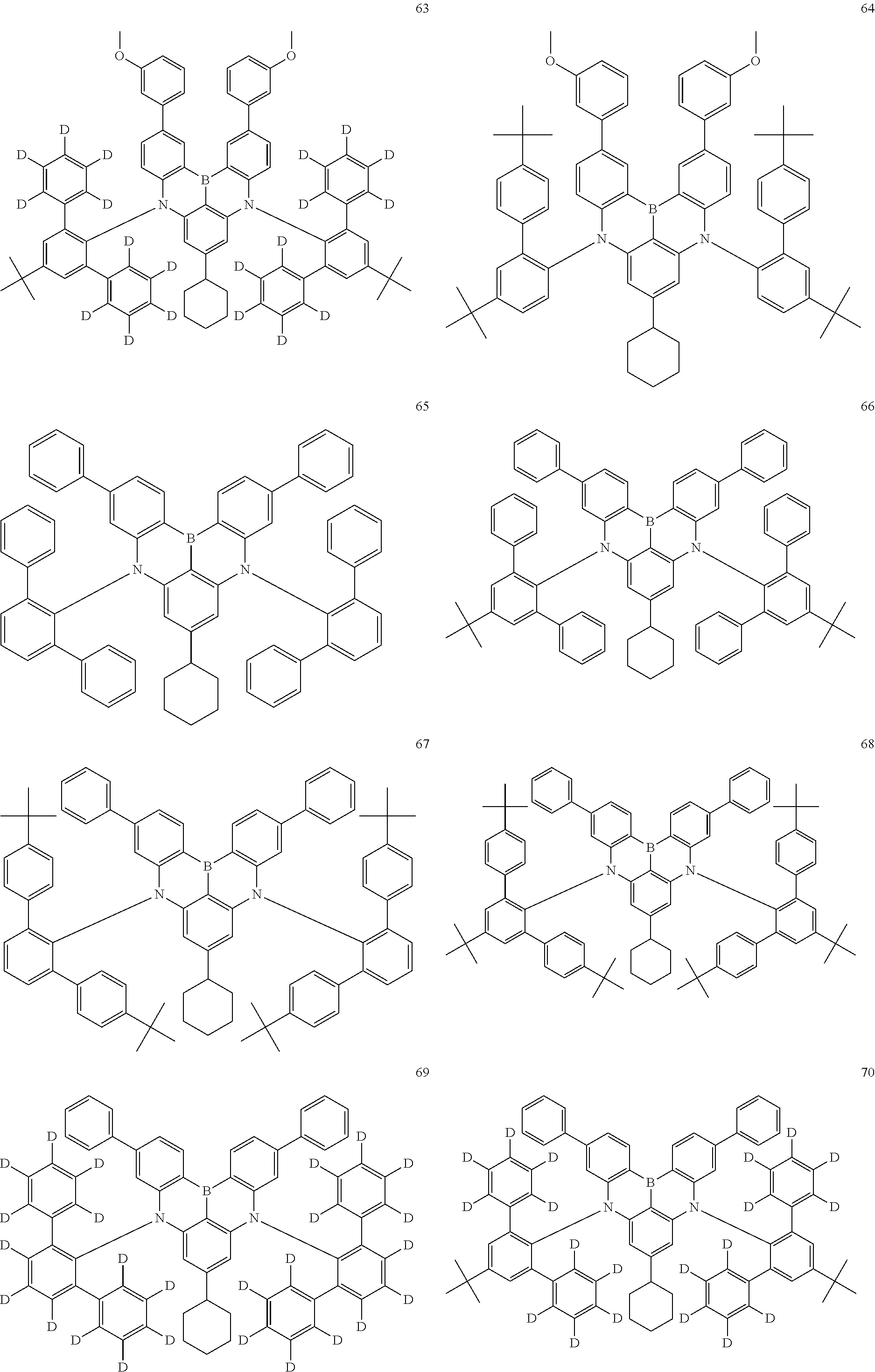

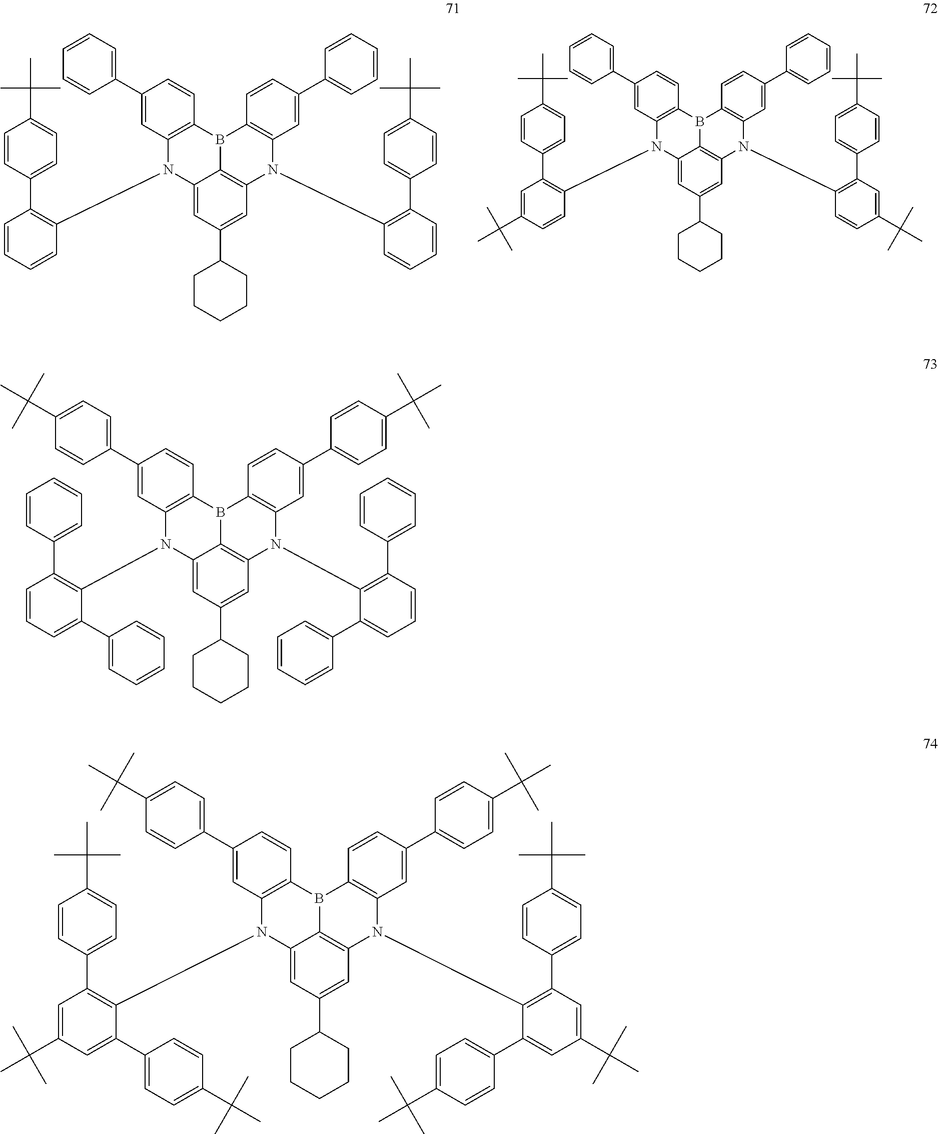

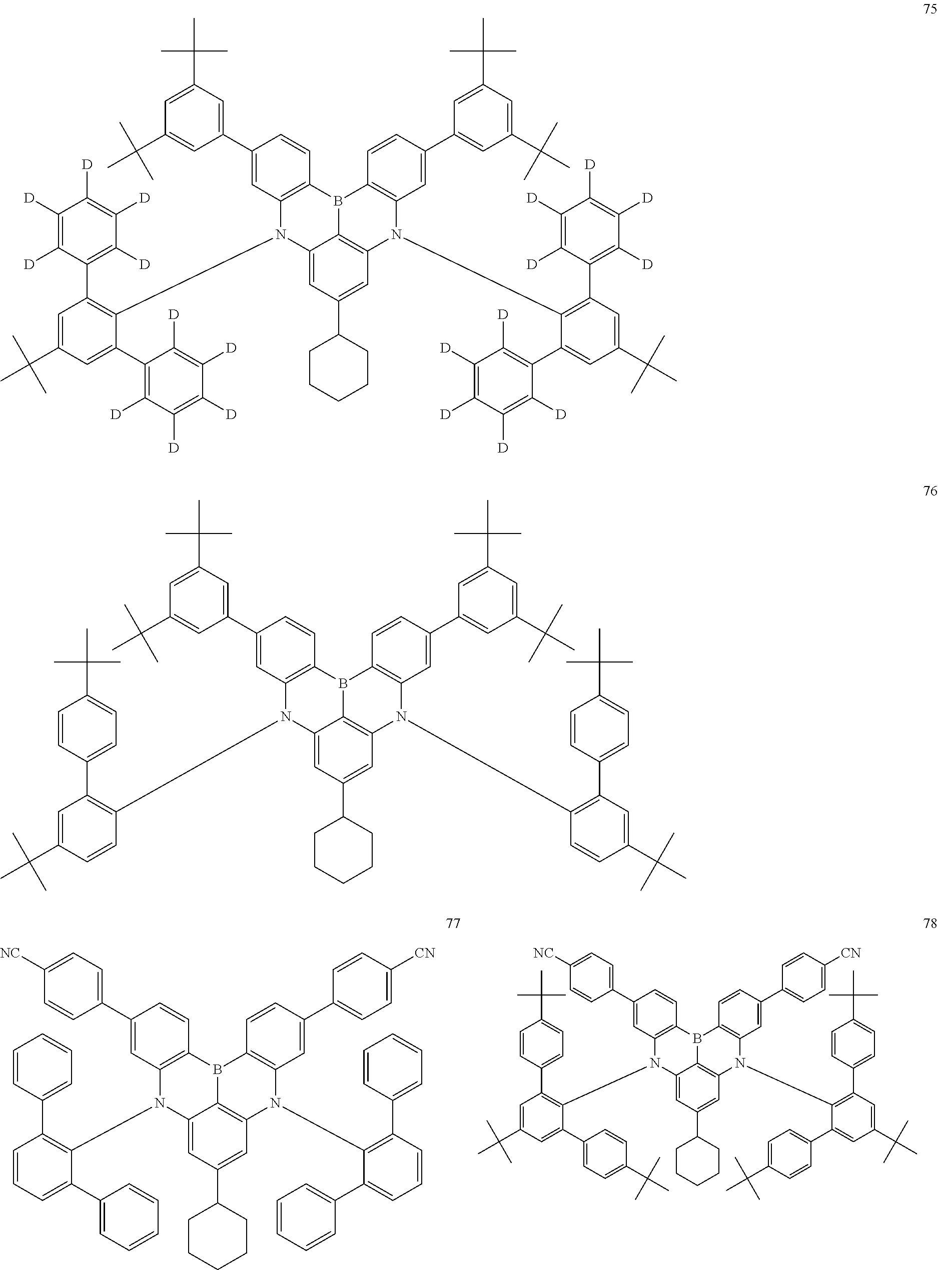

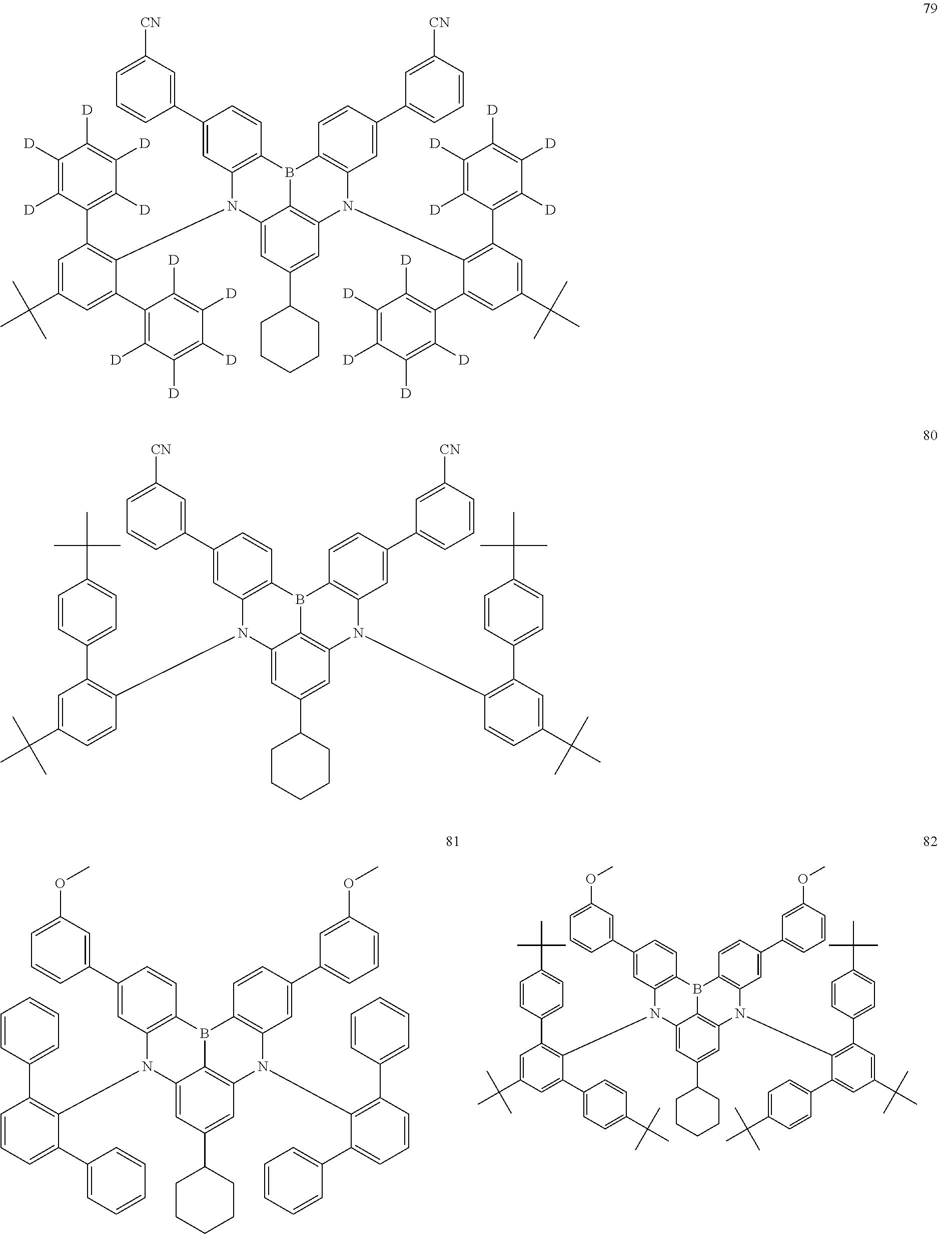

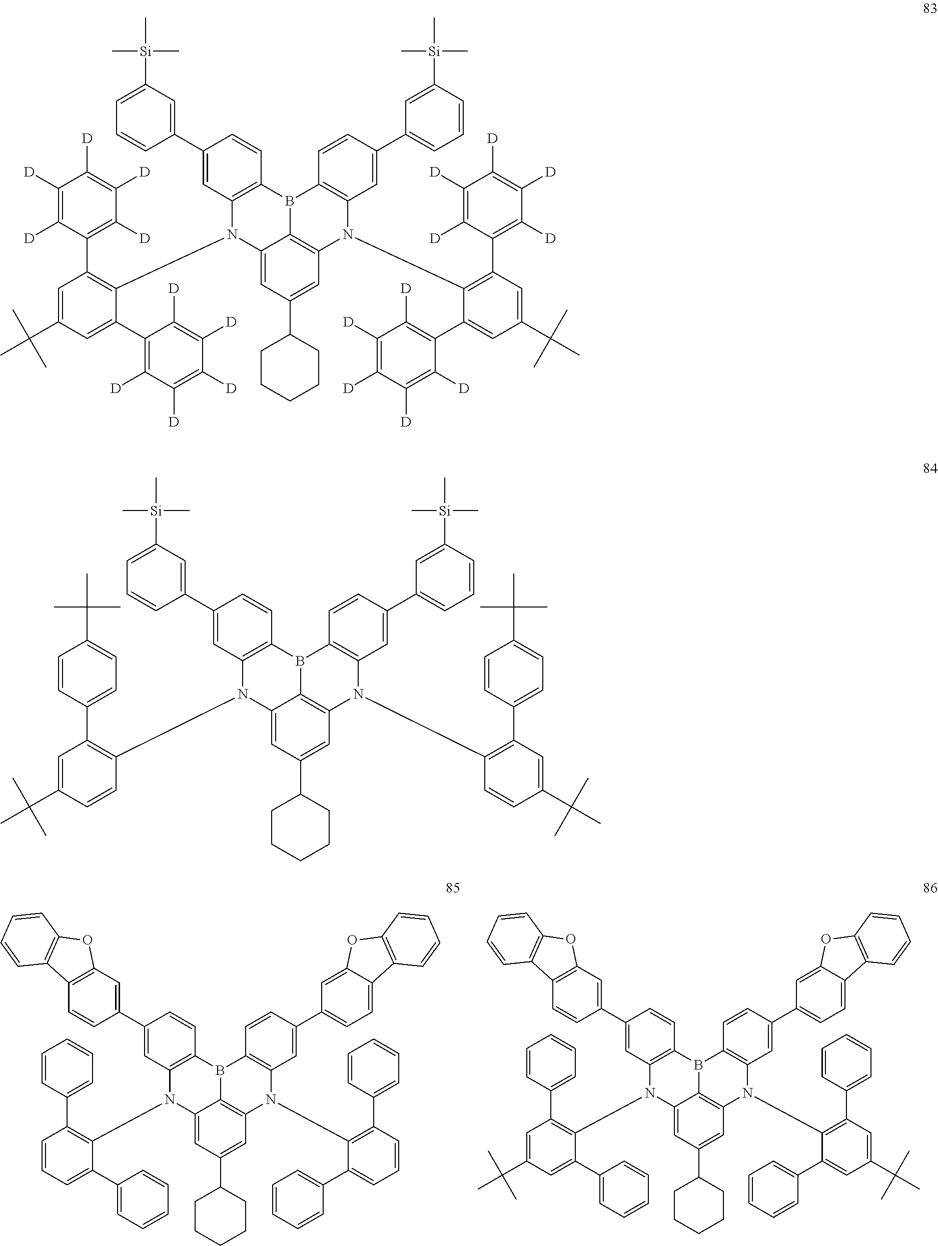

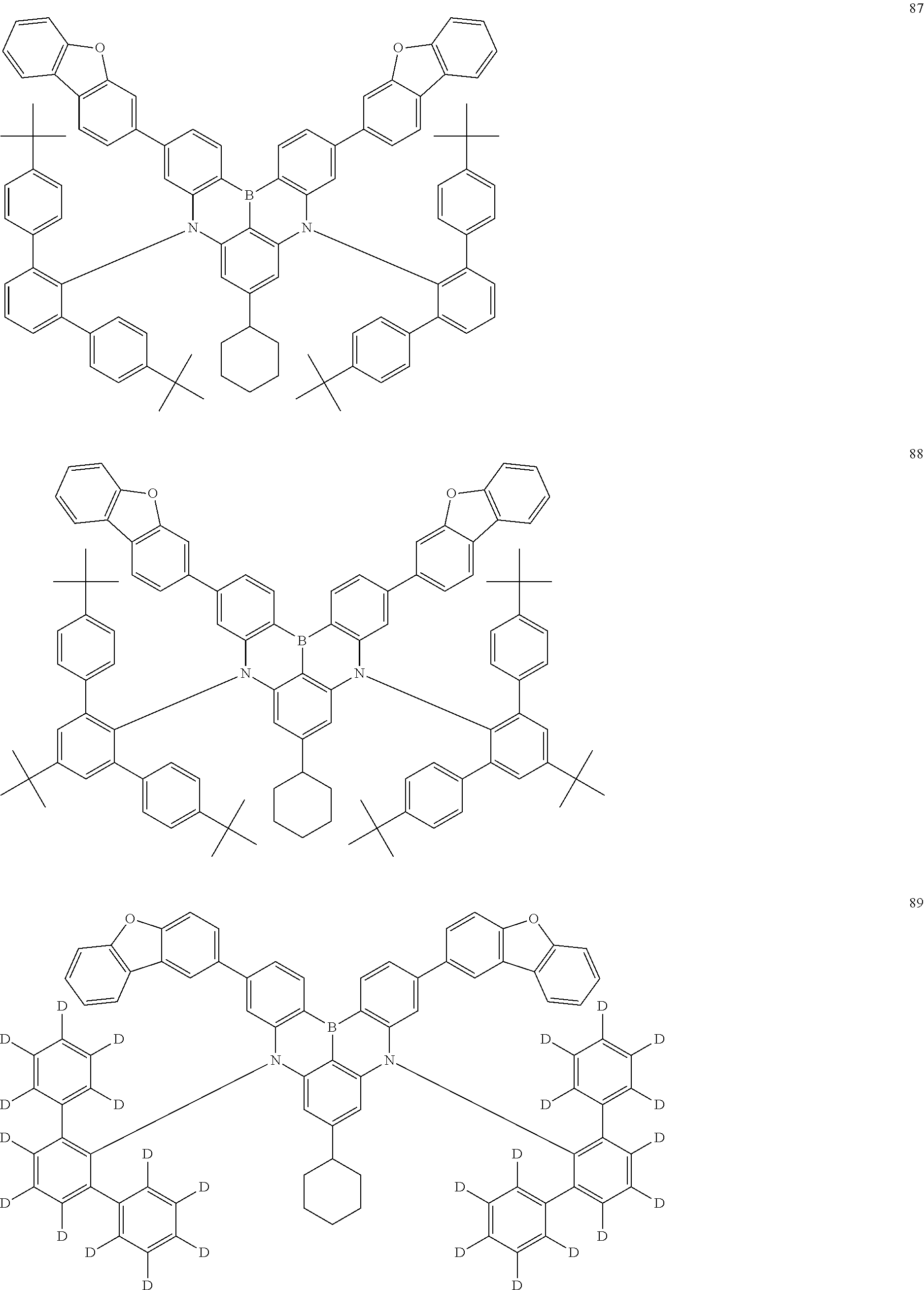

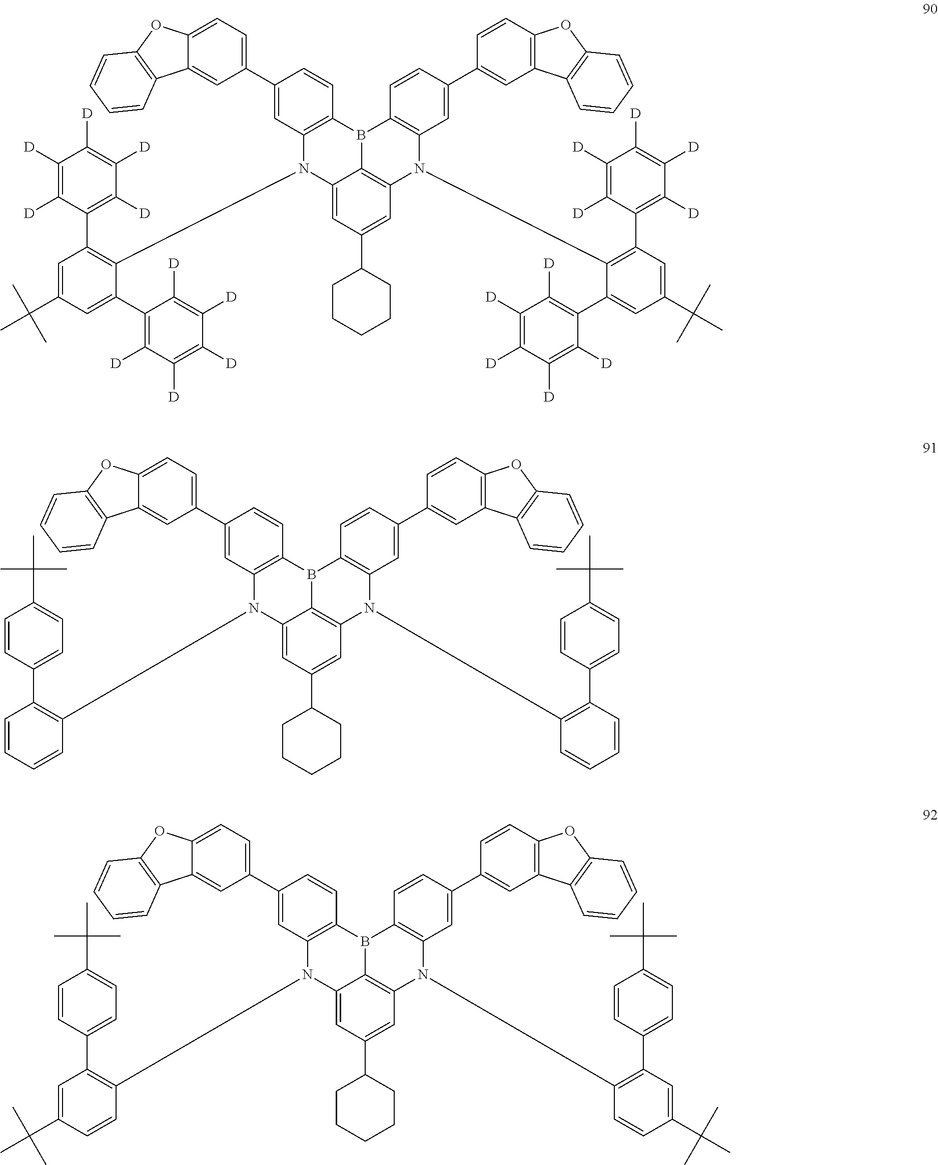

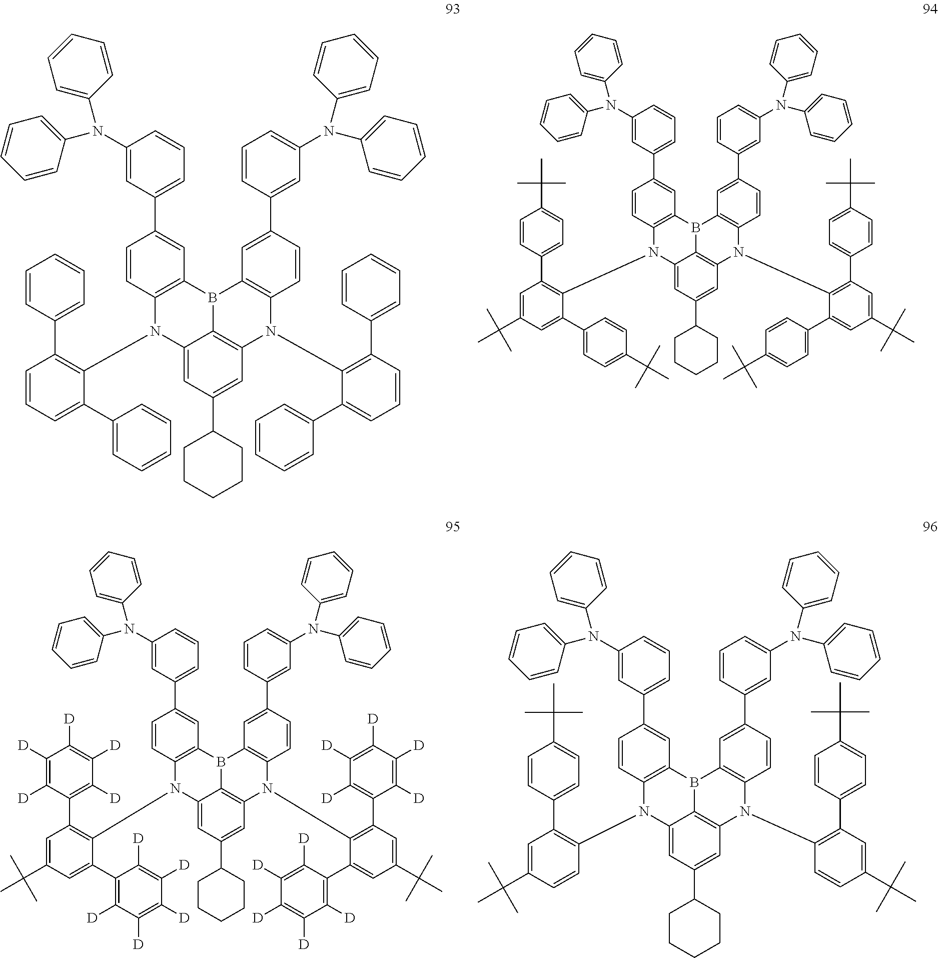

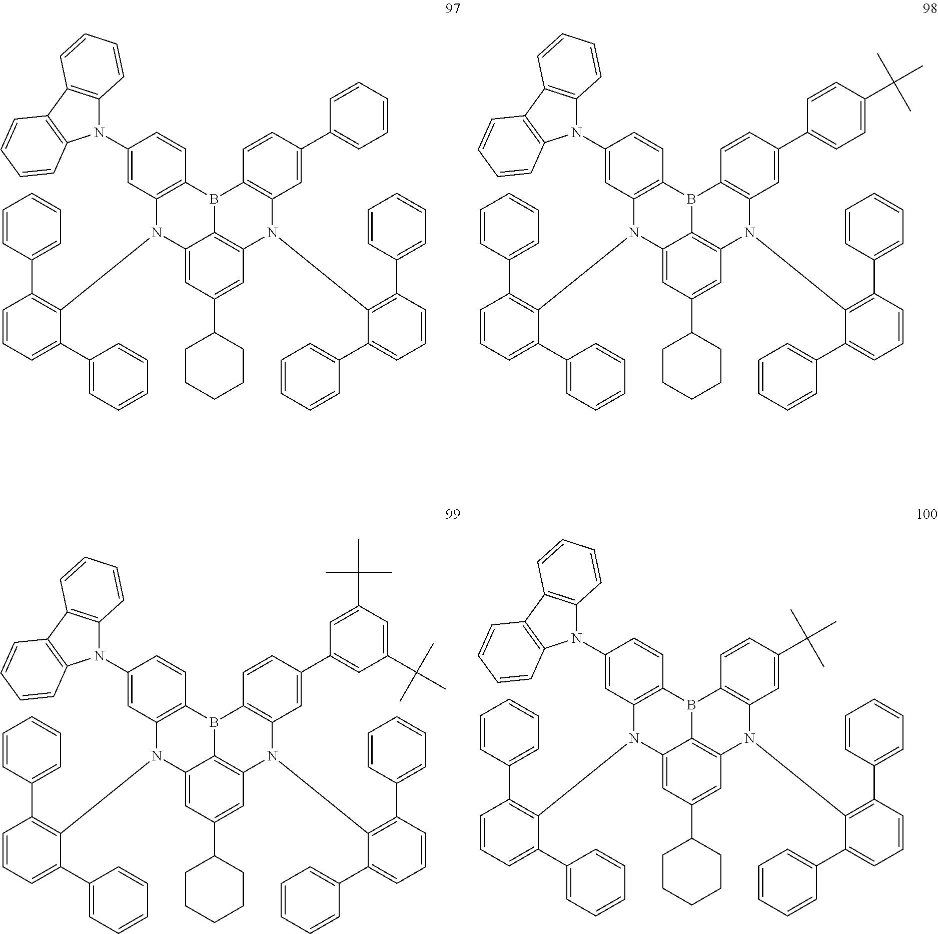

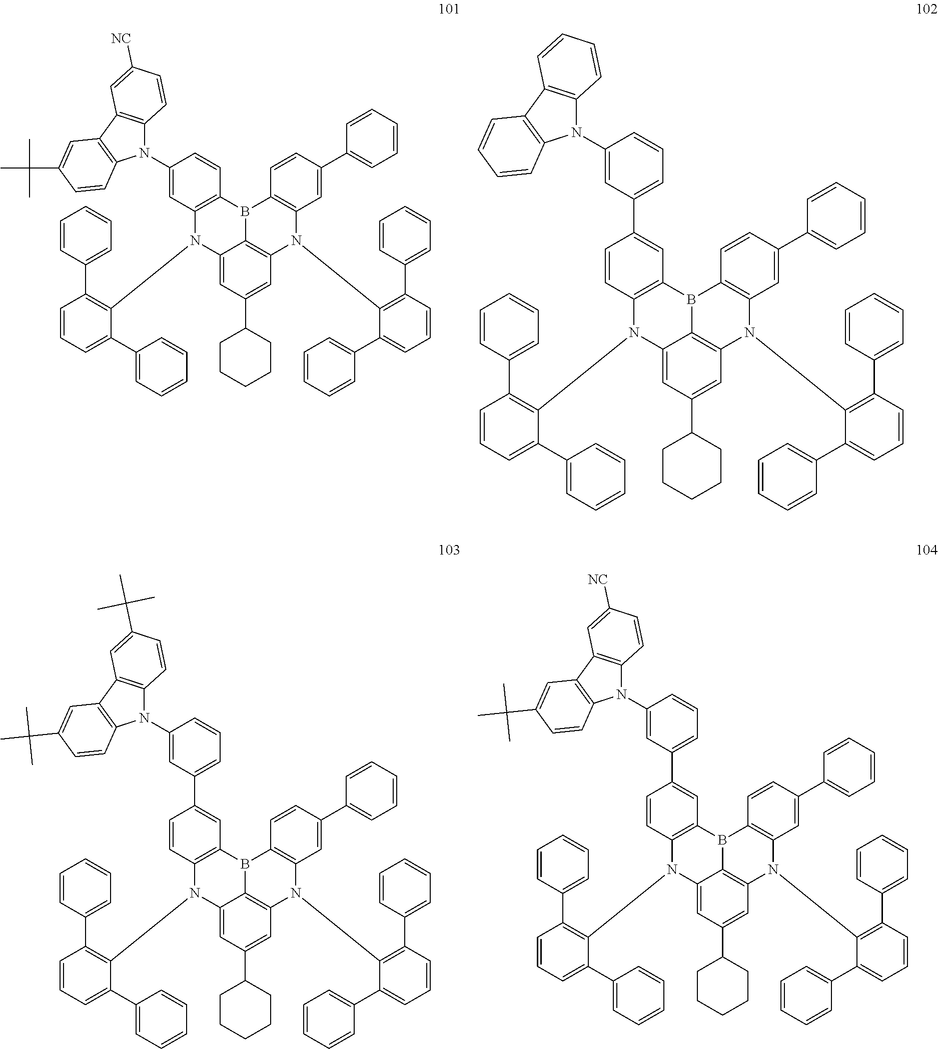

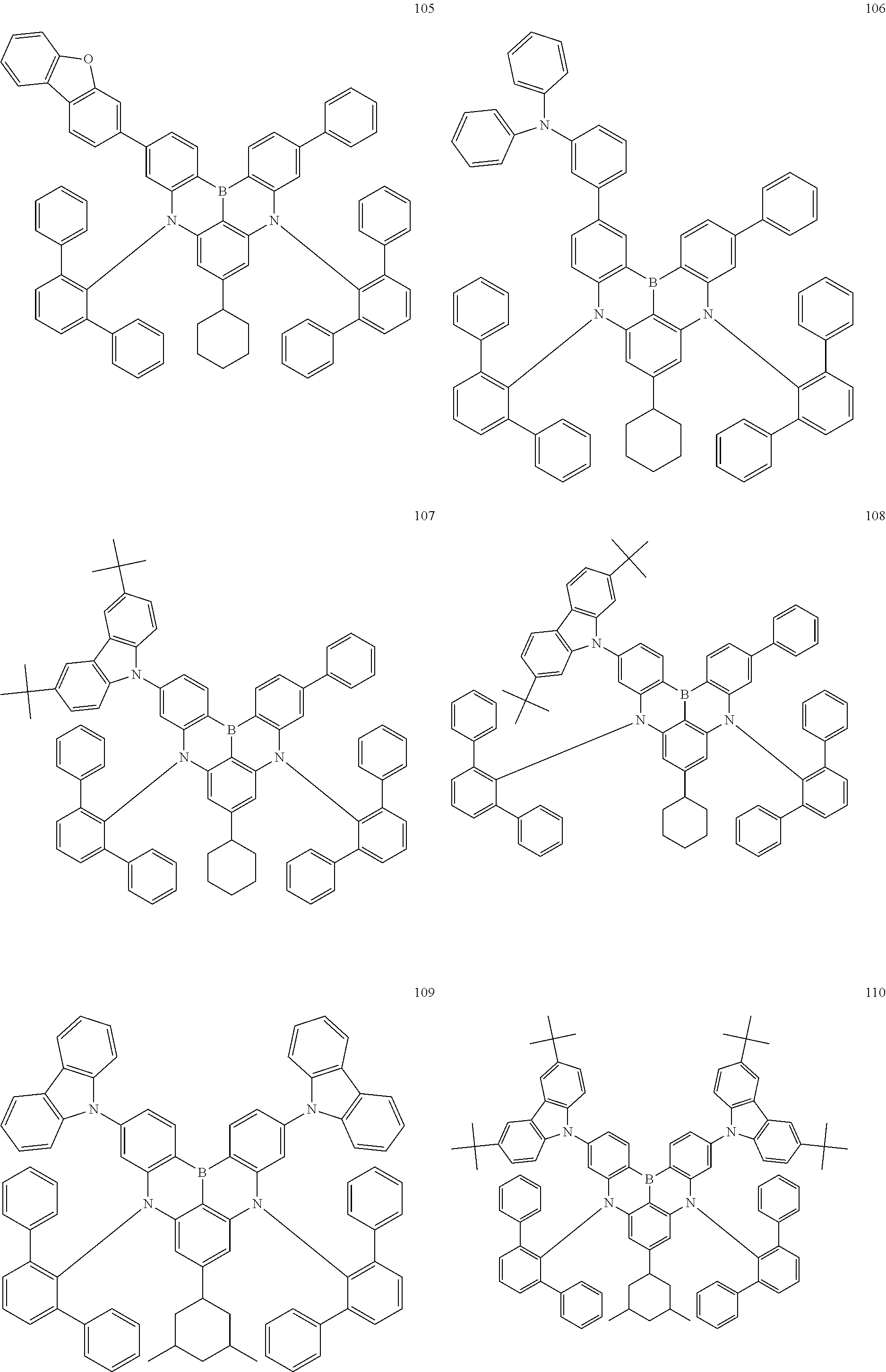

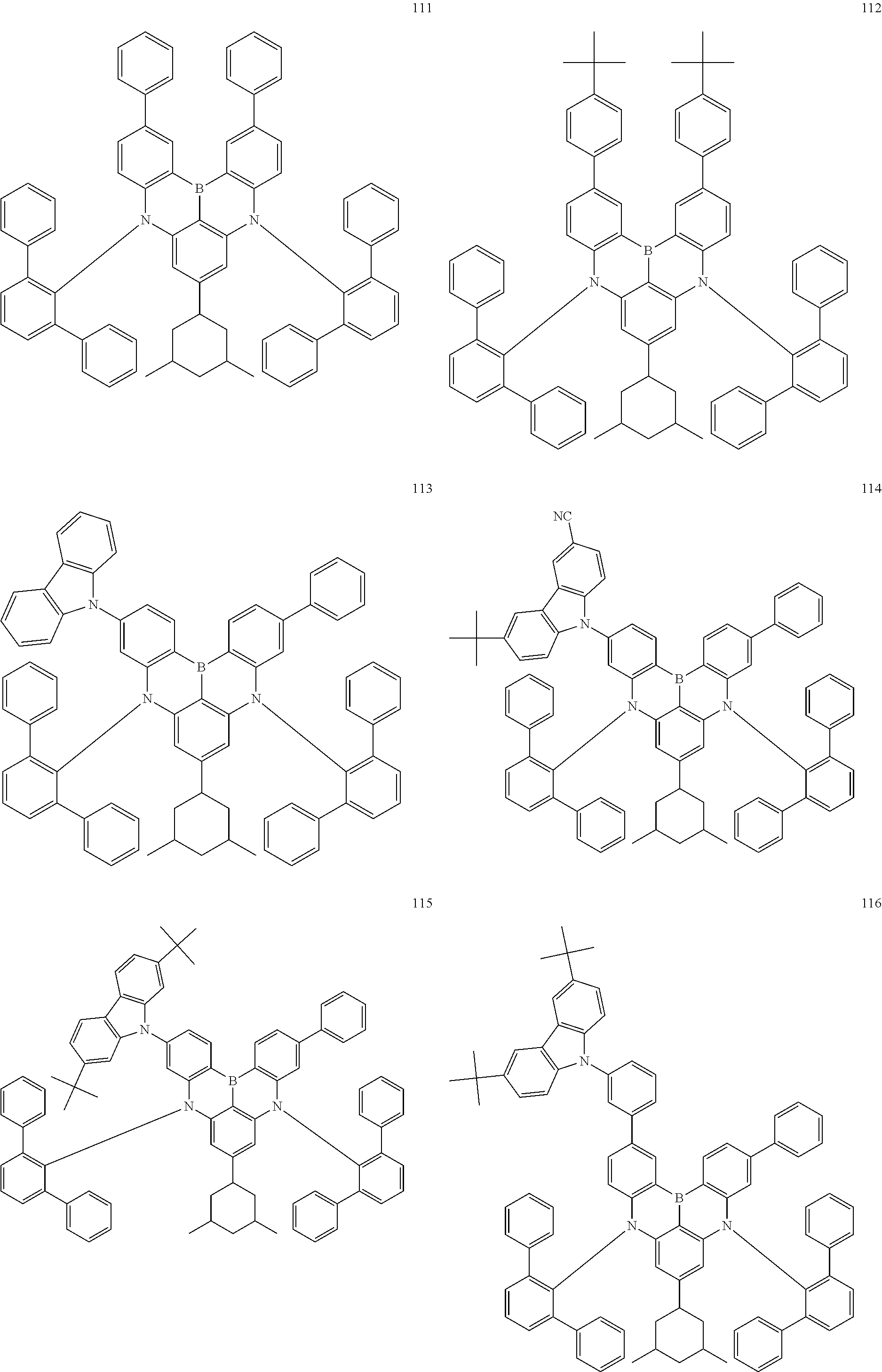

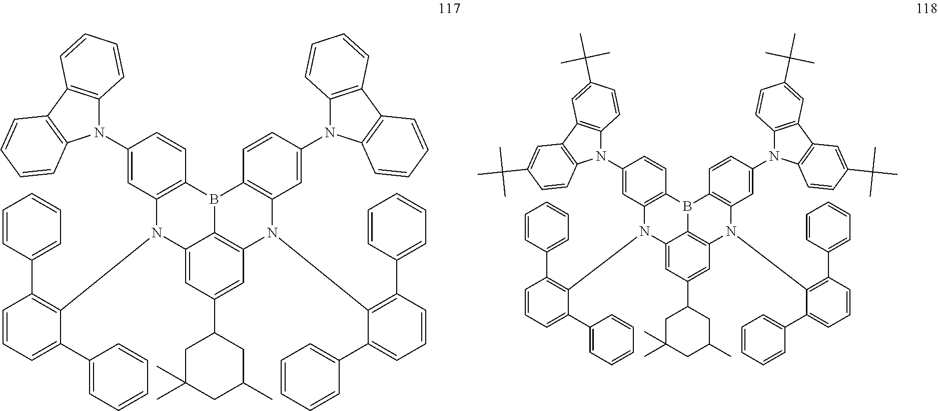 [SMILES: CC1CC(c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)CC(C)(C)C1 ; CC1CC(c2cc3c4c(c2)N(c2c(-c5ccccc5)cccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3ccccc3)cccc2-c2ccccc2)CC(C)(C)C1]

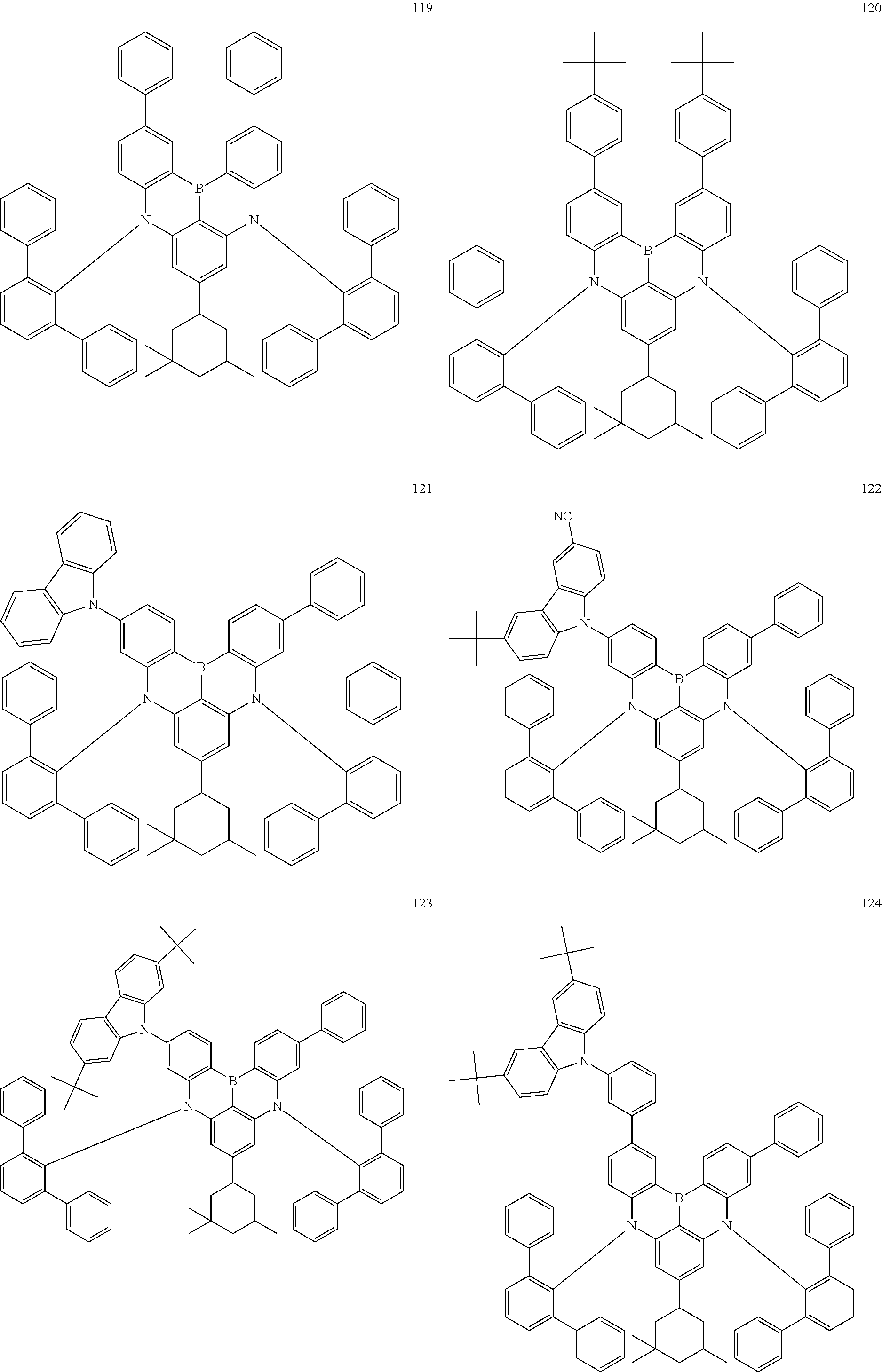

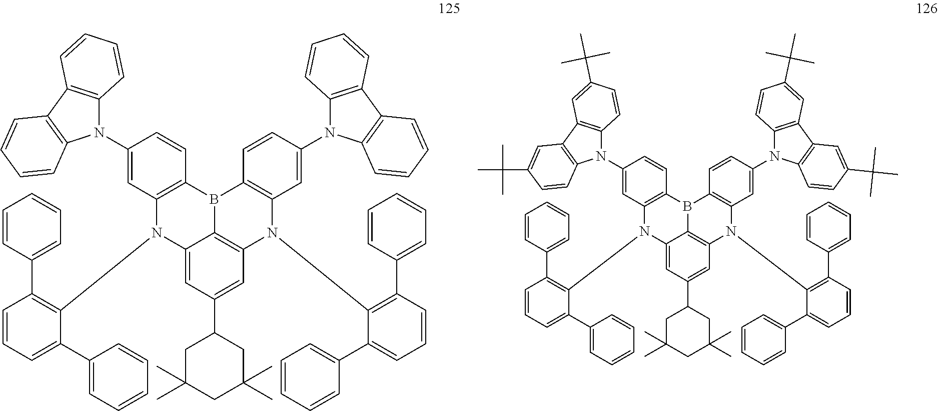 [SMILES: CC1(C)CC(c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)CC(C)(C)C1 ; CC1(C)CC(c2cc3c4c(c2)N(c2c(-c5ccccc5)cccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3ccccc3)cccc2-c2ccccc2)CC(C)(C)C1]

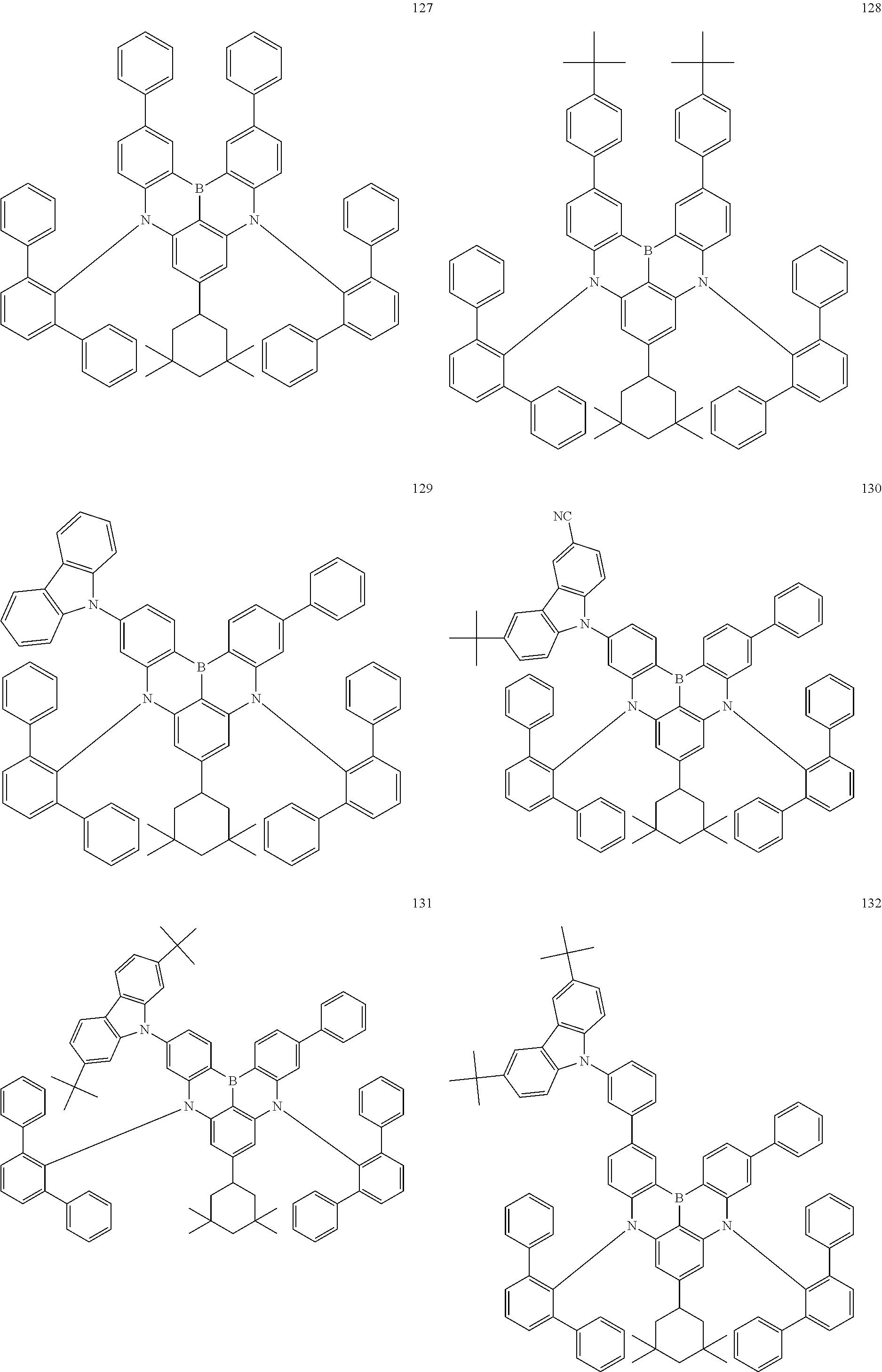

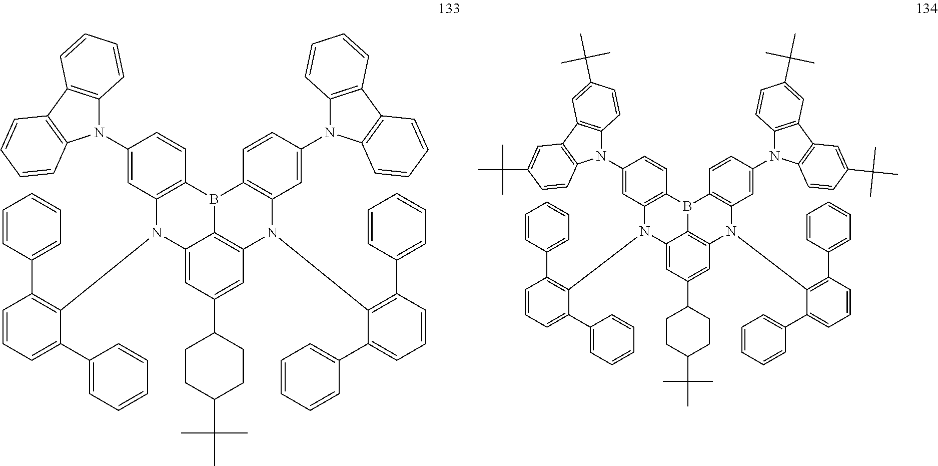 [SMILES: CC(C)(C)C1CCC(c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)CC1 ; CC(C)(C)c1ccc2c(c1)c1cc(C(C)(C)C)ccc1n2-c1ccc2c(c1)N(c1c(-c3ccccc3)cccc1-c1ccccc1)c1cc(C3CCC(C(C)(C)C)CC3)cc3c1B2c1ccc(-n2c4ccc(C(C)(C)C)cc4c4cc(C(C)(C)C)ccc42)cc1N3c1c(-c2ccccc2)cccc1-c1ccccc1]

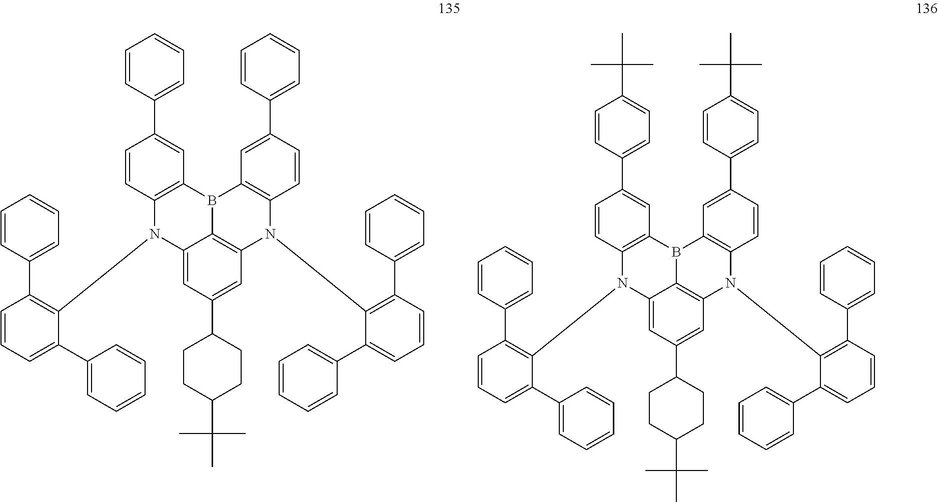 [SMILES: CC(C)(C)C1CCC(c2cc3c4c(c2)N(c2c(-c5ccccc5)cccc2-c2ccccc2)c2ccc(-c5ccccc5)cc2B4c2cc(-c4ccccc4)ccc2N3c2c(-c3ccccc3)cccc2-c2ccccc2)CC1 ; CC(C)(C)c1ccc(-c2ccc3c(c2)B2c4cc(-c5ccc(C(C)(C)C)cc5)ccc4N(c4c(-c5ccccc5)cccc4-c4ccccc4)c4cc(C5CCC(C(C)(C)C)CC5)cc(c42)N3c2c(-c3ccccc3)cccc2-c2ccccc2)cc1]

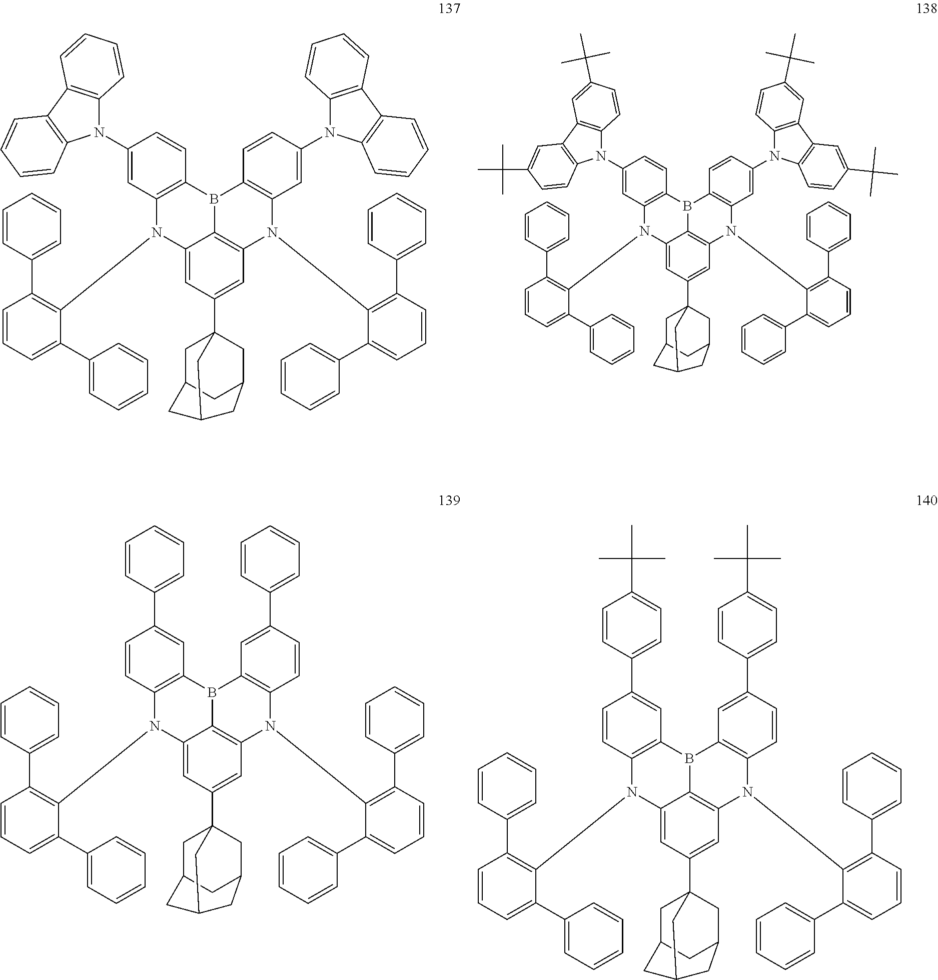

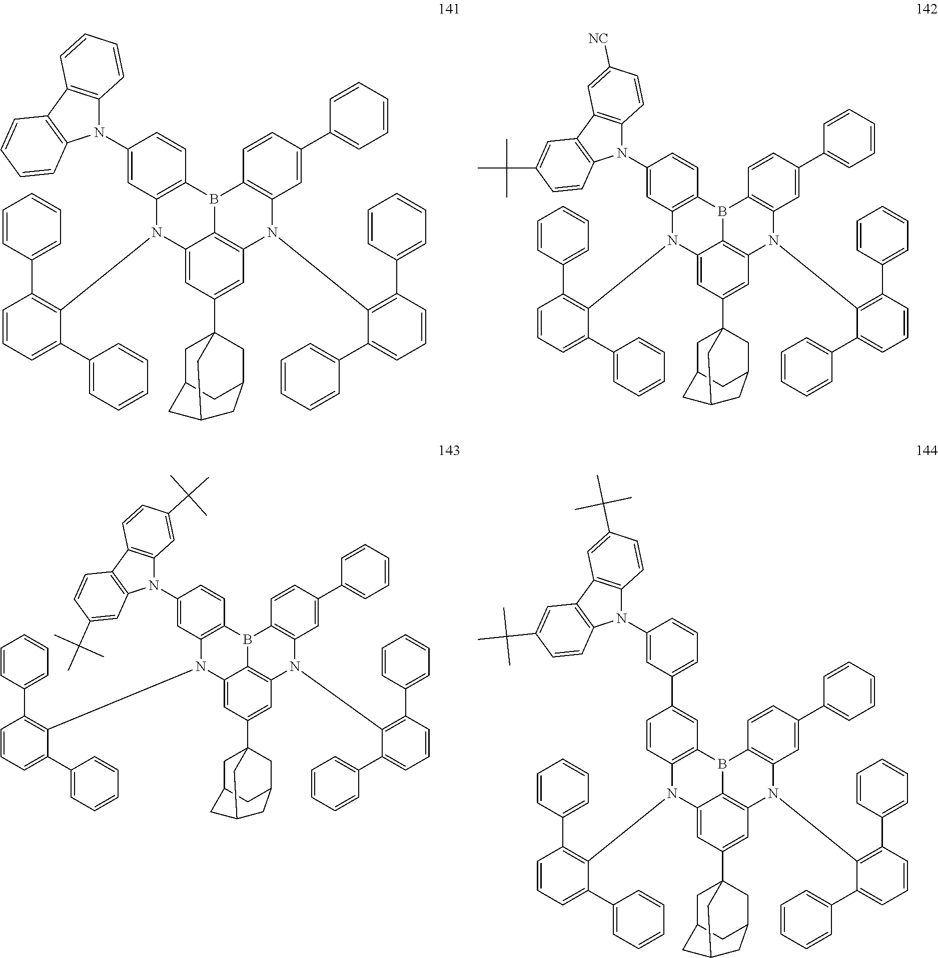

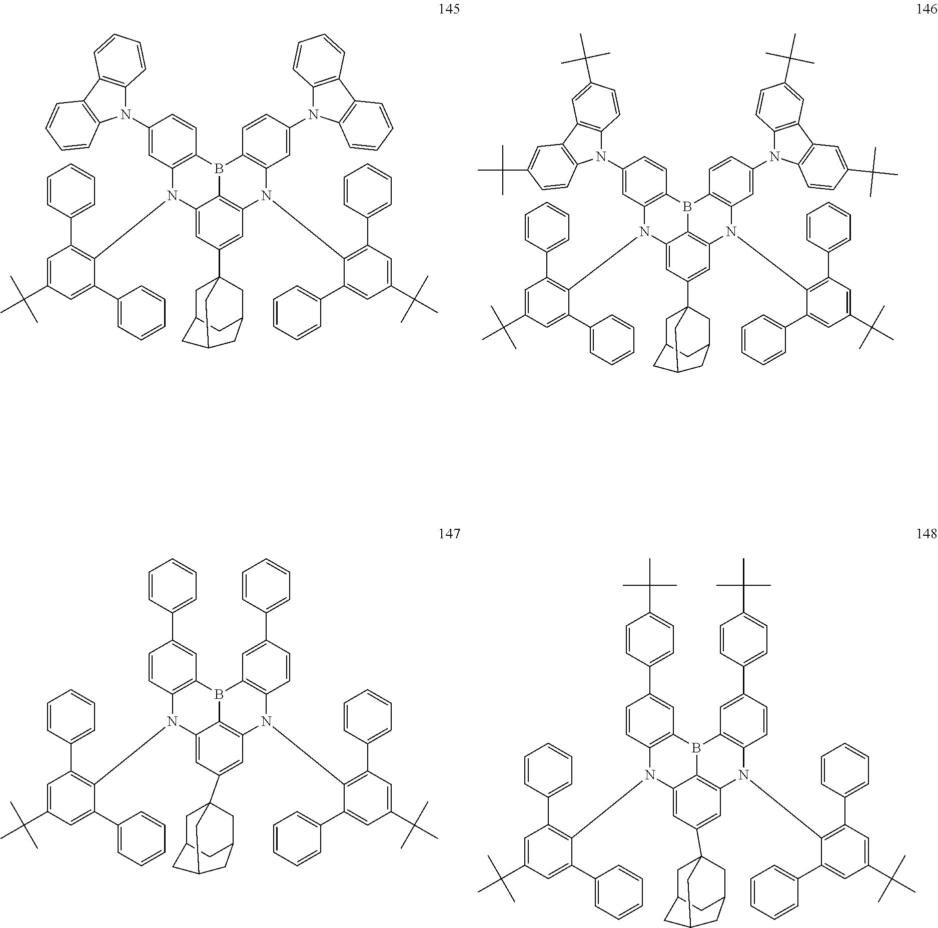

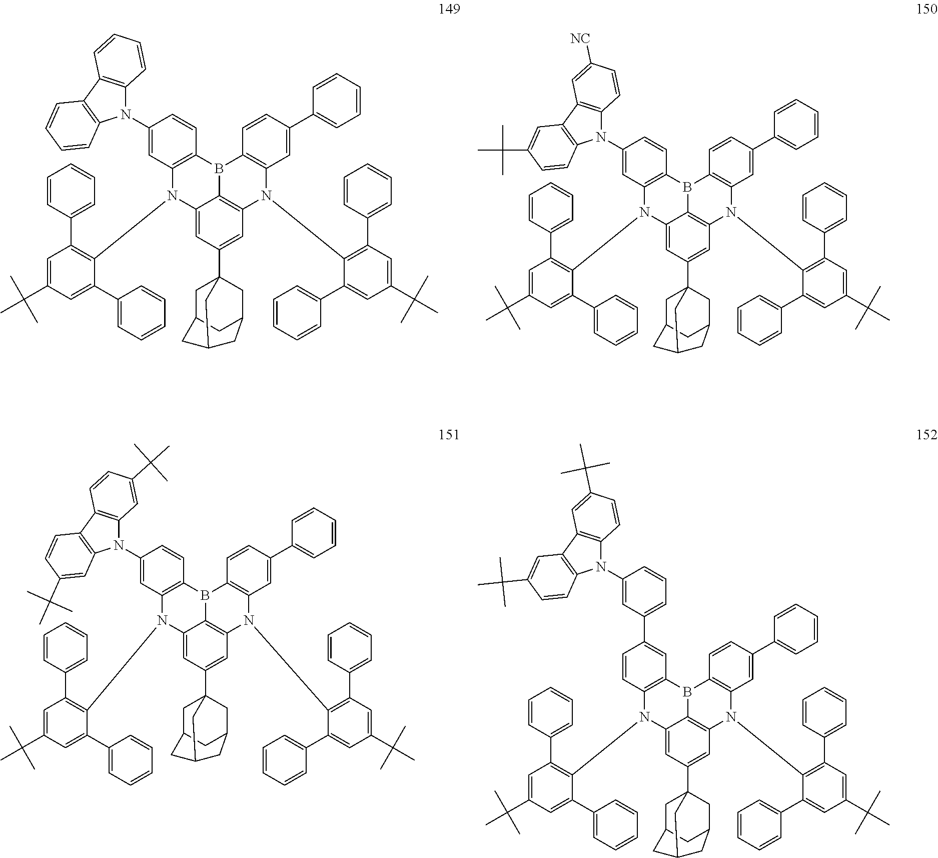

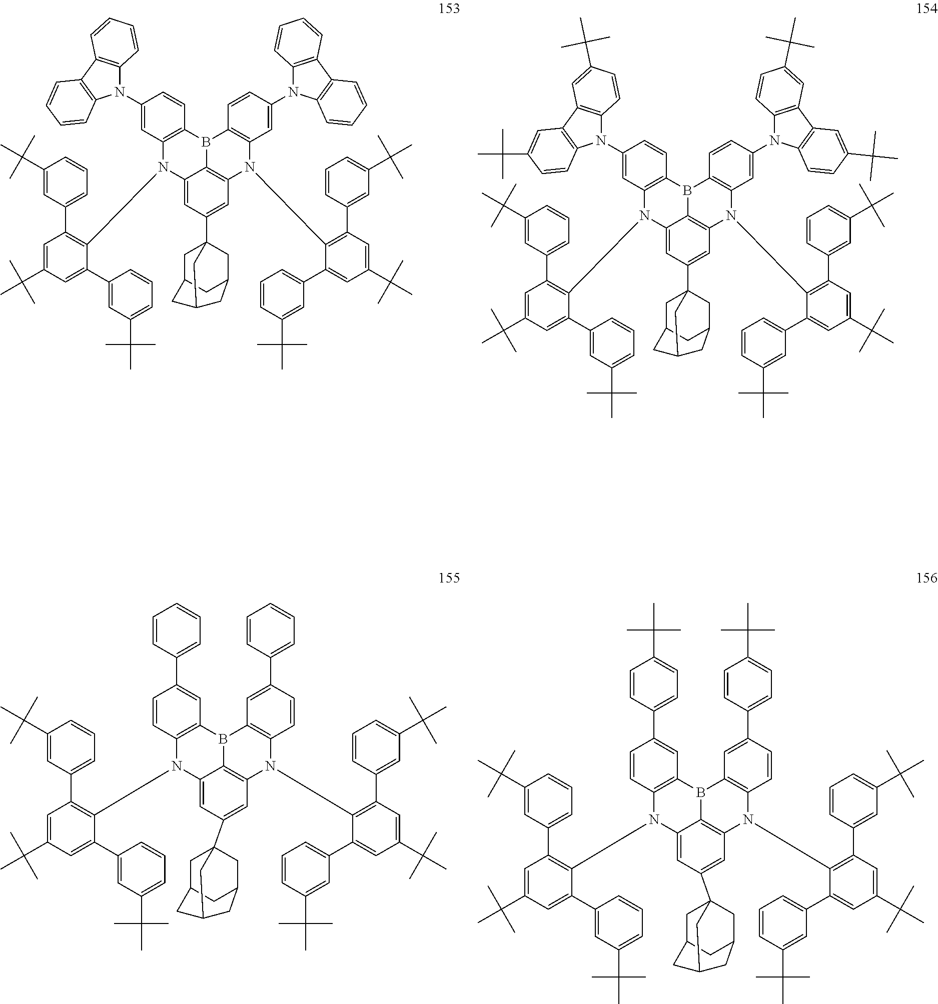

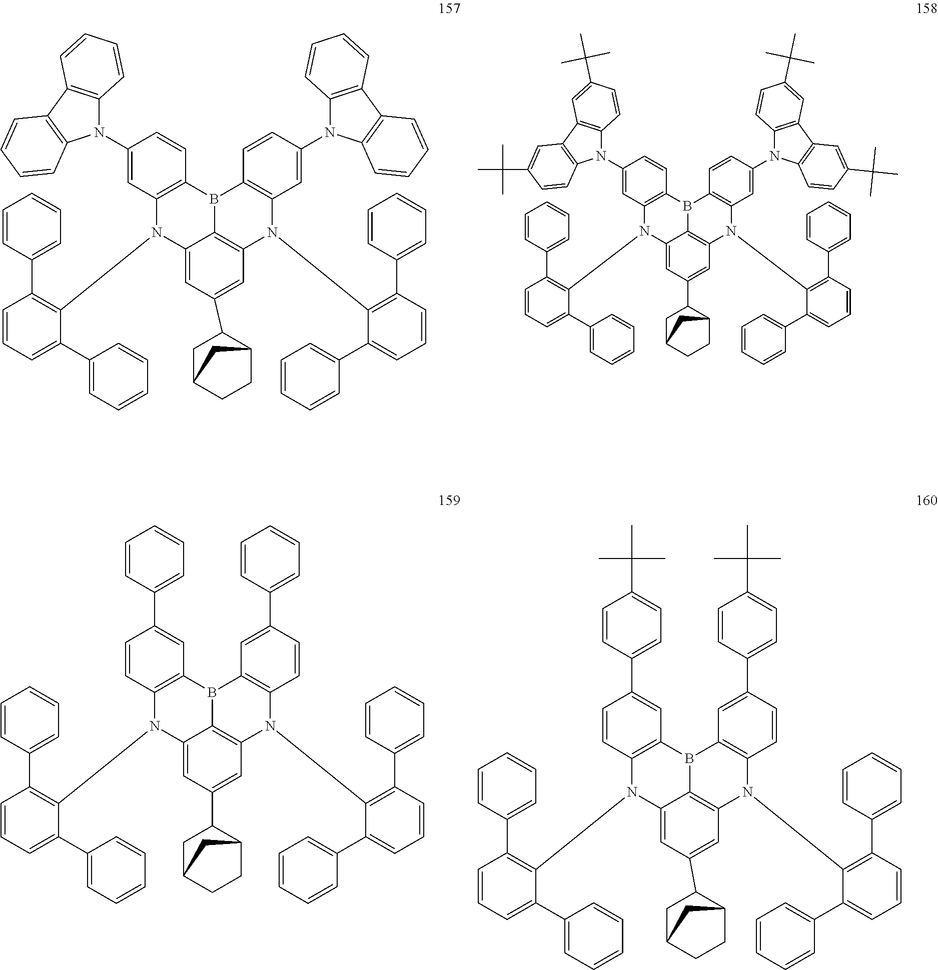

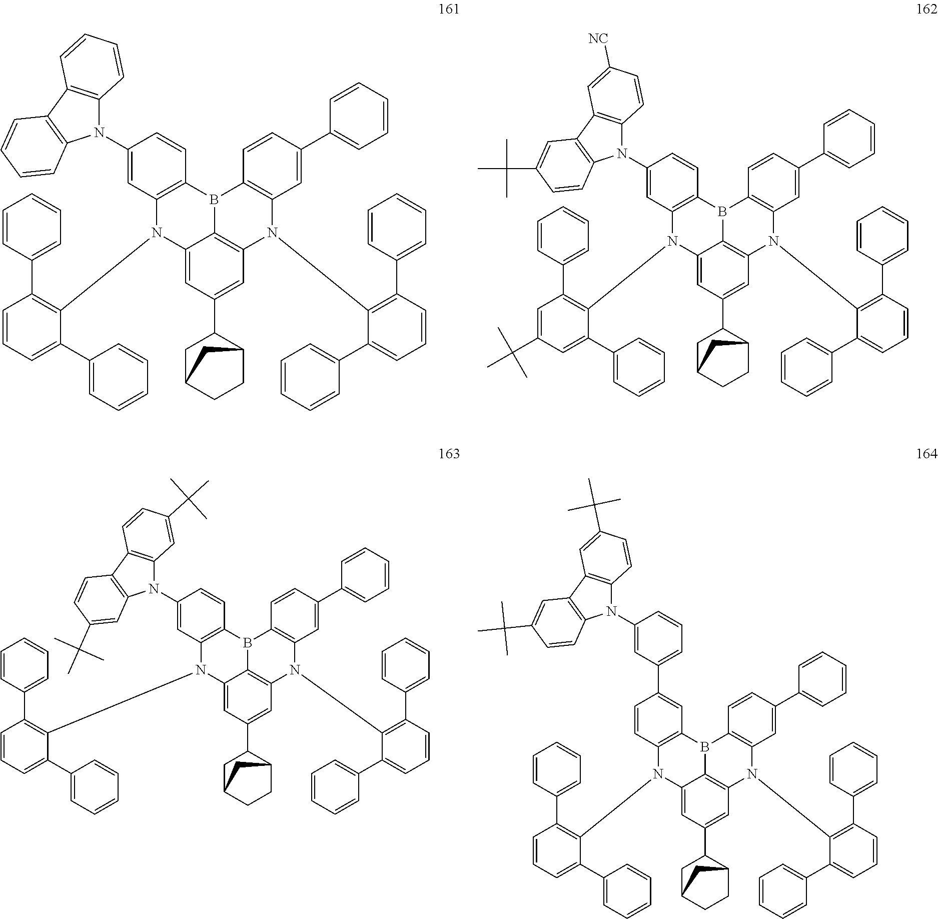

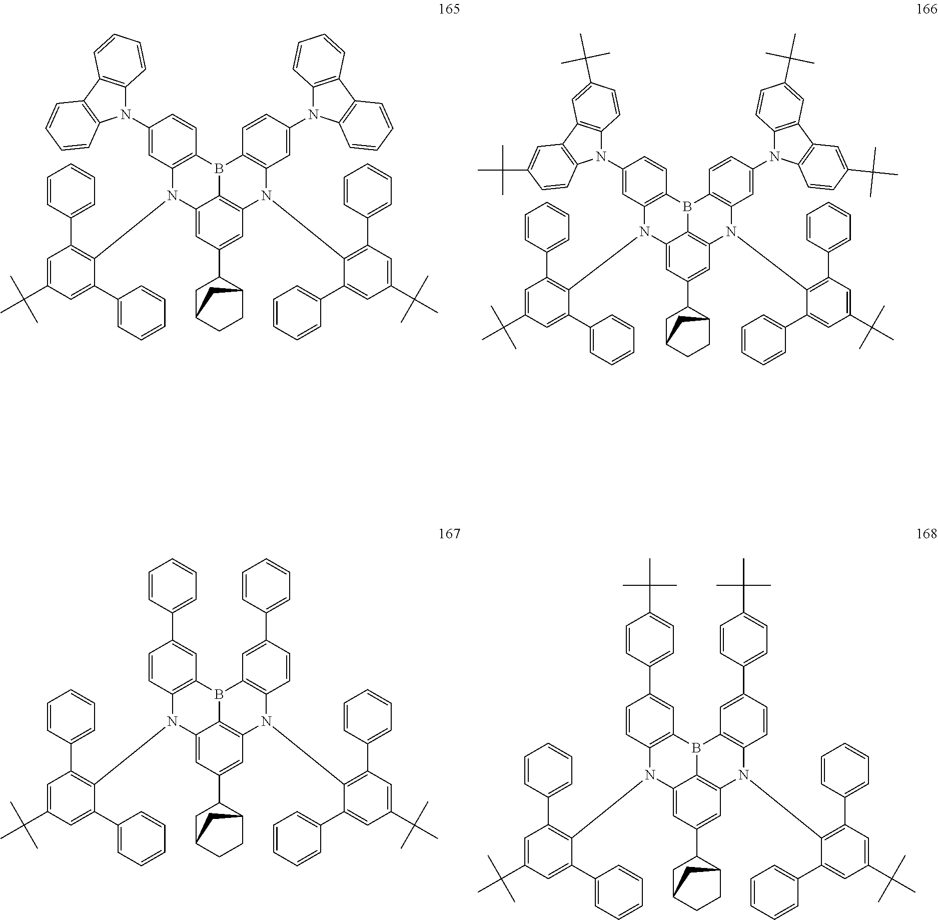

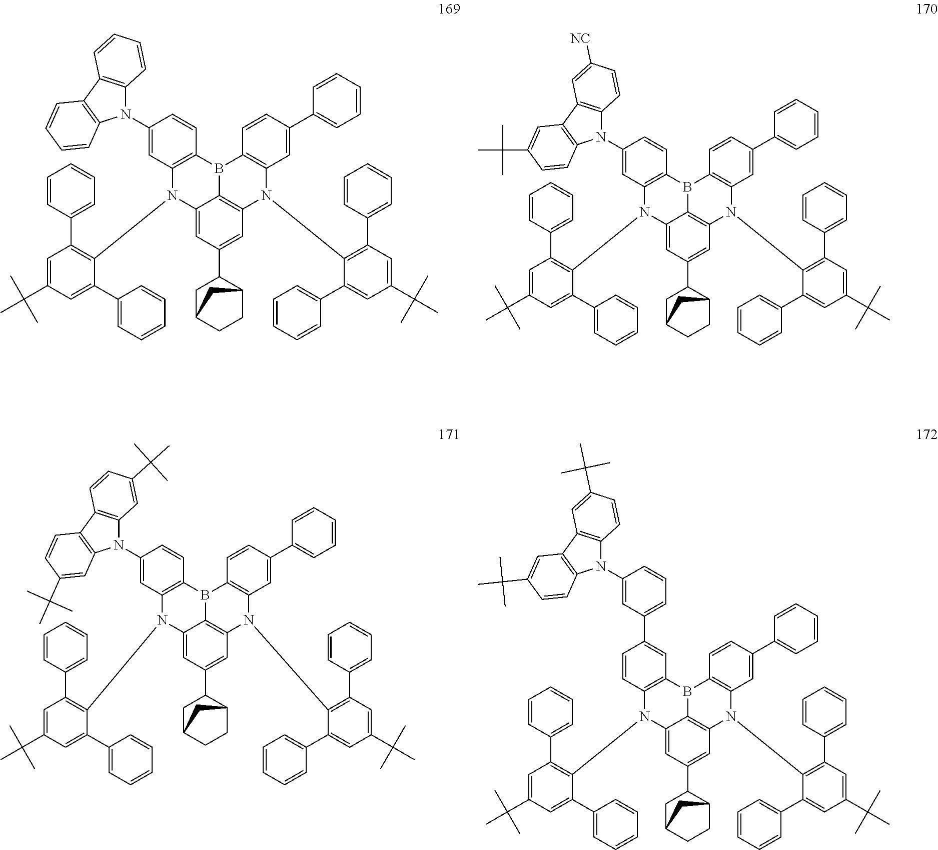

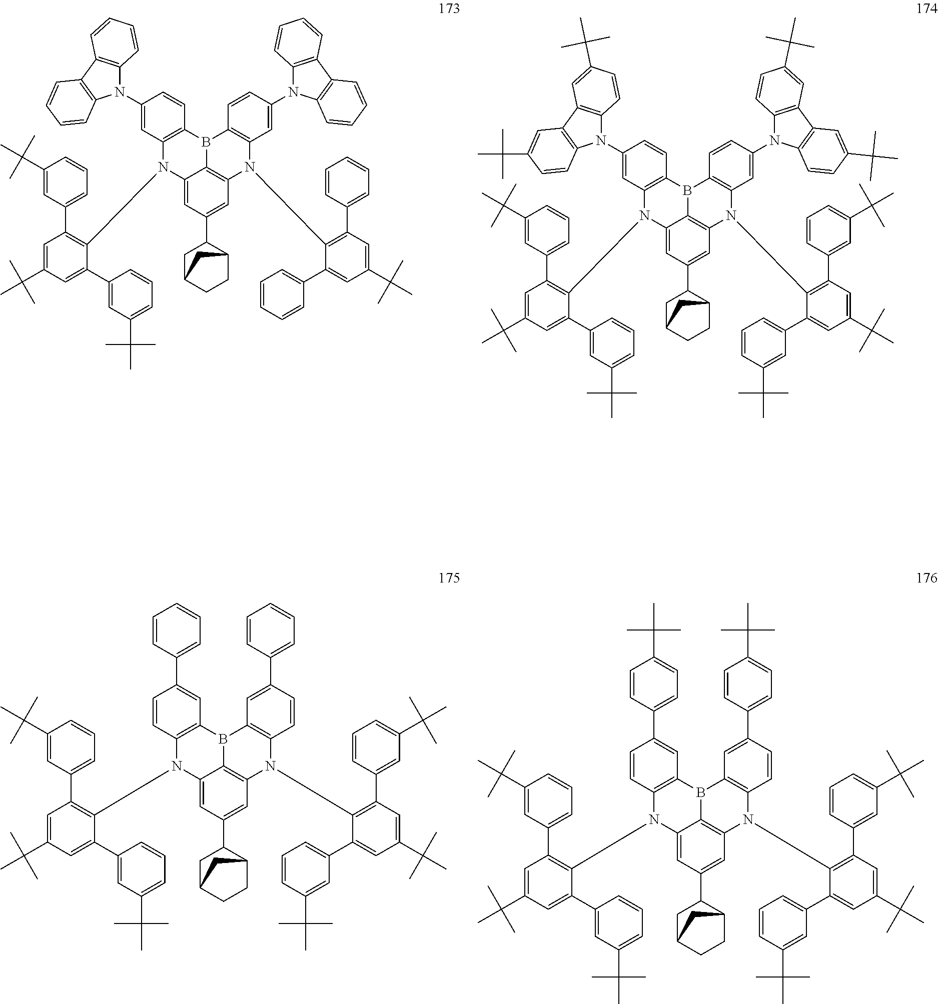

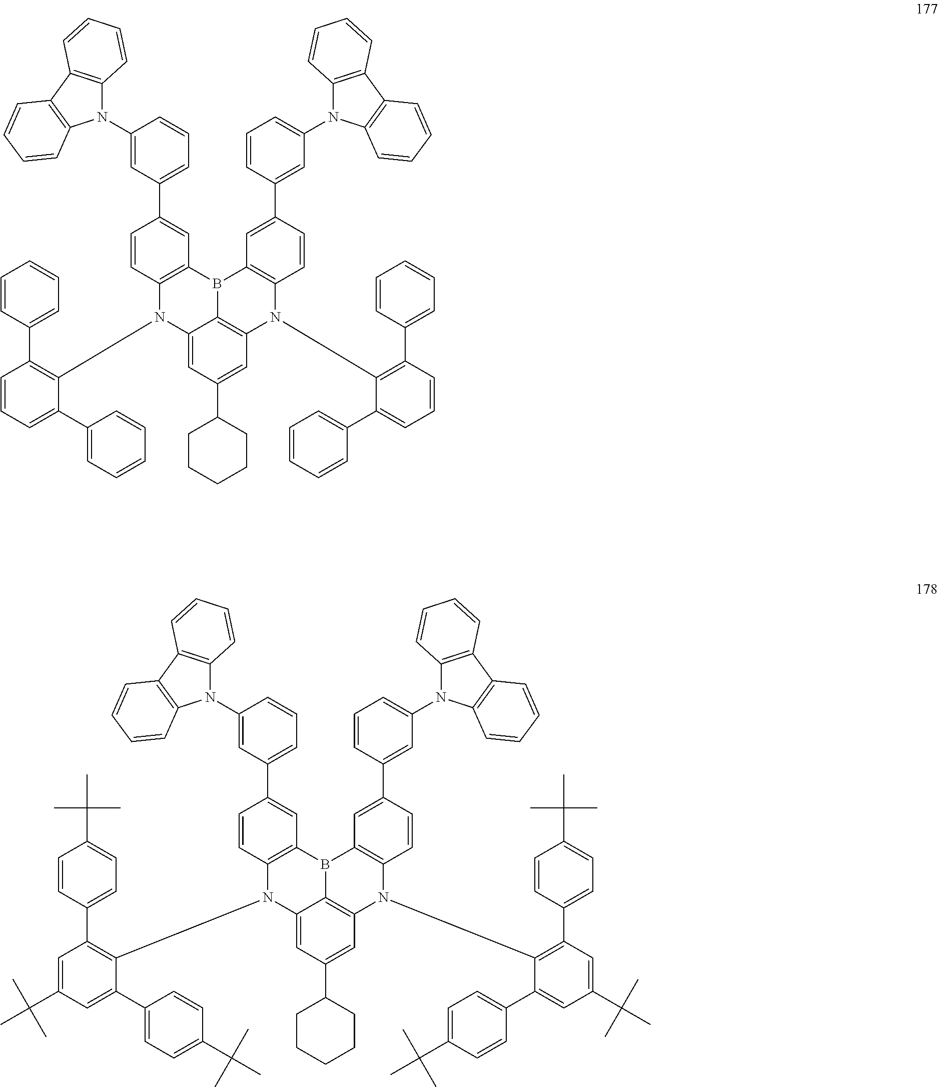 [SMILES: c1ccc(-c2cccc(-c3ccccc3)c2N2c3ccc(-c4cccc(-n5c6ccccc6c6ccccc65)c4)cc3B3c4cc(-c5cccc(-n6c7ccccc7c7ccccc76)c5)ccc4N(c4c(-c5ccccc5)cccc4-c4ccccc4)c4cc(C5CCCCC5)cc2c43)cc1 ; CC(C)(C)c1ccc(-c2cc(C(C)(C)C)cc(-c3ccc(C(C)(C)C)cc3)c2N2c3ccc(-c4cccc(-n5c6ccccc6c6ccccc65)c4)cc3B3c4cc(-c5cccc(-n6c7ccccc7c7ccccc76)c5)ccc4N(c4c(-c5ccc(C(C)(C)C)cc5)cc(C(C)(C)C)cc4-c4ccc(C(C)(C)C)cc4)c4cc(C5CCCCC5)cc2c43)cc1]

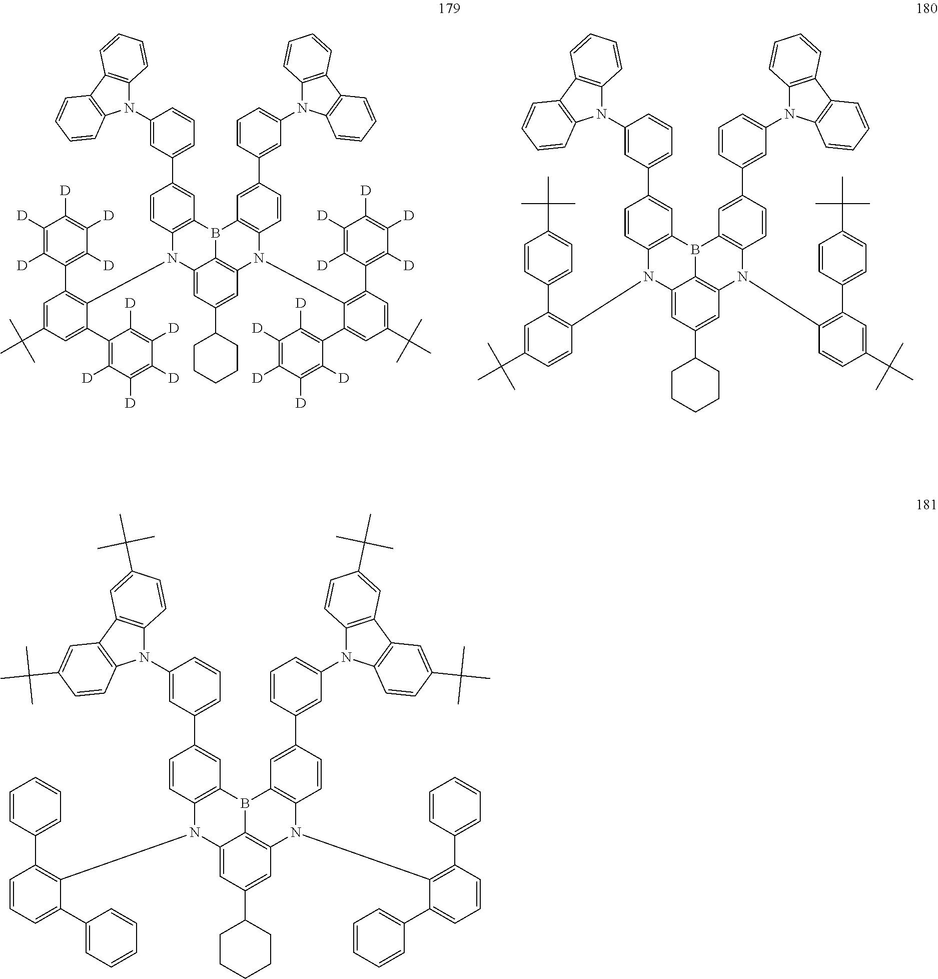

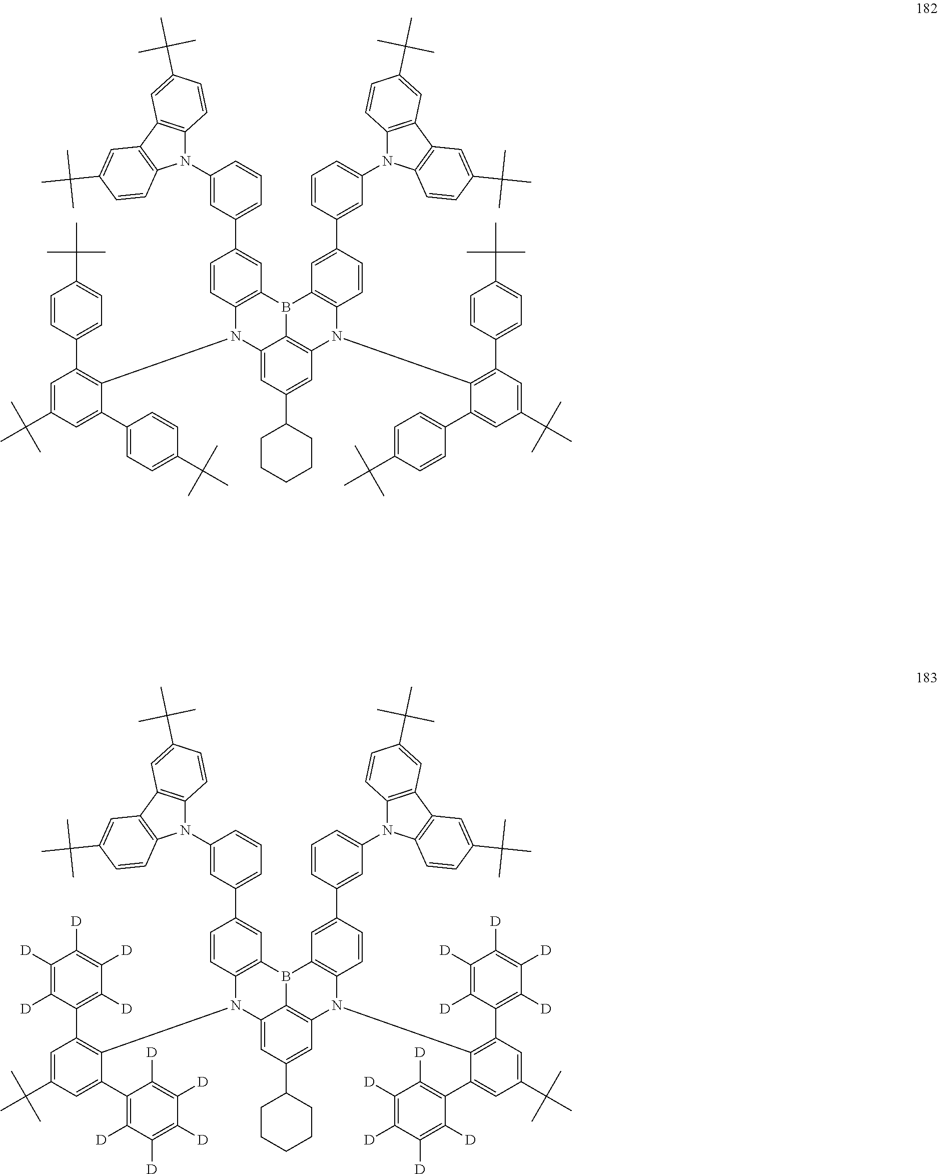

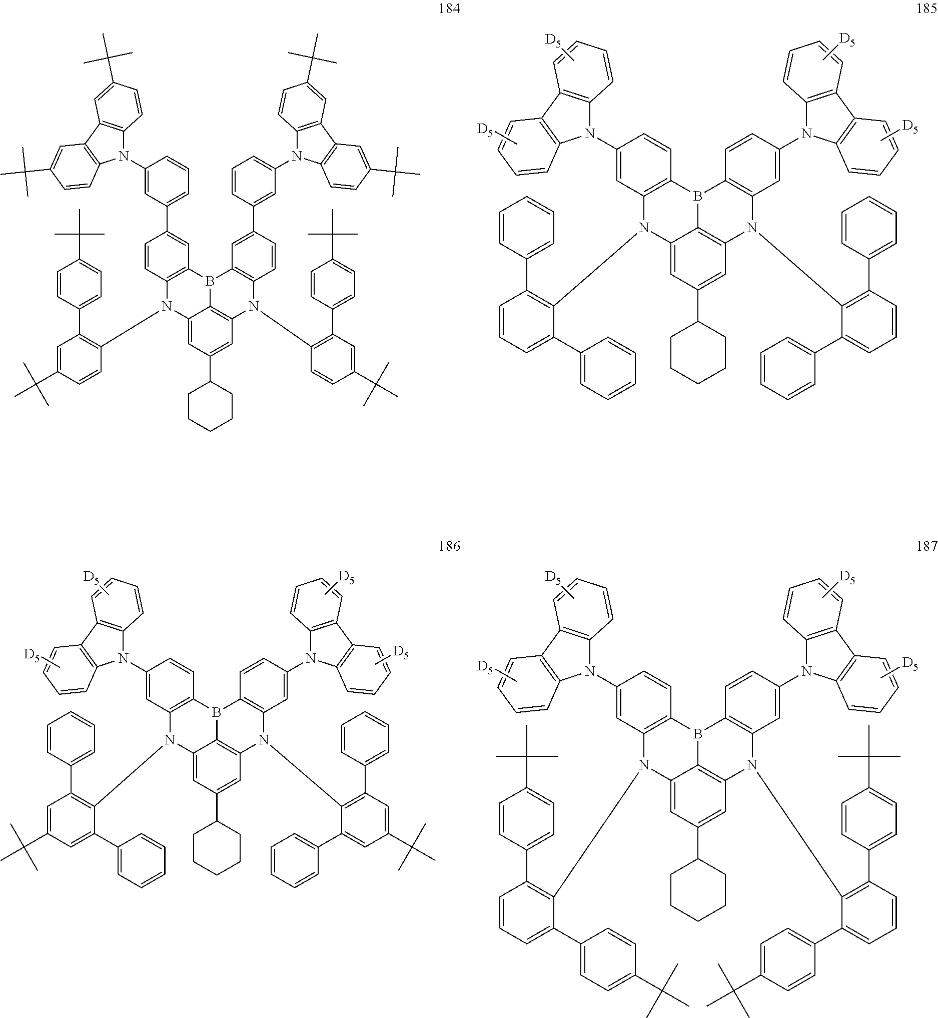

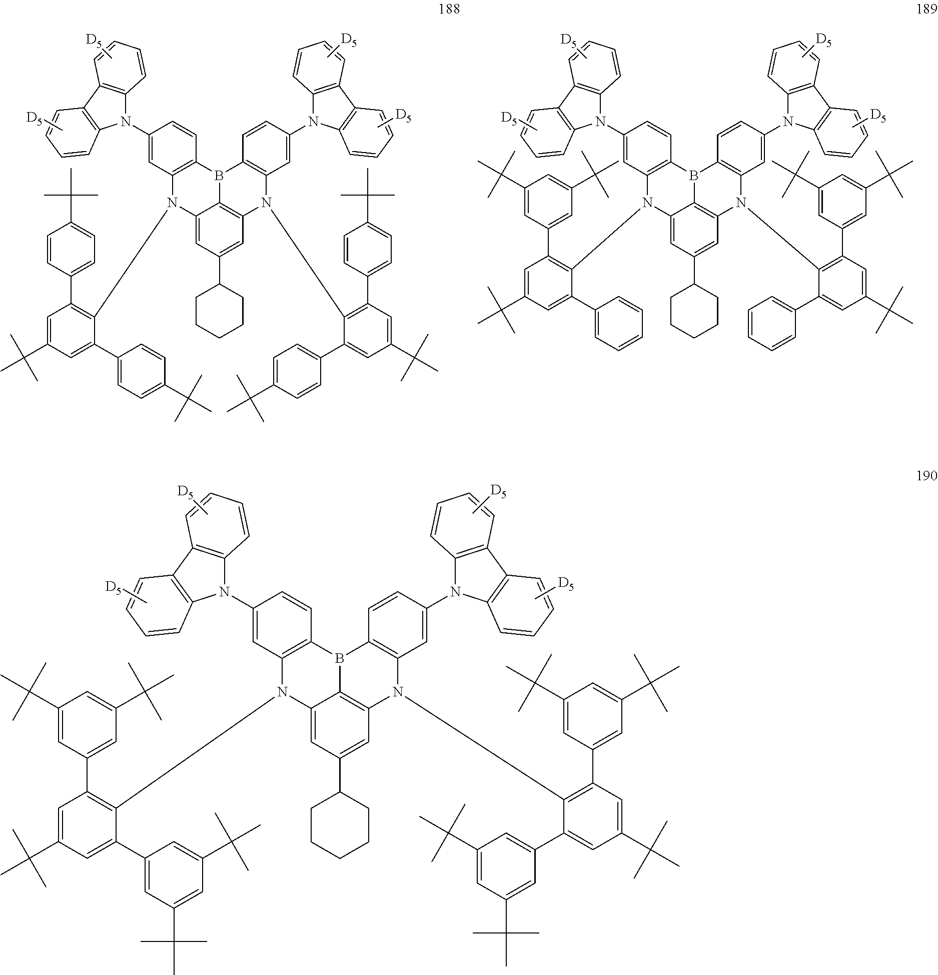

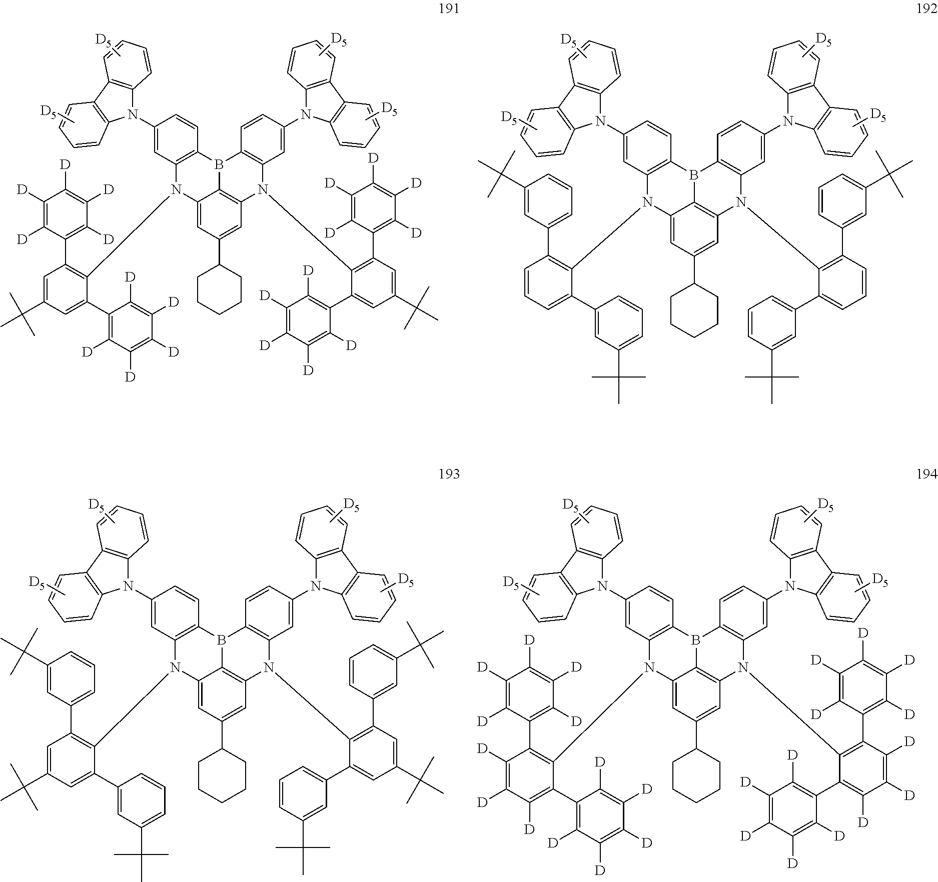

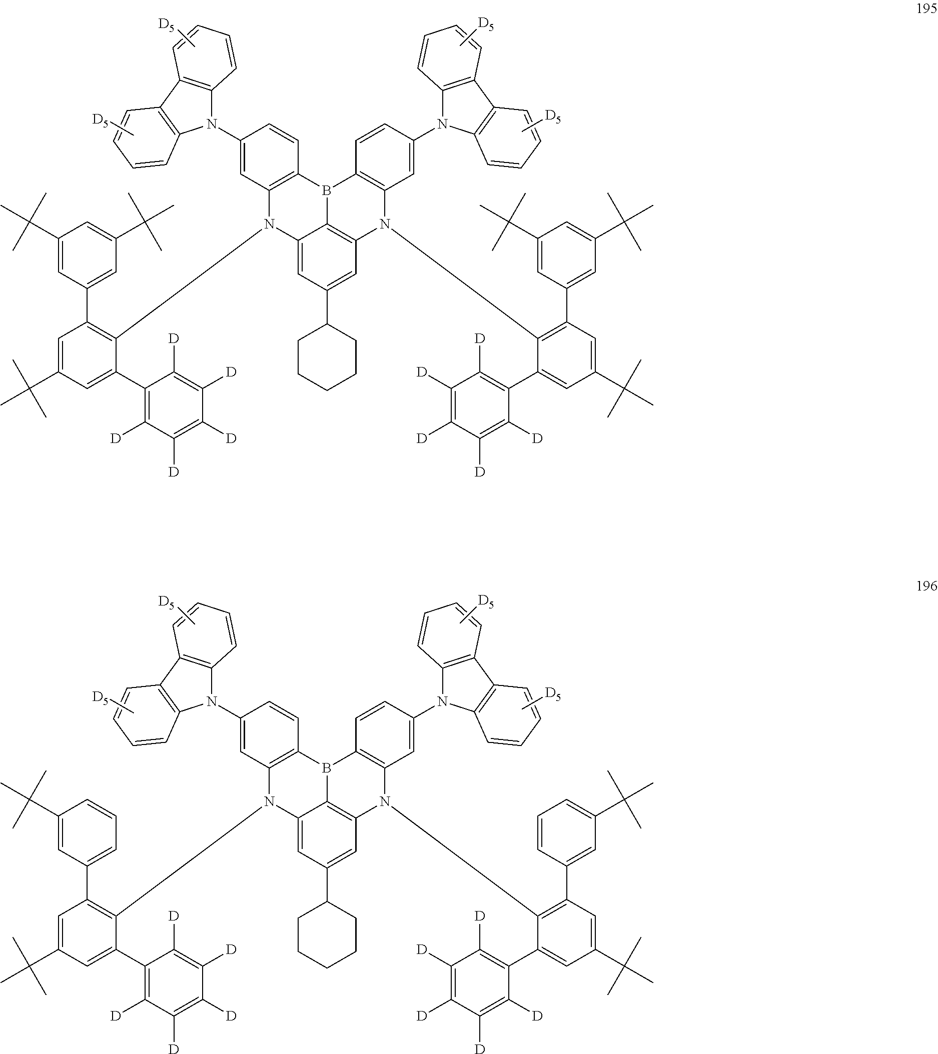

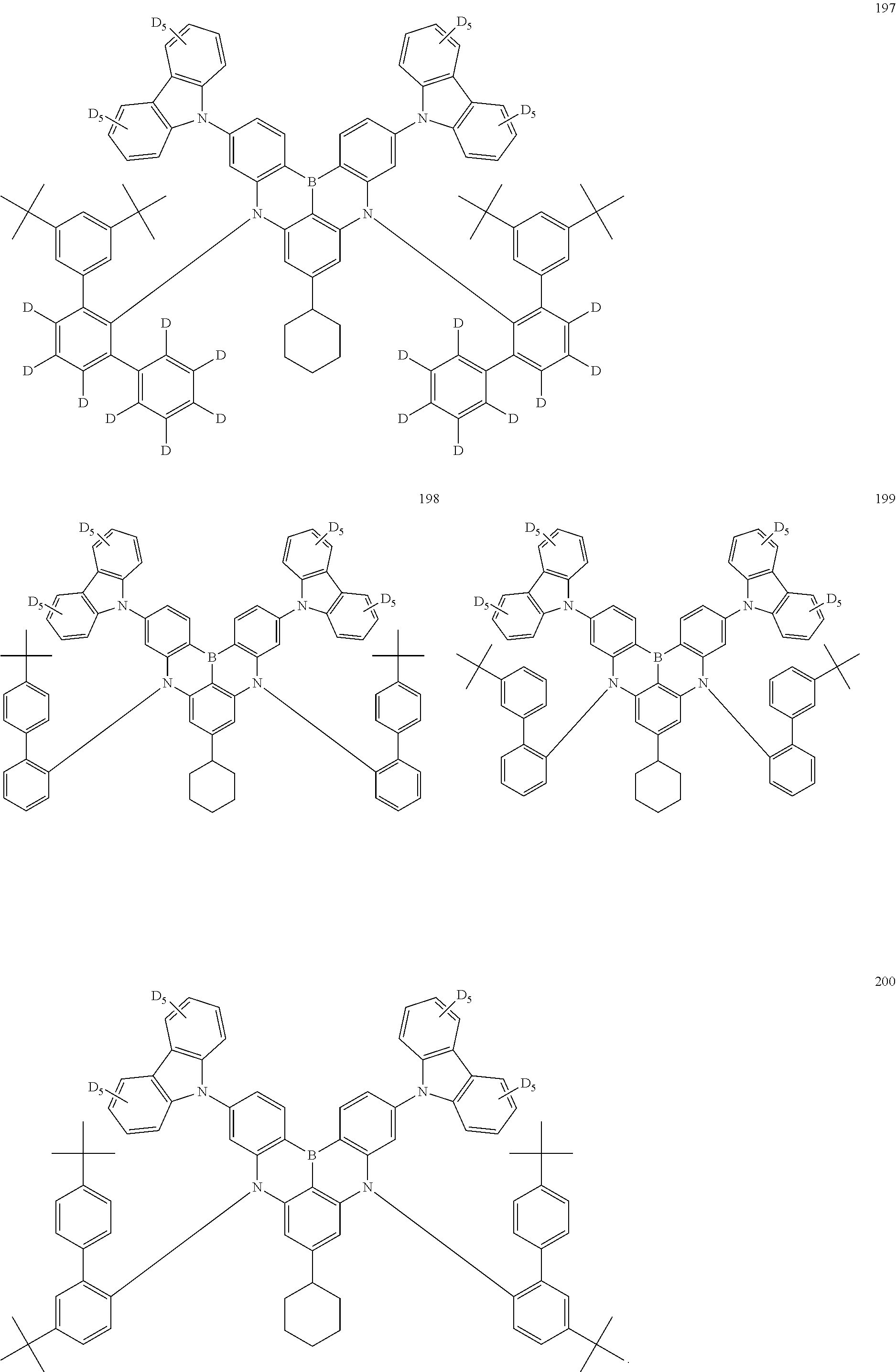

10. The light emitting device of claim 1, wherein the emission layer further includes at least one of a second compound represented by Formula HT-1 or a third compound represented by Formula ET-1: 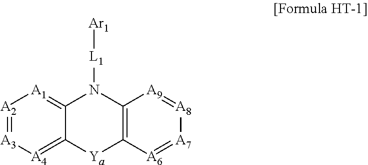
wherein in Formula HT-1,
A₁ to A₄ and A₆ to A₉ are each independently N or C(R₄₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₄₂)(R₄₃), or Si(R₄₄)(R₄₅),
Ar₁ is a substituted or unsubstituted aryl group having 6 to 30 ring-forming carbon atoms or a substituted or unsubstituted heteroaryl group having 2 to 30 ring-forming carbon atoms, and
R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring; and 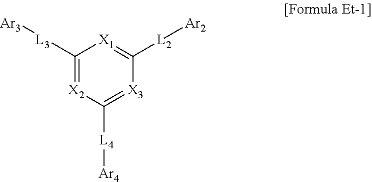
wherein in Formula ET-1,
at least one of X₁ to X₃ is each N,
the remainder of X₁ to X₃ are each independently C(R₄₆),
R₄₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

11. The light emitting device of claim 1, wherein the emission layer further includes a fourth compound represented by Formula D-1: 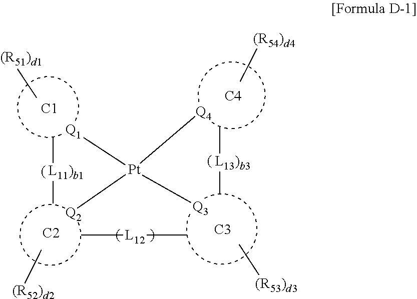
wherein in Formula D-1,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, 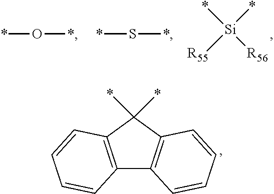
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer from 0 to 4.

12. A fused polycyclic compound represented by Formula 1: 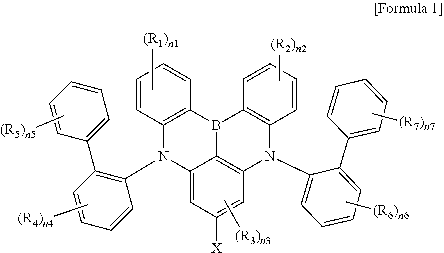
wherein in Formula 1,
X is a substituted or unsubstituted cycloalkyl group having 6 to 12 ring-forming carbon atoms,
R₁ to R₇ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
n1, n2, n4, and n6 are each independently an integer from 0 to 4,
n3 is an integer from 0 to 2, and
n5 and n7 are each independently an integer from 0 to 5.

13. The fused polycyclic compound of claim 12, wherein X is a group represented by one of Formula A-1 to Formula A-4: 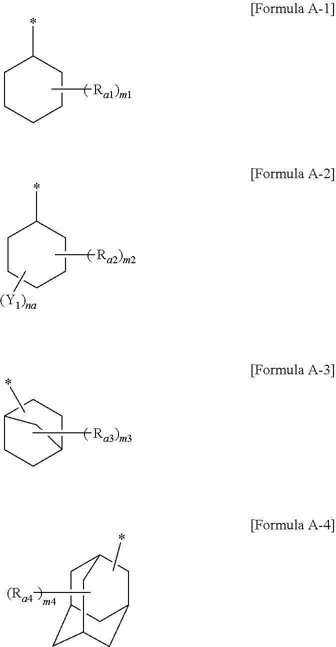
wherein in Formula A-1 to Formula A-4,
Rₐ₁ to Rₐ₄ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Y₁ is a substituted or unsubstituted alkyl group having 1 to 10 carbon atoms,
m1 and m3 are each independently an integer from 0 to 11,
m2 is an integer from 0 to 10,
na is an integer from 1 to 11,
a sum of m2 and na is less than or equal to 11,
m4 is an integer from 0 to 15, and [symbol]
represents a position linked to Formula 1.

14. The fused polycyclic compound of claim 12, wherein Formula 1 is represented by one of Formula 2-1 to Formula 2-3: 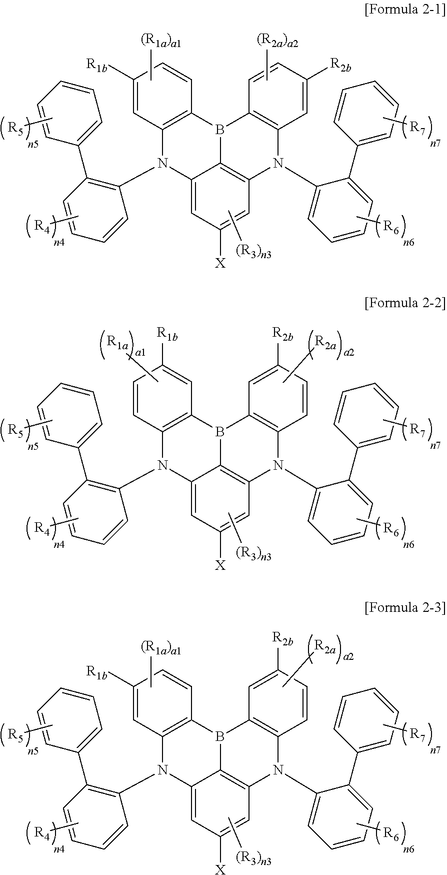
wherein in Formula 2-1 to Formula 2-3,
R₁ₐ and R₂ₐ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{1b} and R_{2b} are each independently a substituted or unsubstituted aryl group having 6 to 30 ring-forming carbon atoms or a substituted or unsubstituted heteroaryl group having 2 to 30 ring-forming carbon atoms,
a1 and a2 are each independently an integer from 0 to 3, and
X, R₃ to R₇, and n3 to n7 are the same as defined in Formula 1.

15. The fused polycyclic compound of claim 14, wherein R_{1b} and R_{2b} are each independently a group represented by one of Formula B-1 to Formula B-3: 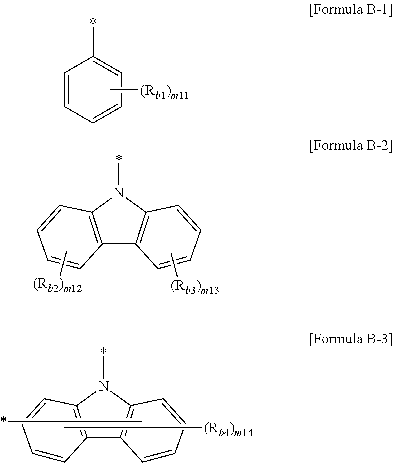
wherein in Formula B-1 to Formula B-3,
Z is N(R_{b5}), O, or S,
R_{b1} to R_{b5} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m11 is an integer from 0 to 5,
m12 and m13 are each independently an integer from 0 to 4, and
m14 is an integer from 0 to 7.

16. The fused polycyclic compound of claim 12, wherein Formula 1 is represented by one of Formula 3-1 to Formula 3-7: 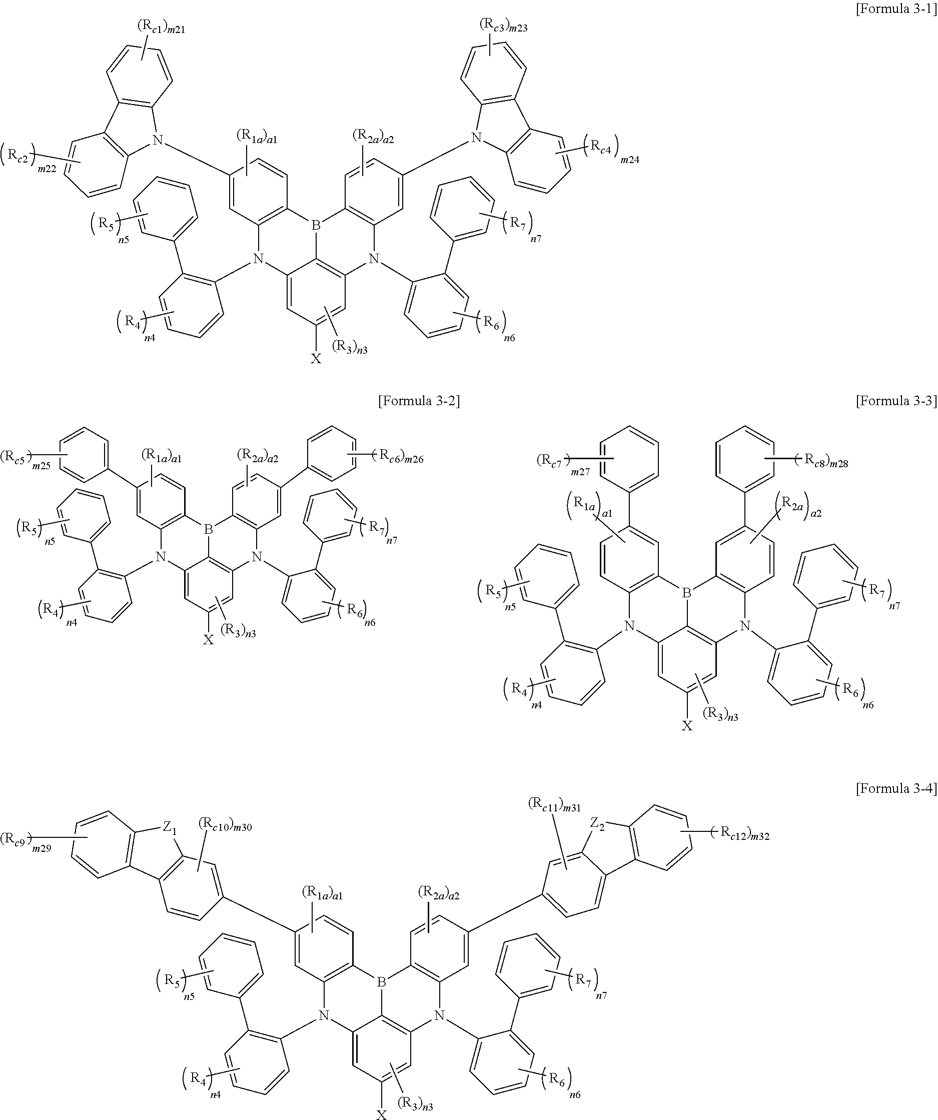 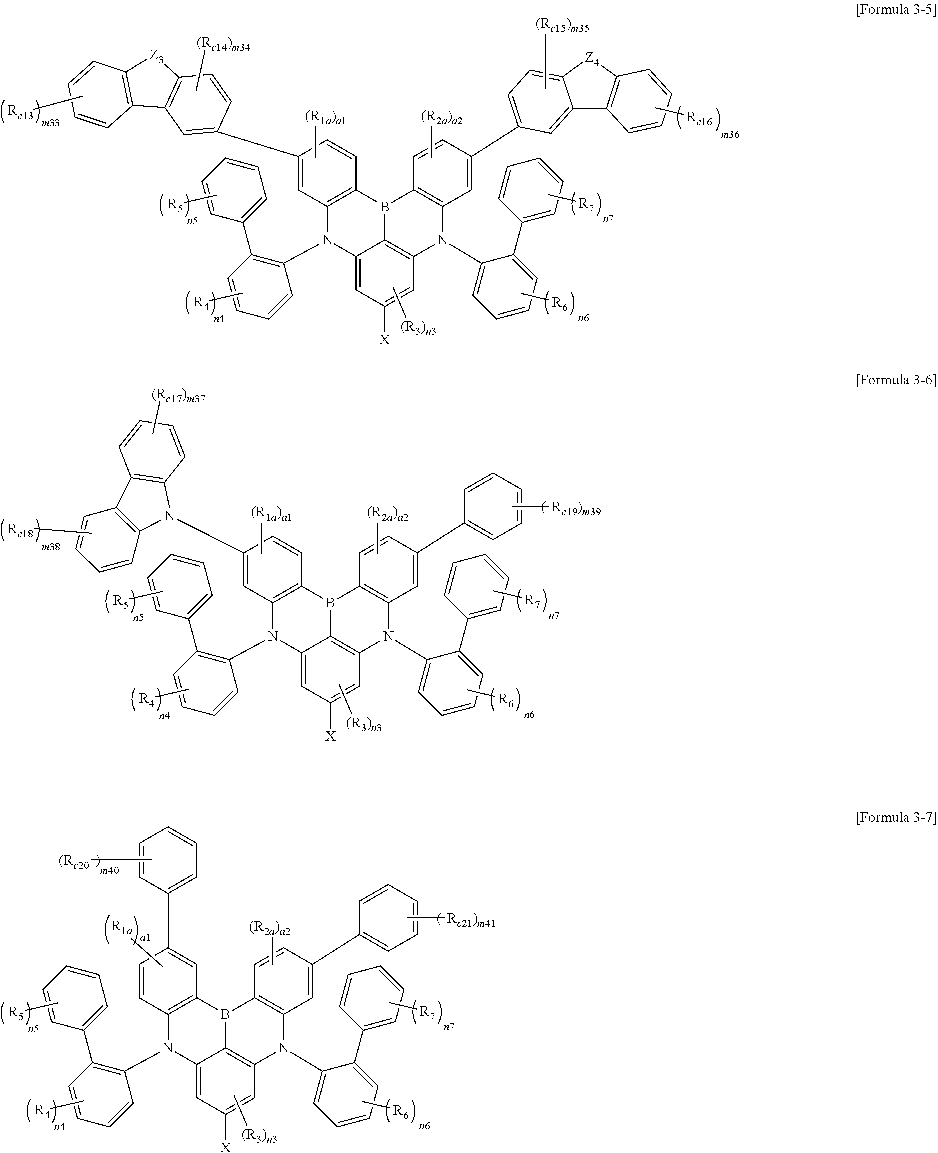
wherein in Formula 3-1 to Formula 3-7,
R₁ₐ and R₂ₐ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
Z₁ to Z₄ are each independently N(R_{c22}), O, or S,
R_{c1} to R_{c22} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a1 and a2 are each independently an integer from 0 to 3,
m21 to m24, m29, m32, m33, and m36 to m38 are each independently an integer from 0 to 4,
m25 to m28 and m39 to m41 are each independently an integer from 0 to 5,
m30, m31, m34, and m35 are each independently an integer from 0 to 3, and
X, R₃ to R₇, and n3 to n7 are the same as defined in Formula 1.

17. The fused polycyclic compound of claim 12, wherein Formula 1 is represented by one of Formula 4-1 to Formula 4-4: 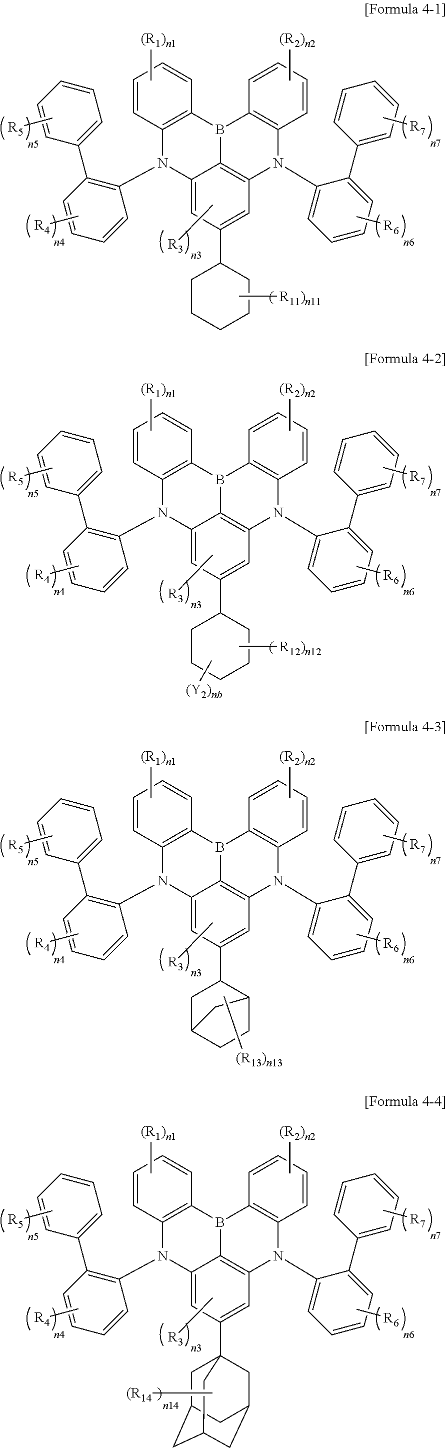
wherein in Formula 4-1 to Formula 4-4,
R₁₁ to R₁₄ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Y₂ is a substituted or unsubstituted alkyl group having 1 to 10 carbon atoms,
n11 and n13 are each independently an integer from 0 to 11,
n12 is an integer from 0 to 10,
nb is an integer from 1 to 11,
a sum of n12 and nb is less than or equal to 11,
n14 is an integer from 0 to 15, and
R₁ to R₇ and n1 to n7 are the same as defined in Formula 1.

18. The fused polycyclic compound of claim 12, wherein Formula 1 is represented by Formula 5: 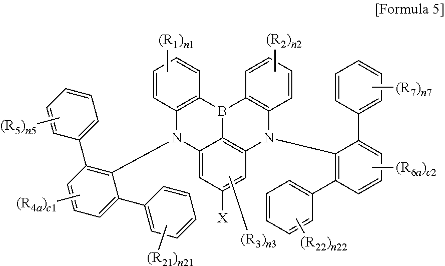
wherein in Formula 5,
R₄ₐ, R₆ₐ, R₂₁, and R₂₂ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
c1 and c2 are each independently an integer from 0 to 3,
n21 and n22 are each independently an integer from 0 to 5, and
X, R₁ to R₃, R₅, R₇, n1 to n3, n5, and n7 are the same as defined in Formula 1.

19. The fused polycyclic compound of claim 12, wherein Formula 1 is represented by one of Formula 6-1 to Formula 6-3: 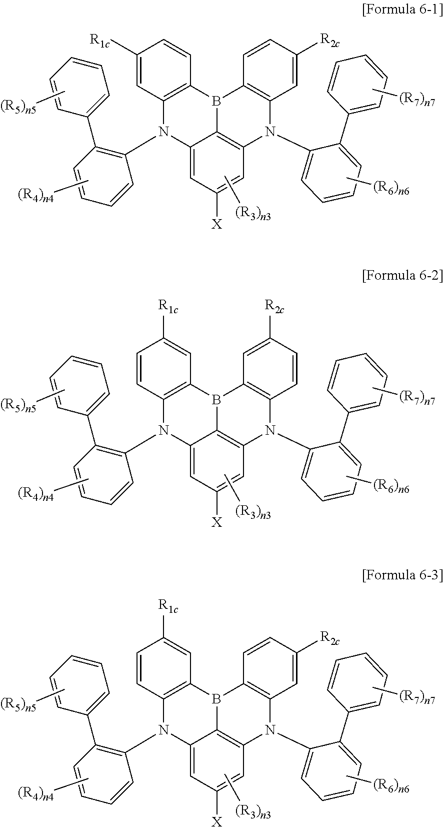
wherein in Formula 6-1 to Formula 6-3,
R_{1c} and R_{2c} are each independently a substituted or unsubstituted phenyl group, a substituted or unsubstituted carbazole group, or a substituted or unsubstituted dibenzofuran group, and
X, R₄ to R₇, and n4 to n7 are the same as defined in Formula 1.

20. The fused polycyclic compound of claim 12, wherein the fused polycyclic compound is selected from Compound Group 1: 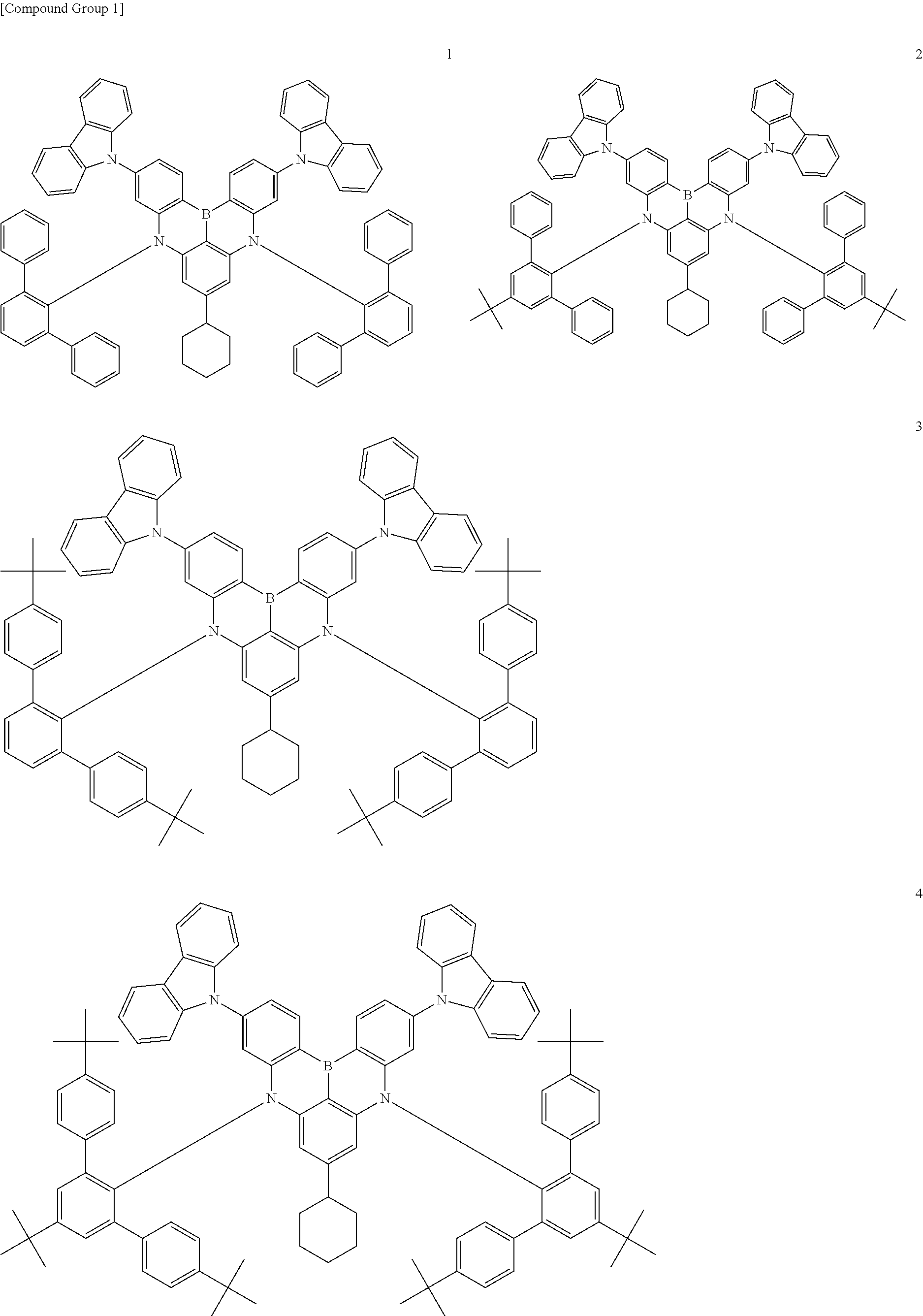 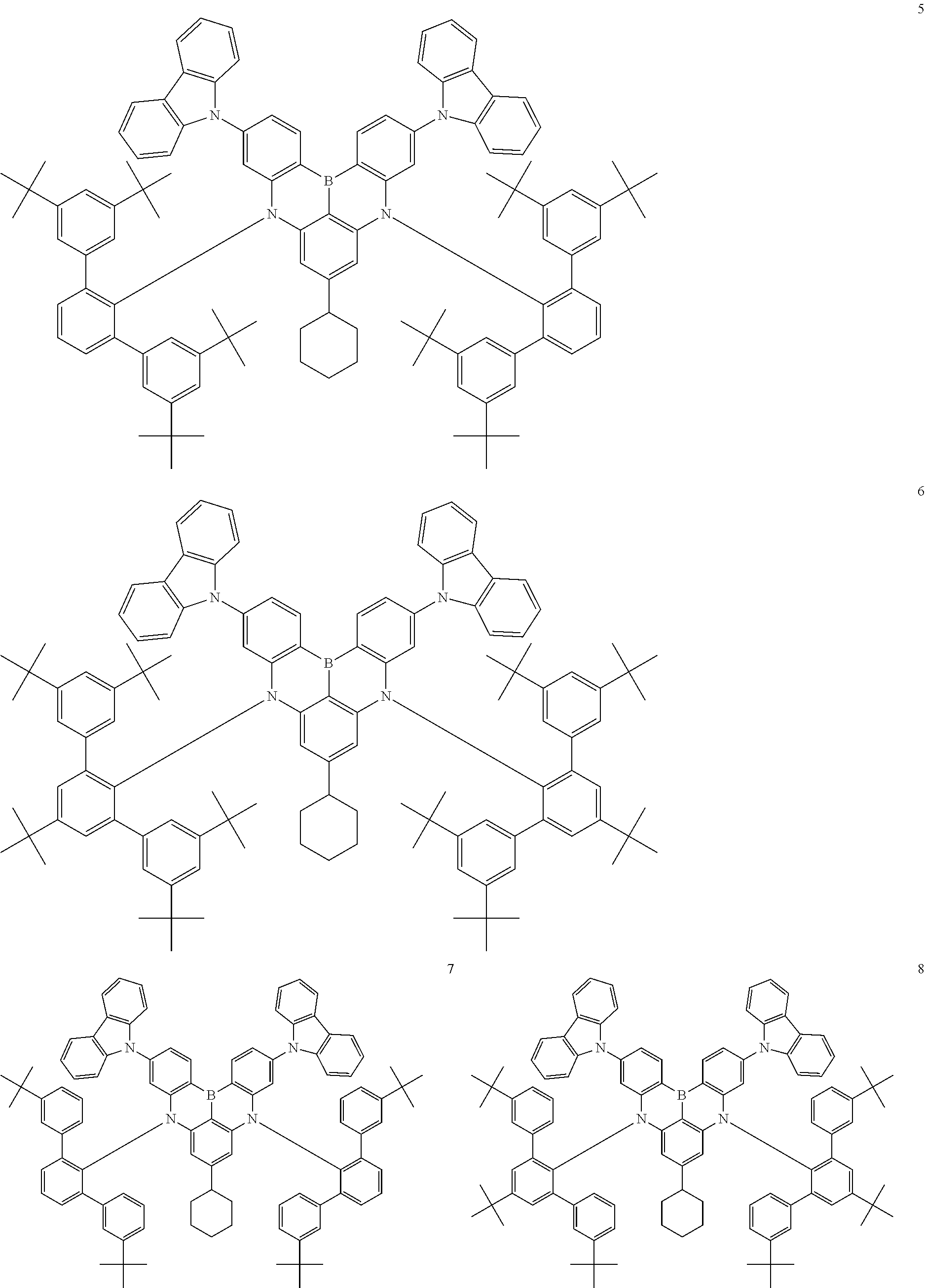 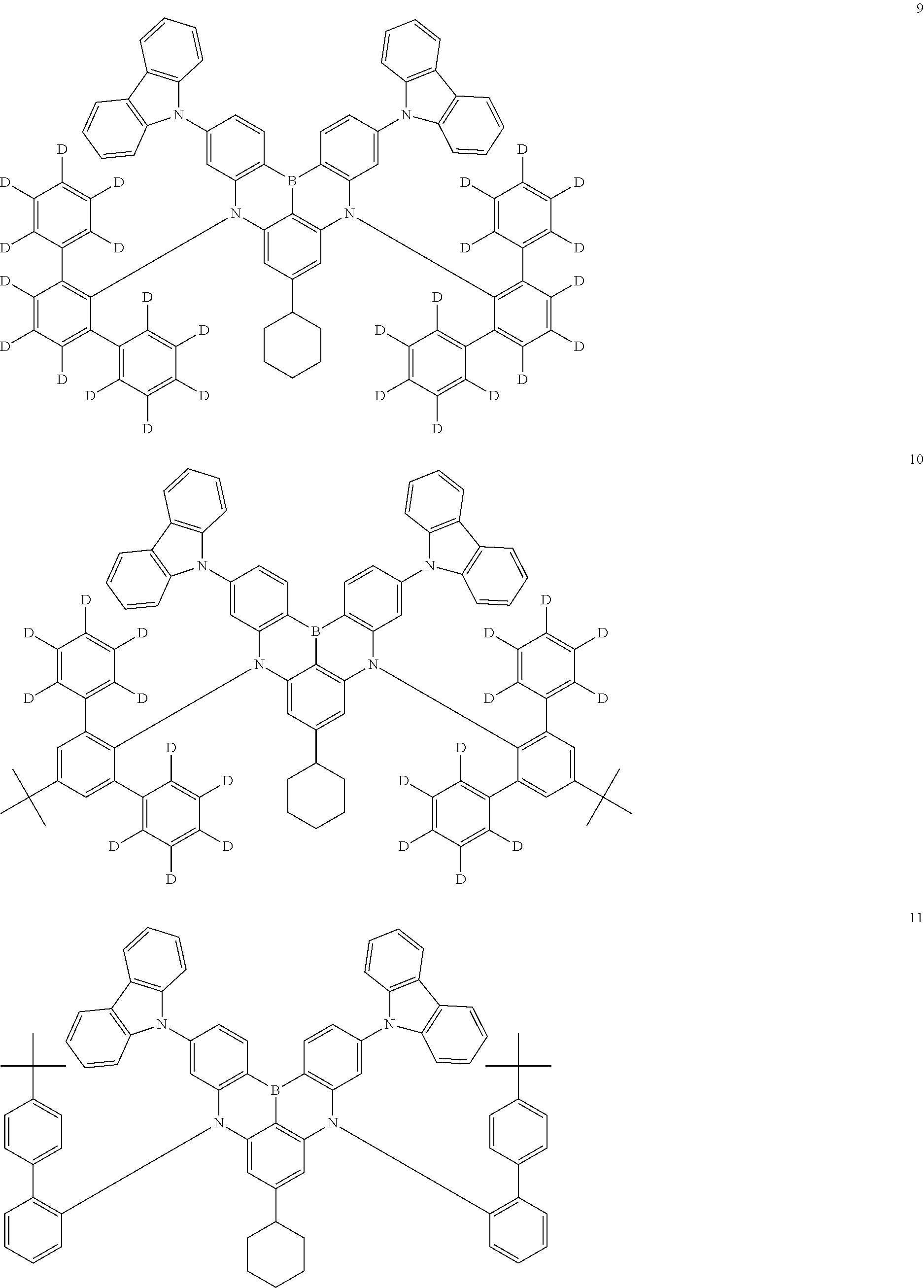 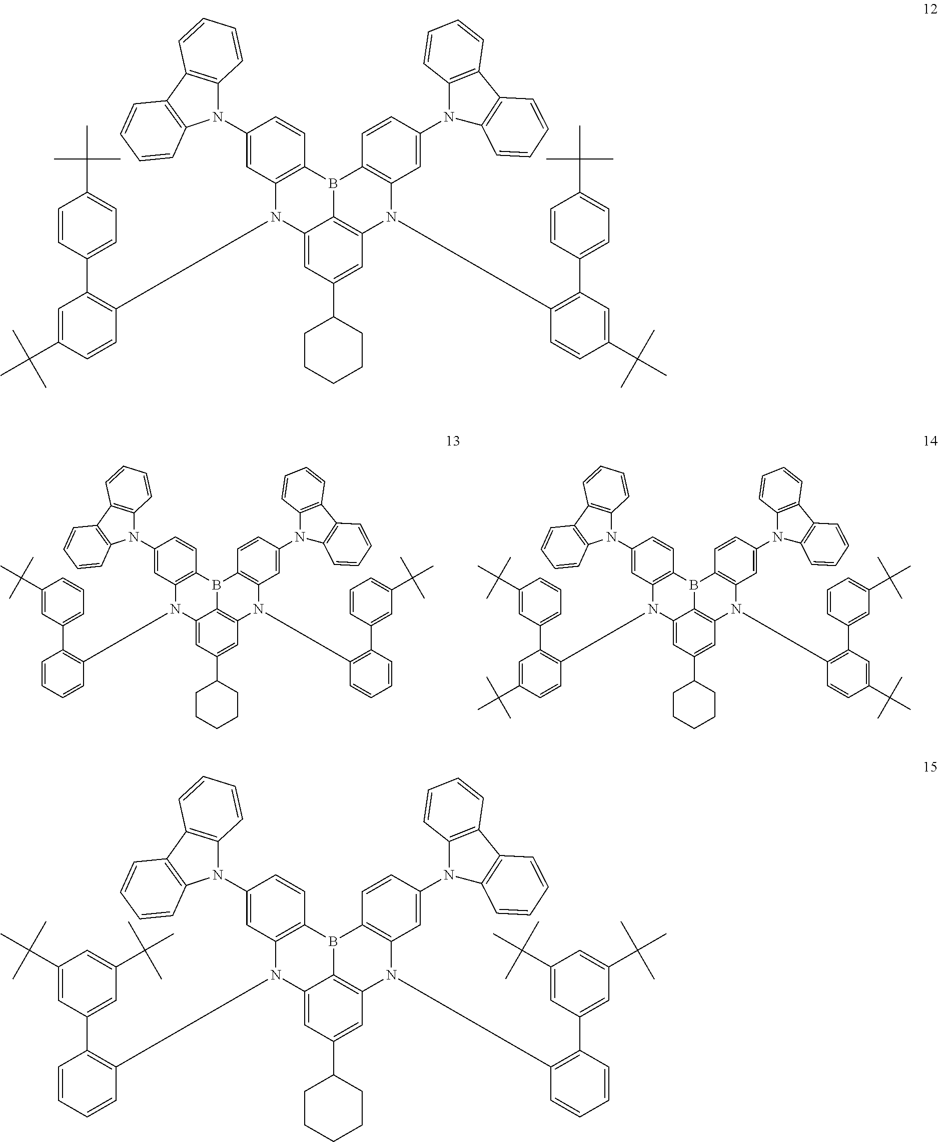 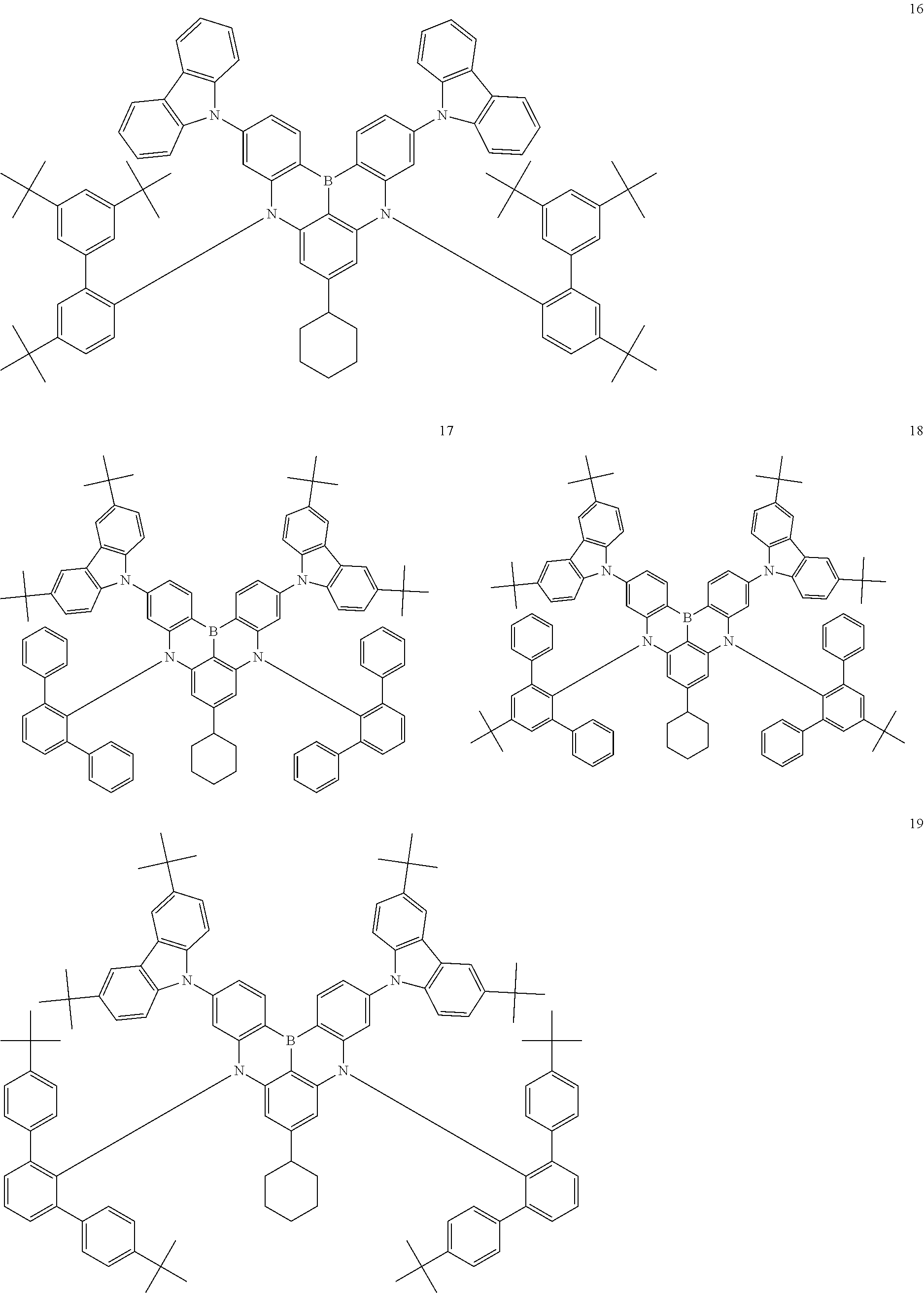 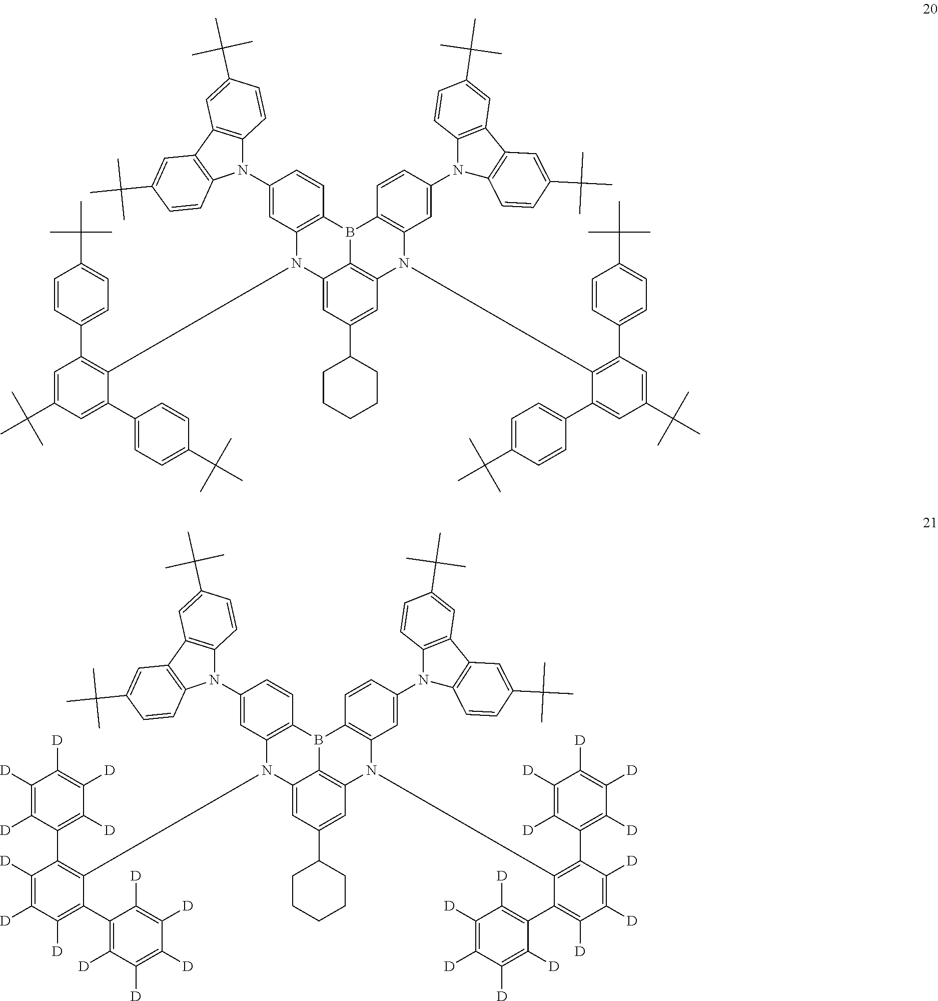 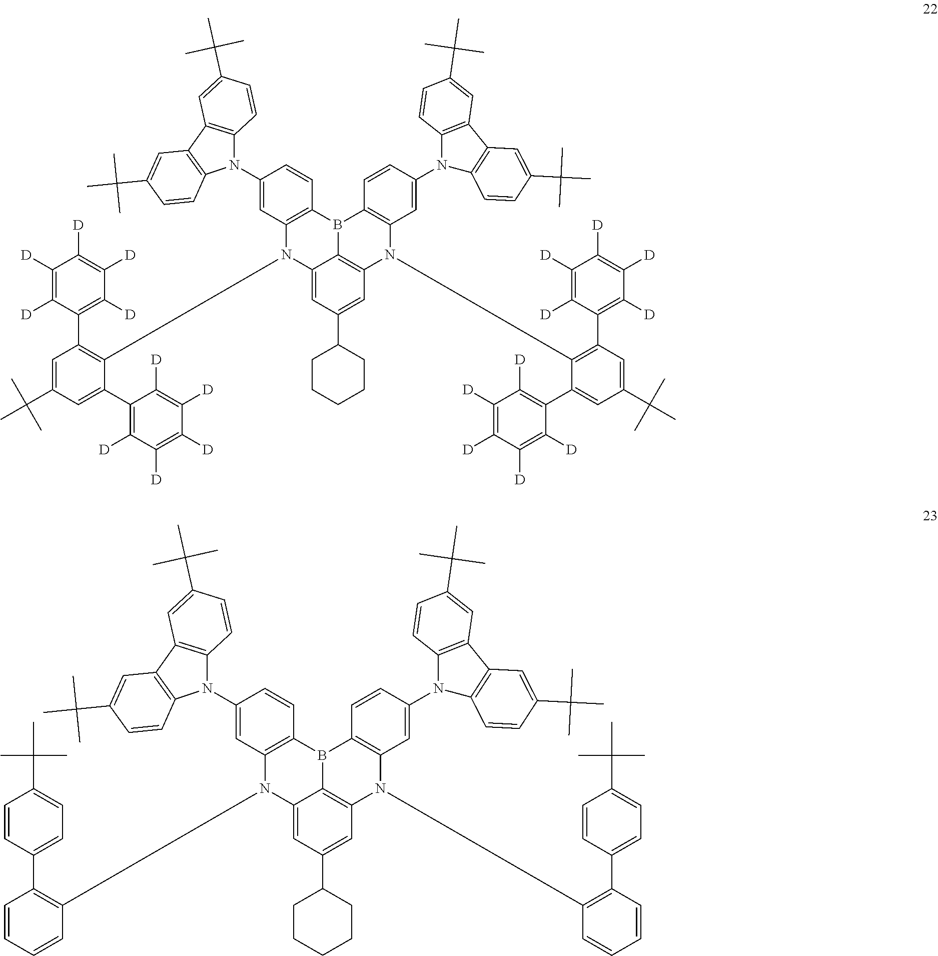 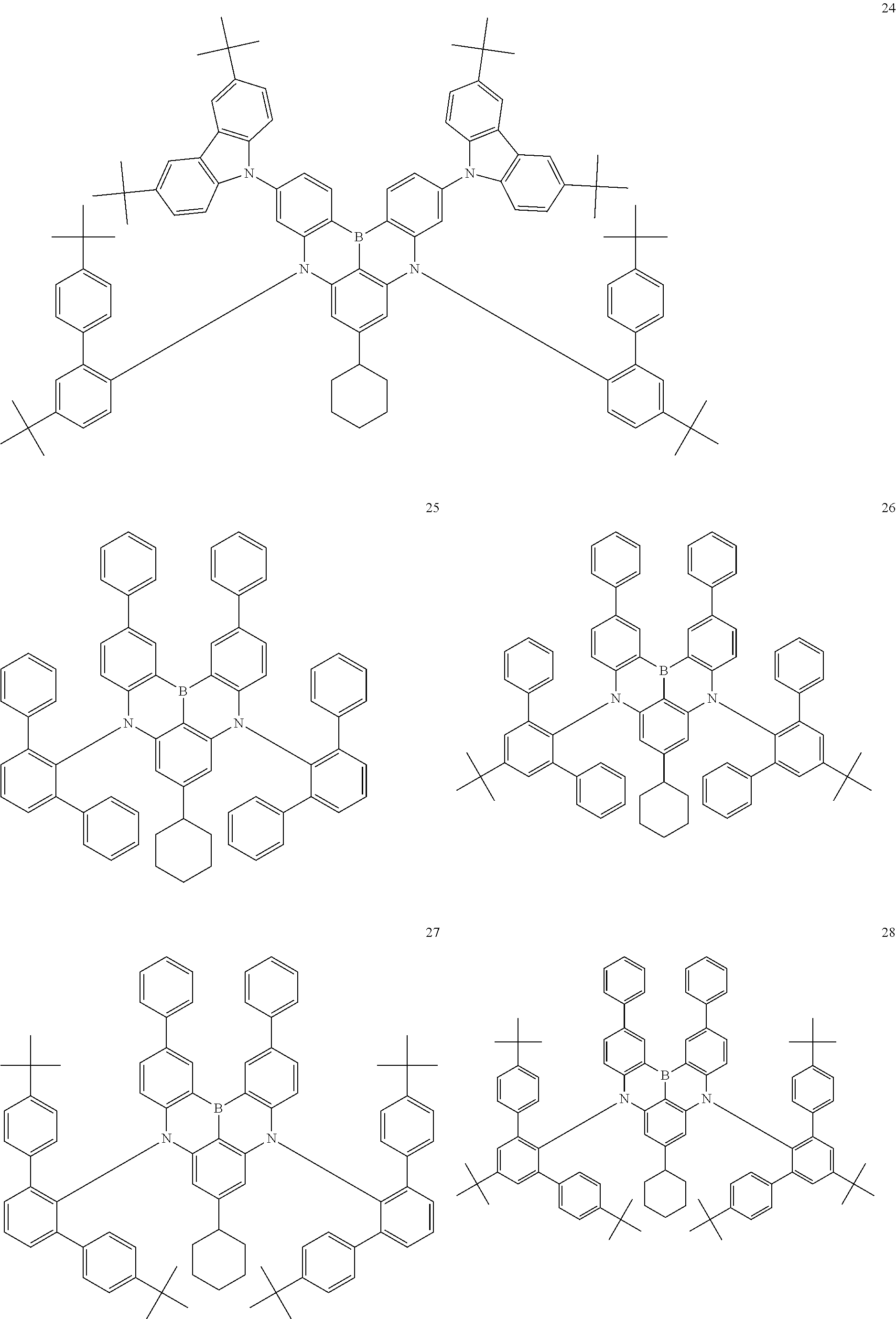 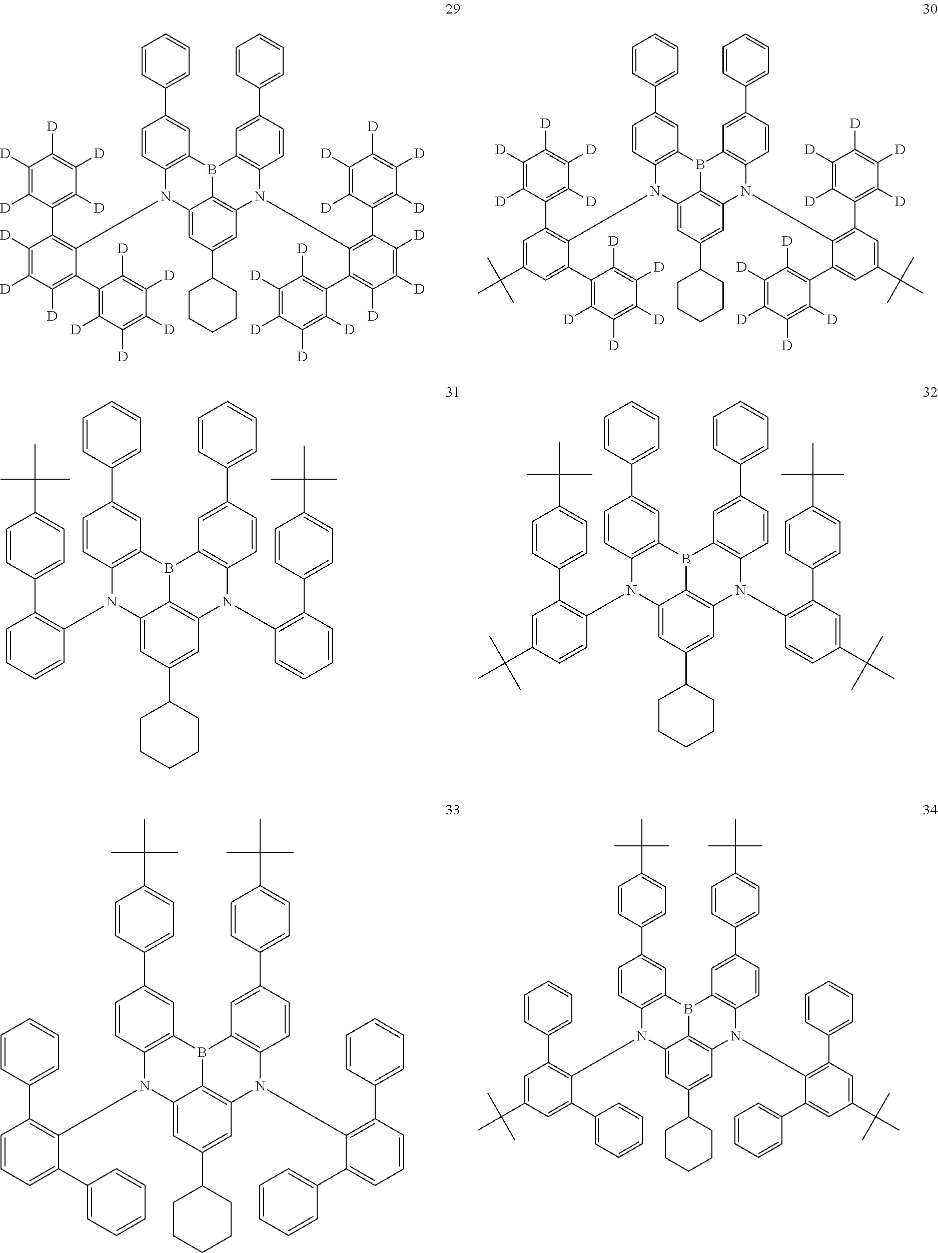 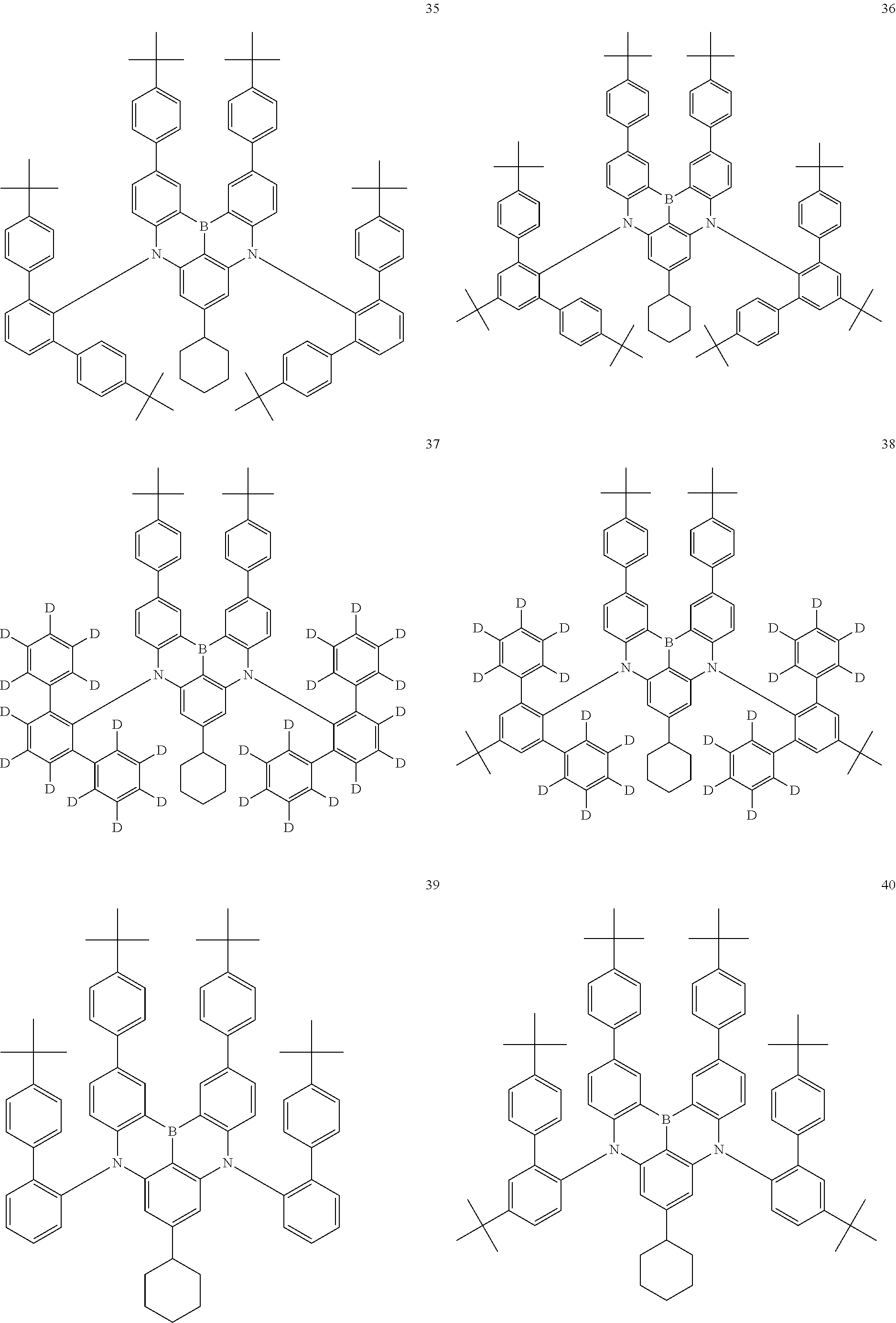 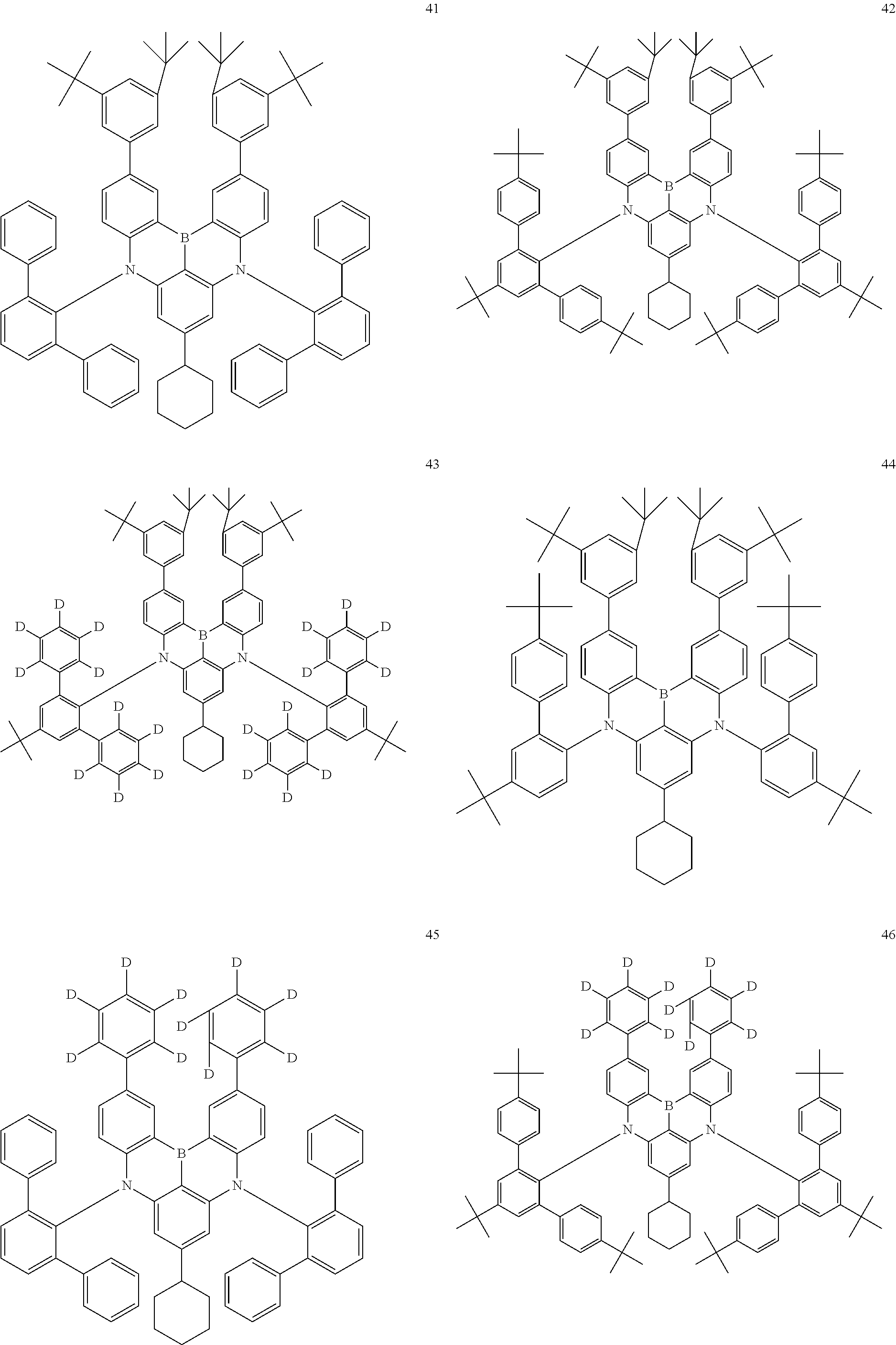 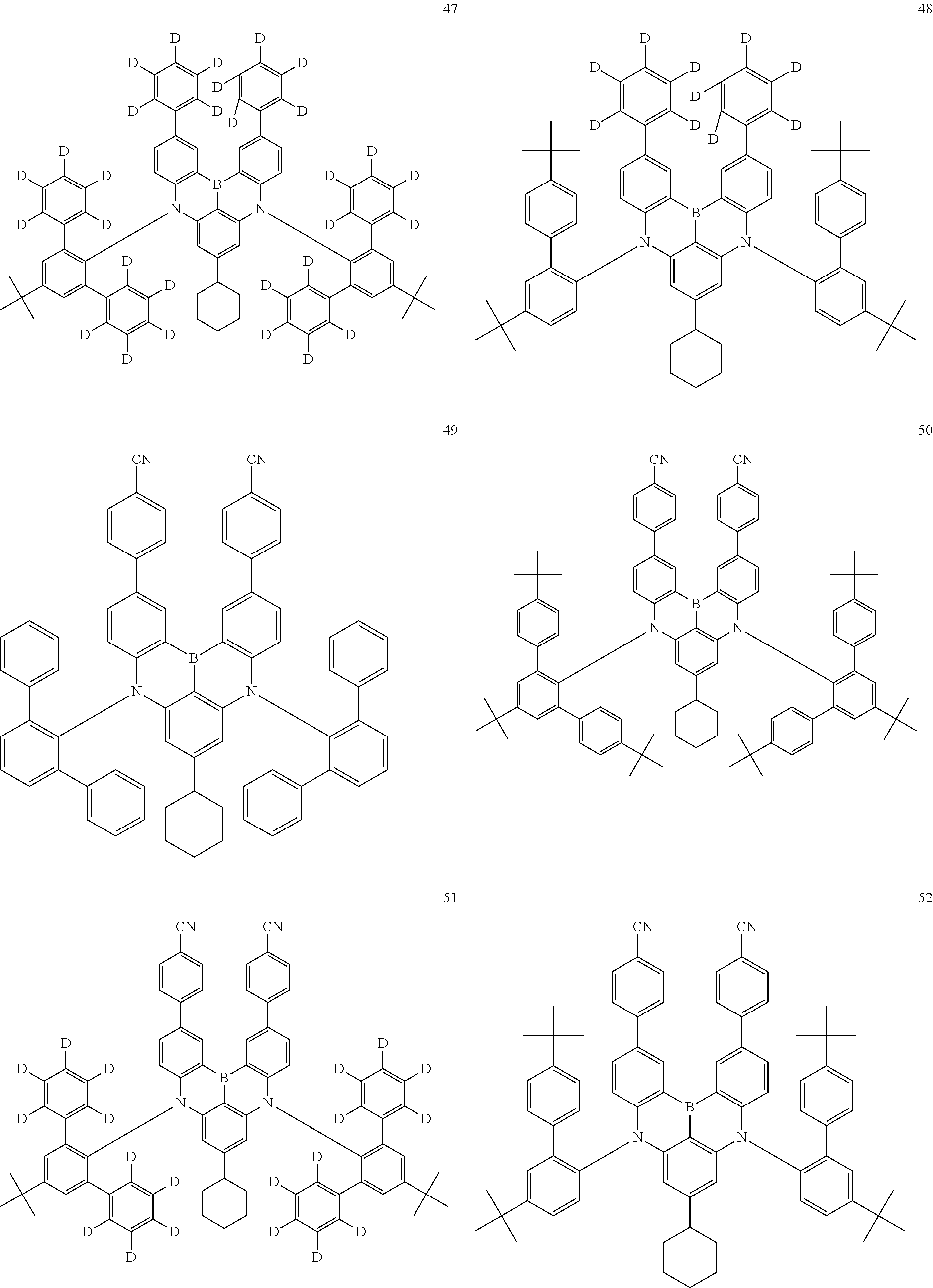 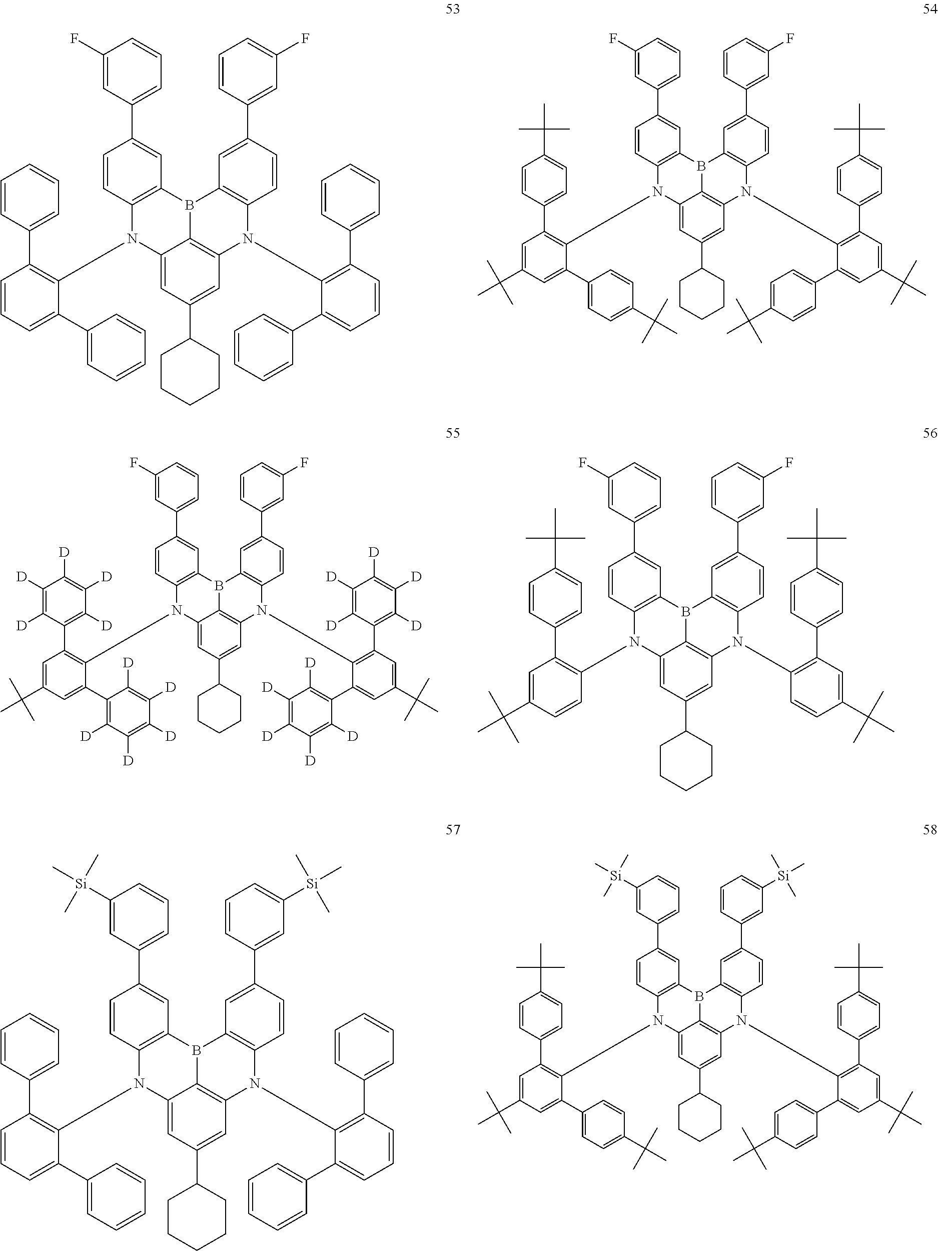 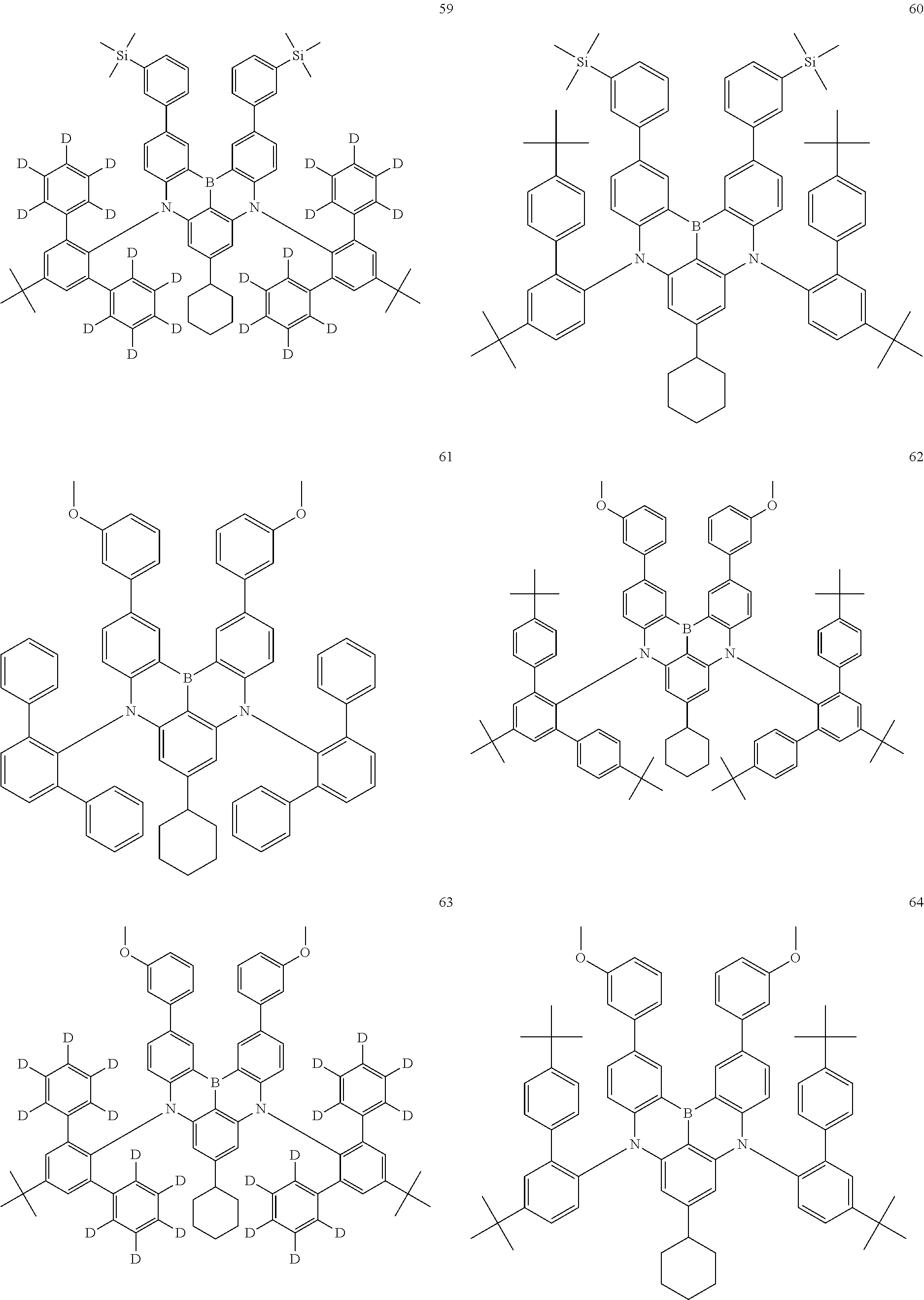 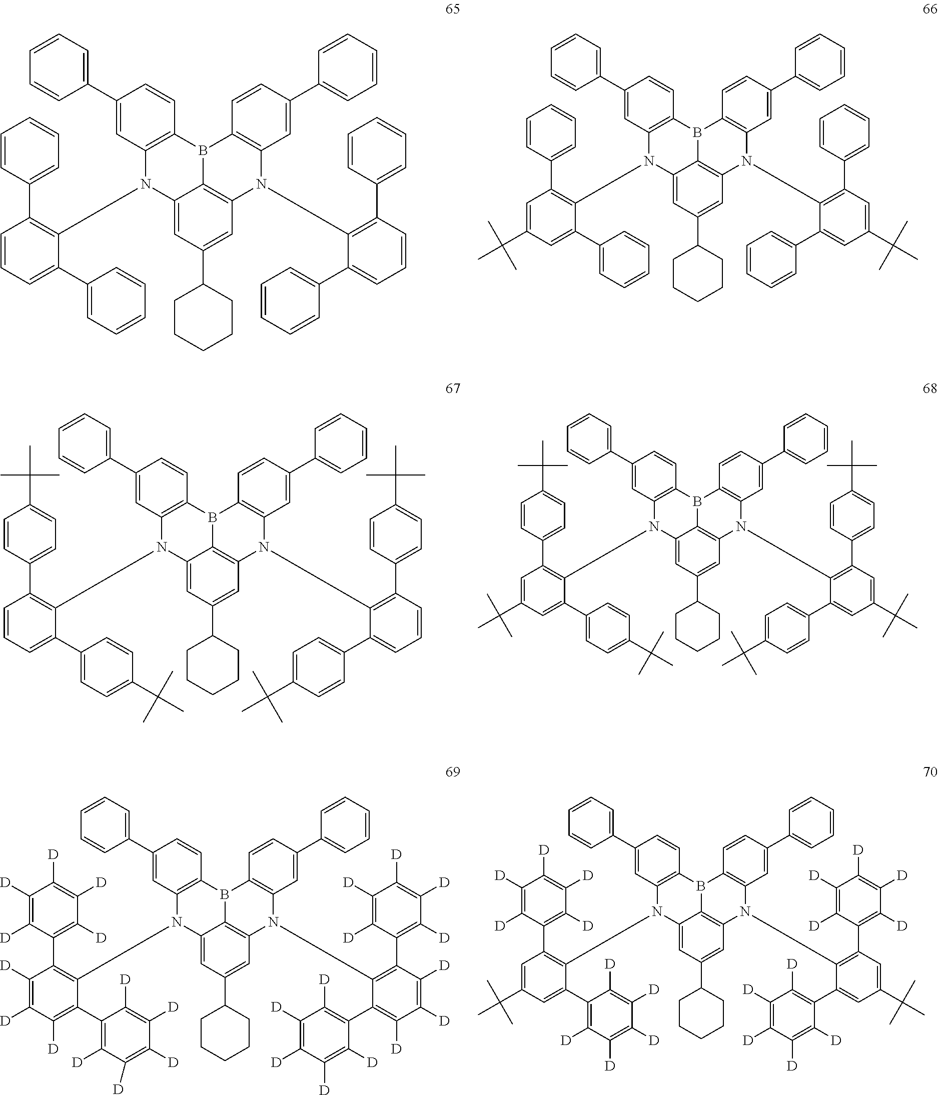 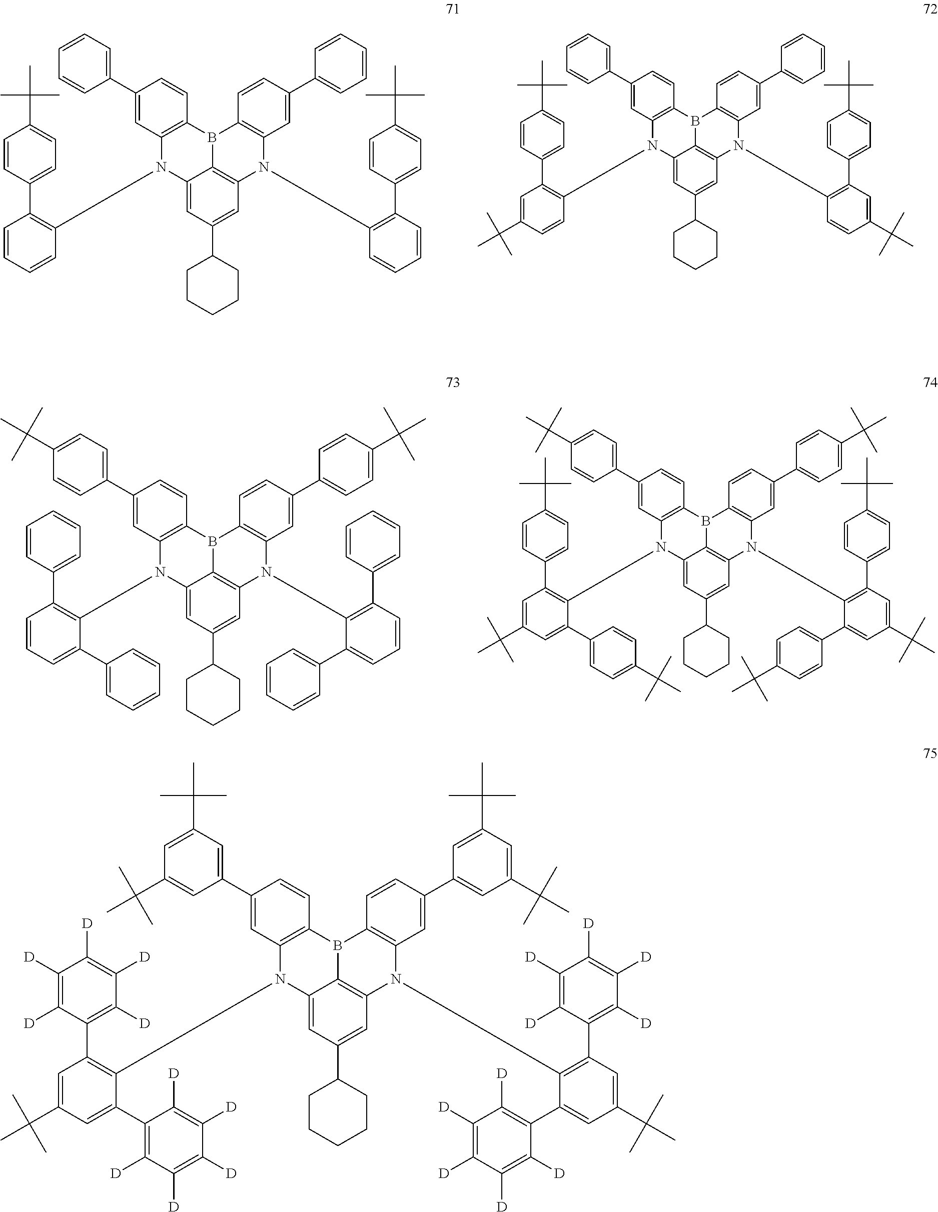 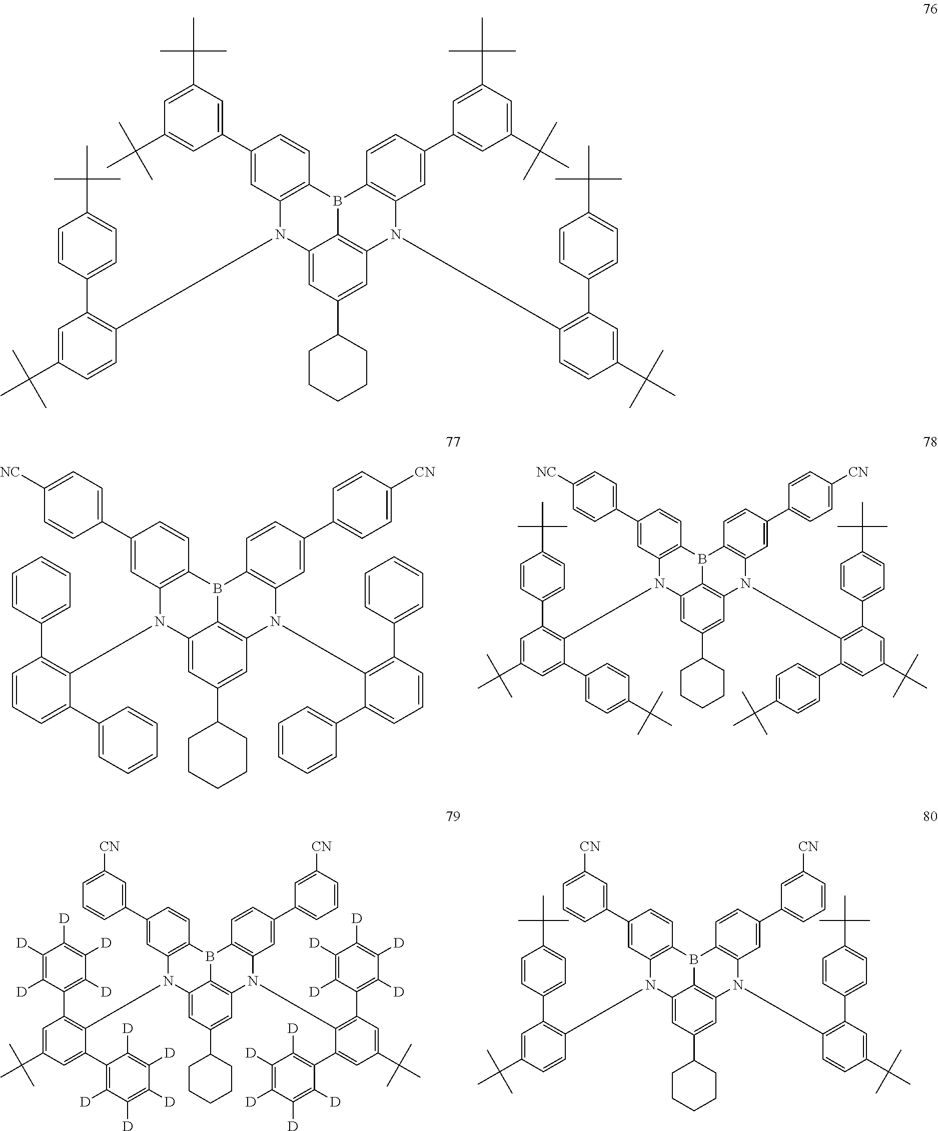 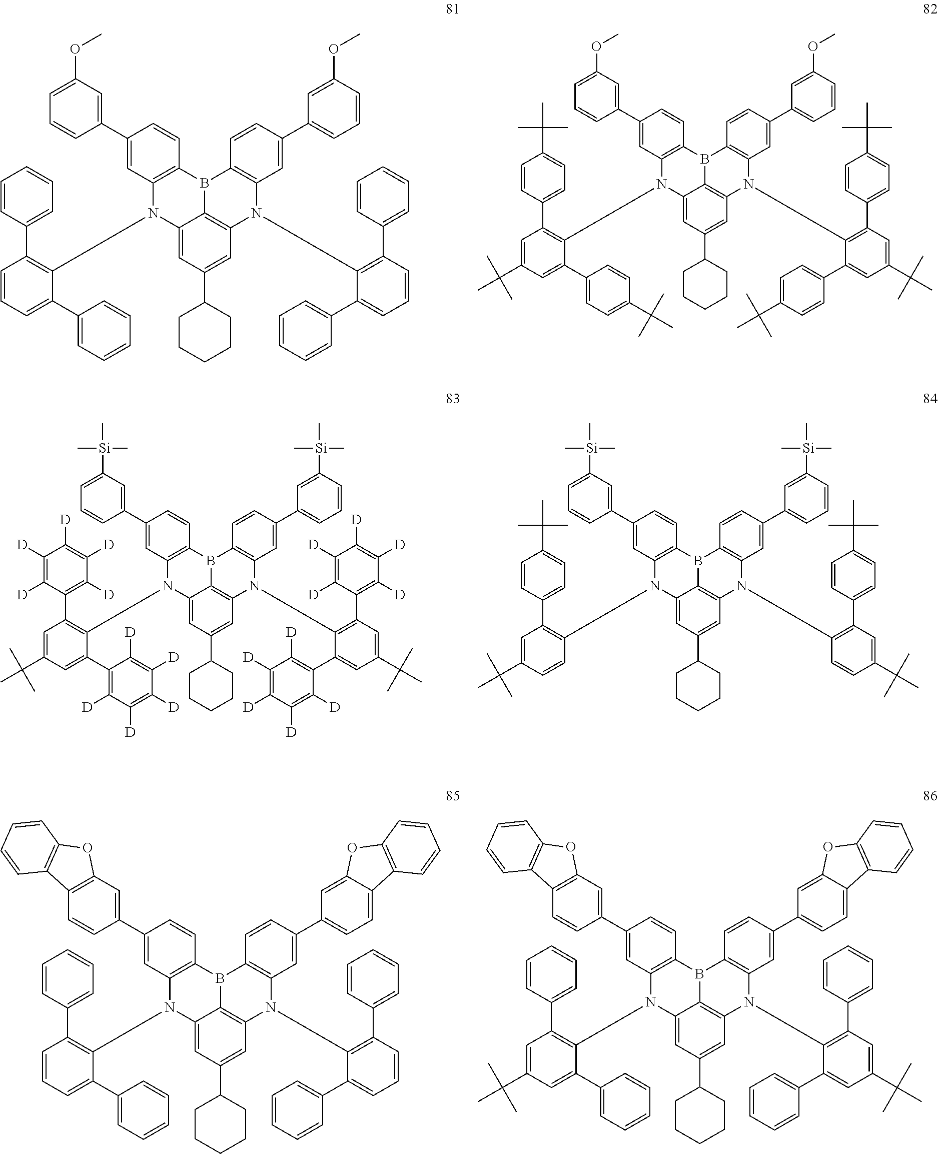 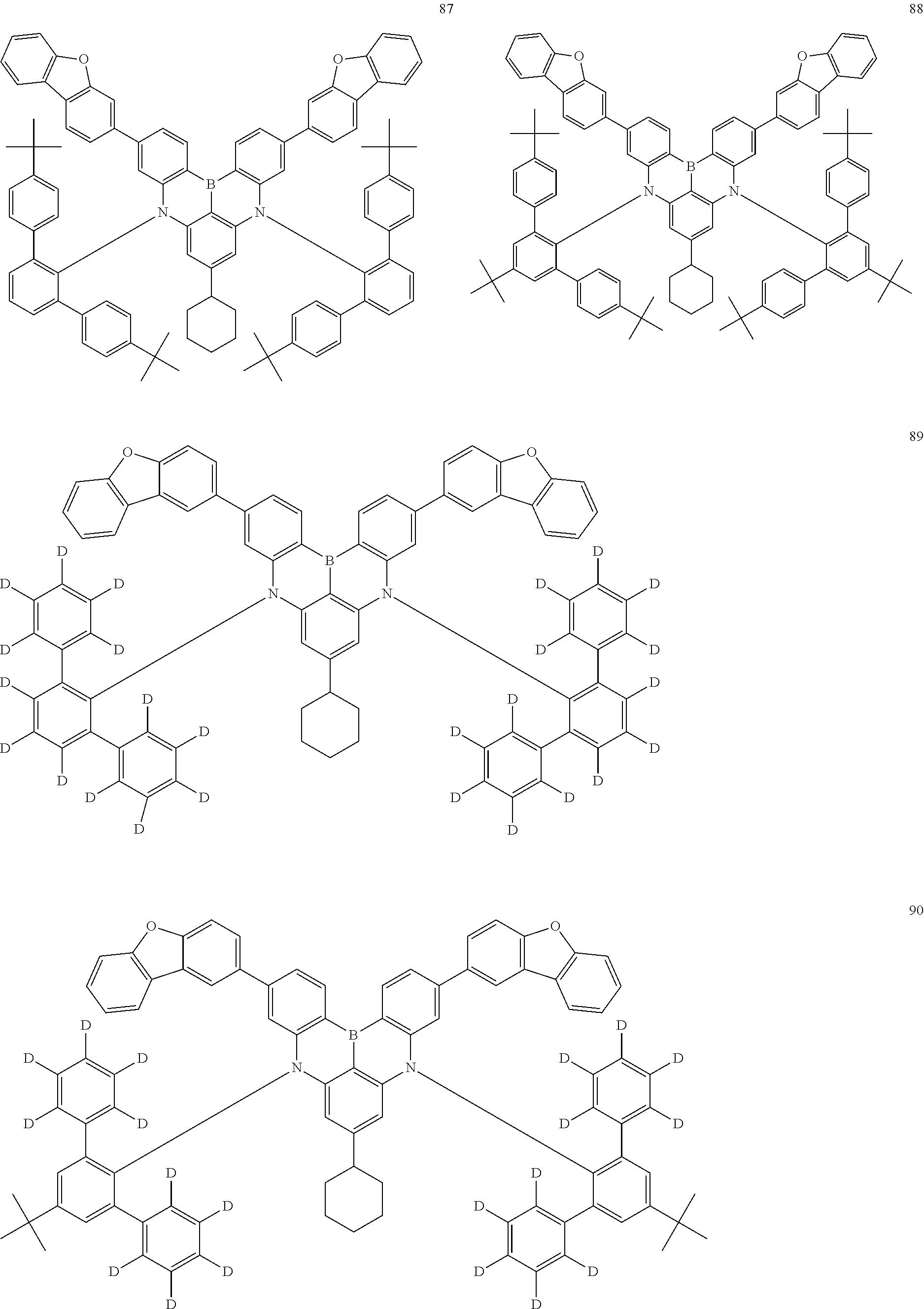 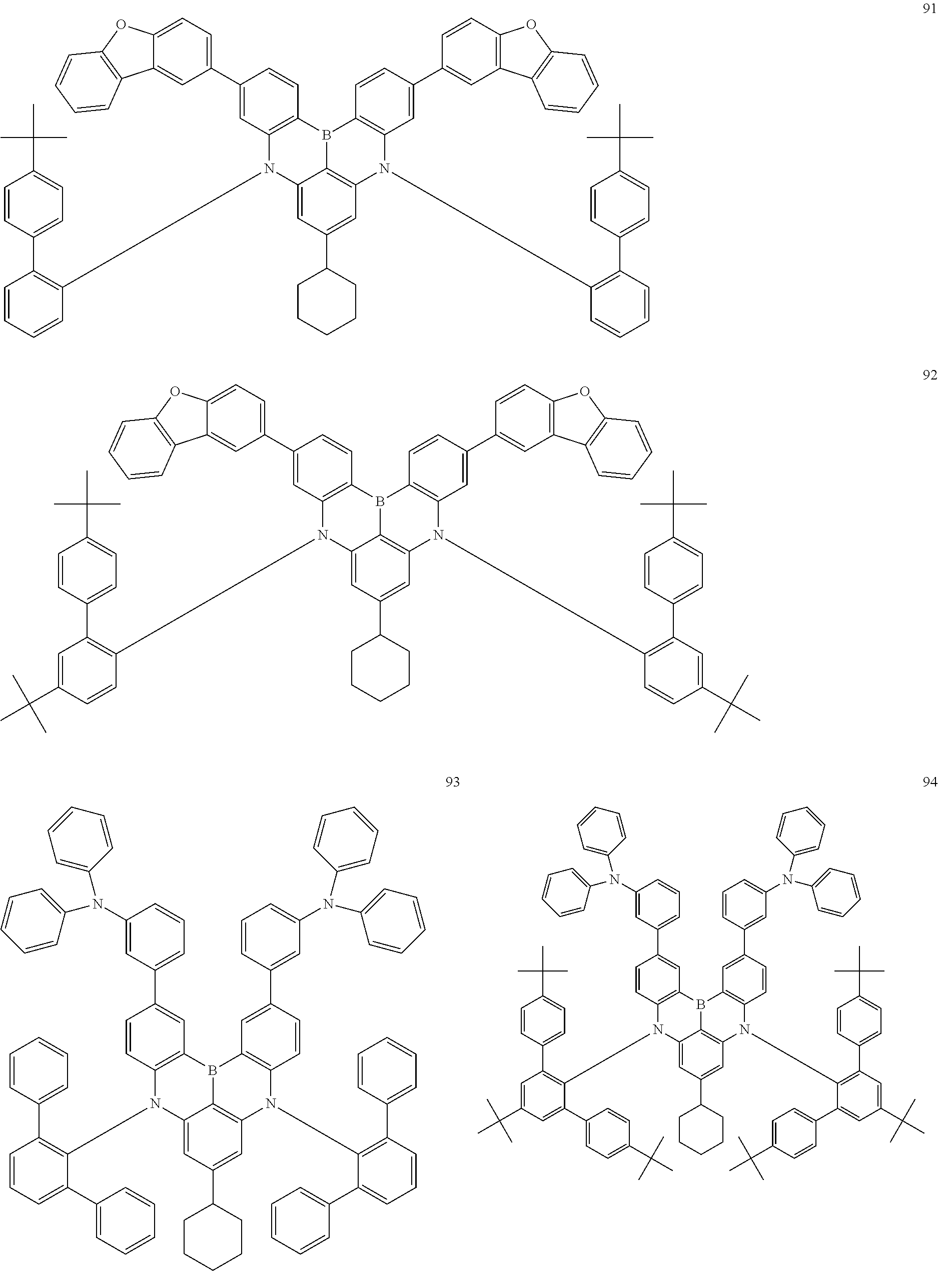 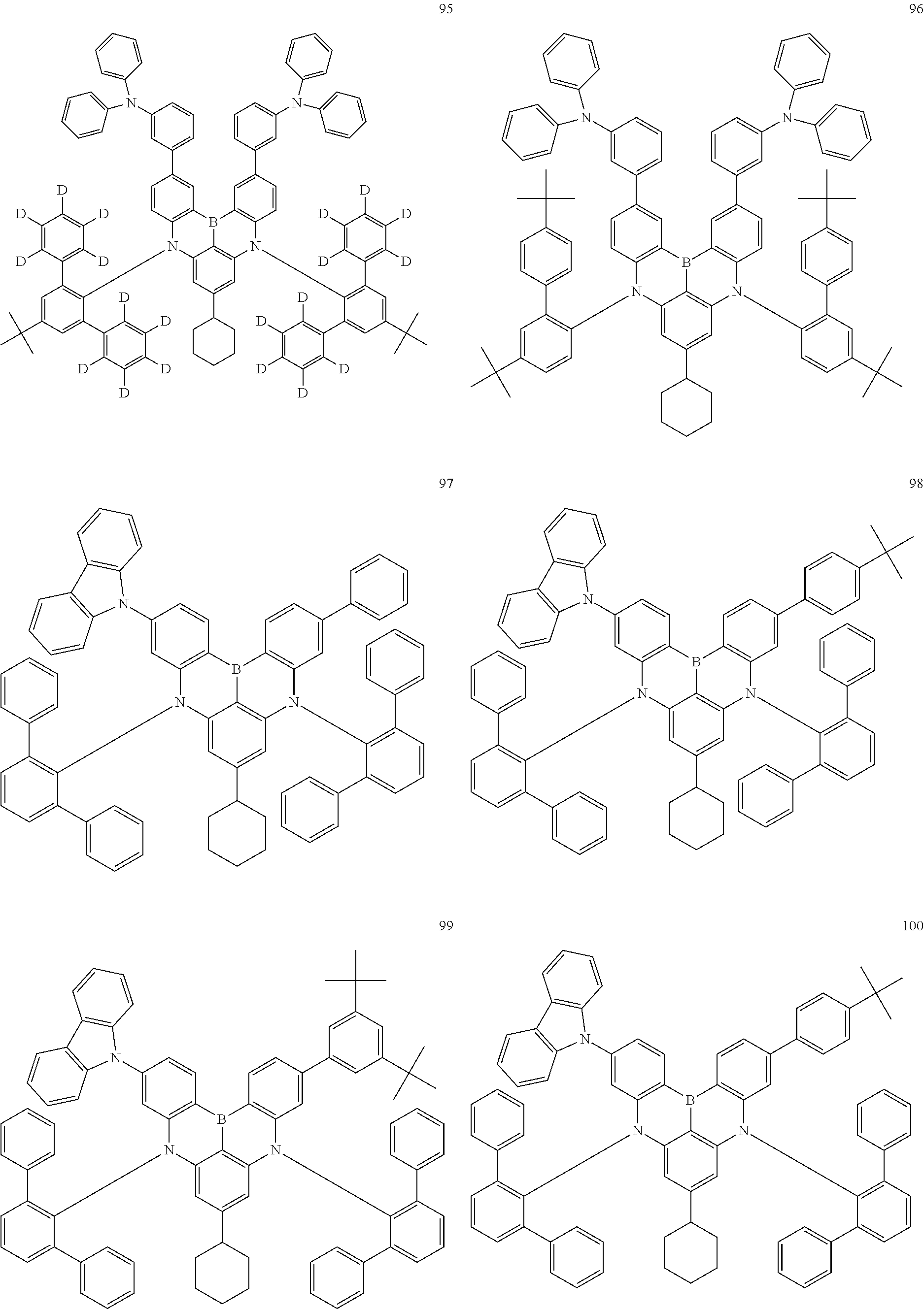 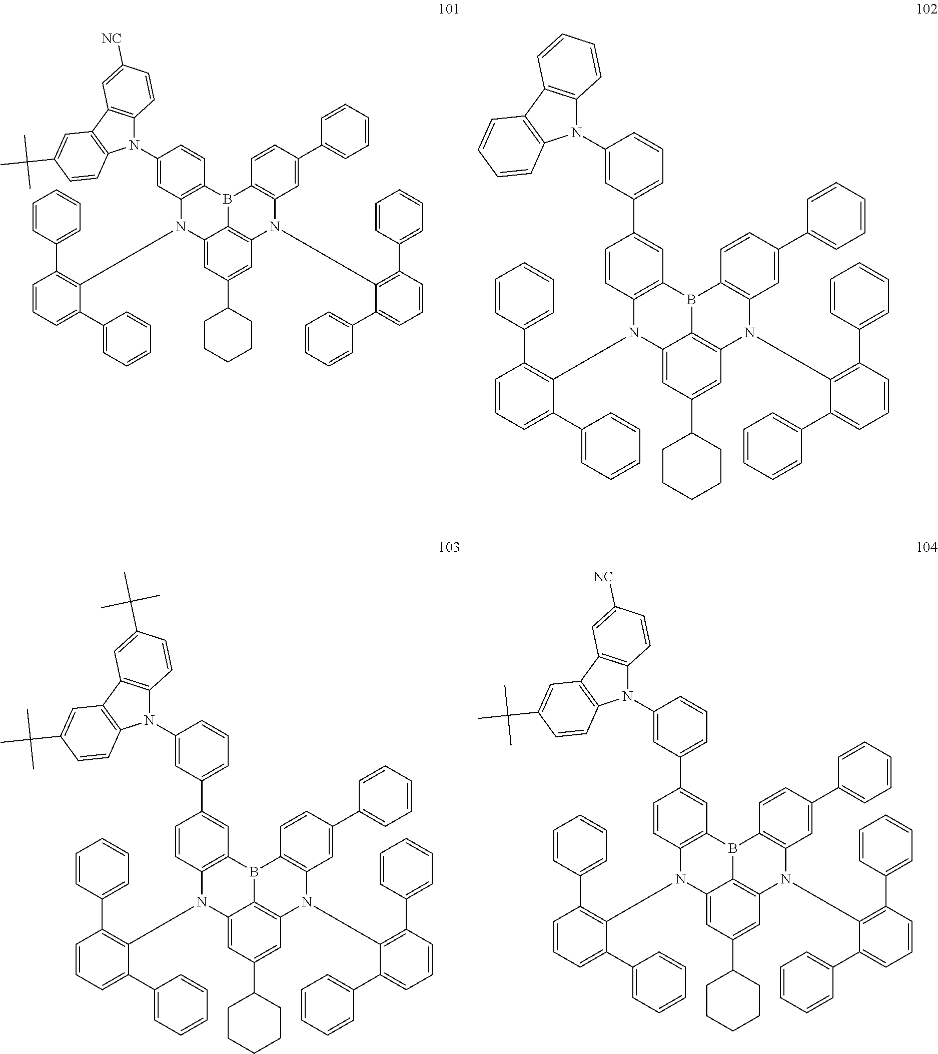 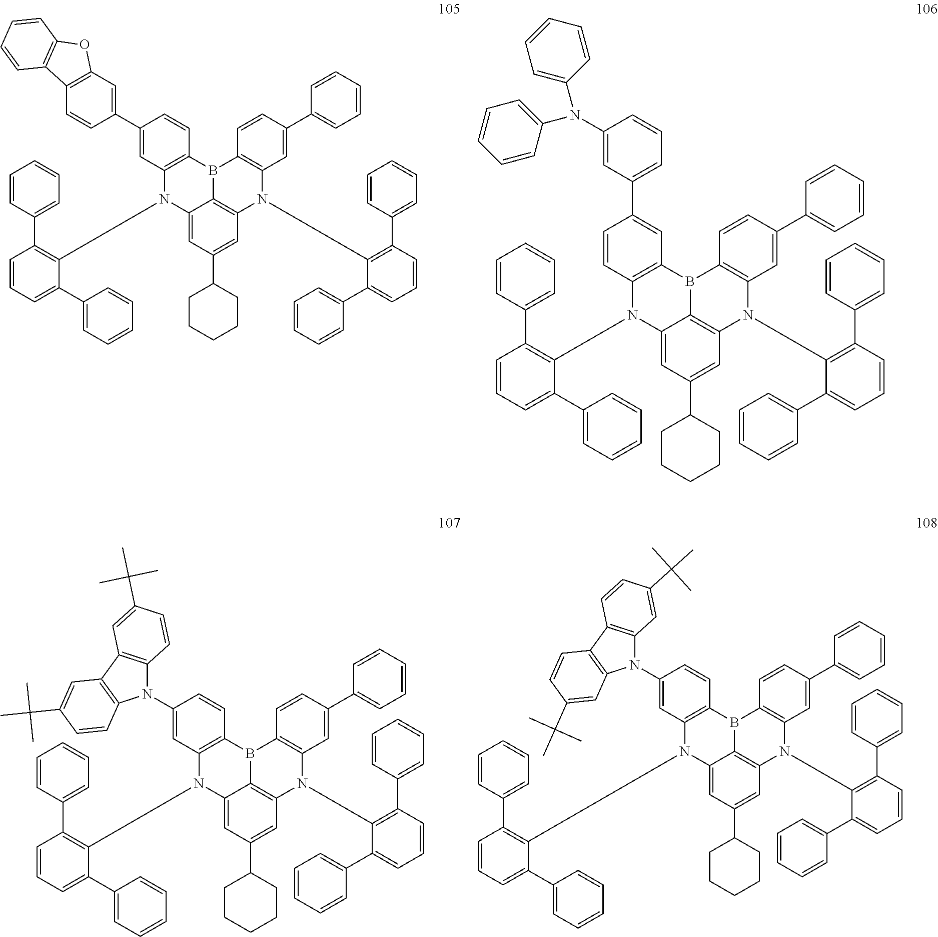 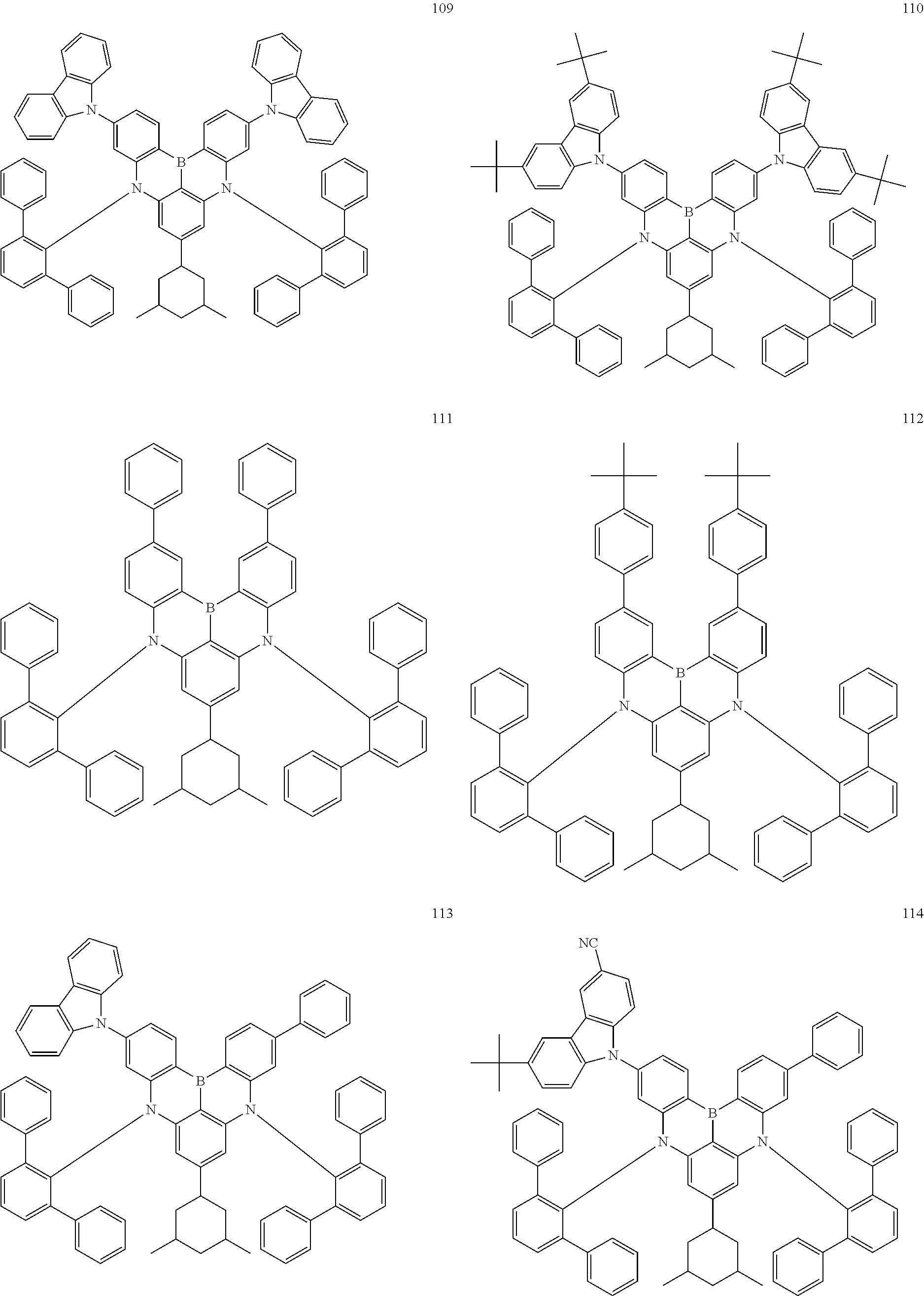 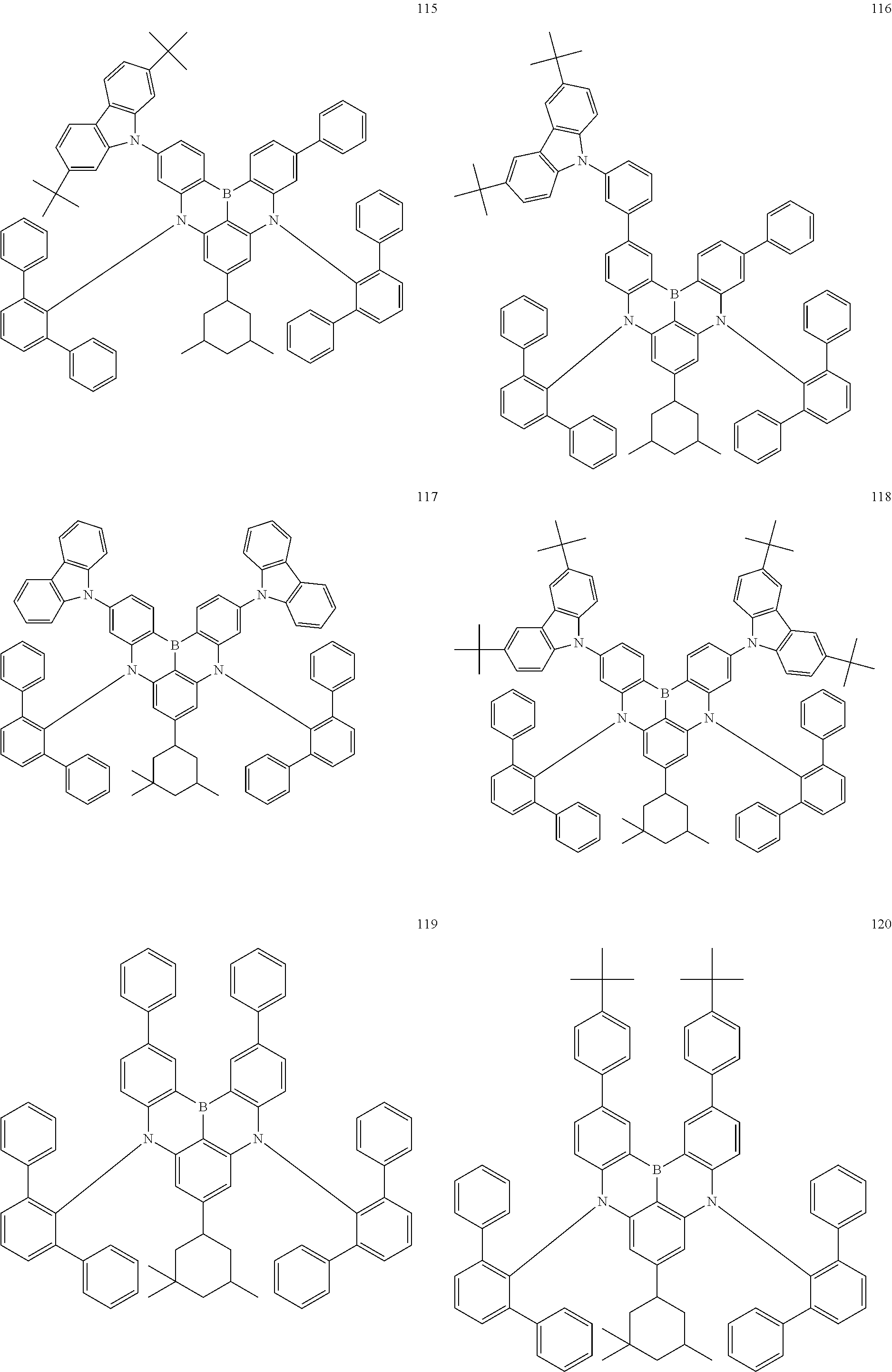 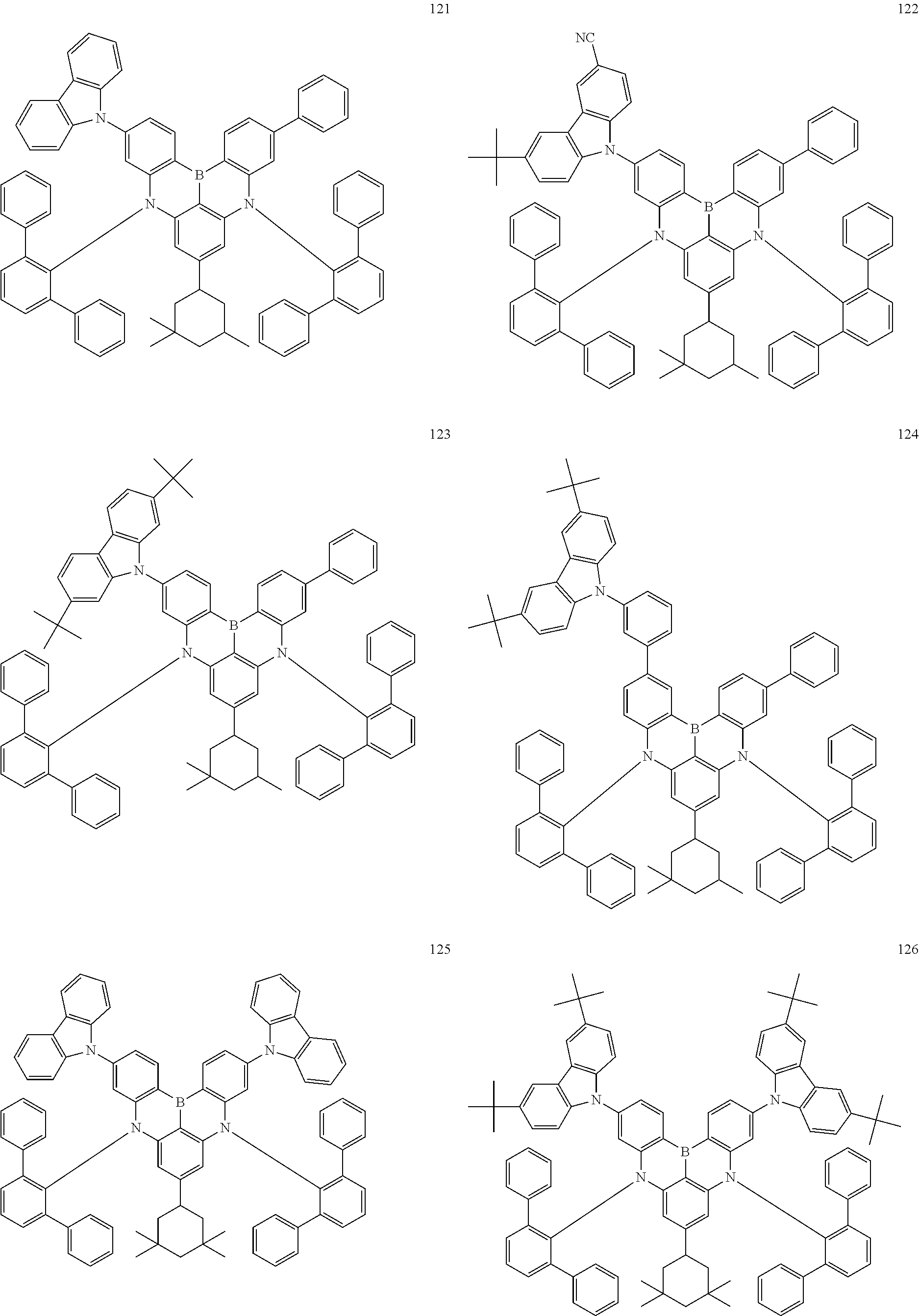 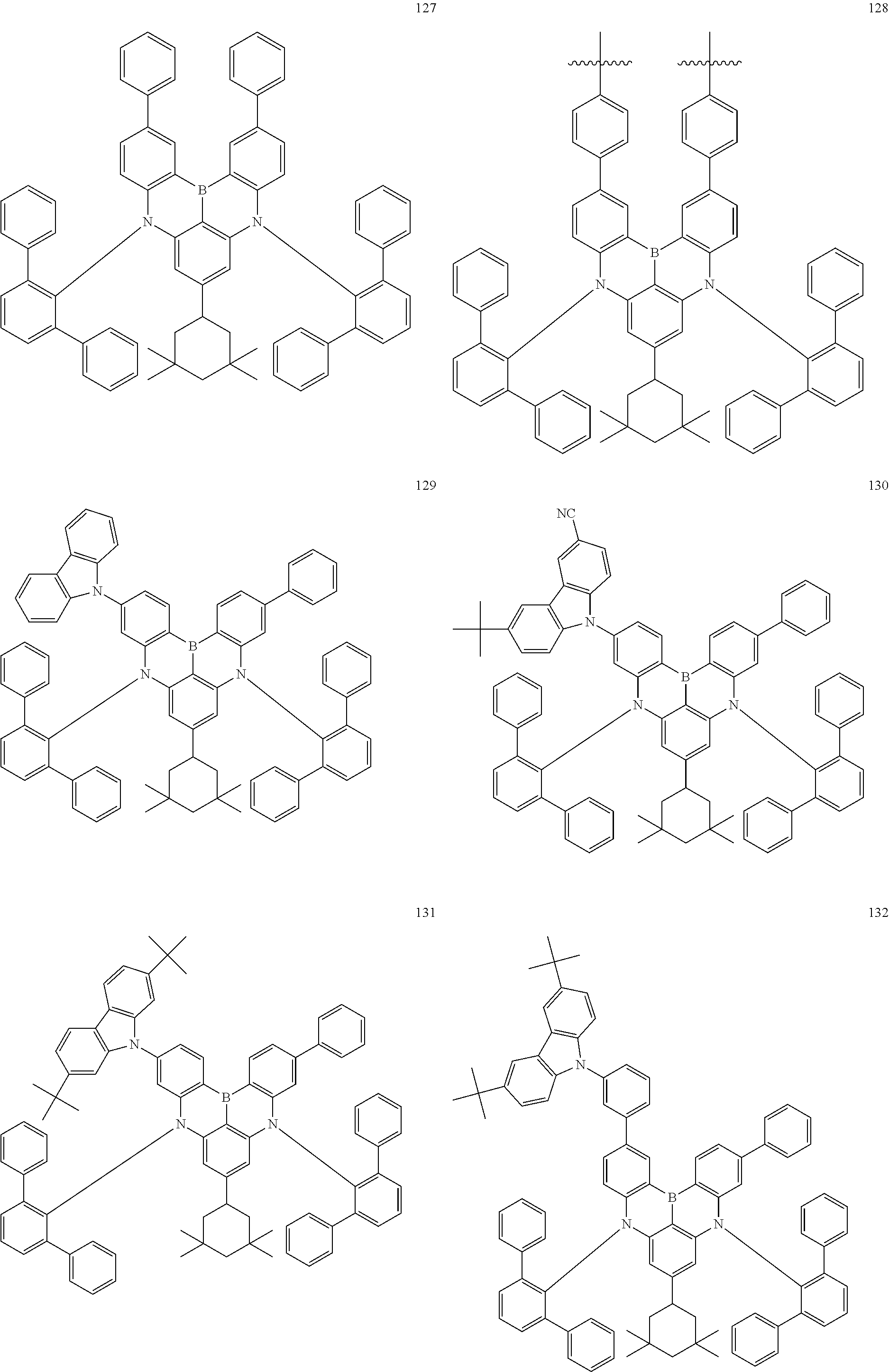 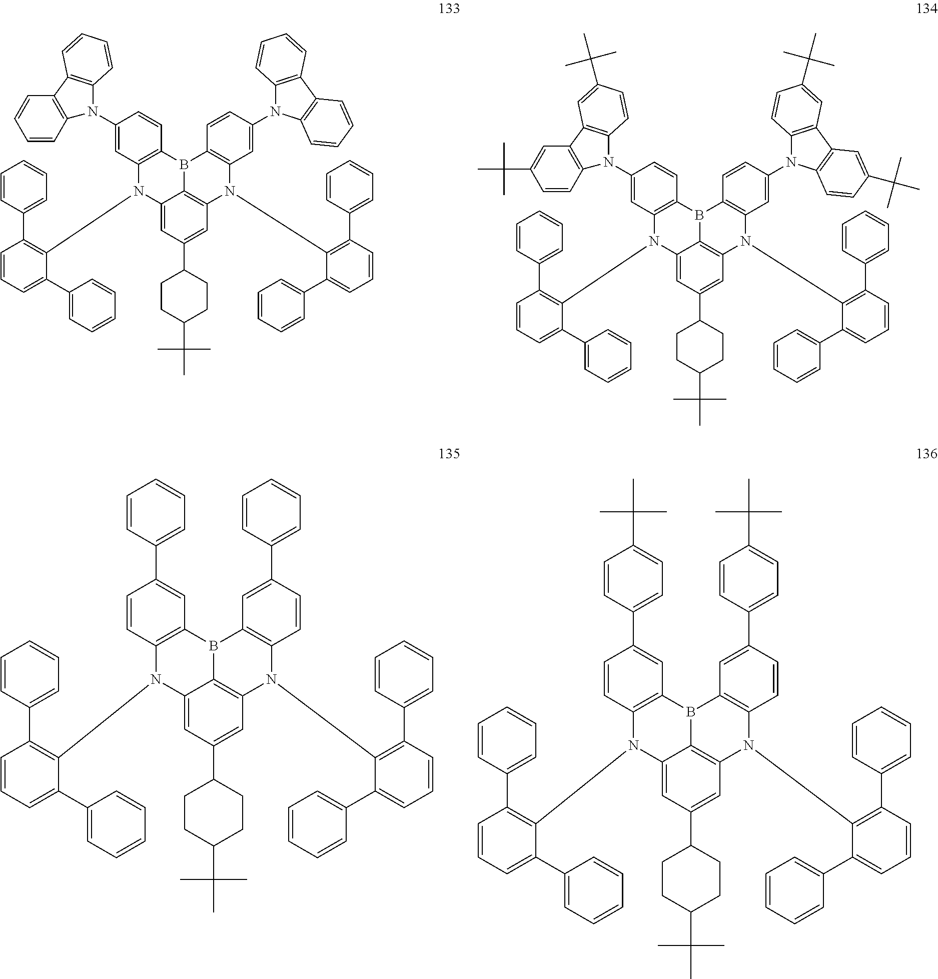 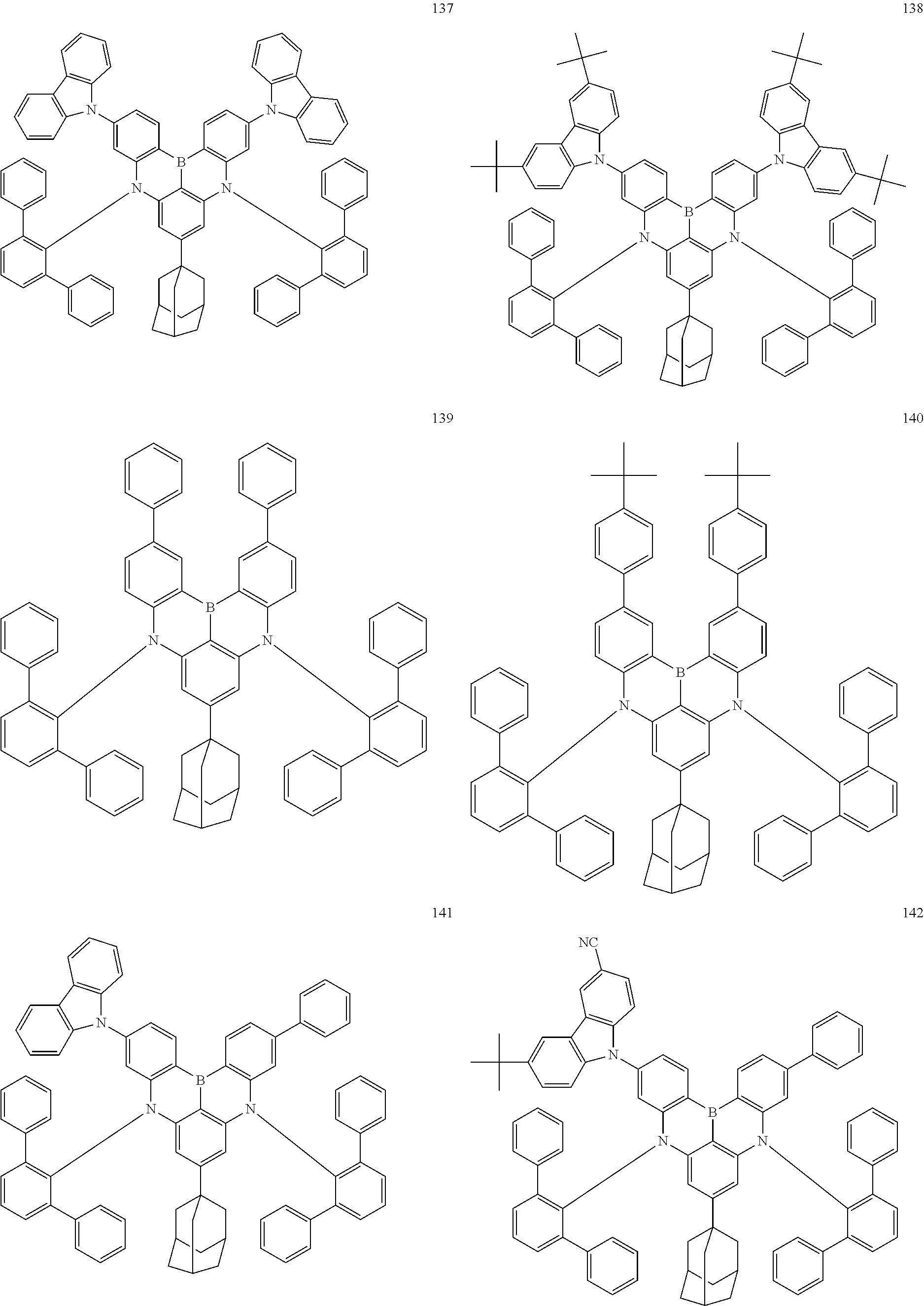 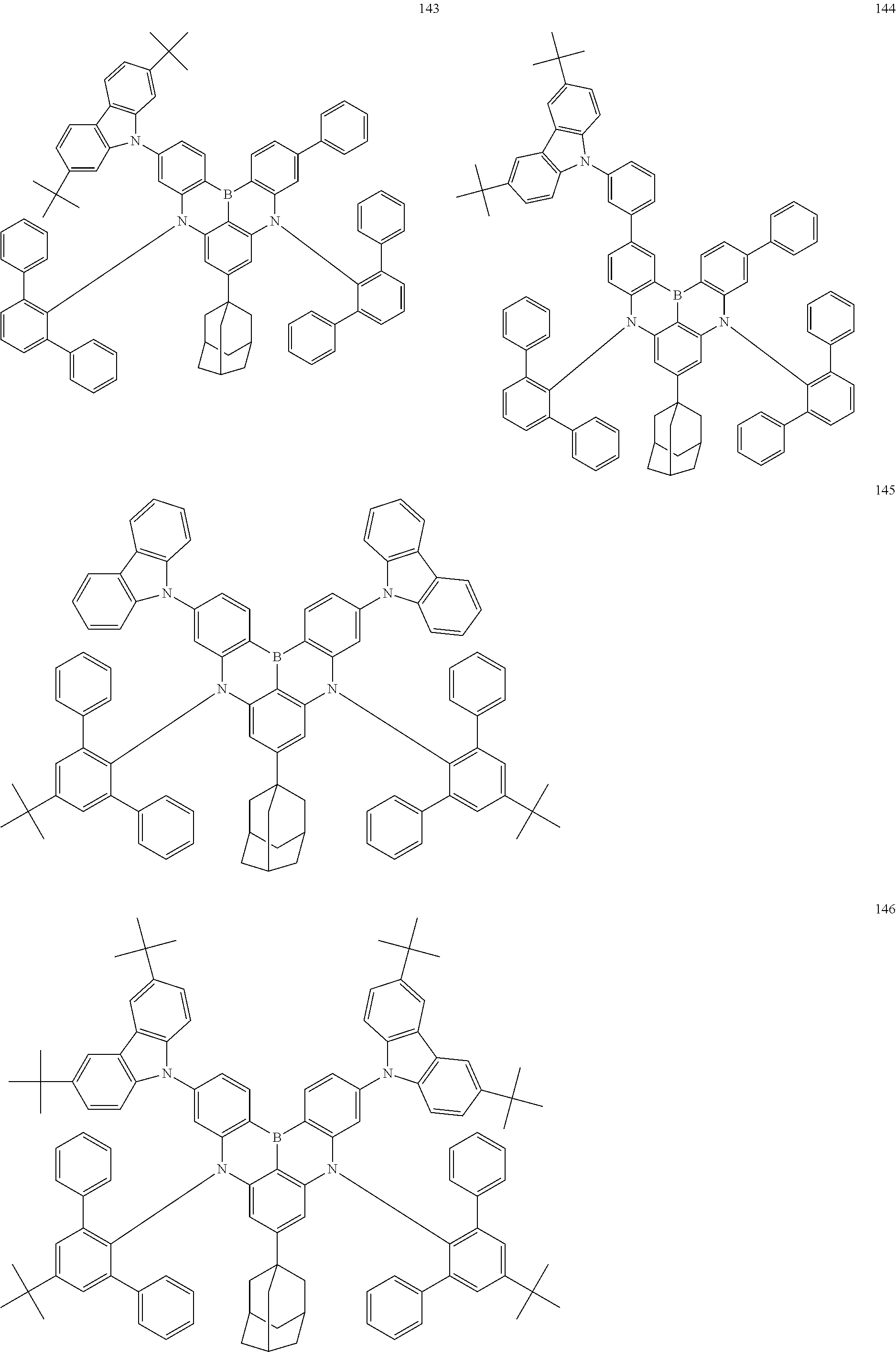 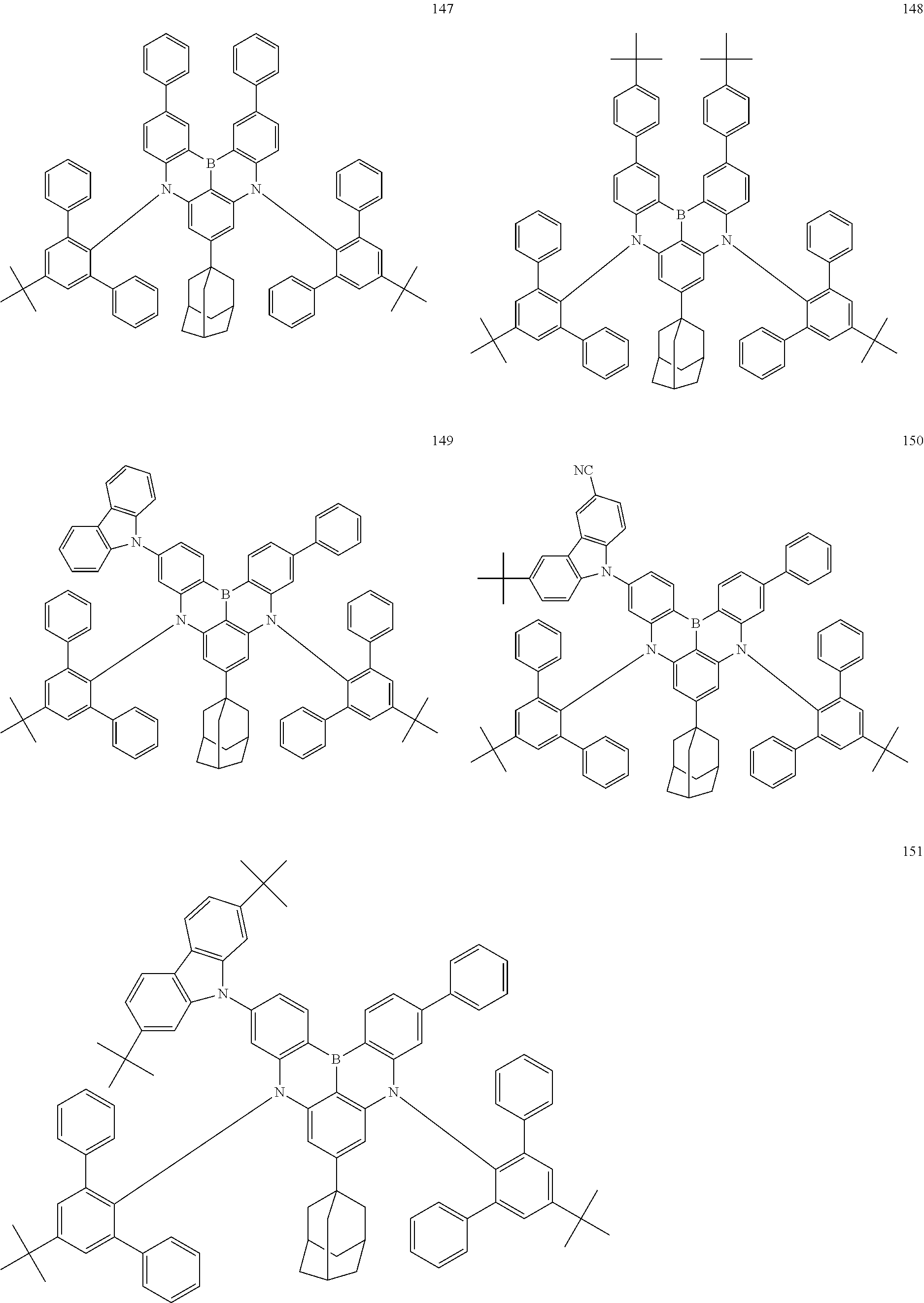 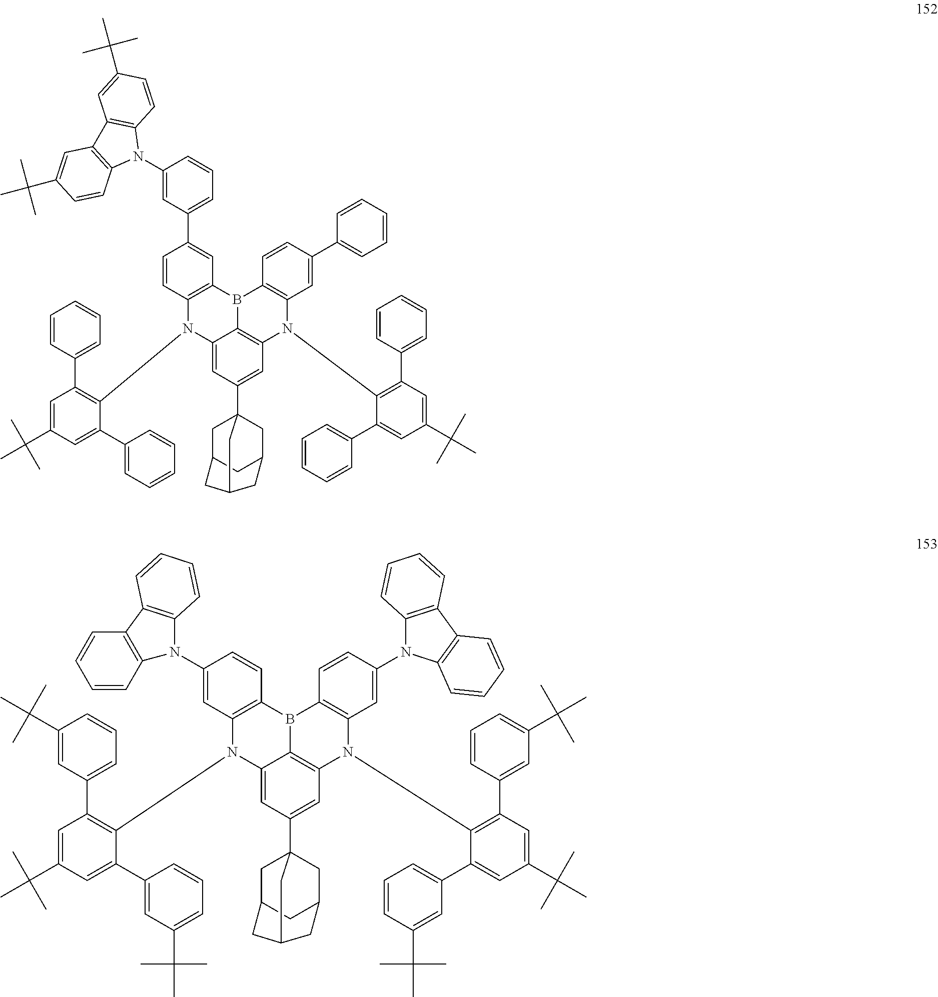 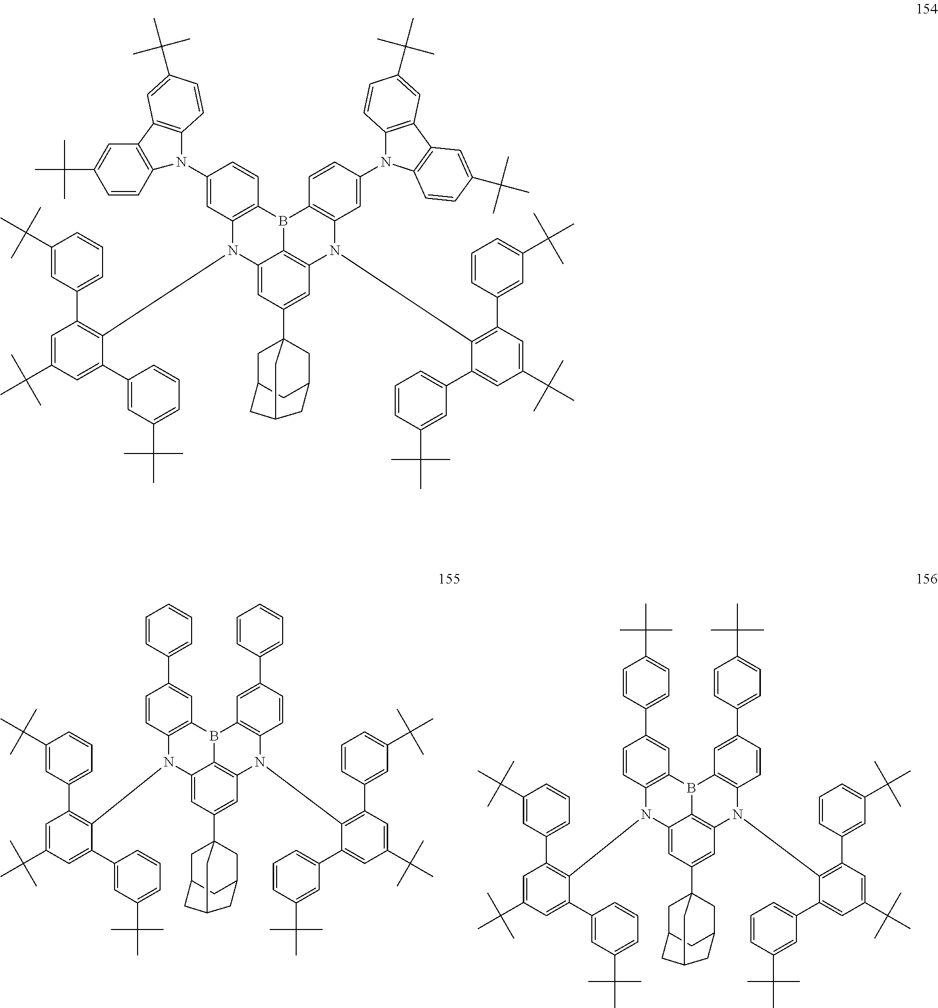 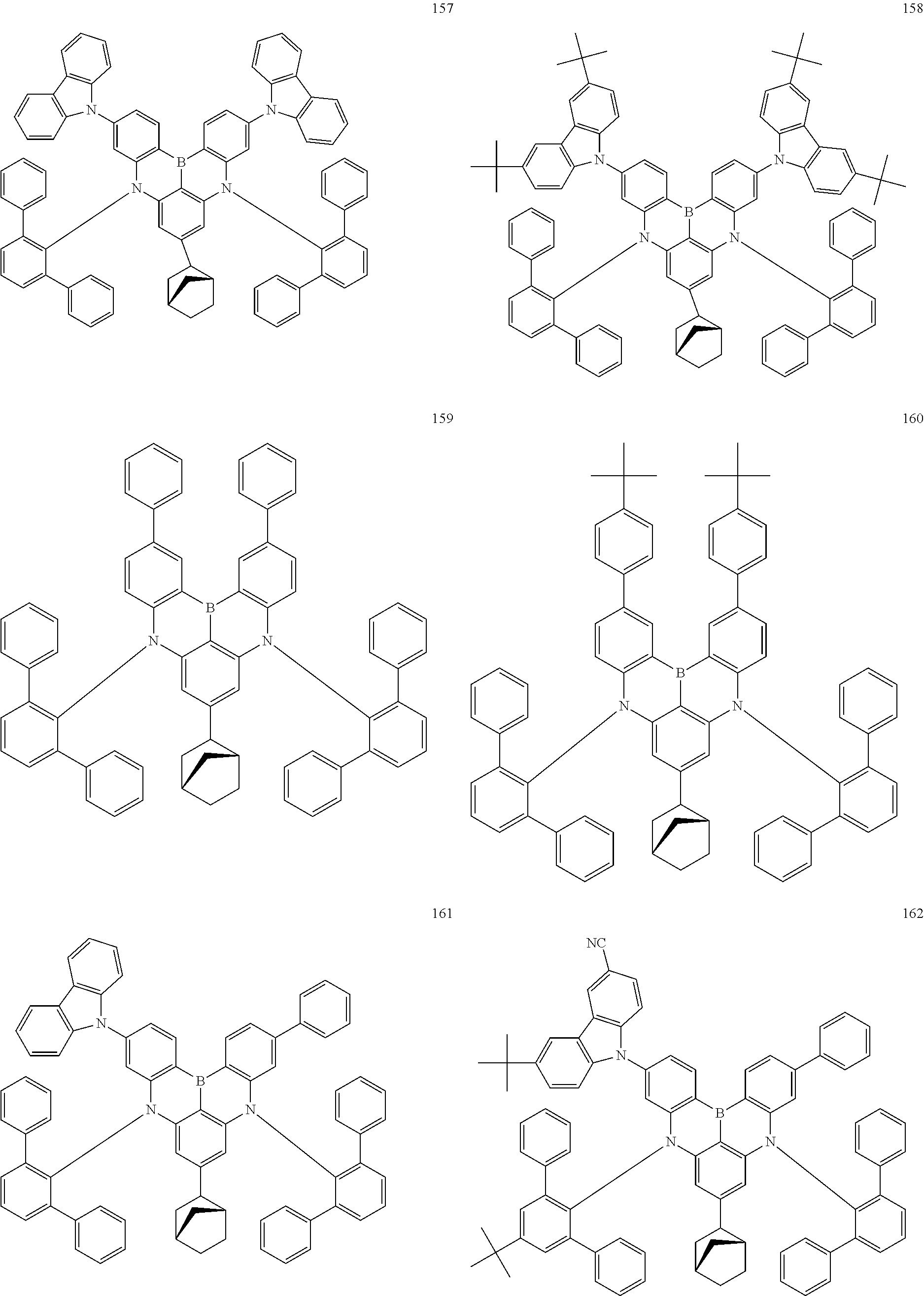 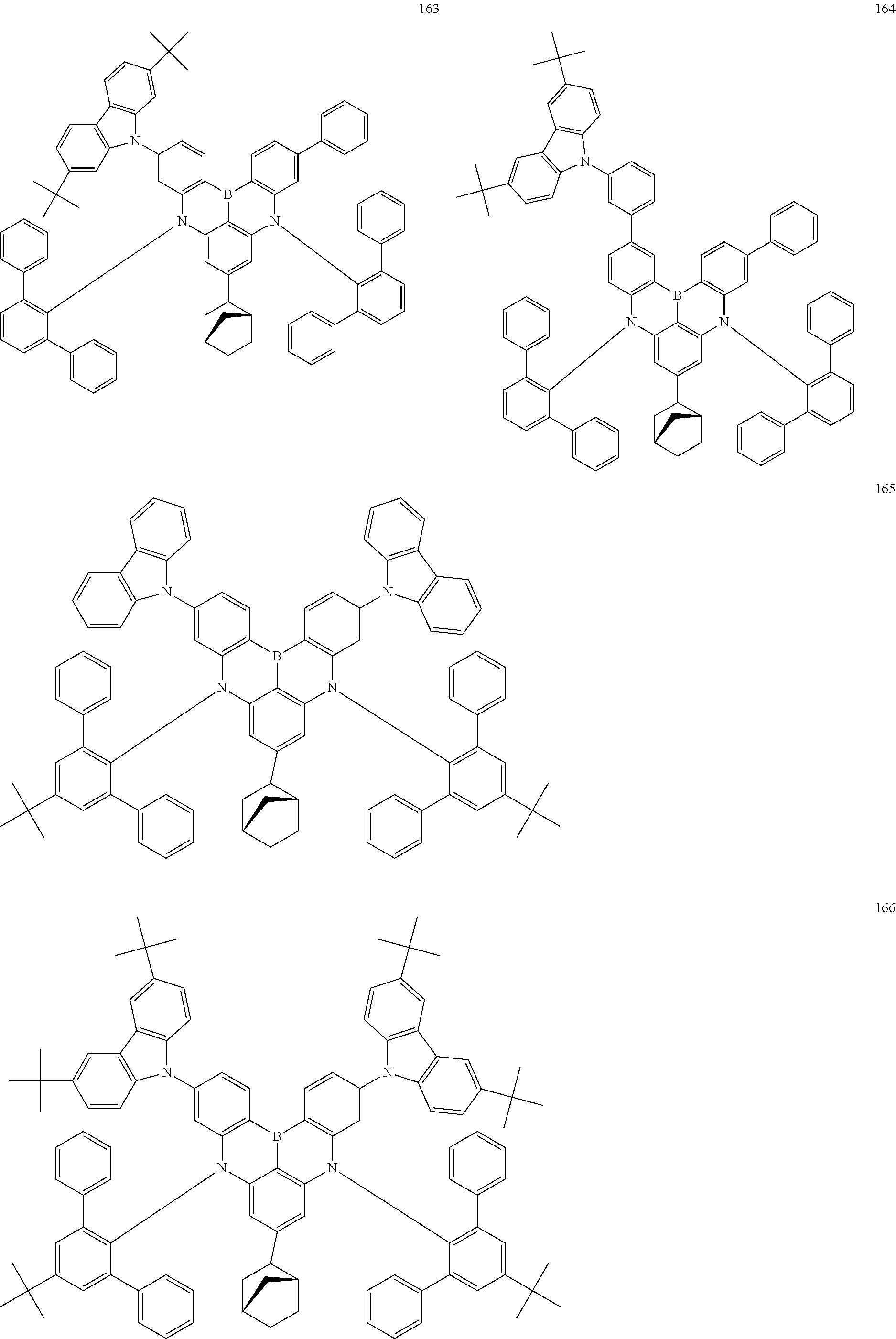 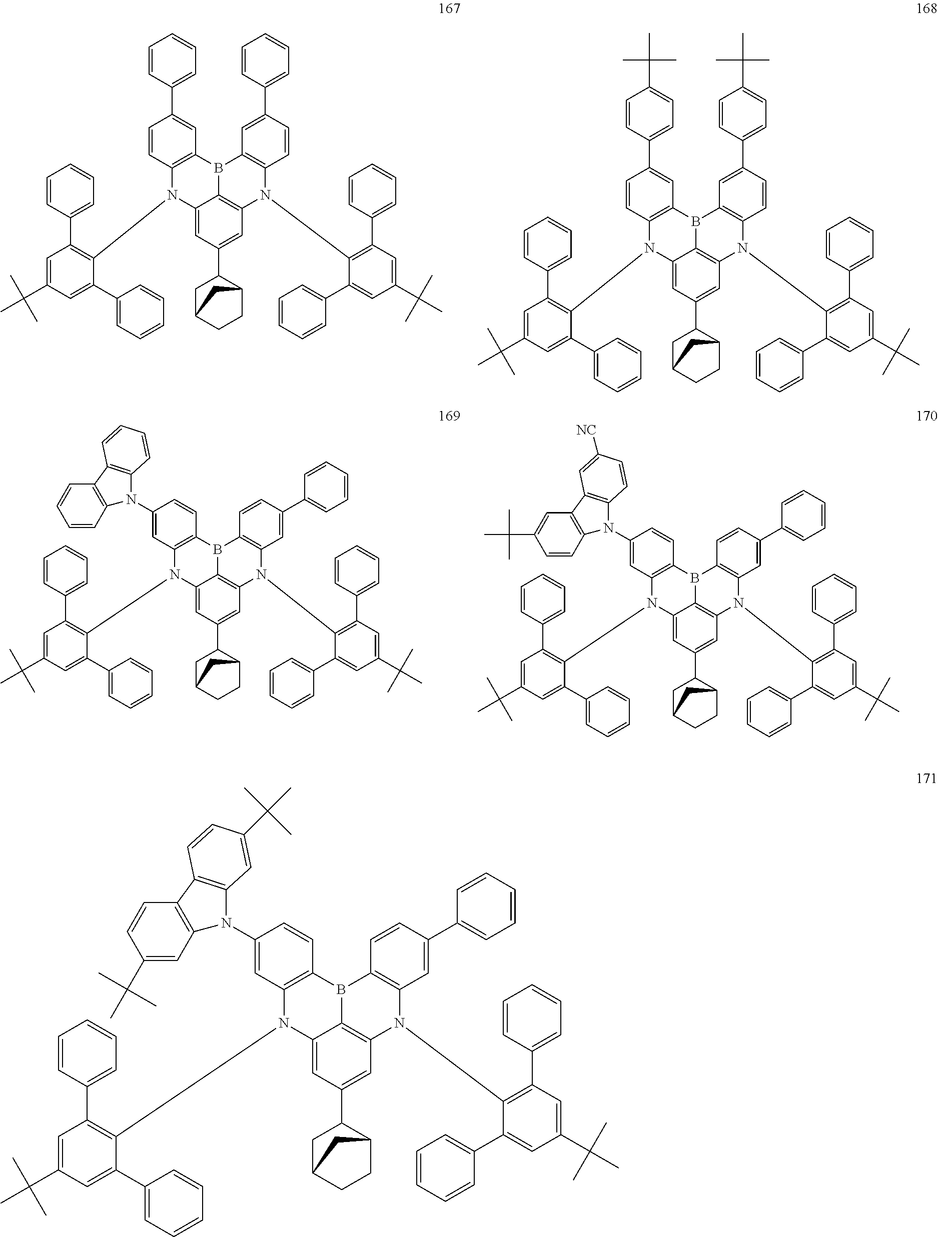 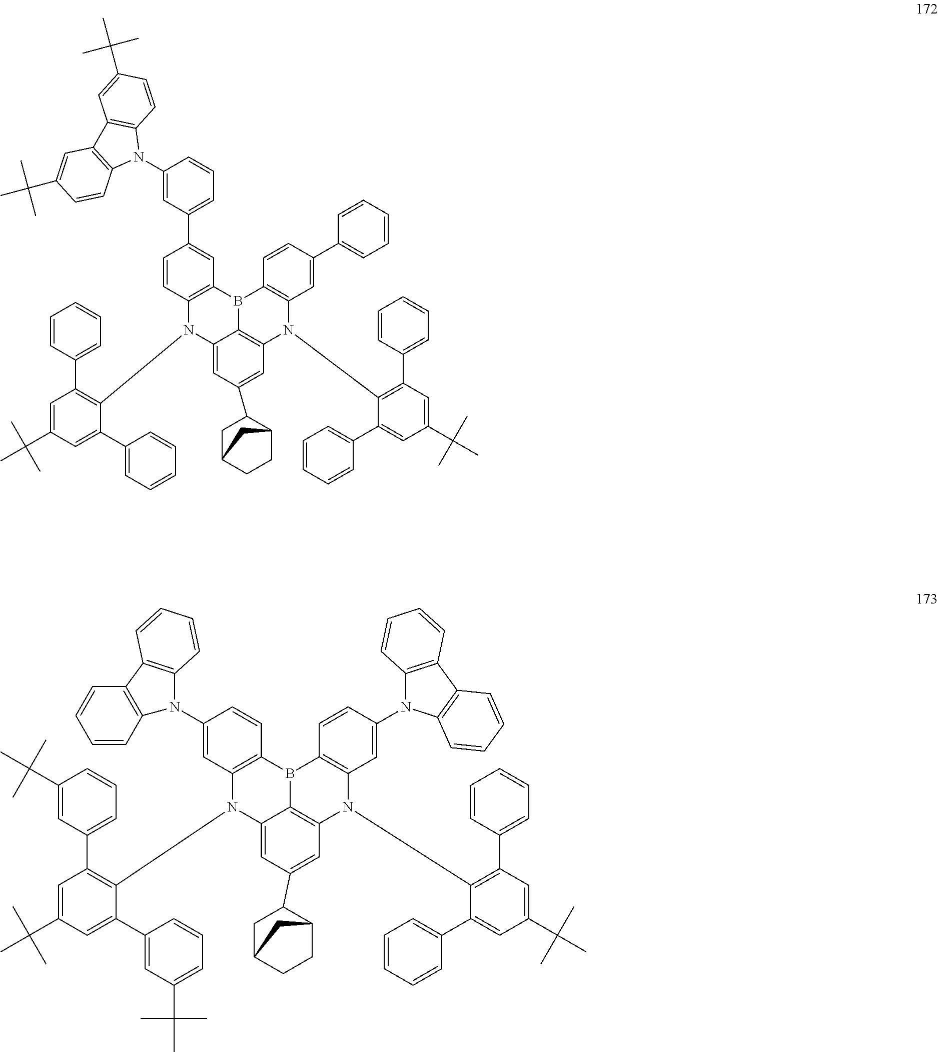 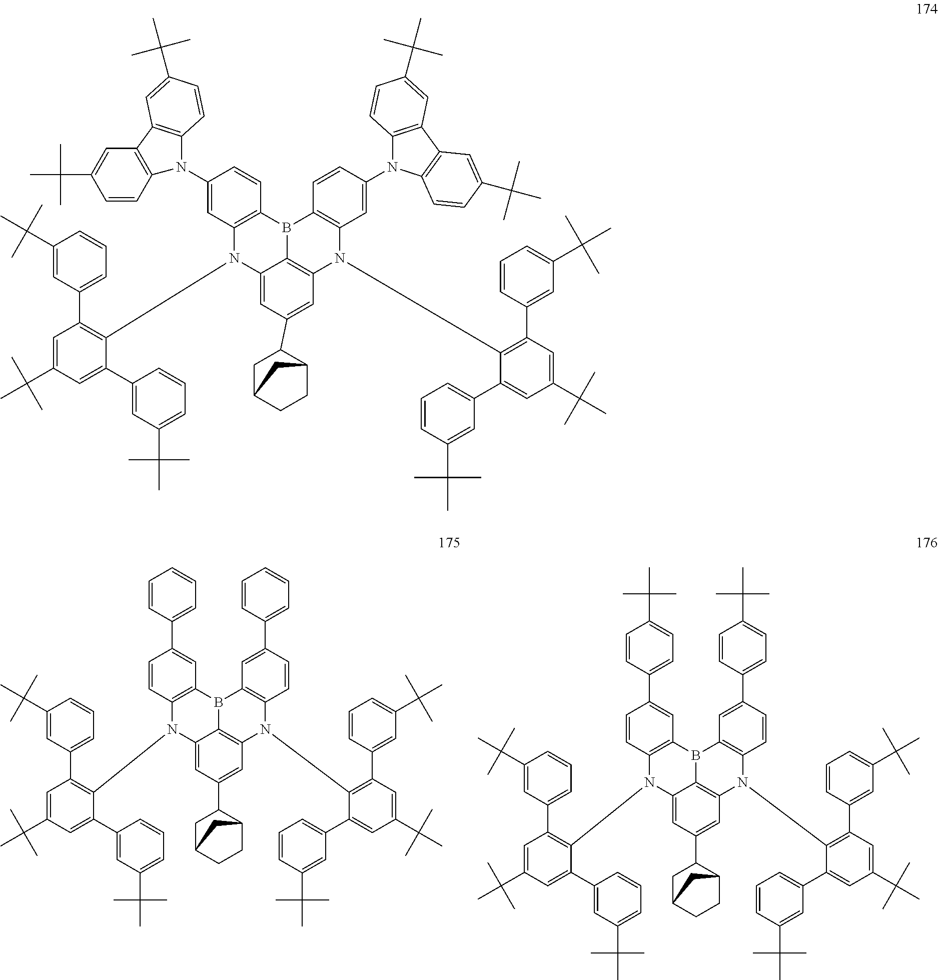 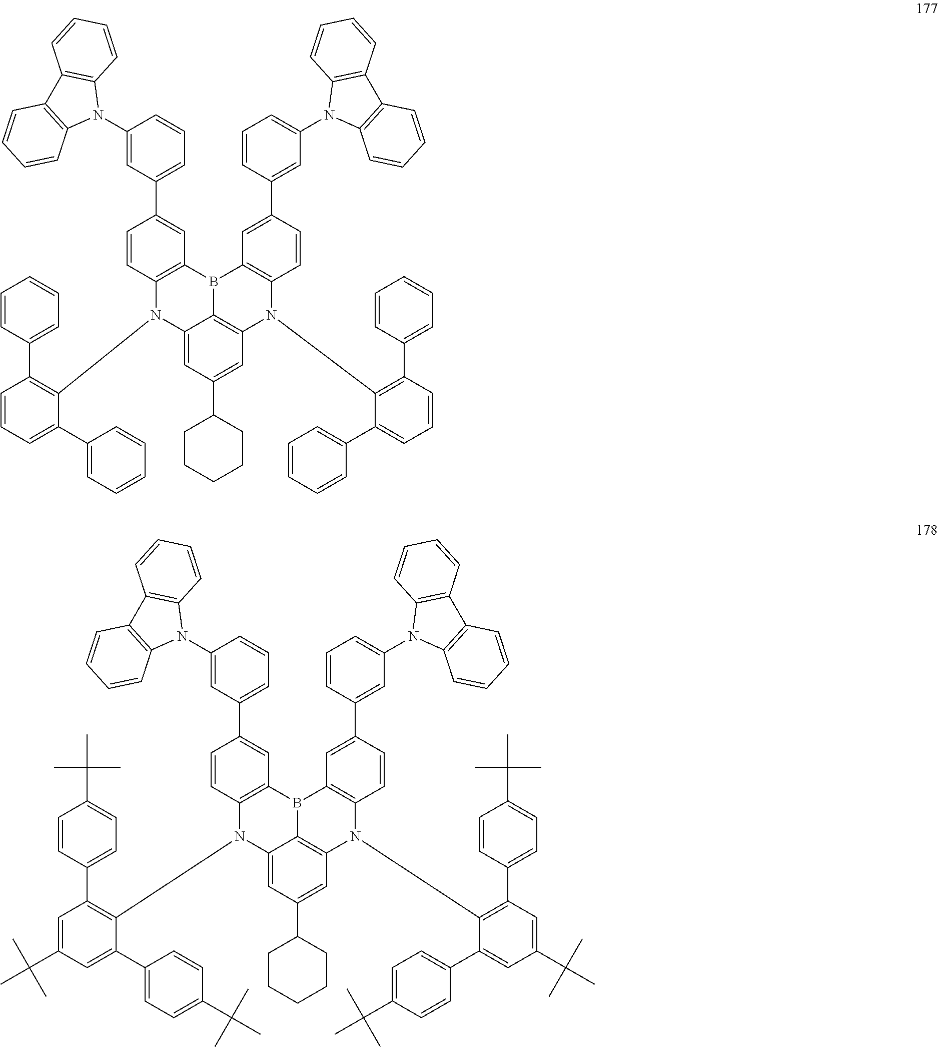 [SMILES: c1ccc(-c2cccc(-c3ccccc3)c2N2c3ccc(-c4cccc(-n5c6ccccc6c6ccccc65)c4)cc3B3c4cc(-c5cccc(-n6c7ccccc7c7ccccc76)c5)ccc4N(c4c(-c5ccccc5)cccc4-c4ccccc4)c4cc(C5CCCCC5)cc2c43)cc1 ; CC(C)(C)c1ccc(-c2cc(C(C)(C)C)cc(-c3ccc(C(C)(C)C)cc3)c2N2c3ccc(-c4cccc(-n5c6ccccc6c6ccccc65)c4)cc3B3c4cc(-c5cccc(-n6c7ccccc7c7ccccc76)c5)ccc4N(c4c(-c5ccc(C(C)(C)C)cc5)cc(C(C)(C)C)cc4-c4ccc(C(C)(C)C)cc4)c4cc(C5CCCCC5)cc2c43)cc1] 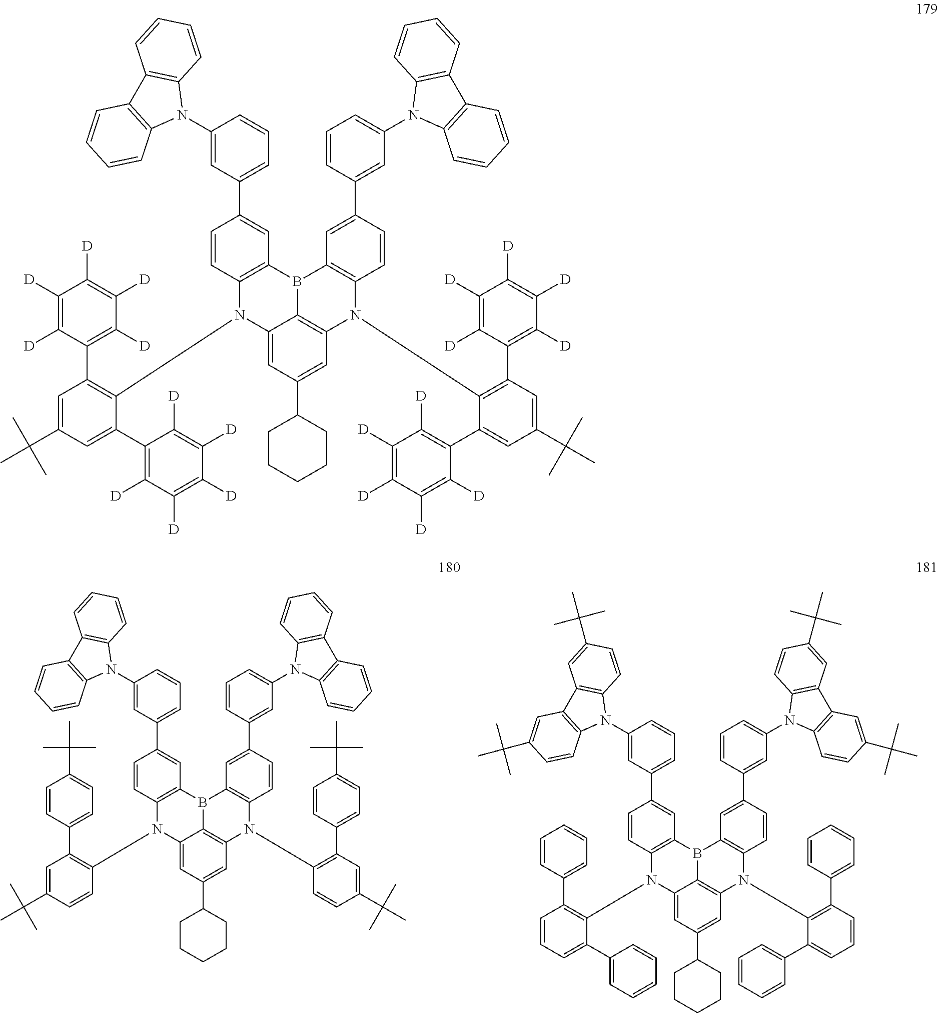 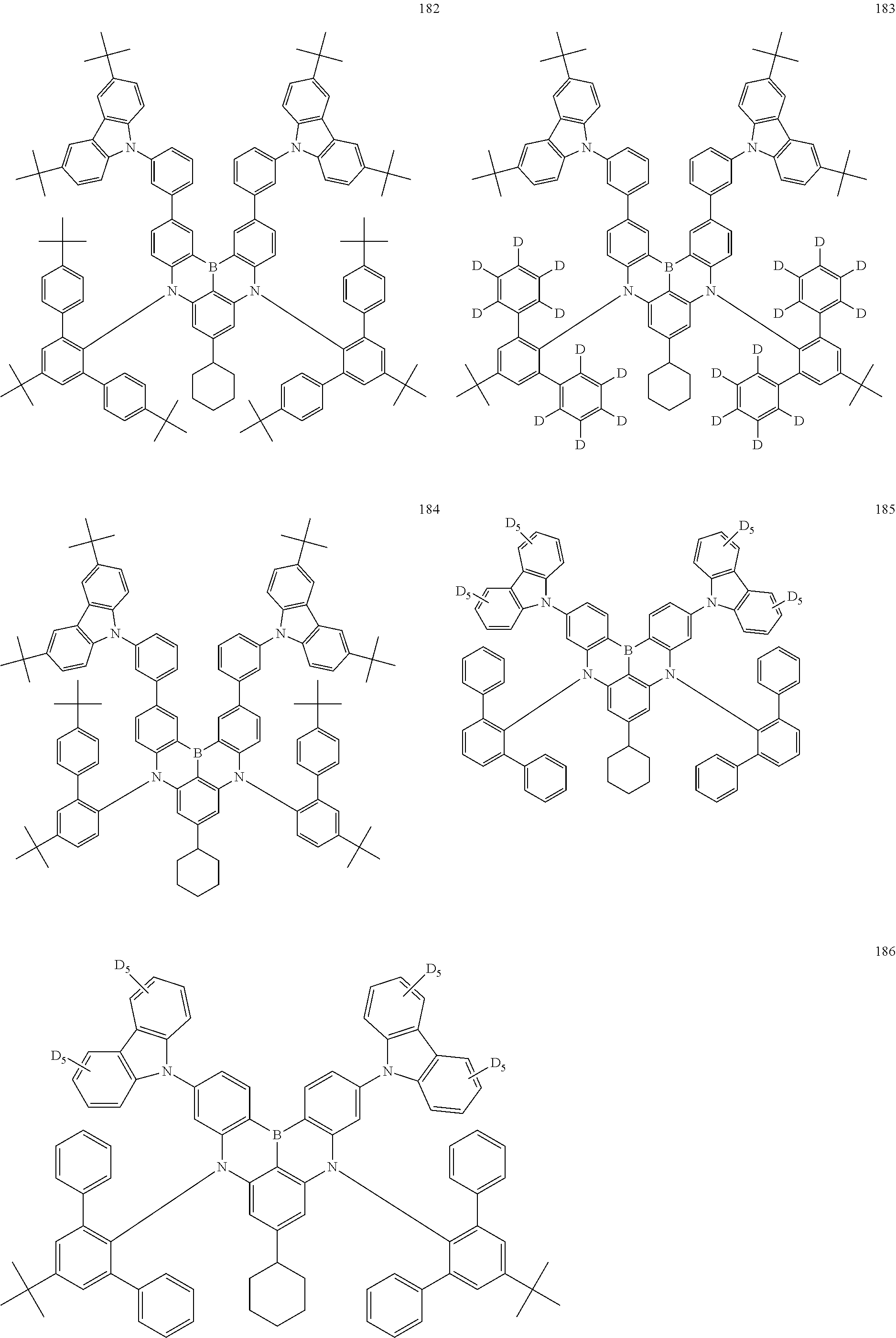 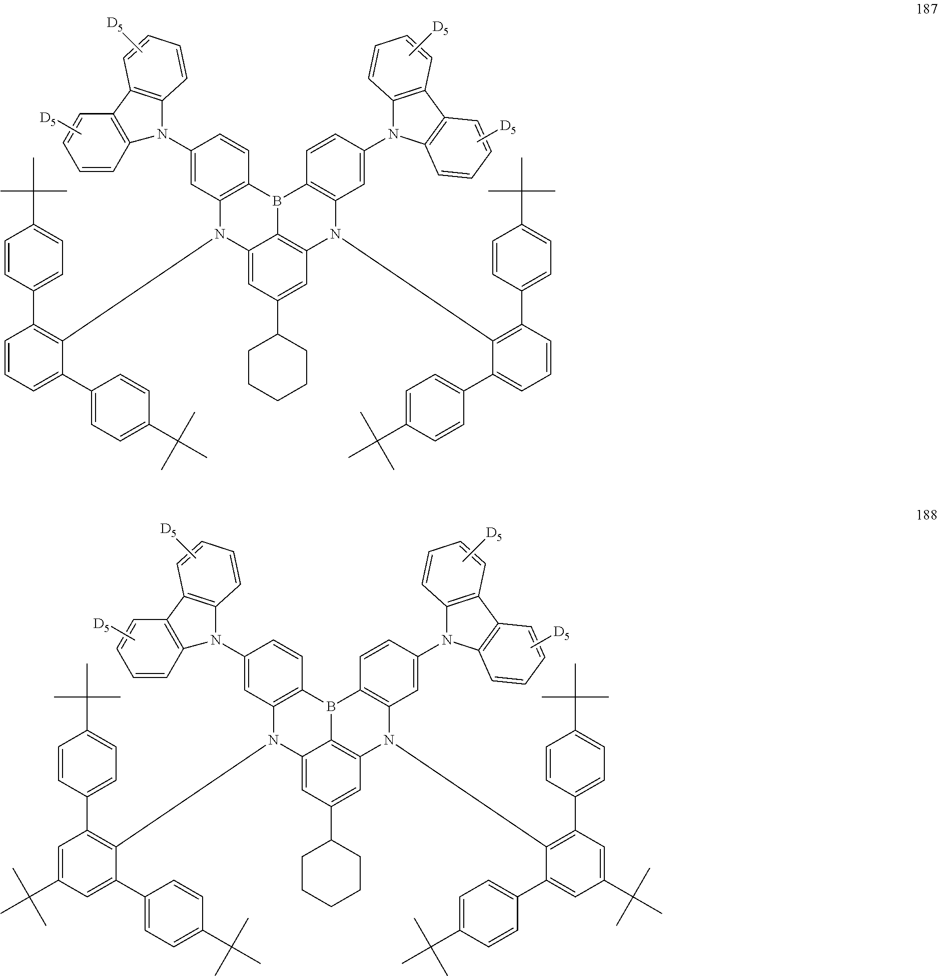 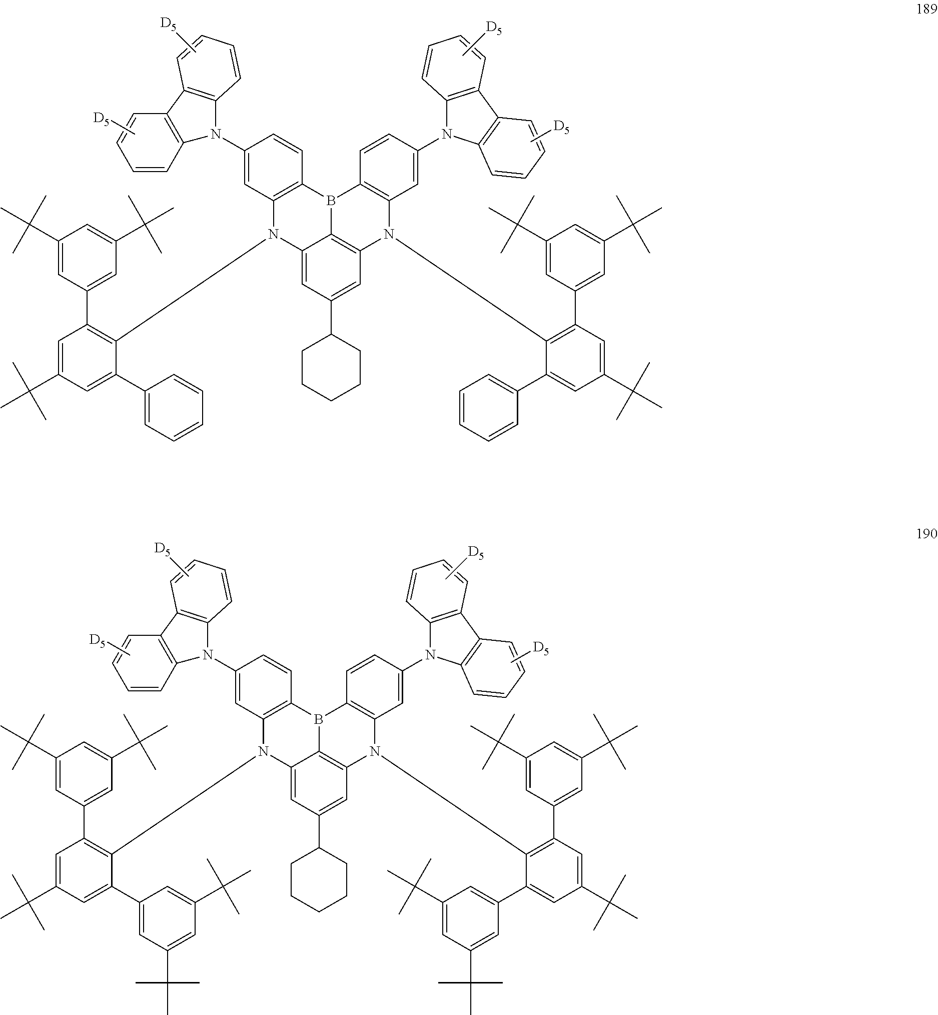 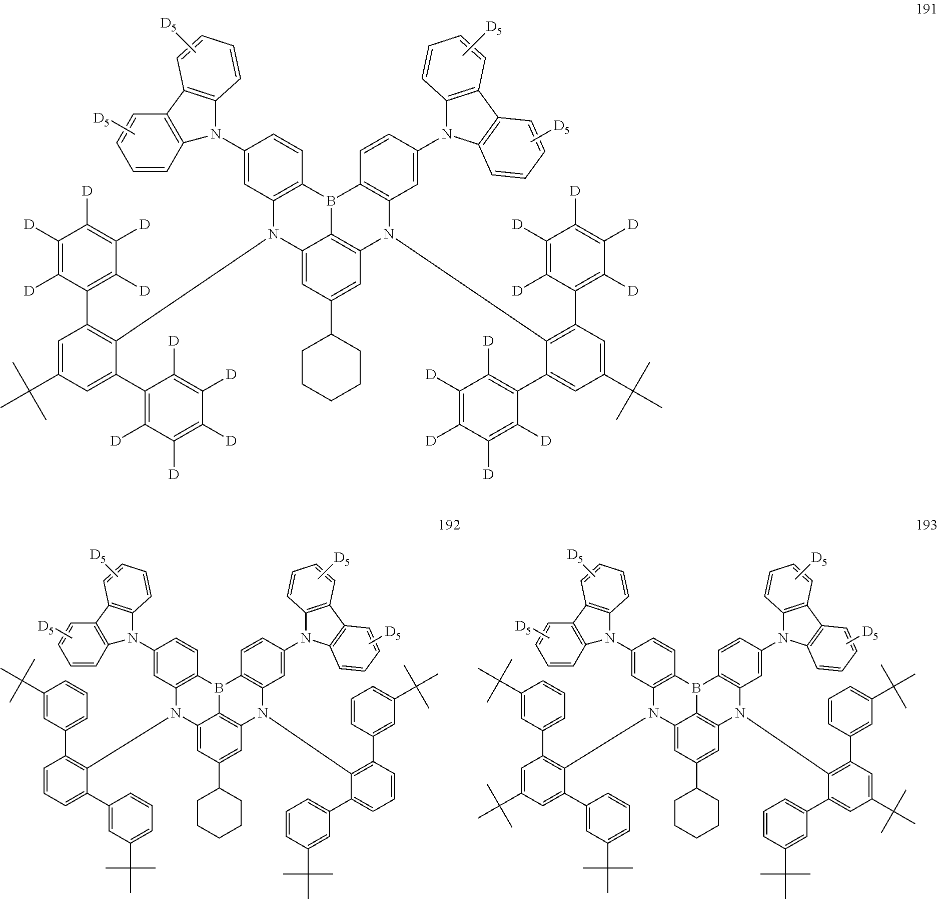 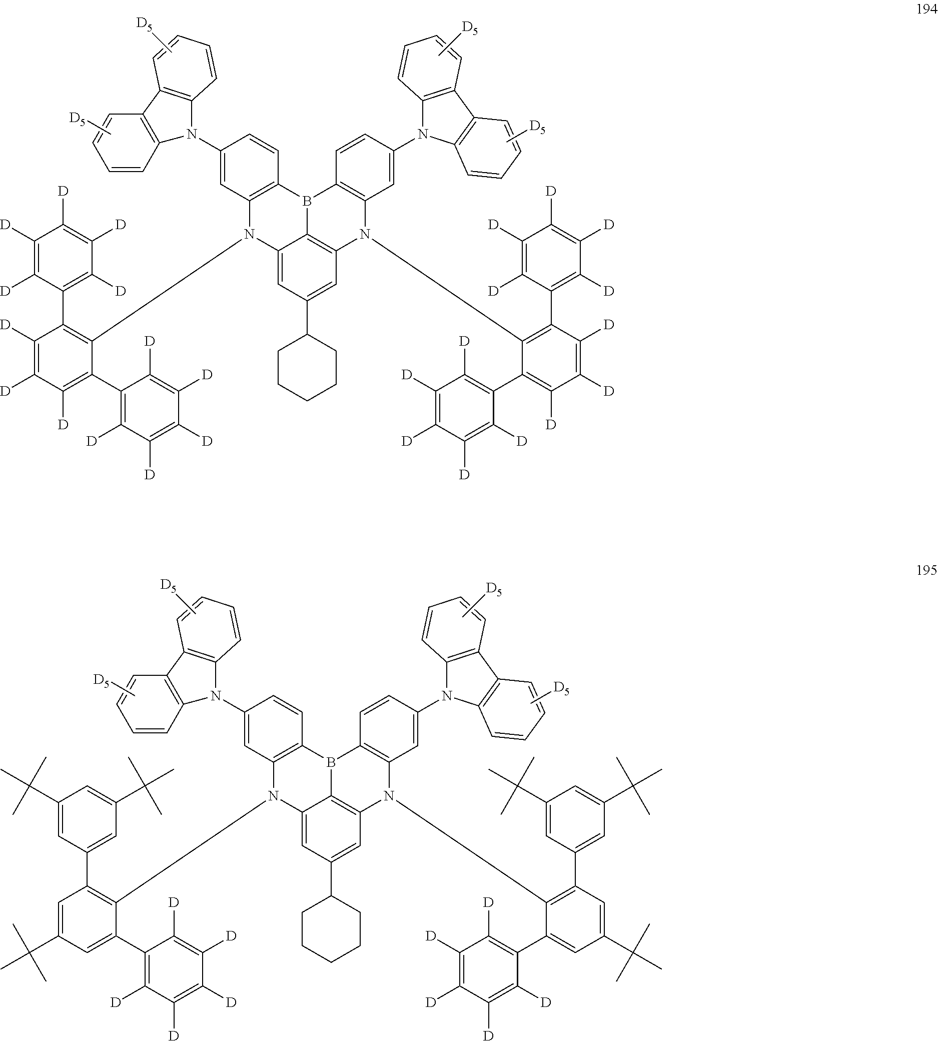 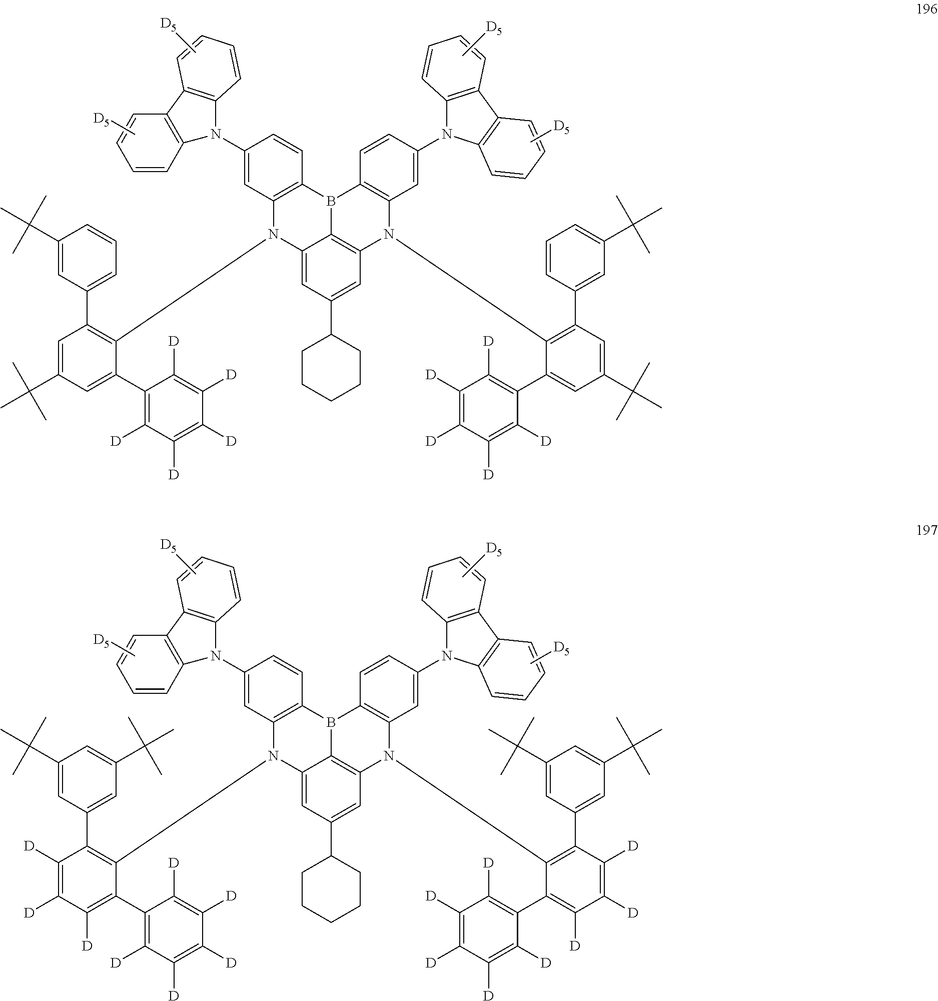 [chemical structure]
